(19) United States
(12) Patent Application Publication
(10) Pub. No.: US 2025/0221303 A1
(43) Pub. Date: Jul. 3, 2025

(54) ORGANIC COMPOUNDS AND ORGANIC LIGHT EMITTING DIODE COMPRISING THE SAME

(71) Applicant: Material Science Co., Ltd., Hwaseong-si (KR)

(72) Inventors: Kwang Seok DO, Hwaseong-si (KR); Won Bin KIM, Hwaseong-si (KR); Ran CHOE, Hwaseong-si (KR); Sang Hoon HONG, Hwaseong-si (KR)

(21) Appl. No.: 19/001,059

(22) Filed: Dec. 24, 2024

(30) Foreign Application Priority Data
Dec. 28, 2023 (KR) 10-2023-0195194
Dec. 18, 2024 (KR) 10-2024-0190173

(51) Int. Cl. H10K 85/60; C07F 5/02; C09K 11/06; H10K 50/12

(52) U.S. Cl. CPC H10K 85/636; C07F 5/027; C09K 11/06; H10K 85/633; C09K 2211/1007; C09K 2211/1011; C09K 2211/1014; C09K 2211/1022; H10K 50/12; H10K 85/615; H10K 85/6572; H10K 85/6574; H10K 85/6576; H10K 85/658

(57) ABSTRACT

An organic compound represented by Chemical Formula 1 and an organic light emitting diode including the same. Comprising the organic compound represented by Chemical Formula 1 into an emitting layer provides reduced driving voltage, enhanced luminous efficacy, and increased lifetime of organic light emitting diodes.

### CROSS-REFERENCE TO RELATED APPLICATION

This application claims priority from Korean Patent Application No. 10-2023-0195194 filed on Dec. 28, 2023 and Korean Patent Application No. 10-2024-0190173 filed on Dec. 18, 2024 in the Korean Intellectual Property Office, and all the benefits accruing therefrom under 35 U.S.C. 119, the contents of which in its entirety are herein incorporated by reference.

### FIELD

The present invention relates to an organic compound and an organic light emitting diode including the same.

### BACKGROUND

Organic light emitting diode (OLED) displays have a simple structure, offer various manufacturing benefits, and have high luminance, wide viewing angle, fast response time, and low driving voltage, as compared to other typical flat-panel displays such as liquid crystal displays (LCDs), plasma display panels (PDPs), and field emission displays (FEDs). Due to these advantages, OLEDs are being actively developed and commercialized for use in flat-panel displays such as wall-mounted TVs, backlights for displays, and light sources for advertisement panels.

An organic light emitting diode includes an organic layer interposed between a pair of electrodes. Electrons and holes injected from the respective electrodes into an emitting layer recombine within the emitting layer to generate excitons. Relaxation of these excitons from an excited state to a ground state results in emission of light.

Organic light emitting diodes may include at least one emitting layer. Generally, such organic light emitting diodes include emitting layers that emit light having different peak wavelengths to realize specific colors through combination of the lights having different peak wavelengths.

These organic light emitting diodes may be classified into top-emission OLEDs and bottom-emission OLEDs. In top-emission OLEDs, a reflective second electrode (cathode) is used to reflect light generated from an emitting layer toward a semi-transparent first electrode (anode). On the other hand, in bottom-emission OLEDs, a reflective first electrode (anode) is used to reflect light generated from an emitting layer toward a transparent second electrode (cathode), that is, in the direction of a thin-film transistor.

### PRIOR ART REFERENCE

[Patent Document] CN 117024455 A

### SUMMARY

It is an object of the present invention to provide a novel organic compound and an organic light emitting diode including the same.

Exemplary embodiments of the present invention may be used to achieve the above and other objects.

The present invention is not limited thereto and other objects and advantages of the present invention will be apparent to those skilled in the art from the detailed description of the following embodiments. In addition, it will be understood that the objects and advantages of the present invention can be realized by features set forth in the claims and combinations thereof.

In accordance with one aspect of the present invention, there is provided an organic compound represented by Chemical Formula 1:

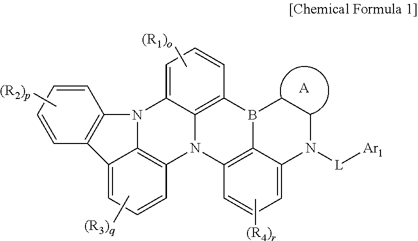

where circle A has a structure selected from among structures (A-1) and (A-2):

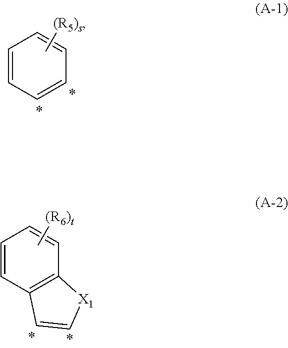

(where * is a linking site and X₁ is oxygen (O) or sulfur (S));
o, q, and r are integers selected from among 0 to 3, and p, s, and t are integers selected from among 0 to 4;
L is a single bond or a substituted or unsubstituted C₆ to C₃₀ arylene group;
Ar₁ is selected from among a substituted or unsubstituted C₆ to C₃₀ aryl group, a substituted or unsubstituted C₅ to C₆₀ heteroaryl group, a substituted or unsubstituted C₆ to

C₃₀ arylamino group, and a compound represented by Formula a1

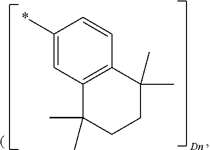

where Dn denotes the number of substituted deuterium atoms therein, n being an integer selected from among 0 to 3);

R₁ to R₆ are identical to each other or different from each other, are each independently selected from the group consisting of hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group, and form a structure represented by Formula b

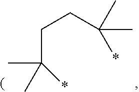 [SMILES: *C(C)(C)CCC(*)(C)C]

where * is a linking site) with a functional group adjacent thereto; and,
when substituted, L, Ar₁, and R₁ to R₆ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group, and, when a plurality of substituents is used, the substituents are identical to each other or different from each other.

In accordance with another aspect of the present invention, there is provided an organic light emitting diode including: a first electrode; a second electrode facing the first electrode; and one or more organic layers disposed between the first electrode and the second electrode, wherein at least one of the organic layers includes the organic compound represented by Chemical Formula 1.

The organic light emitting diode including the organic compound represented by Chemical Formula 1 according to the present invention can have reduced driving voltage, enhanced luminous efficacy, and increased lifetime. Furthermore, the organic compound represented by Chemical Formula 1 can ensure high color rendering index and color purity, especially in blue or green emitting layers.

The effects of the present invention are not limited thereto and other effects will be apparent to those skilled in the art from the detailed description of the following embodiments.

The aforementioned effects and additional benefits will be described in detail below.

### DETAILED DESCRIPTION

The aforementioned objects, features, and advantages will be described in detail below such that a person having ordinary knowledge in the art to which the present invention pertains can readily practice the invention.

Description of known functions and constructions which may unnecessarily obscure the subject matter of the present invention will be omitted.

As used herein, the terms “includes”, “comprises”, “has”, “contains”, “including”, “comprising”, “having”, and/or “containing” specify the presence of stated features, steps, operations, elements, and/or components, but do not preclude the presence or addition of one or more other features, steps, operations, elements, components, and/or groups unless such terms are preceded by “only”. As used herein, the singular forms “a”, “an”, and “the” are intended to include the plural forms as well, unless the context clearly indicates otherwise.

A numerical value related to a certain component is construed to include a tolerance range in interpretation of components, unless clearly stated otherwise.

When an element such as a layer, film, region or substrate is referred to as being placed “above (or below)” or “on (or under)” another element, it can be directly placed on the other element, or intervening layer(s) may also be present.

As used herein, the term “halogen group” includes fluorine, chlorine, bromine, and iodine.

As used herein, the term “alkyl group” refers to both a linear alkyl radical and a branched alkyl radical. Unless specified otherwise, the alkyl group contains 1 to 30 carbon atoms and may include methyl, ethyl, propyl, isopropyl, butyl, sec-butyl, isobutyl, tert-butyl, pentyl, isoamyl, and hexyl groups, without being limited thereto. Additionally, the alkyl group may be arbitrarily substituted.

As used herein, the term “cycloalkyl group” refers to a cyclic alkyl radical. Unless specified otherwise, the cycloalkyl group contains 3 to 20 carbon atoms and may include cyclopropyl, cyclobutyl, cyclopentyl, cyclohexyl, norbornyl, and adamantyl groups, without being limited thereto. Additionally, the cycloalkyl group may be arbitrarily substituted.

As used herein, the term “alkenyl group” refers to both linear and branched alkenyl radicals having at least one carbon-carbon double bond. Unless specified otherwise, the alkenyl group contains 2 to 30 carbon atoms and may include vinyl, allyl, isopropenyl, and 2-butenyl groups, without being limited thereto. Additionally, the alkenyl group may be arbitrarily substituted.

As used herein, the term “cycloalkenyl group” refers to a cyclic alkenyl radical. Unless specified otherwise, the cycloalkenyl group contains 3 to 20 carbon atoms. Additionally, the cycloalkenyl group may be arbitrarily substituted.

As used herein, the term “alkynyl group” refers to both linear and branched alkynyl radicals having at least one carbon-carbon triple bond. Unless specified otherwise, the alkynyl group contains 2 to 30 carbon atoms and may include ethynyl and 2-propynyl groups. Additionally, the alkynyl group may be arbitrarily substituted.

As used herein, the term “cycloalkynyl group” refers to a cyclic alkynyl radical. Unless specified otherwise, the cycloalkynyl group contains 3 to 20 carbon atoms. Additionally, the cycloalkynyl group may be arbitrarily substituted.

As used herein, the terms “aralkyl group” or “arylalkyl group” are used interchangeably and refer to an alkyl group having an aromatic group as a substituent. Additionally, the aralkyl (arylalkyl) group may be arbitrarily substituted.

As used herein, the terms “aryl group” or “aromatic group” are used interchangeably, and the aryl group includes both monocyclic and polycyclic ring structures. A polycyclic ring may include a “condensed ring”, which refers to two or more rings in which two carbons are shared by two adjoining rings. In addition, the polycyclic ring may also include two or more rings simply attached to each other or condensed. Unless specified otherwise, the aryl group contains 6 to 30 carbon atoms and may include phenyl, naphthyl, anthracenyl, phenanthryl, fluorenyl, dimethylfluorenyl, diphenylfluorenyl, and spirofluorenyl groups, without being limited thereto. Additionally, the aryl group may be arbitrarily substituted.

As used herein, the terms “heteroaryl group” or “heteroaromatic group” are used interchangeably, and the heteroaryl group includes both monocyclic and polycyclic groups. A polycyclic ring may include a “condensed ring”, which refers to two or more rings in which two carbon atoms or two hetero elements are shared by two adjoining rings. The polycyclic ring may also include two or more rings simply attached to each other or condensed. Unless specified otherwise, the heteroaryl group contains 5 to 60 carbon atoms and may further contain an additional hetero element to form a ring with 1 or 2 carbon atoms. In addition, the heteroaryl group may contain 1 to 30 carbon atoms, wherein at least one carbon atom in a ring is substituted with a heteroatom, such as oxygen (O), nitrogen (N), sulfur (S), or selenium (Se), and may include: 6-membered monocyclic rings, such as pyridyl, pyrazinyl, pyrimidinyl, pyridazinyl, and triazinyl; polycyclic rings, such as phenoxathiinyl, indolizinyl, indolyl, purinyl, quinolyl, isoquinolyl, benzoxazolyl, benzothiazolyl, dibenzoxazolyl, dibenzothiazolyl, benzoimidazolyl, benzofuranyl, dibenzofuranyl, benzothiophenyl, dibenzothiophenyl, phenylcarbazolyl, 9-phenylcarbazolyl, and carbazolyl; 2-furanyl; N-imidazolyl; 2-isoxazolyl; 2-pyridinyl; and 2-pyrimidinyl, without being limited thereto. Additionally, the heteroaryl group may be arbitrarily substituted.

As used herein, the term “heterocyclic group” means that at least one of the carbon atoms constituting an aryl group, a cycloalkyl group, a cycloalkenyl group, a cycloalkynyl group, an arylalkyl group, an arylamino group, or the like is substituted with a heteroatom such as oxygen (O), nitrogen (N), sulfur (S), or the like. With reference to the above definition, the heterocyclic group may include a heterocycloalkyl group, a heterocycloalkenyl group, a heterocycloalkynyl group, a heteroarylalkyl group, a heteroarylamino group, and the like. Additionally, the heterocyclic group may be arbitrarily substituted.

As used herein, the term “carbon ring” may be used to include both a cycloaliphatic ring group, such as “cycloalkyl”, “cycloalkenyl”, “cycloalkynyl”, and an aromatic ring group, such as “aryl”, unless specified otherwise.

As used herein, the terms “heteroalkyl group”, “heteroalkenyl group”, “heteroalkynyl group”, and “heteroarylalkyl group” mean that at least one of the carbon atoms constituting a corresponding group is substituted with a heteroatom such as oxygen (O), nitrogen (N), sulfur (S), or the like. Additionally, the heteroalkyl group, the heteroalkenyl group, the heteroalkynyl group, and the heteroarylalkyl group may be arbitrarily substituted.

As used herein, the terms “alkylamino group”, “arylalkylamino group”, “arylamino group”, and “heteroarylamino group” refer to an amino group (or amine group) substituted with the alkyl, arylalkyl, aryl, or heteroaryl group, and may include primary, secondary, and tertiary amino groups. Additionally, the alkylamino group, the arylalkylamino group, the arylamino group, and the heteroarylamino group may be arbitrarily substituted.

As used herein, the terms “alkylsilyl group”, “arylsilyl group”, “alkoxy group”, “aryloxy group”, “alkylthio group”, and “arylthio group” refer to silyl, oxy, and thio groups substituted with the alkyl and aryl groups, respectively. Additionally, the alkylsilyl group, the arylsilyl group, the alkoxy group, the aryloxy group, the alkylthio group, and the arylthio group may be arbitrarily substituted.

As used herein, the terms “arylene group”, “arylalkylene group”, “heteroarylene group”, and “heteroarylalkylene group” mean that each of the aryl, arylalkyl, heteroaryl, and heteroarylalkyl groups is a bivalent substitution product containing at least one additional substituent. Additionally, the arylene group, the arylalkylene group, the heteroarylene group, and the heteroarylalkylene group may be arbitrarily substituted.

As used herein, the term “substituted” means that a hydrogen (H) atom bonded to a carbon atom of a compound of the invention is replaced by a substituent other than hydrogen, and, when two or more substituents are present, each of the substituents may be the same or different.

Each of the substituents may be independently selected from the group consisting of deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group.

Unless specified otherwise herein, a substitution position is not particularly restricted so long as a corresponding hydrogen atom can be substituted with a substituent, and when two or more substituents are present, the substituents may be identical to each other or different from each other.

Unless mentioned otherwise, each entity and substituent defined herein may be the same or different.

Unless stated otherwise, a unit of measure as used herein is based on weight (wt). For example, “%” refers to percent by weight (wt %).

Hereinafter, an organic compound according to the present invention and an organic light emitting diode including the same will be described in detail.

The organic compound according to the present invention may be represented by Chemical Formula 1.

[Chemical Formula 1]

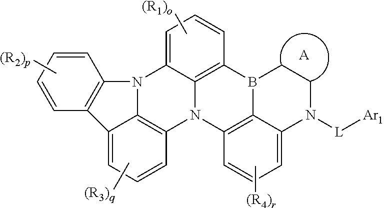

where circle A has a structure selected from among structures (A-1) and (A-2):

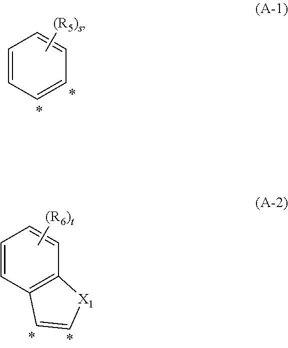

(where * is a linking site and X₁ is oxygen (O) or sulfur (S));
o, q, and r are integers selected from among 0 to 3, and p, s, and t are integers selected from among 0 to 4;
L is a single bond or a substituted or unsubstituted C₆ to C₃₀ arylene group;
Ar₁ is selected from among a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted C₆ to C₃₀ arylamino group, a substituted or unsubstituted C₆ to C₃₀ arylalkylamino group, a substituted or unsubstituted C₅ to C₆₀ heteroarylamino group, a substituted or unsubstituted C₆ to C₃₀ arylsilyl group, a substituted or unsubstituted C₆ to C₃₀ aryloxy group, and a compound represented by Formula a1

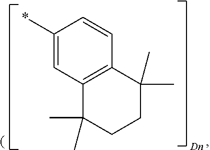

where Dn denotes the number of substituted deuterium atoms therein, n being an integer selected from among 0 to 3);
R₁ to R₆ are identical to each other or different from each other, are each independently one selected from the group consisting of hydrogen, deuterium, a cyano group, a trifluoromethyl group, a nitro group, a halogen group, a hydroxyl group, a trimethylsilyl group (TMS), a substituted or unsubstituted C₁ to C₃₀ alkyl group, a substituted or unsubstituted C₃ to C₂₀ cycloalkyl group, a substituted or unsubstituted C₂ to C₃₀ alkenyl group, a substituted or unsubstituted C₃ to C₂₀ cycloalkenyl group, a substituted or unsubstituted C₂ to C₃₀ alkynyl group, a substituted or unsubstituted C₃ to C₂₀ cycloalkynyl group, a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted amine group, a substituted or unsubstituted C₁ to C₃₀ alkylamino group, a substituted or unsubstituted C₇ to C₃₀ arylalkylamino group, a substituted or unsubstituted C₆ to C₃₀ arylamino group, a substituted or unsubstituted C₅ to C₆₀ heteroarylamino group, a substituted or unsubstituted silyl group, a substituted or unsubstituted C₁ to C₃₀ alkylsilyl group, a substituted or unsubstituted C₆ to C₃₀ arylsilyl group, a substituted or unsubstituted C₁ to C₃₀ alkoxy group, a substituted or unsubstituted C₆ to C₃₀ aryloxy group, a substituted or unsubstituted C₁ to C₃₀ alkylthio group, and a substituted or unsubstituted C₆ to C₃₀ arylthio group, and form a structure represented by Formula b

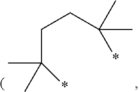 [SMILES: *C(C)(C)CCC(*)(C)C]

where * is a linking site) with a functional group adjacent thereto; and,

when substituted, L, Ar₁, and R₁ to R₆ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other and form a substituted or unsubstituted ring with a functional group adjacent thereto.

According to one embodiment, in Chemical Formula 1, circle A has a structure selected from among structures (A-1) and (A-2):

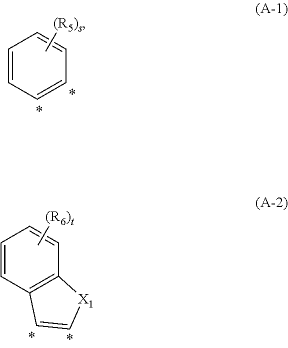

(where * is a linking site and X₁ is oxygen (O) or sulfur (S));
o, q, and r are integers selected from among 0 to 3, and p, s, and t are integers selected from among 0 to 4;
L is a single bond or a substituted or unsubstituted C₆ to C₃₀ arylene group;
Ar₁ is selected from among a substituted or unsubstituted C₆ to C₃₀ aryl group, a substituted or unsubstituted C₅ to C₆₀ heteroaryl group, a substituted or unsubstituted C₆ to C₃₀ arylamino group, and the compound represented by Formula a1

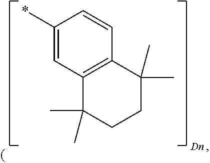

where Dn denotes the number of substituted deuterium atoms therein, n being an integer selected from among 0 to 3);
R₁ to R₆ are identical to each other or different from each other, are each independently one selected from the group consisting of hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group, and form the structure represented by Formula b

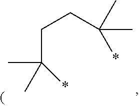 [SMILES: *C(C)(C)CCC(*)(C)C]

where * is a linking site) with a functional group adjacent thereto; and,
when substituted, L, Ar₁, and R₁ to R₆ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

The organic compound represented by Chemical Formula 1 is a boron-based dopant and has a polycyclic aromatic structure with a core structure containing boron (B) and nitrogen (N) atoms on the right and left sides of boron. The organic compound has a structural feature in which the nitrogen atom on the left side of the core is fused to a carbazole group, the nitrogen atom on the right side of the core is fused to circle A together with boron to form a fused ring, and Ar₁ is bonded to the nitrogen atom on the right side of a backbone including the core structure via a linker L. As such, fusion of the carbazole group to the left side of the core and fusion of circle A to the right side of the core suppress structural deformation of molecules, and a resonance structure spread within the molecules through connection between multiple aromatic rings as depicted in Chemical Formula 1 ensures a stable structure, thereby enhancing stability of the organic compound represented by Chemical Formula 1. Accordingly, for example when used in organic light emitting diodes as a dopant in the light-emitting layer, the compound represented by Chemical Formula 1 can provide improved properties to the diode such as longer lifetime. Furthermore, due to the extended conjugated structure thereof, the compound represented by Chemical Formula 1 may be used as a dopant of an emitting layer, for example, a green emitting layer or a blue emitting layer, preferably a green emitting layer. Additionally, due to the substituent (R₄) introduced onto a benzene ring located at a bottom of the backbone containing the core, the compound represented by Chemical Formula 1 can have a narrower full width at half maximum (FWHM) even in the green spectrum. This feature allows fine-tuning to a specific wavelength in the green spectrum, thereby ensuring effective improvement in color gamut and enhancement in luminous efficacy. According to one embodiment of the present invention, Chemical Formula 1 may be represented by one of Chemical Formulas 2 to 4.

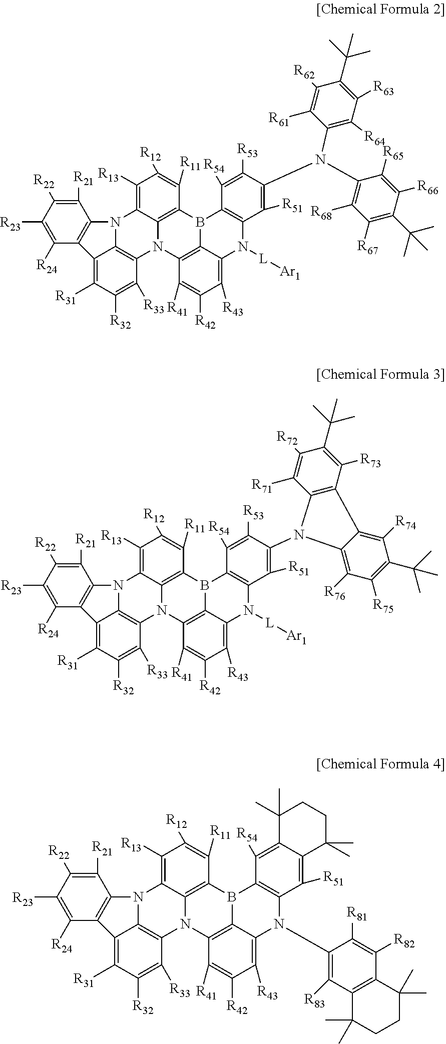

In Chemical Formulas 2 to 4,
L and Ar₁ are the same as defined in Chemical Formula 1;
R₁₁ to R₁₃, R₂₁ to R₂₄, R₃₁ to R₃₃, R₄₁ to R₄₃, R₅₁ 1, R₅₃, R₅₄, R₆₁ to R₆₈, R₇₁ to R₇₆, and R₈₁ to R₈₃ are identical to each other or different from each other, are each independently one selected from among hydrogen, deuterium, a cyano group, a trifluoromethyl group, a nitro group, a halogen group, a hydroxyl group, a trimethylsilyl group (TMS), a substituted or unsubstituted C₁ to C₃₀ alkyl group, a substituted or unsubstituted C₃ to C₂₀ cycloalkyl group, a substituted or unsubstituted C₂ to C₃₀ alkenyl group, a substituted or unsubstituted C₃ to C₂₀ cycloalkenyl group, a substituted or unsubstituted C₂ to C₃₀ alkynyl group, a substituted or unsubstituted C₃ to C₂₀ cycloalkynyl group, a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted amine group, a substituted or unsubstituted C₁ to C₃₀ alkylamino group, a substituted or unsubstituted C₇ to C₃₀ arylalkylamino group, a substituted or unsubstituted C₆ to C₃₀ arylamino group, a substituted or unsubstituted C₅ to C₆₀ heteroarylamino group, a substituted or unsubstituted silyl group, a substituted or unsubstituted C₁ to C₃₀ alkylsilyl group, a substituted or unsubstituted C₆ to C₃₀ arylsilyl group, a substituted or unsubstituted C₁ to C₃₀ alkoxy group, a substituted or unsubstituted C₆ to C₃₀ aryloxy group, a substituted or unsubstituted C₁ to C₃₀ alkylthio group, and a substituted or unsubstituted C₆ to C₃₀ arylthio group, and form a substituted or unsubstituted ring with a functional group adjacent thereto; and,
when substituted, R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, R₈₁ to R₈₃ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other and form a substituted or unsubstituted ring with a functional group adjacent thereto.

According to one embodiment, R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, and R₈₁ to R₈₃ are identical to each other or different from each other and may be each independently one selected from among hydrogen, deuterium, a cyano group, a substituted or unsubstituted methyl group, a substituted or unsubstituted ethyl group, a substituted or unsubstituted propyl group, a substituted or unsubstituted isopropyl group, a substituted or unsubstituted butyl group, a substituted or unsubstituted sec-butyl group, a substituted or unsubstituted isobutyl group, a substituted or unsubstituted tert-butyl group, a substituted or unsubstituted pentyl group, a substituted or unsubstituted isoamyl group, a substituted or unsubstituted hexyl group, a substituted or unsubstituted phenyl group, a substituted or unsubstituted naphthyl group, a substituted or unsubstituted anthracenyl group, a substituted or unsubstituted phenanthryl group, a substituted or unsubstituted phenanthryl group, a substituted or unsubstituted fluorenyl group, a substituted or unsubstituted dimethylfluorenyl group, a substituted or unsubstituted diphenylfluorenyl group, a substituted or unsubstituted spirofluorenyl group, a substituted or unsubstituted dibenzofuranyl group, a substituted or unsubstituted a dibenzothiophenyl group, a substituted or unsubstituted phenylcarbazolyl group, a substituted or unsubstituted 9-phenylcarbazolyl group, a substituted or unsubstituted carbazolyl group, and a substituted or unsubstituted diphenylamino group.

According to one embodiment, R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, and R₈₁ to R₈₃ are identical to each other or different from each other and may be each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₀ heteroaryl group, and a substituted or unsubstituted C₆ to C₃₀ arylamino group.

According to one embodiment, R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, and R₈₁ to R₈₃ are identical to each other or different from each other and may be each independently one selected from among hydrogen, deuterium, a cyano group, an unsubstituted methyl group, an unsubstituted tert-butyl group, a substituted or unsubstituted phenyl group, a substituted or unsubstituted carbazolyl group, and a substituted or unsubstituted diphenylamino group.

According to one embodiment, R₁₂, R₂₃, and R₃₂ are identical to each other or different from each other and may be each independently one selected from among hydrogen, deuterium, and an unsubstituted tert-butyl group.

According to one embodiment, R₄₂ may be one selected from among a cyano group, a methyl group, a tert-butyl group, a deuterium-substituted or unsubstituted diphenylamino group, and a deuterium-substituted or unsubstituted carbazolyl group.

According to one embodiment, L may be one selected from among a single bond and a deuterium-substituted or unsubstituted phenylene group.

According to one embodiment, Ar₁ may be one selected from among a substituted or unsubstituted C₆ to C₃₀ aryl group, a substituted or unsubstituted C₅ to C₆₀ heteroaryl group, and a substituted or unsubstituted C₆ to C₃₀ arylamino group.

According to one embodiment, Ar₁ may be one selected from among a substituted or unsubstituted phenyl group, a substituted or unsubstituted biphenyl group, a substituted or unsubstituted terphenyl group, a substituted or unsubstituted naphthyl group, a substituted or unsubstituted dibenzofuranyl group, and a substituted or unsubstituted dibenzothiophenyl group.

According to one embodiment of the present invention, Ar₁ may be selected from among structural formulas a1 to a15.

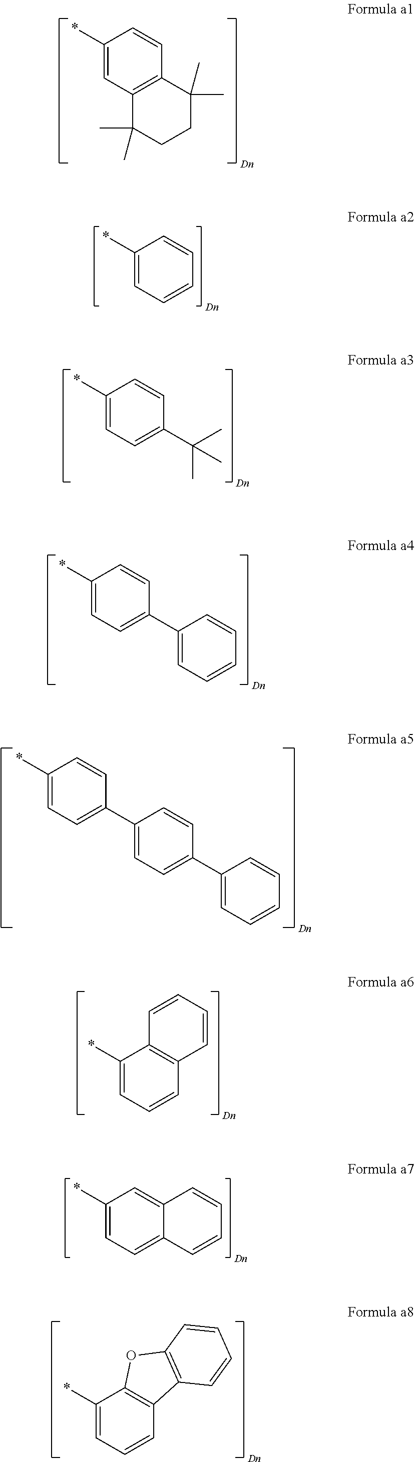

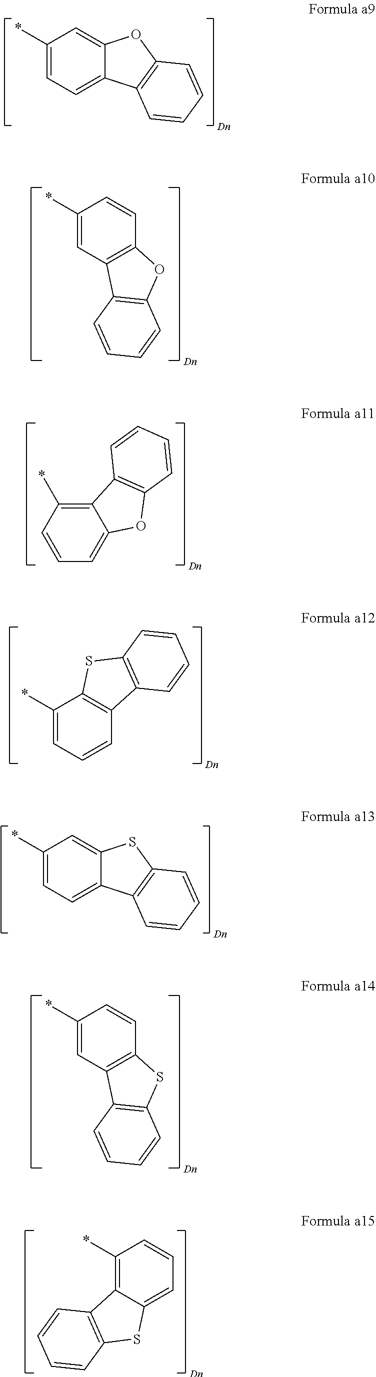

In Formulas a1 to a15, Dn is the number of substituted deuterium atoms therein, wherein n is an integer of 0 or greater.

According to one embodiment of the present invention, in Formula a1, n is an integer selected from 0 to 3, in Formula a2, n is an integer selected from 0 to 5, in Formula a3, n is an integer selected from 0 to 4, in Formula a4, n is an integer selected from 0 to 9, in Formula a5, n is an integer selected from 0 to 13, in Formulas a6 to a7, n is an integer selected from 0 to 7, and, in Formulas a8 to a15, n is an integer selected from 0 to 7.

According to one embodiment, Chemical Formula 1 may be represented by Chemical Formula 5.

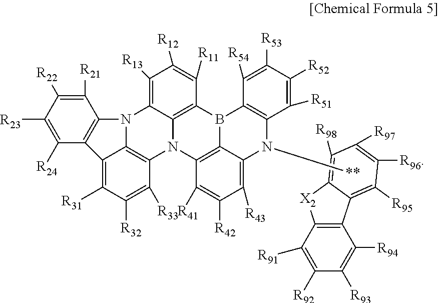

In Chemical Formula 5, R₁₁ to R₁₃, R₂₁ to R₂₄, R₃₁ to R₃₃, R₄₁ to R₄₃, R₅₁, R₅₃, and R₅₄ are the same as defined in Chemical Formulas 2 to 4, X₂ is oxygen (O) or sulfur (S), and ** is a linking site to a ring structure containing X₂;
R₅₂ and R₉₁ to R₉₈ are identical to each other or different from each other, are each independently one selected from among hydrogen, deuterium, a cyano group, a trifluoromethyl group, a nitro group, a halogen group, a hydroxyl group, a trimethylsilyl group (TMS), a substituted or unsubstituted C₁ to C₃₀ alkyl group, a substituted or unsubstituted C₃ to C₂₀ cycloalkyl group, a substituted or unsubstituted C₂ to C₃₀ alkenyl group, a substituted or unsubstituted C₃ to C₂₀ cycloalkenyl group, a substituted or unsubstituted C₂ to C₃₀ alkynyl group, a substituted or unsubstituted C₃ to C₂₀ cycloalkynyl group, a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted amine group, a substituted or unsubstituted C₁ to C₃₀ alkylamino group, a substituted or unsubstituted C₇ to C₃₀ arylalkylamino group, a substituted or unsubstituted C₆ to C₃₀ arylamino group, a substituted or unsubstituted C₅ to C₆₀ heteroarylamino group, a substituted or unsubstituted silyl group, a substituted or unsubstituted C₁ to C₃₀ alkylsilyl group, a substituted or unsubstituted C₆ to C₃₀ arylsilyl group, a substituted or unsubstituted C₁ to C₃₀ alkoxy group, a substituted or unsubstituted C₆ to C₃₀ aryloxy group, a substituted or unsubstituted C₁ to C₃₀ alkylthio group, and a substituted or unsubstituted C₆ to C₃₀ arylthio group, and form a substituted or unsubstituted ring with a functional group adjacent thereto; and,
when substituted, R₅₂ and R₉₁ to R₉₈ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other and form a substituted or unsubstituted ring with a functional group adjacent thereto.

According to one embodiment, the linking site indicated by ** may be one selected from among R₉₅, R₉₆, R₉₇, and R₉₈.

According to one embodiment, R₅₃ may be one selected from among hydrogen, deuterium, and a substituted or unsubstituted C₁ to C₃₀ alkyl group.

According to one embodiment, R₅₃ may be one selected from among hydrogen, deuterium, and an unsubstituted tert-butyl group.

According to one embodiment, Chemical Formula 1, more specifically Chemical Formula 5, may be represented by one of Chemical Formulas 6 to 9.

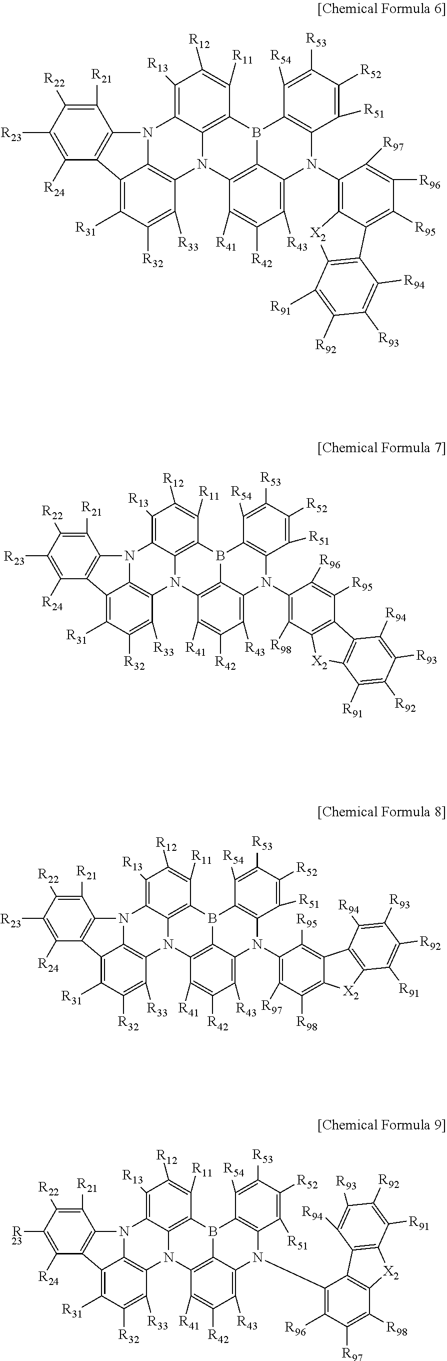

In Chemical Formulas 6 to 9, R₁₁ to R₁₃, R₂₁ to R₂₄, R₃₁ to R₃₃, R₄₁ to R₄₃, R₅₁, R₅₃ and R₅₄ are the same as defined in Chemical Formulas 2 to 4, and X₂, R₅₂ and R₉₁ to R₉₈ are the same as defined in Chemical Formula 5.

According to one embodiment, Chemical Formula 1 may be represented by Chemical Formula 10.

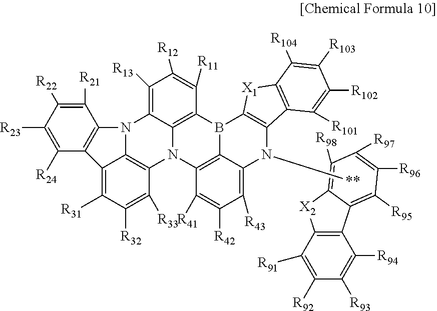

In Chemical Formula 10,
X₁ is the same as defined in Chemical Formula 1, R₁₁ to R₁₃, R₂₁ to R₂₄, R₃₁ to R₃₃, and R₄₁ to R₄₃ are the same as defined in Chemical Formulas 2 to 4, X₂ and R₉₁ to R₉₈ are the same as defined in Chemical Formula 5, and ** denotes a linking site to a ring structure containing X₂;
R₁₀₁ to R₁₀₄ are identical to each other or different from each other, are each independently one selected from among hydrogen, deuterium, a cyano group, a trifluoromethyl group, a nitro group, a halogen group, a hydroxyl group, a trimethylsilyl group (TMS), a substituted or unsubstituted C₁ to C₃₀ alkyl group, a substituted or unsubstituted C₃ to C₂₀ cycloalkyl group, a substituted or unsubstituted C₂ to C₃₀ alkenyl group, a substituted or unsubstituted C₃ to C₂₀ cycloalkenyl group, a substituted or unsubstituted C₂ to C₃₀ alkynyl group, a substituted or unsubstituted C₃ to C₂₀ cycloalkynyl group, a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted amine group, a substituted or unsubstituted C₁ to C₃₀ alkylamino group, a substituted or unsubstituted C₇ to C₃₀ arylalkylamino group, a substituted or unsubstituted C₆ to C₃₀ arylamino group, a substituted or unsubstituted C₅ to C₆₀ heteroarylamino group, a substituted or unsubstituted silyl group, a substituted or unsubstituted C₁ to C₃₀ alkylsilyl group, a substituted or unsubstituted C₆ to C₃₀ arylsilyl group, a substituted or unsubstituted C₁ to C₃₀ alkoxy group, a substituted or unsubstituted C₆ to C₃₀ aryloxy group, a substituted or unsubstituted C₁ to C₃₀ alkylthio group, and a substituted or unsubstituted C₆ to C₃₀ arylthio group, and form a substituted or unsubstituted ring with a functional group adjacent thereto; and,
when substituted, R₁₀₁ to R₁₀₄ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and when a plurality of substituents is used, the substituents are identical to each other or different from each other and form a substituted or unsubstituted ring with a functional group adjacent thereto.

According to one embodiment, the linking site indicated by ** may be one selected from among R₉₅, R₉₆, R₉₇, and R₉₈.

According to one embodiment, R₁₀₂ may be one selected from among hydrogen, deuterium, a substituted or unsubstituted C₁ to C₃₀ alkyl group, and a substituted or unsubstituted C₆ to C₃₀ aryl group.

According to one embodiment, R₁₀₂ may be one selected from among hydrogen, deuterium, a substituted or unsubstituted methyl group, a substituted or unsubstituted ethyl group, a substituted or unsubstituted propyl group, a substituted or unsubstituted isopropyl group, a substituted or unsubstituted butyl group, a substituted or unsubstituted sec-butyl group, a substituted or unsubstituted isobutyl group, a substituted or unsubstituted tert-butyl group, a substituted or unsubstituted pentyl group, a substituted or unsubstituted isoamyl group, a substituted or unsubstituted hexyl group, a substituted or unsubstituted phenyl group, a substituted or unsubstituted naphthyl group, a substituted or unsubstituted anthracenyl group, a substituted or unsubstituted phenanthryl group, a substituted or unsubstituted fluorenyl group, a substituted or unsubstituted dimethylfluorenyl group, a substituted or unsubstituted diphenylfluorenyl group, and a substituted or unsubstituted spirofluorenyl group.

According to one embodiment, R₁₀₂ may be one selected from among a substituted or unsubstituted tert-butyl group and a substituted or unsubstituted phenyl group.

According to one embodiment, Chemical Formula 1, more specifically Chemical Formula 10, may be represented by one of Chemical Formulas 11 to 14.

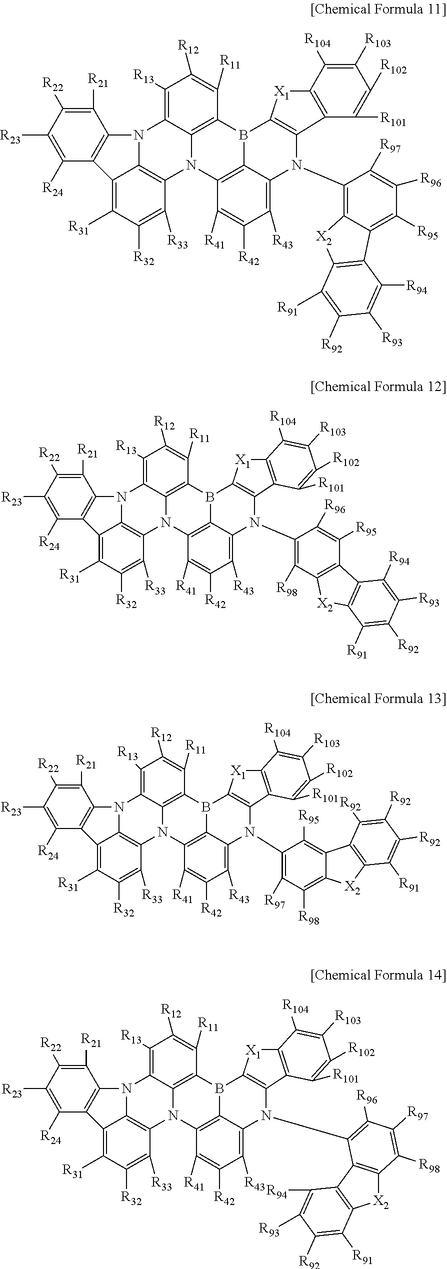

In Chemical Formulas 11 to 14,
X₁ is the same as defined in Formula 1, R₁₁ to R₁₃, R₂₁ to R₂₄, R₃₁ to R₃₃, and R₄₁ to R₄₃ are the same as defined in Formulas 2 to 4, X₂ and R₉₁ to R₉₈ are the same as defined in Formula 5, and R₁₀₁ to R₁₀₄ are the same as defined in Chemical Formula 10.

According to one embodiment of the present invention, Chemical Formula 1 may be represented by Chemical Formula 15.

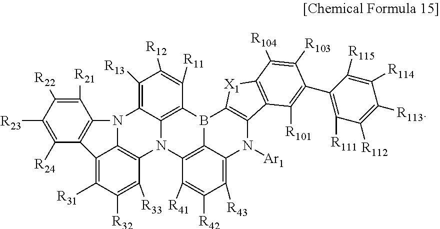

In Chemical Formula 15,
X₁ and Ar₁ are the same as defined in Chemical Formula 1, R₁₁ to R₁₃, R₂₁ to R₂₄, R₃₁ to R₃₃, and R₄₁ to R₄₃ are the same as defined in Chemical Formulas 2 to 4, and R₁₀₁, R₁₀₃, and R₁₀₄ are the same as defined in Chemical Formula 10;
R₁₁₁ to R₁₁₅ are identical to each other or different from each other, are each independently one selected from among hydrogen, deuterium, a cyano group, a trifluoromethyl group, a nitro group, a halogen group, a hydroxyl group, a trimethylsilyl group (TMS), a substituted or unsubstituted C₁ to C₃₀ alkyl group, a substituted or unsubstituted C₃ to C₂₀ cycloalkyl group, a substituted or unsubstituted C₂ to C₃₀ alkenyl group, a substituted or unsubstituted C₃ to C₂₀ cycloalkenyl group, a substituted or unsubstituted C₂ to C₃₀ alkynyl group, a substituted or unsubstituted C₃ to C₂₀ cycloalkynyl group, a substituted or unsubstituted C₆ to C₃₀ aryl group, a substituted or unsubstituted C₇ to C₃₀ arylalkyl group, a substituted or unsubstituted C₅ to C₆₀ heteroaryl group, a substituted or unsubstituted C₆ to C₆₀ heteroarylalkyl group, a substituted or unsubstituted amine group, a substituted or unsubstituted C₁ to C₃₀ alkylamino group, a substituted or unsubstituted C₇ to C₃₀ arylalkylamino group, a substituted or unsubstituted C₆ to C₃₀ arylamino group, a substituted or unsubstituted C₅ to C₆₀ heteroarylamino group, a substituted or unsubstituted silyl group, a substituted or unsubstituted C₁ to C₃₀ alkylsilyl group, a substituted or unsubstituted C₆ to C₃₀ arylsilyl group, a substituted or unsubstituted C₁ to C₃₀ alkoxy group, a substituted or unsubstituted C₆ to C₃₀ aryloxy group, a substituted or unsubstituted C₁ to C₃₀ alkylthio group, and a substituted or unsubstituted C₆ to C₃₀ arylthio group, and form a substituted or unsubstituted ring with a functional group adjacent thereto; and,
when substituted, R₁₁₁ to R₁₁₅ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other and form a substituted or unsubstituted ring with a functional group adjacent thereto.

According to one embodiment, R₁₁₁ to R₁₁₅ are identical to each other or different from each other and are each independently hydrogen or deuterium.

According to one embodiment, the compound represented by Chemical Formula 1 may be selected from the group consisting of Compounds 1 to 1137, without being limited thereto.

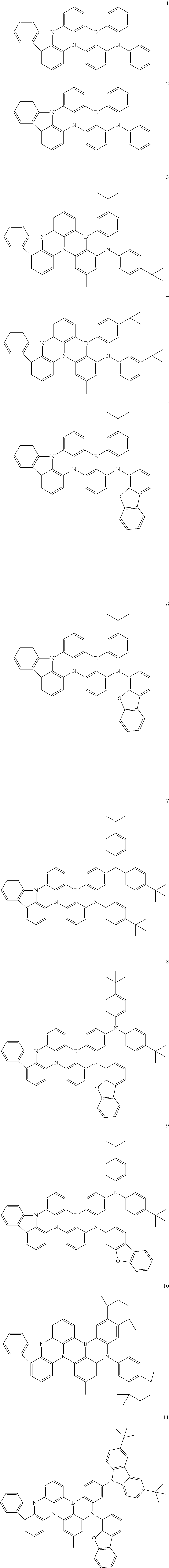

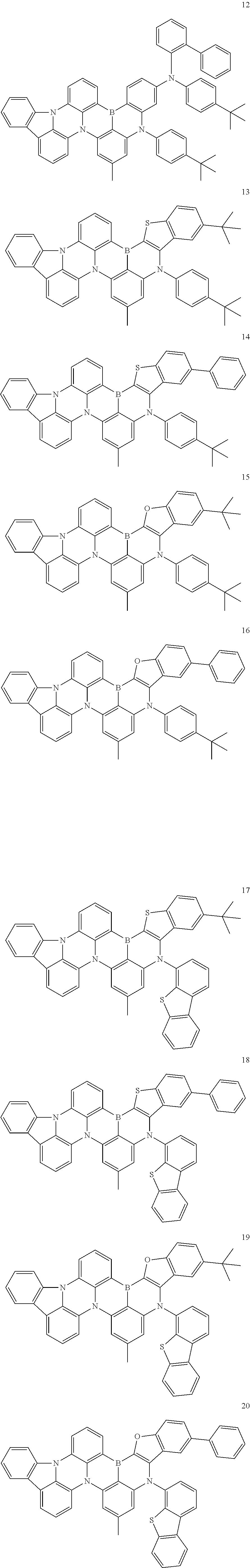

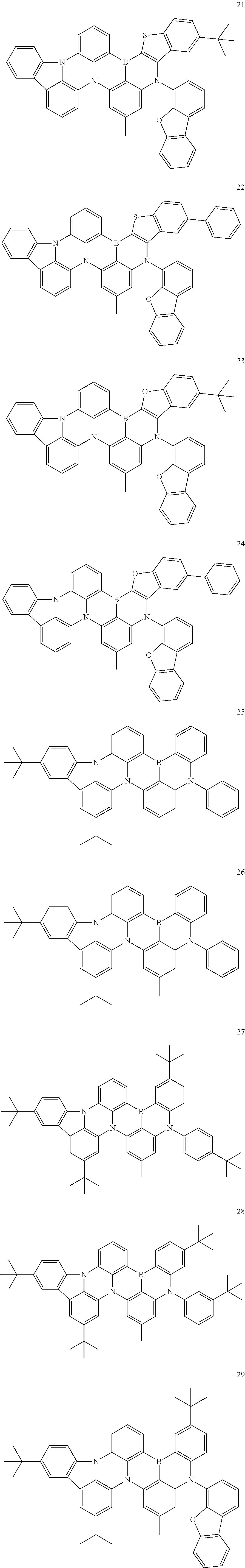

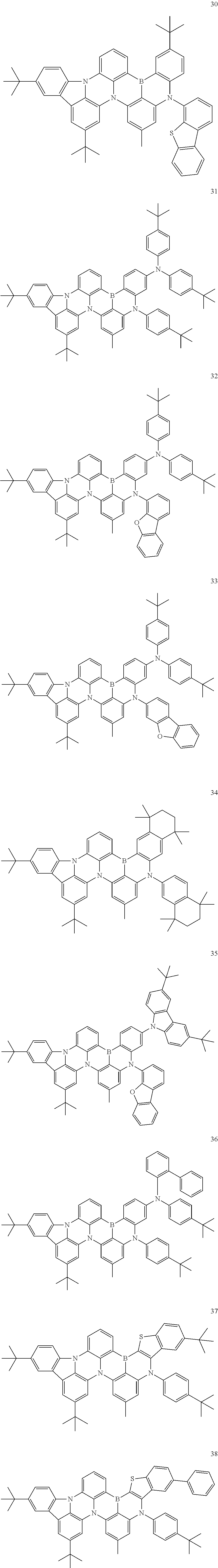

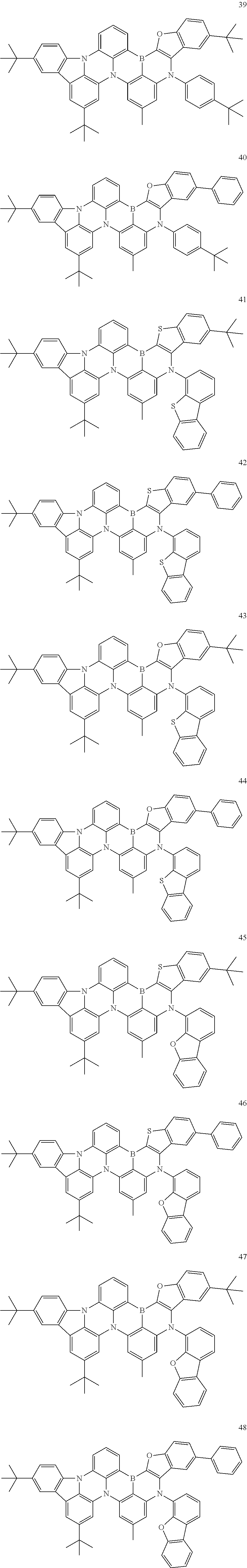

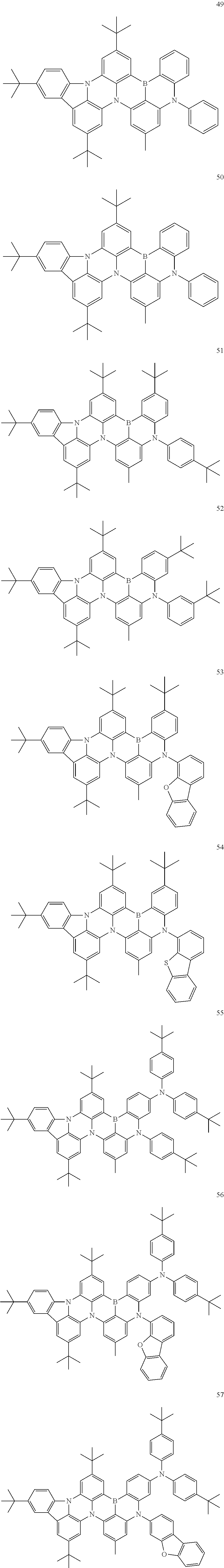

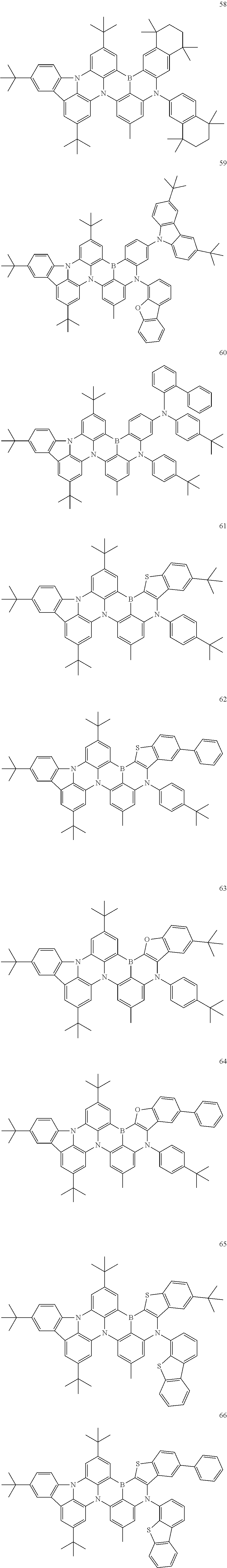

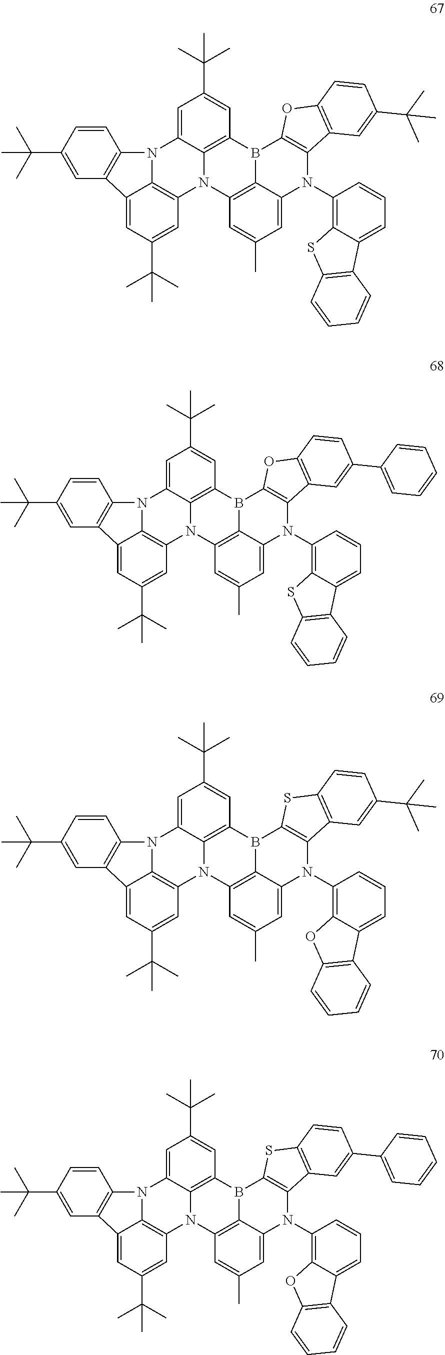

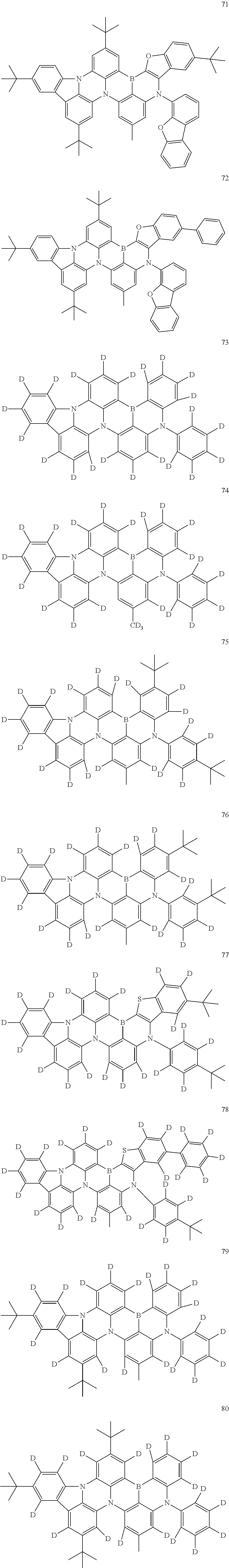

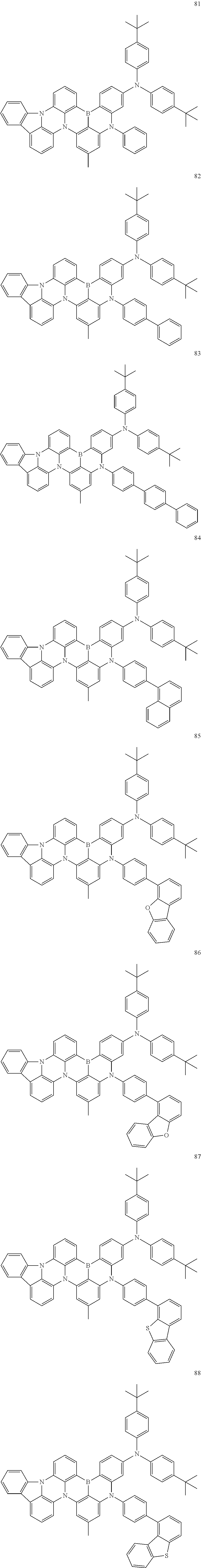

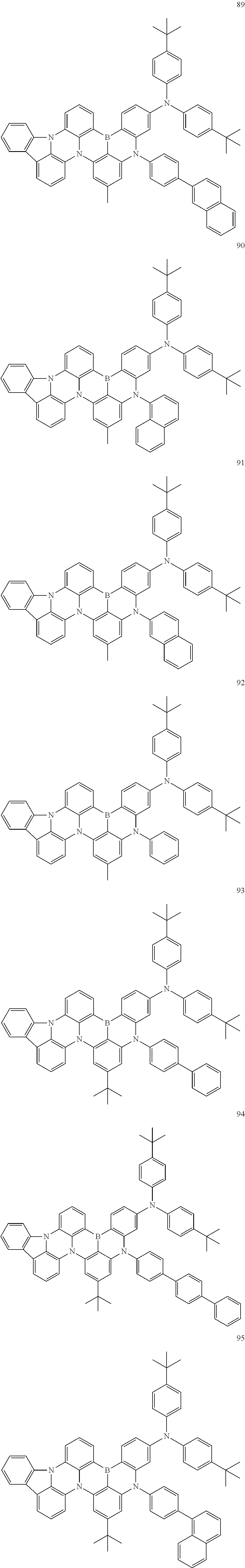

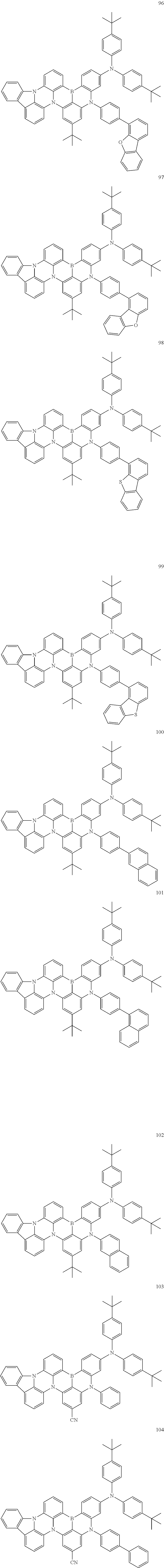

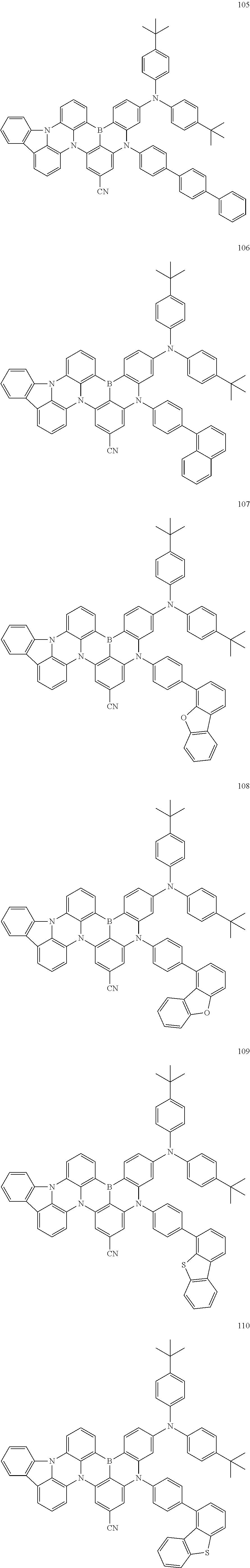

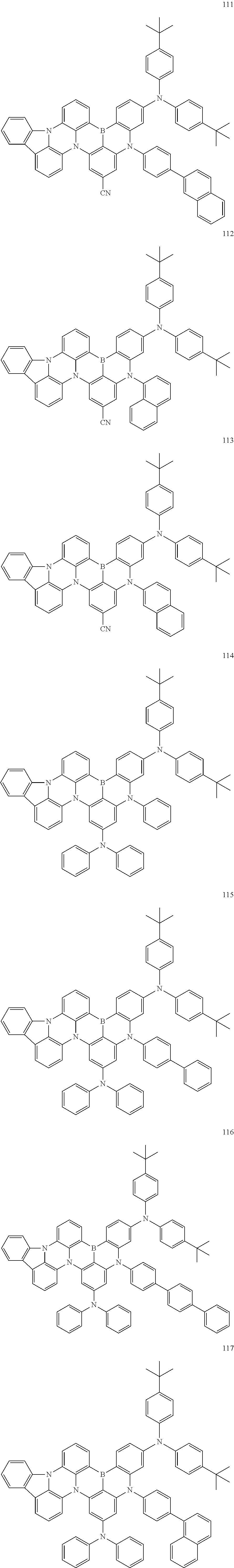

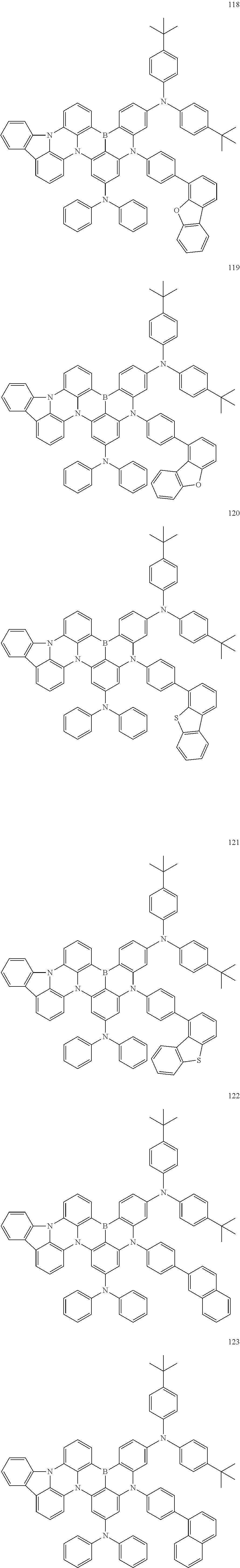

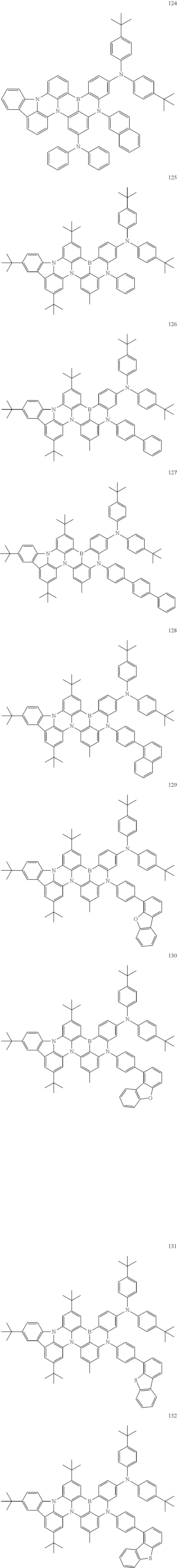

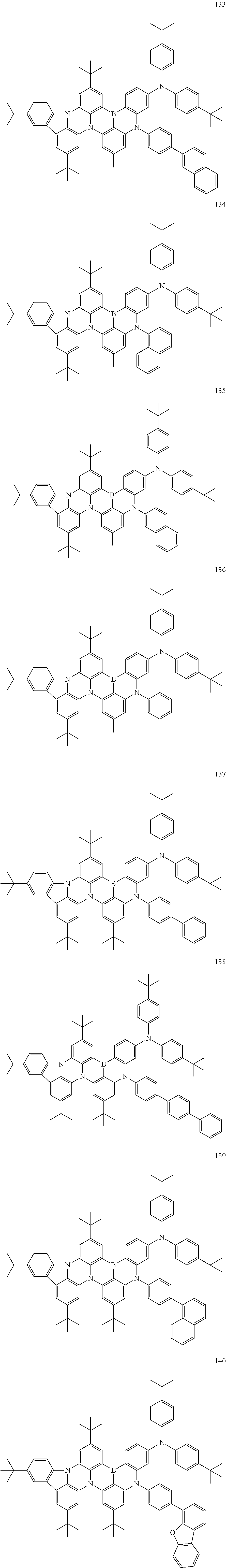

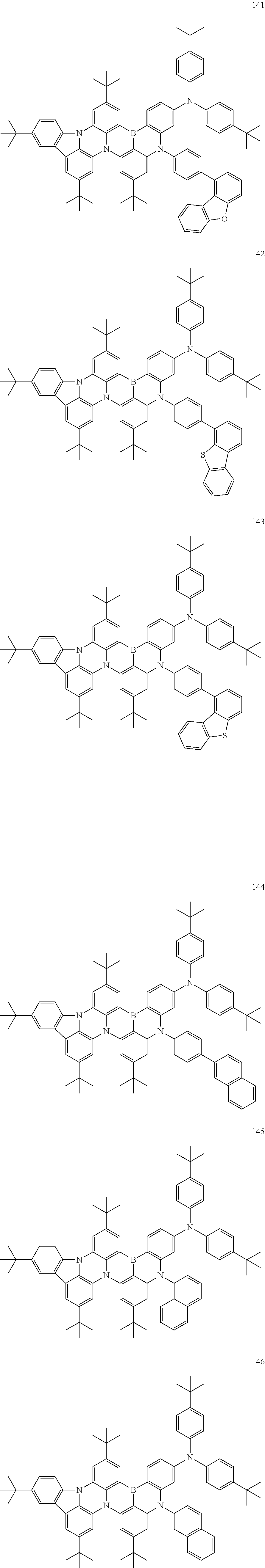

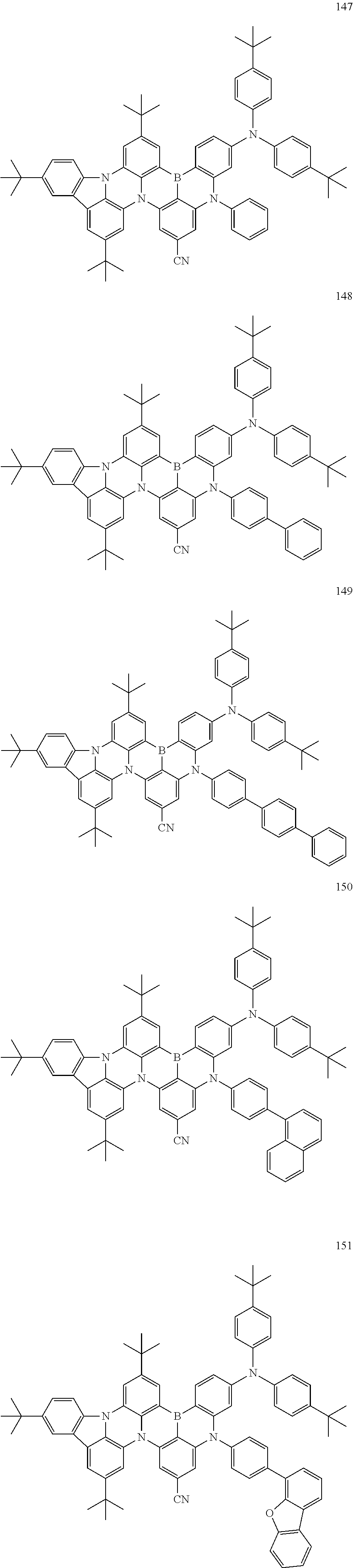

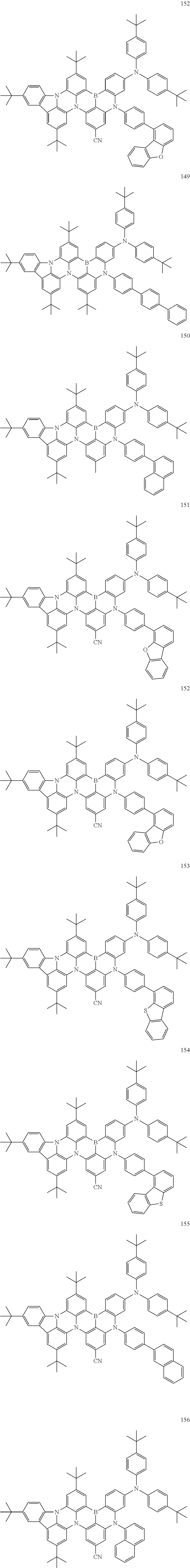

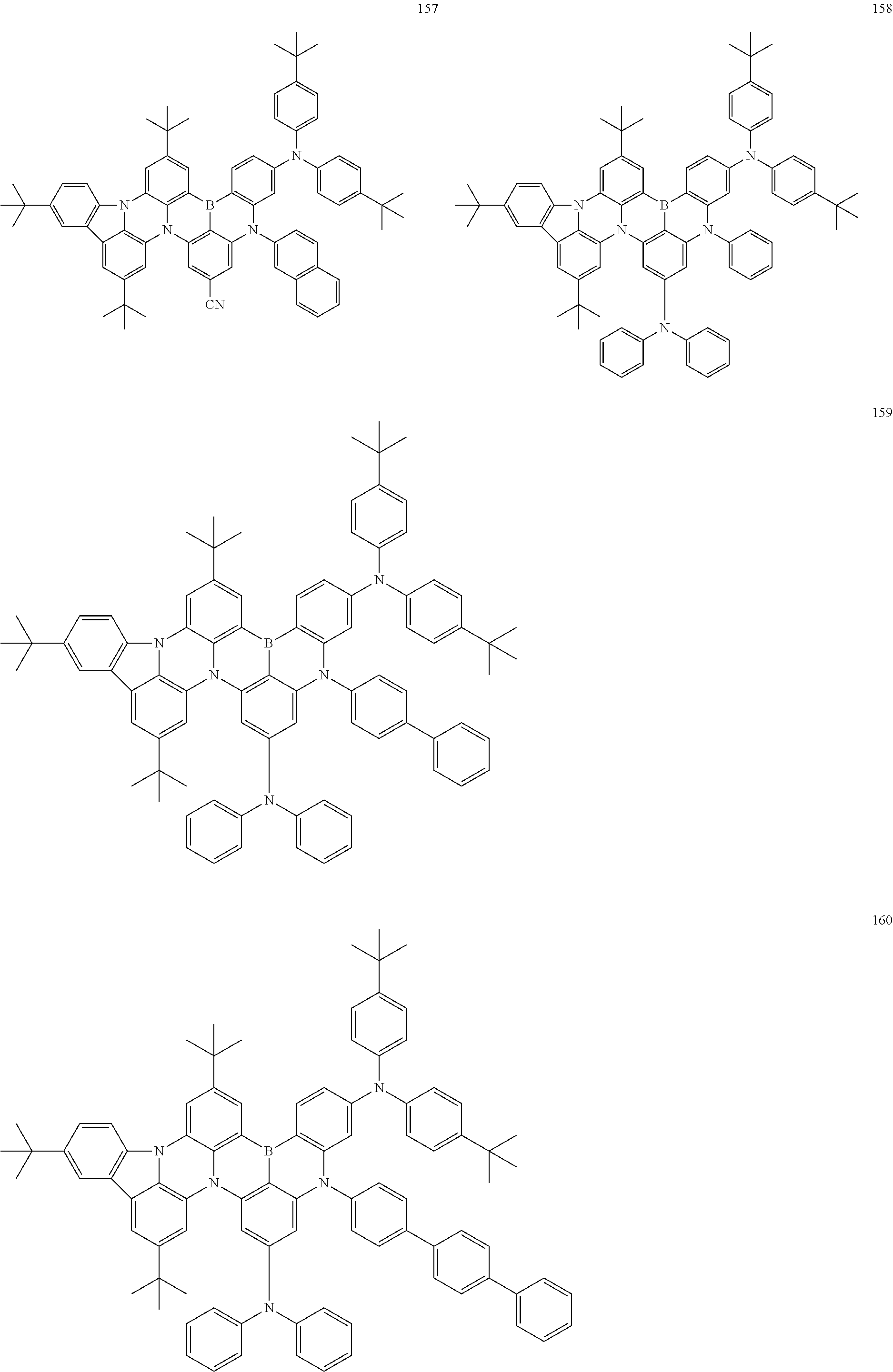

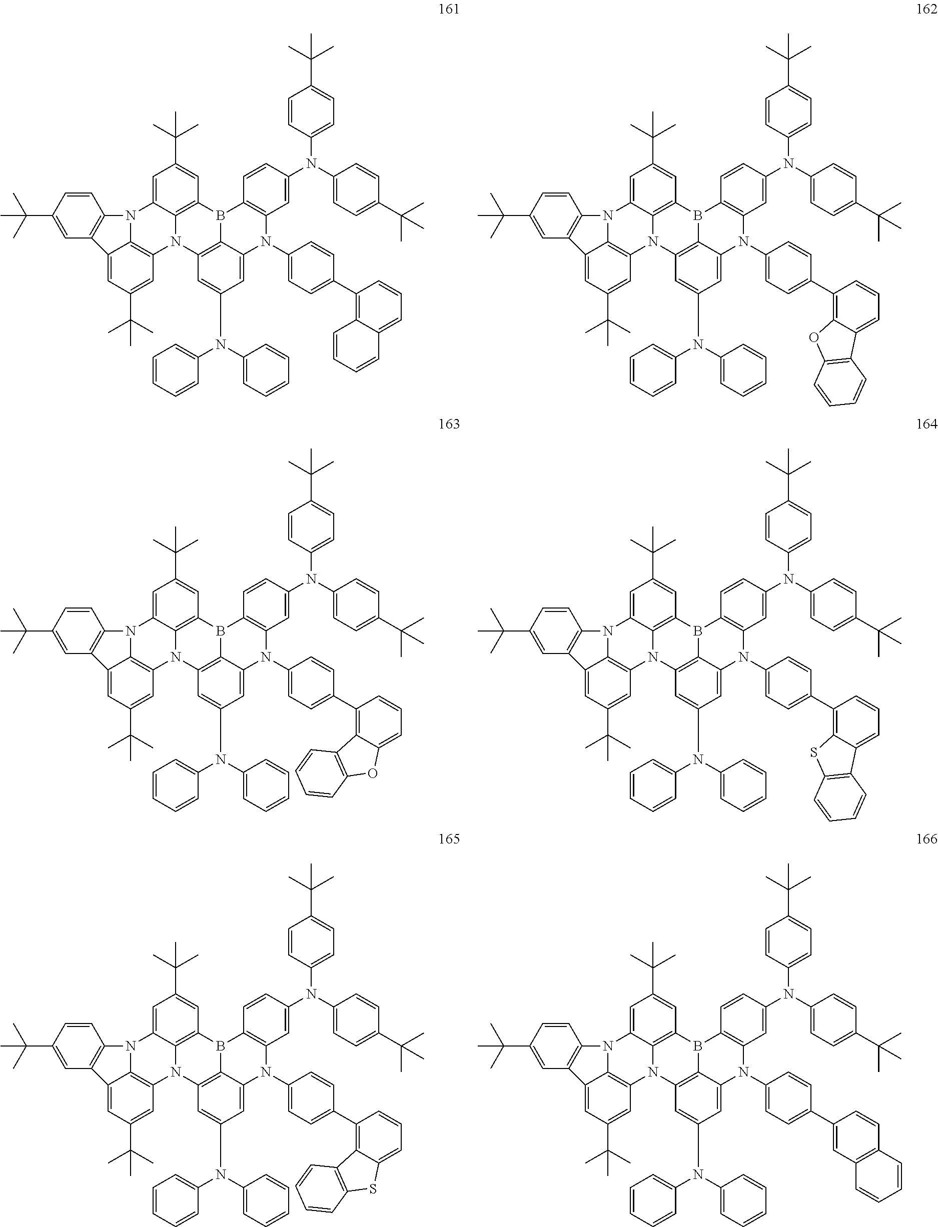

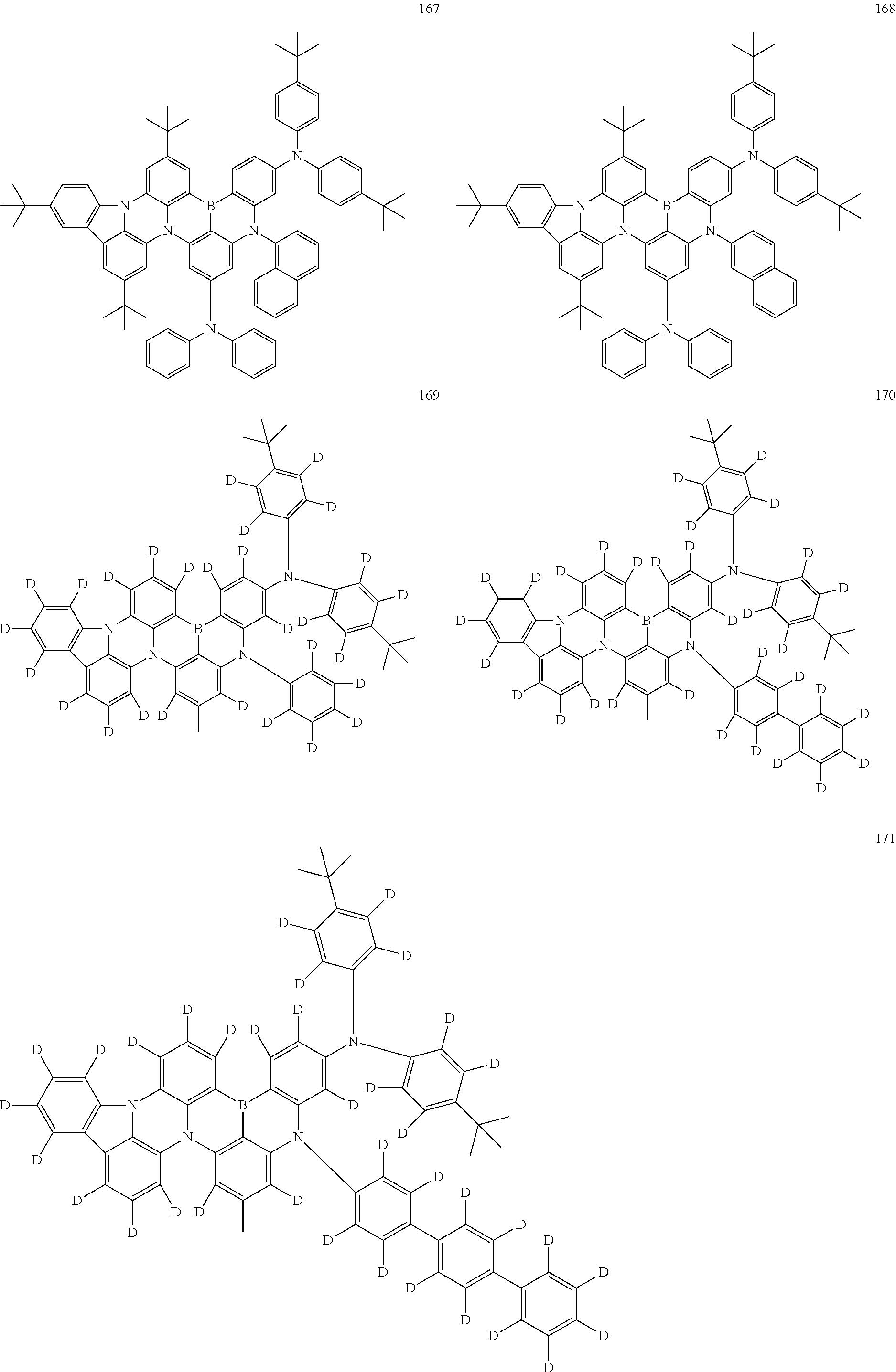

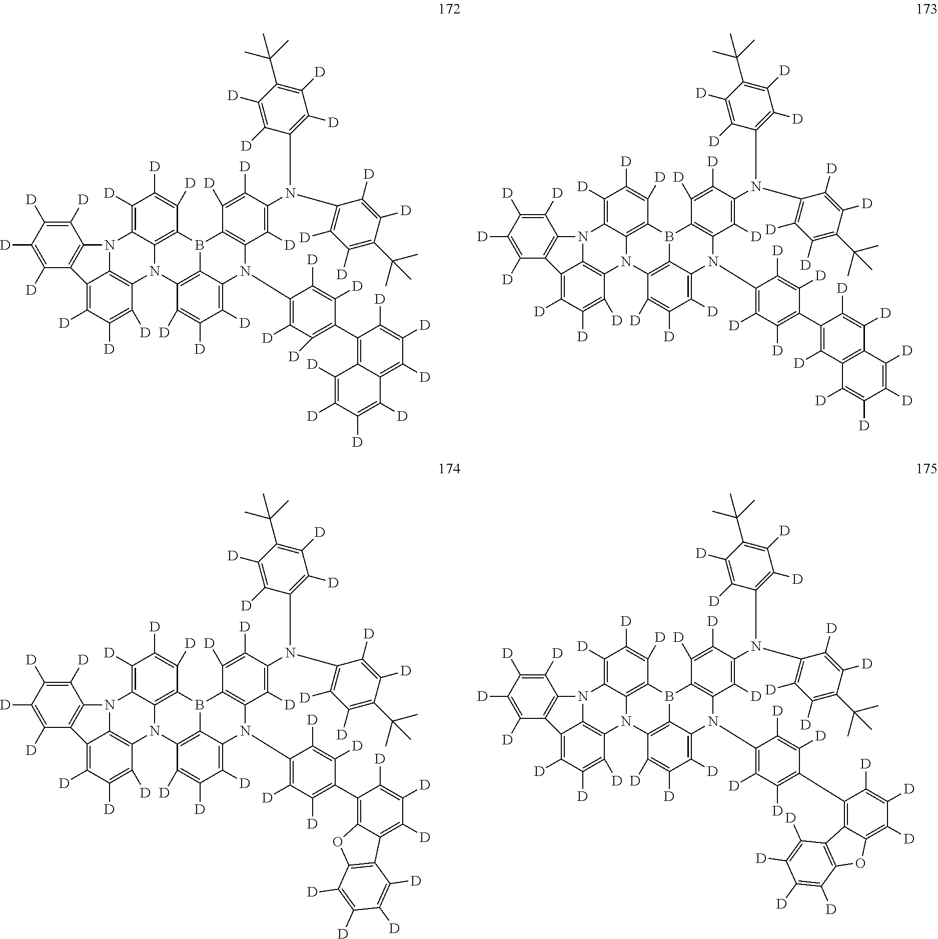

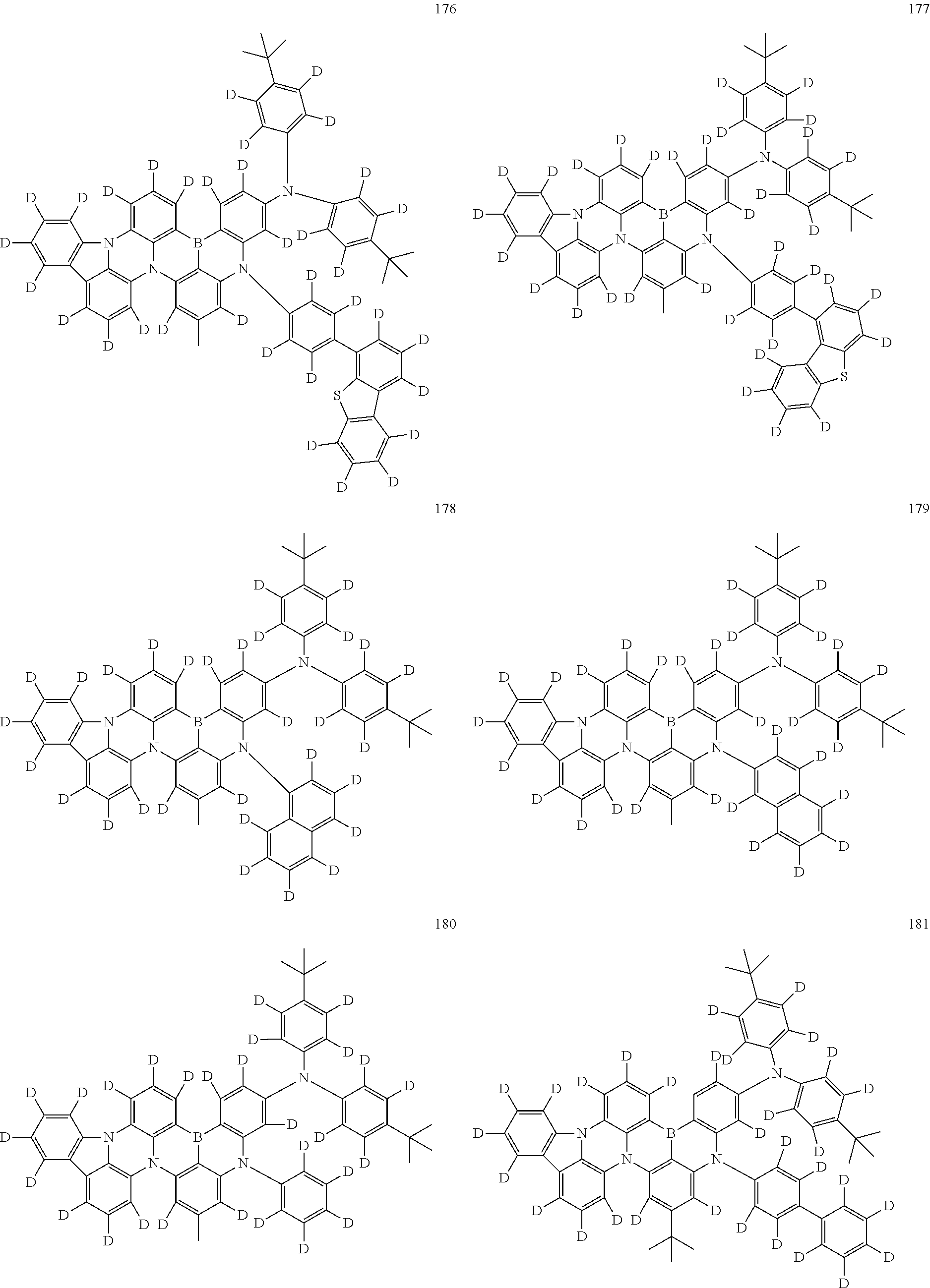

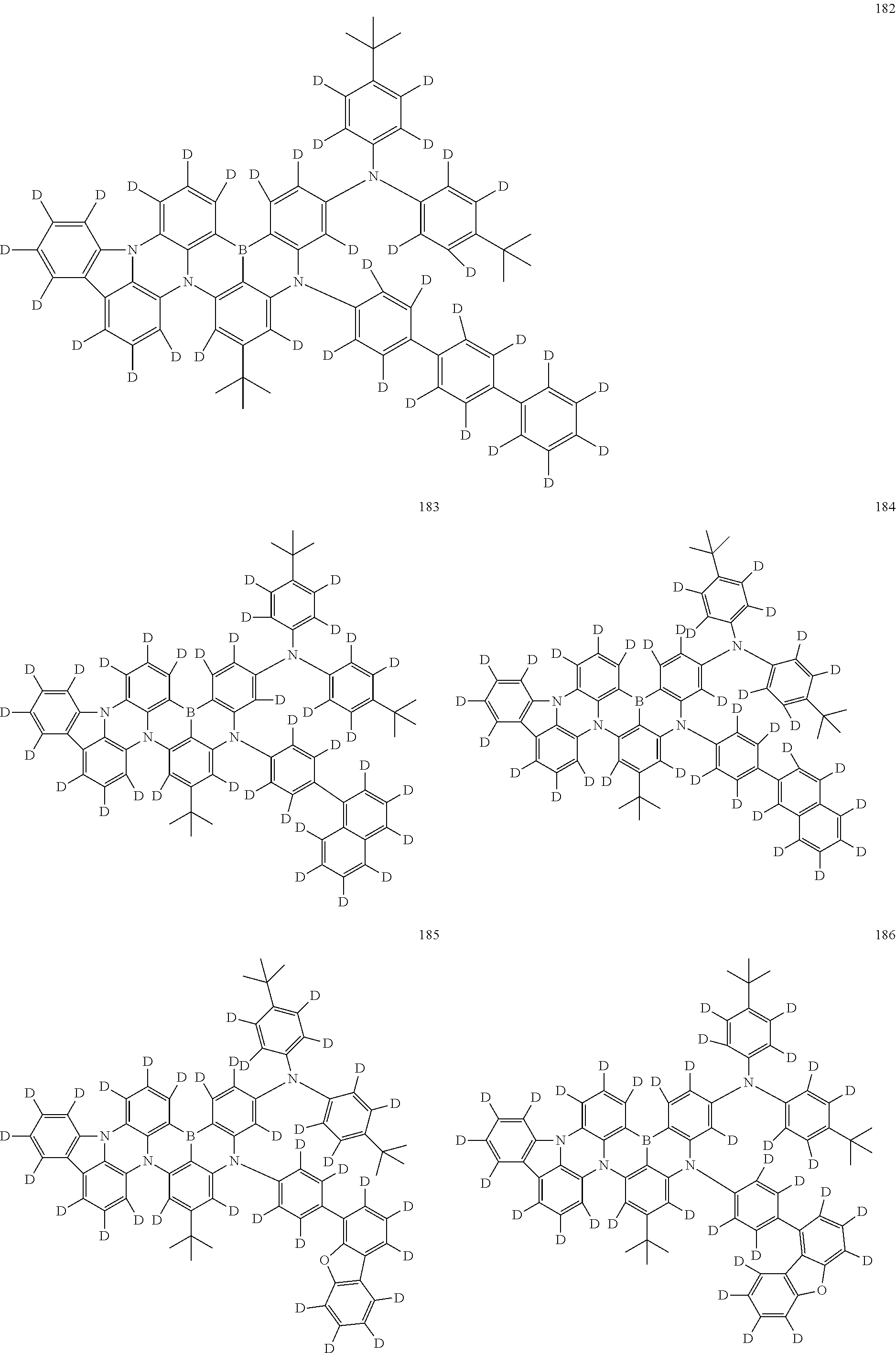

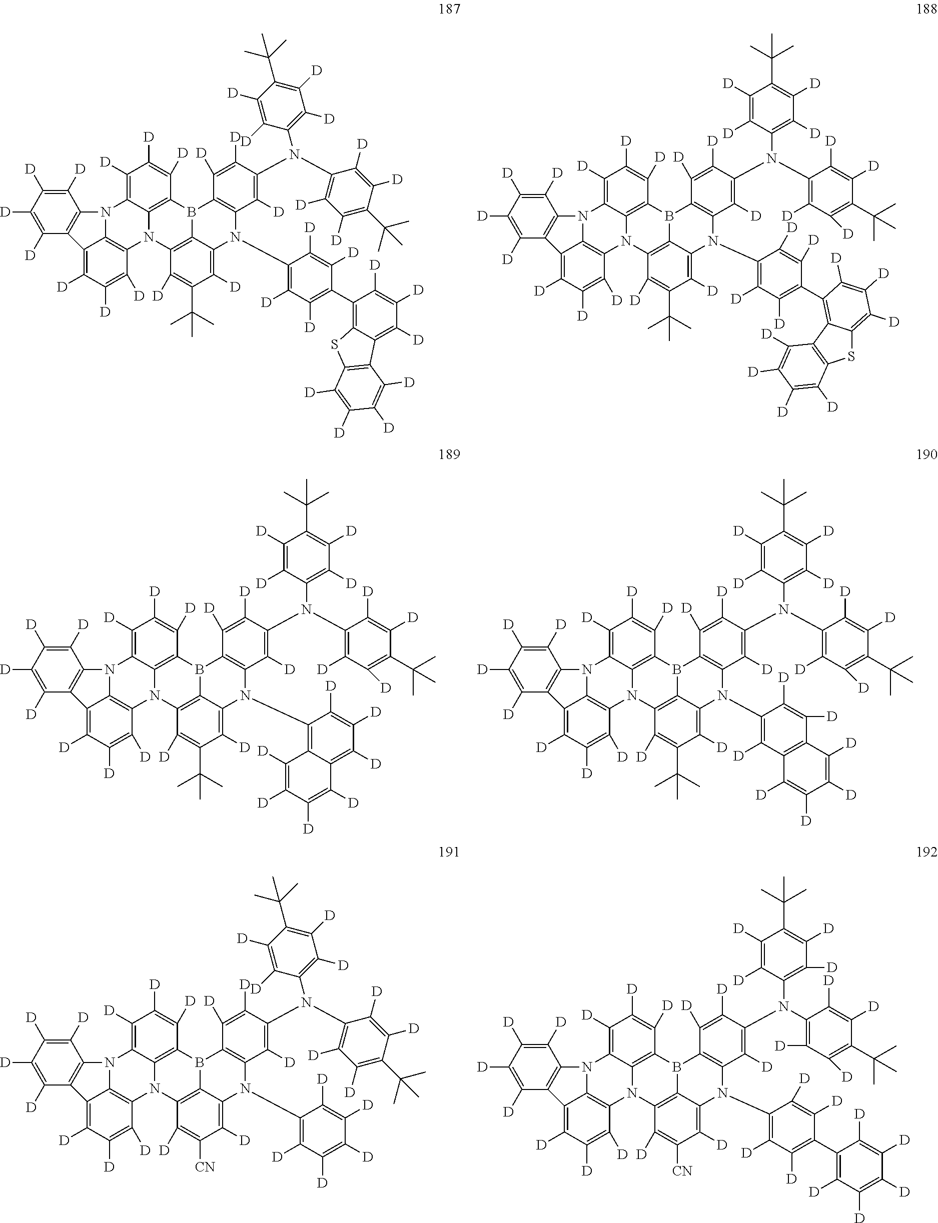

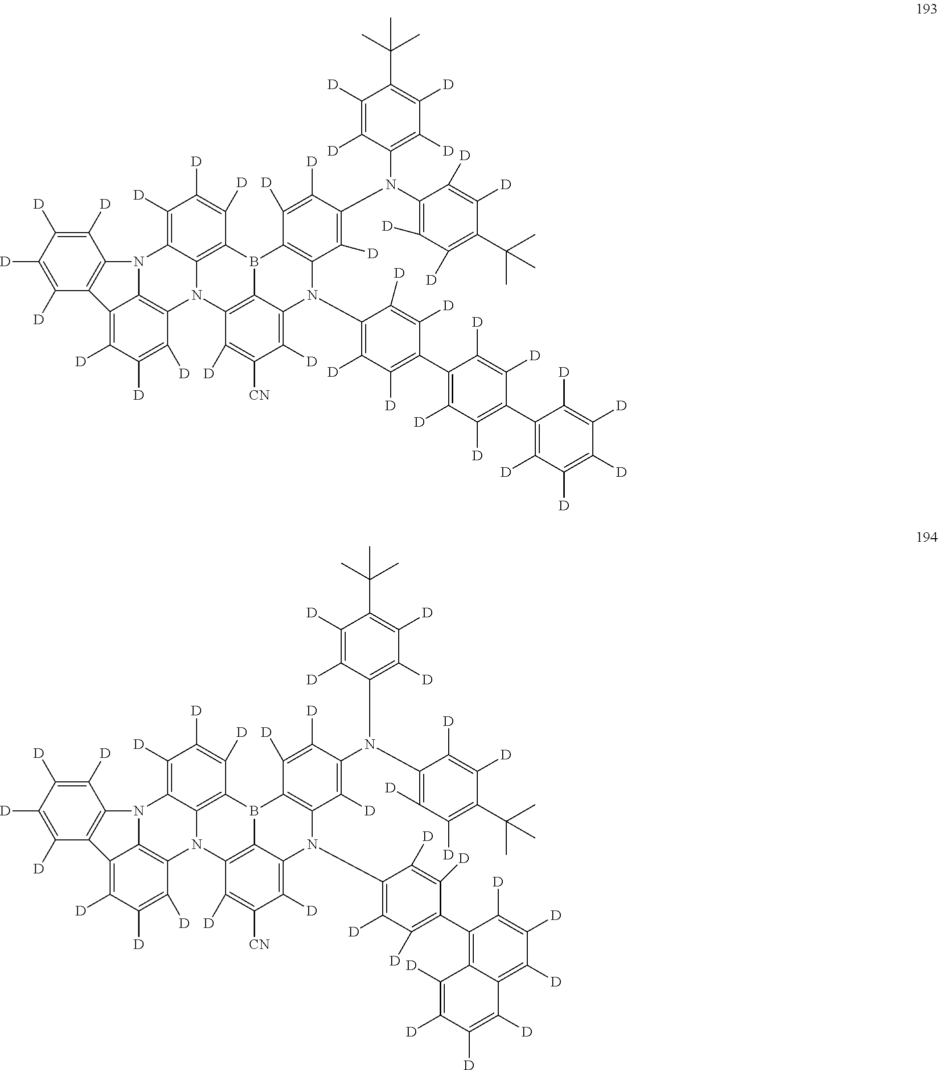

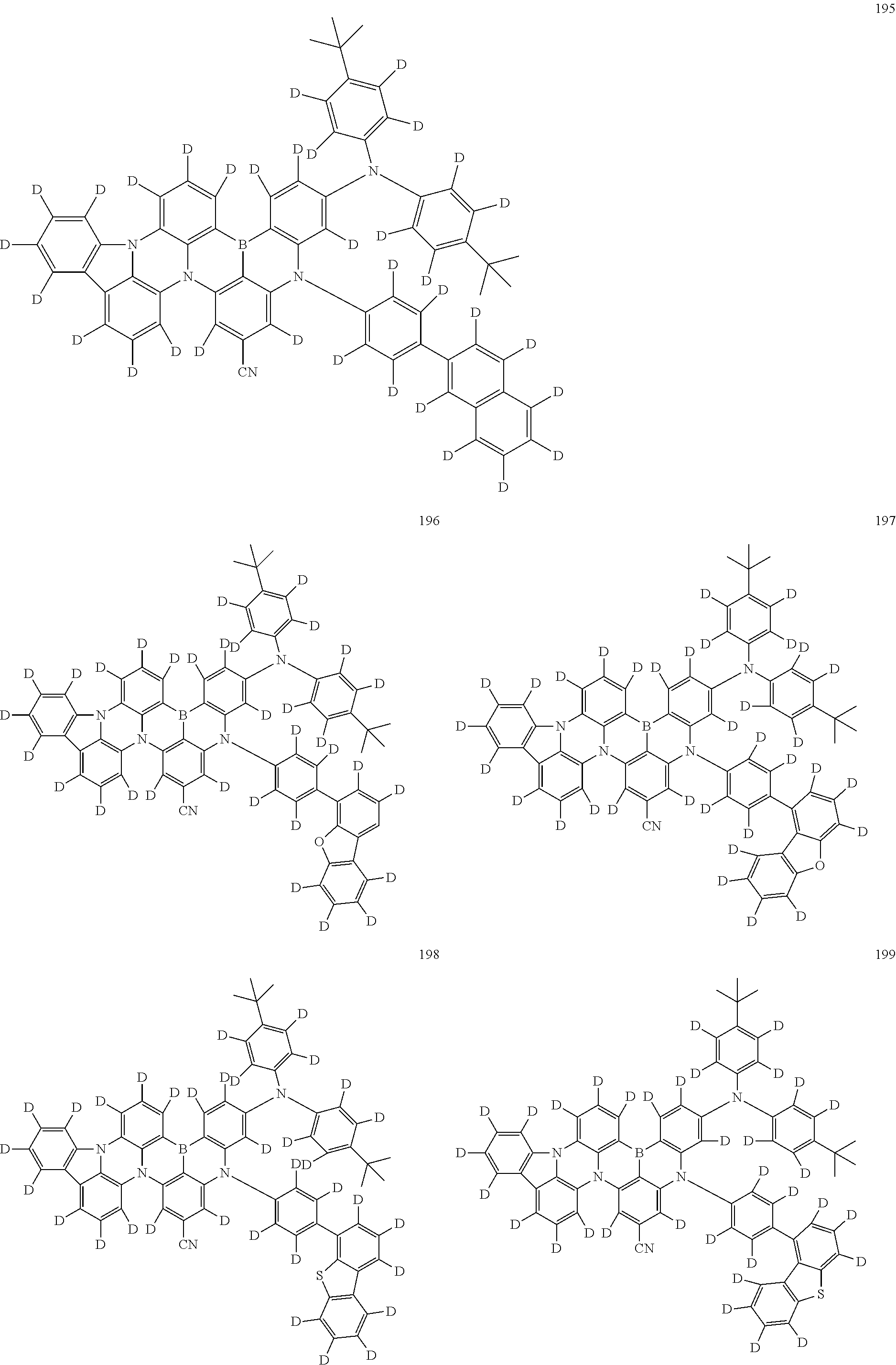

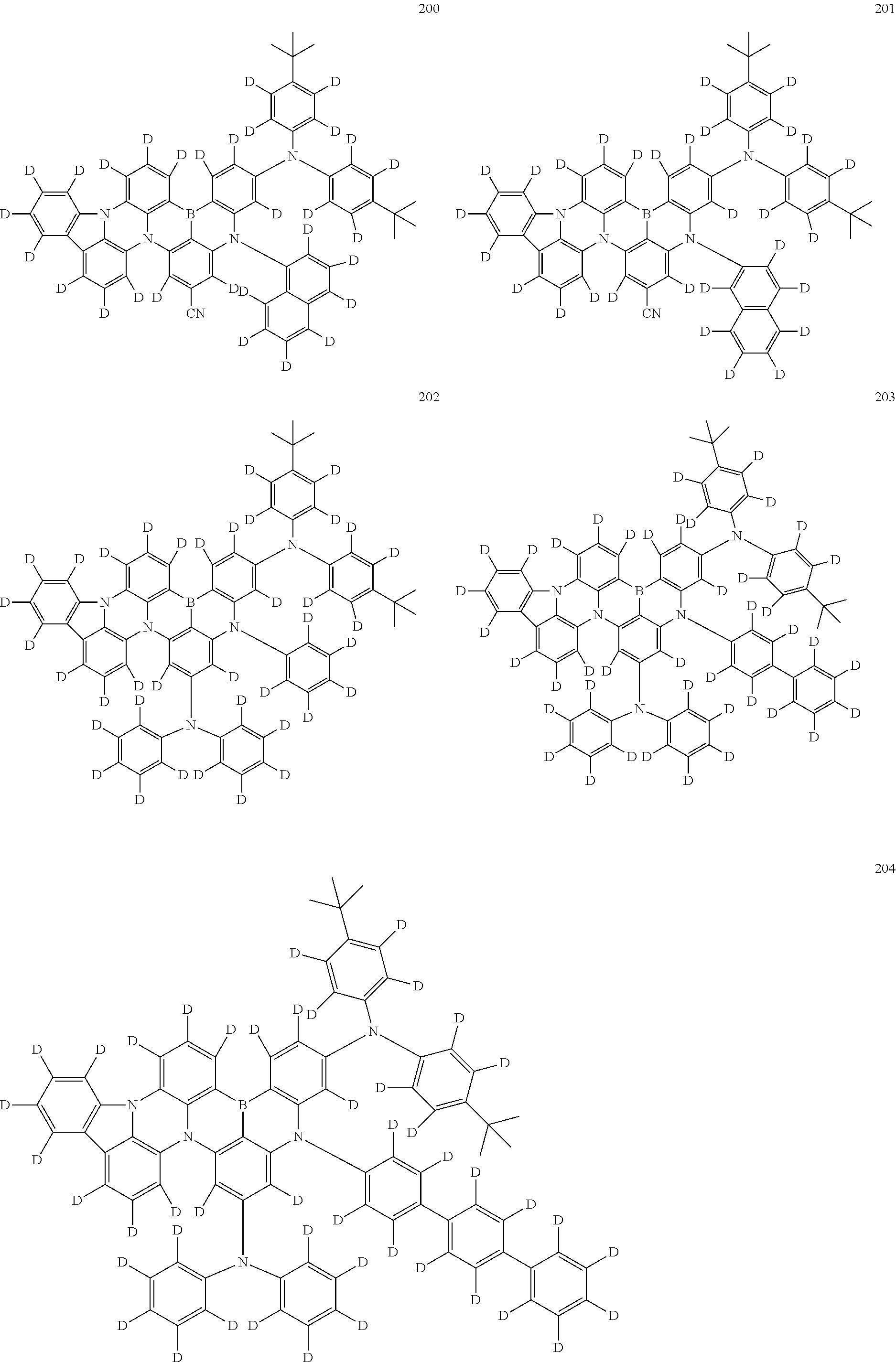

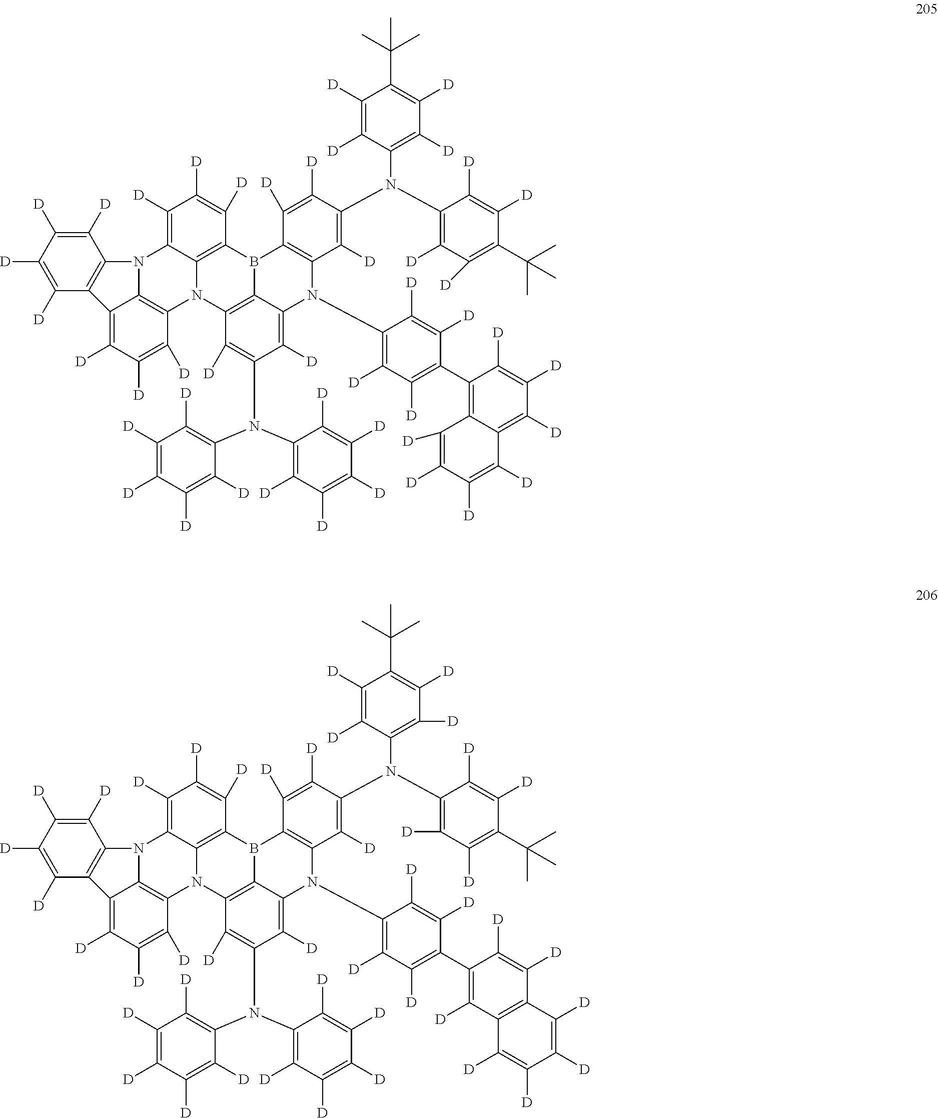

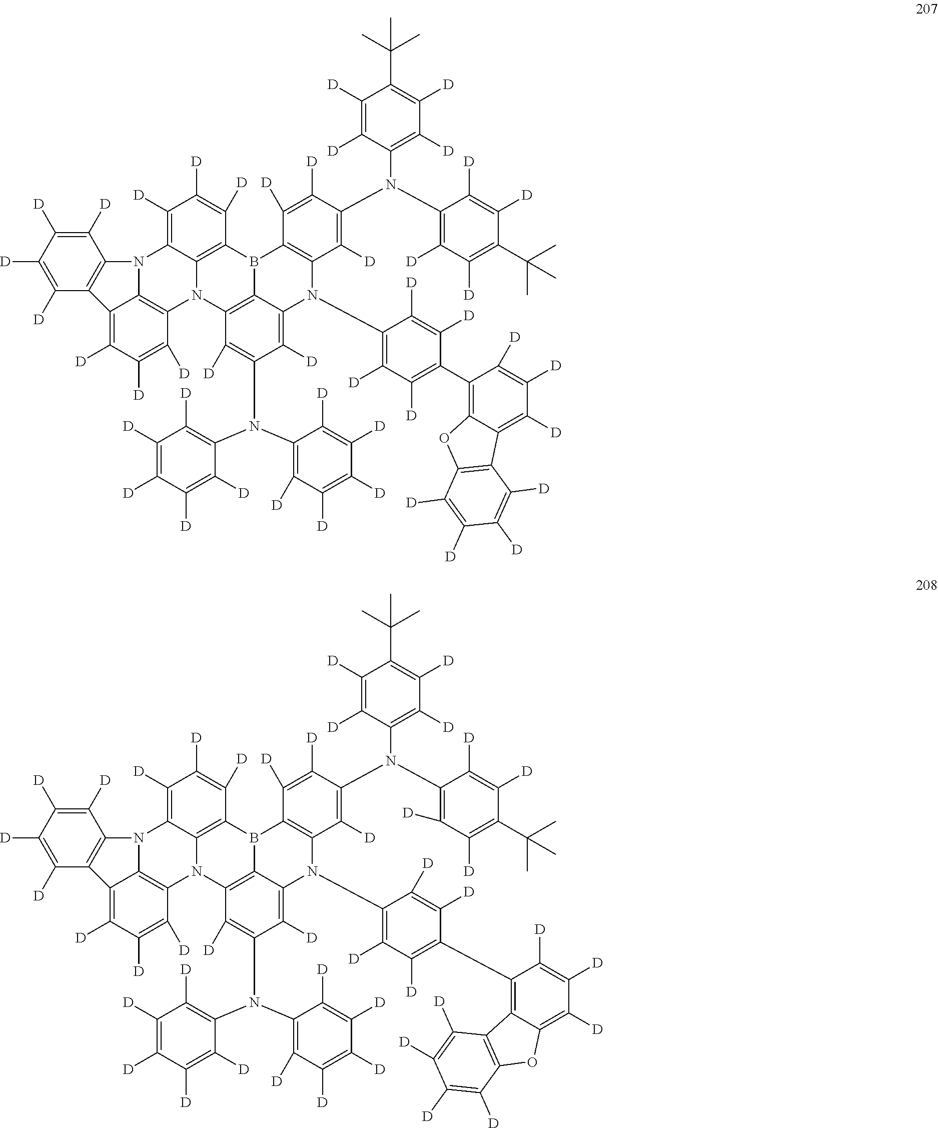

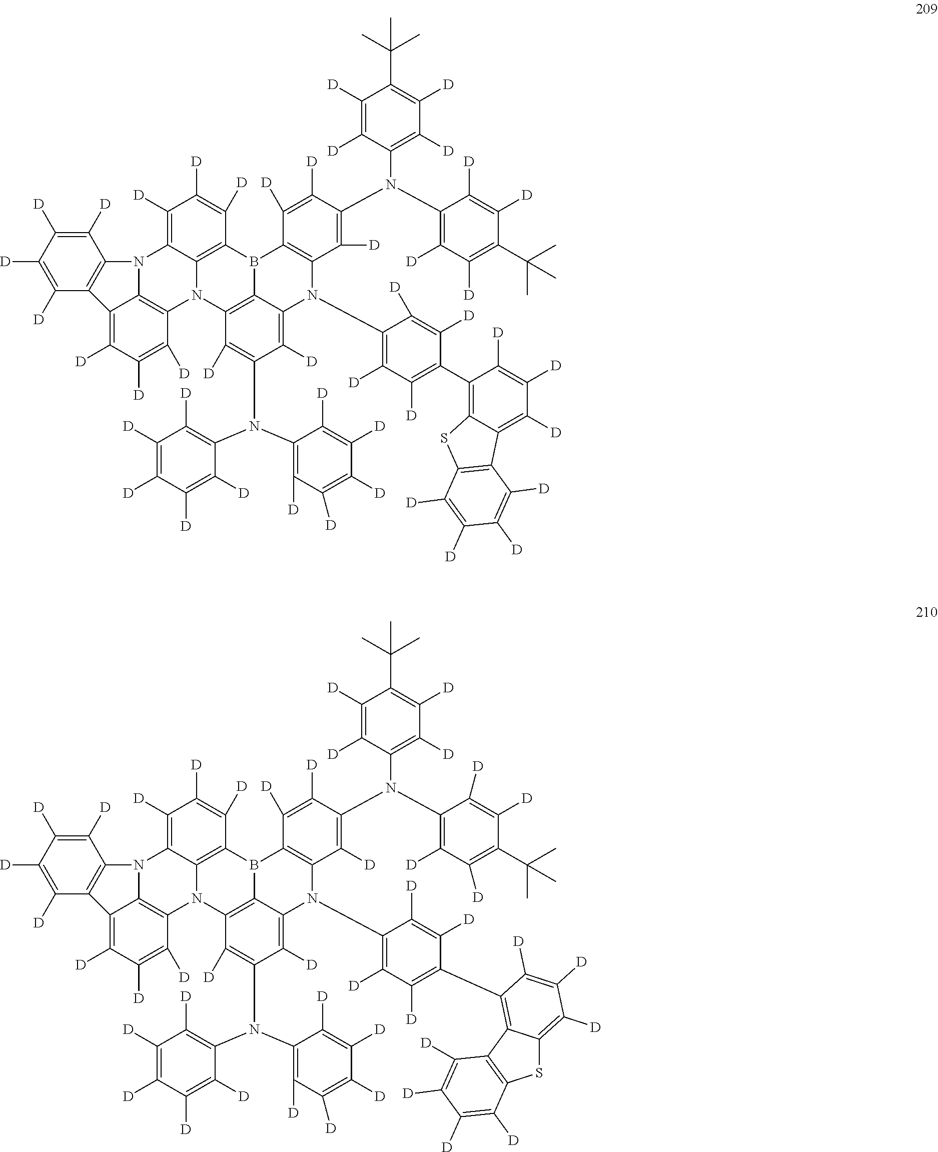

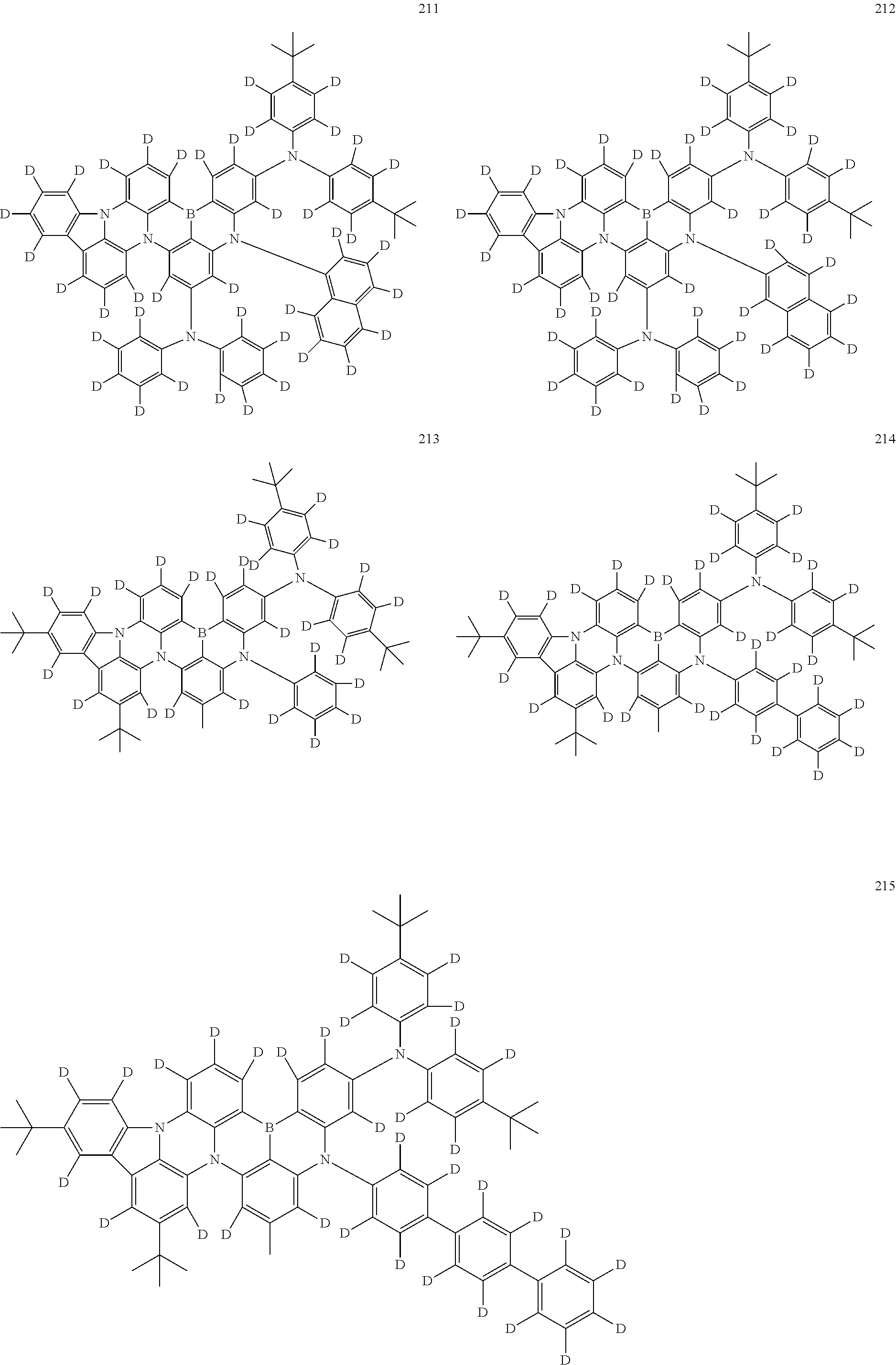

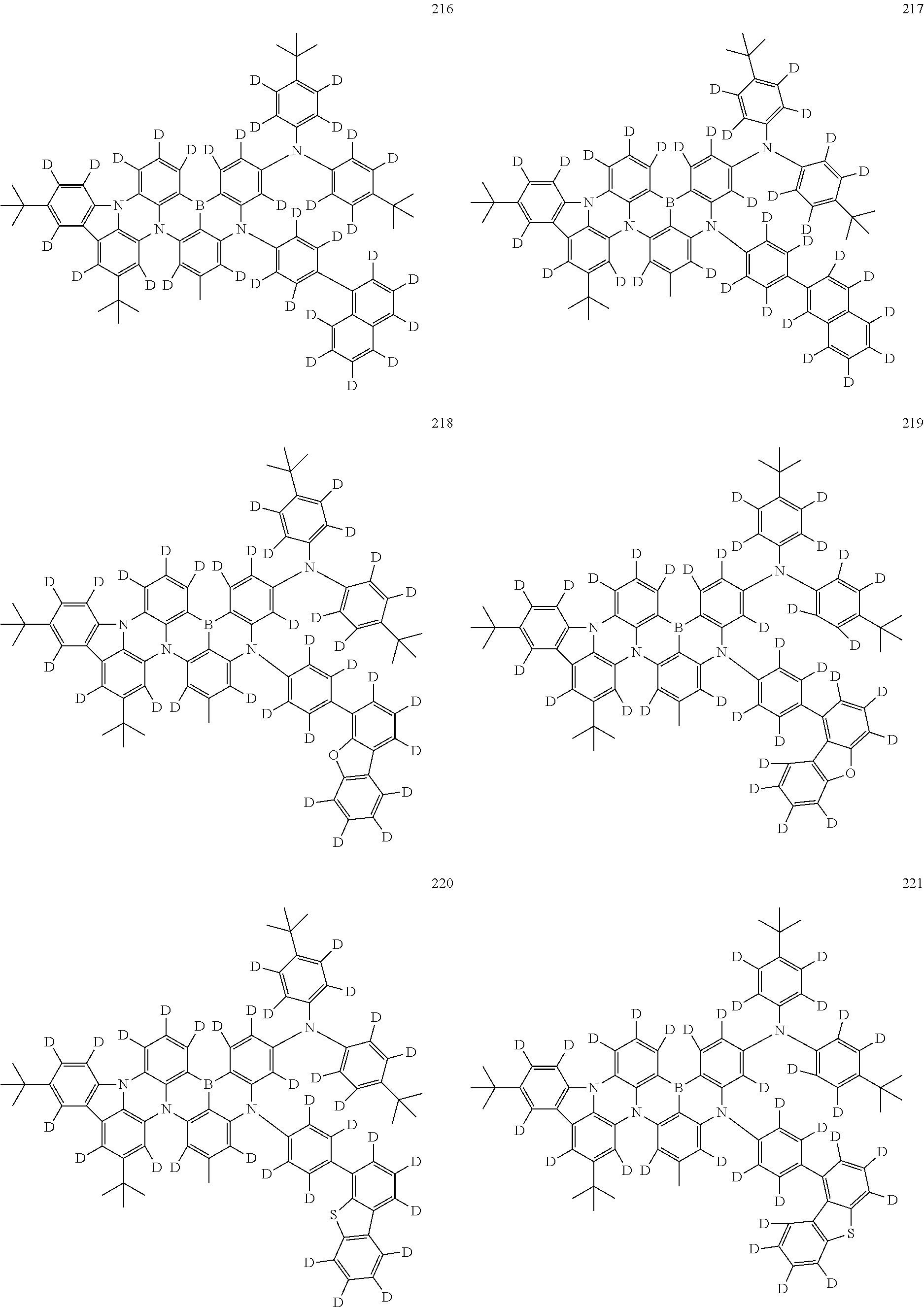

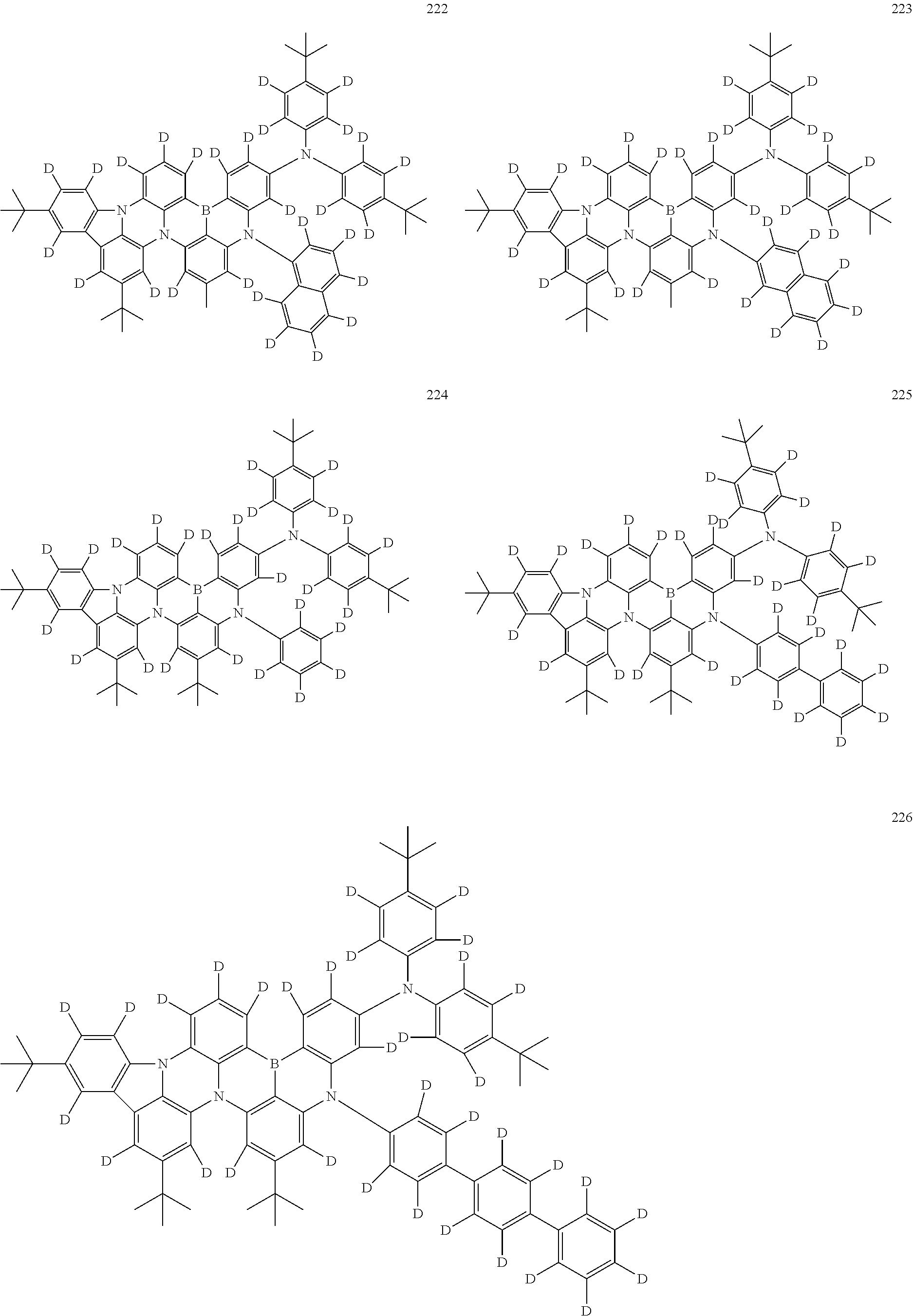

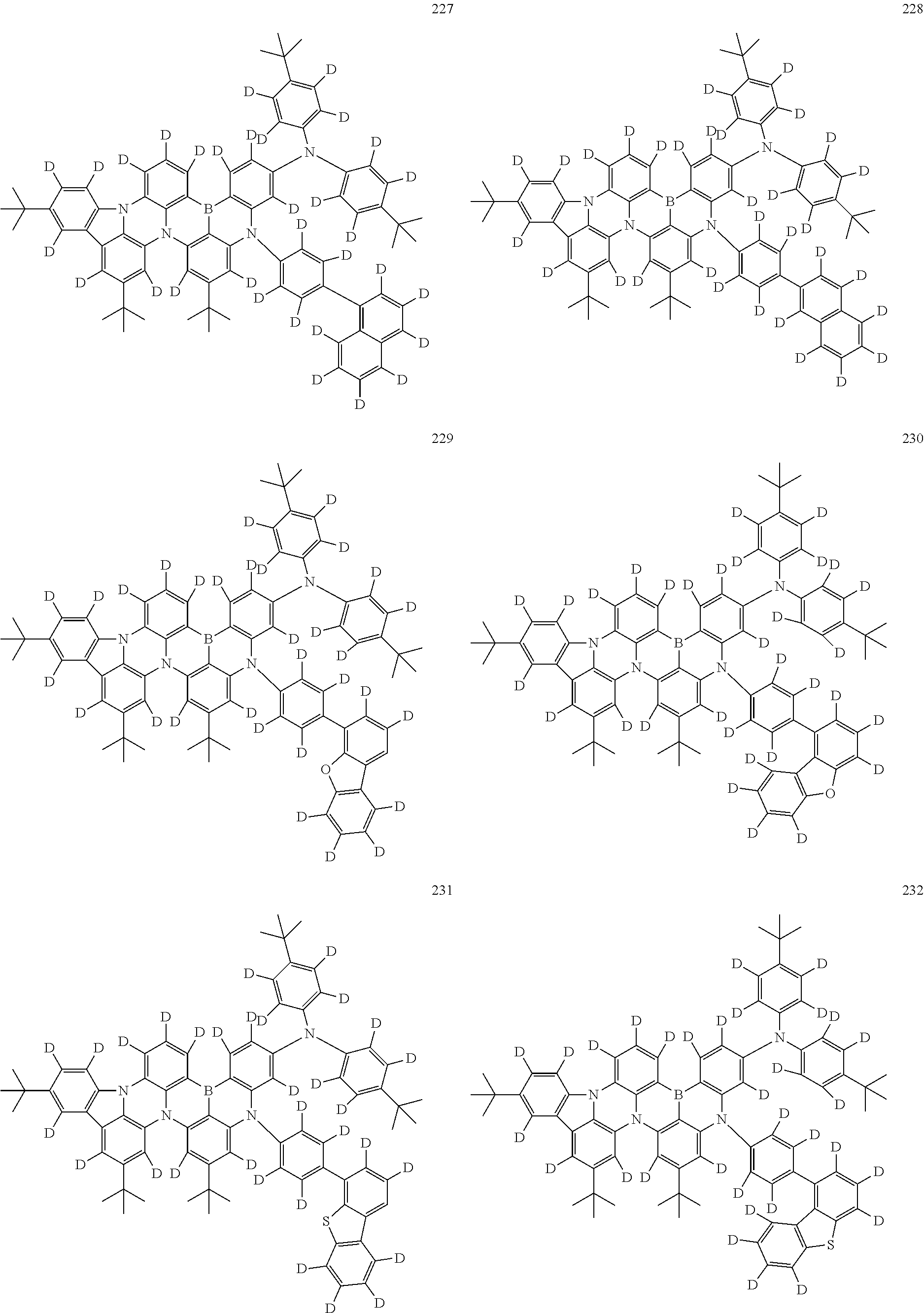

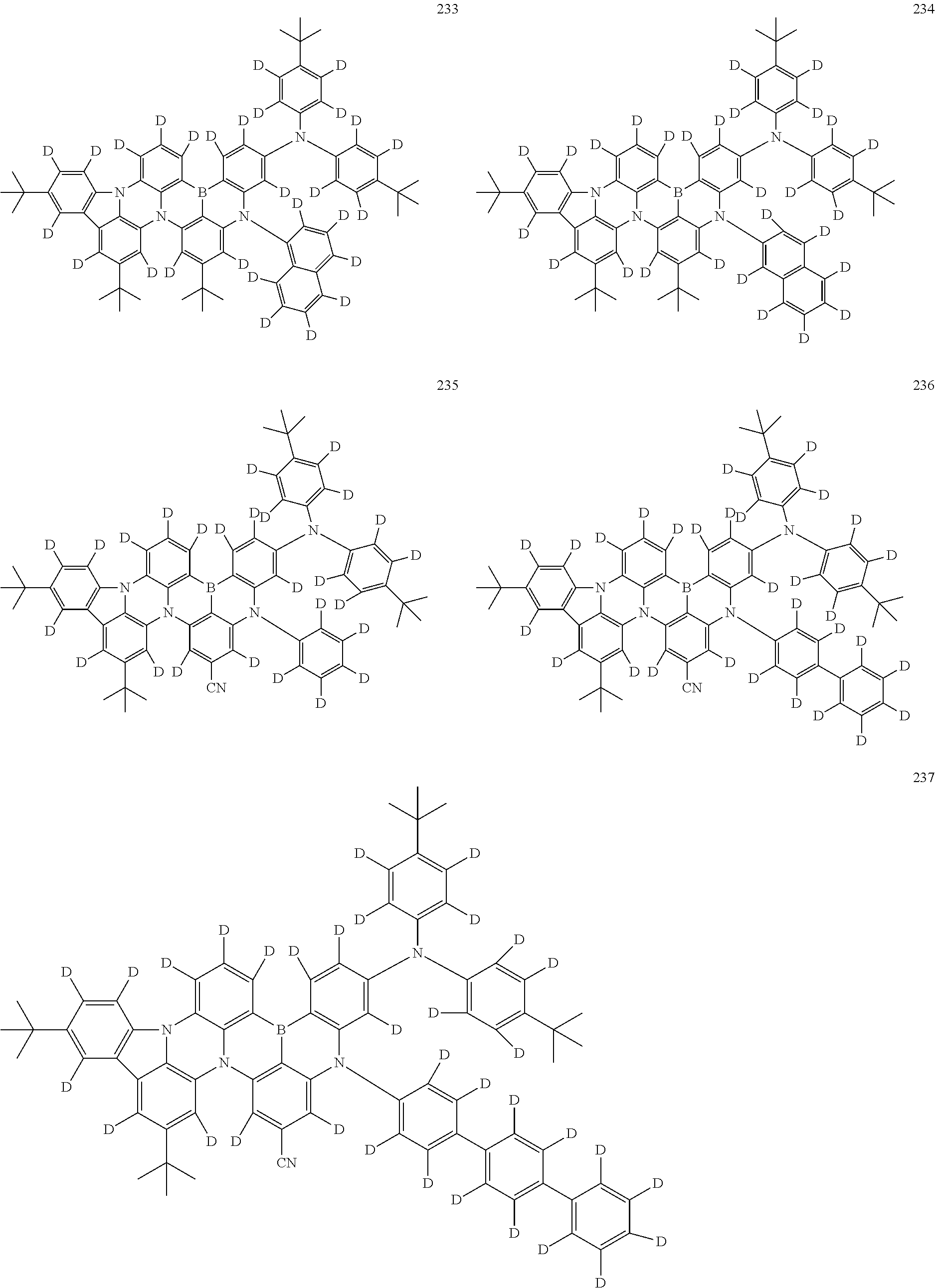

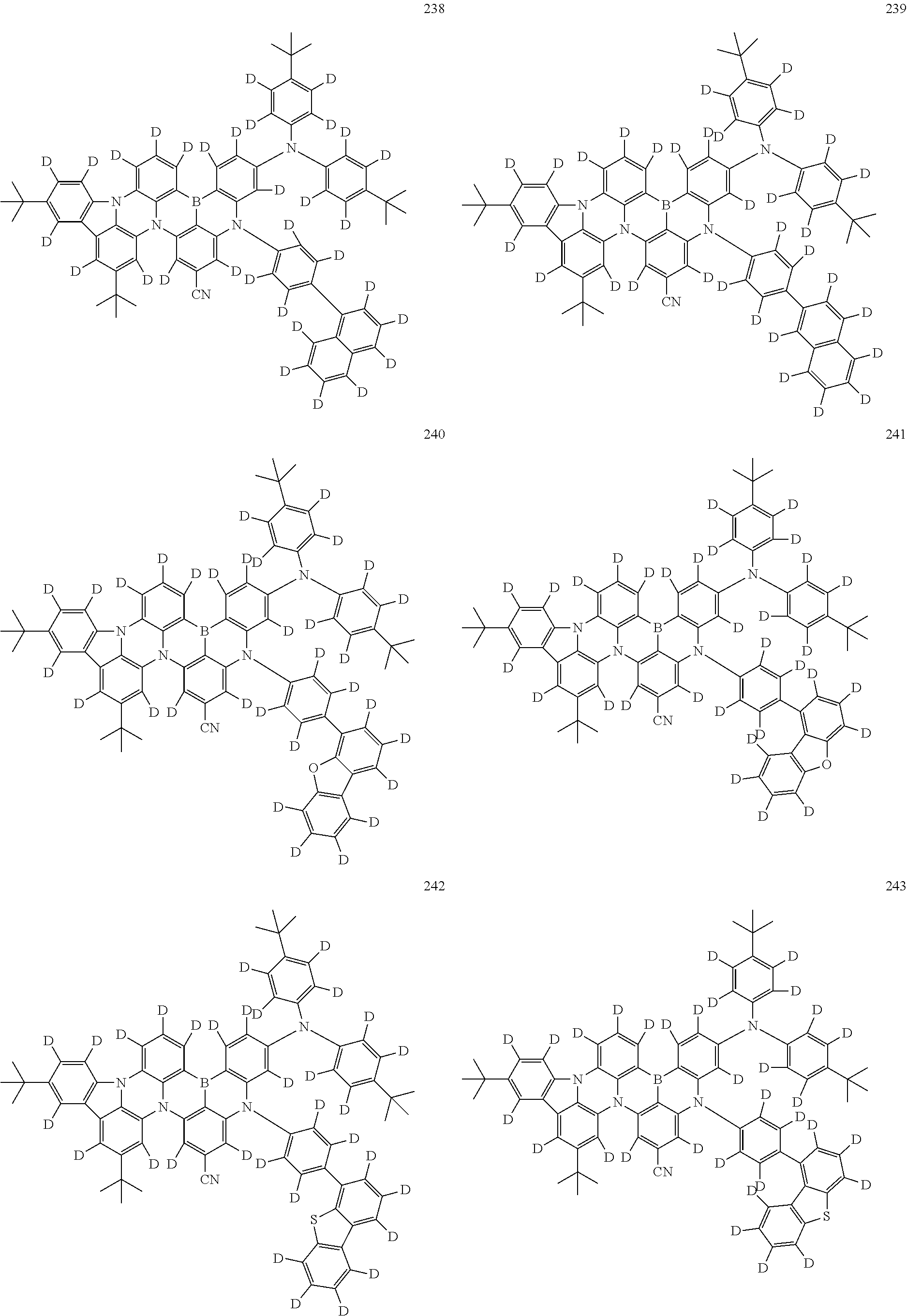

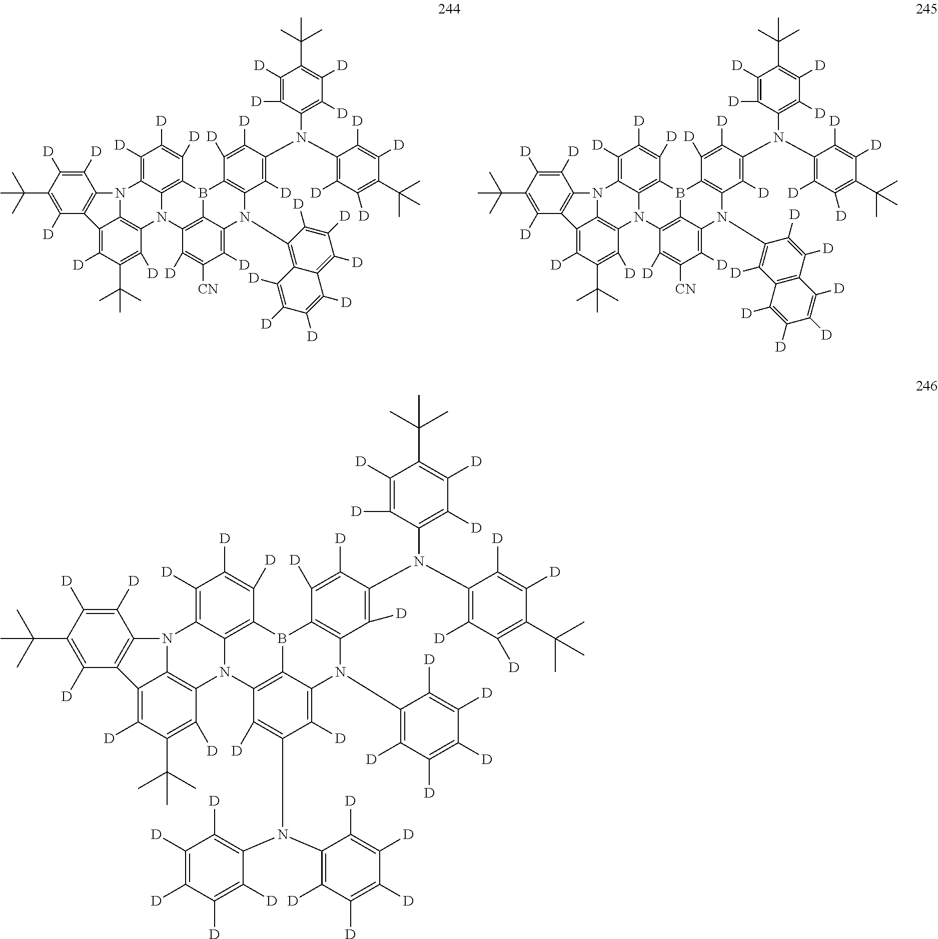

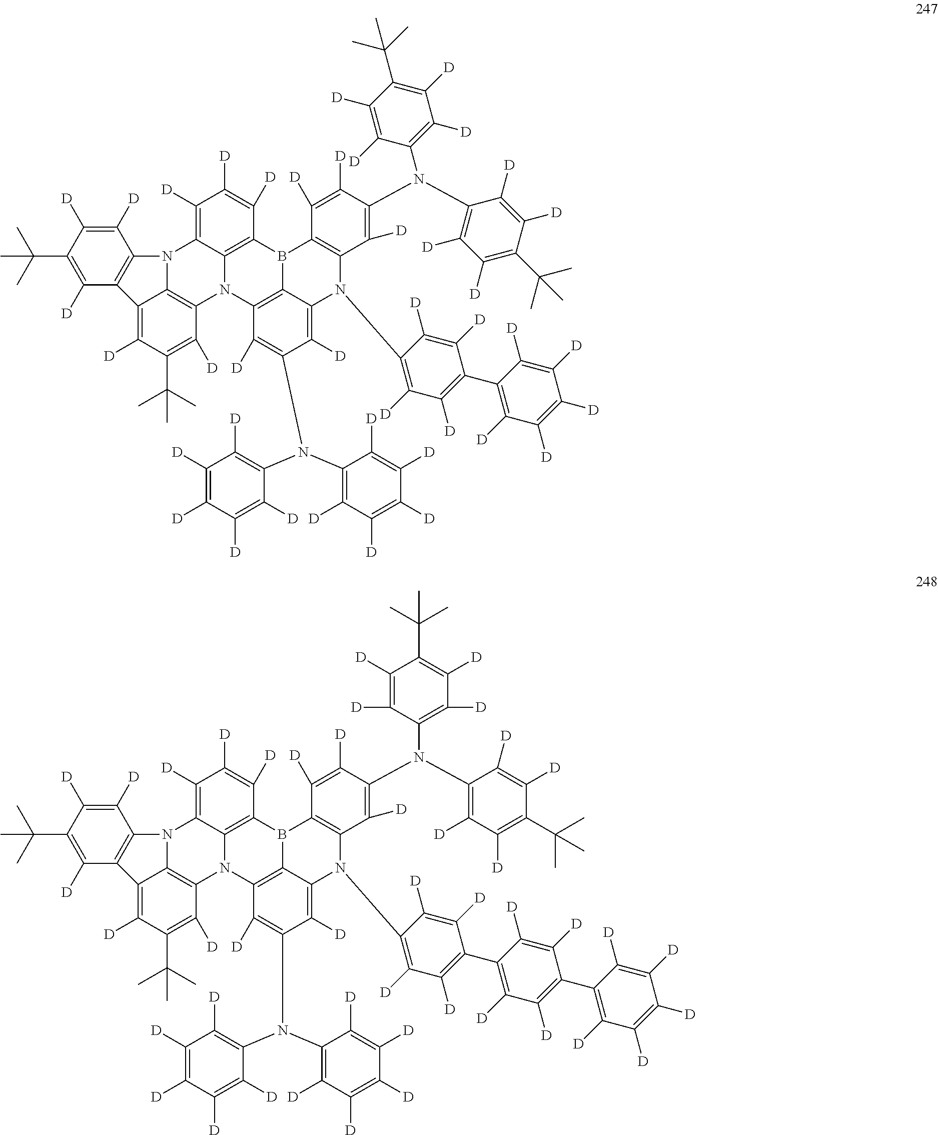

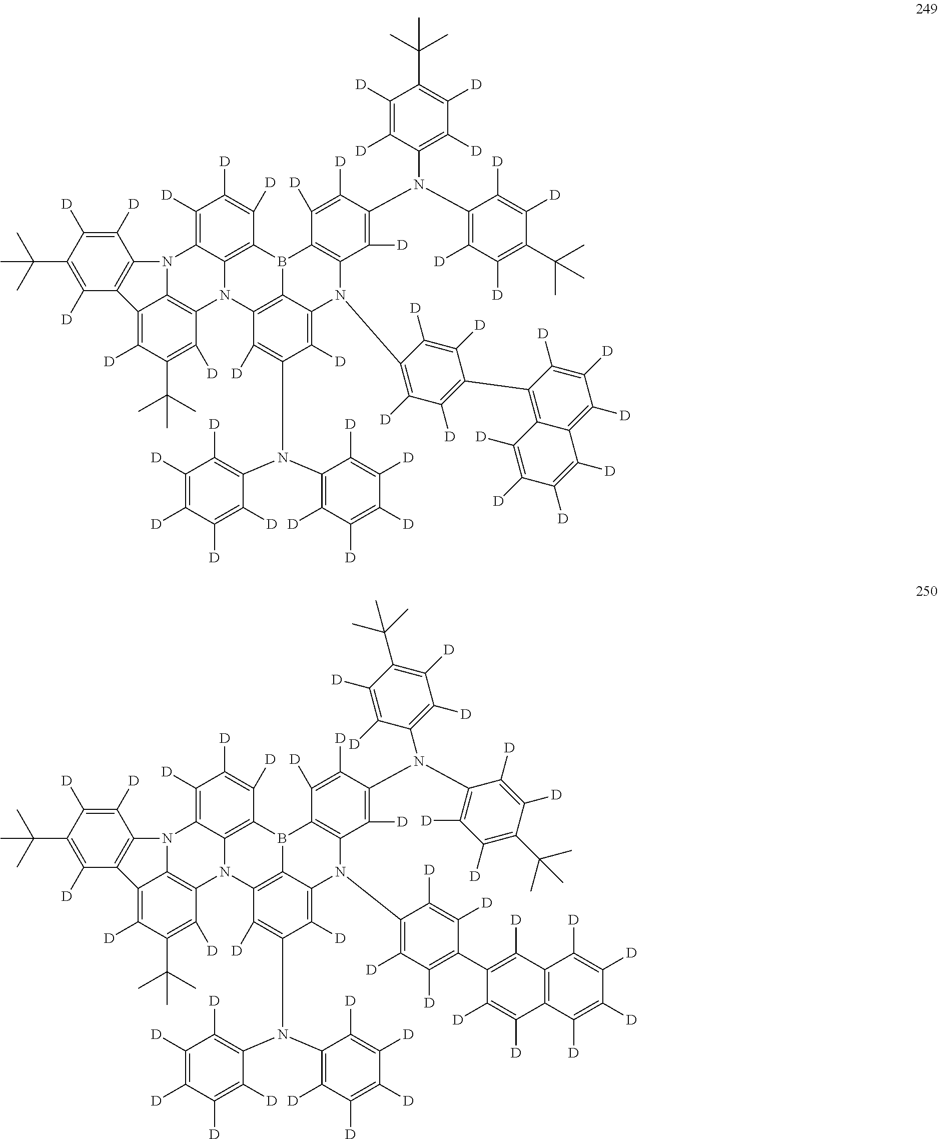

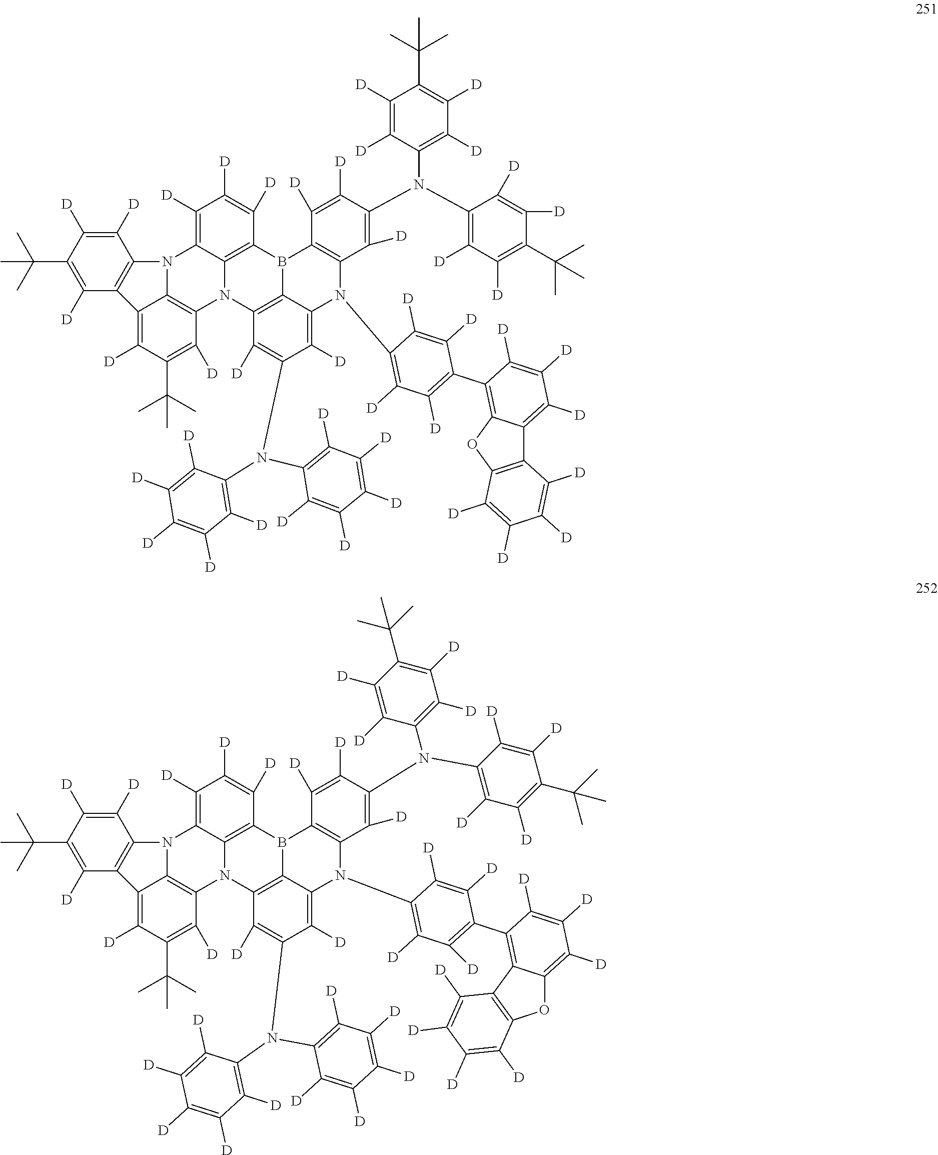

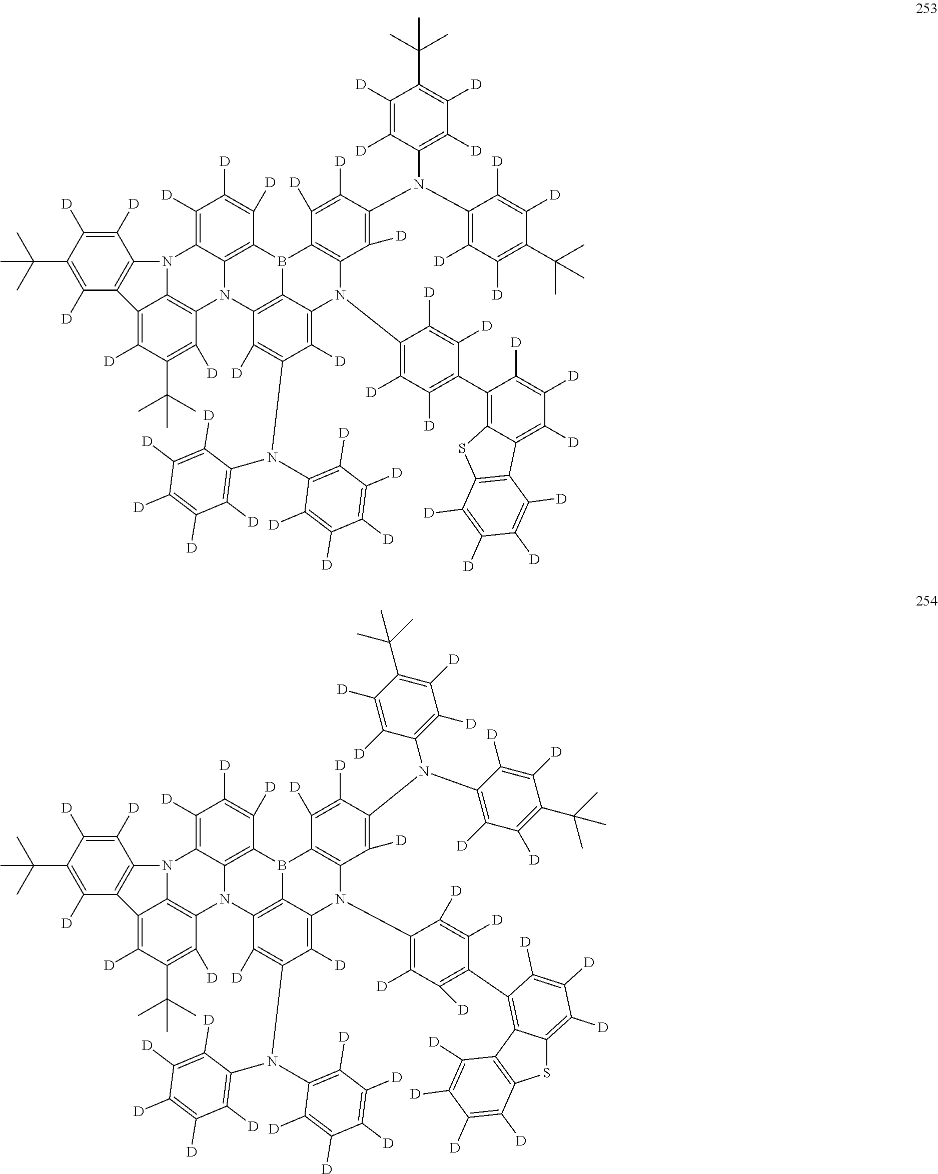

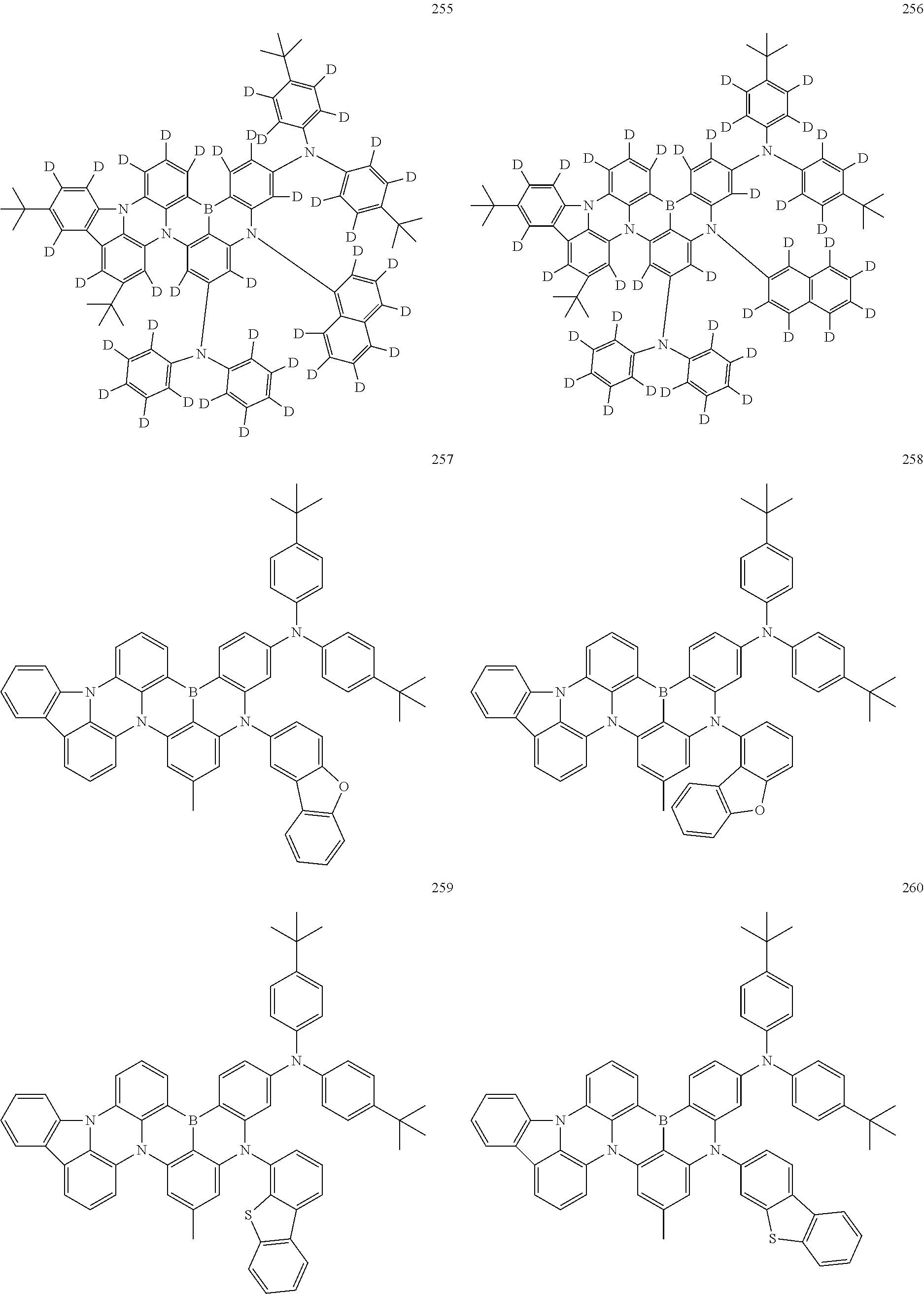

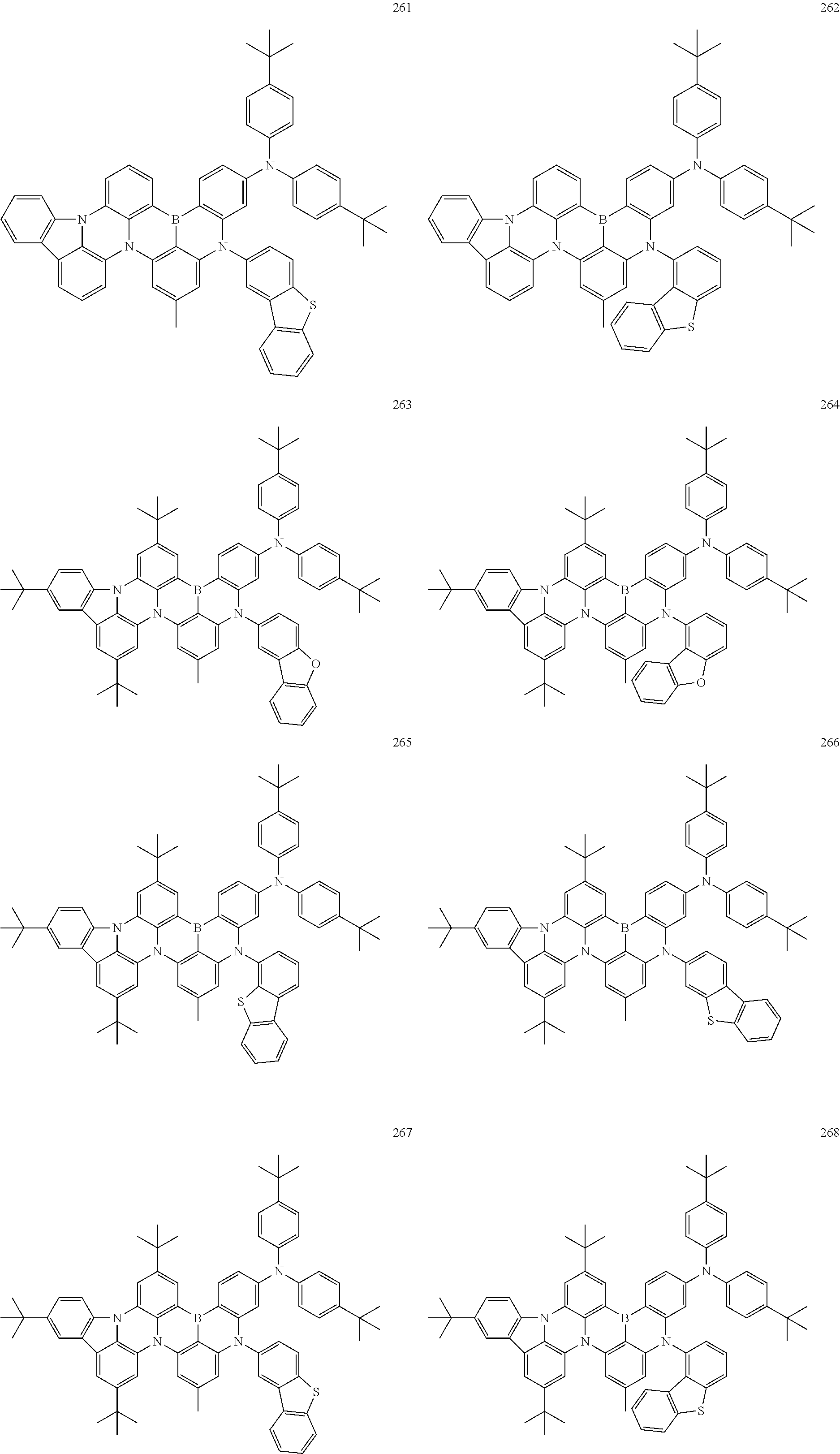

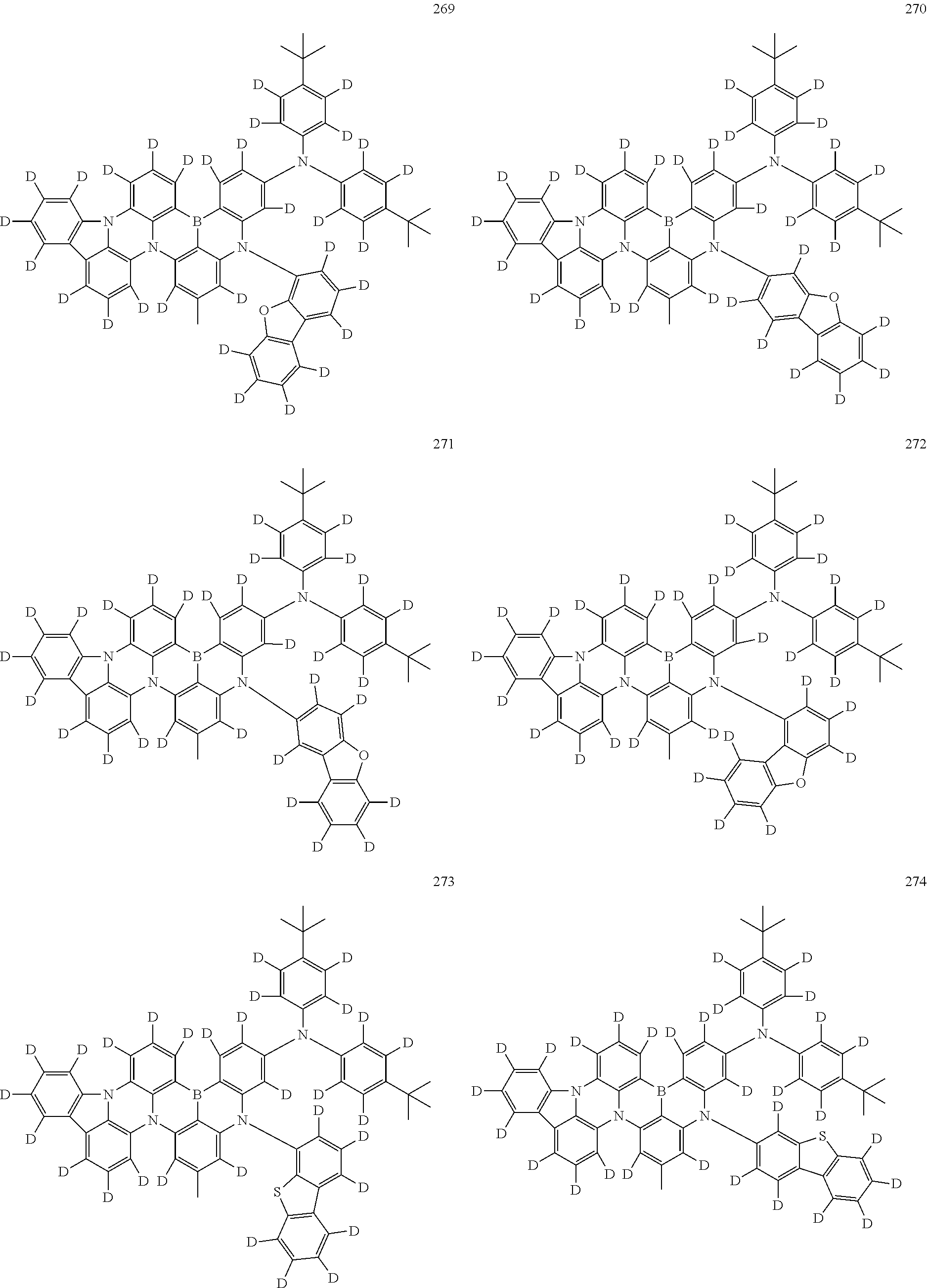

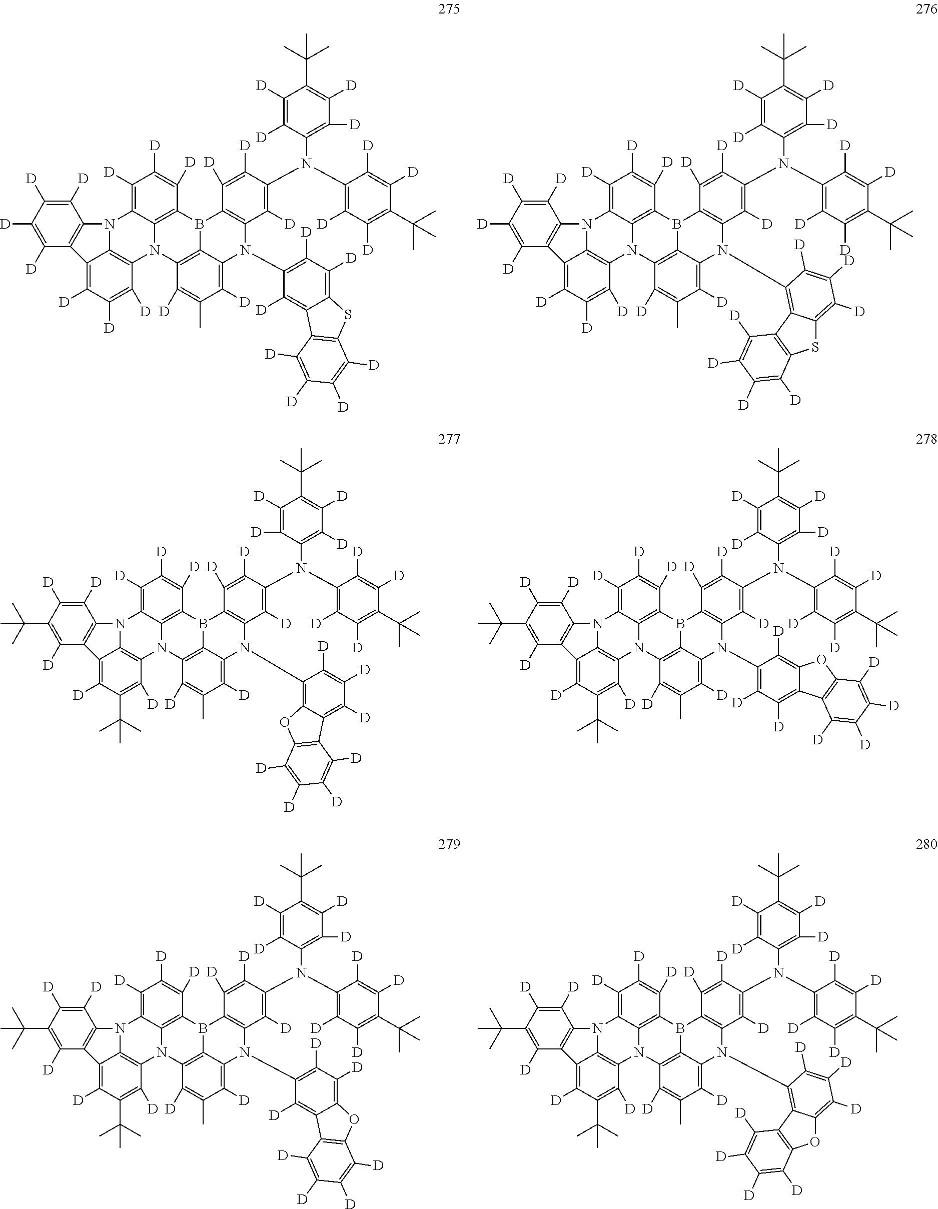

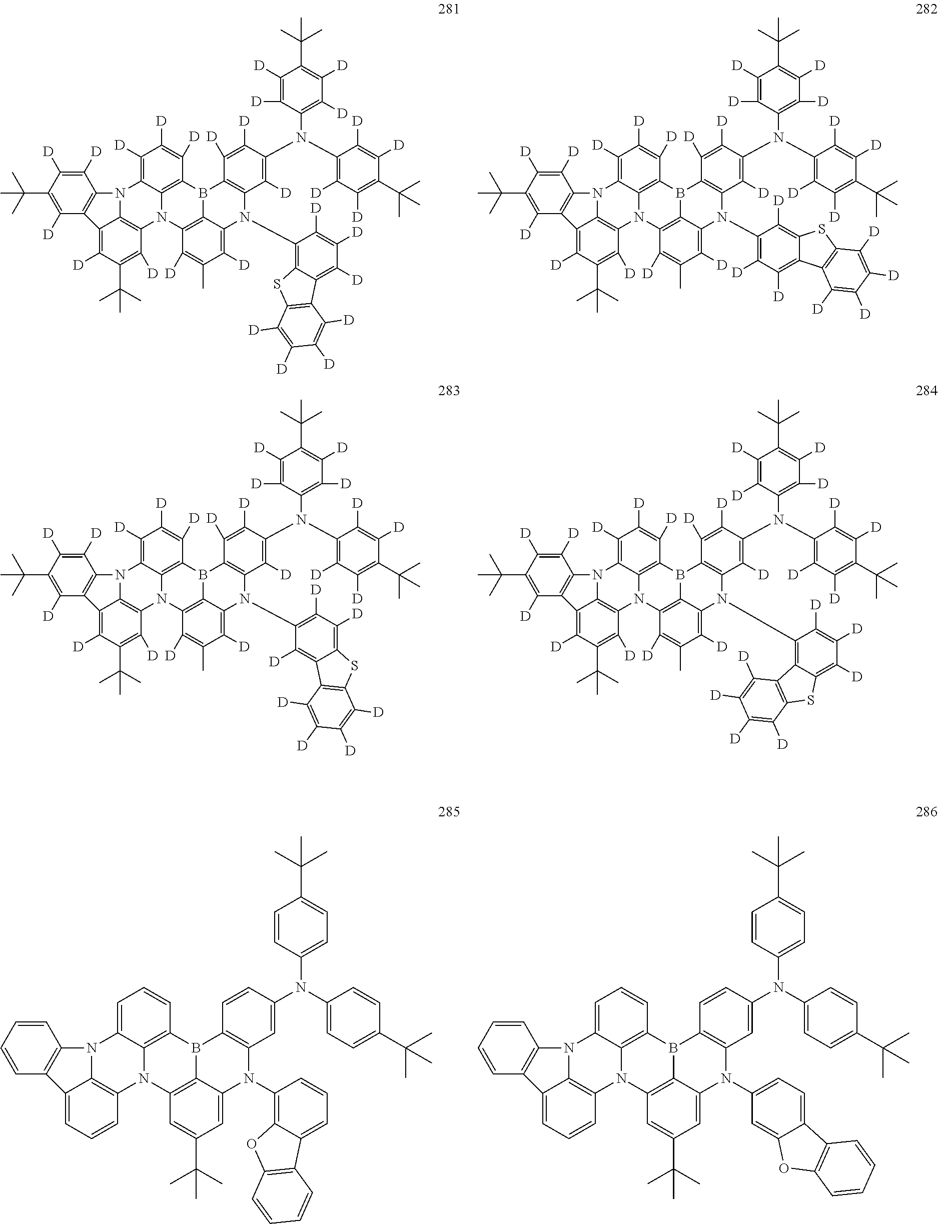

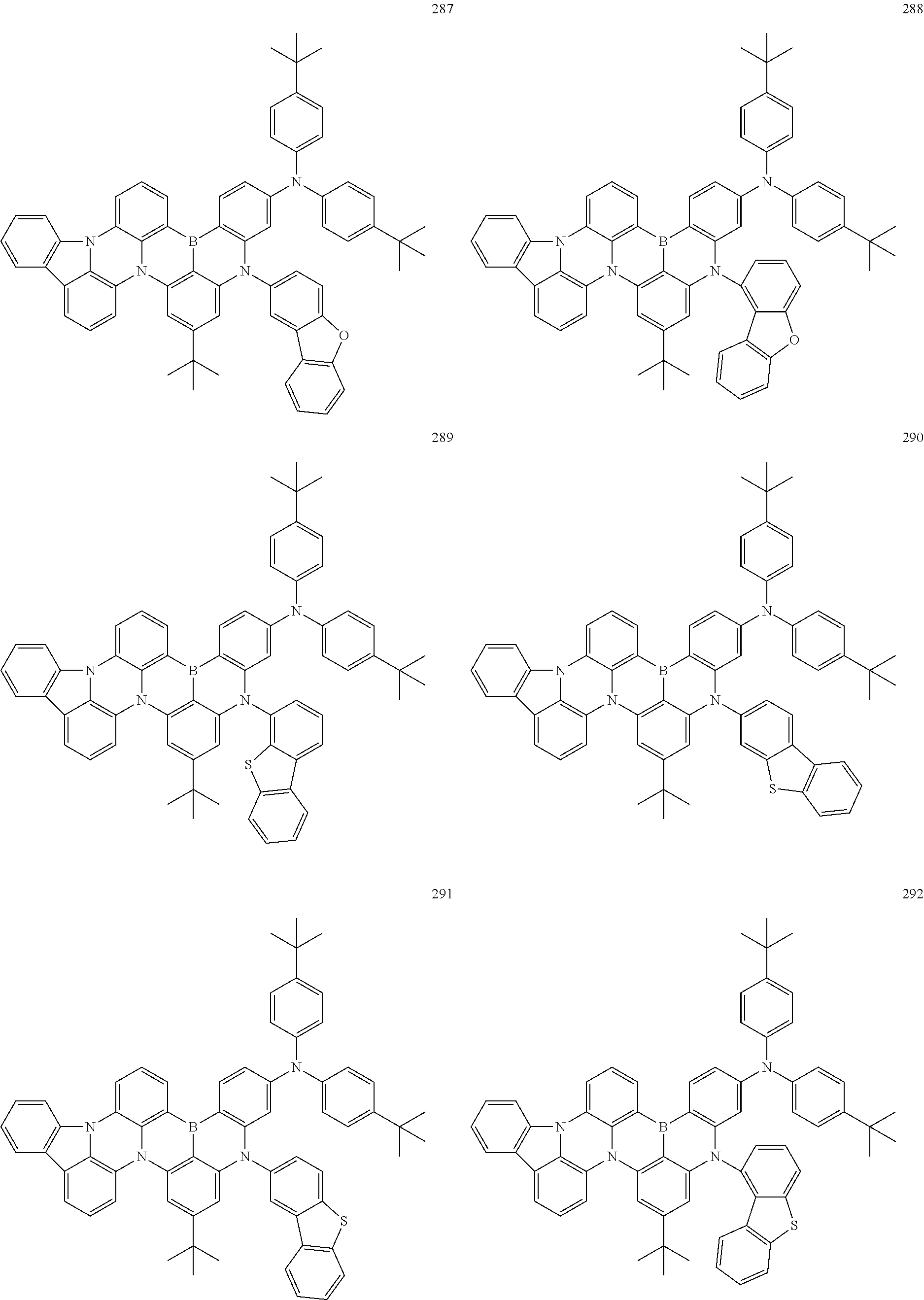

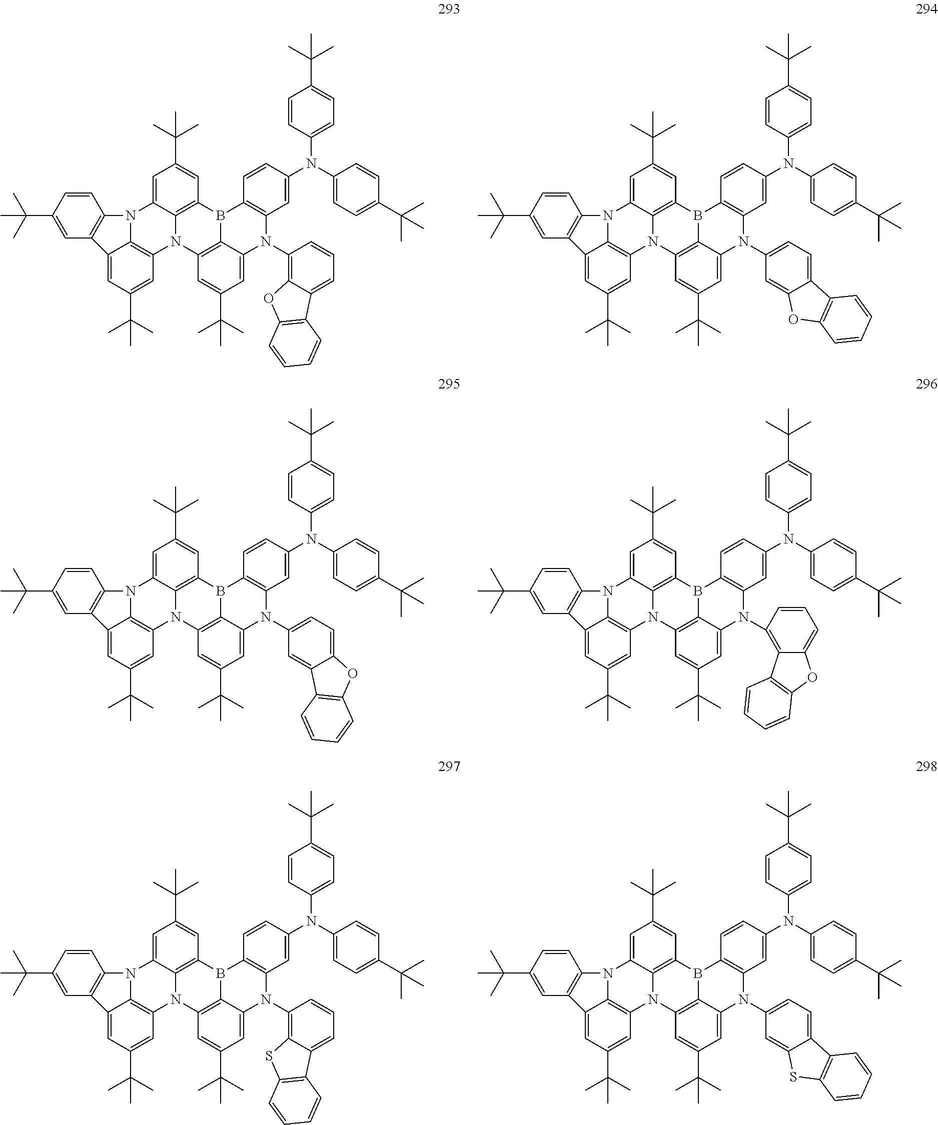

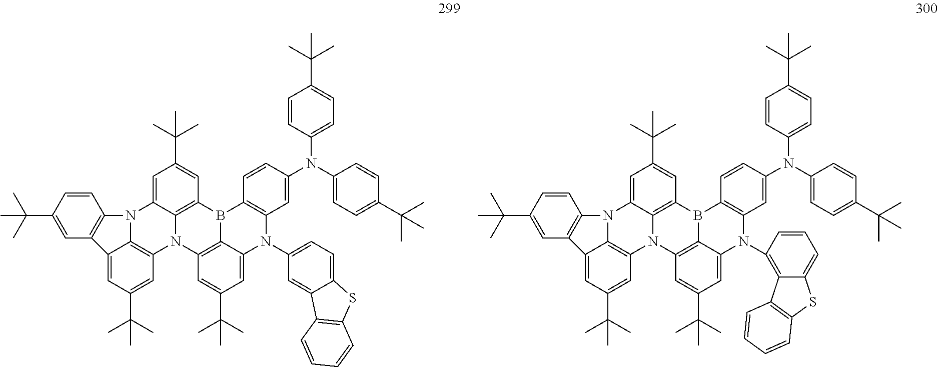 [SMILES: CC(C)(C)c1ccc(N(c2ccc(C(C)(C)C)cc2)c2ccc3c(c2)N(c2ccc4sc5ccccc5c4c2)c2cc(C(C)(C)C)cc4c2B3c2cc(C(C)(C)C)cc3c2N4c2cc(C(C)(C)C)cc4c5cc(C(C)(C)C)ccc5n-3c24)cc1 ; CC(C)(C)c1ccc(N(c2ccc(C(C)(C)C)cc2)c2ccc3c(c2)N(c2cccc4sc5ccccc5c24)c2cc(C(C)(C)C)cc4c2B3c2cc(C(C)(C)C)cc3c2N4c2cc(C(C)(C)C)cc4c5cc(C(C)(C)C)ccc5n-3c24)cc1]

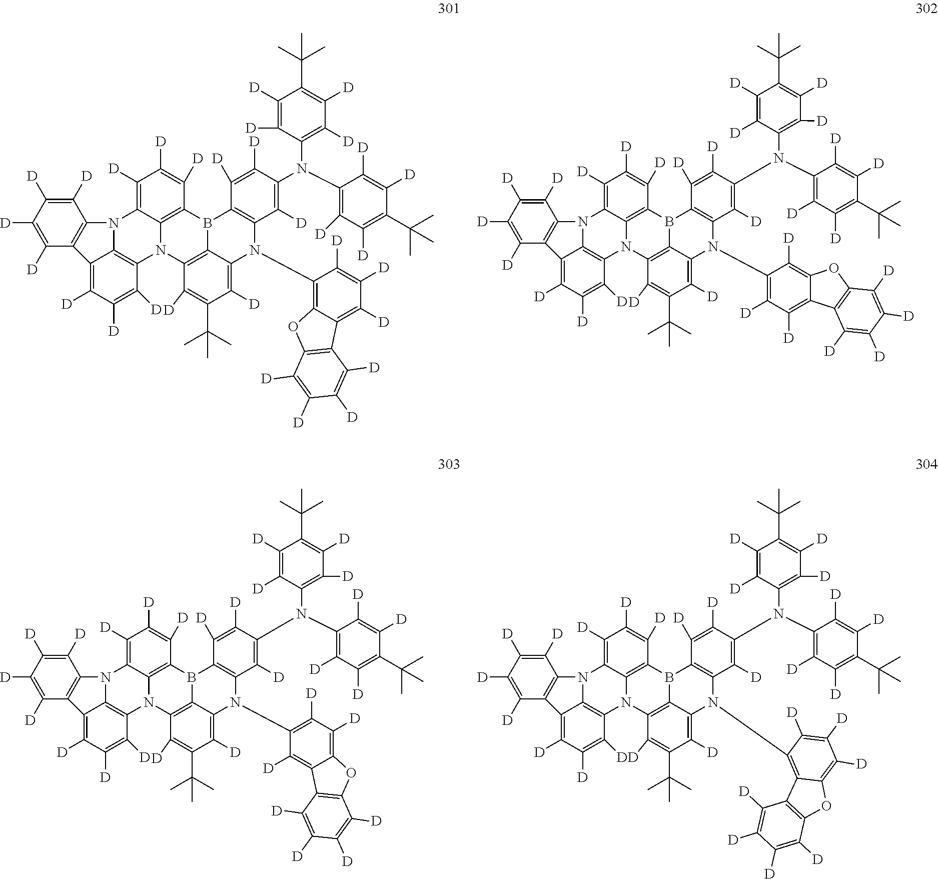

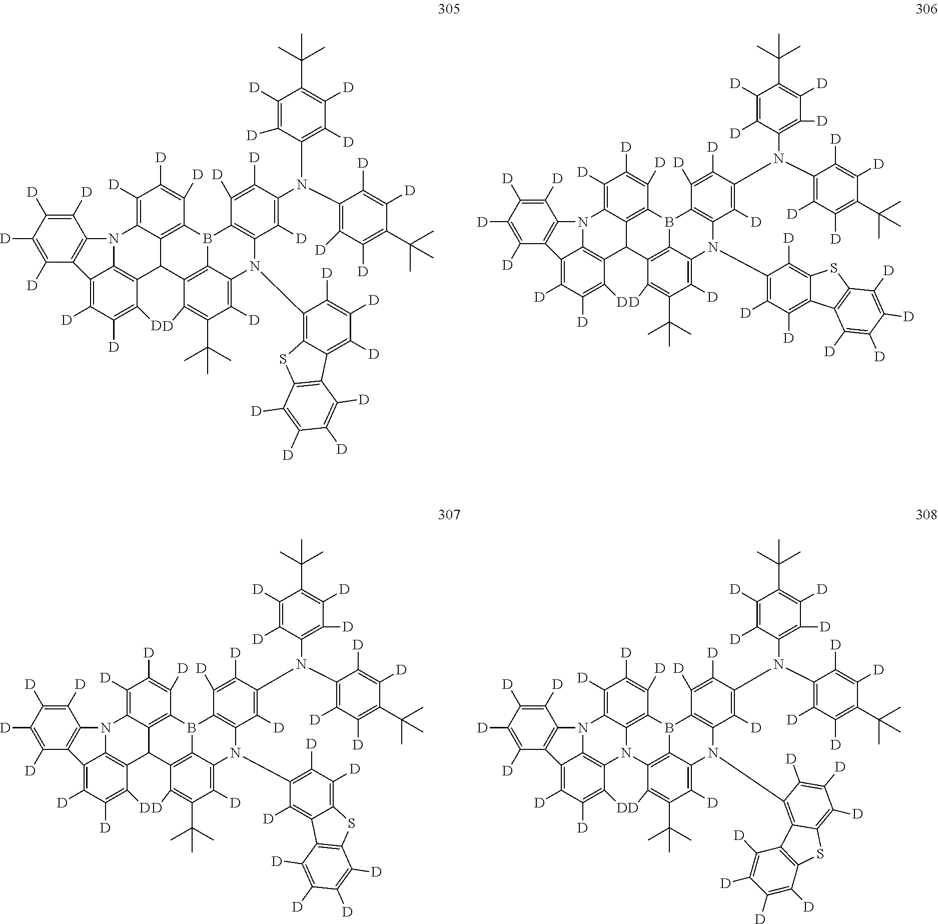

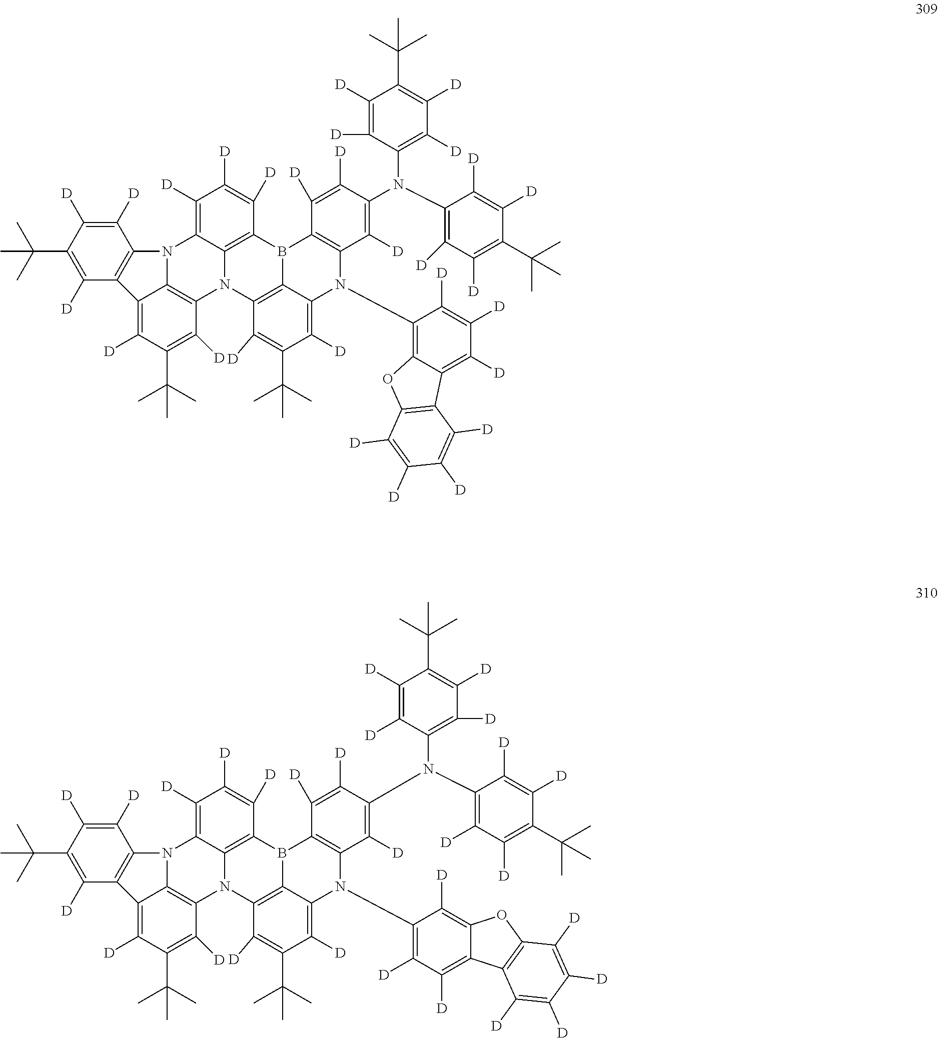

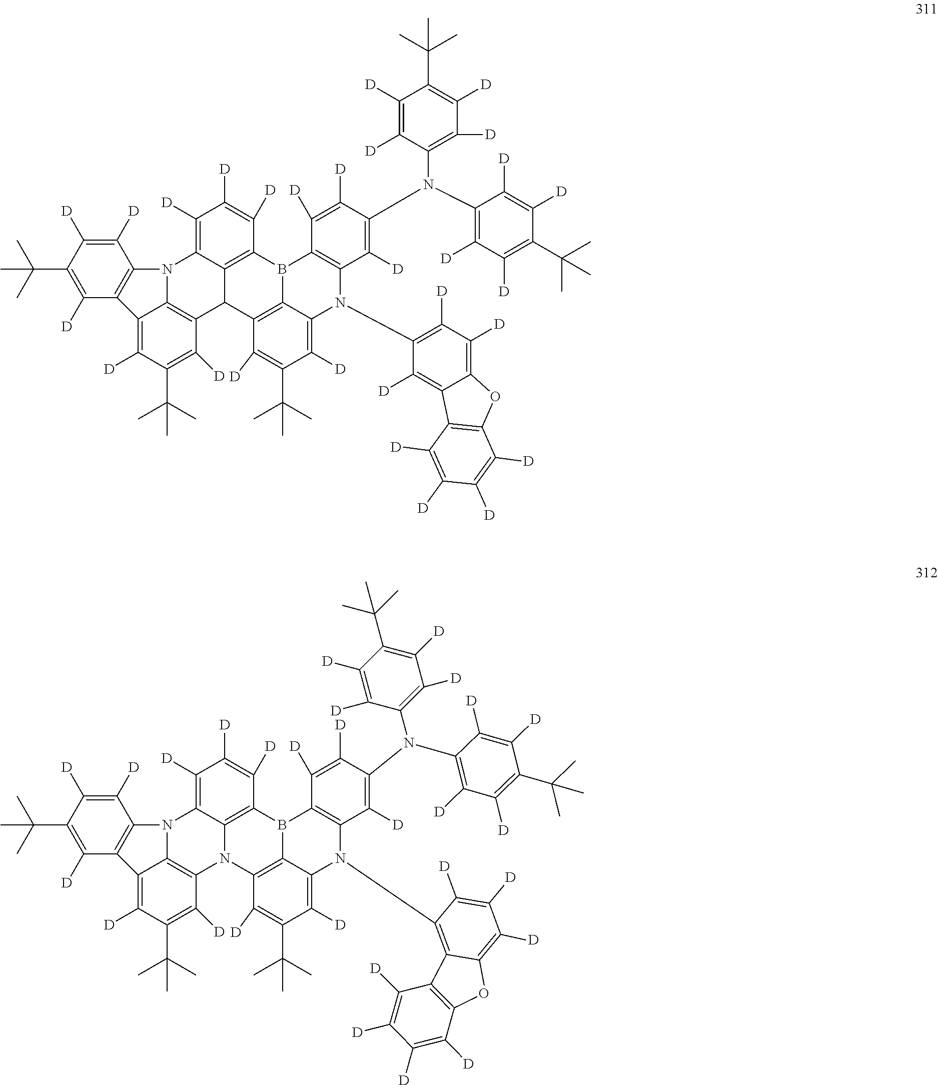

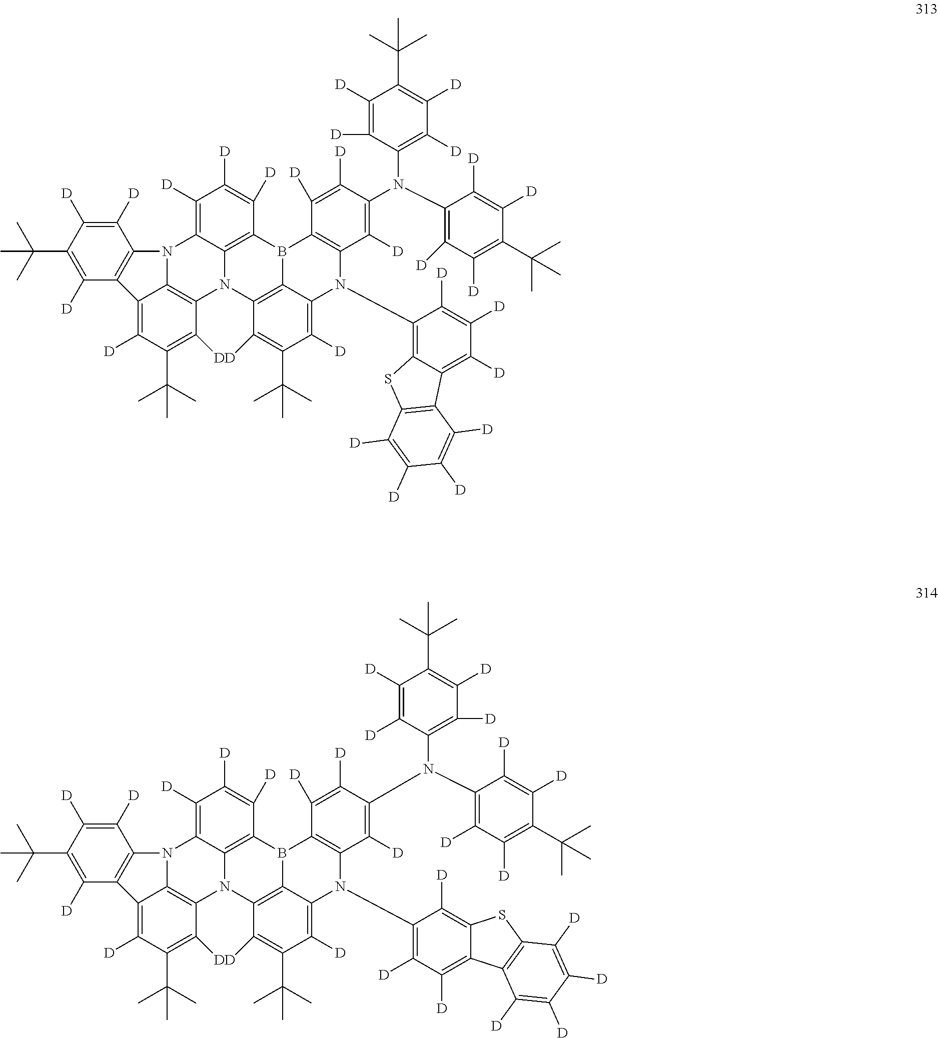

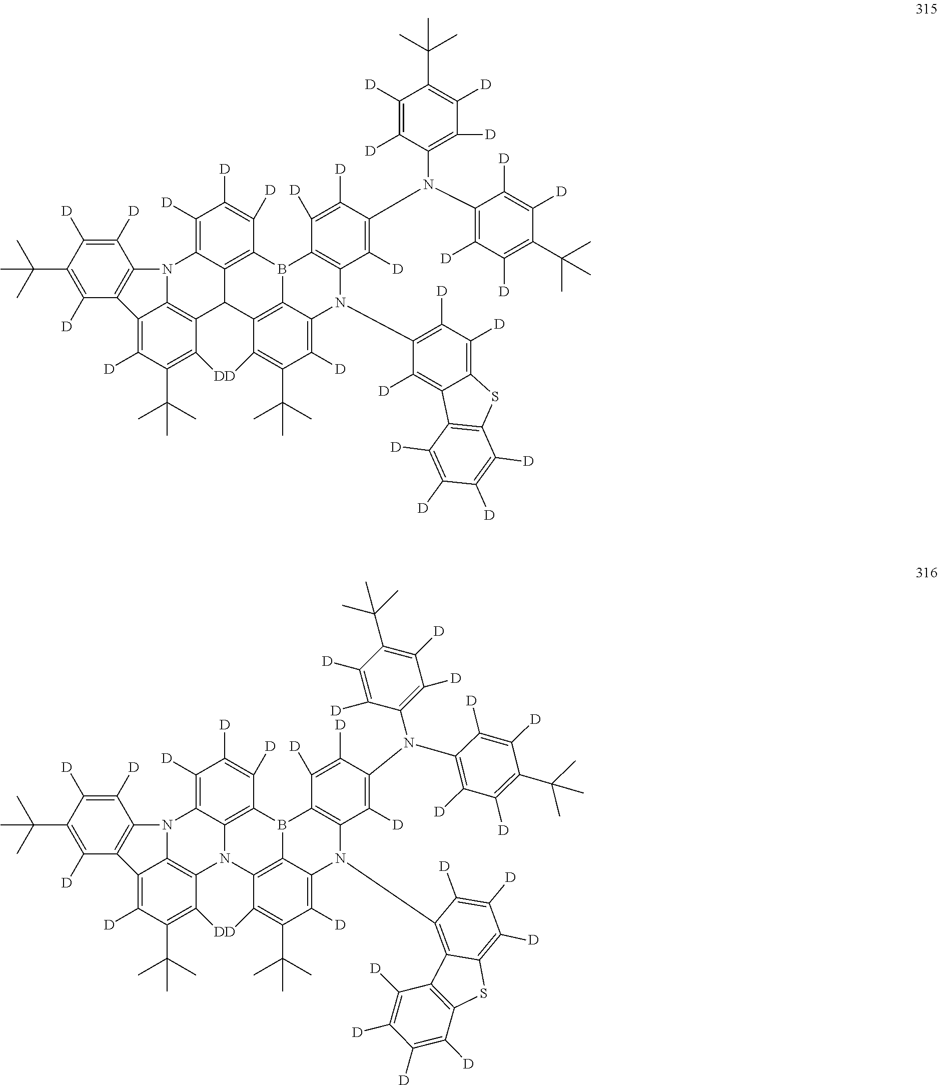

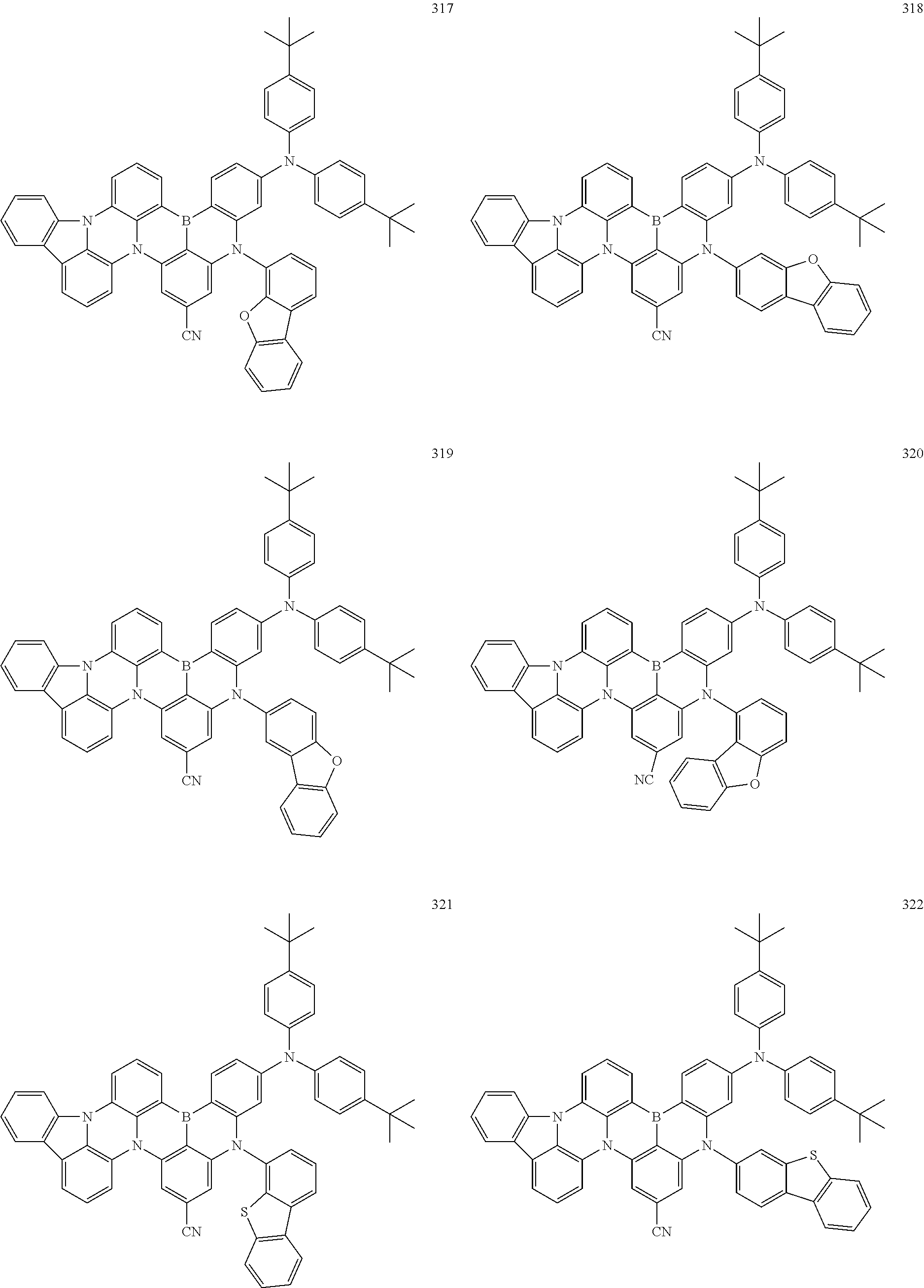

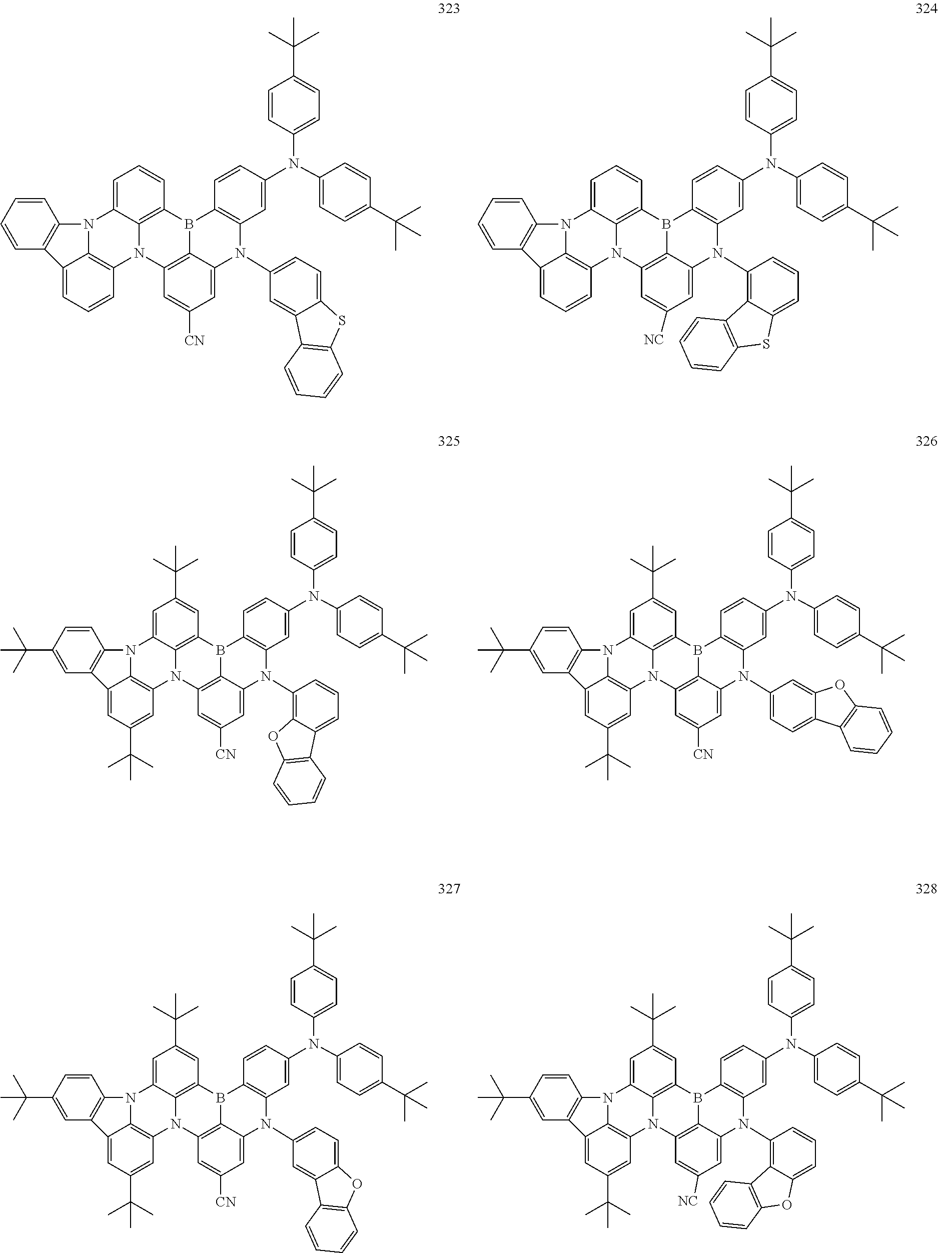

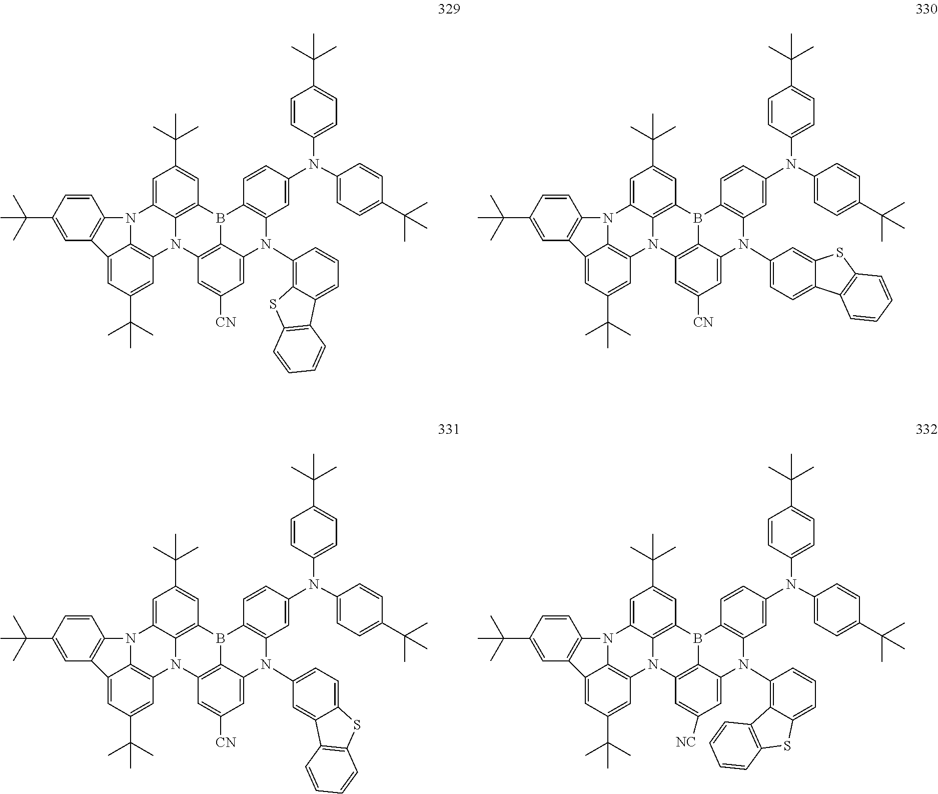

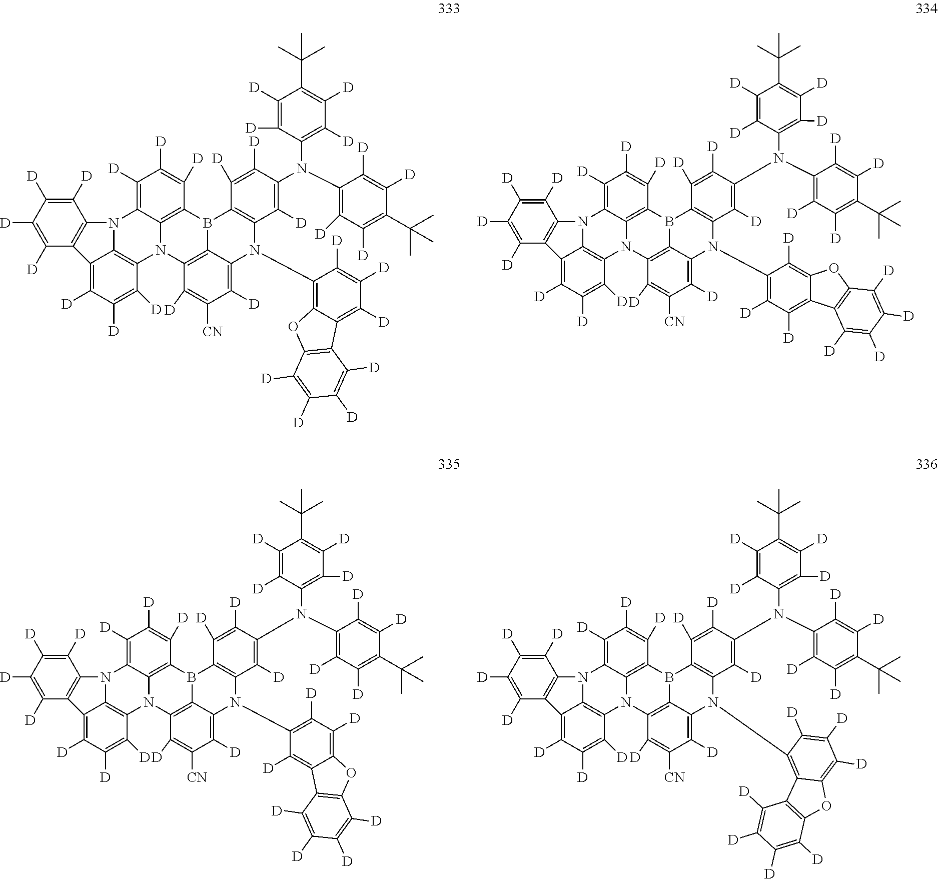

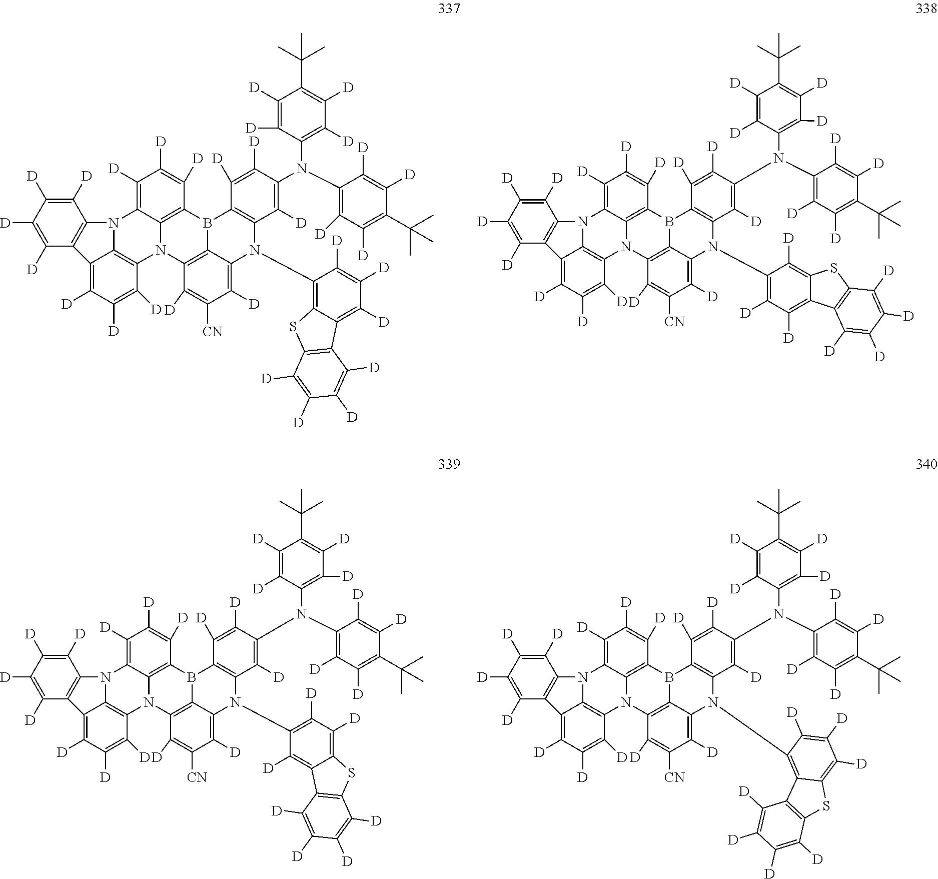

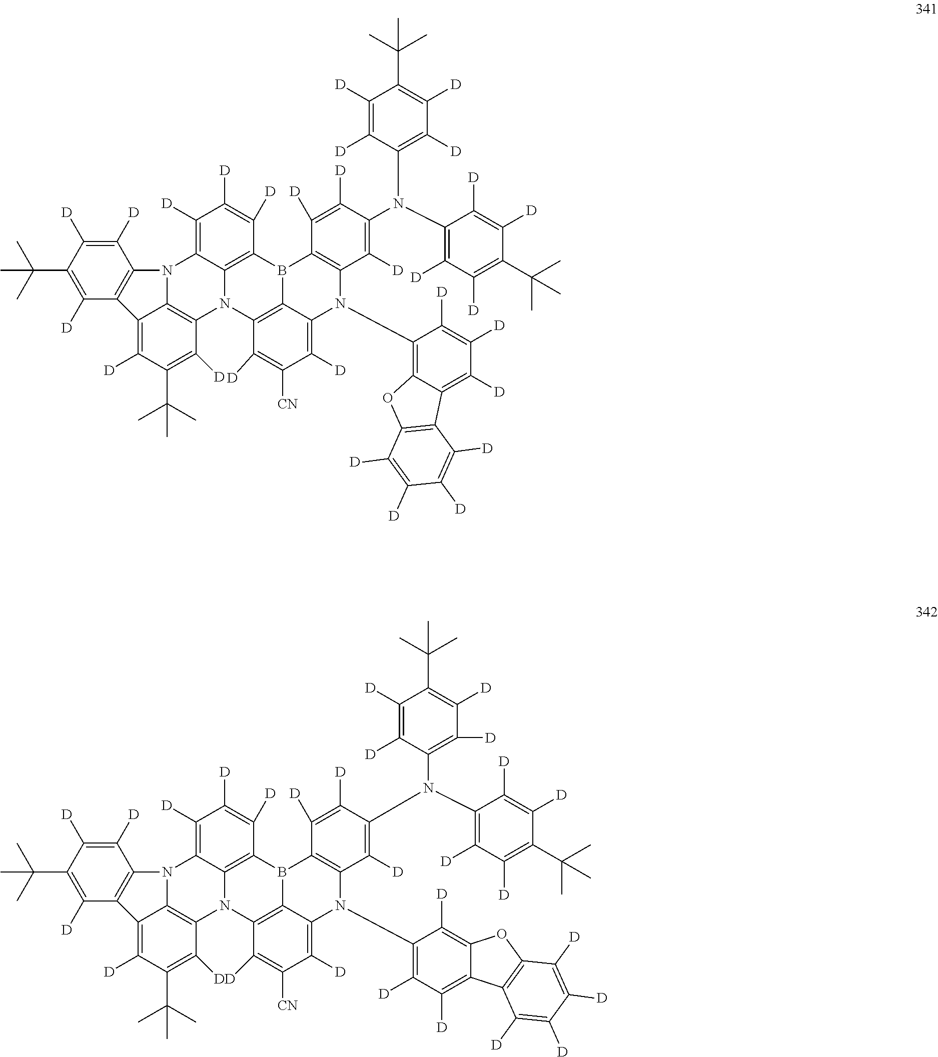

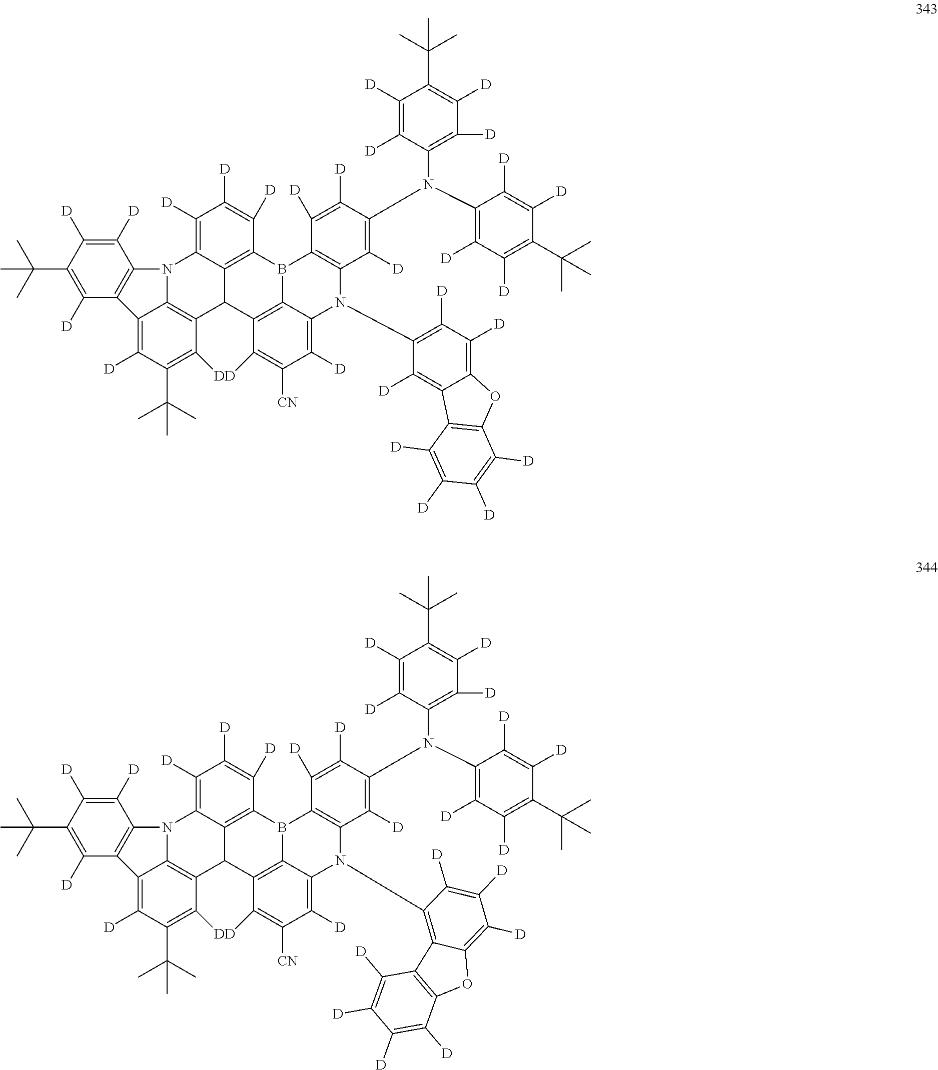

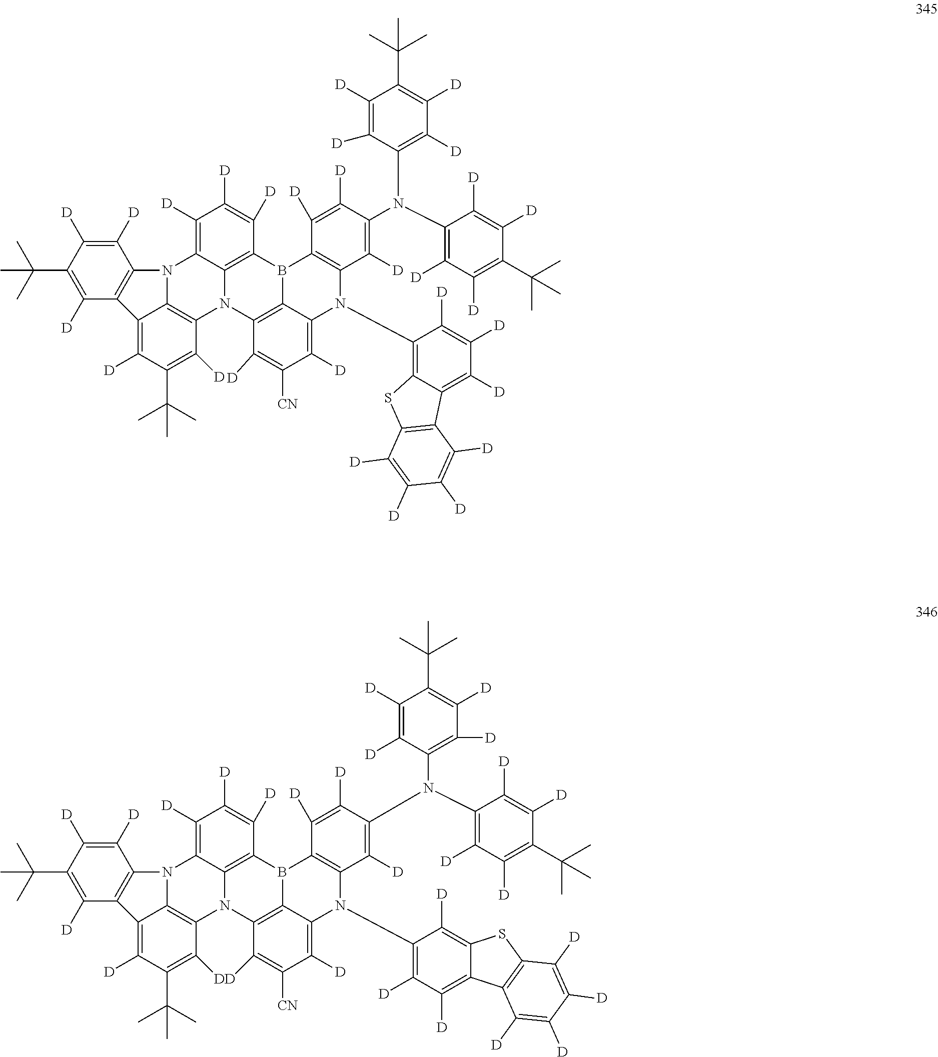

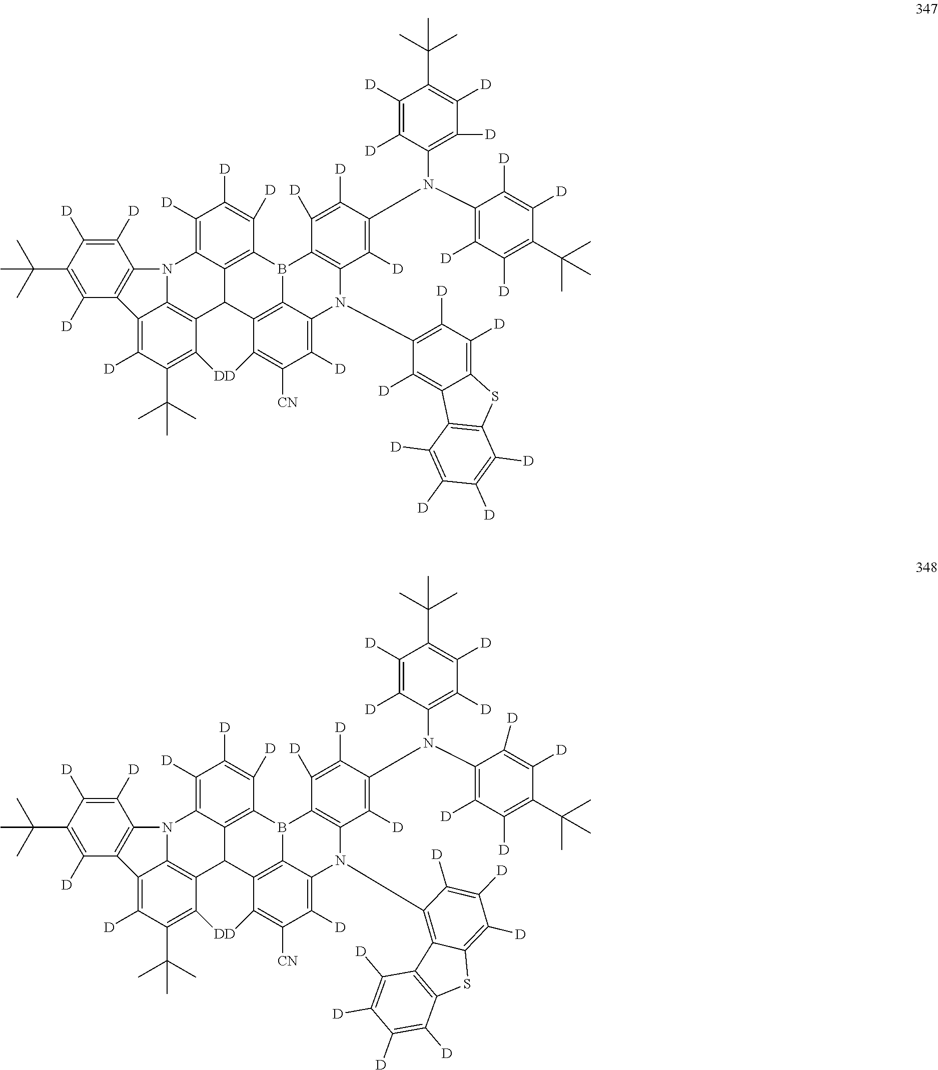

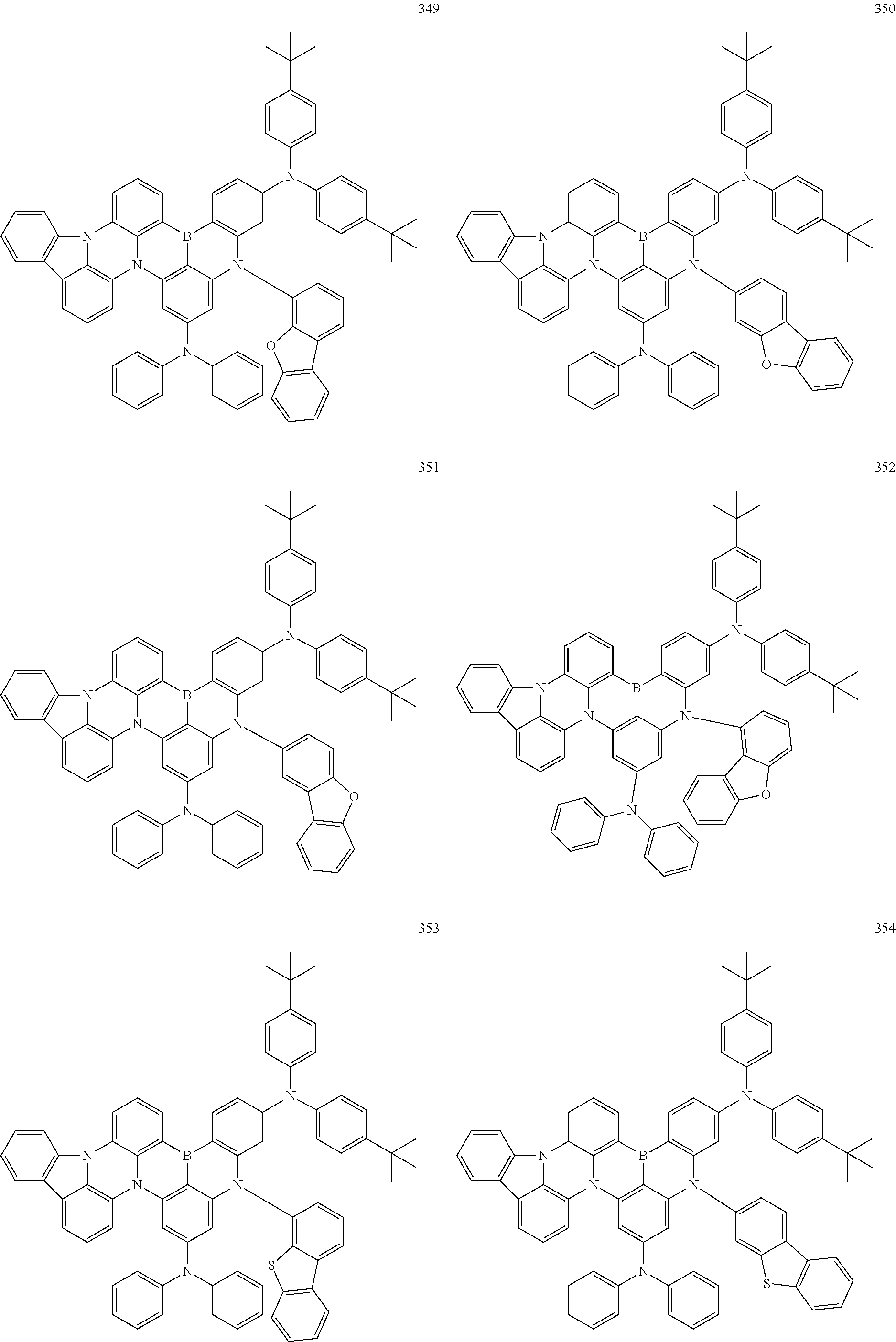

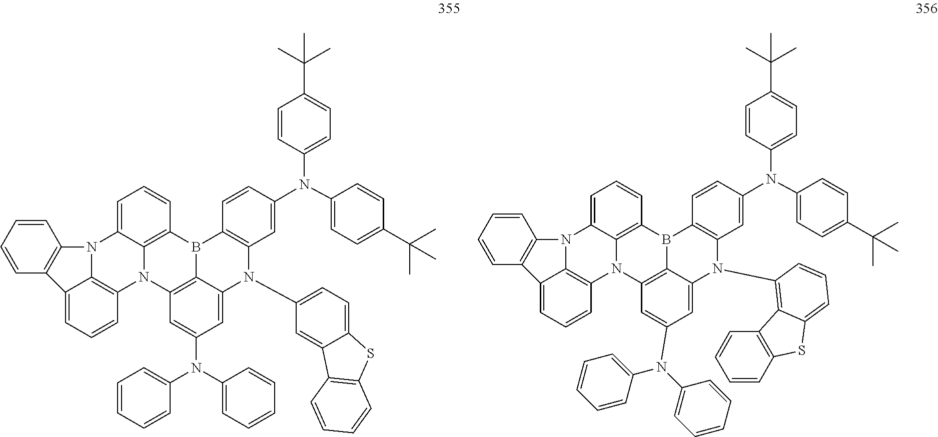 [SMILES: CC(C)(C)c1ccc(N(c2ccc(C(C)(C)C)cc2)c2ccc3c(c2)N(c2ccc4sc5ccccc5c4c2)c2cc(N(c4ccccc4)c4ccccc4)cc4c2B3c2cccc3c2N4c2cccc4c5ccccc5n-3c24)cc1 ; CC(C)(C)c1ccc(N(c2ccc(C(C)(C)C)cc2)c2ccc3c(c2)N(c2cccc4sc5ccccc5c24)c2cc(N(c4ccccc4)c4ccccc4)cc4c2B3c2cccc3c2N4c2cccc4c5ccccc5n-3c24)cc1]

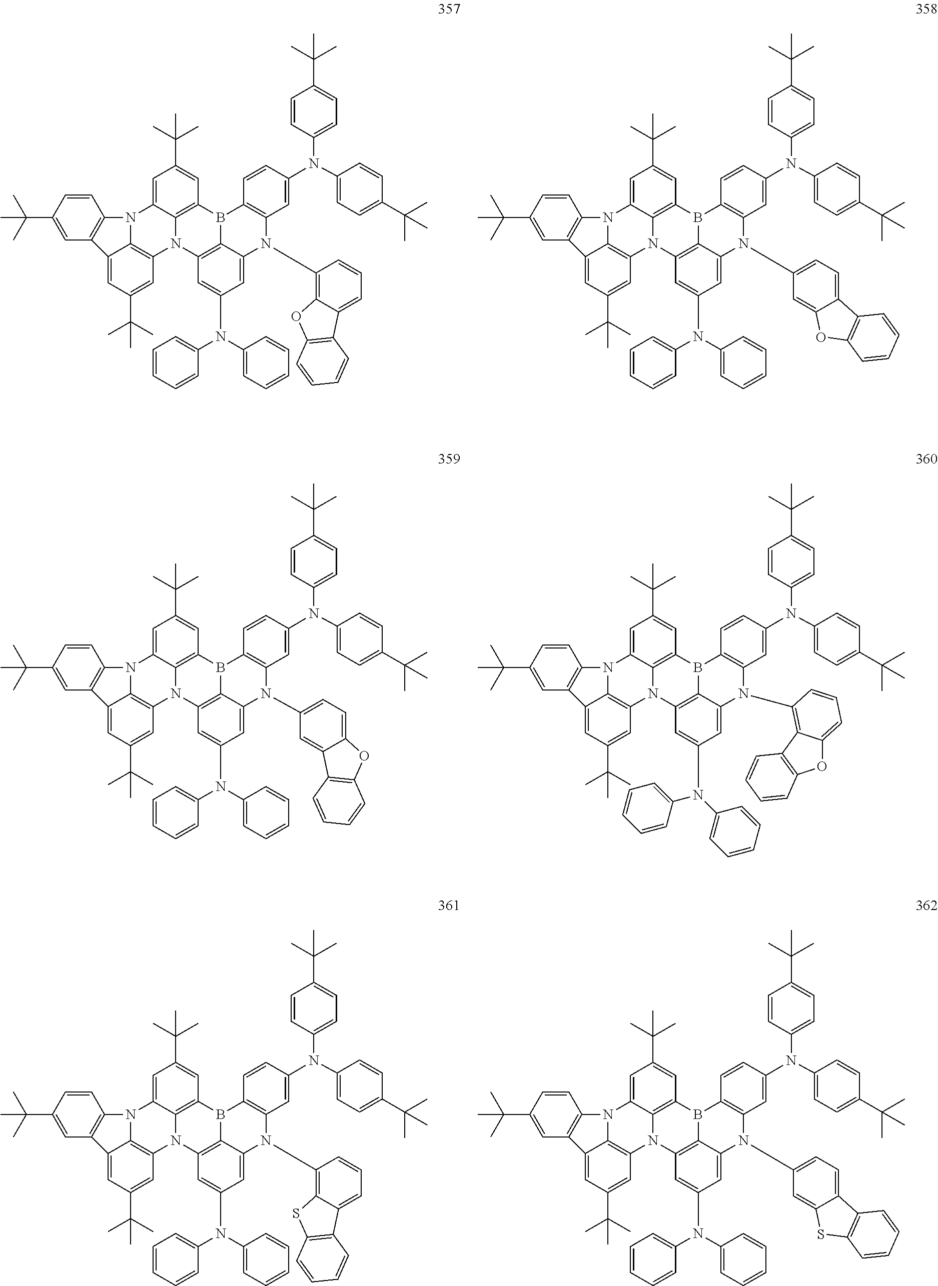

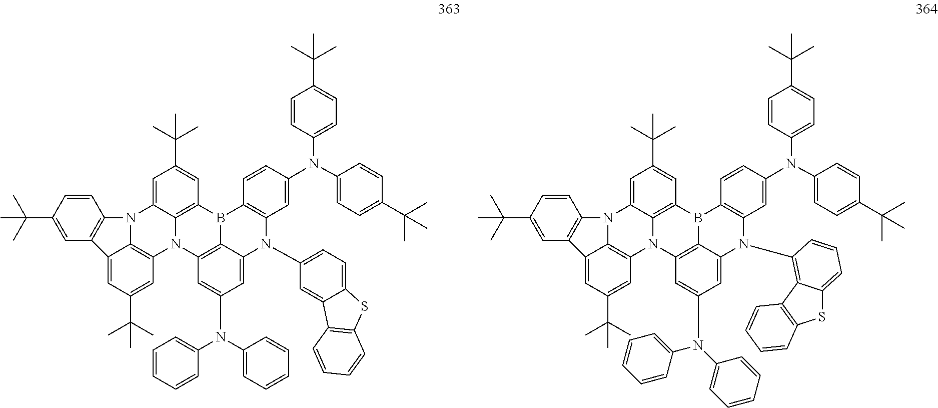 [SMILES: CC(C)(C)c1ccc(N(c2ccc(C(C)(C)C)cc2)c2ccc3c(c2)N(c2ccc4sc5ccccc5c4c2)c2cc(N(c4ccccc4)c4ccccc4)cc4c2B3c2cc(C(C)(C)C)cc3c2N4c2cc(C(C)(C)C)cc4c5cc(C(C)(C)C)ccc5n-3c24)cc1 ; CC(C)(C)c1ccc(N(c2ccc(C(C)(C)C)cc2)c2ccc3c(c2)N(c2cccc4sc5ccccc5c24)c2cc(N(c4ccccc4)c4ccccc4)cc4c2B3c2cc(C(C)(C)C)cc3c2N4c2cc(C(C)(C)C)cc4c5cc(C(C)(C)C)ccc5n-3c24)cc1]

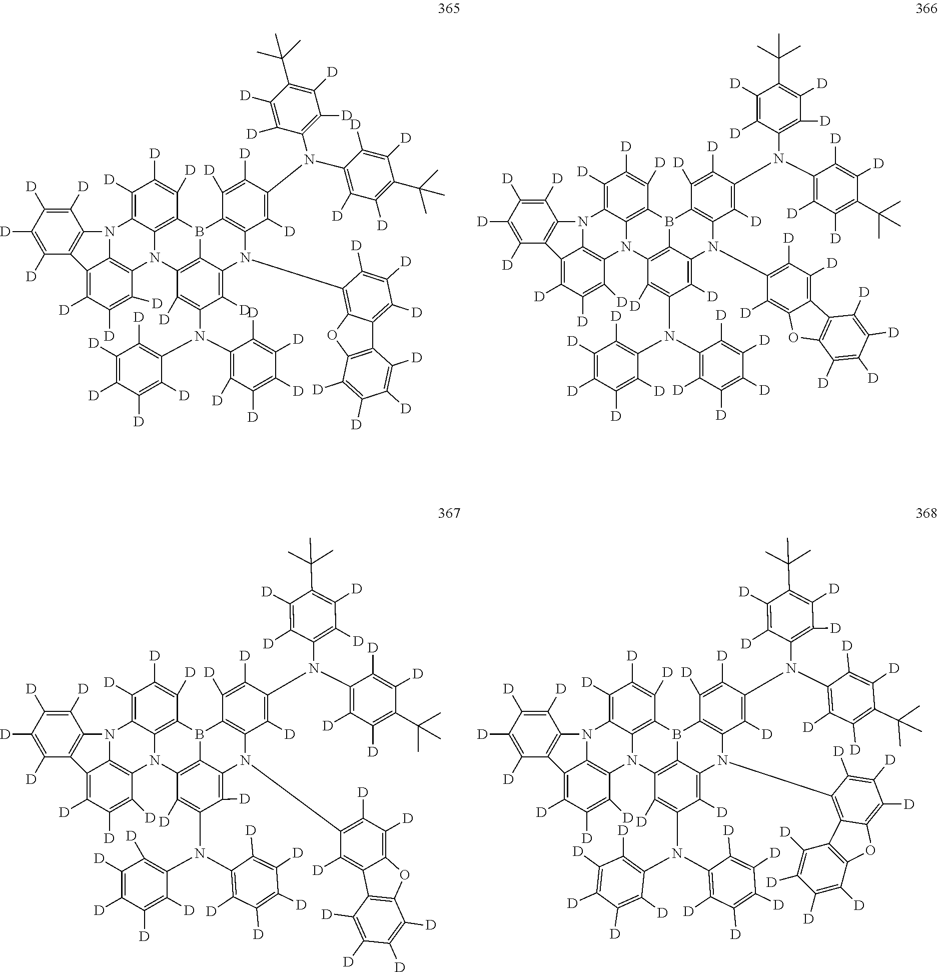

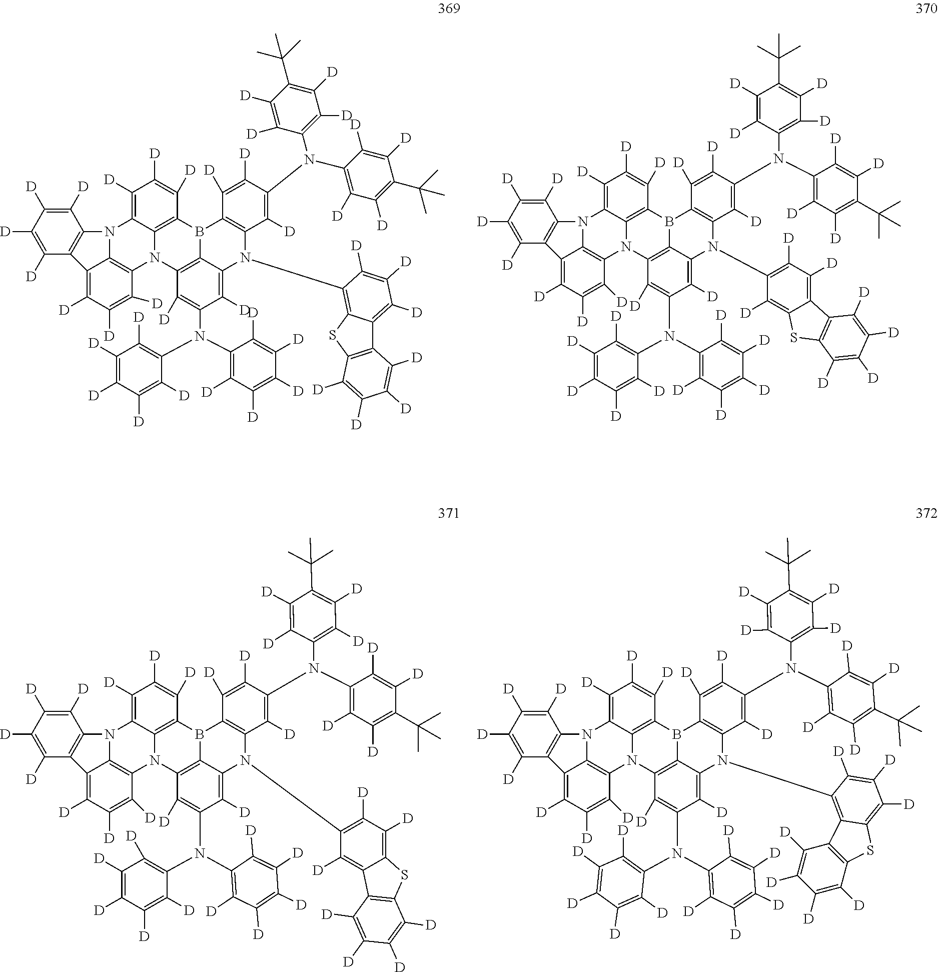

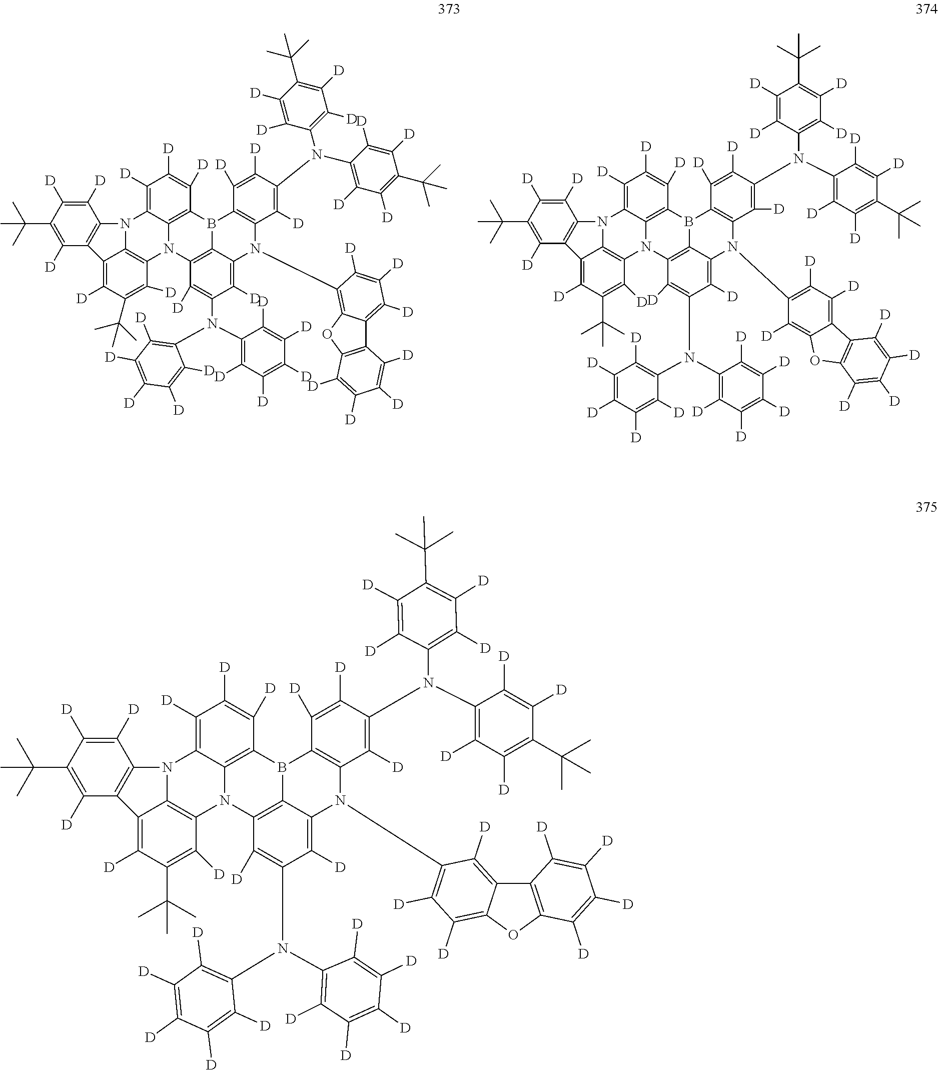

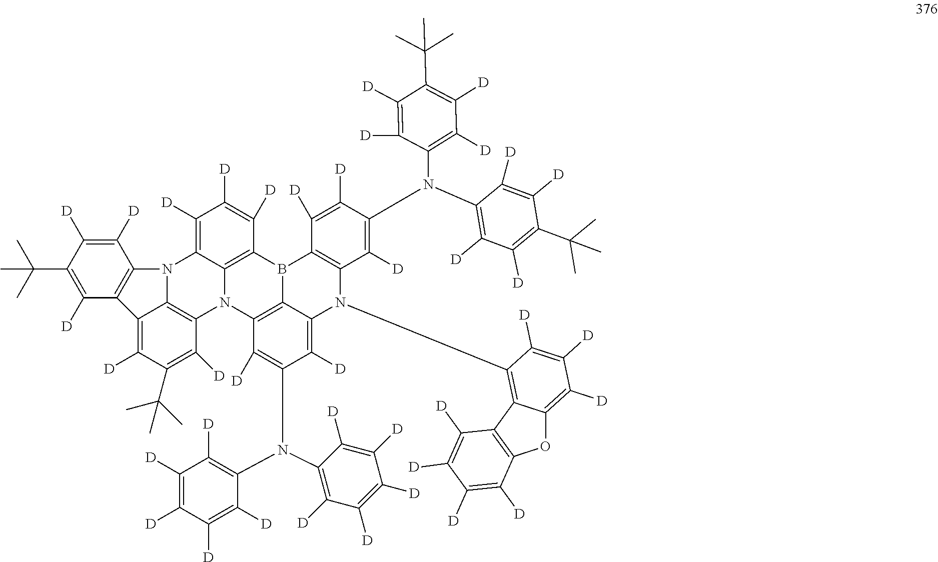 [SMILES: [2H]c1c([2H])c([2H])c(N(c2c([2H])c([2H])c([2H])c([2H])c2[2H])c2c([2H])c3c4c(c2[2H])N2c5c(c([2H])c([2H])c([2H])c5-n5c6c([2H])c([2H])c(C(C)(C)C)c([2H])c6c6c([2H])c(C(C)(C)C)c([2H])c2c65)B4c2c([2H])c([2H])c(N(c4c([2H])c([2H])c(C(C)(C)C)c([2H])c4[2H])c4c([2H])c([2H])c(C(C)(C)C)c([2H])c4[2H])c([2H])c2N3c2c([2H])c([2H])c([2H])c3oc4c([2H])c([2H])c([2H])c([2H])c4c23)c([2H])c1[2H]]

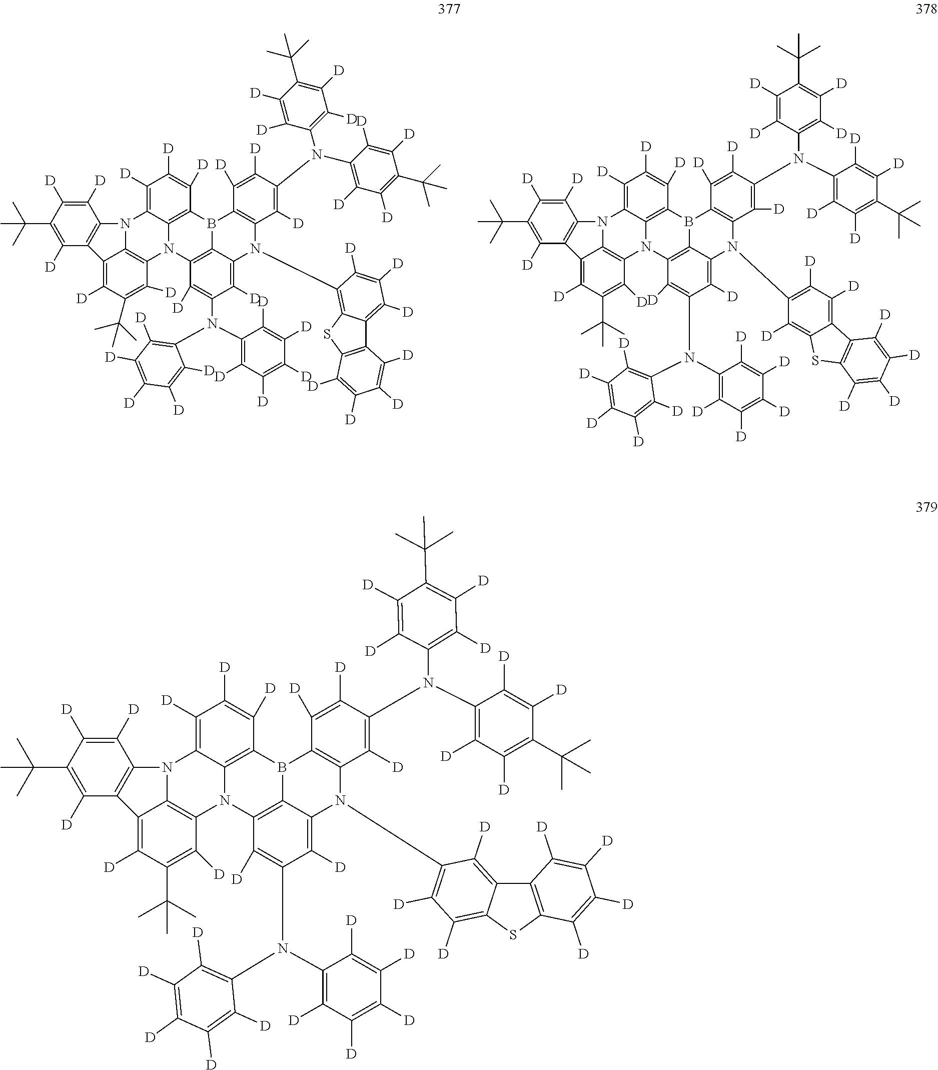

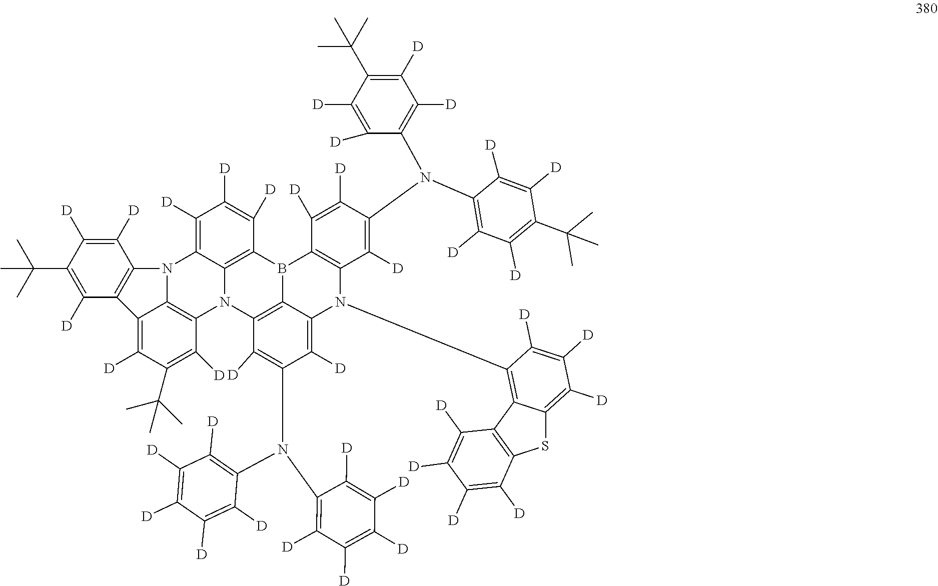 [SMILES: [2H]c1c([2H])c([2H])c(N(c2c([2H])c([2H])c([2H])c([2H])c2[2H])c2c([2H])c3c4c(c2[2H])N2c5c(c([2H])c([2H])c([2H])c5-n5c6c([2H])c([2H])c(C(C)(C)C)c([2H])c6c6c([2H])c(C(C)(C)C)c([2H])c2c65)B4c2c([2H])c([2H])c(N(c4c([2H])c([2H])c(C(C)(C)C)c([2H])c4[2H])c4c([2H])c([2H])c(C(C)(C)C)c([2H])c4[2H])c([2H])c2N3c2c([2H])c([2H])c([2H])c3sc4c([2H])c([2H])c([2H])c([2H])c4c23)c([2H])c1[2H]]

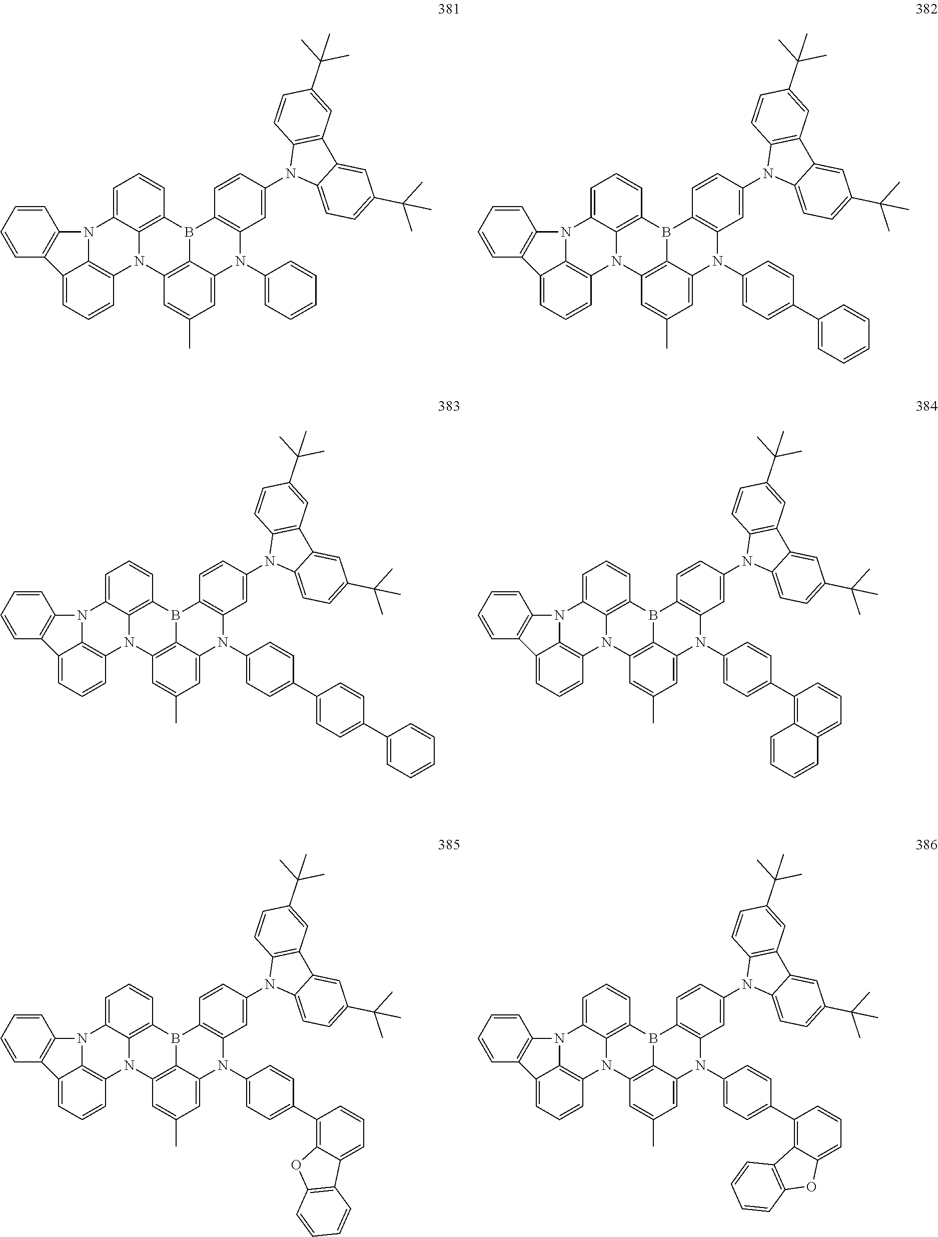

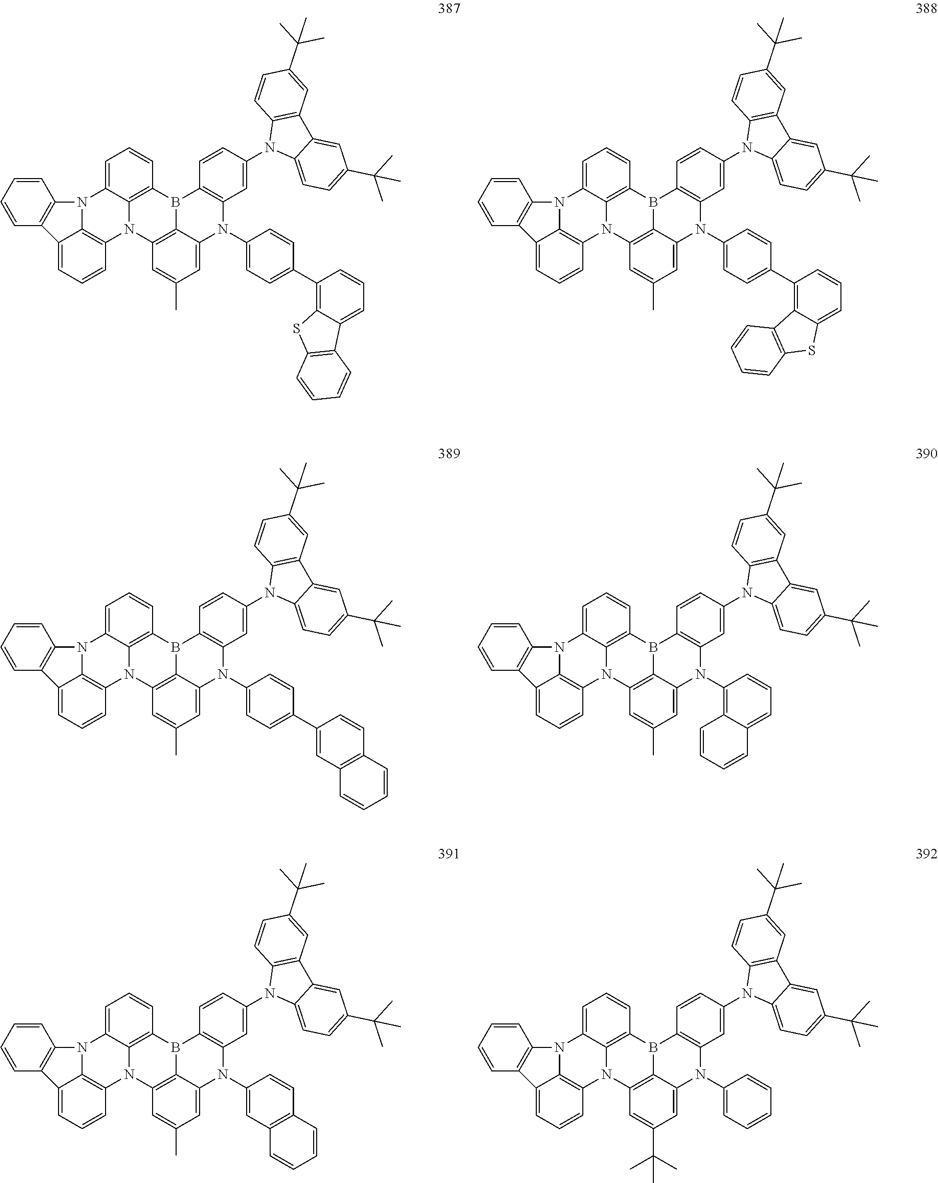

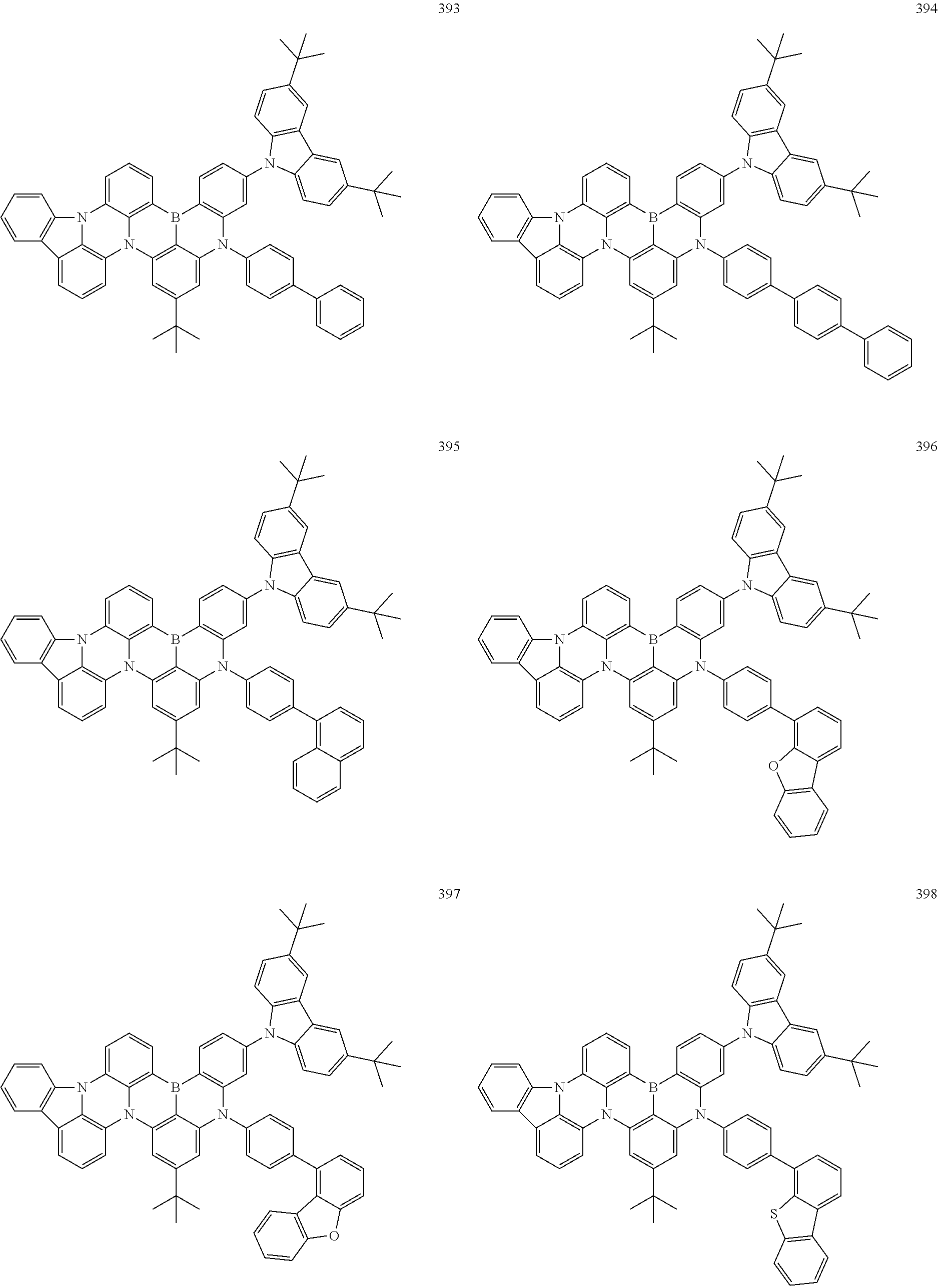

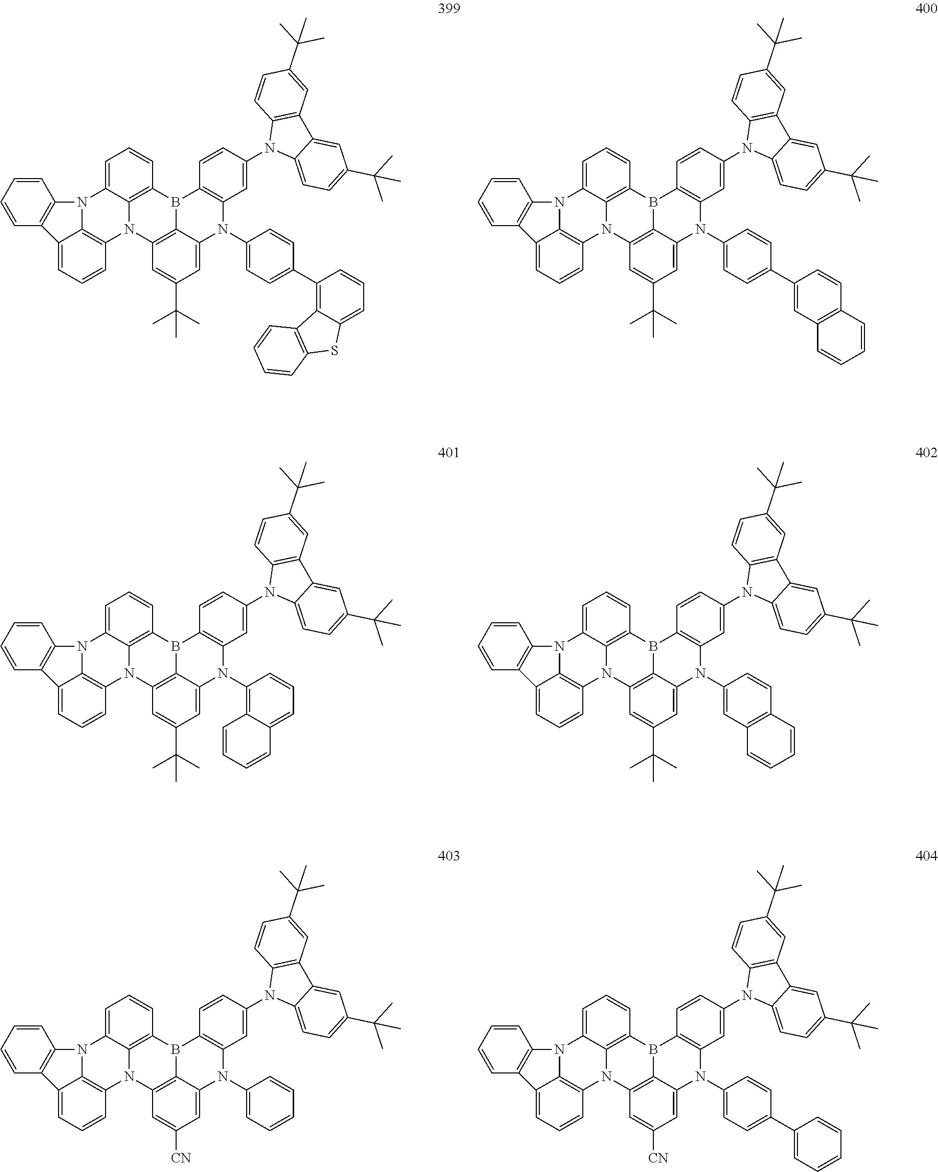

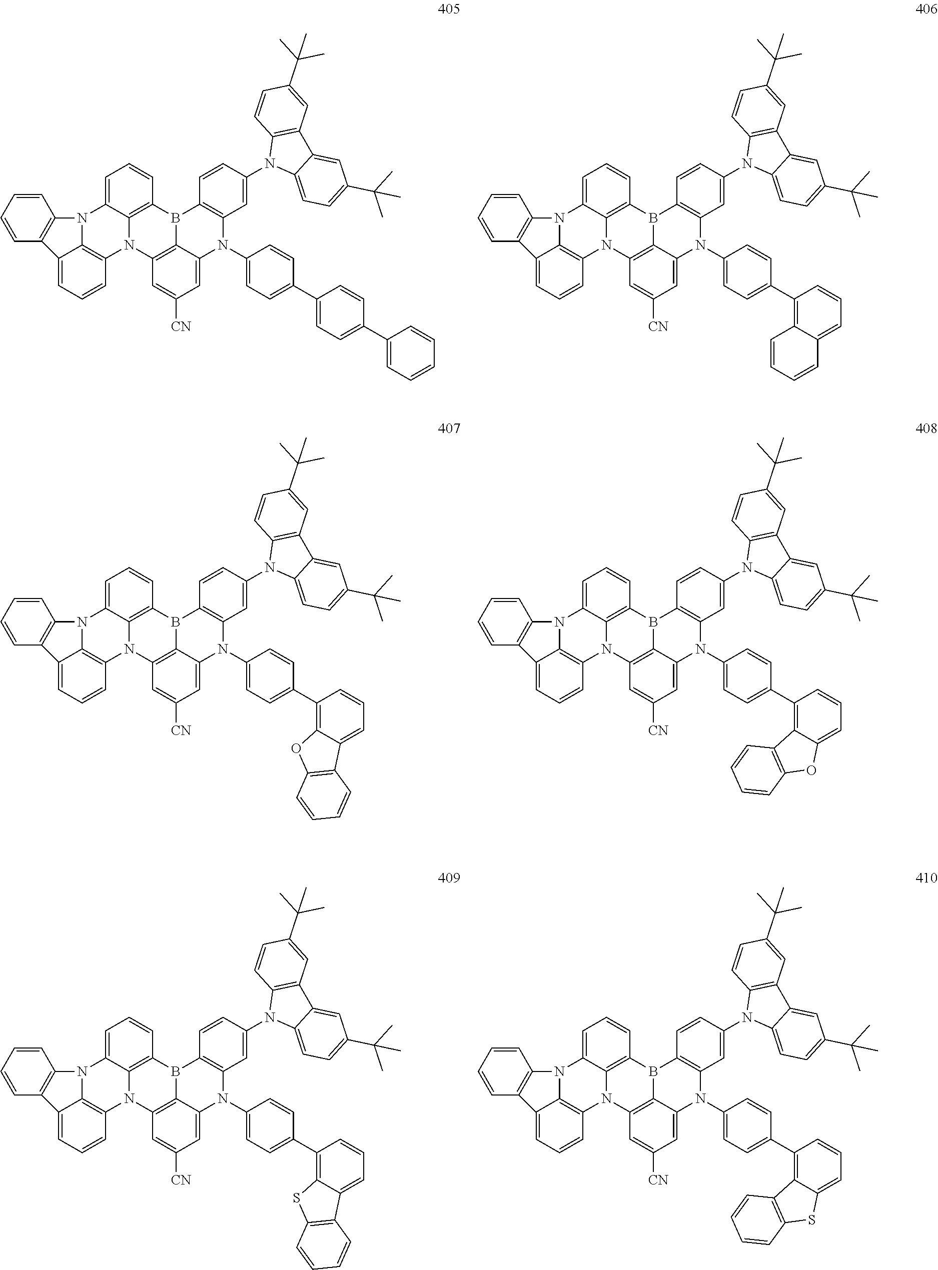

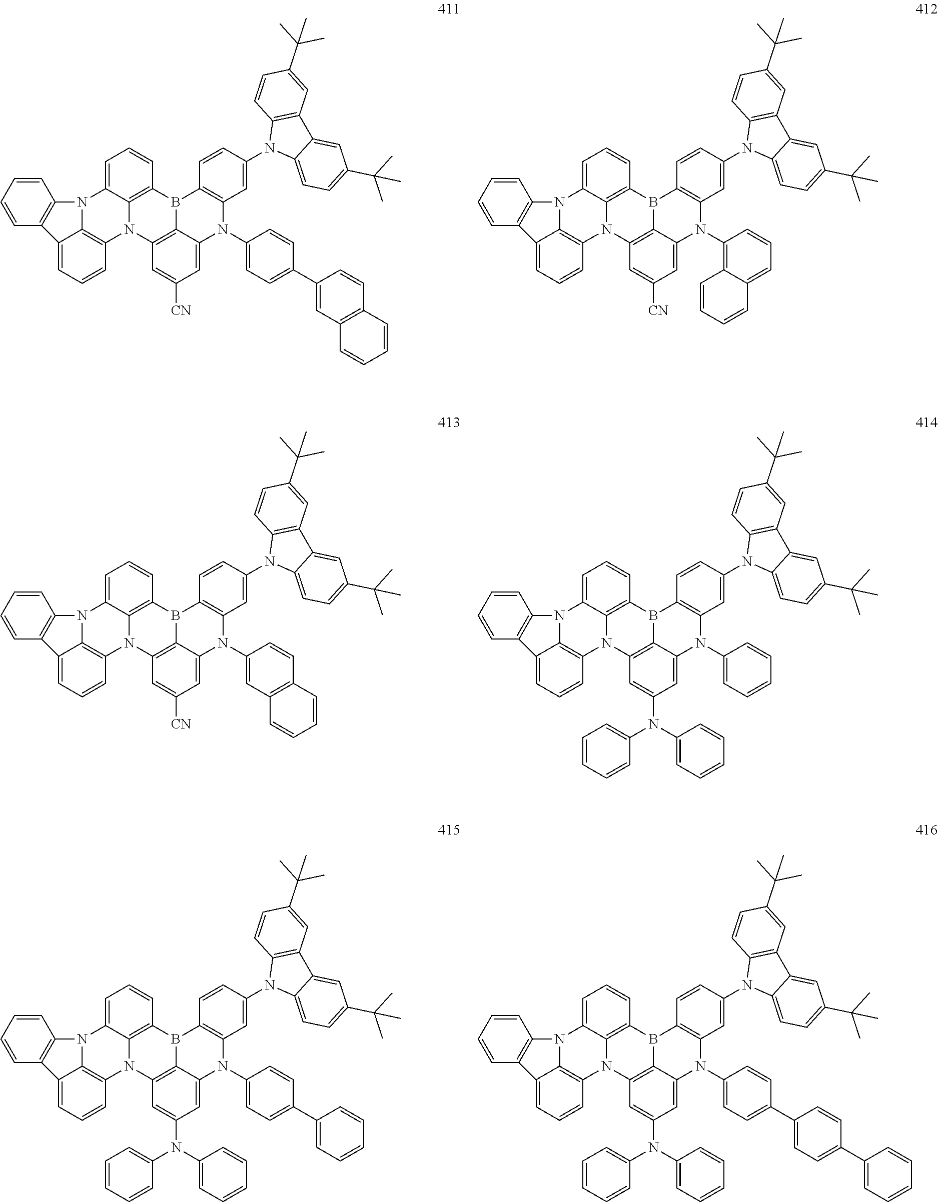

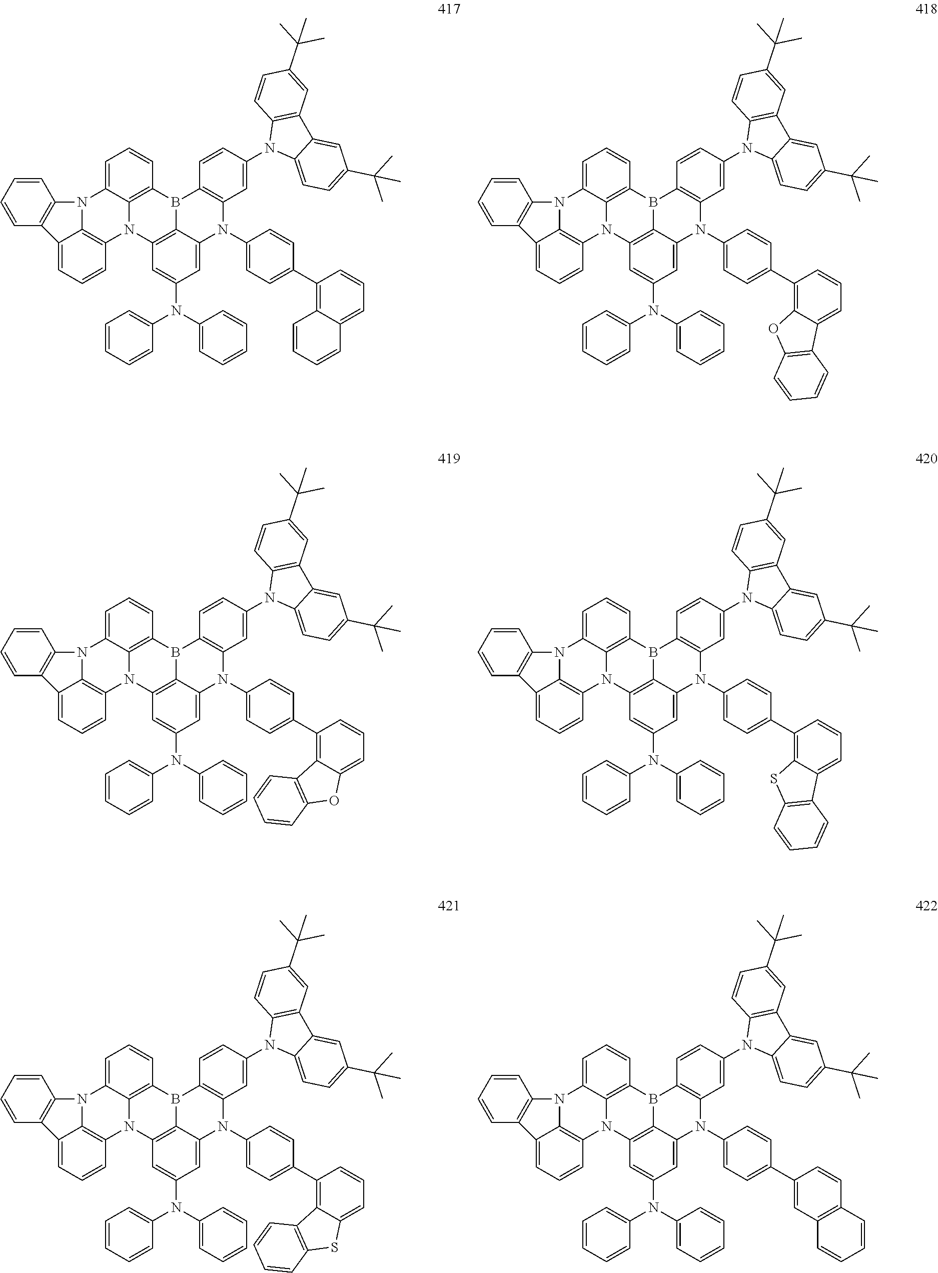

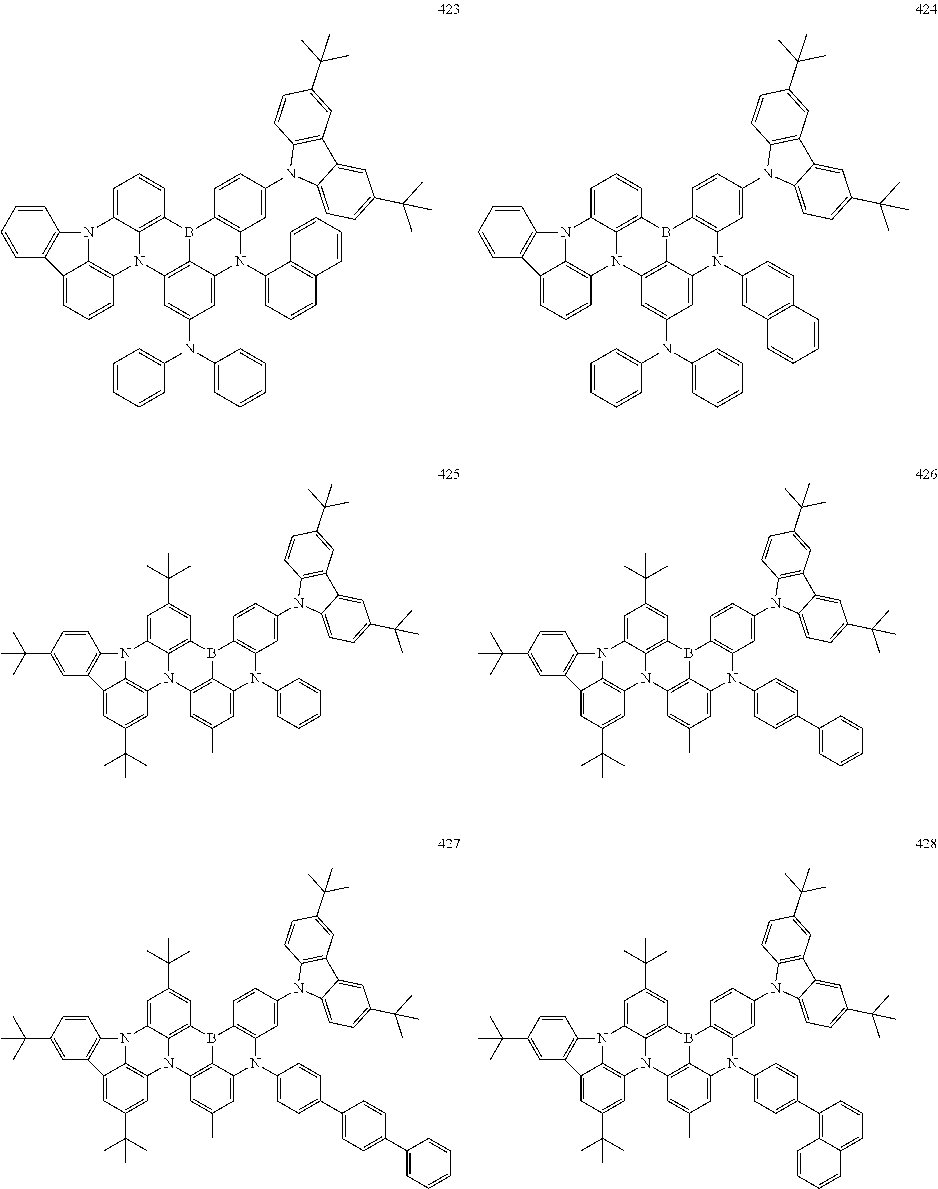

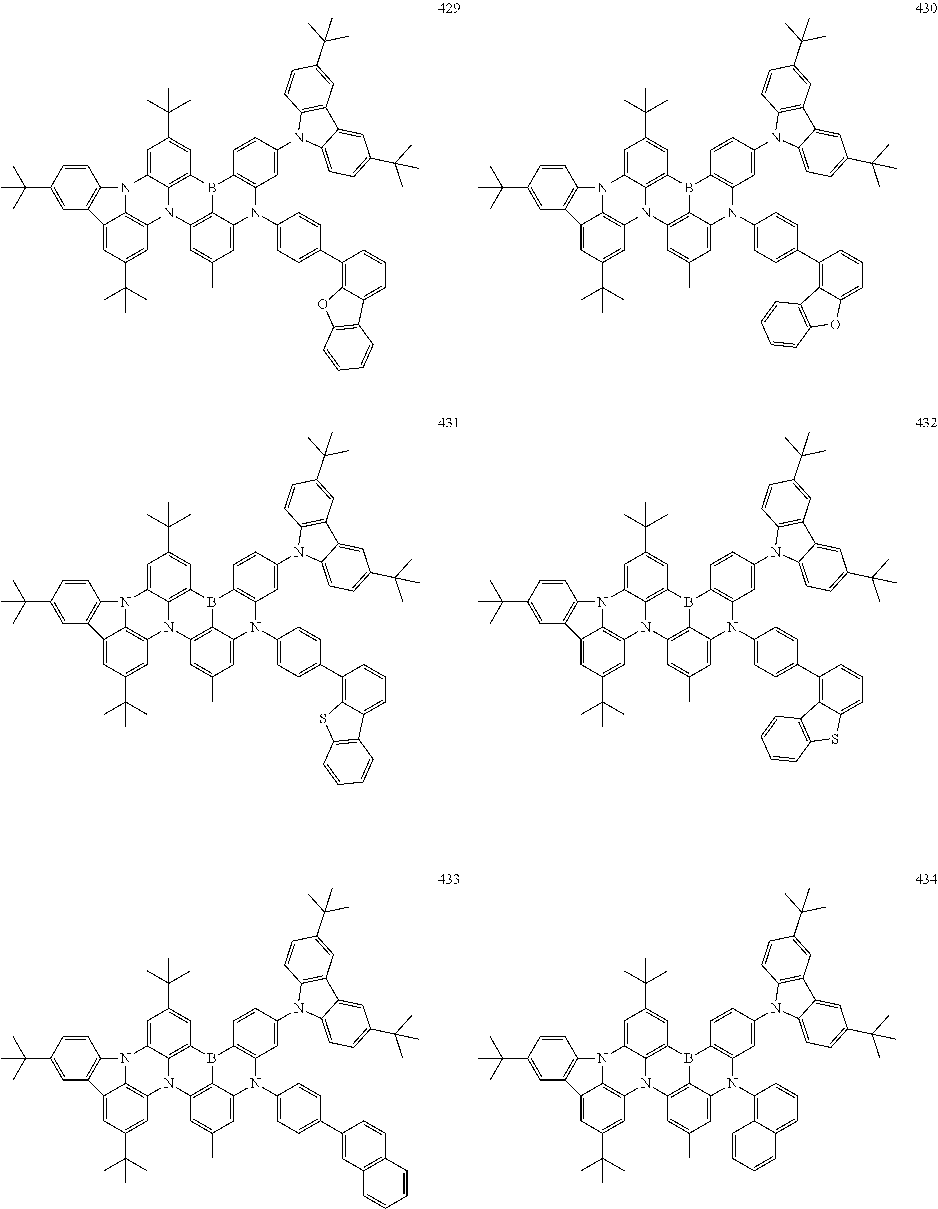

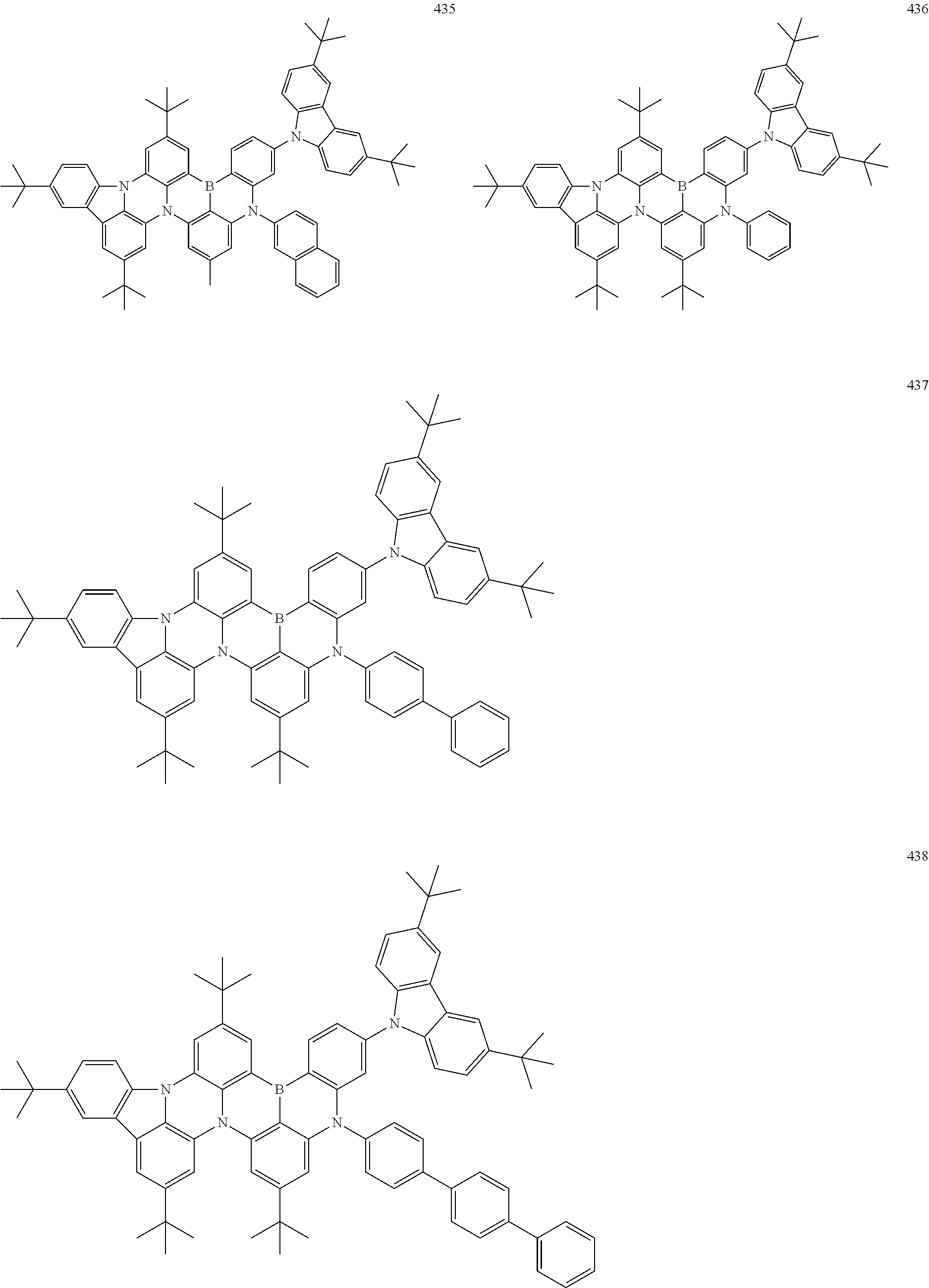

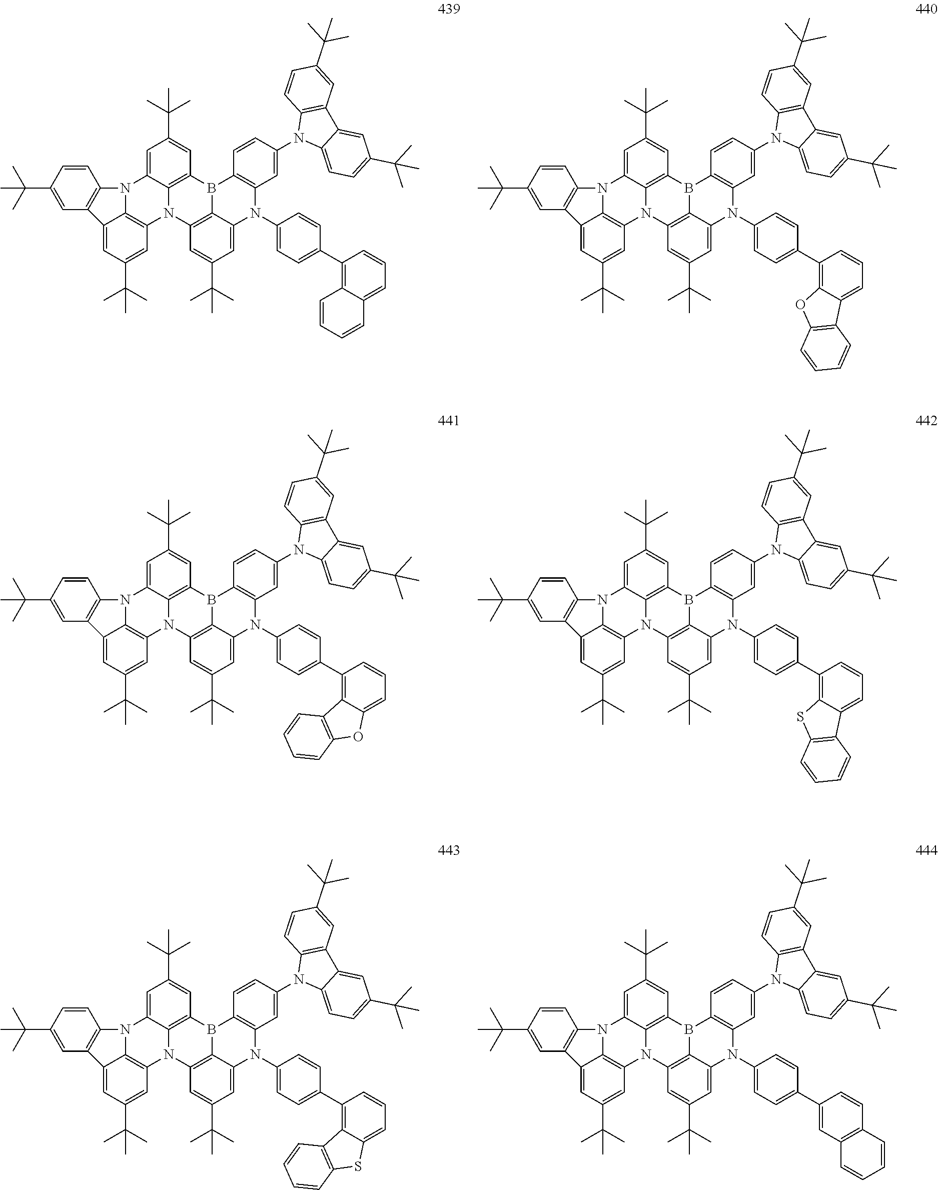

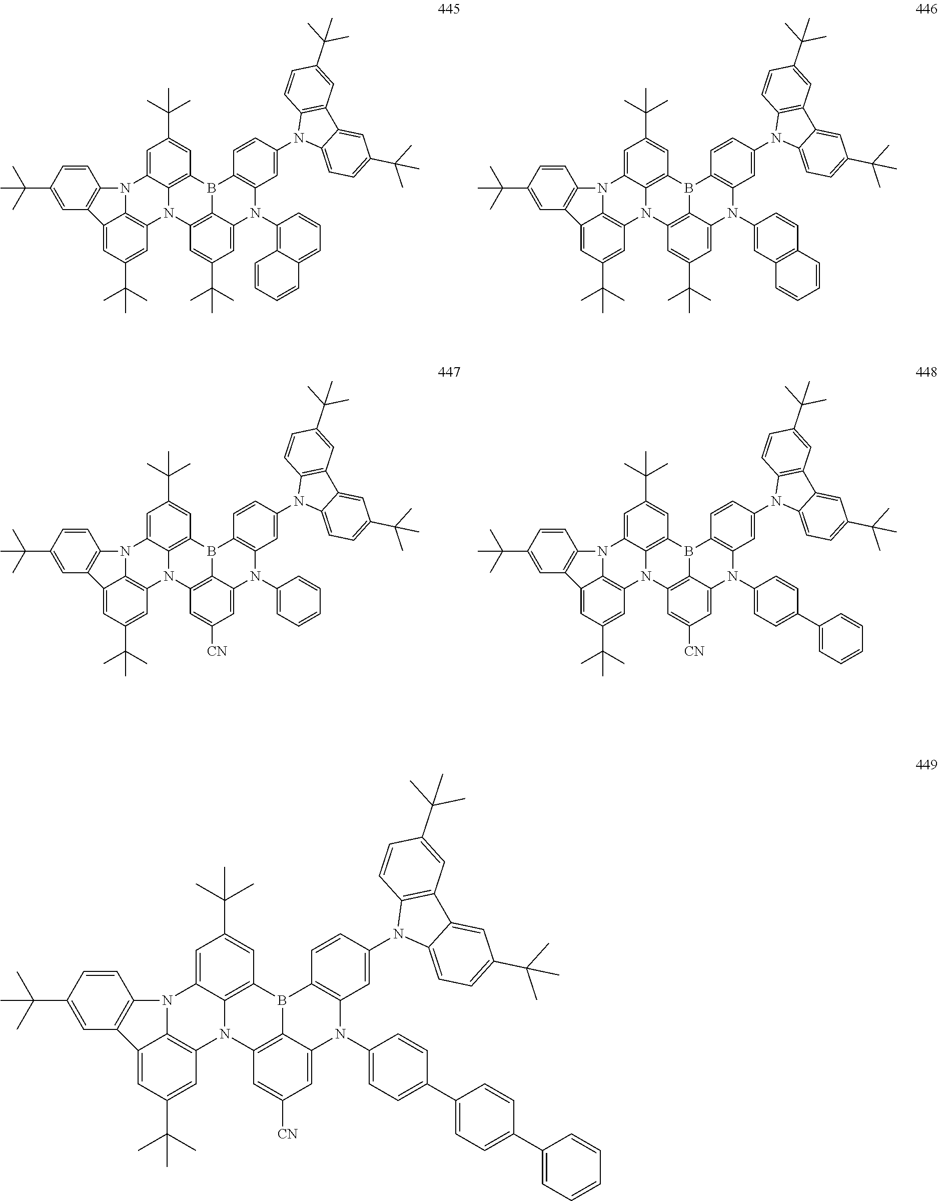

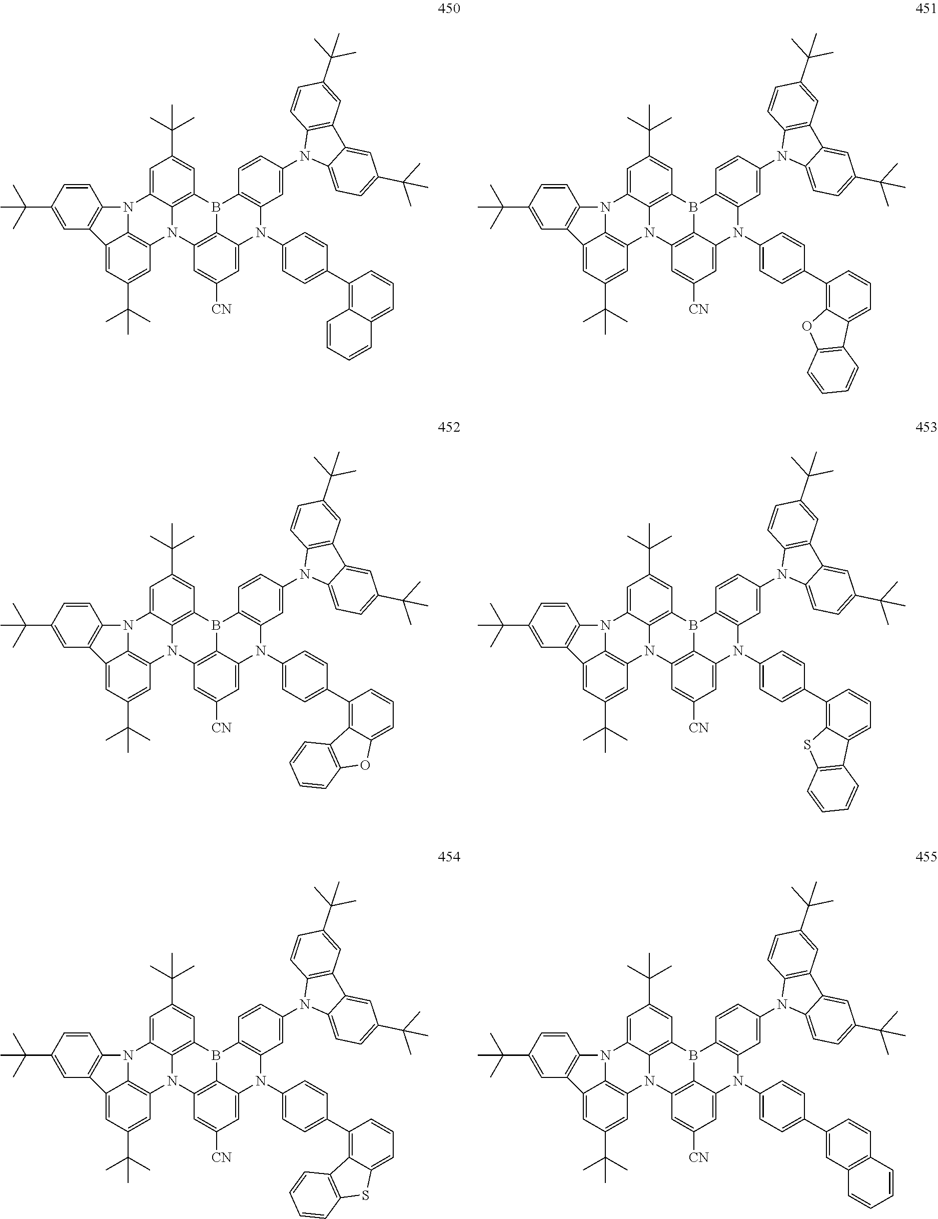

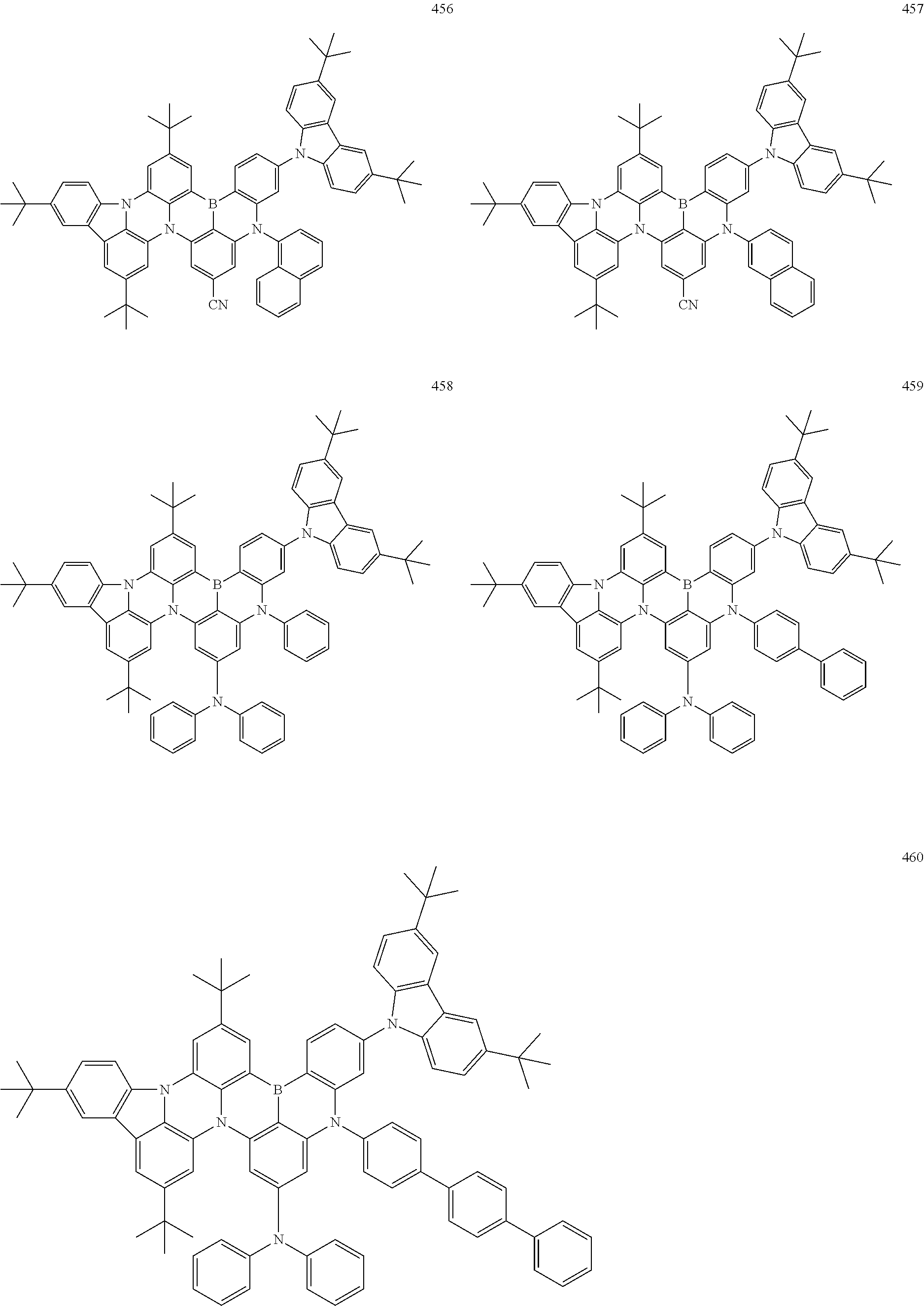

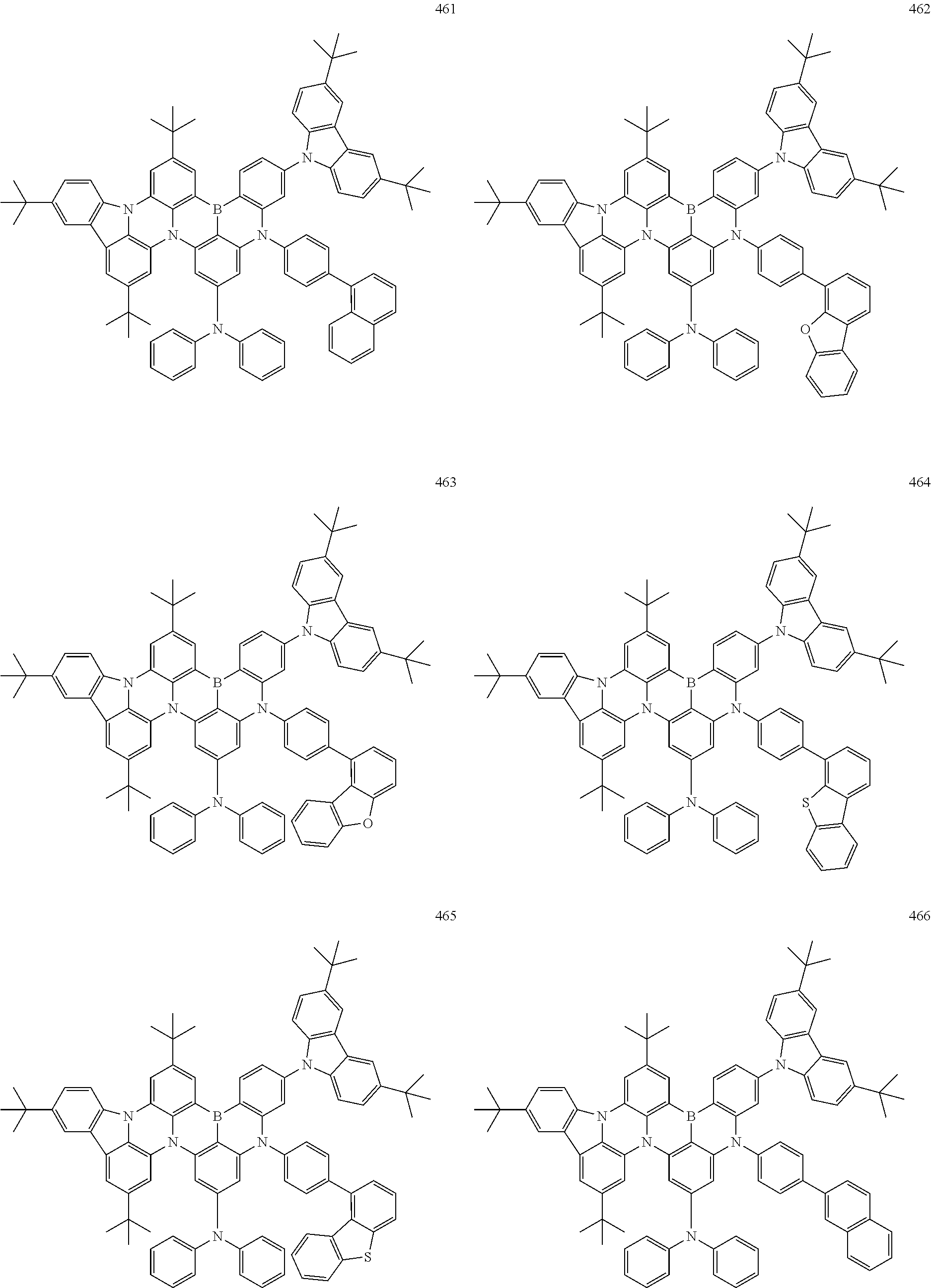

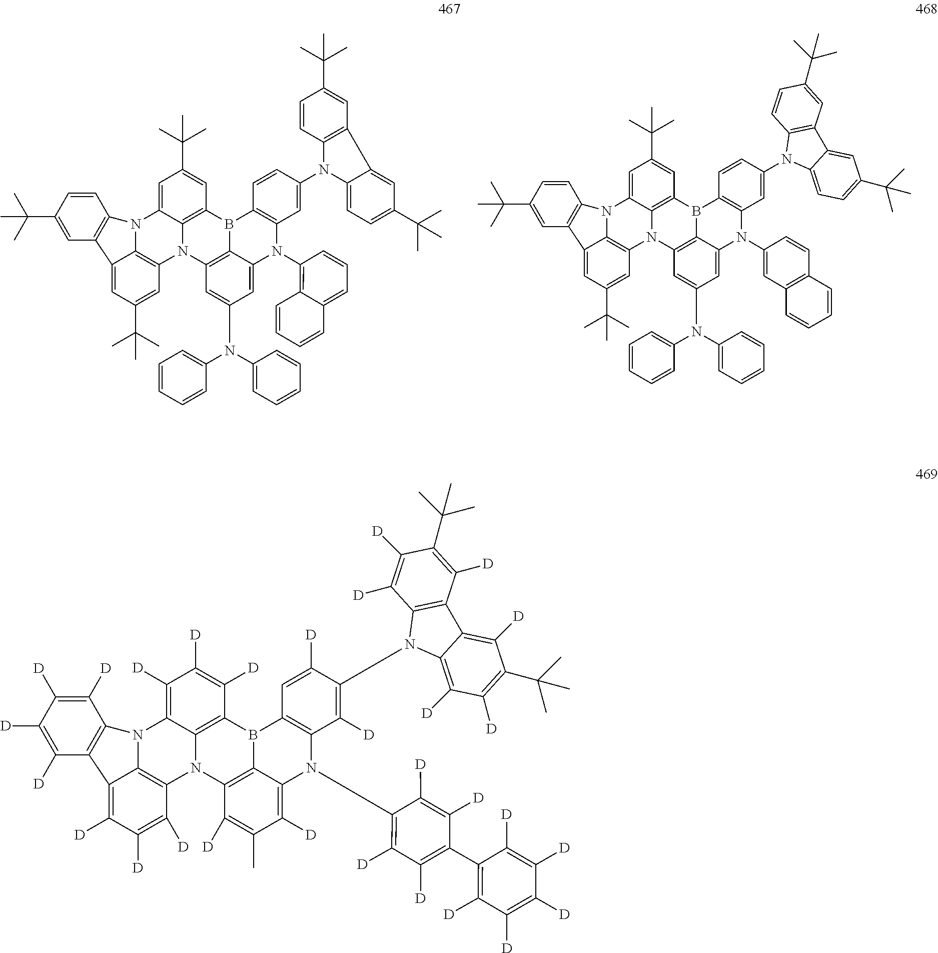

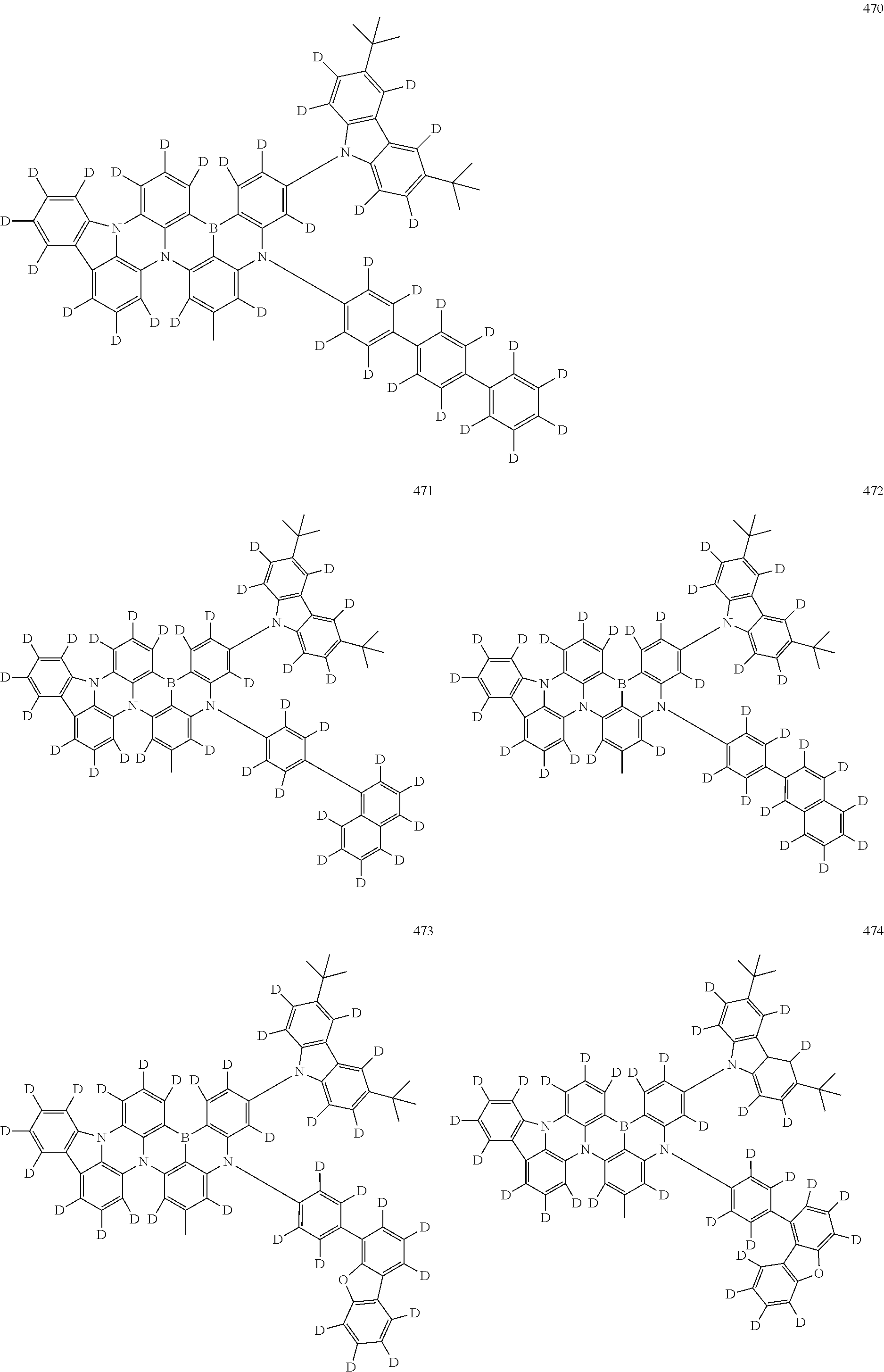

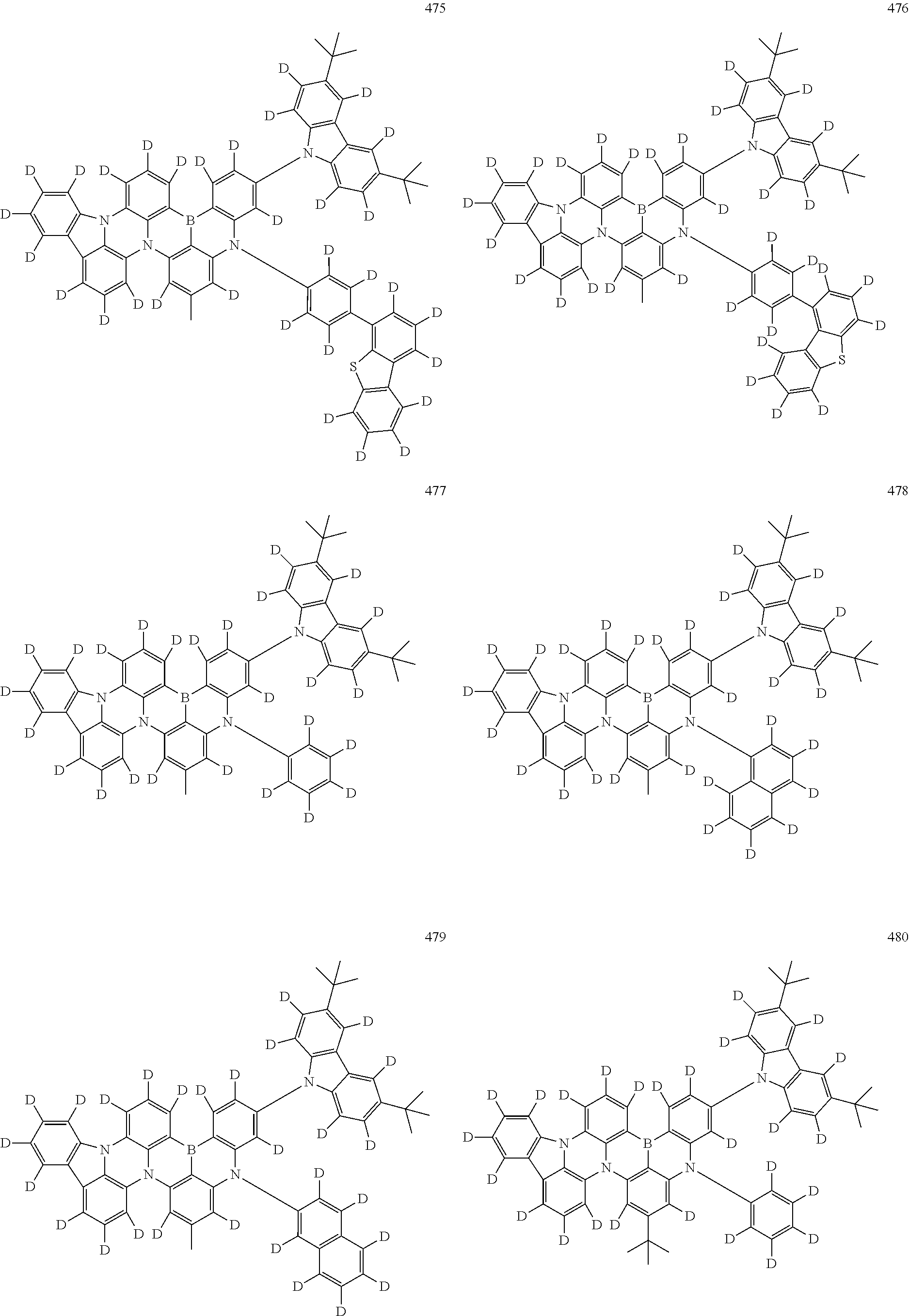

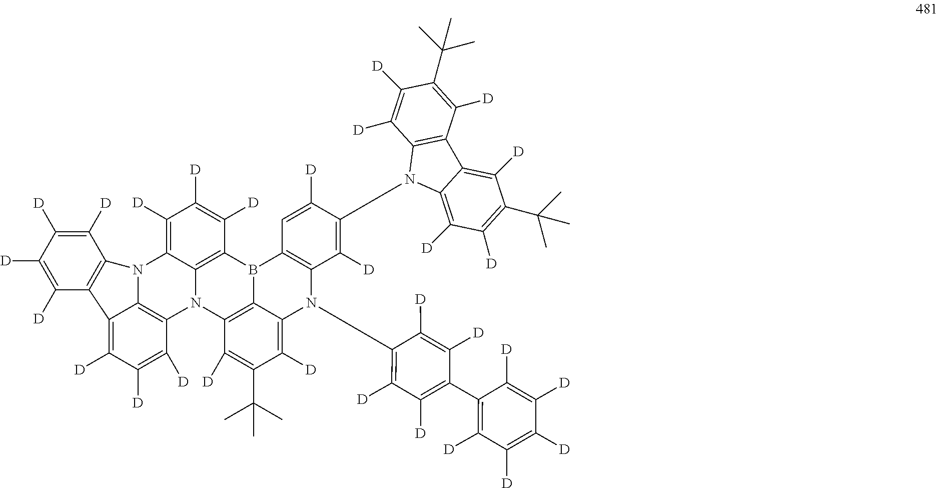 [SMILES: [2H]c1cc2c(c([2H])c1-n1c3c([2H])c([2H])c(C(C)(C)C)c([2H])c3c3c([2H])c(C(C)(C)C)c([2H])c([2H])c31)N(c1c([2H])c([2H])c(-c3c([2H])c([2H])c([2H])c([2H])c3[2H])c([2H])c1[2H])c1c([2H])c(C(C)(C)C)c([2H])c3c1B2c1c([2H])c([2H])c([2H])c2c1N3c1c([2H])c([2H])c([2H])c3c4c([2H])c([2H])c([2H])c([2H])c4n-2c13]

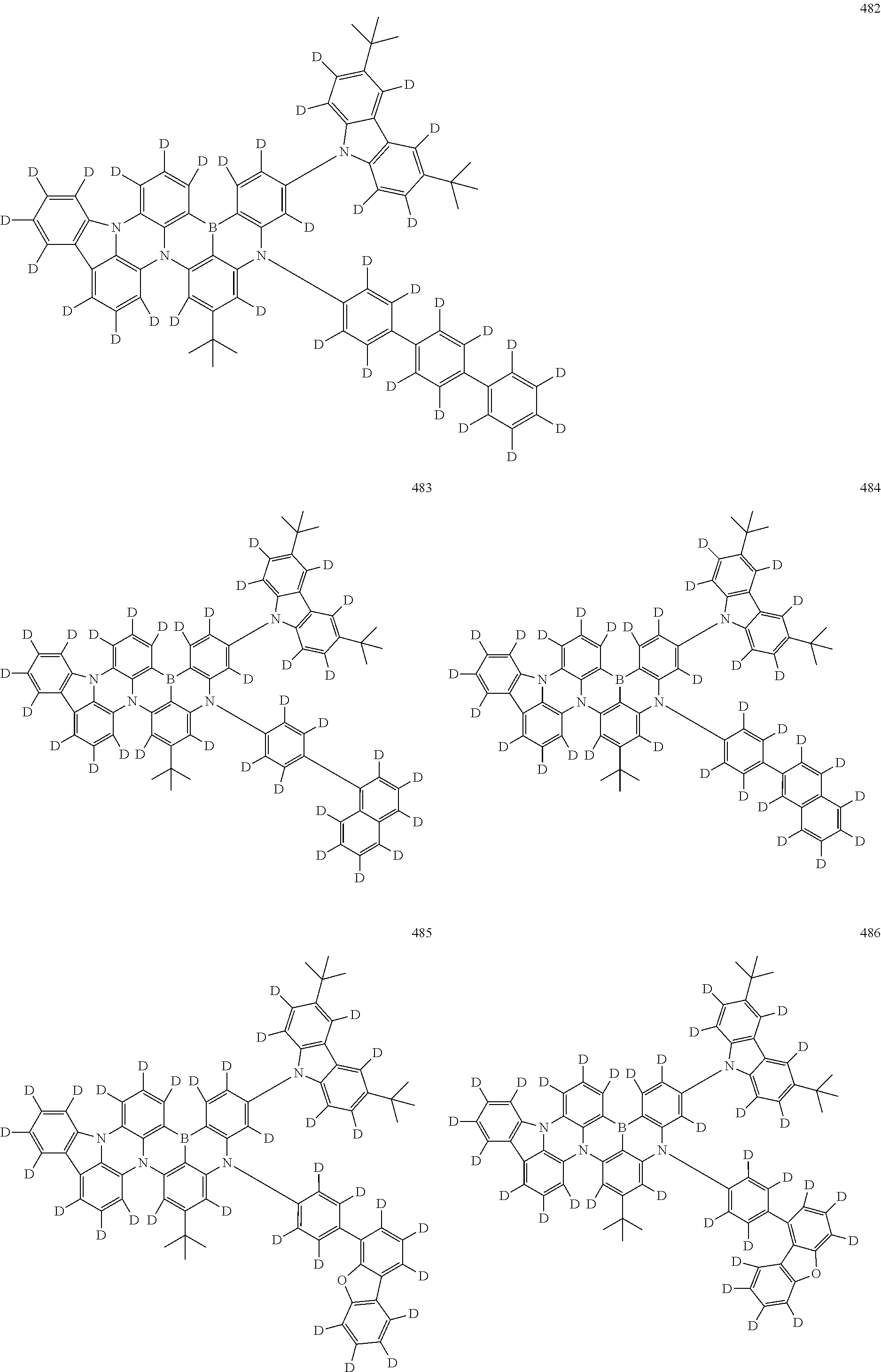

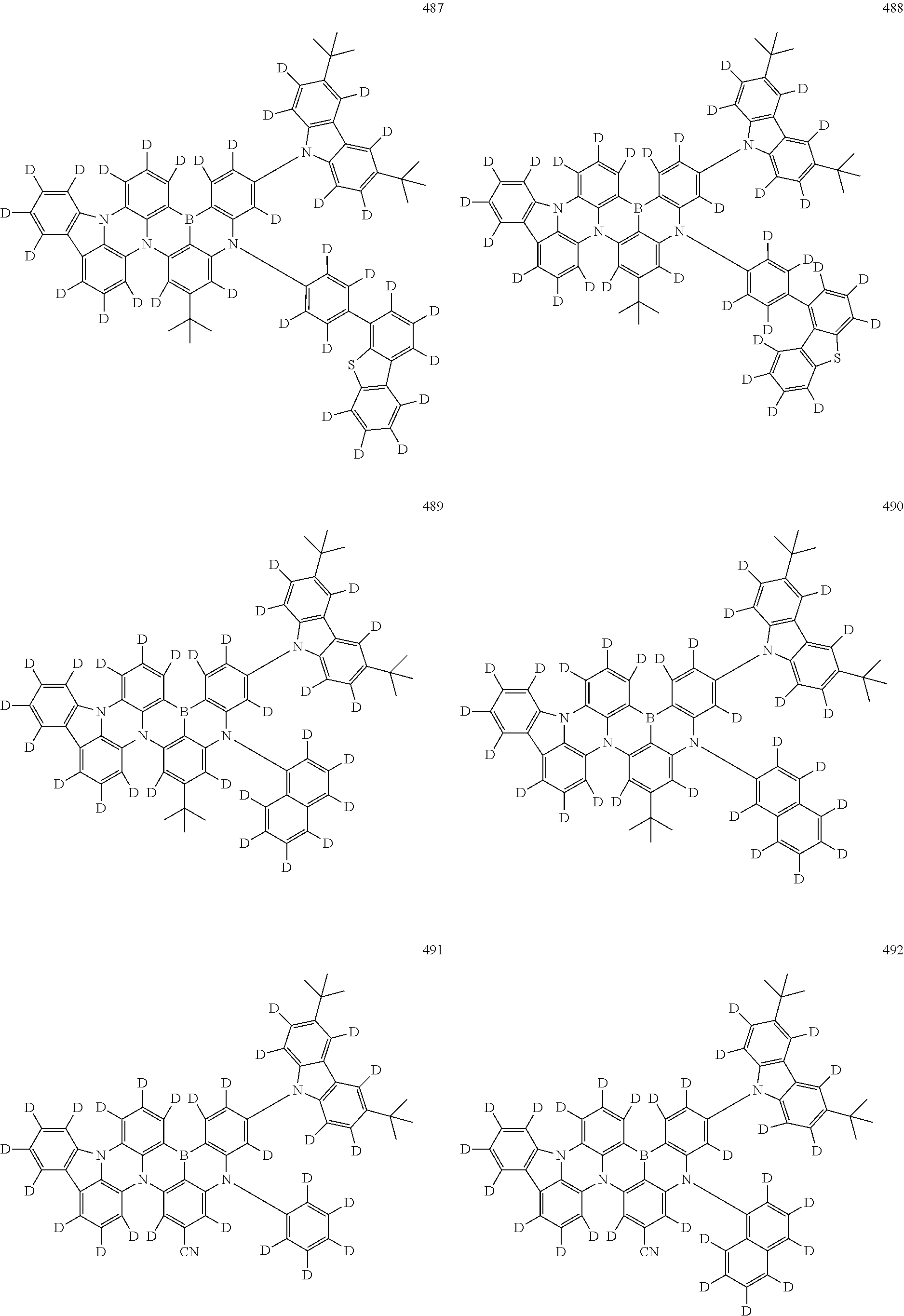

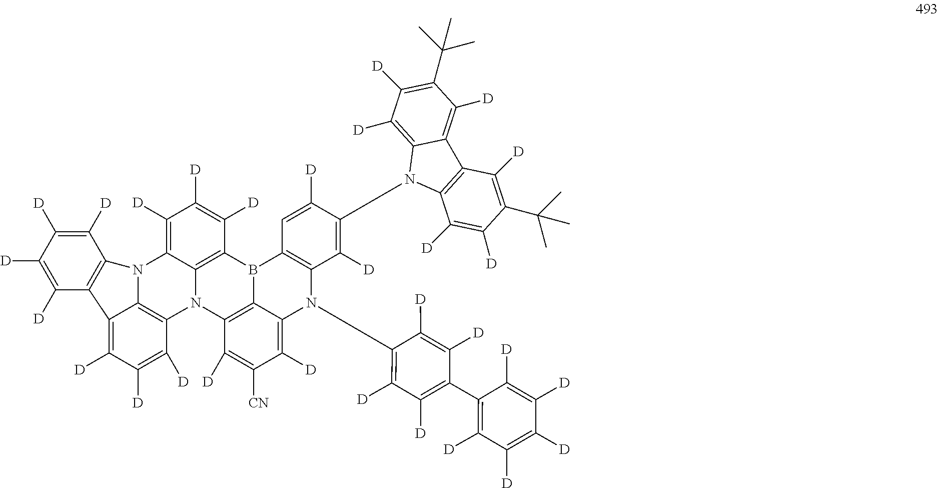 [SMILES: [2H]c1cc2c(c([2H])c1-n1c3c([2H])c([2H])c(C(C)(C)C)c([2H])c3c3c([2H])c(C(C)(C)C)c([2H])c([2H])c31)N(c1c([2H])c([2H])c(-c3c([2H])c([2H])c([2H])c([2H])c3[2H])c([2H])c1[2H])c1c([2H])c(C#N)c([2H])c3c1B2c1c([2H])c([2H])c([2H])c2c1N3c1c([2H])c([2H])c([2H])c3c4c([2H])c([2H])c([2H])c([2H])c4n-2c13]

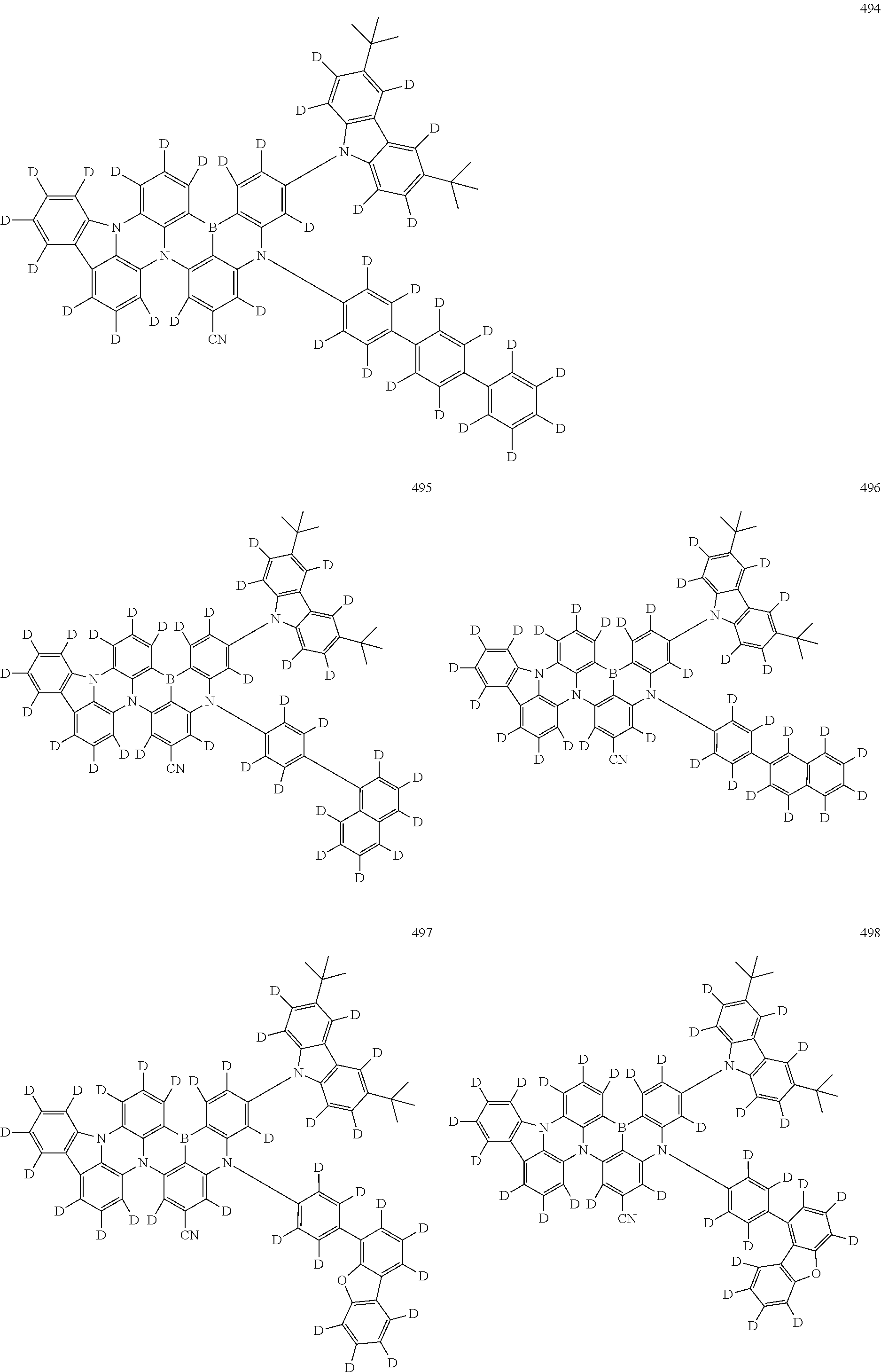

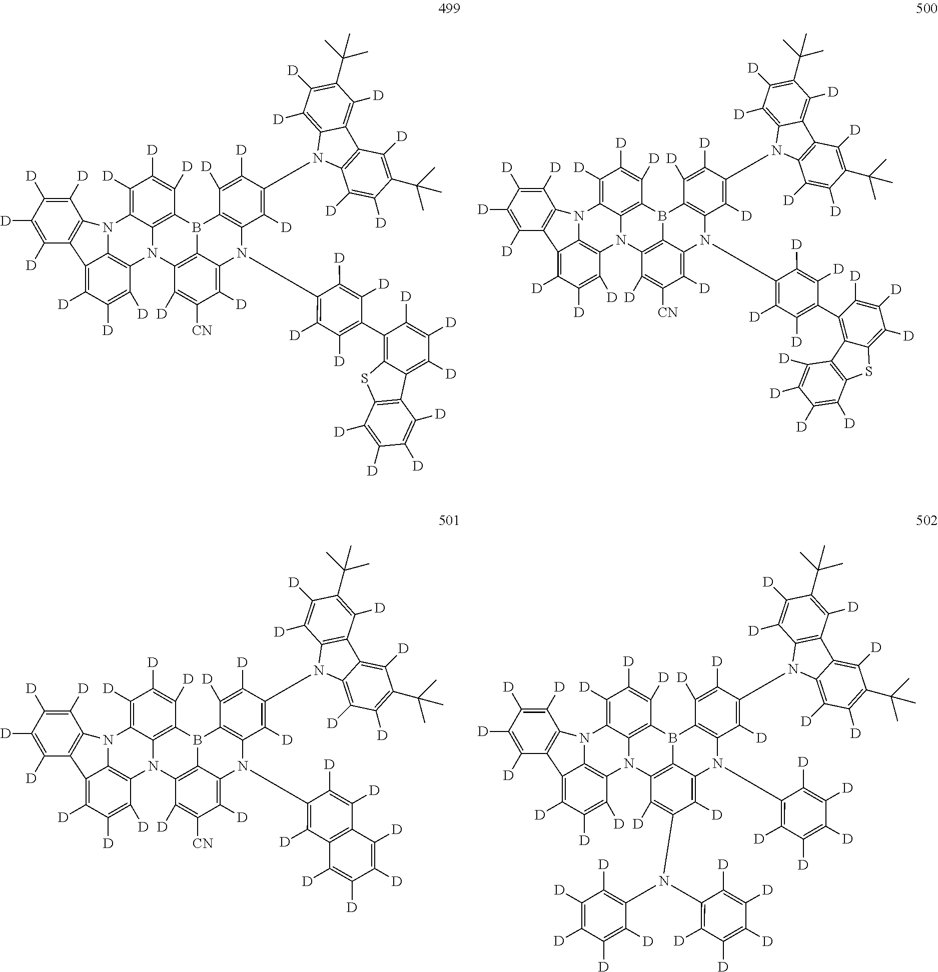

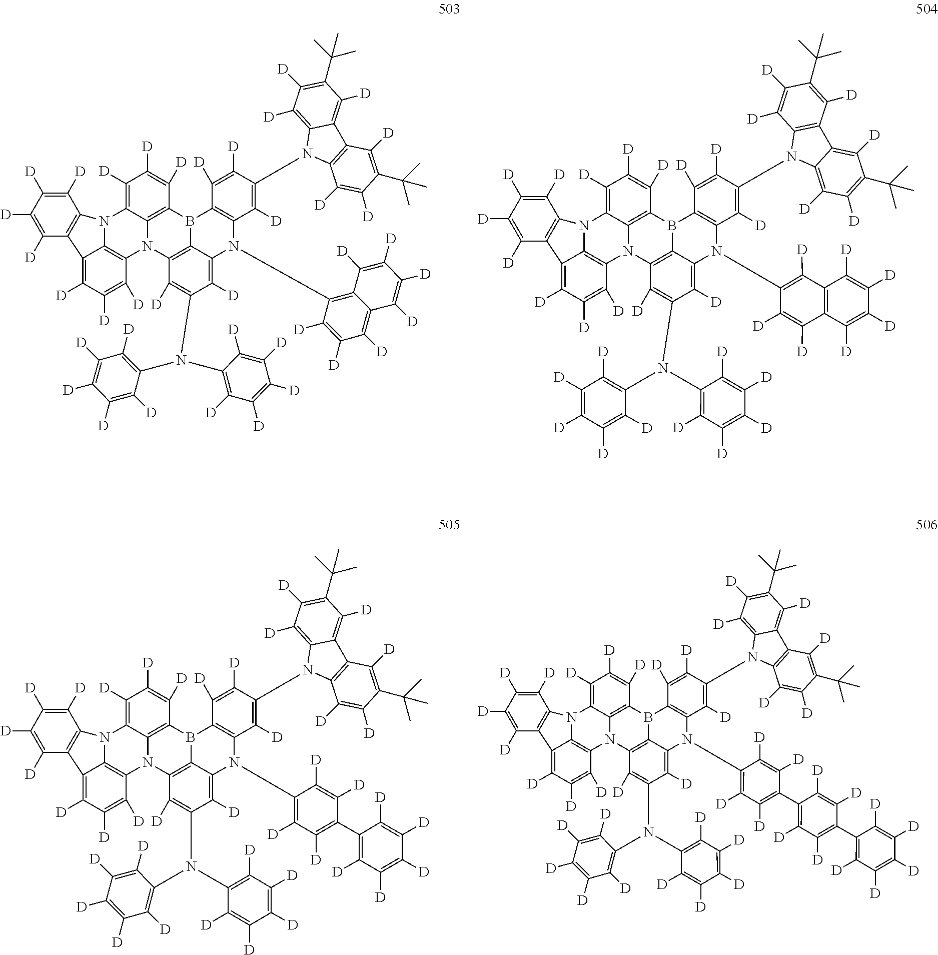

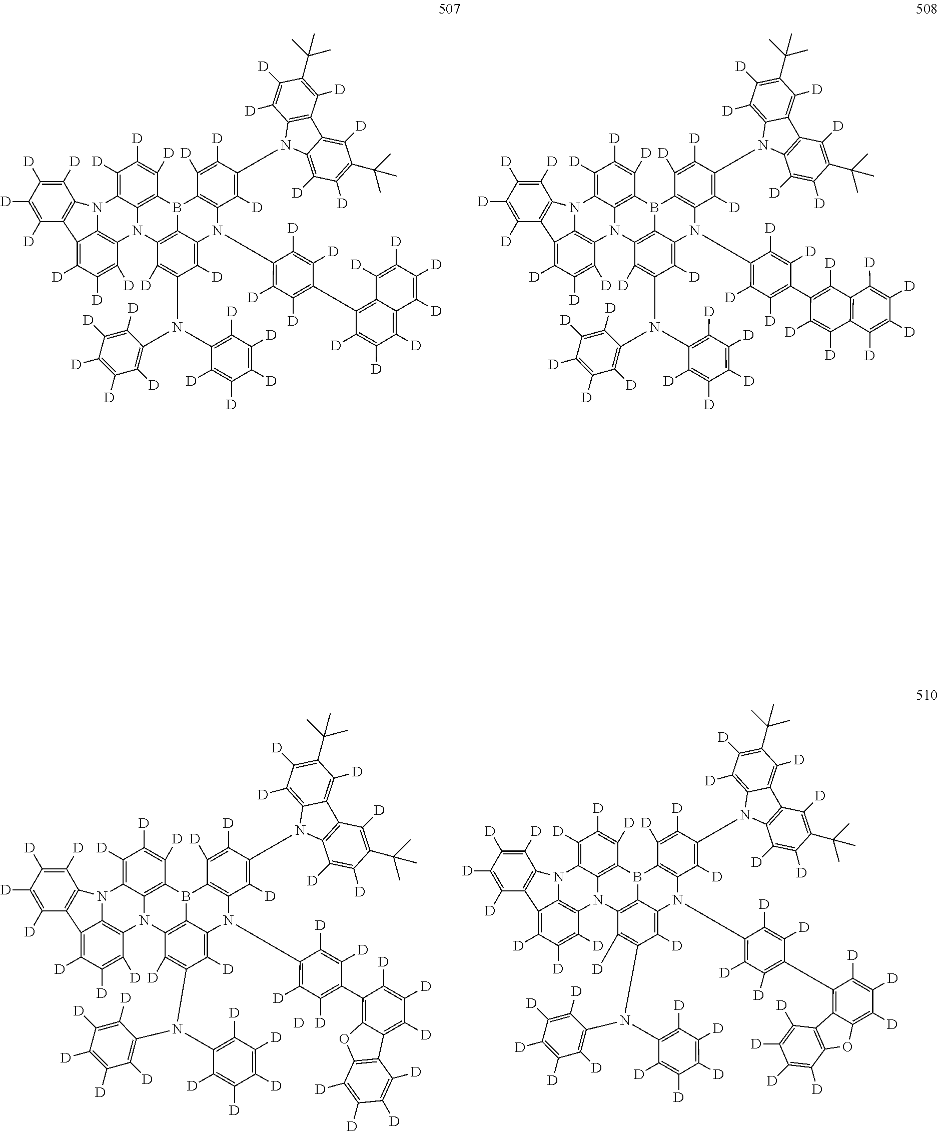

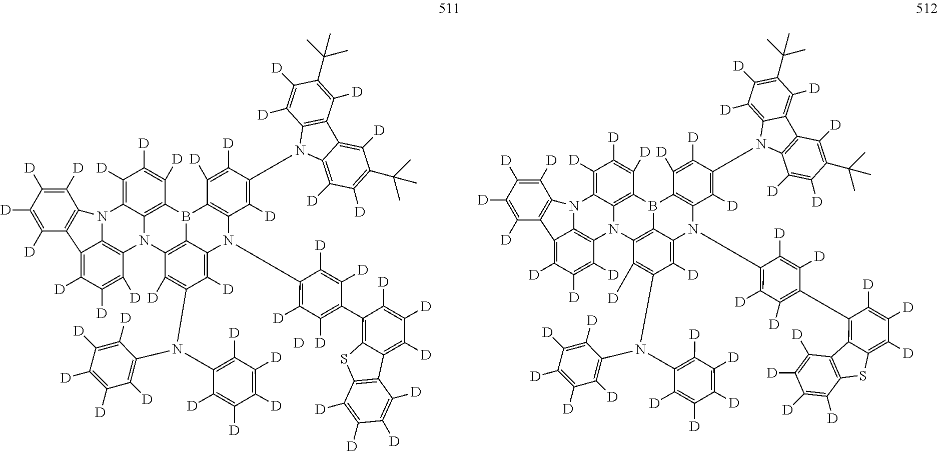

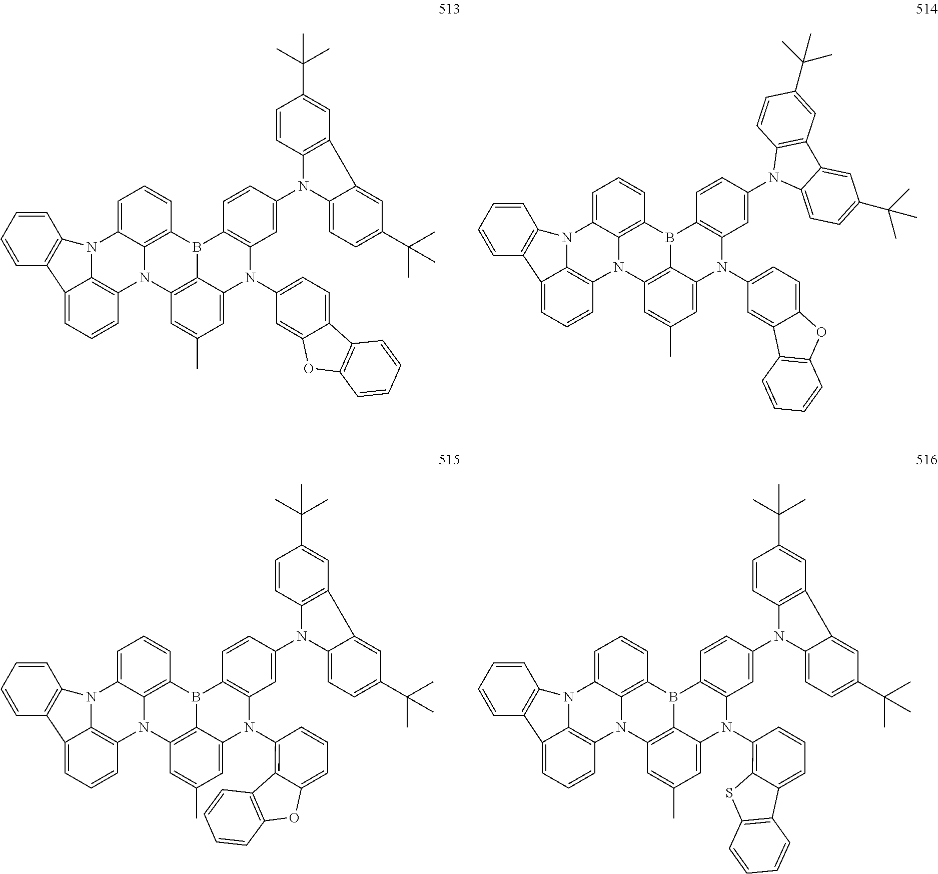 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1ccc2c(c1)oc1ccccc12 ; Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1ccc2oc3ccccc3c2c1 ; Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2oc3ccccc3c12 ; Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2c1sc1ccccc12]

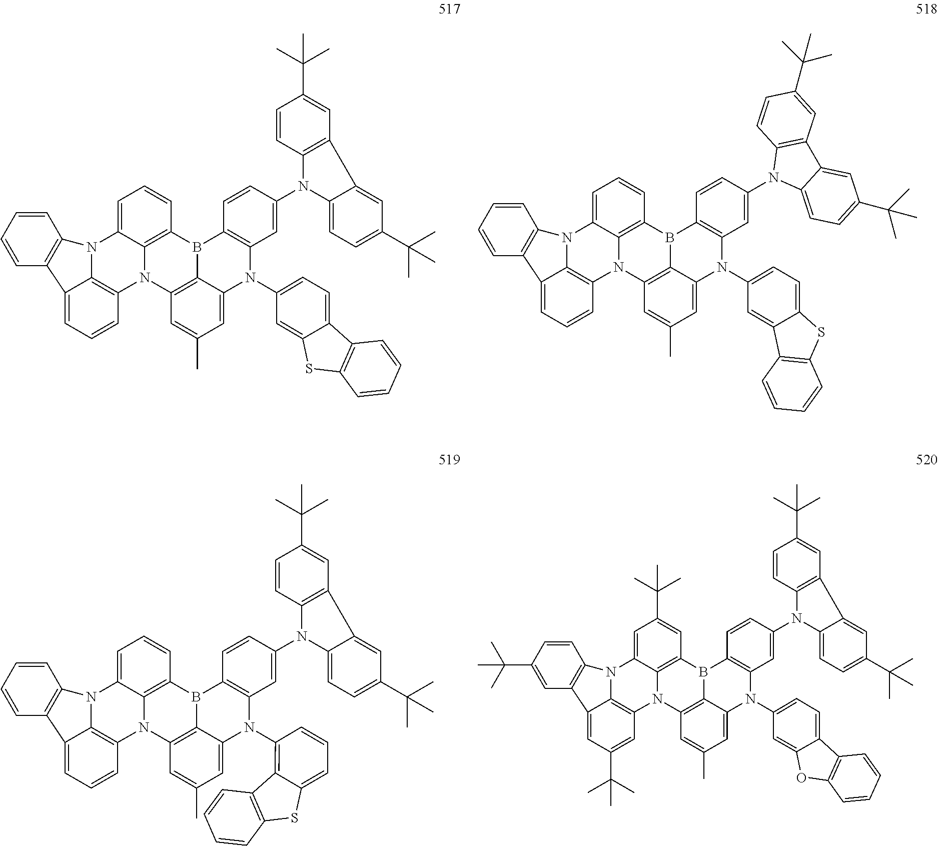

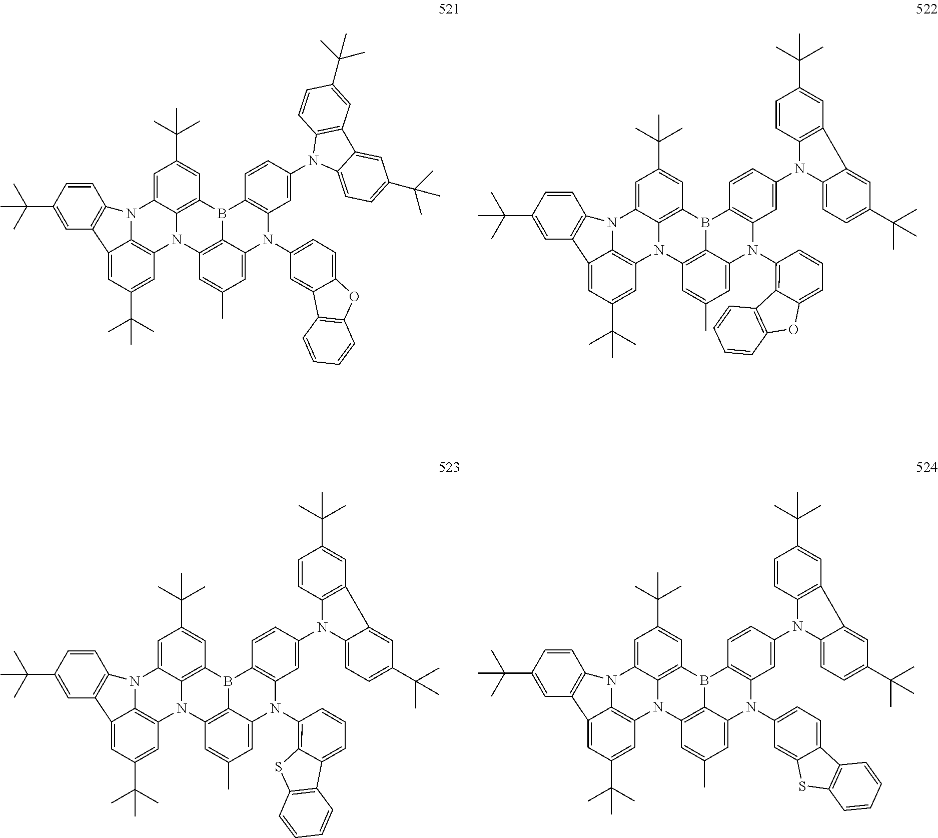

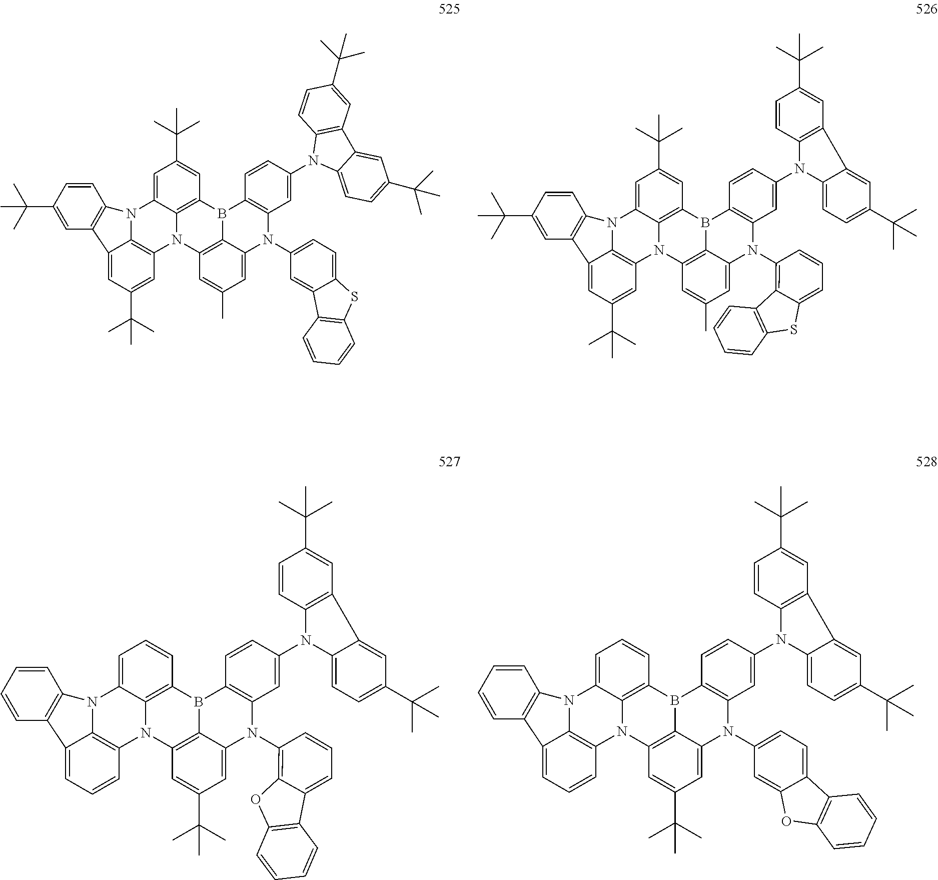

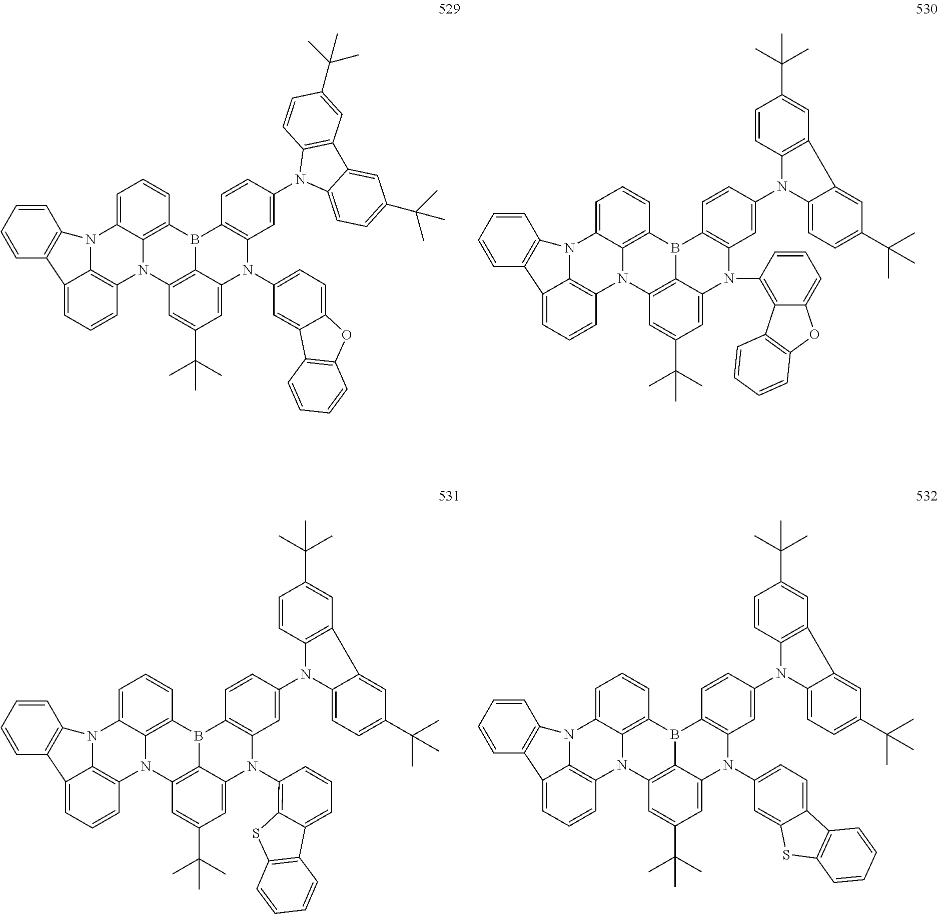

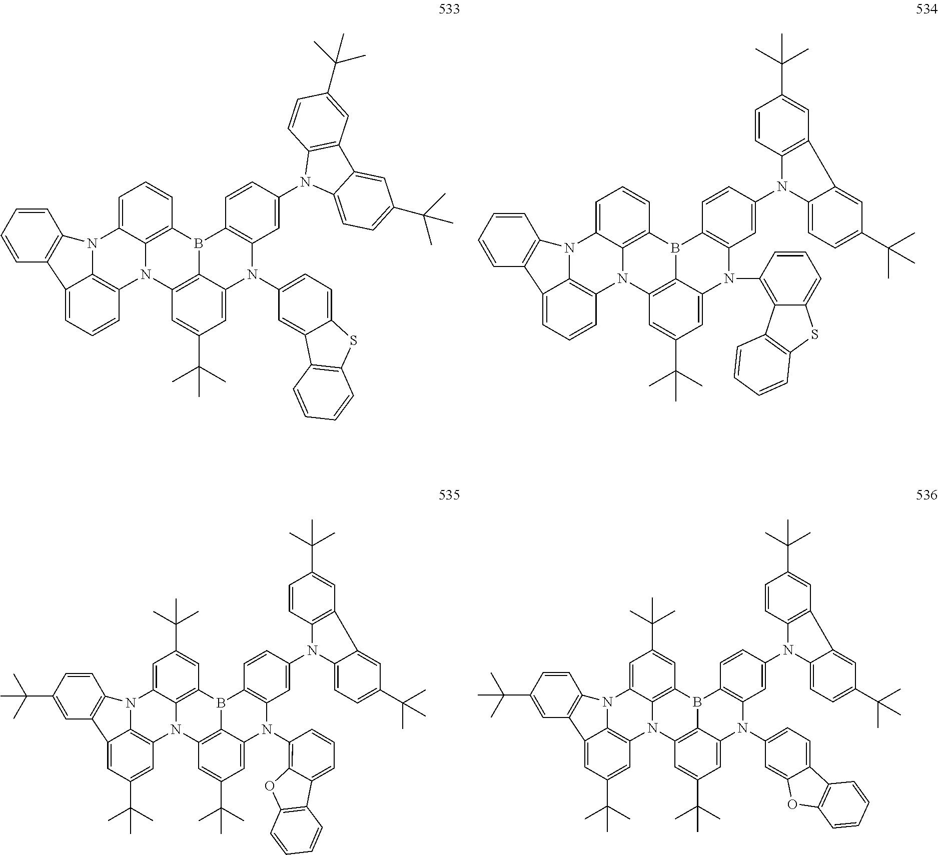

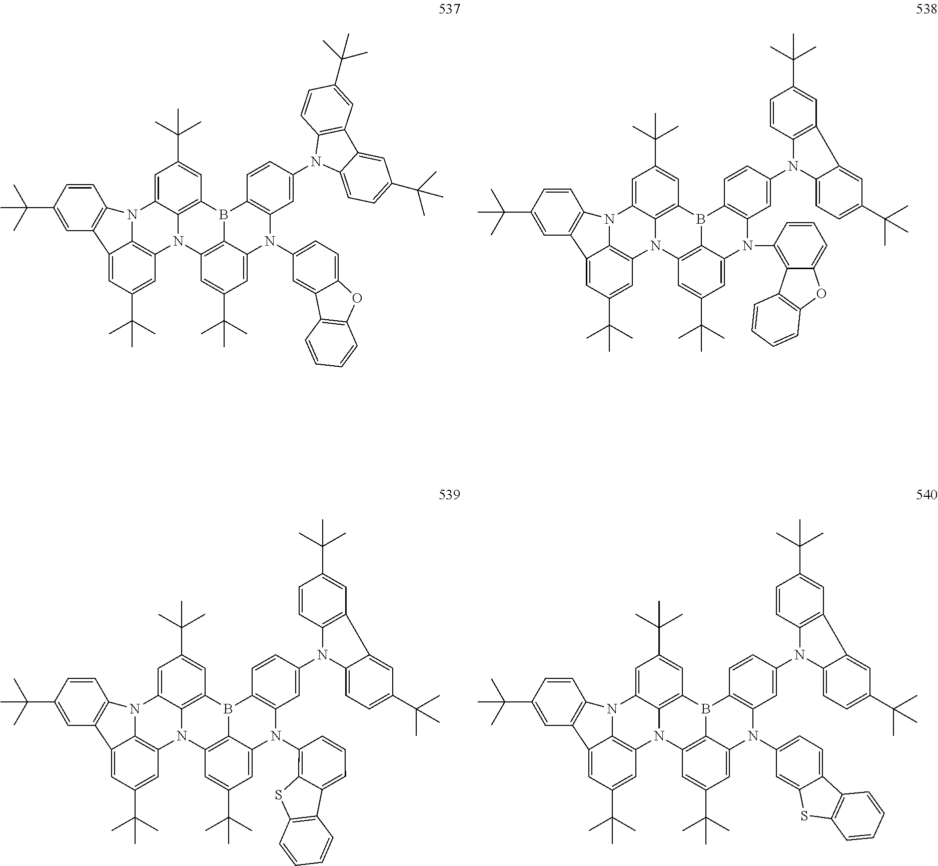

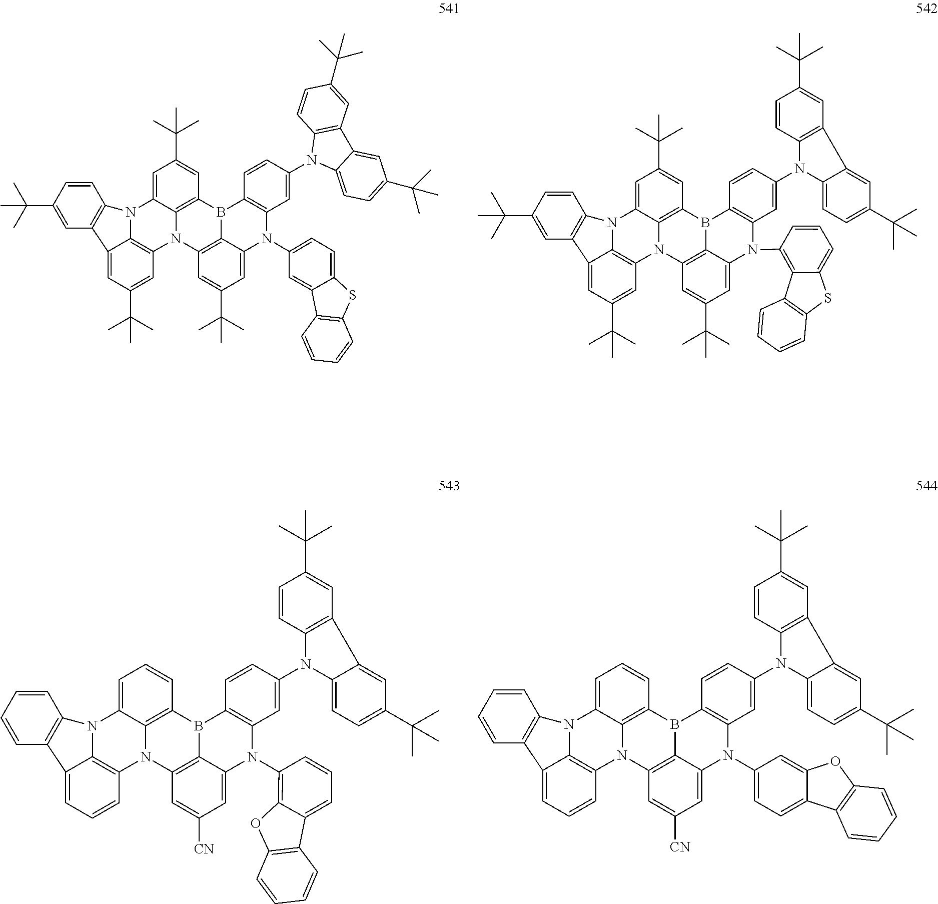

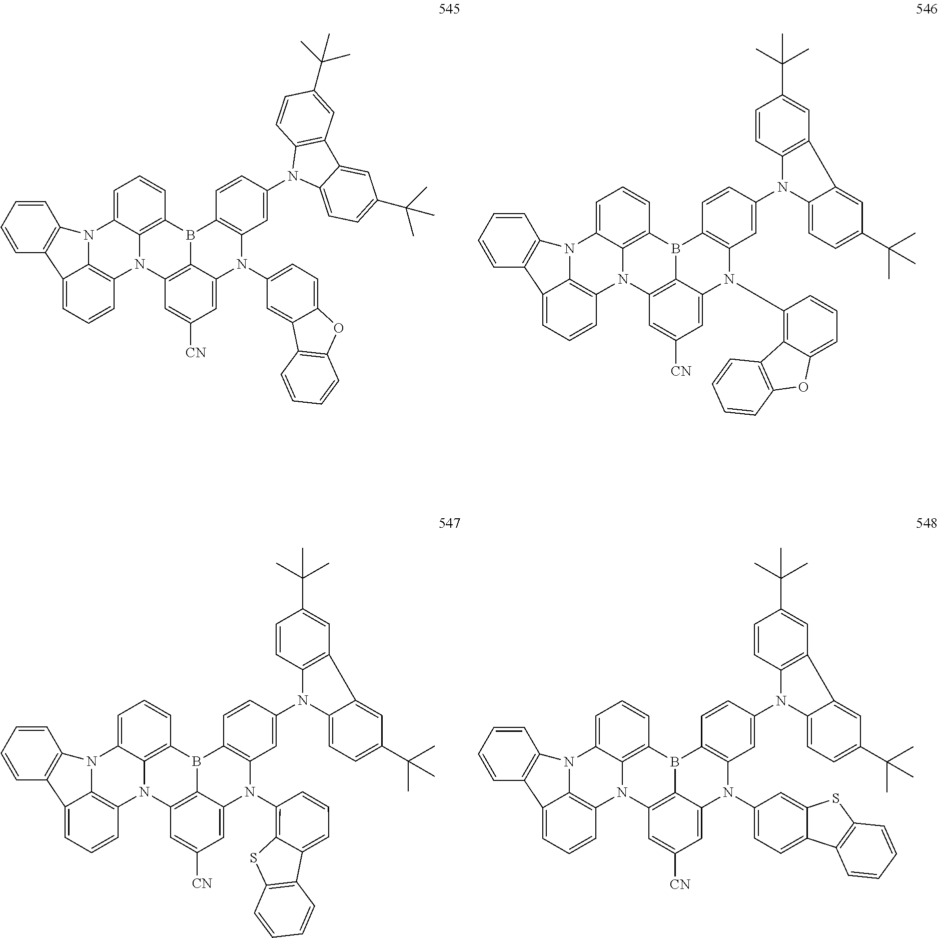 [SMILES: CC(C)(C)c1ccc2c(c1)c1cc(C(C)(C)C)ccc1n2-c1ccc2c(c1)N(c1ccc3oc4ccccc4c3c1)c1cc(C#N)cc3c1B2c1cccc2c1N3c1cccc3c4ccccc4n-2c13 ; CC(C)(C)c1ccc2c(c1)c1cc(C(C)(C)C)ccc1n2-c1ccc2c(c1)N(c1cccc3oc4ccccc4c13)c1cc(C#N)cc3c1B2c1cccc2c1N3c1cccc3c4ccccc4n-2c13 ; CC(C)(C)c1ccc2c(c1)c1cc(C(C)(C)C)ccc1n2-c1ccc2c(c1)N(c1cccc3c1sc1ccccc13)c1cc(C#N)cc3c1B2c1cccc2c1N3c1cccc3c4ccccc4n-2c13 ; CC(C)(C)c1ccc2c(c1)c1cc(C(C)(C)C)ccc1n2-c1ccc2c(c1)N(c1ccc3c(c1)sc1ccccc13)c1cc(C#N)cc3c1B2c1cccc2c1N3c1cccc3c4ccccc4n-2c13]

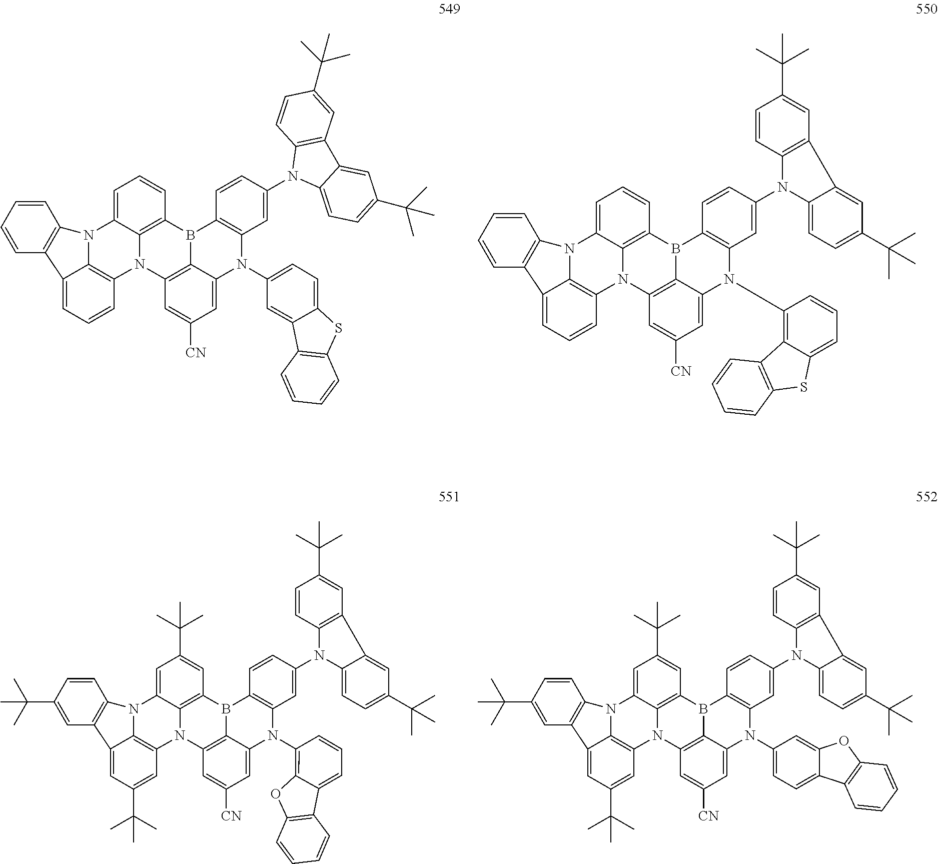

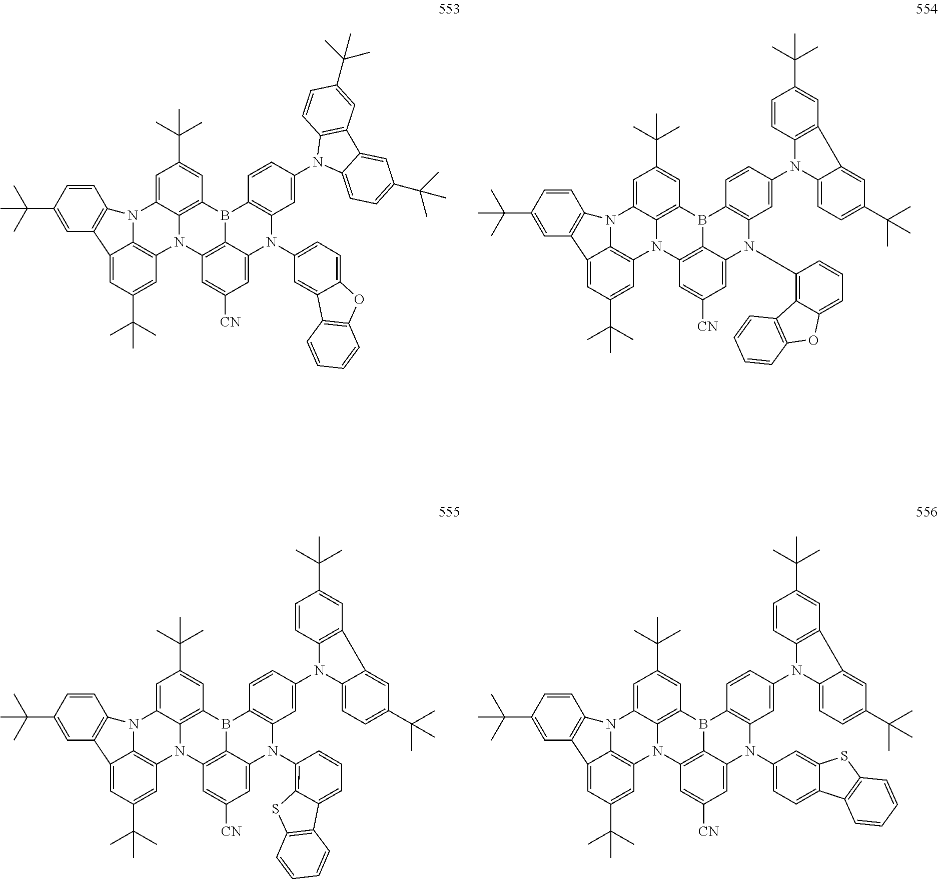

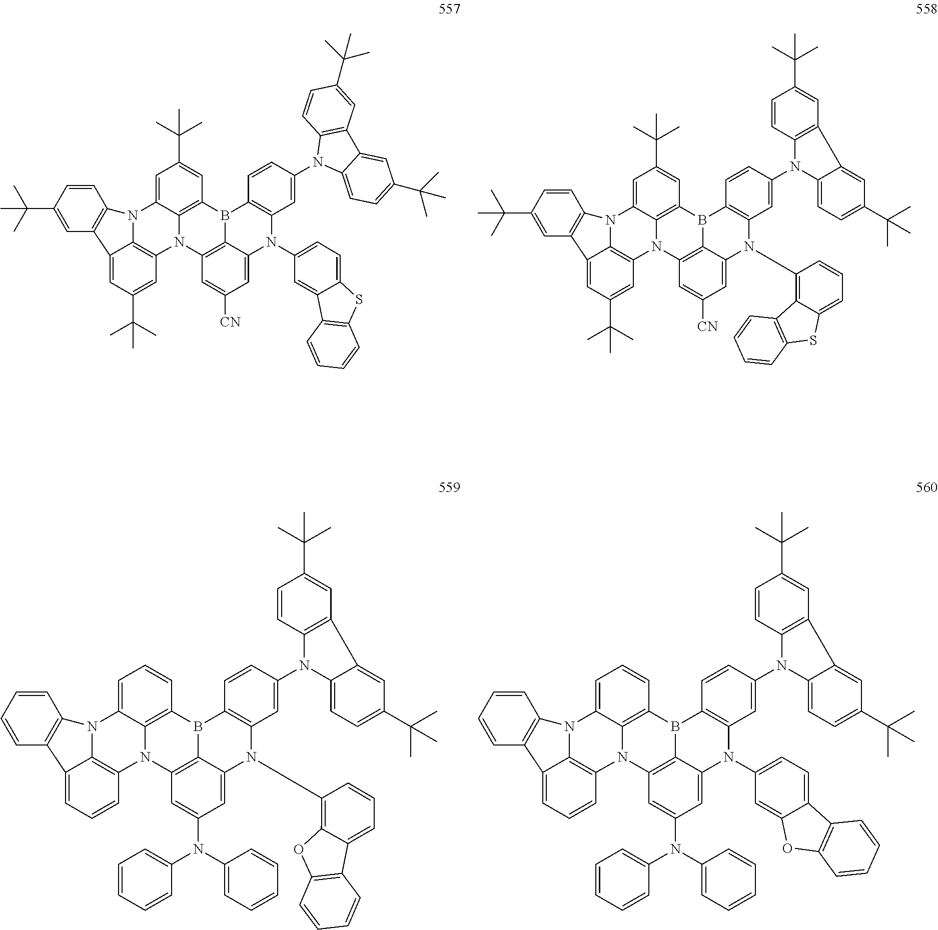

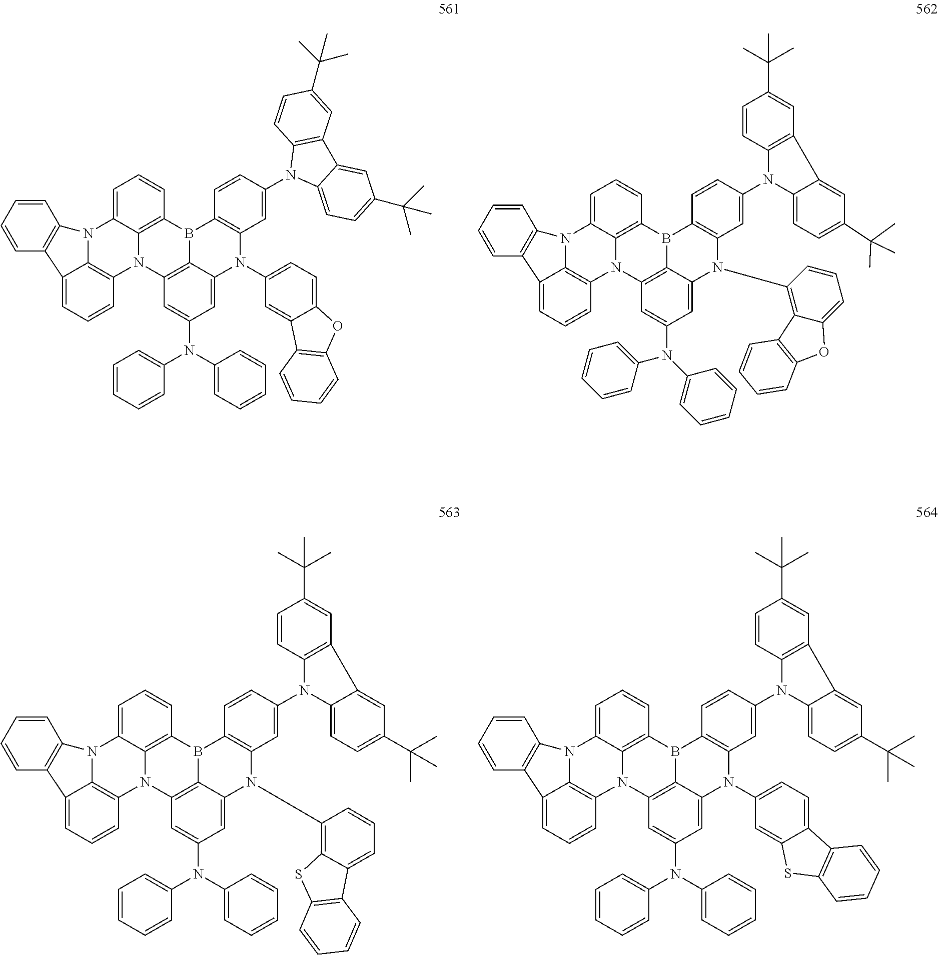

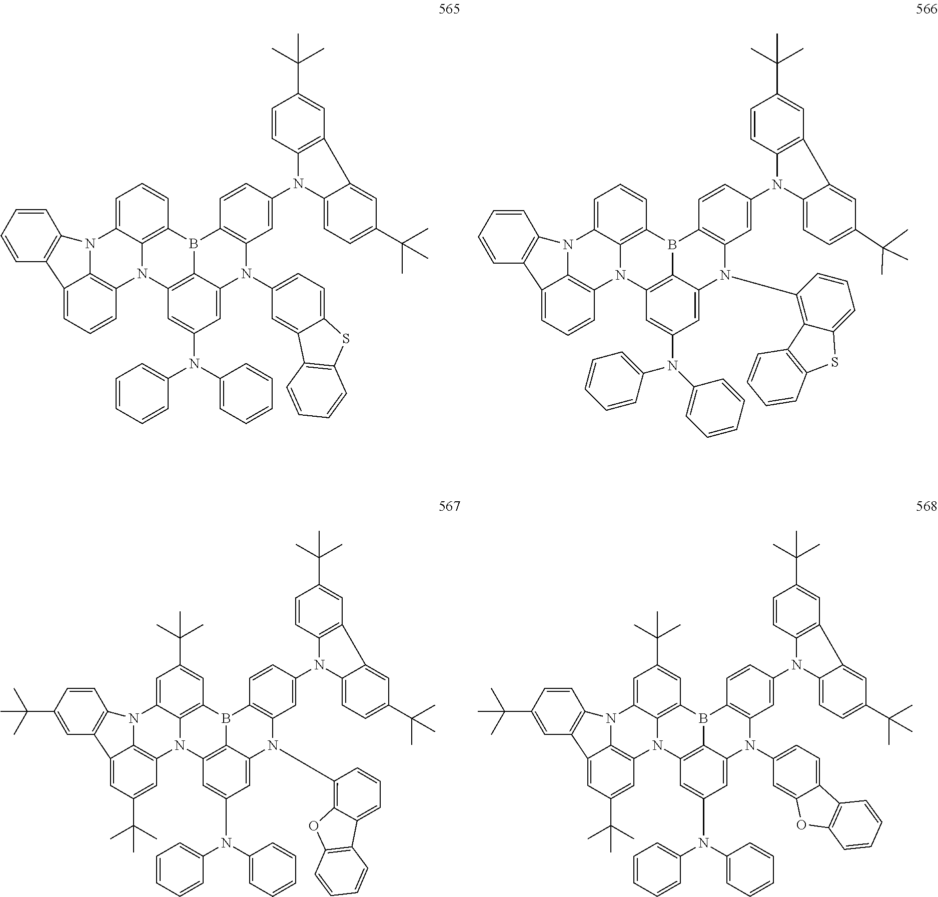

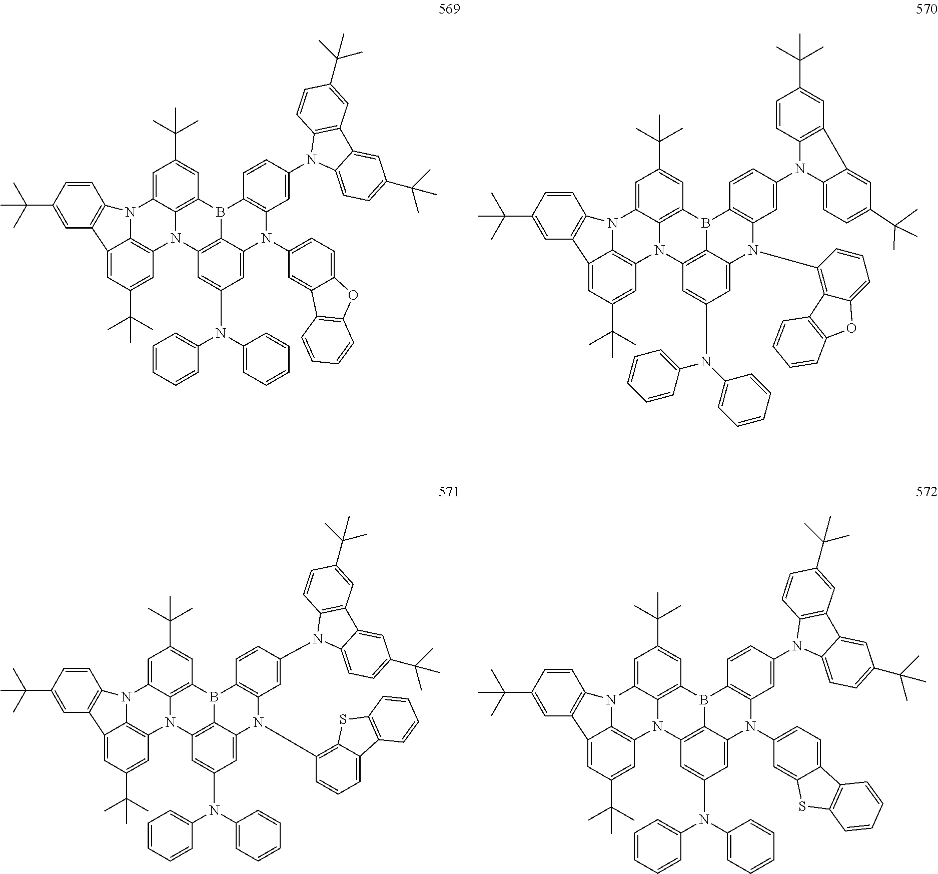

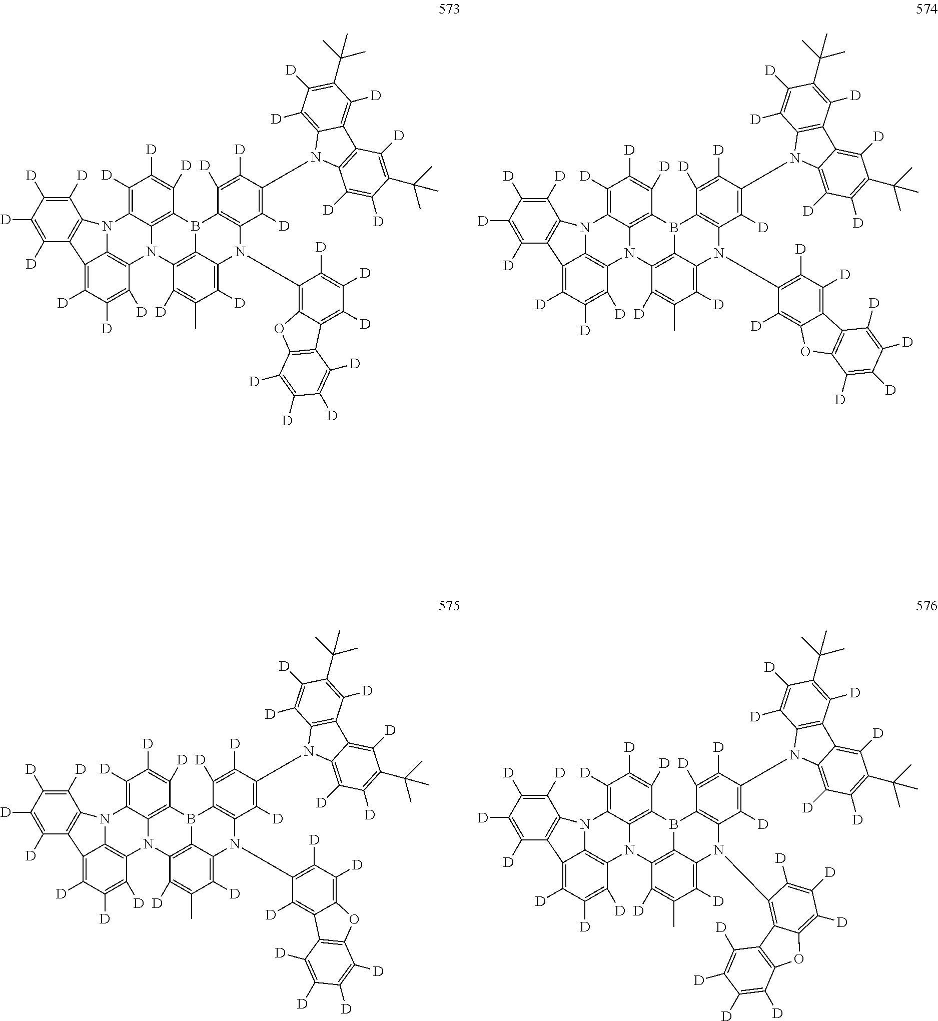

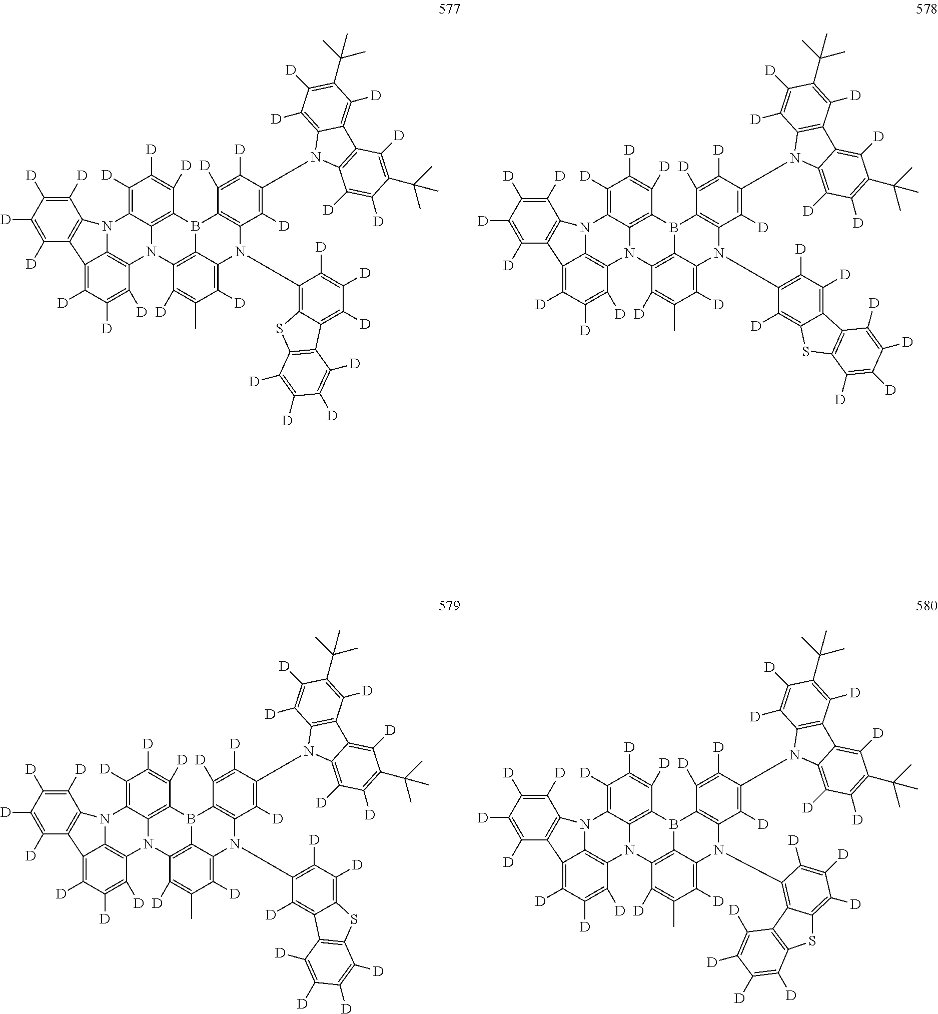

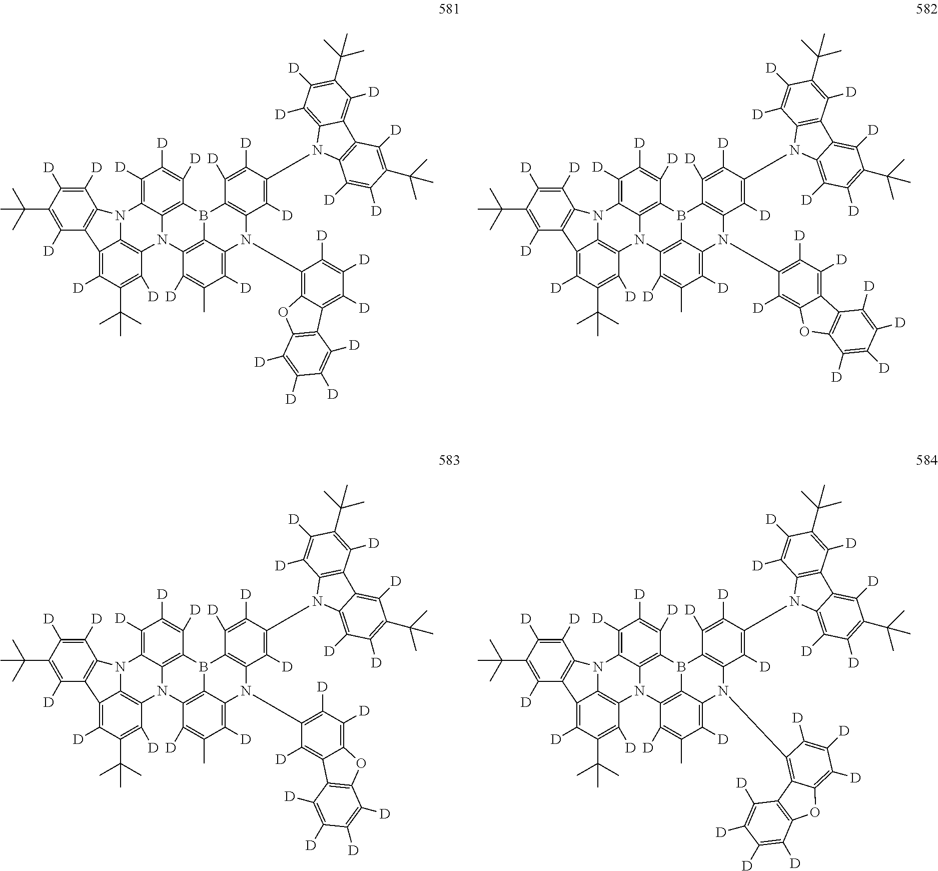

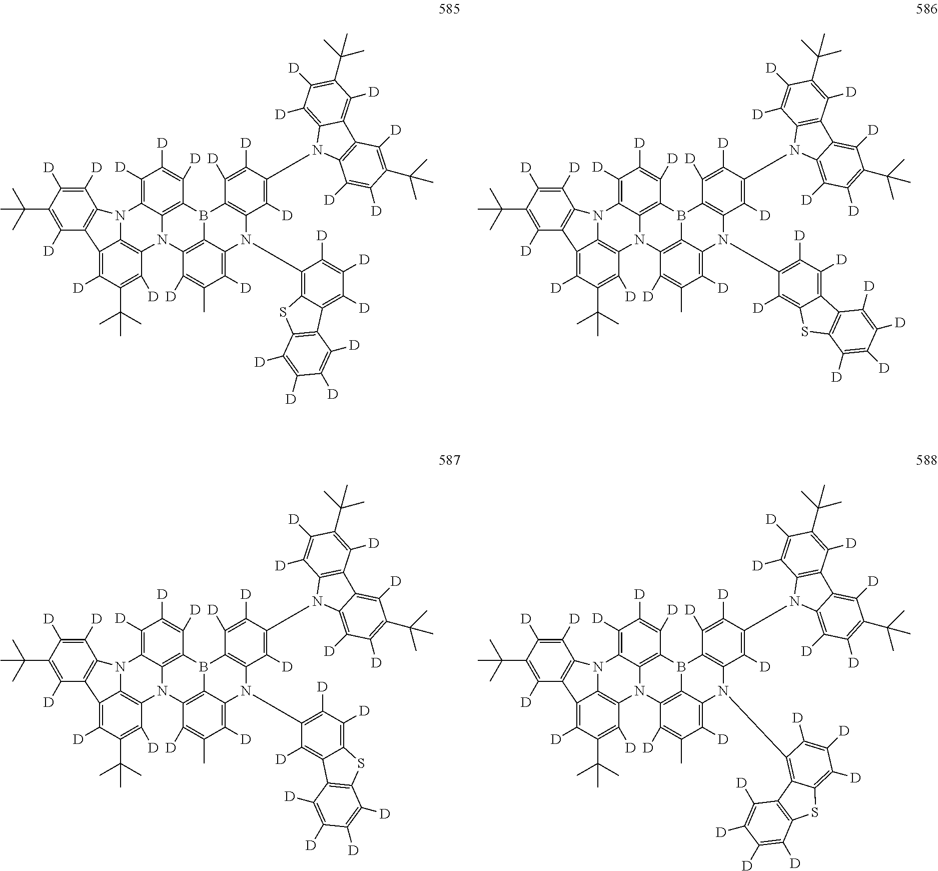

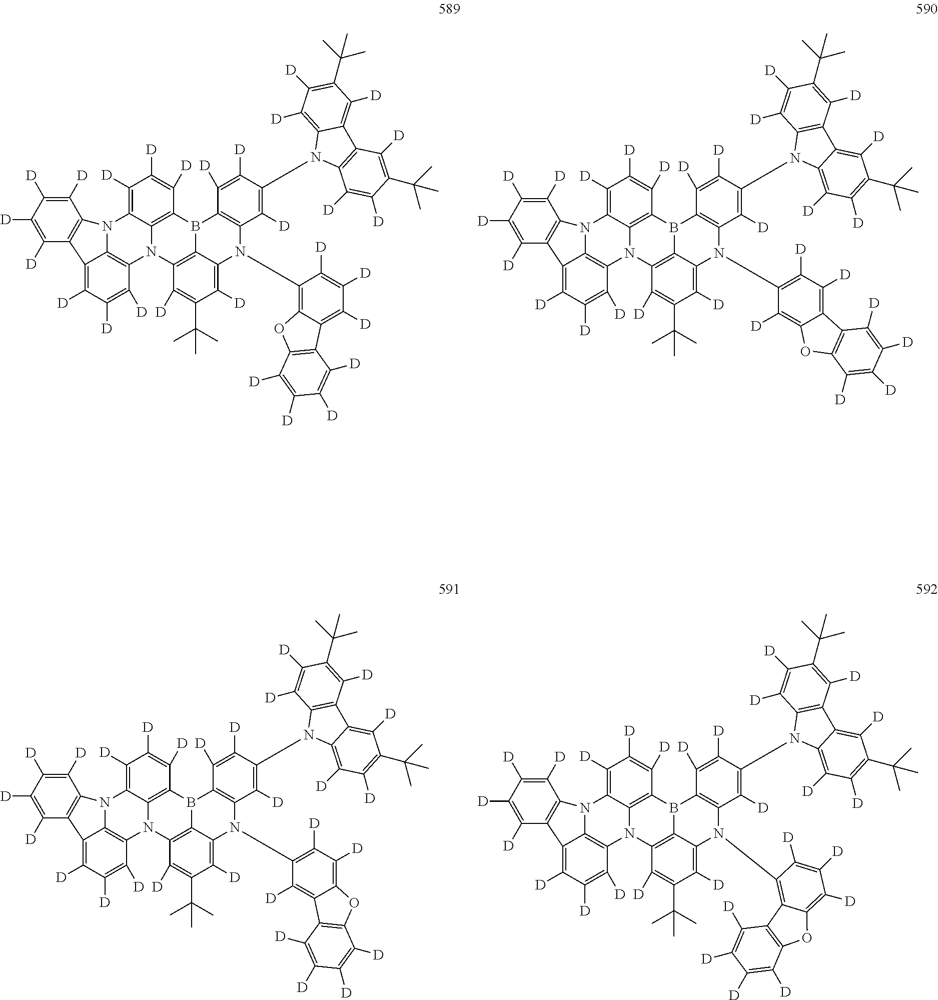

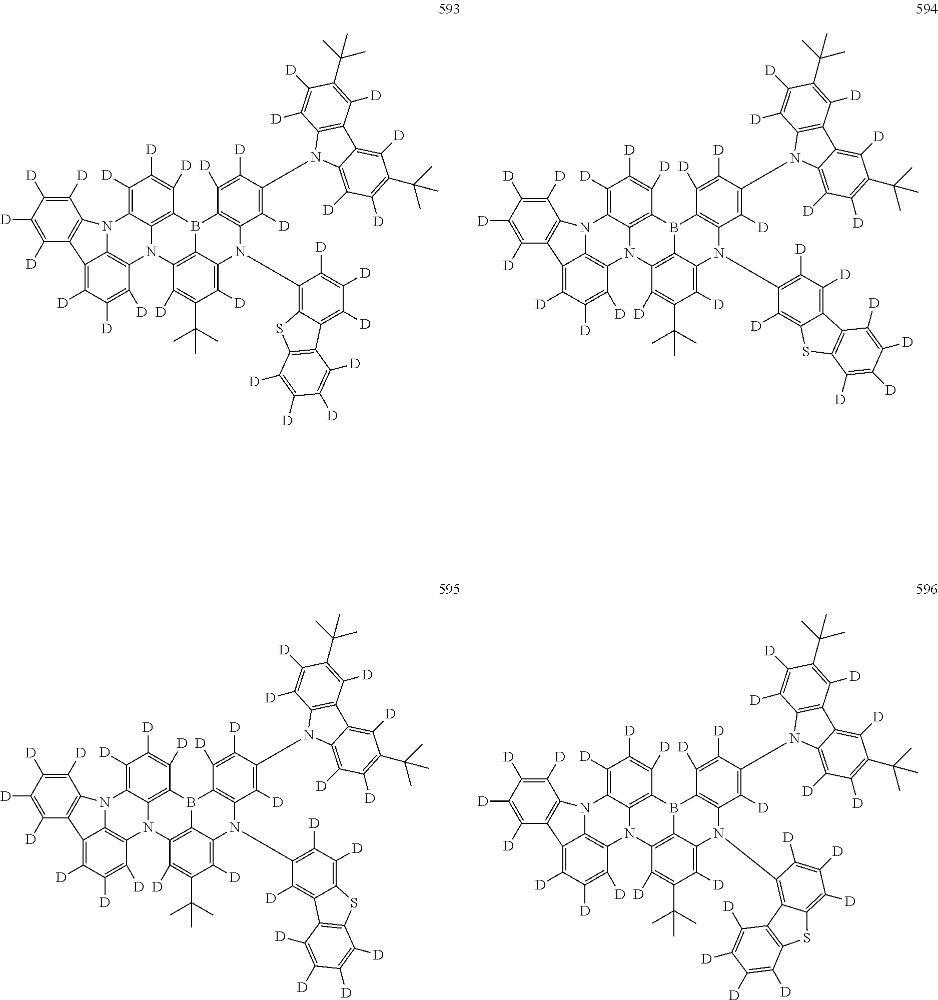

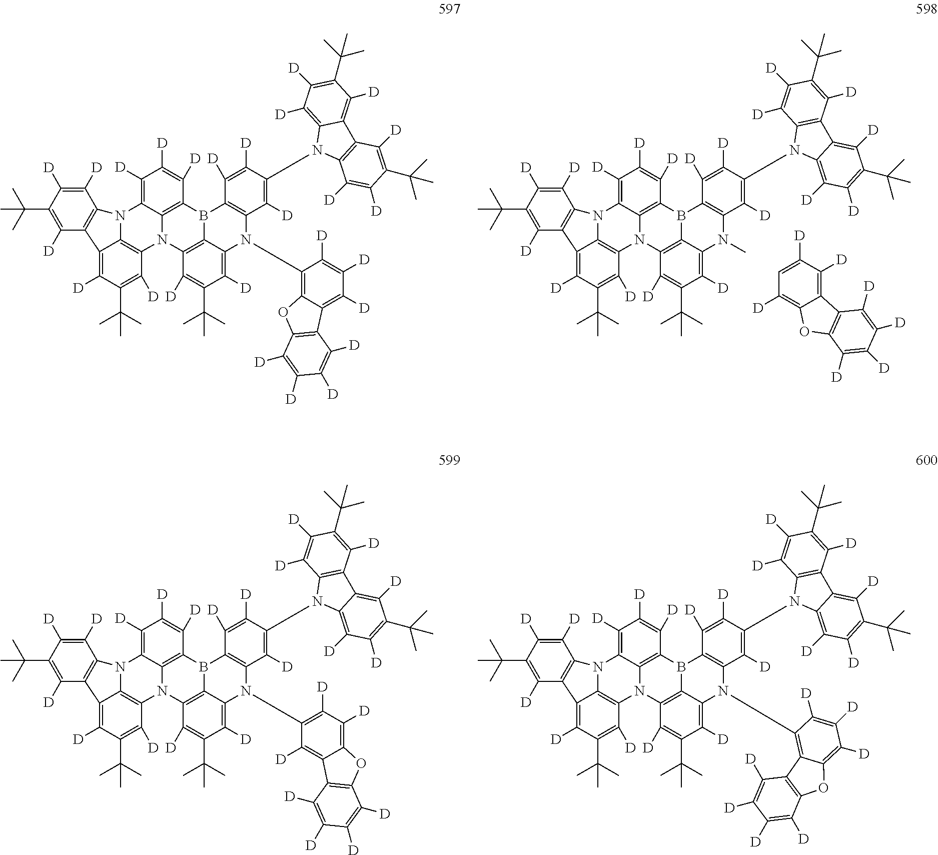

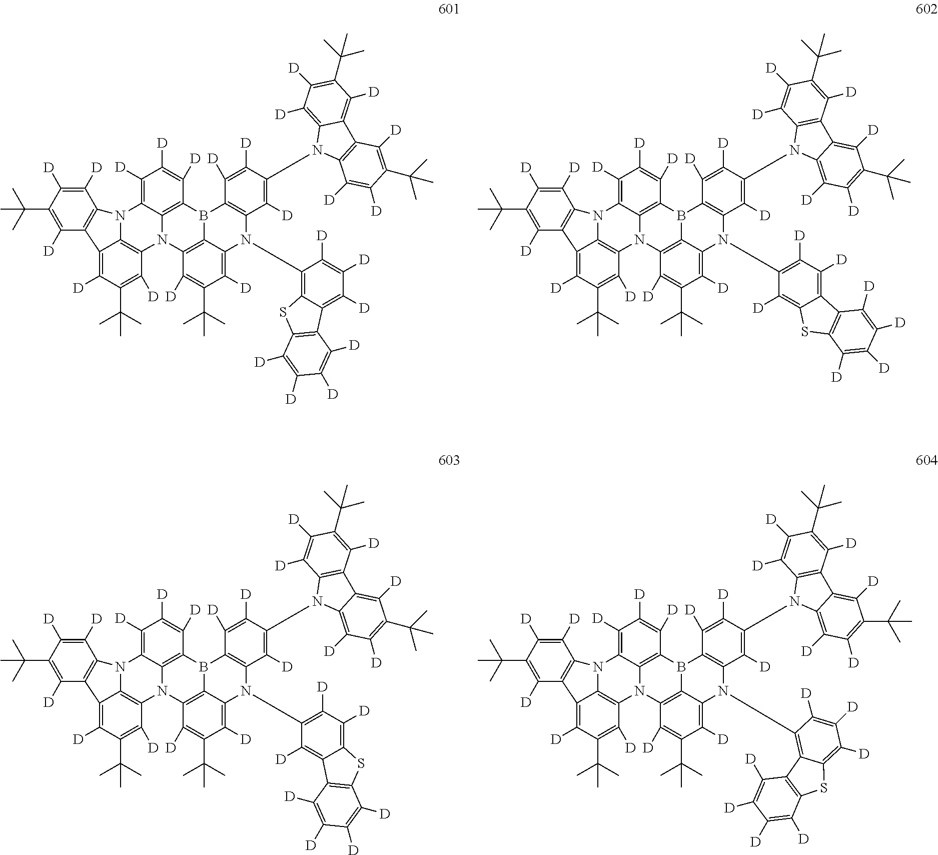

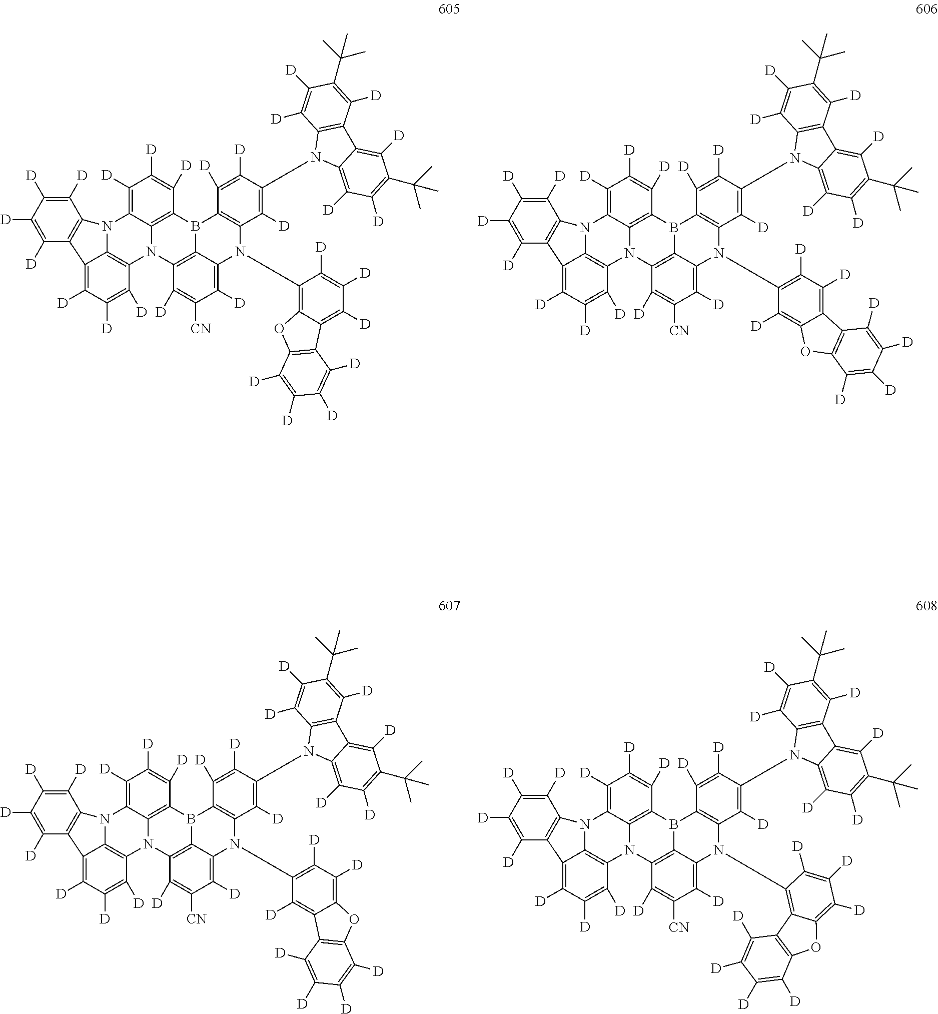

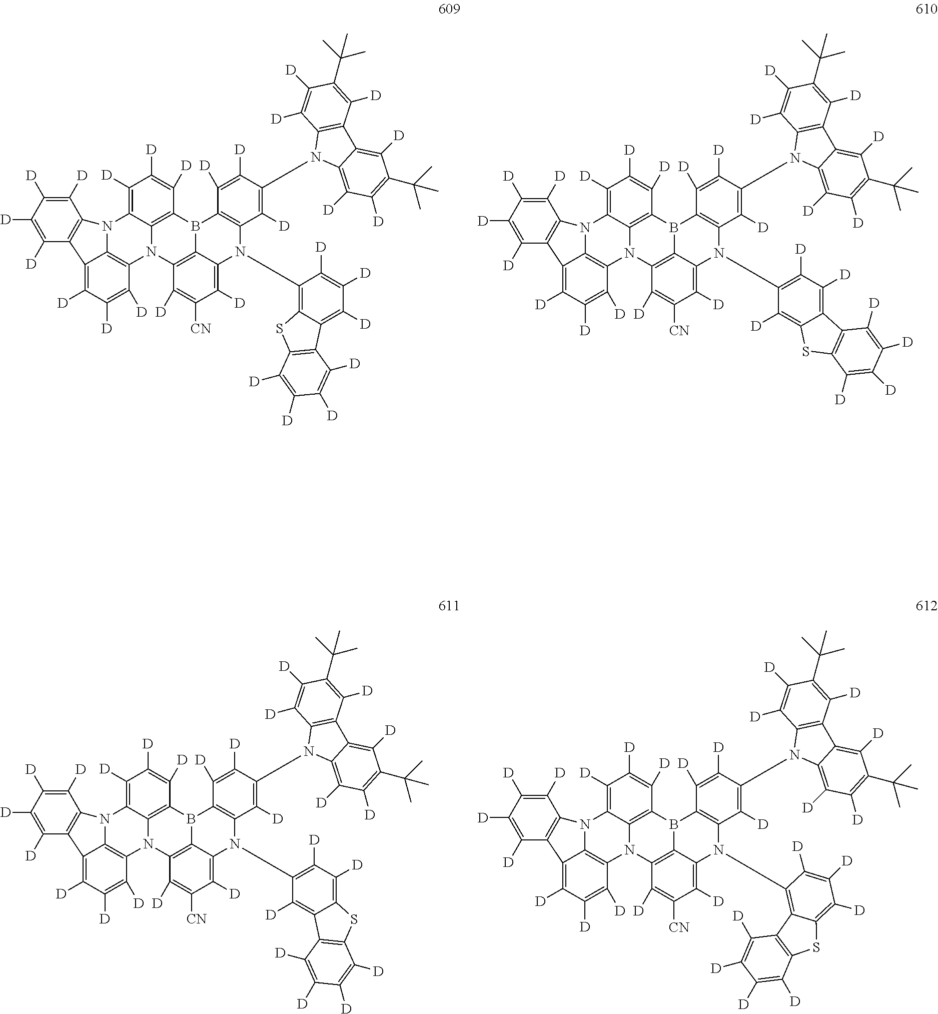

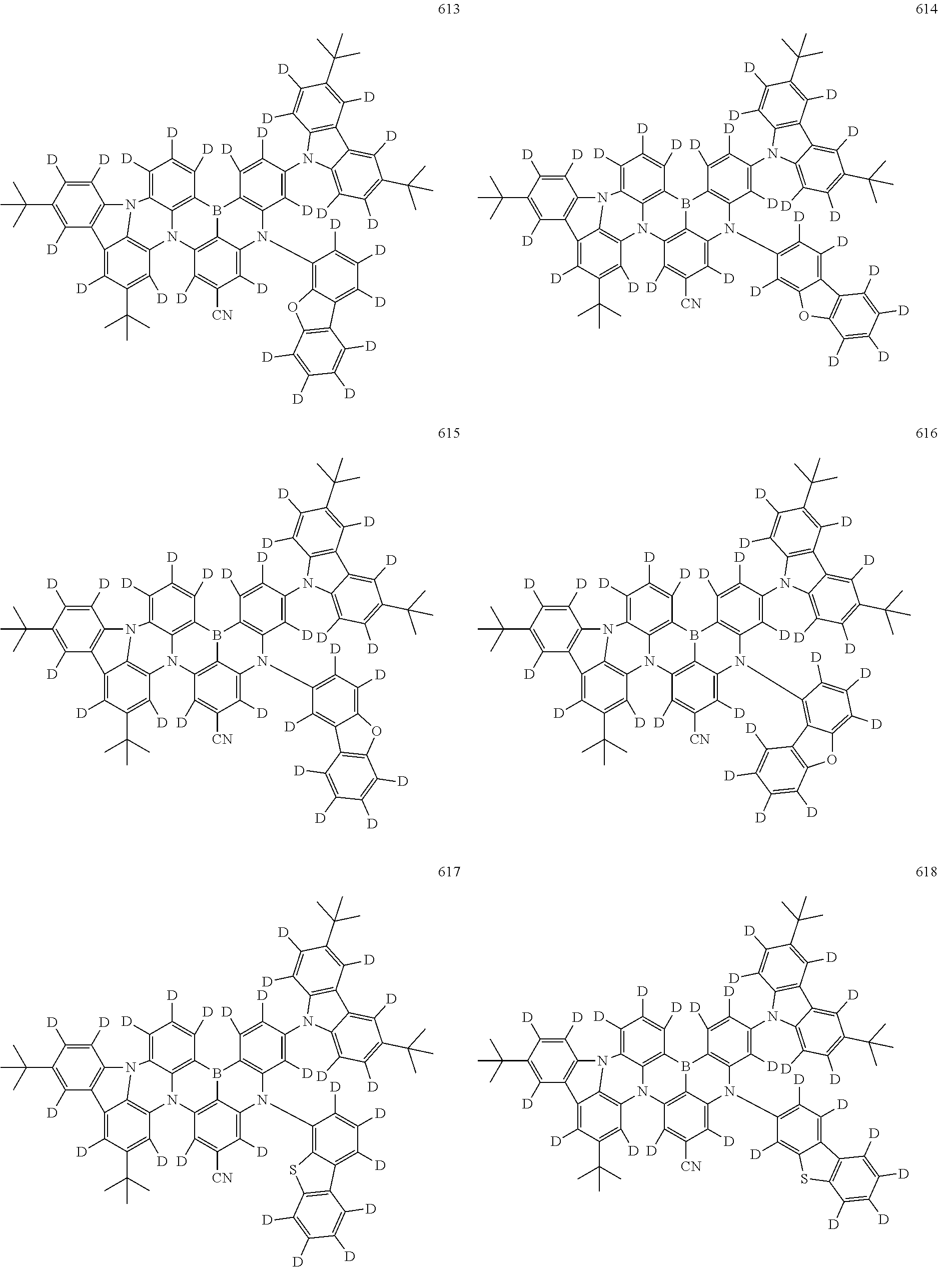

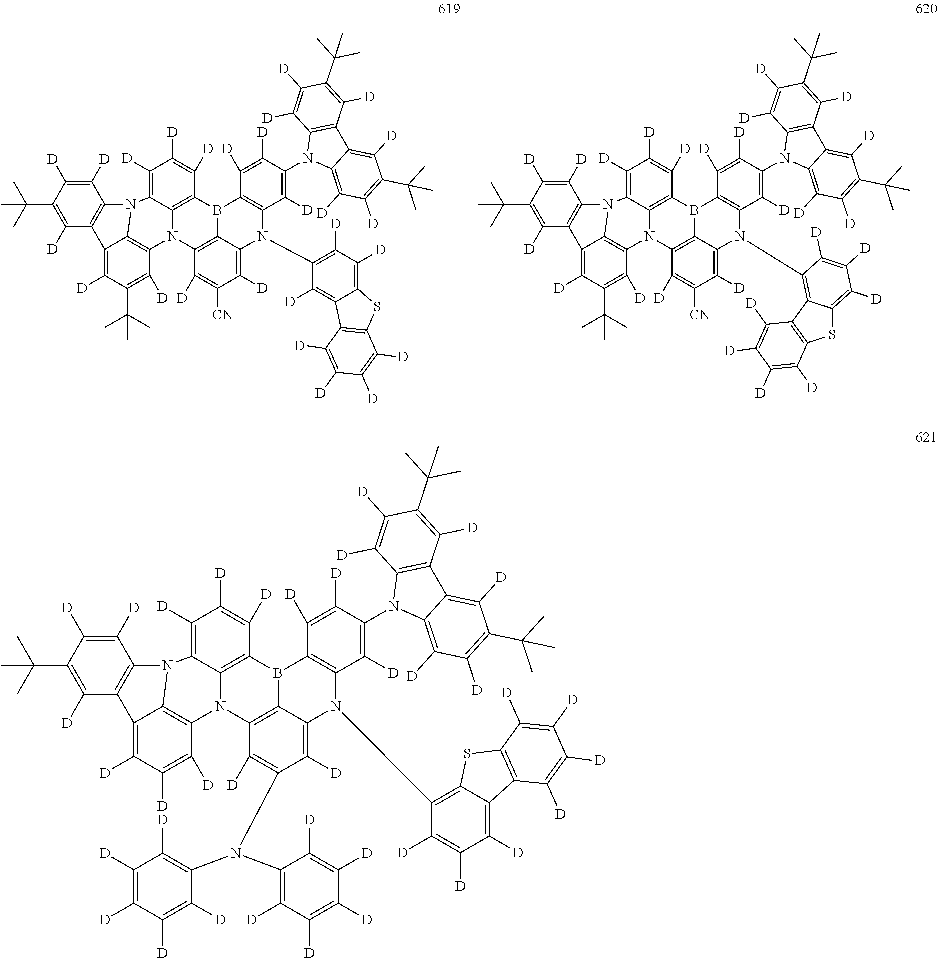

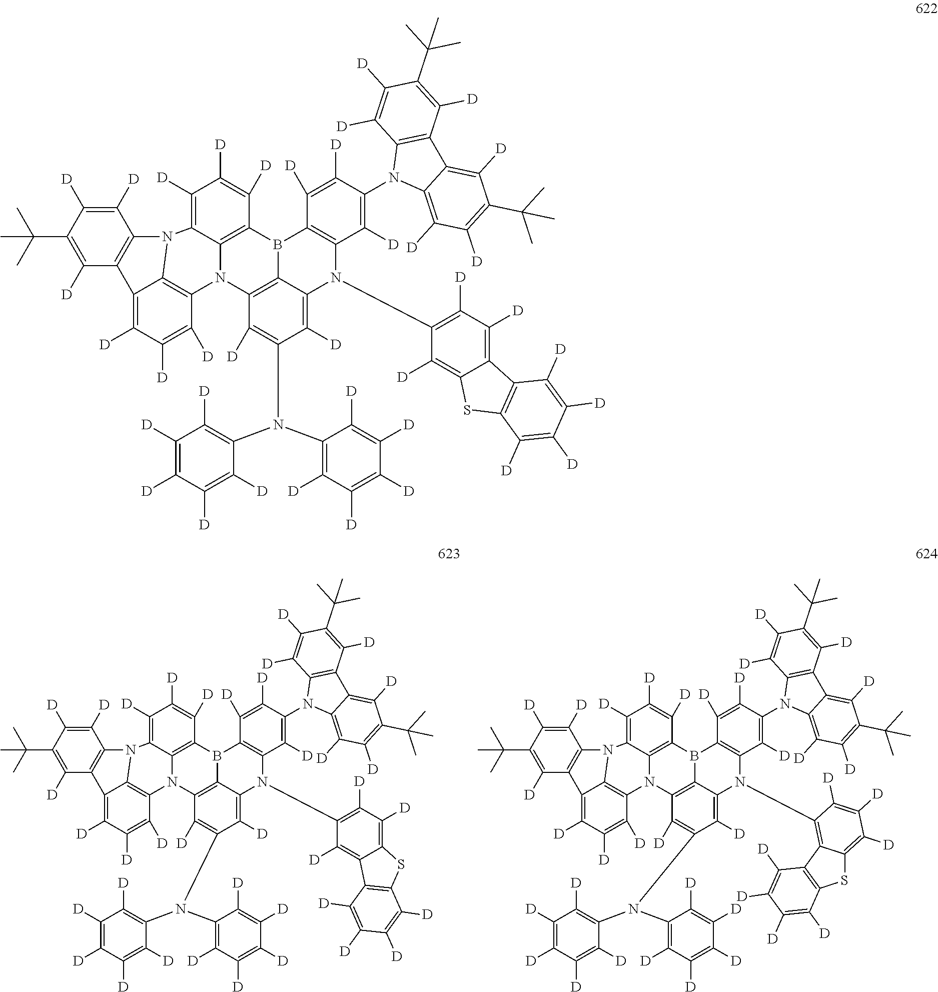

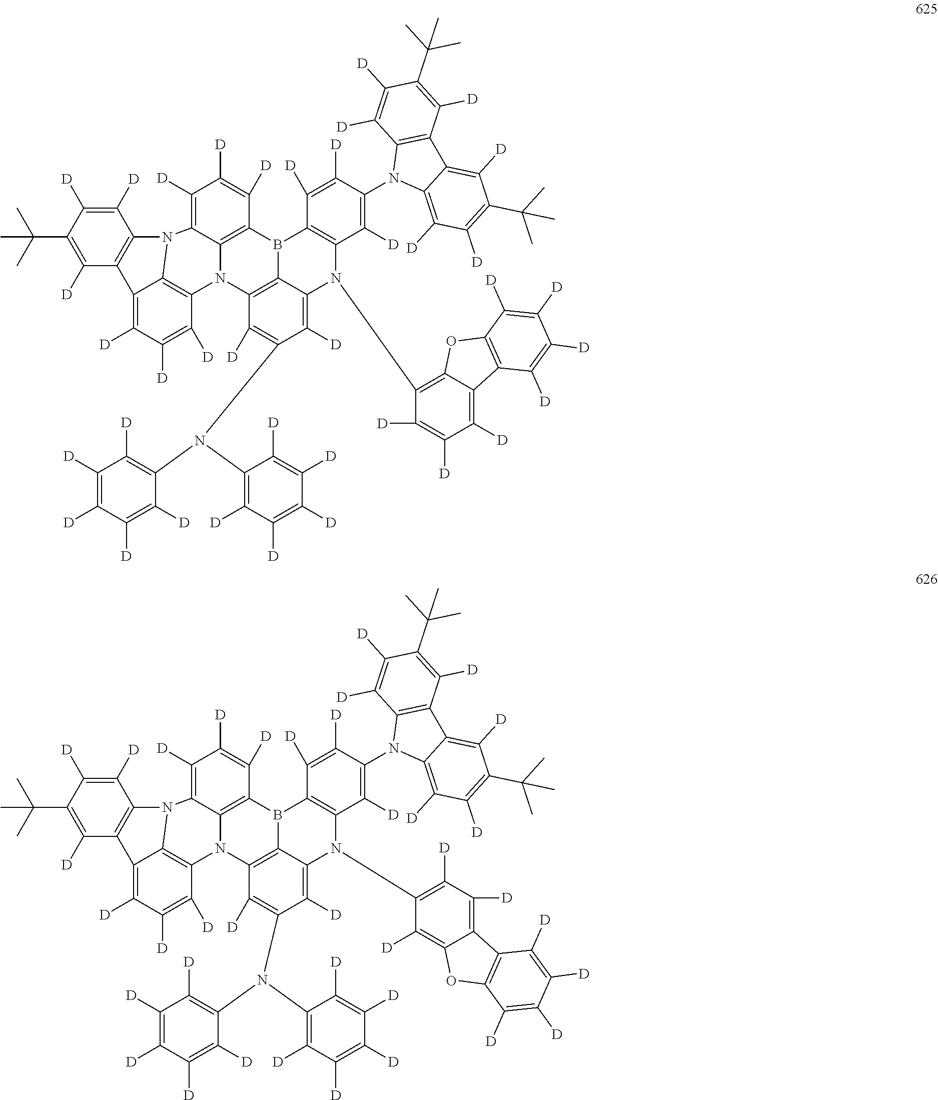

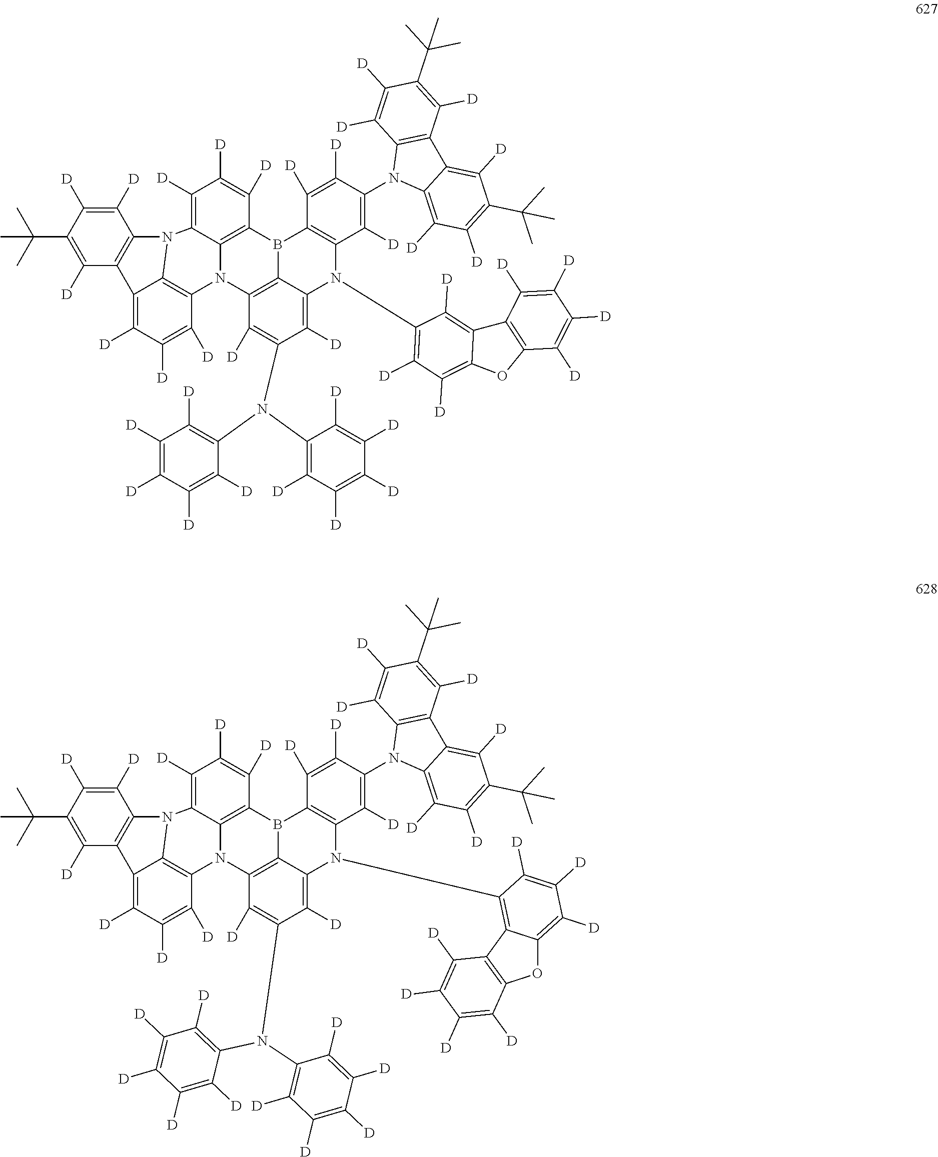

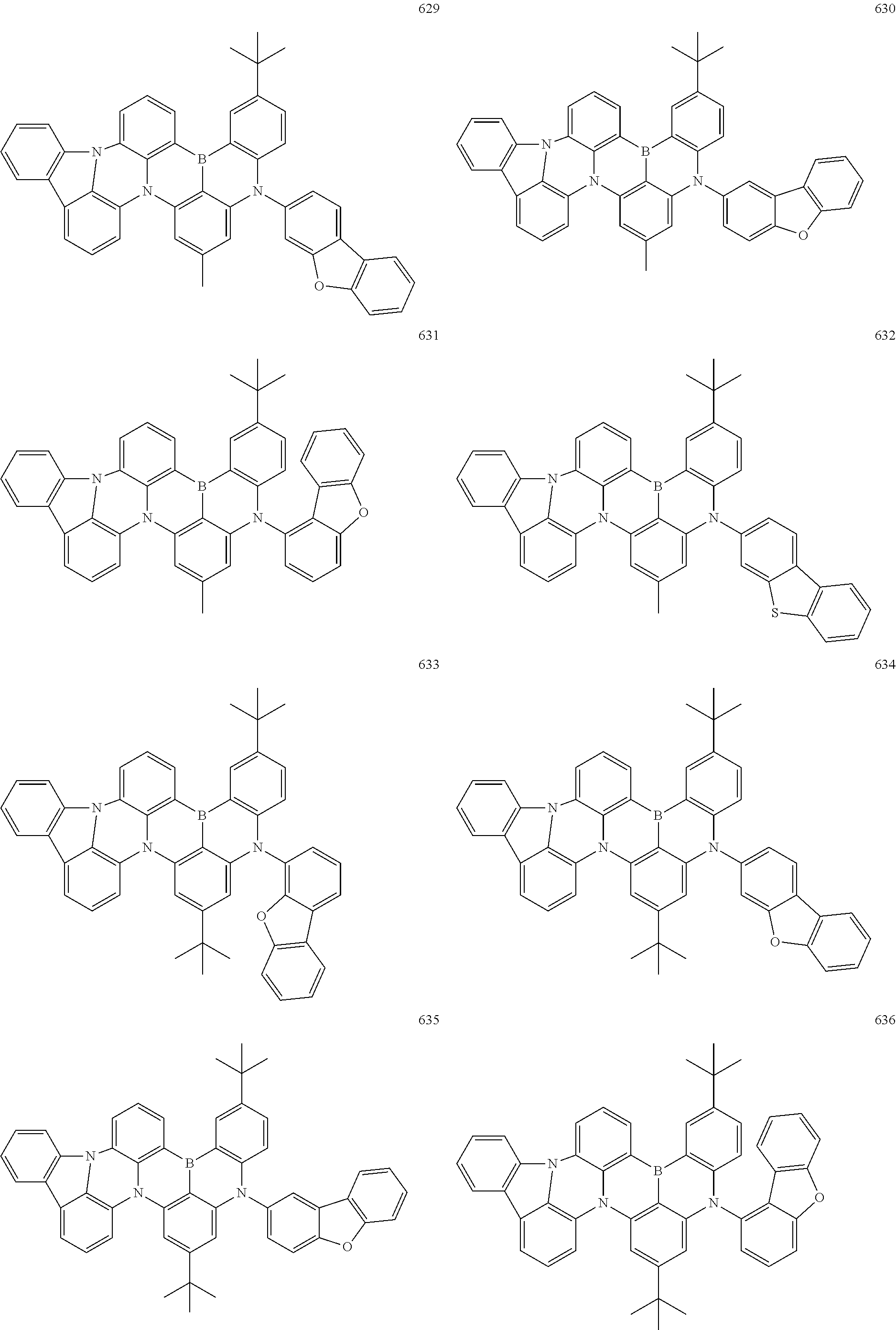

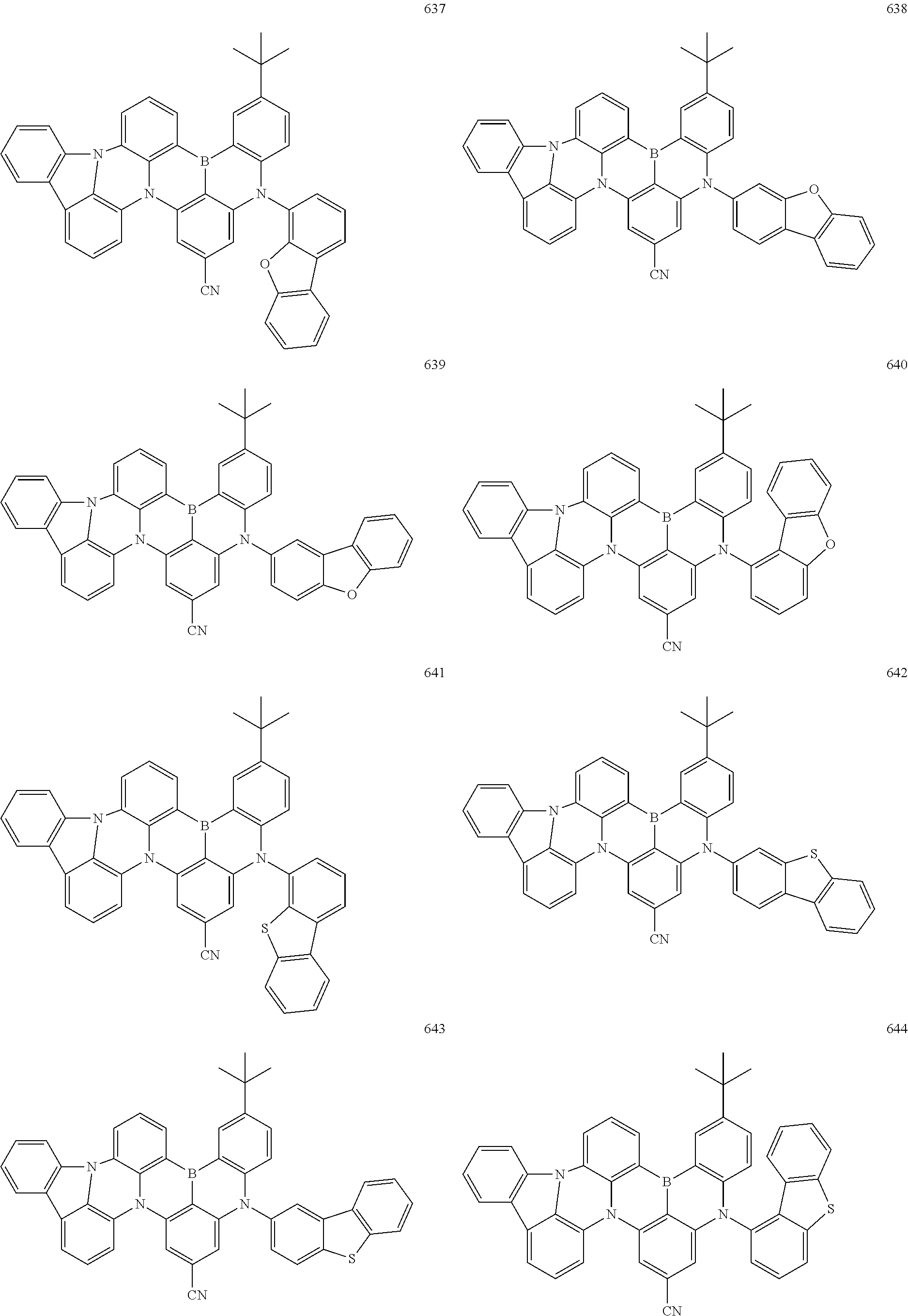

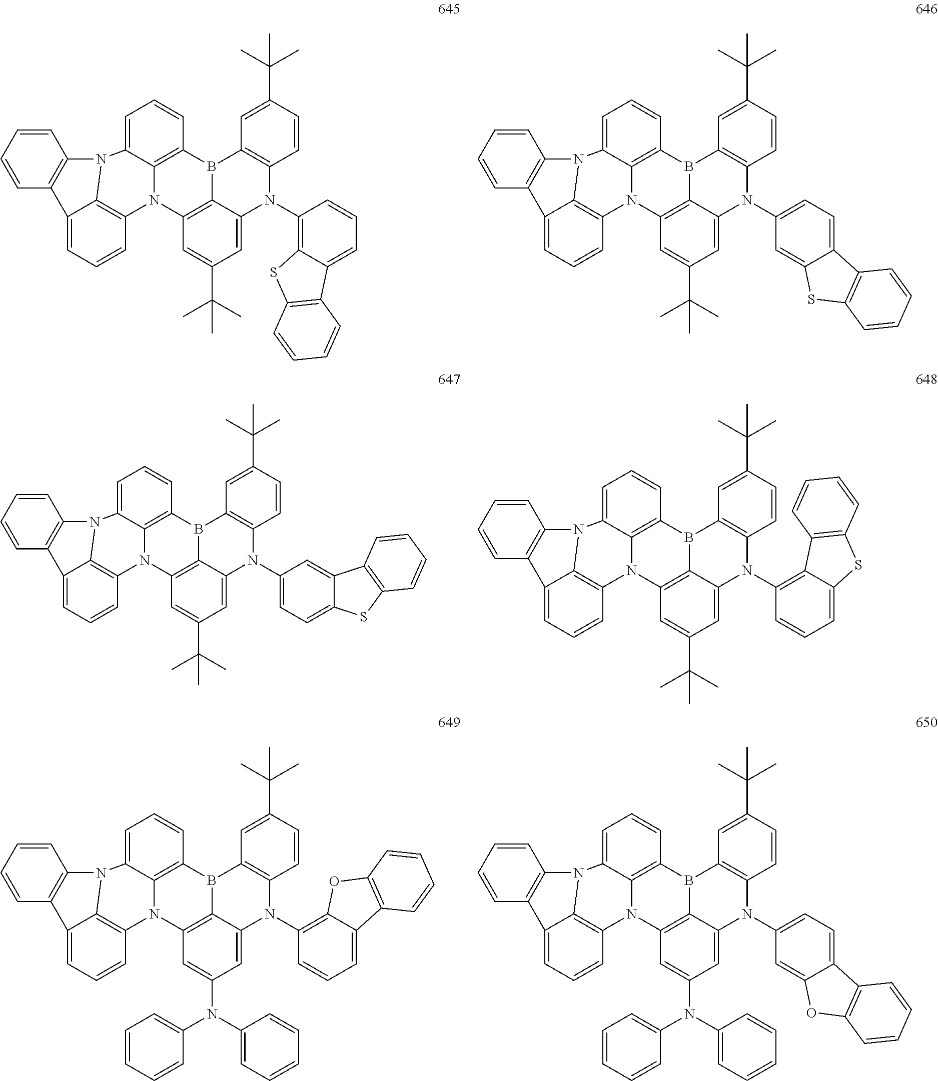

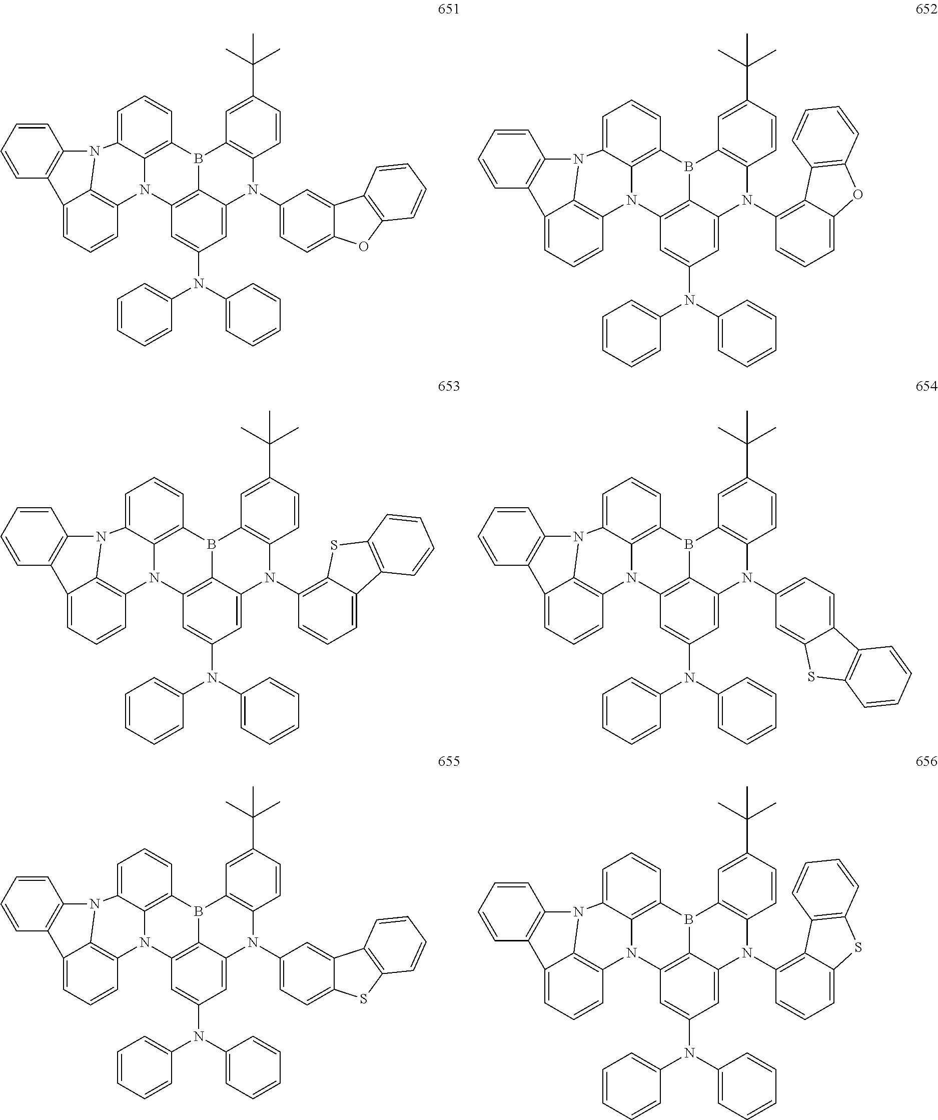

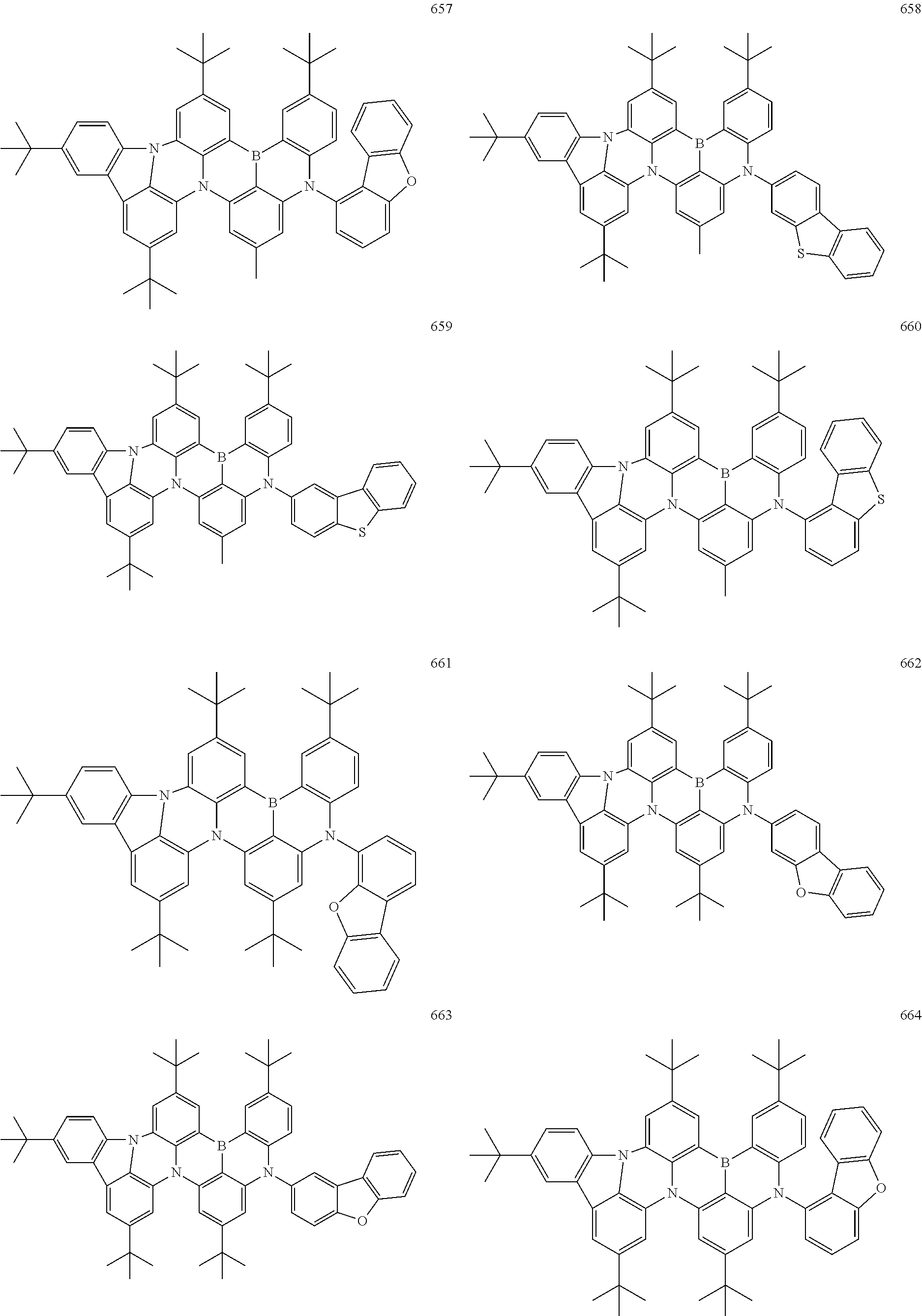

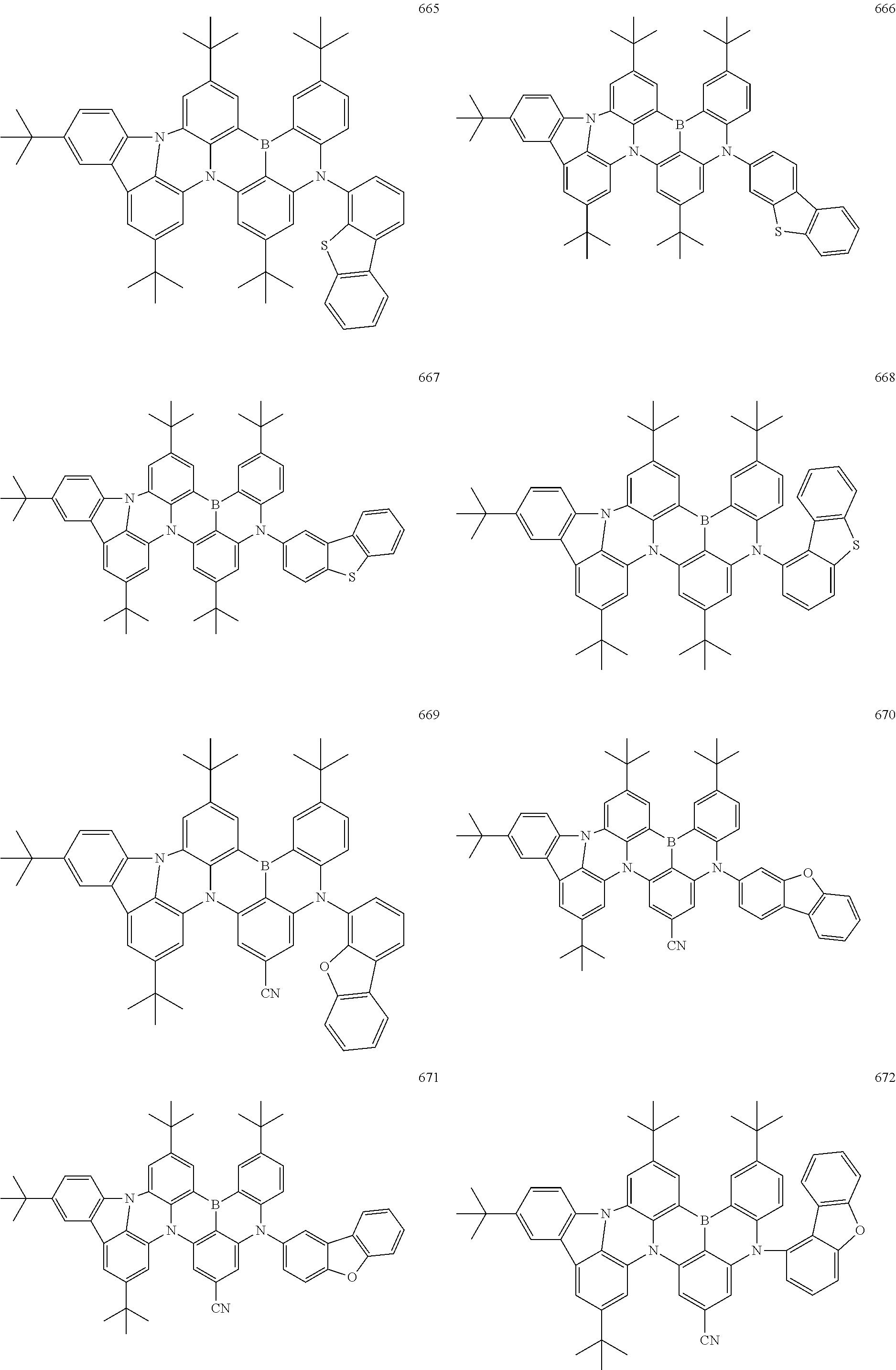

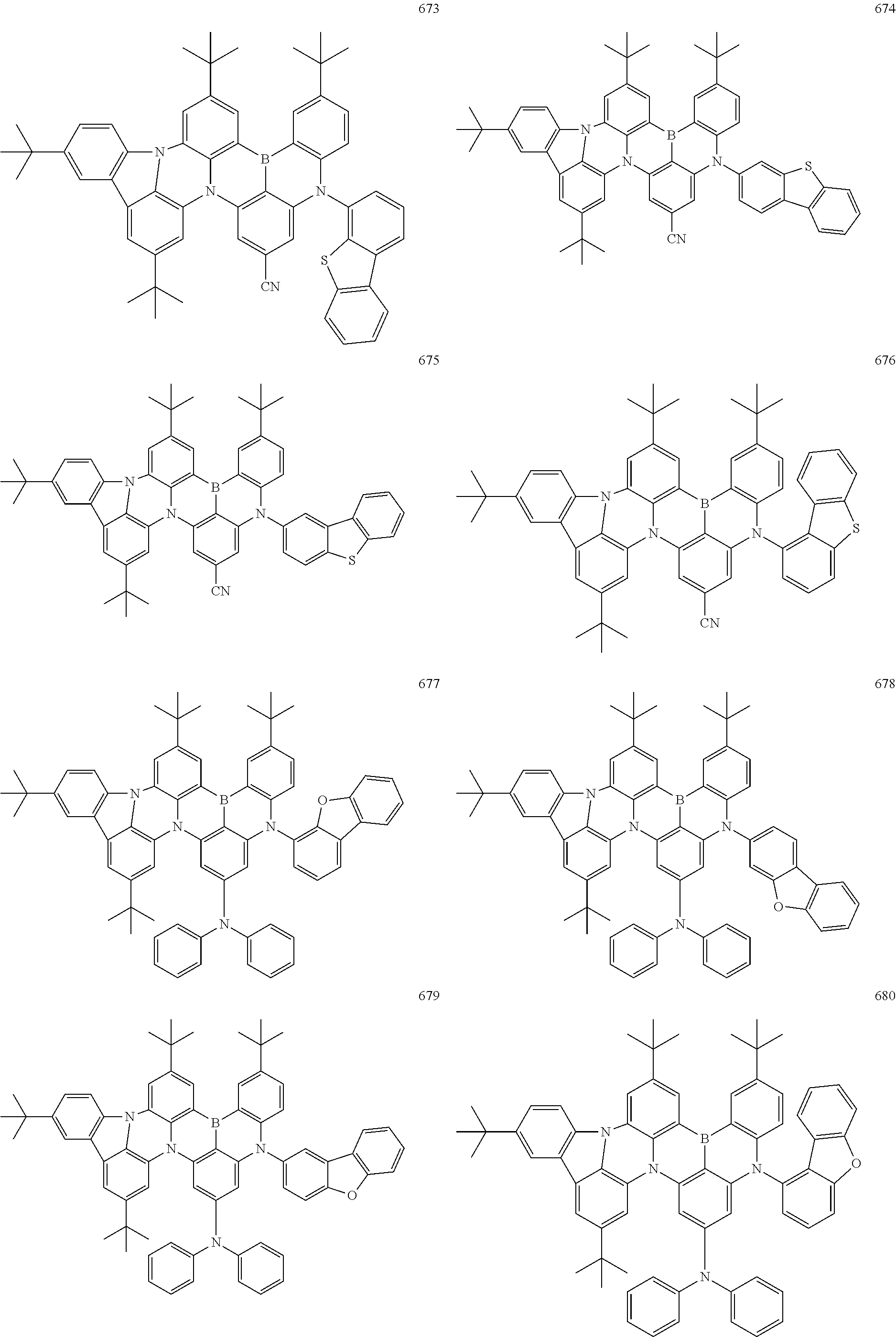

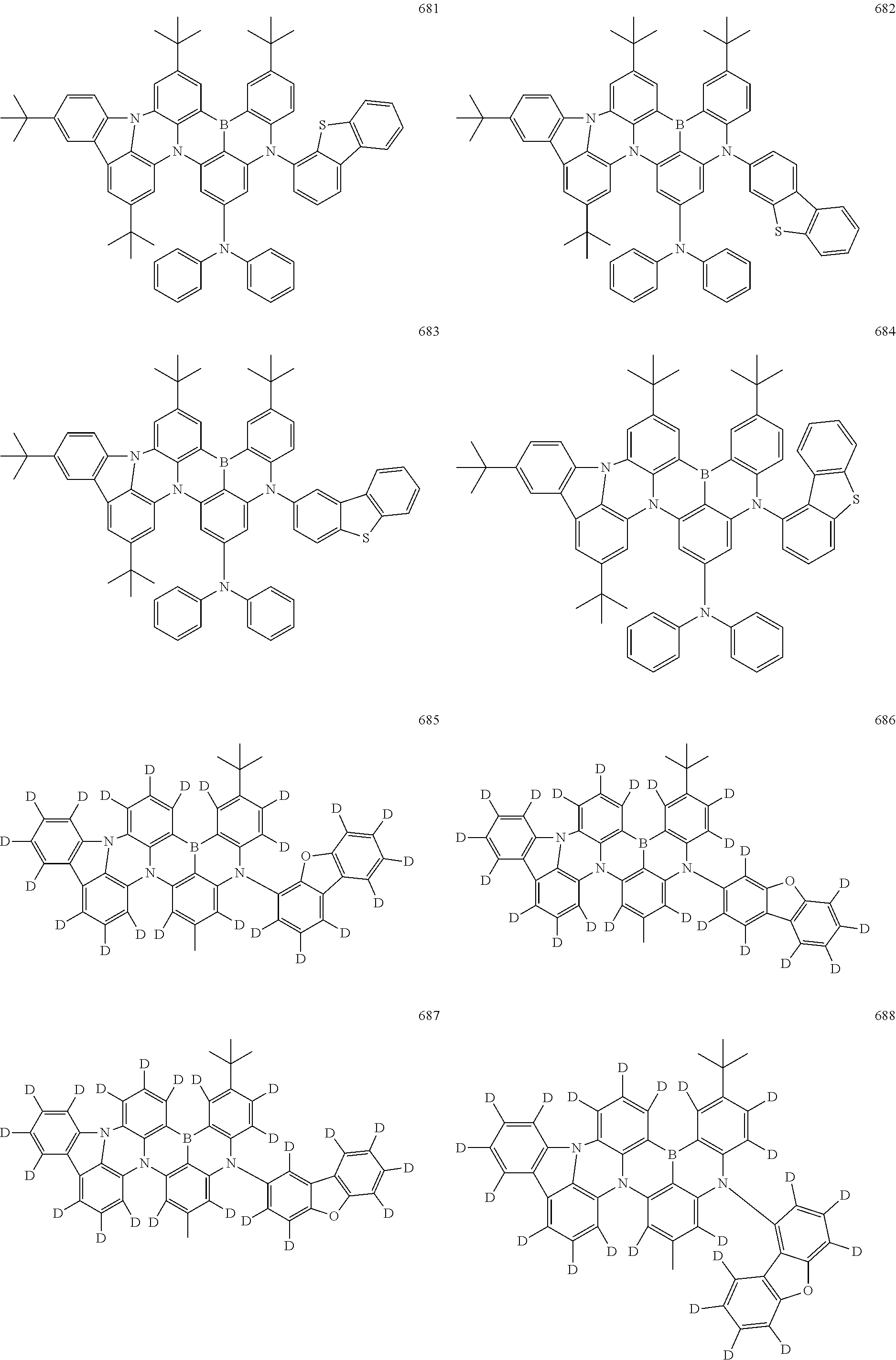

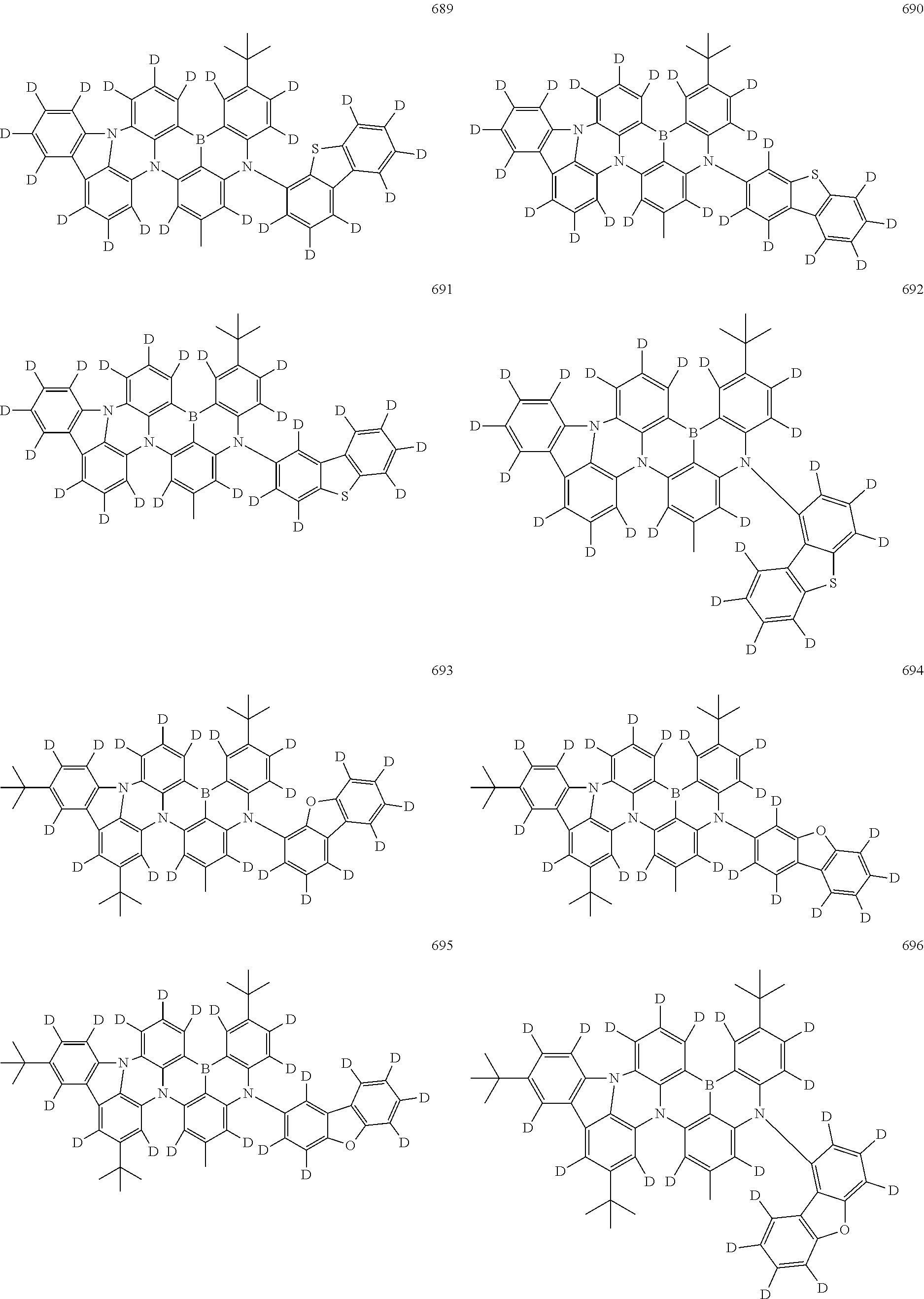

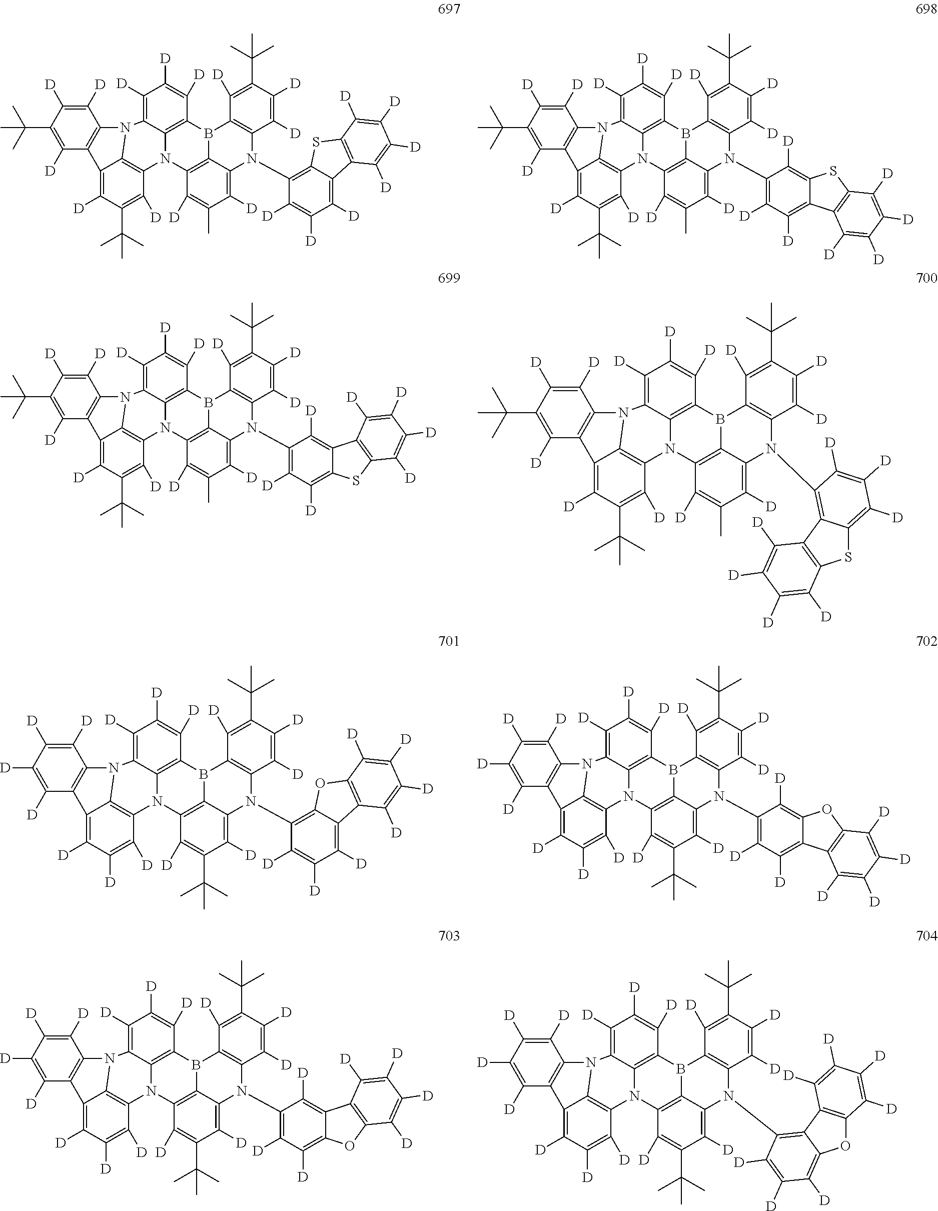

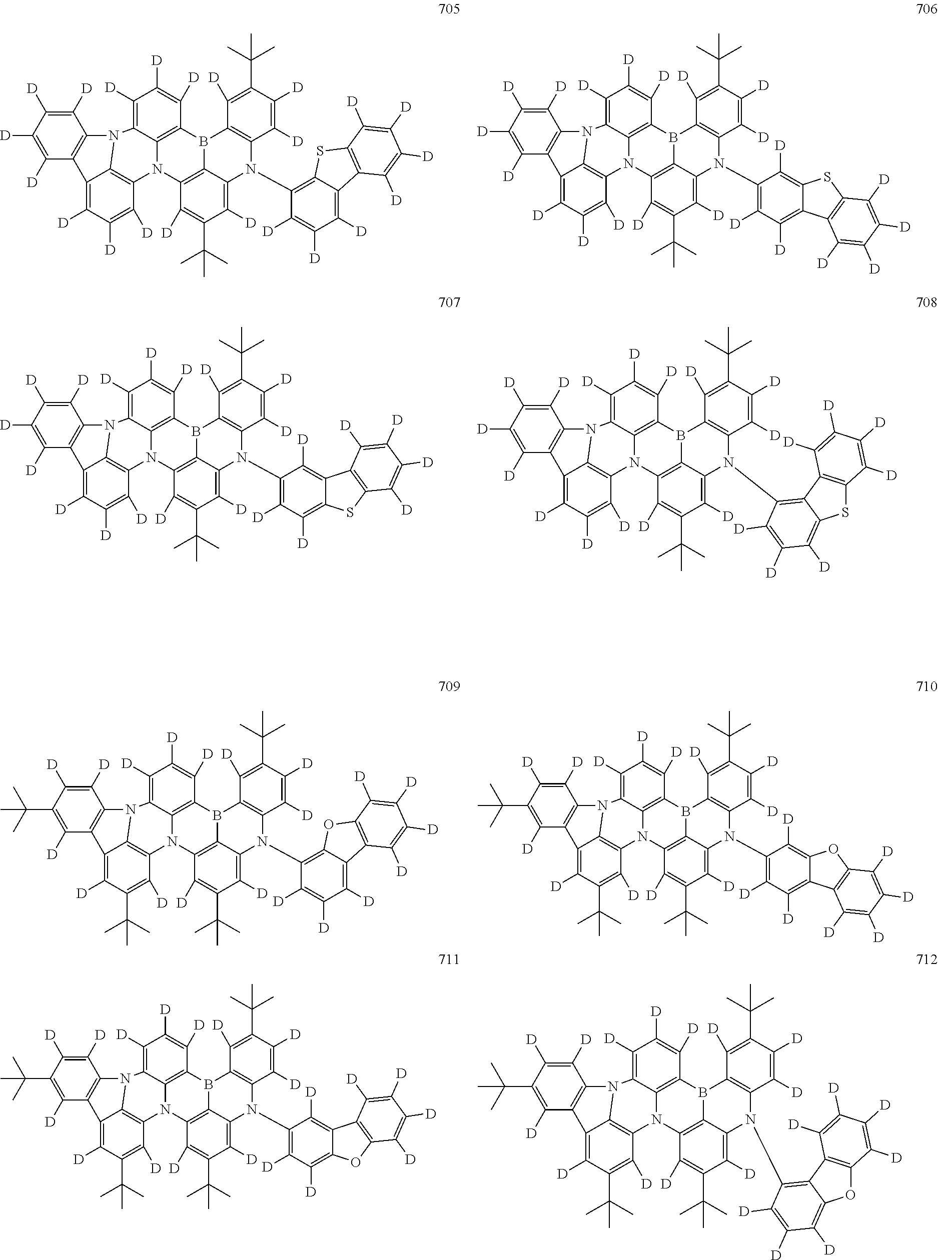

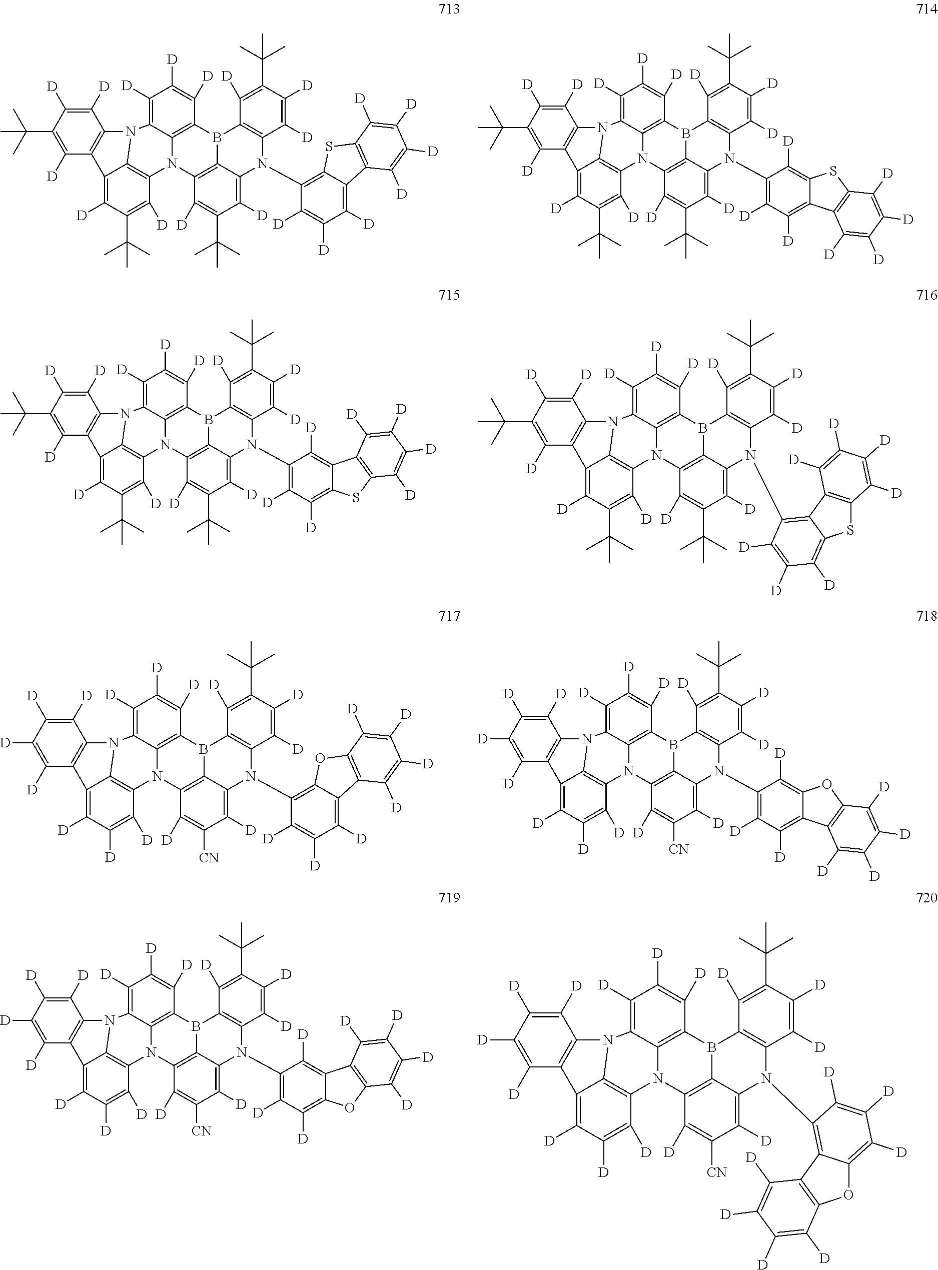

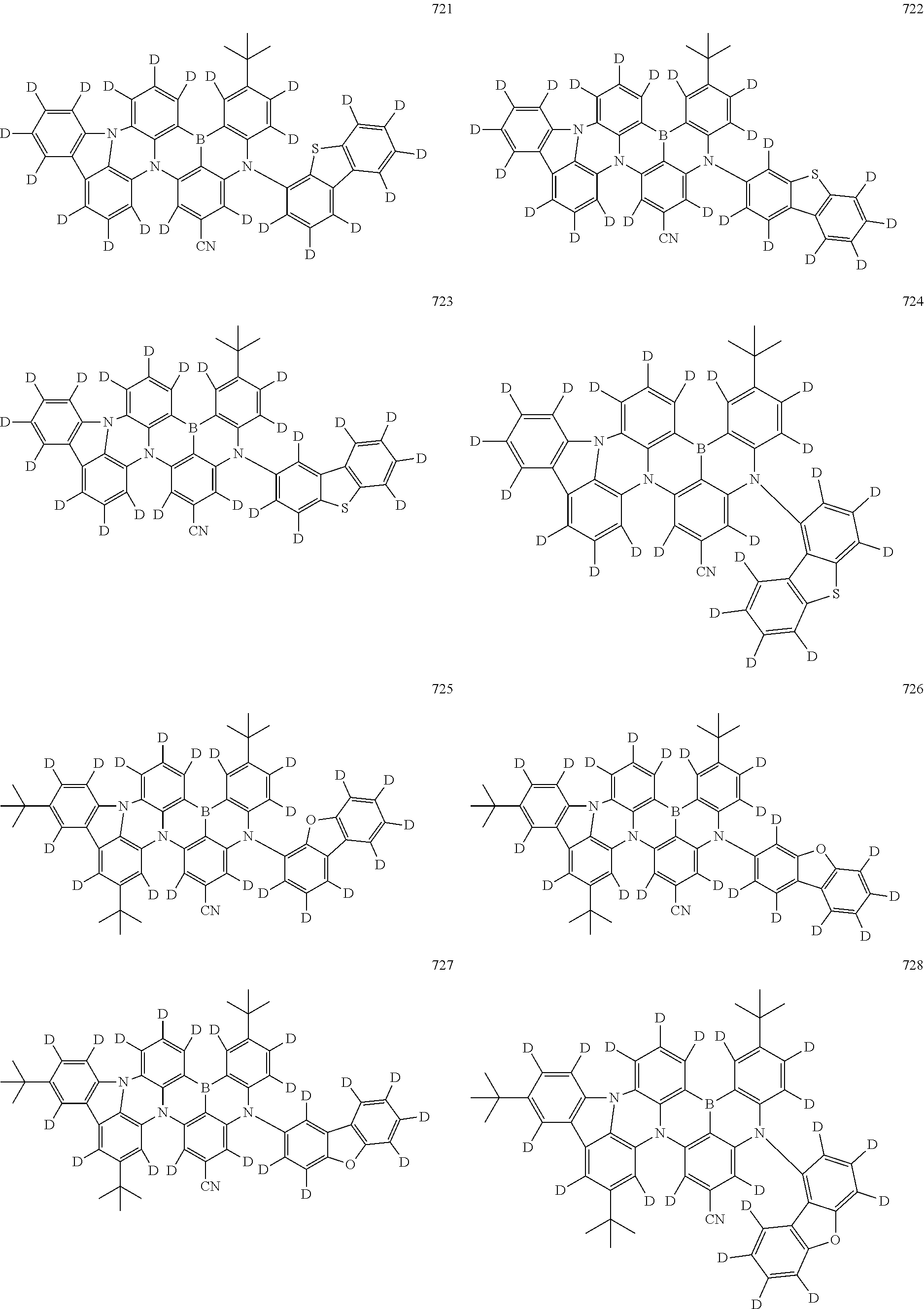

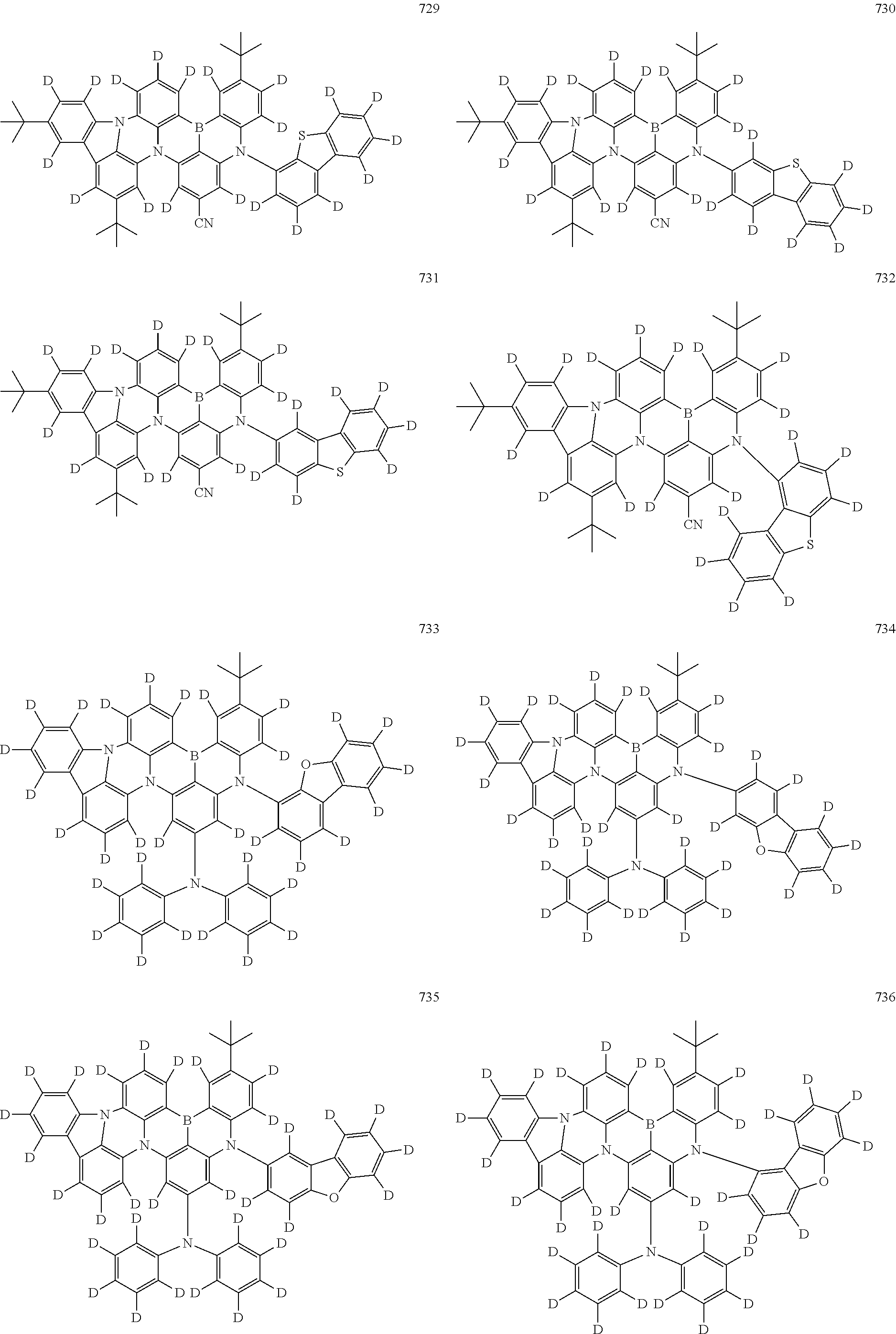

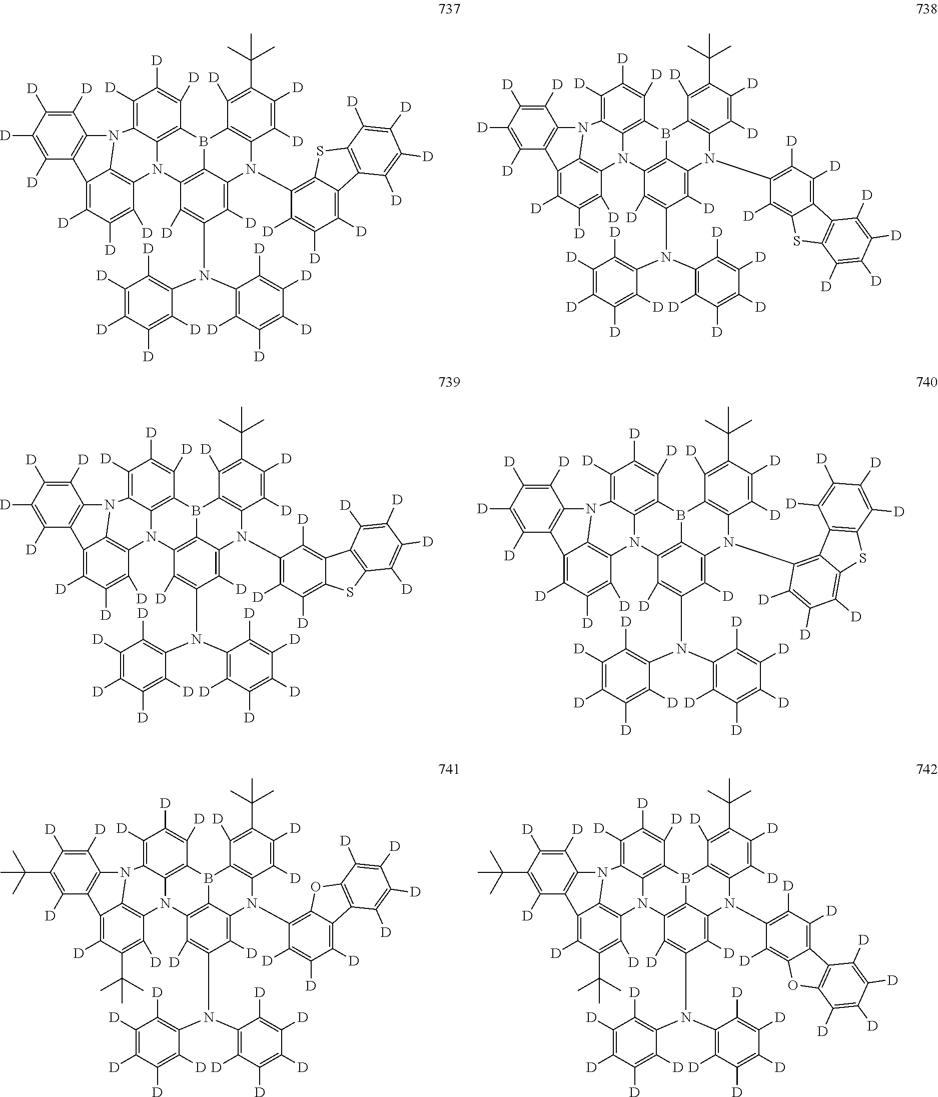

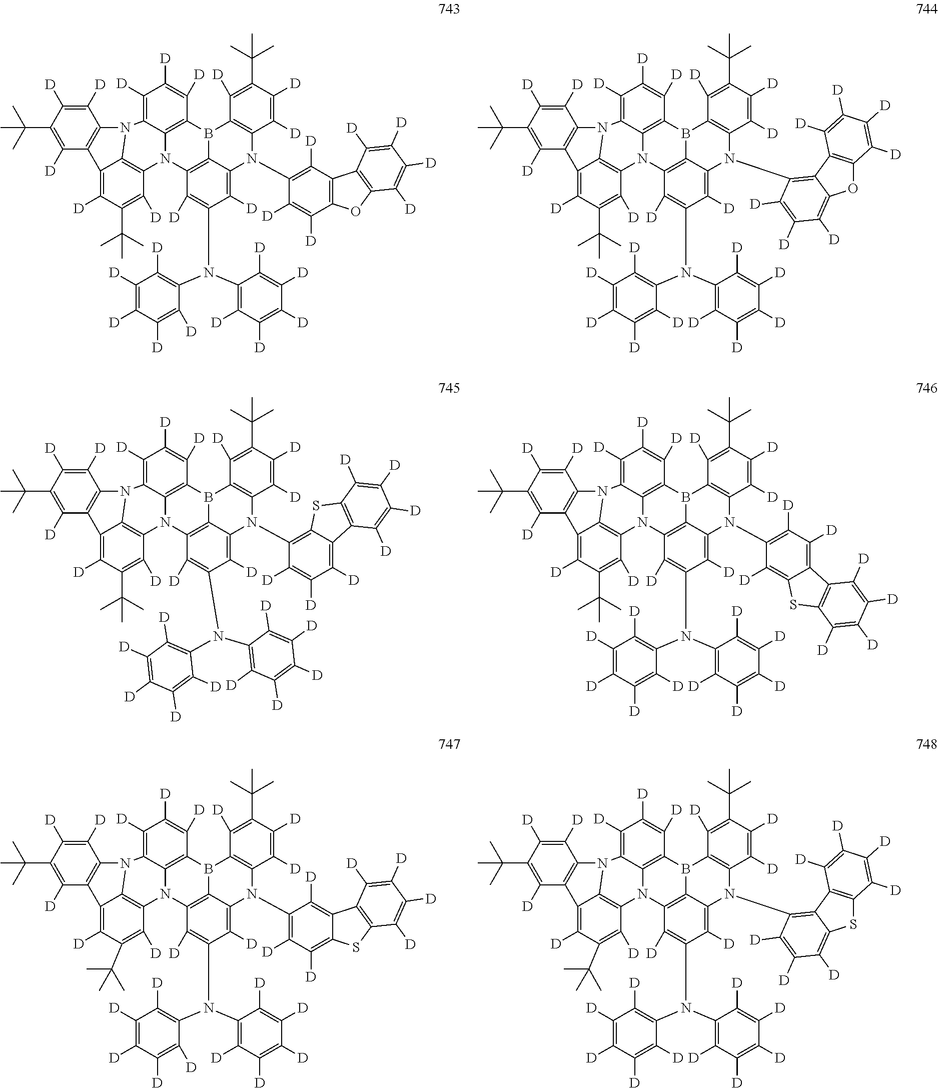

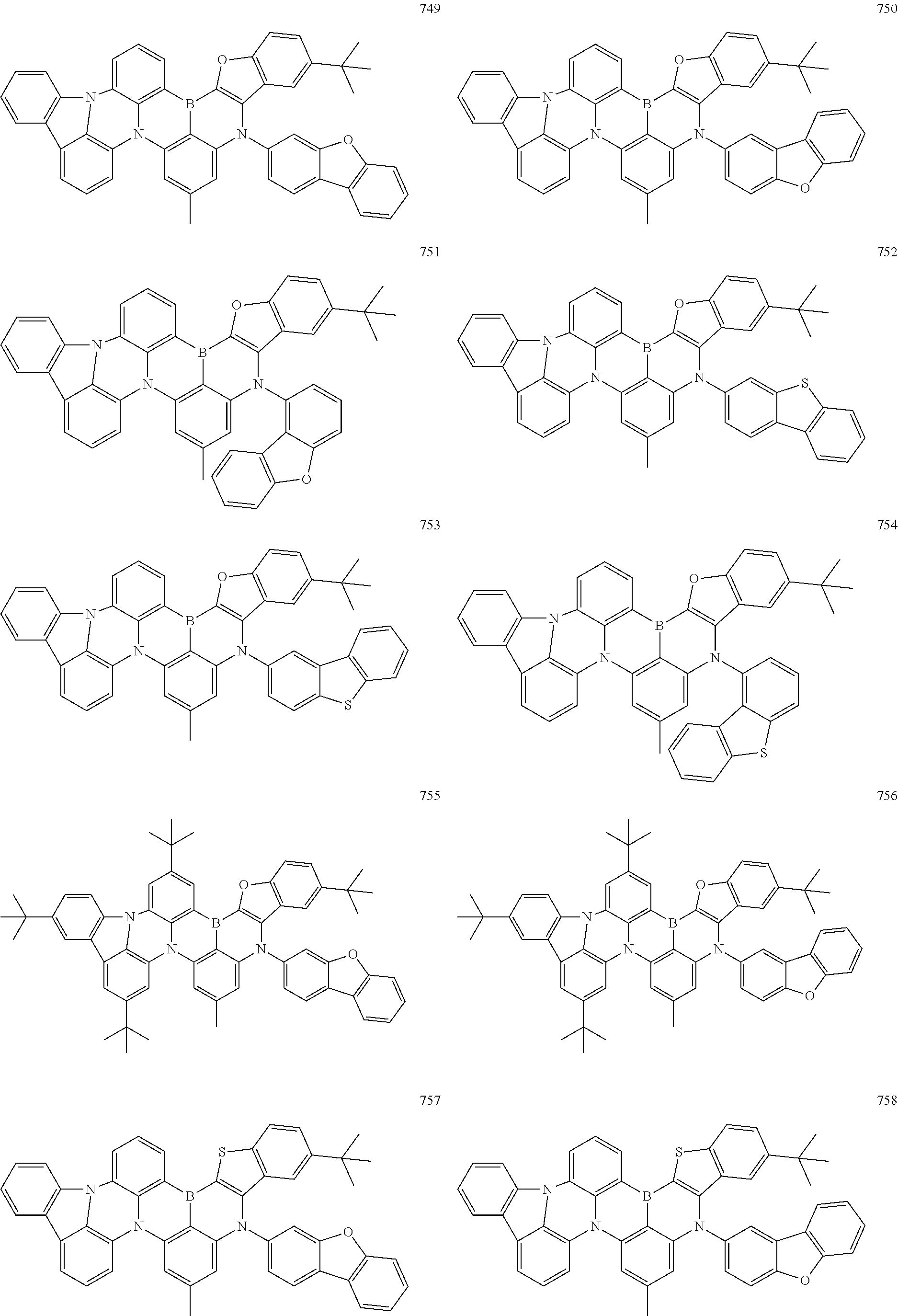

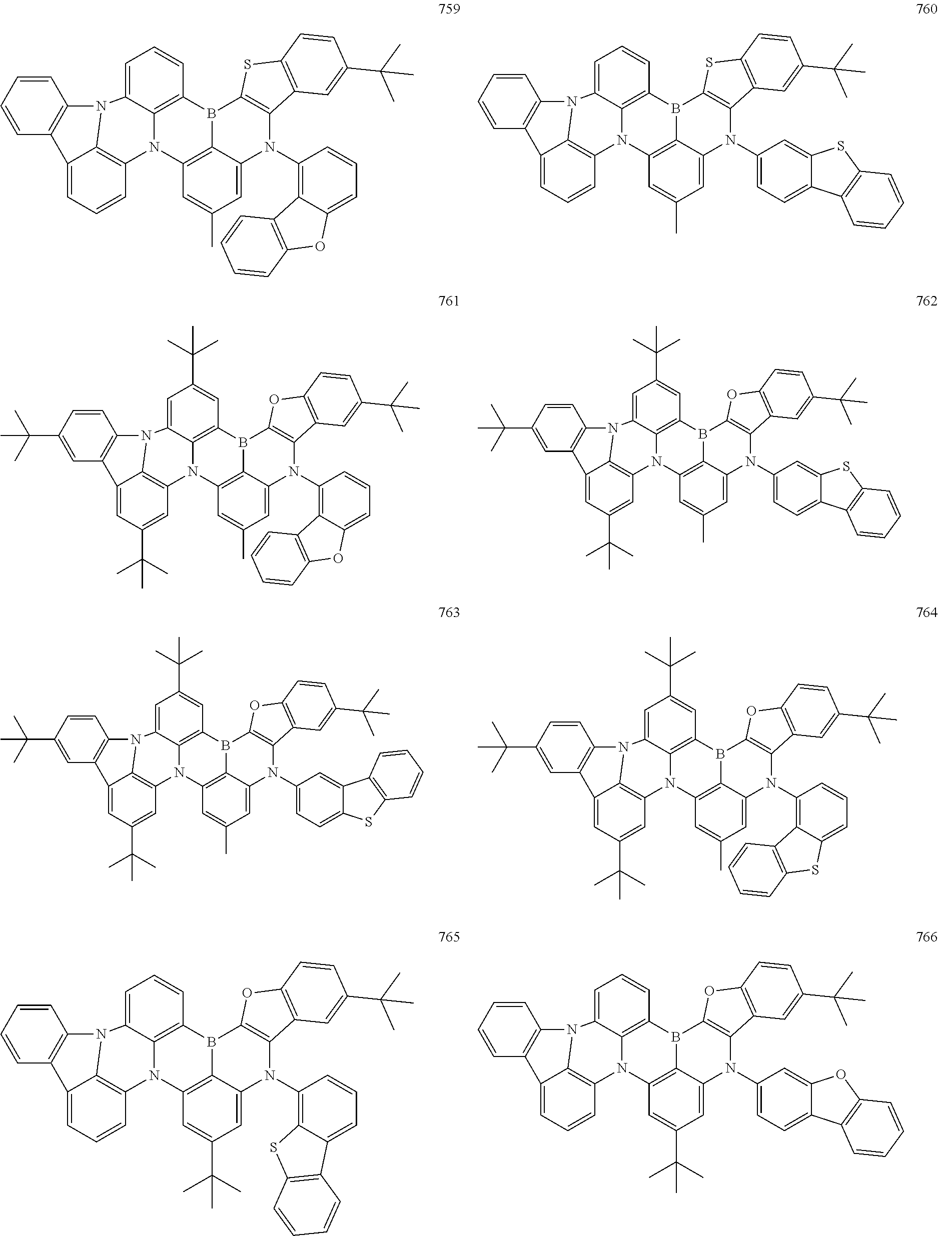

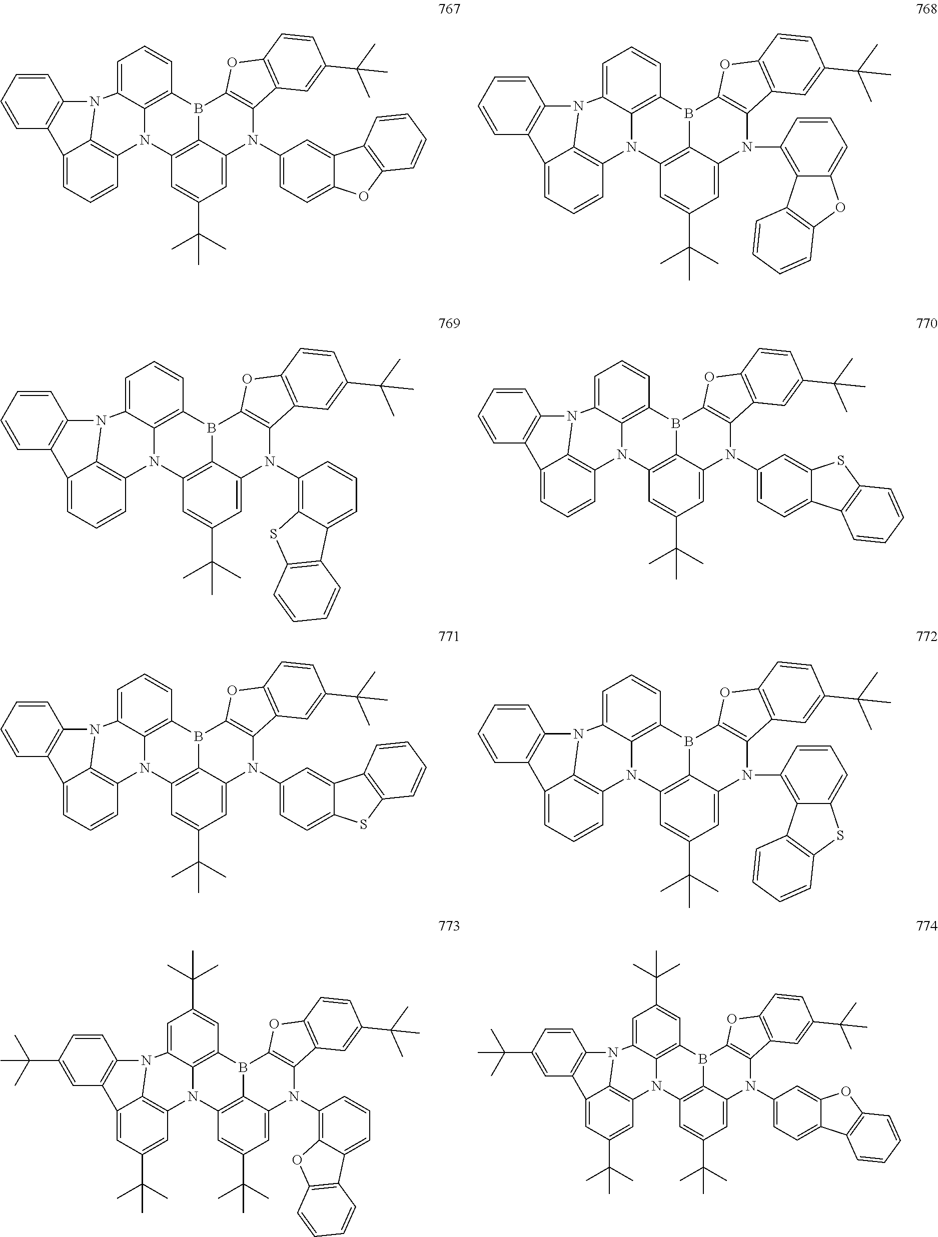

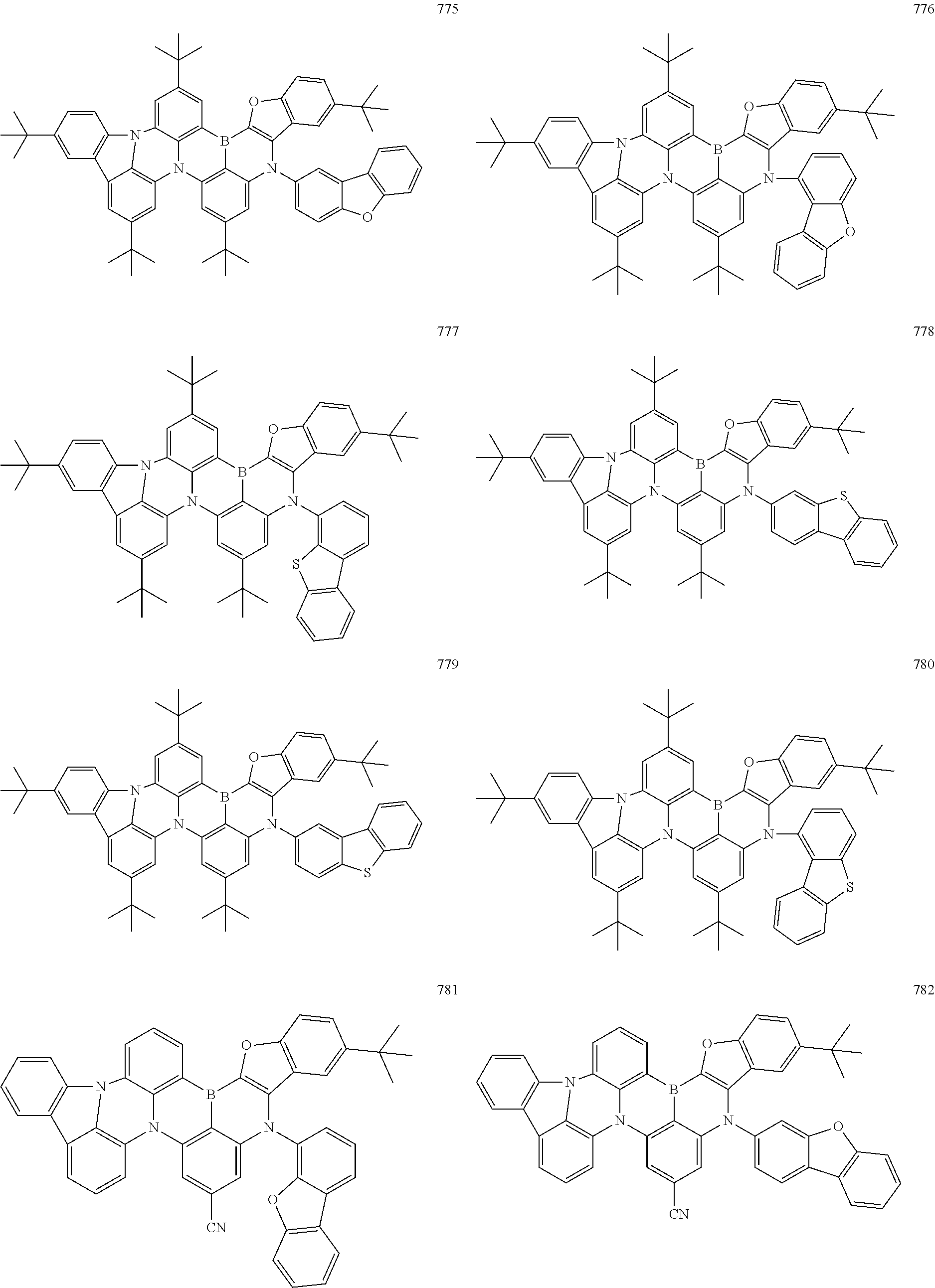

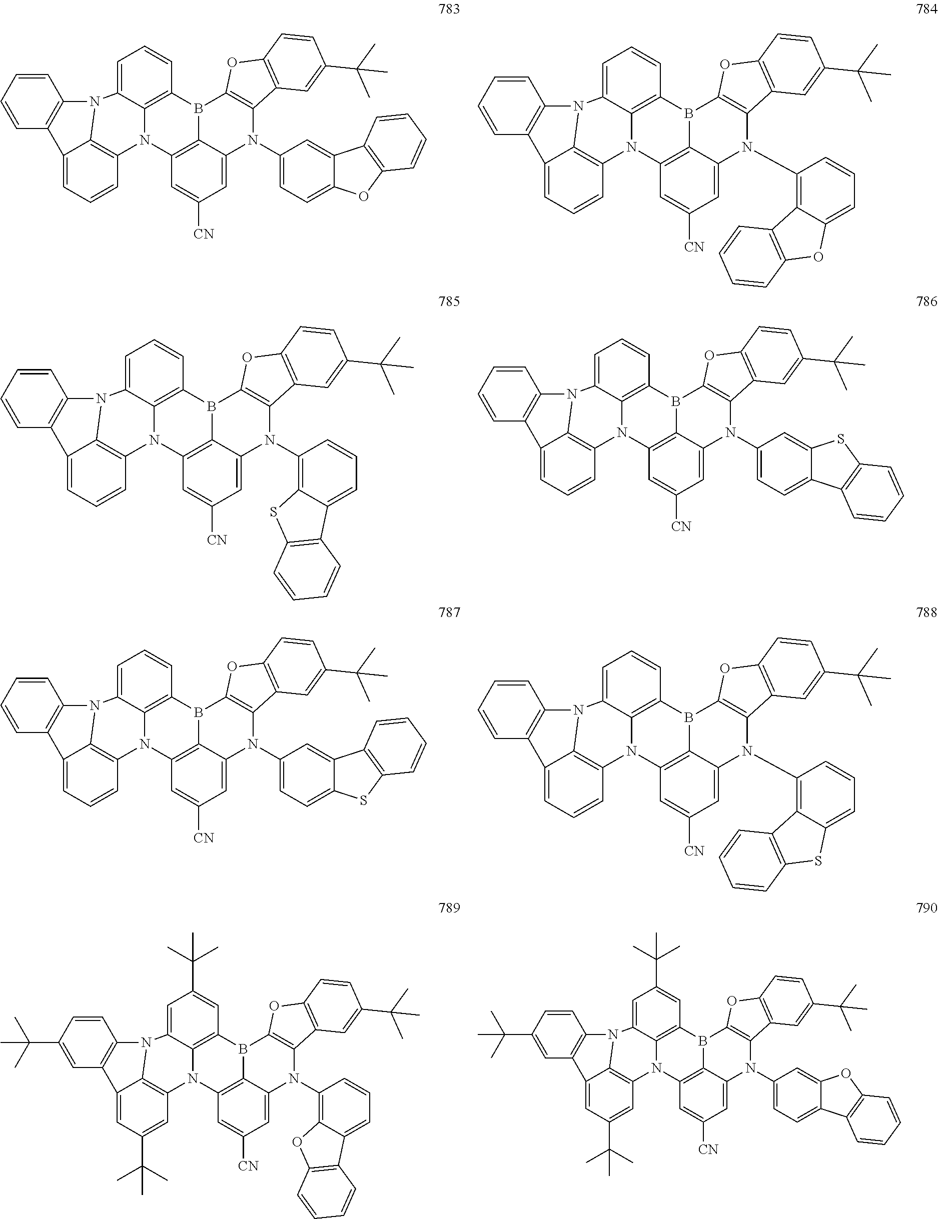

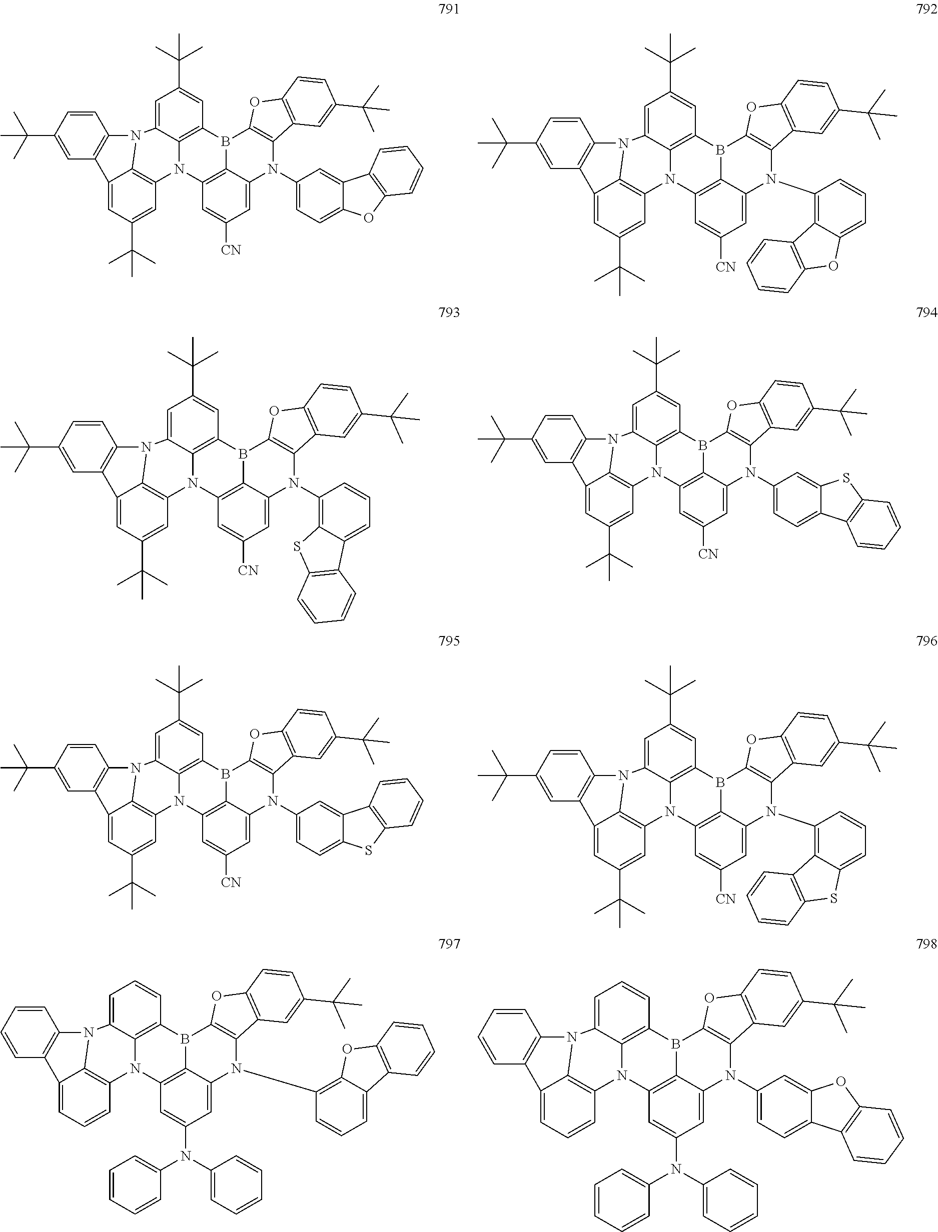

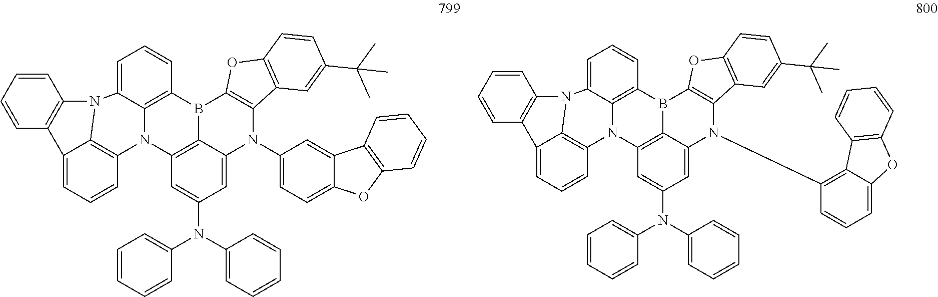 [SMILES: CC(C)(C)c1ccc2oc3c(c2c1)N(c1ccc2oc4ccccc4c2c1)c1cc(N(c2ccccc2)c2ccccc2)cc2c1B3c1cccc3c1N2c1cccc2c4ccccc4n-3c12 ; CC(C)(C)c1ccc2oc3c(c2c1)N(c1cccc2oc4ccccc4c12)c1cc(N(c2ccccc2)c2ccccc2)cc2c1B3c1cccc3c1N2c1cccc2c4ccccc4n-3c12]

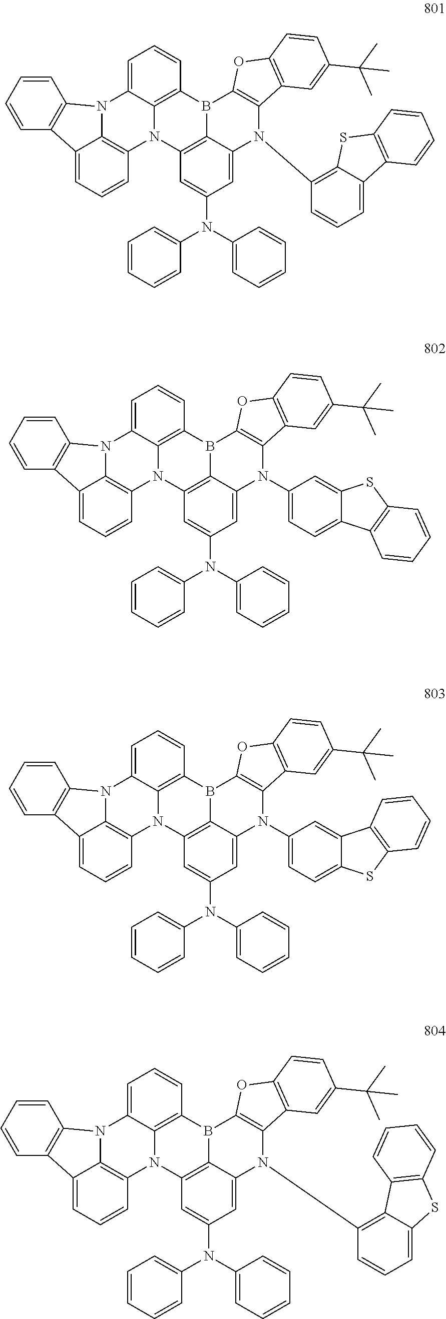 [SMILES: CC(C)(C)c1ccc2oc3c(c2c1)N(c1cccc2c1sc1ccccc12)c1cc(N(c2ccccc2)c2ccccc2)cc2c1B3c1cccc3c1N2c1cccc2c4ccccc4n-3c12 ; CC(C)(C)c1ccc2oc3c(c2c1)N(c1ccc2c(c1)sc1ccccc12)c1cc(N(c2ccccc2)c2ccccc2)cc2c1B3c1cccc3c1N2c1cccc2c4ccccc4n-3c12 ; CC(C)(C)c1ccc2oc3c(c2c1)N(c1ccc2sc4ccccc4c2c1)c1cc(N(c2ccccc2)c2ccccc2)cc2c1B3c1cccc3c1N2c1cccc2c4ccccc4n-3c12 ; CC(C)(C)c1ccc2oc3c(c2c1)N(c1cccc2sc4ccccc4c12)c1cc(N(c2ccccc2)c2ccccc2)cc2c1B3c1cccc3c1N2c1cccc2c4ccccc4n-3c12]

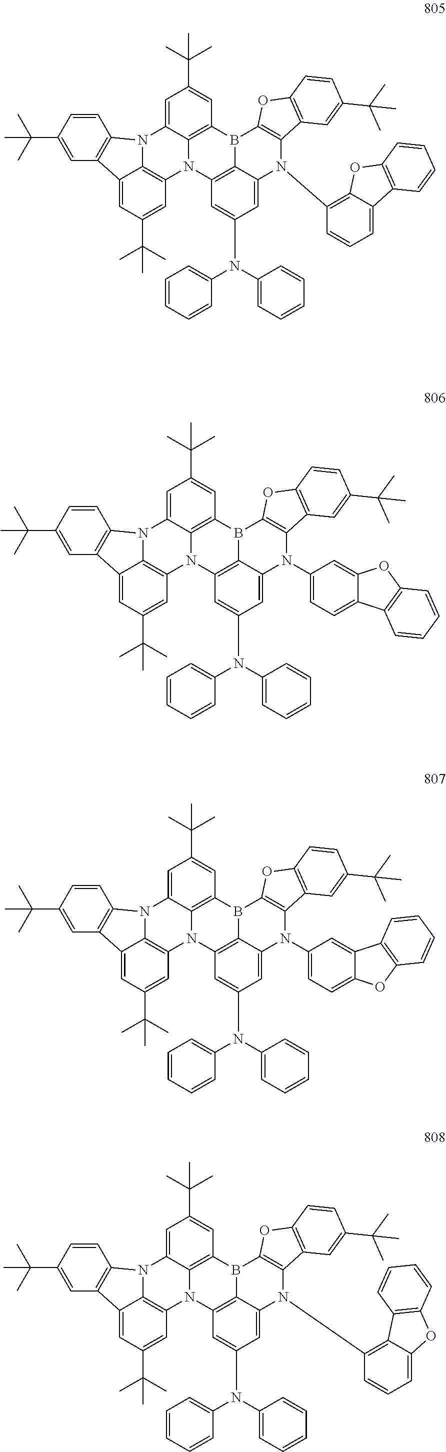

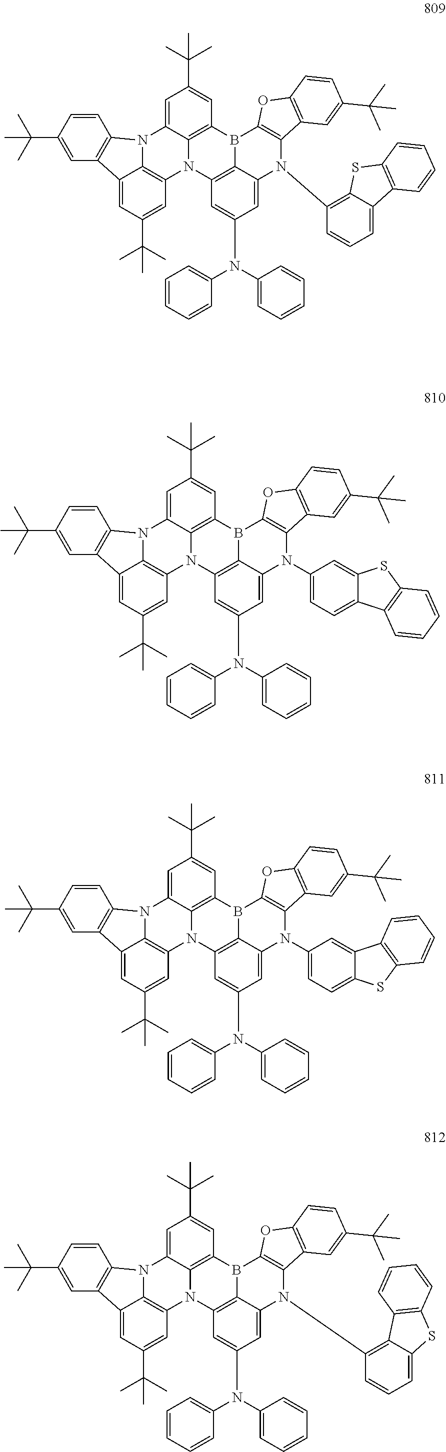

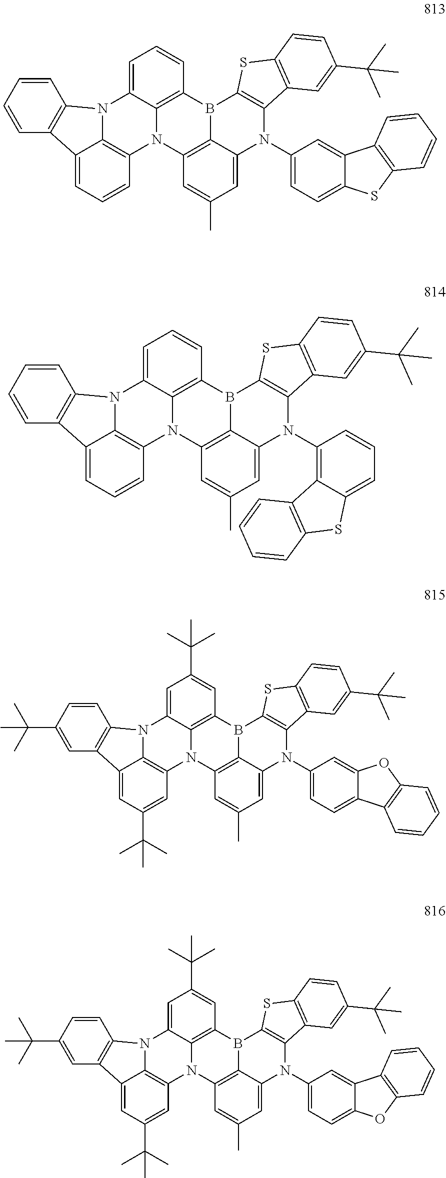

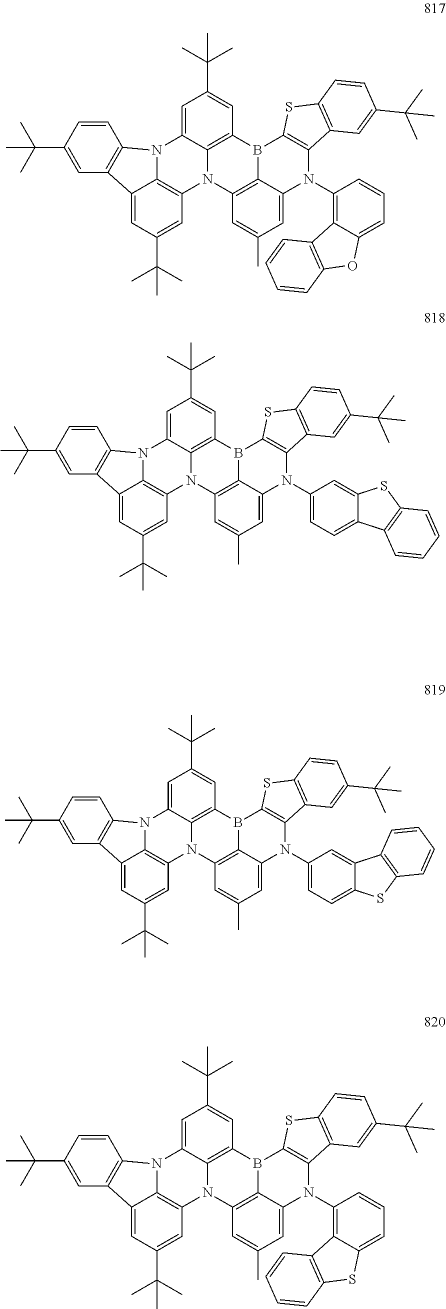

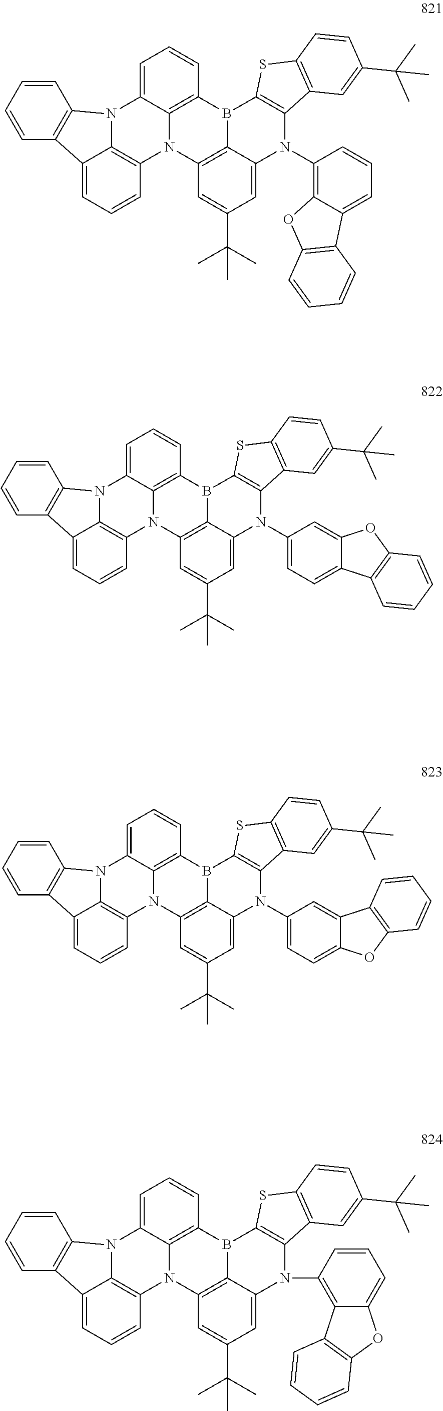 [SMILES: CC(C)(C)c1cc2c3c(c1)N1c4c(cccc4-n4c5ccccc5c5cccc1c54)B3c1sc3ccc(C(C)(C)C)cc3c1N2c1cccc2c1oc1ccccc12 ; CC(C)(C)c1cc2c3c(c1)N1c4c(cccc4-n4c5ccccc5c5cccc1c54)B3c1sc3ccc(C(C)(C)C)cc3c1N2c1ccc2c(c1)oc1ccccc12 ; CC(C)(C)c1cc2c3c(c1)N1c4c(cccc4-n4c5ccccc5c5cccc1c54)B3c1sc3ccc(C(C)(C)C)cc3c1N2c1ccc2oc3ccccc3c2c1 ; CC(C)(C)c1cc2c3c(c1)N1c4c(cccc4-n4c5ccccc5c5cccc1c54)B3c1sc3ccc(C(C)(C)C)cc3c1N2c1cccc2oc3ccccc3c12]

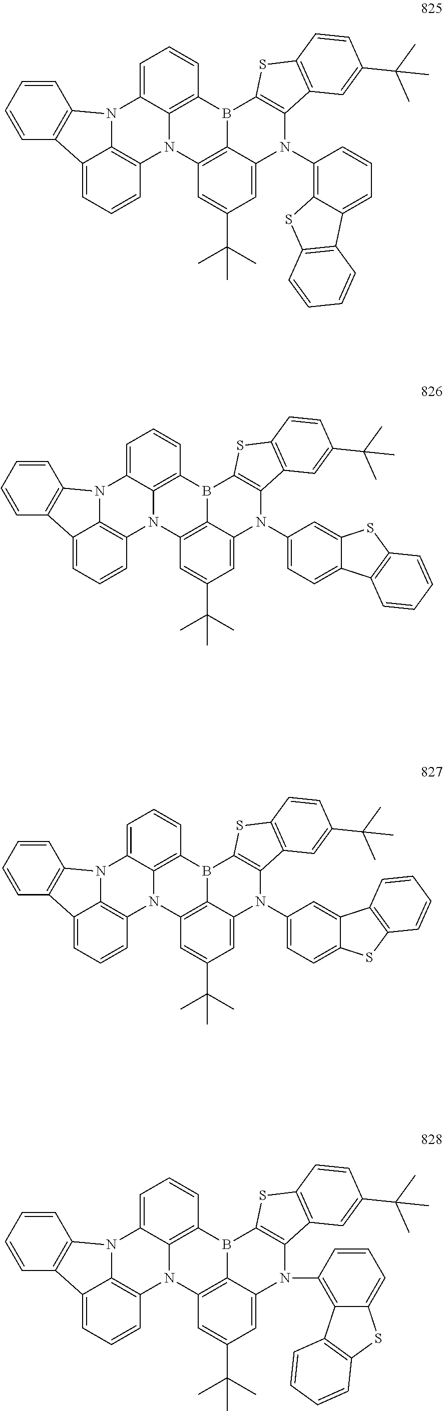 [SMILES: CC(C)(C)c1cc2c3c(c1)N1c4c(cccc4-n4c5ccccc5c5cccc1c54)B3c1sc3ccc(C(C)(C)C)cc3c1N2c1cccc2c1sc1ccccc12 ; CC(C)(C)c1cc2c3c(c1)N1c4c(cccc4-n4c5ccccc5c5cccc1c54)B3c1sc3ccc(C(C)(C)C)cc3c1N2c1ccc2c(c1)sc1ccccc12 ; CC(C)(C)c1cc2c3c(c1)N1c4c(cccc4-n4c5ccccc5c5cccc1c54)B3c1sc3ccc(C(C)(C)C)cc3c1N2c1ccc2sc3ccccc3c2c1 ; CC(C)(C)c1cc2c3c(c1)N1c4c(cccc4-n4c5ccccc5c5cccc1c54)B3c1sc3ccc(C(C)(C)C)cc3c1N2c1cccc2sc3ccccc3c12]

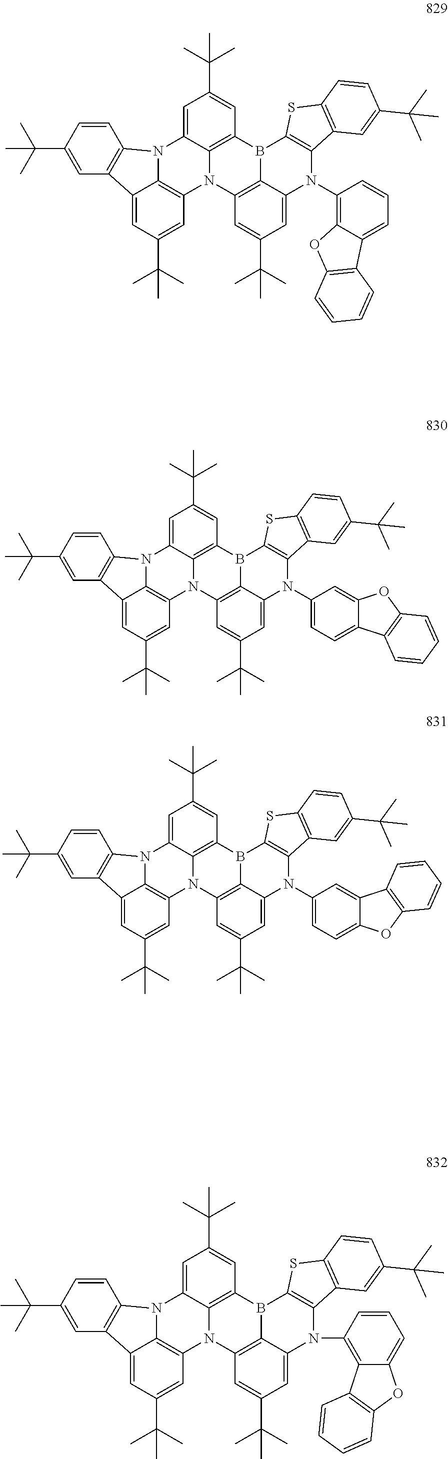

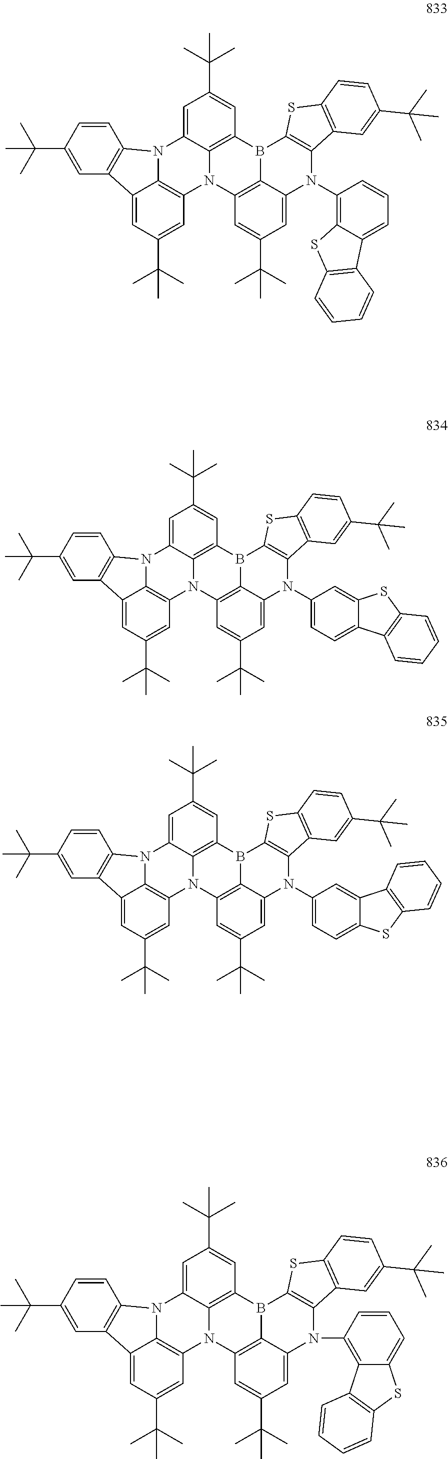

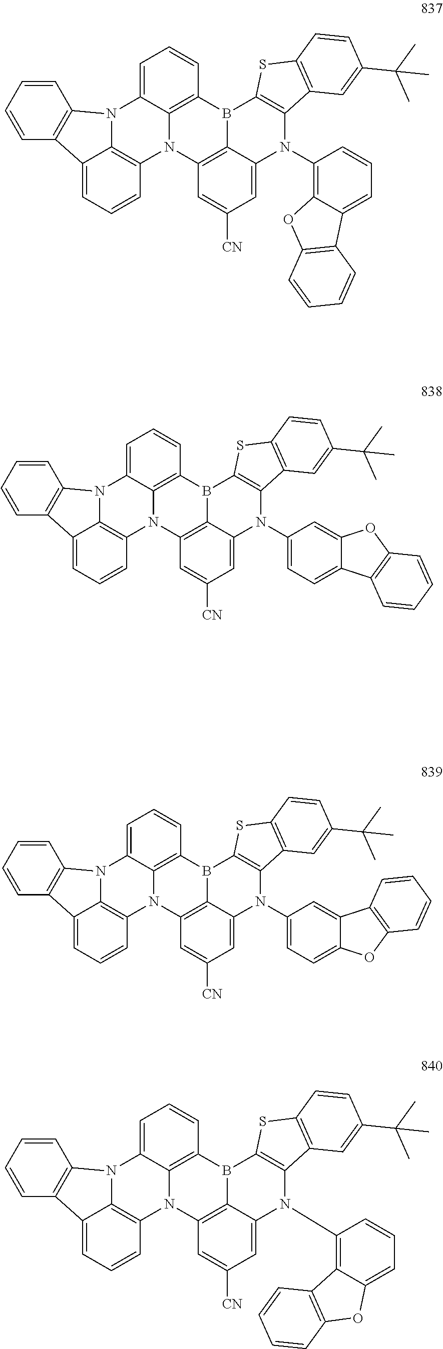 [SMILES: CC(C)(C)c1ccc2sc3c(c2c1)N(c1cccc2c1oc1ccccc12)c1cc(C#N)cc2c1B3c1cccc3c1N2c1cccc2c4ccccc4n-3c12 ; CC(C)(C)c1ccc2sc3c(c2c1)N(c1ccc2c(c1)oc1ccccc12)c1cc(C#N)cc2c1B3c1cccc3c1N2c1cccc2c4ccccc4n-3c12 ; CC(C)(C)c1ccc2sc3c(c2c1)N(c1ccc2oc4ccccc4c2c1)c1cc(C#N)cc2c1B3c1cccc3c1N2c1cccc2c4ccccc4n-3c12 ; CC(C)(C)c1ccc2sc3c(c2c1)N(c1cccc2oc4ccccc4c12)c1cc(C#N)cc2c1B3c1cccc3c1N2c1cccc2c4ccccc4n-3c12]

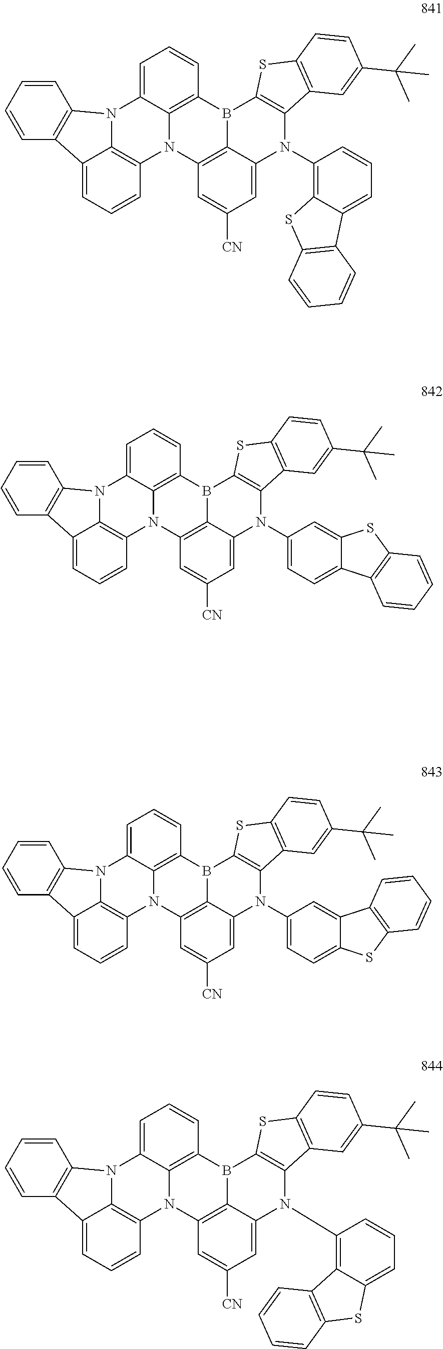 [SMILES: CC(C)(C)c1ccc2sc3c(c2c1)N(c1cccc2c1sc1ccccc12)c1cc(C#N)cc2c1B3c1cccc3c1N2c1cccc2c4ccccc4n-3c12 ; CC(C)(C)c1ccc2sc3c(c2c1)N(c1ccc2c(c1)sc1ccccc12)c1cc(C#N)cc2c1B3c1cccc3c1N2c1cccc2c4ccccc4n-3c12 ; CC(C)(C)c1ccc2sc3c(c2c1)N(c1ccc2sc4ccccc4c2c1)c1cc(C#N)cc2c1B3c1cccc3c1N2c1cccc2c4ccccc4n-3c12 ; CC(C)(C)c1ccc2sc3c(c2c1)N(c1cccc2sc4ccccc4c12)c1cc(C#N)cc2c1B3c1cccc3c1N2c1cccc2c4ccccc4n-3c12]

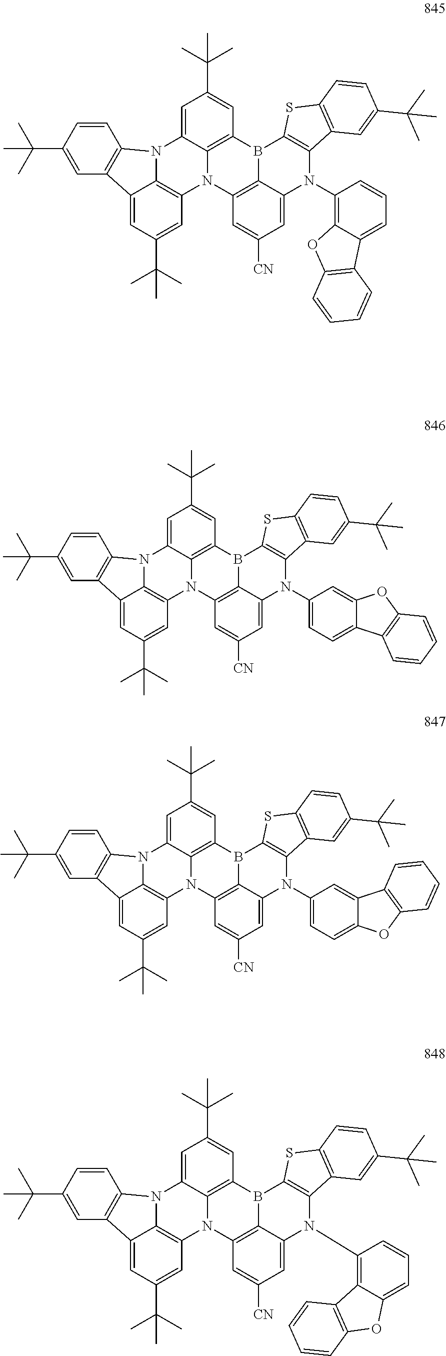

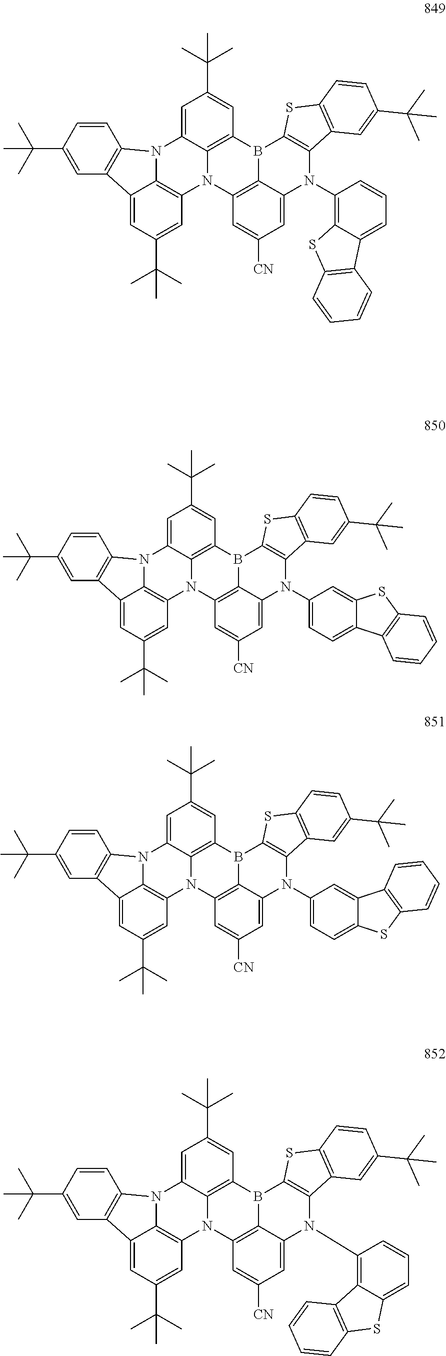

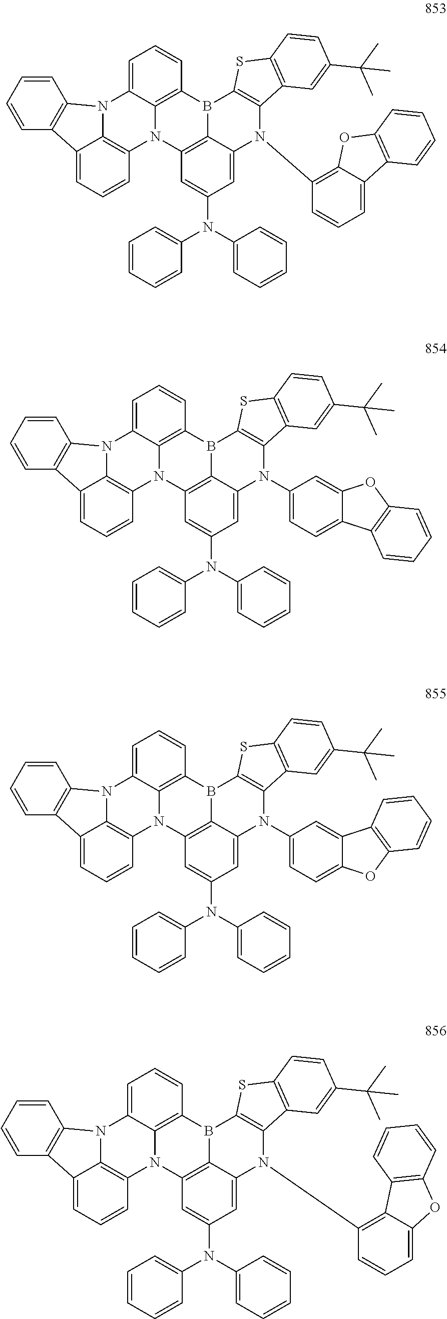 [SMILES: CC(C)(C)c1ccc2sc3c(c2c1)N(c1cccc2c1oc1ccccc12)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1ccc2c(c1)oc1ccccc12)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1ccc2oc4ccccc4c2c1)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1cccc2oc4ccccc4c12)c1cc(N(c2ccccc2)c2ccccc2)cc2c1B3c1cccc3c1N2c1cccc2c4ccccc4n-3c12]

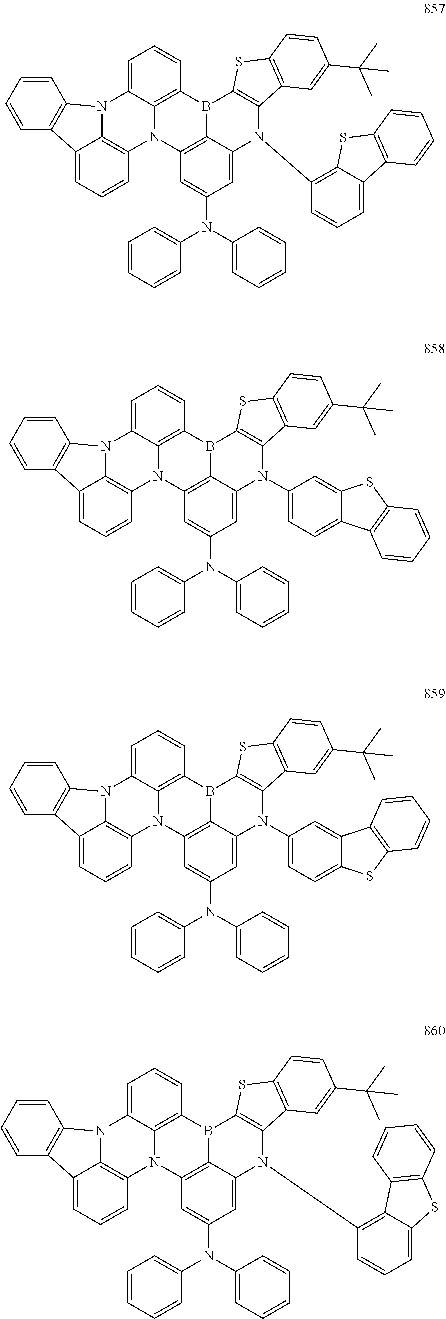 [SMILES: CC(C)(C)c1ccc2sc3c(c2c1)N(c1cccc2c1sc1ccccc12)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1ccc2c(c1)sc1ccccc12)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1ccc2sc4ccccc4c2c1)c1cc(N(c2ccccc2)c2ccccc2)cc2c1B3c1cccc3c1N2c1cccc2c4ccccc4n-3c12 ; CC(C)(C)c1ccc2sc3c(c2c1)N(c1cccc2sc4ccccc4c12)c1cc(N(c2ccccc2)c2ccccc2)cc2c1B3c1cccc3c1N2c1cccc2c4ccccc4n-3c12]

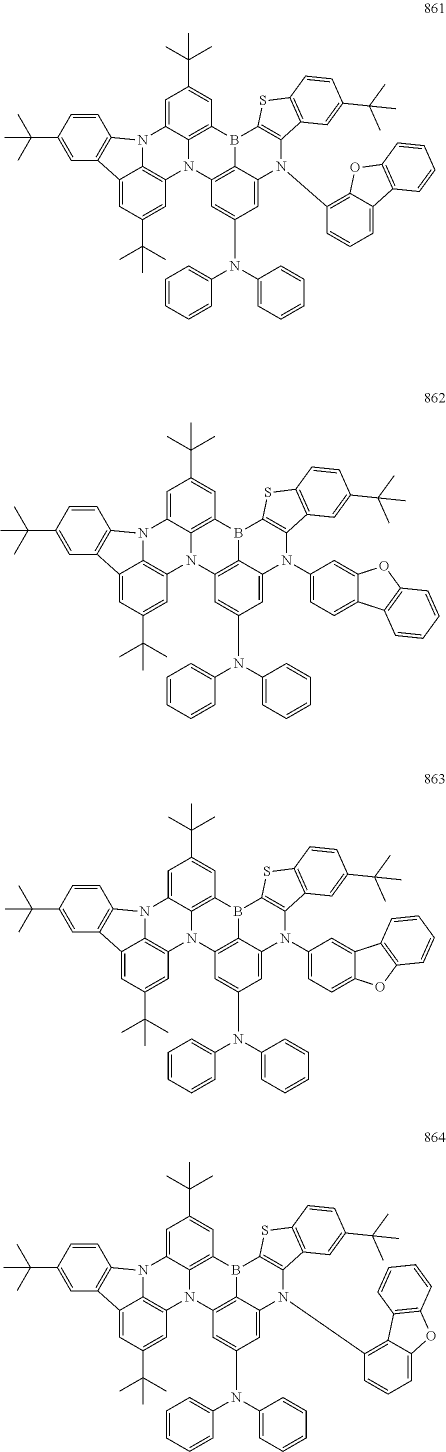

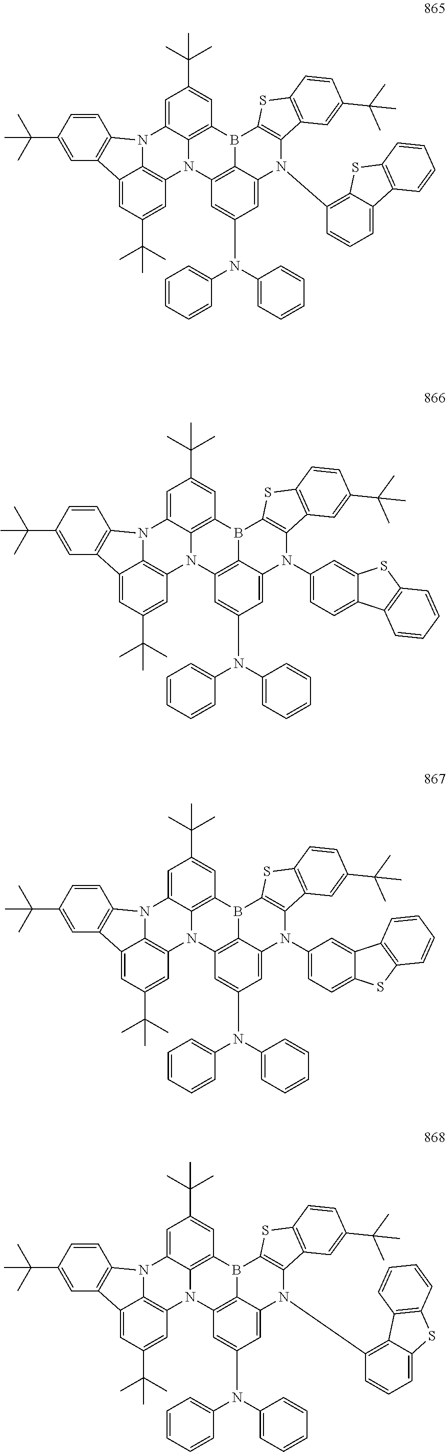

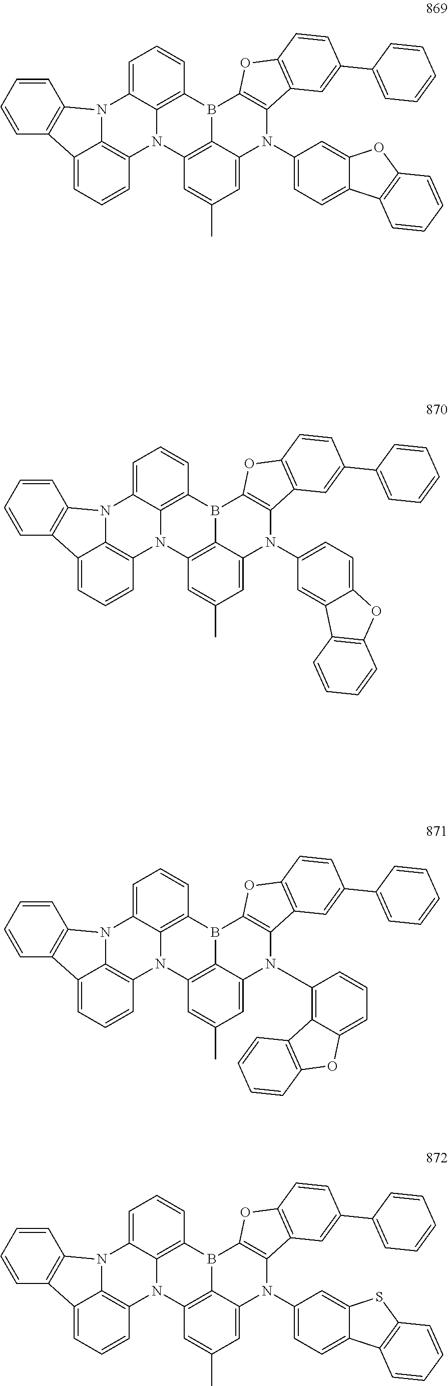 [SMILES: Cc1cc2c3c(c1)N1c4c(cccc4-n4c5ccccc5c5cccc1c54)B3c1oc3ccc(-c4ccccc4)cc3c1N2c1ccc2c(c1)oc1ccccc12 ; Cc1cc2c3c(c1)N1c4c(cccc4-n4c5ccccc5c5cccc1c54)B3c1oc3ccc(-c4ccccc4)cc3c1N2c1ccc2oc3ccccc3c2c1 ; Cc1cc2c3c(c1)N1c4c(cccc4-n4c5ccccc5c5cccc1c54)B3c1oc3ccc(-c4ccccc4)cc3c1N2c1cccc2oc3ccccc3c12 ; Cc1cc2c3c(c1)N1c4c(cccc4-n4c5ccccc5c5cccc1c54)B3c1oc3ccc(-c4ccccc4)cc3c1N2c1ccc2c(c1)sc1ccccc12]

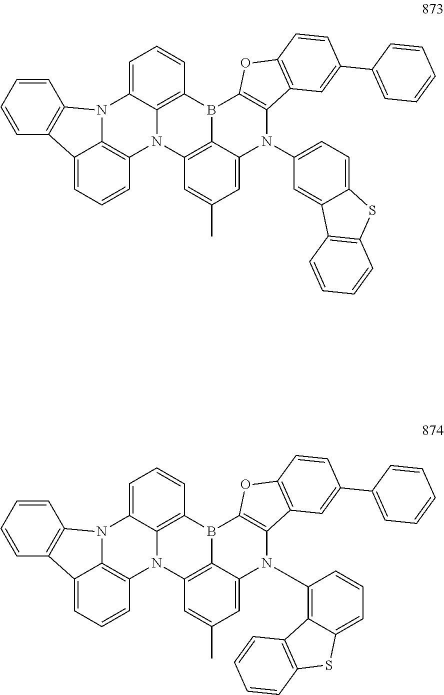 [SMILES: Cc1cc2c3c(c1)N1c4c(cccc4-n4c5ccccc5c5cccc1c54)B3c1oc3ccc(-c4ccccc4)cc3c1N2c1ccc2sc3ccccc3c2c1 ; Cc1cc2c3c(c1)N1c4c(cccc4-n4c5ccccc5c5cccc1c54)B3c1oc3ccc(-c4ccccc4)cc3c1N2c1cccc2sc3ccccc3c12]

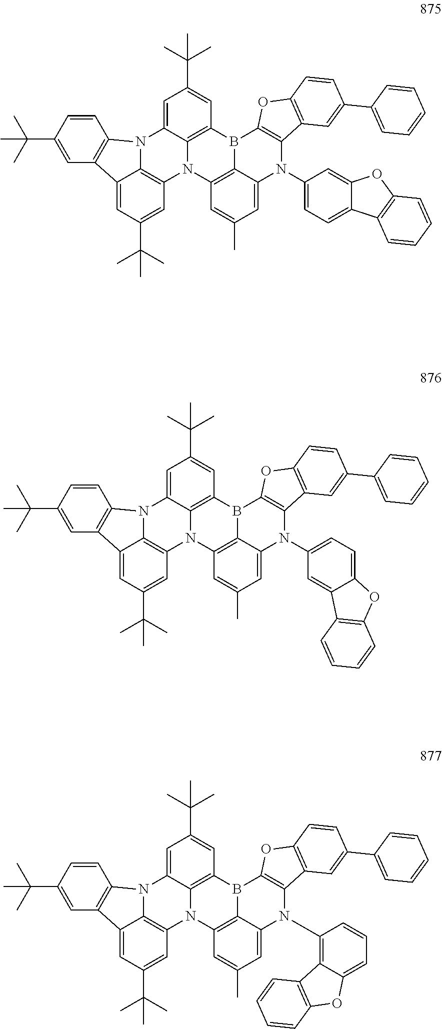 [SMILES: Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1ccc2c(c1)oc1ccccc12 ; Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1ccc2oc3ccccc3c2c1 ; Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1cccc2oc3ccccc3c12]

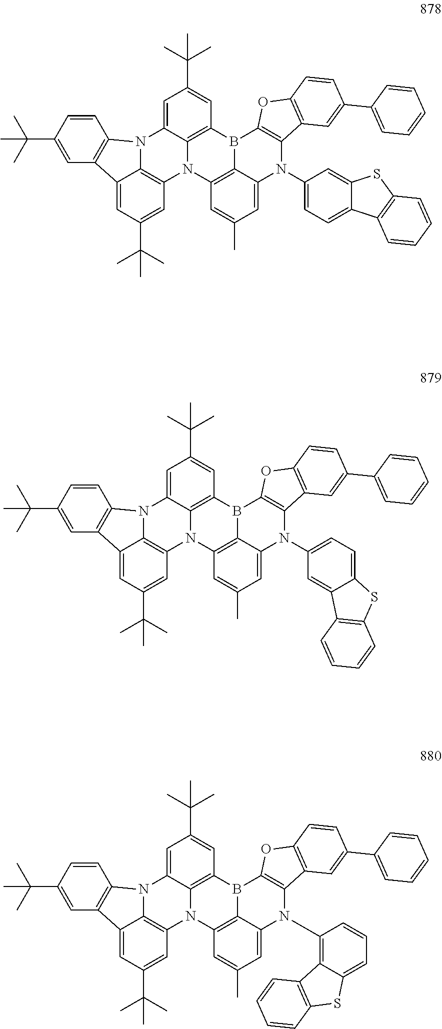 [SMILES: Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1ccc2c(c1)sc1ccccc12 ; Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1ccc2sc3ccccc3c2c1 ; Cc1cc2c3c(c1)N1c4c(cc(C(C)(C)C)cc4-n4c5ccc(C(C)(C)C)cc5c5cc(C(C)(C)C)cc1c54)B3c1oc3ccc(-c4ccccc4)cc3c1N2c1cccc2sc3ccccc3c12]

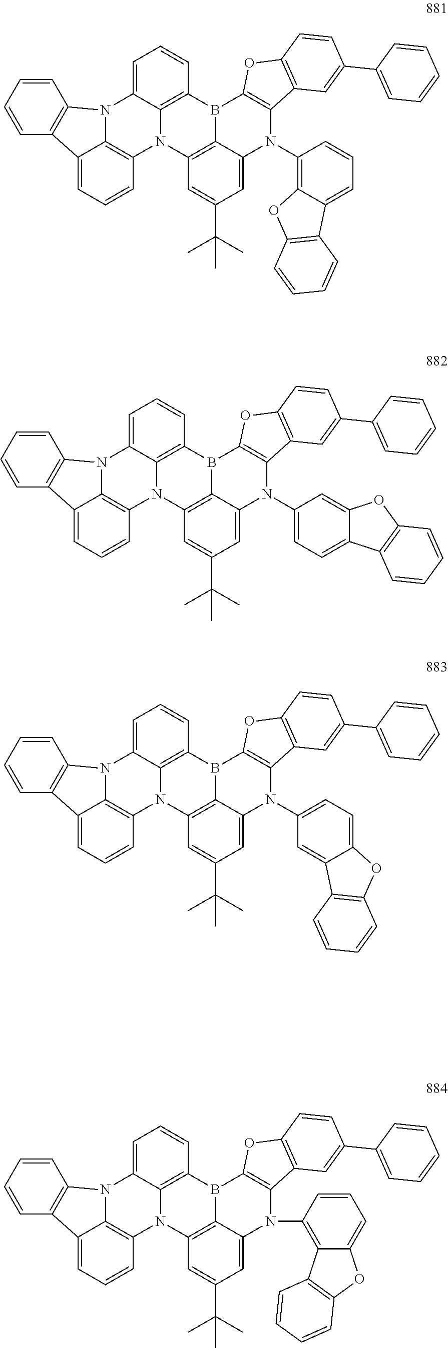 [SMILES: CC(C)(C)c1cc2c3c(c1)N1c4c(cccc4-n4c5ccccc5c5cccc1c54)B3c1oc3ccc(-c4ccccc4)cc3c1N2c1cccc2c1oc1ccccc12 ; CC(C)(C)c1cc2c3c(c1)N1c4c(cccc4-n4c5ccccc5c5cccc1c54)B3c1oc3ccc(-c4ccccc4)cc3c1N2c1ccc2c(c1)oc1ccccc12 ; CC(C)(C)c1cc2c3c(c1)N1c4c(cccc4-n4c5ccccc5c5cccc1c54)B3c1oc3ccc(-c4ccccc4)cc3c1N2c1ccc2oc3ccccc3c2c1 ; CC(C)(C)c1cc2c3c(c1)N1c4c(cccc4-n4c5ccccc5c5cccc1c54)B3c1oc3ccc(-c4ccccc4)cc3c1N2c1cccc2oc3ccccc3c12]

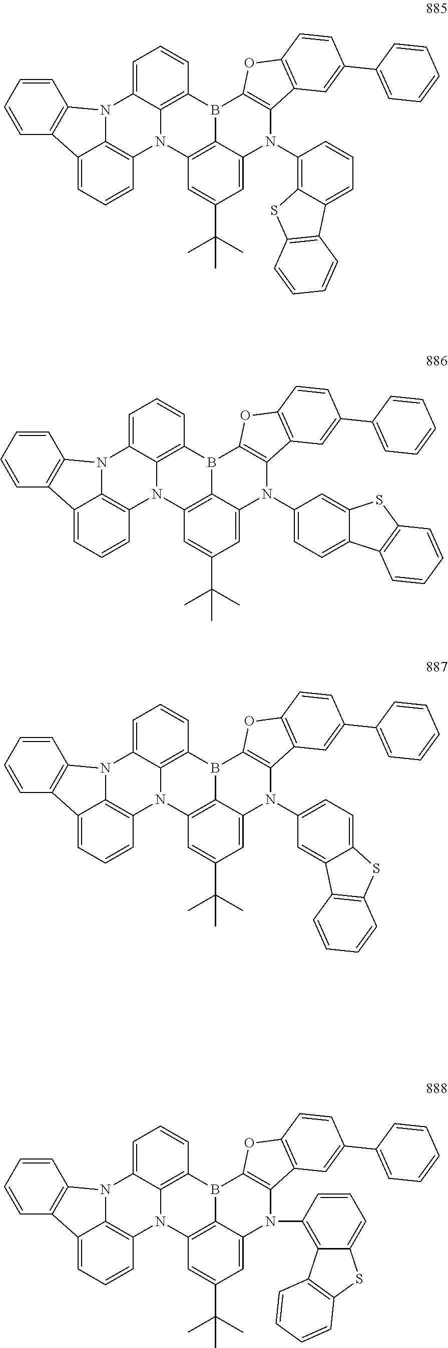 [SMILES: CC(C)(C)c1cc2c3c(c1)N1c4c(cccc4-n4c5ccccc5c5cccc1c54)B3c1oc3ccc(-c4ccccc4)cc3c1N2c1cccc2c1sc1ccccc12 ; CC(C)(C)c1cc2c3c(c1)N1c4c(cccc4-n4c5ccccc5c5cccc1c54)B3c1oc3ccc(-c4ccccc4)cc3c1N2c1ccc2c(c1)sc1ccccc12 ; CC(C)(C)c1cc2c3c(c1)N1c4c(cccc4-n4c5ccccc5c5cccc1c54)B3c1oc3ccc(-c4ccccc4)cc3c1N2c1ccc2sc3ccccc3c2c1 ; CC(C)(C)c1cc2c3c(c1)N1c4c(cccc4-n4c5ccccc5c5cccc1c54)B3c1oc3ccc(-c4ccccc4)cc3c1N2c1cccc2sc3ccccc3c12]

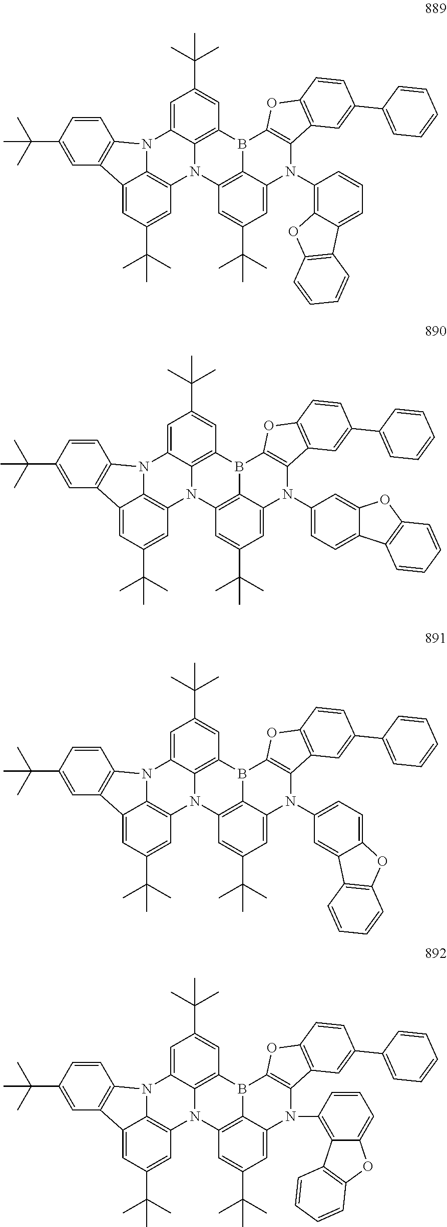

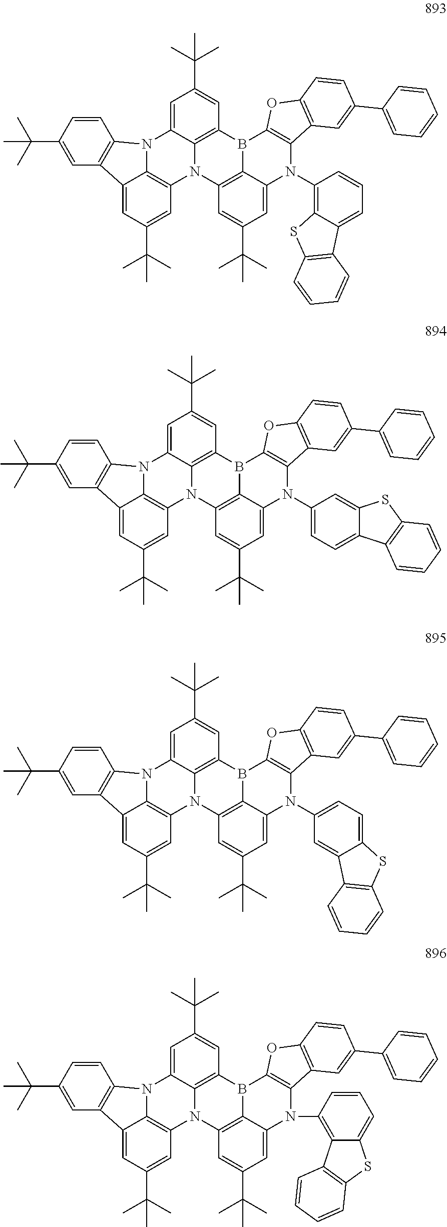

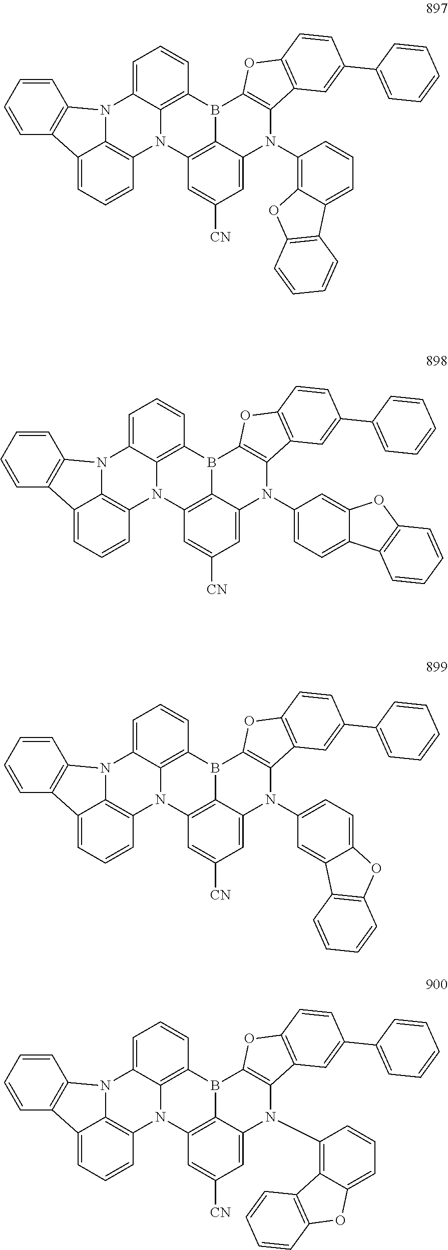 [SMILES: N#Cc1cc2c3c(c1)N1c4c(cccc4-n4c5ccccc5c5cccc1c54)B3c1oc3ccc(-c4ccccc4)cc3c1N2c1cccc2c1oc1ccccc12 ; N#Cc1cc2c3c(c1)N1c4c(cccc4-n4c5ccccc5c5cccc1c54)B3c1oc3ccc(-c4ccccc4)cc3c1N2c1ccc2c(c1)oc1ccccc12 ; N#Cc1cc2c3c(c1)N1c4c(cccc4-n4c5ccccc5c5cccc1c54)B3c1oc3ccc(-c4ccccc4)cc3c1N2c1ccc2oc3ccccc3c2c1 ; N#Cc1cc2c3c(c1)N1c4c(cccc4-n4c5ccccc5c5cccc1c54)B3c1oc3ccc(-c4ccccc4)cc3c1N2c1cccc2oc3ccccc3c12]

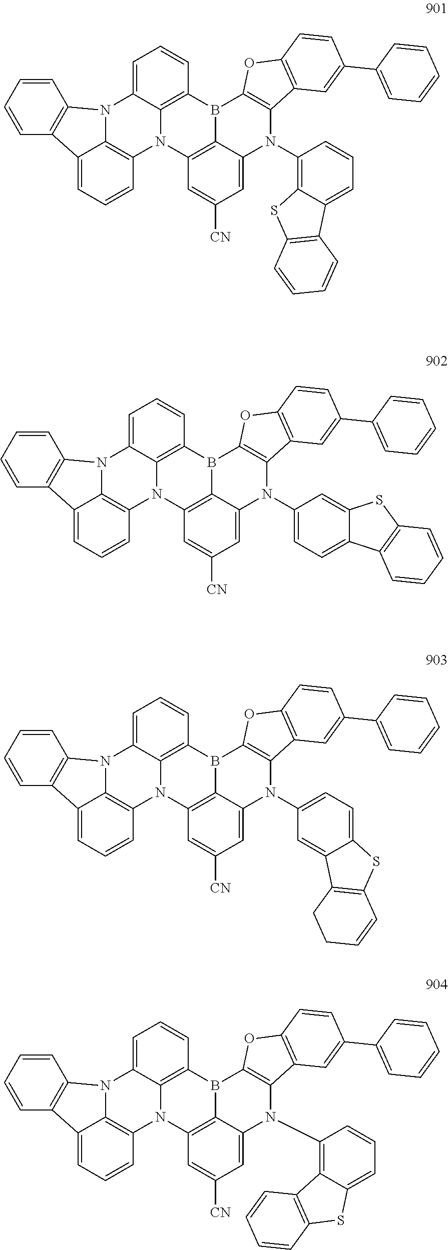 [SMILES: N#Cc1cc2c3c(c1)N1c4c(cccc4-n4c5ccccc5c5cccc1c54)B3c1oc3ccc(-c4ccccc4)cc3c1N2c1cccc2c1sc1ccccc12 ; N#Cc1cc2c3c(c1)N1c4c(cccc4-n4c5ccccc5c5cccc1c54)B3c1oc3ccc(-c4ccccc4)cc3c1N2c1ccc2c(c1)sc1ccccc12 ; N#Cc1cc2c3c(c1)N1c4c(cccc4-n4c5ccccc5c5cccc1c54)B3c1oc3ccc(-c4ccccc4)cc3c1N2c1ccc2sc3c(c2c1)CCC=C3 ; N#Cc1cc2c3c(c1)N1c4c(cccc4-n4c5ccccc5c5cccc1c54)B3c1oc3ccc(-c4ccccc4)cc3c1N2c1cccc2sc3ccccc3c12]

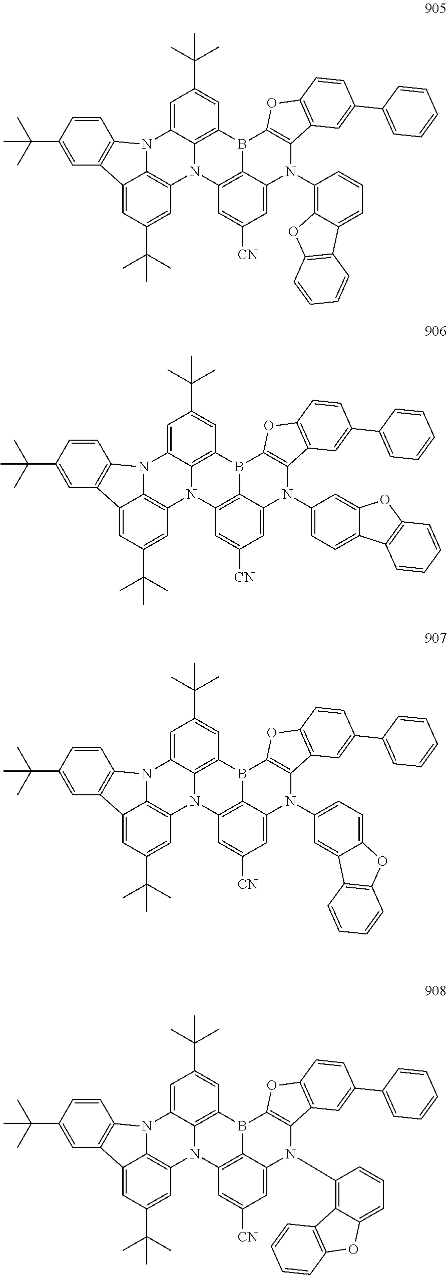

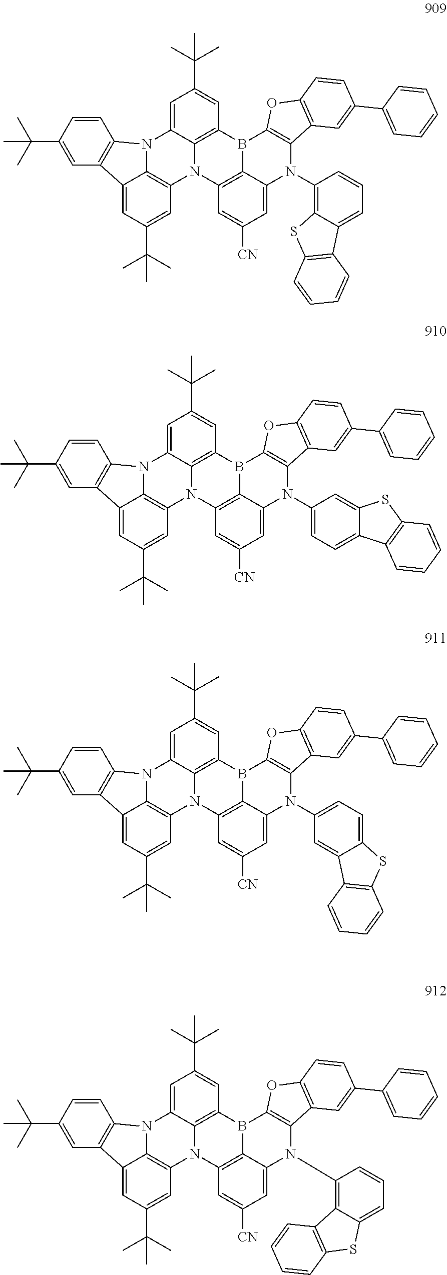

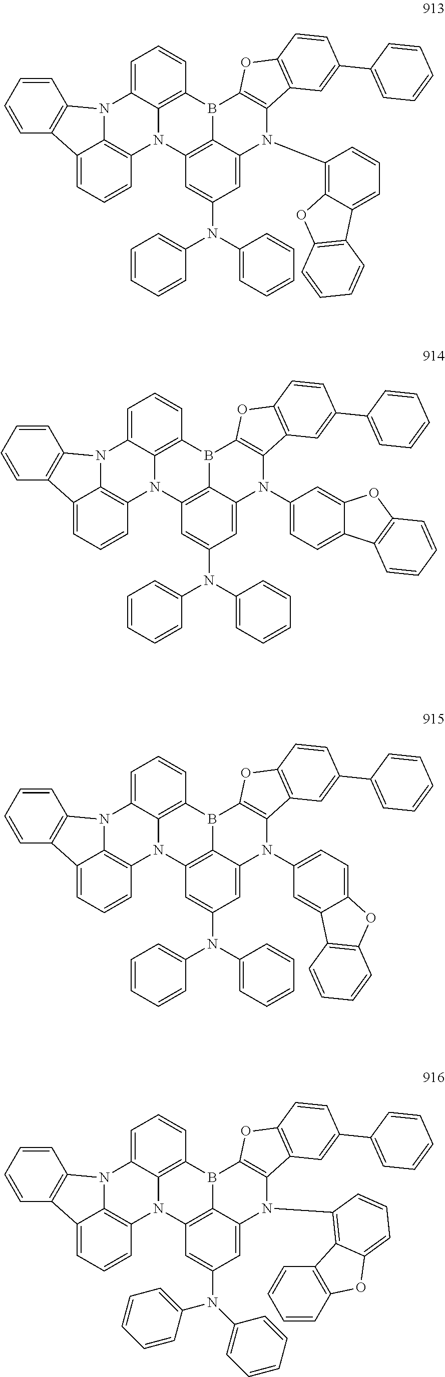 [SMILES: c1ccc(-c2ccc3oc4c(c3c2)N(c2cccc3c2oc2ccccc23)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2ccc3c(c2)oc2ccccc23)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2ccc3oc5ccccc5c3c2)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2cccc3oc5ccccc5c23)c2cc(N(c3ccccc3)c3ccccc3)cc3c2B4c2cccc4c2N3c2cccc3c5ccccc5n-4c23)cc1]

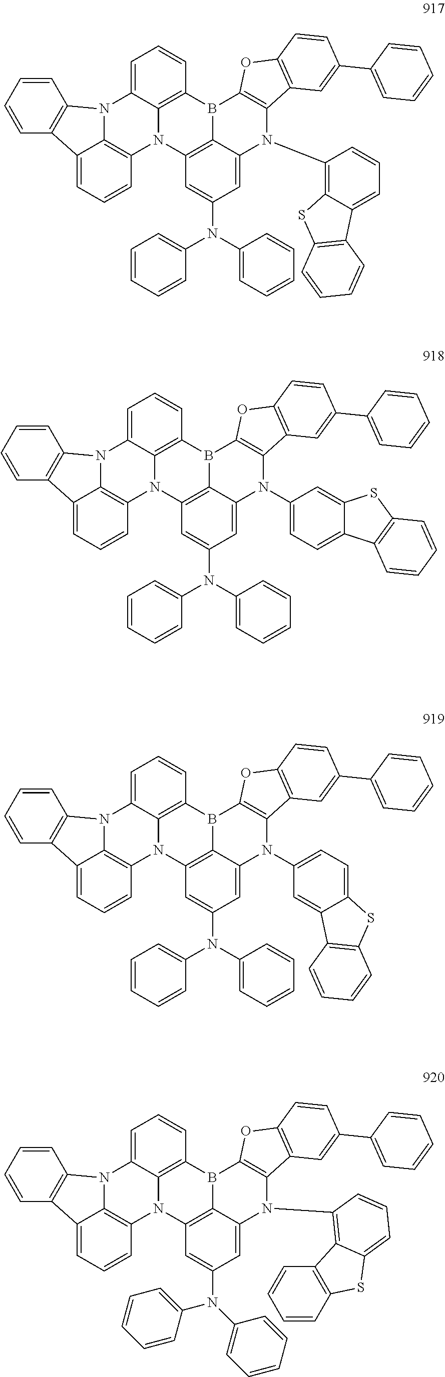 [SMILES: c1ccc(-c2ccc3oc4c(c3c2)N(c2cccc3c2sc2ccccc23)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2ccc3c(c2)sc2ccccc23)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2ccc3sc5ccccc5c3c2)c2cc(N(c3ccccc3)c3ccccc3)cc3c2B4c2cccc4c2N3c2cccc3c5ccccc5n-4c23)cc1 ; c1ccc(-c2ccc3oc4c(c3c2)N(c2cccc3sc5ccccc5c23)c2cc(N(c3ccccc3)c3ccccc3)cc3c2B4c2cccc4c2N3c2cccc3c5ccccc5n-4c23)cc1]

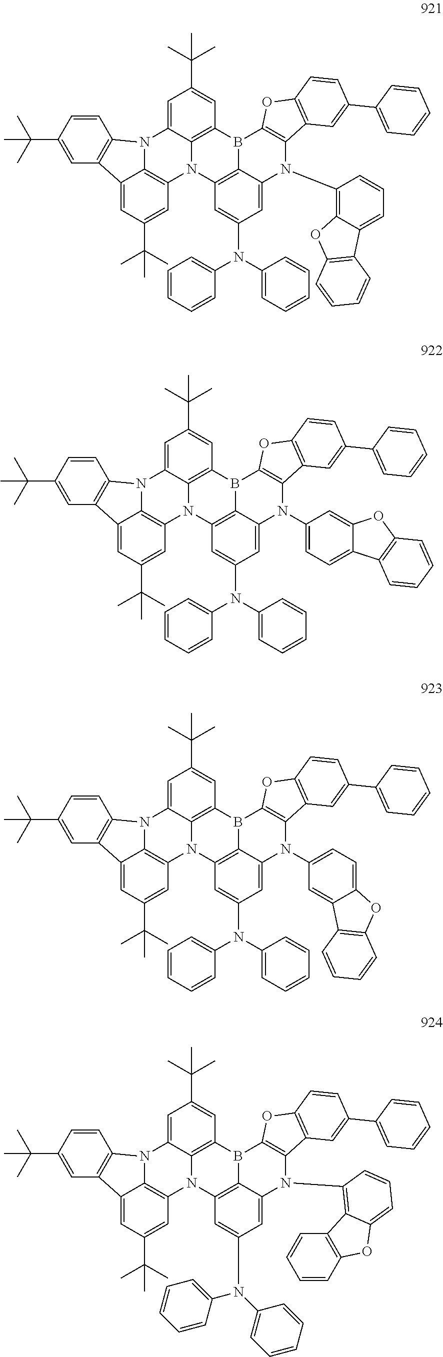

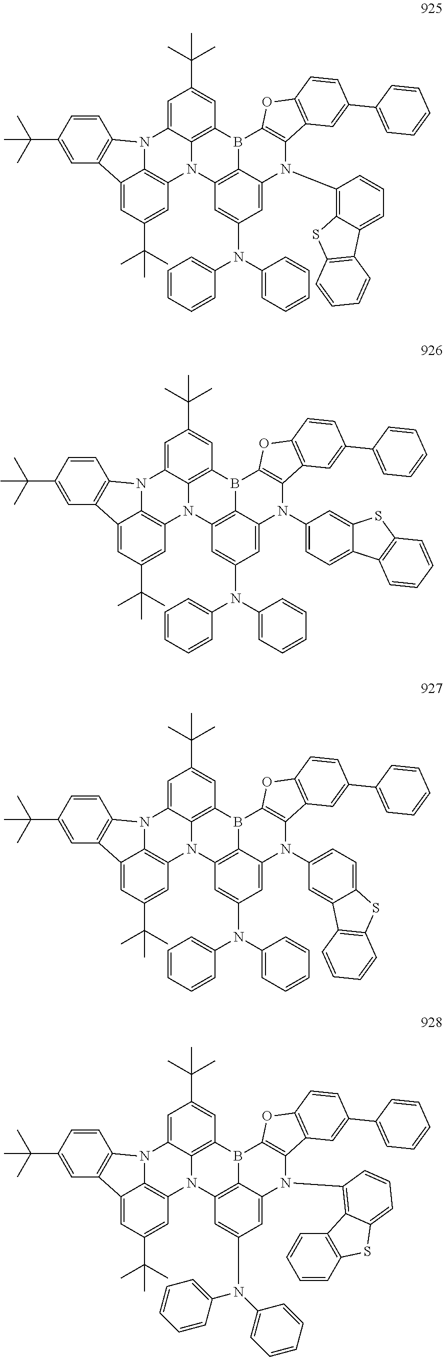

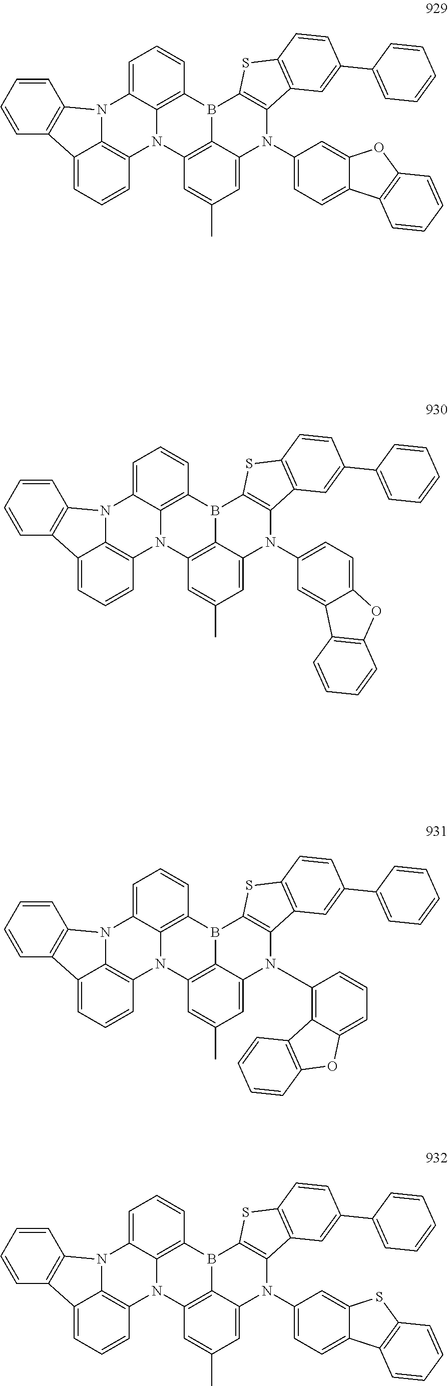 [SMILES: Cc1cc2c3c(c1)N1c4c(cccc4-n4c5ccccc5c5cccc1c54)B3c1sc3ccc(-c4ccccc4)cc3c1N2c1ccc2c(c1)oc1ccccc12 ; Cc1cc2c3c(c1)N1c4c(cccc4-n4c5ccccc5c5cccc1c54)B3c1sc3ccc(-c4ccccc4)cc3c1N2c1ccc2oc3ccccc3c2c1 ; Cc1cc2c3c(c1)N1c4c(cccc4-n4c5ccccc5c5cccc1c54)B3c1sc3ccc(-c4ccccc4)cc3c1N2c1cccc2oc3ccccc3c12 ; Cc1cc2c3c(c1)N1c4c(cccc4-n4c5ccccc5c5cccc1c54)B3c1sc3ccc(-c4ccccc4)cc3c1N2c1ccc2c(c1)sc1ccccc12]

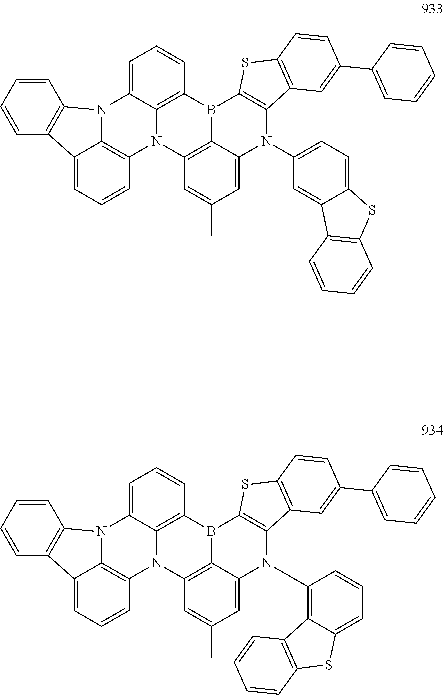 [SMILES: Cc1cc2c3c(c1)N1c4c(cccc4-n4c5ccccc5c5cccc1c54)B3c1sc3ccc(-c4ccccc4)cc3c1N2c1ccc2sc3ccccc3c2c1 ; Cc1cc2c3c(c1)N1c4c(cccc4-n4c5ccccc5c5cccc1c54)B3c1sc3ccc(-c4ccccc4)cc3c1N2c1cccc2sc3ccccc3c12]

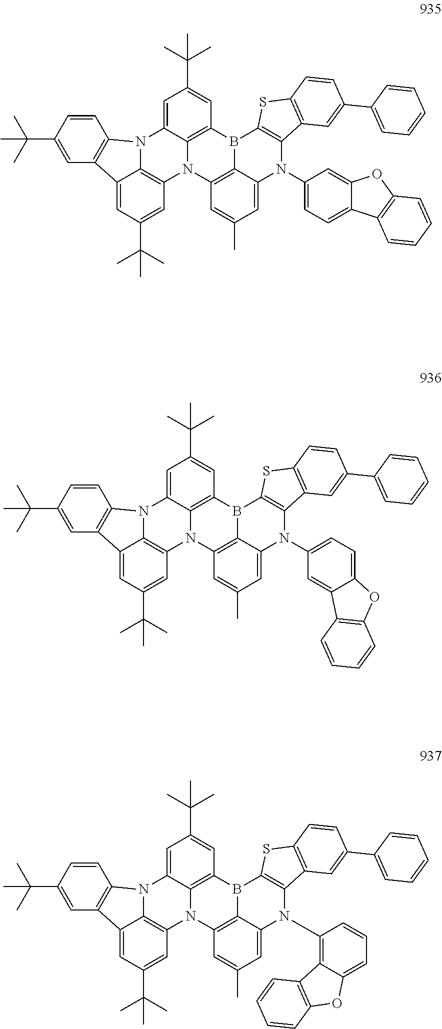 [SMILES: Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2c(c1)oc1ccccc12 ; Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2oc3ccccc3c2c1 ; Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1cccc2oc3ccccc3c12]

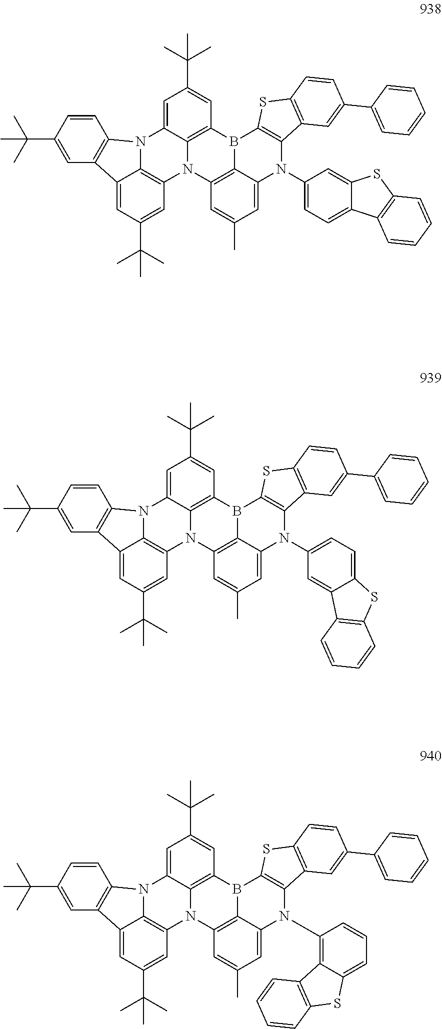 [SMILES: Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2c(c1)sc1ccccc12 ; Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2sc3ccccc3c2c1 ; Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1cccc2sc3ccccc3c12]

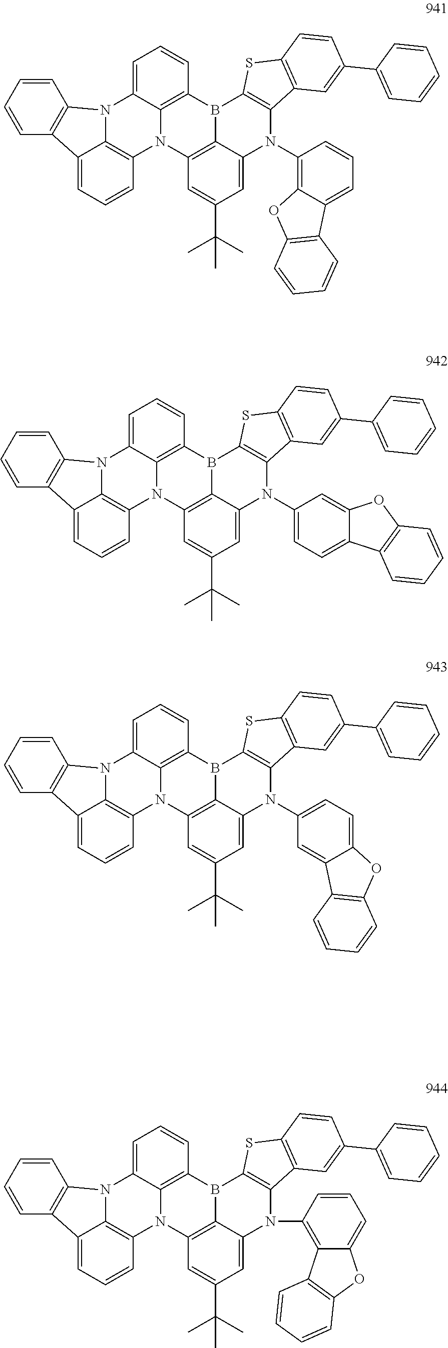 [SMILES: CC(C)(C)c1cc2c3c(c1)N1c4c(cccc4-n4c5ccccc5c5cccc1c54)B3c1sc3ccc(-c4ccccc4)cc3c1N2c1cccc2c1oc1ccccc12 ; CC(C)(C)c1cc2c3c(c1)N1c4c(cccc4-n4c5ccccc5c5cccc1c54)B3c1sc3ccc(-c4ccccc4)cc3c1N2c1ccc2c(c1)oc1ccccc12 ; CC(C)(C)c1cc2c3c(c1)N1c4c(cccc4-n4c5ccccc5c5cccc1c54)B3c1sc3ccc(-c4ccccc4)cc3c1N2c1ccc2oc3ccccc3c2c1 ; CC(C)(C)c1cc2c3c(c1)N1c4c(cccc4-n4c5ccccc5c5cccc1c54)B3c1sc3ccc(-c4ccccc4)cc3c1N2c1cccc2oc3ccccc3c12]

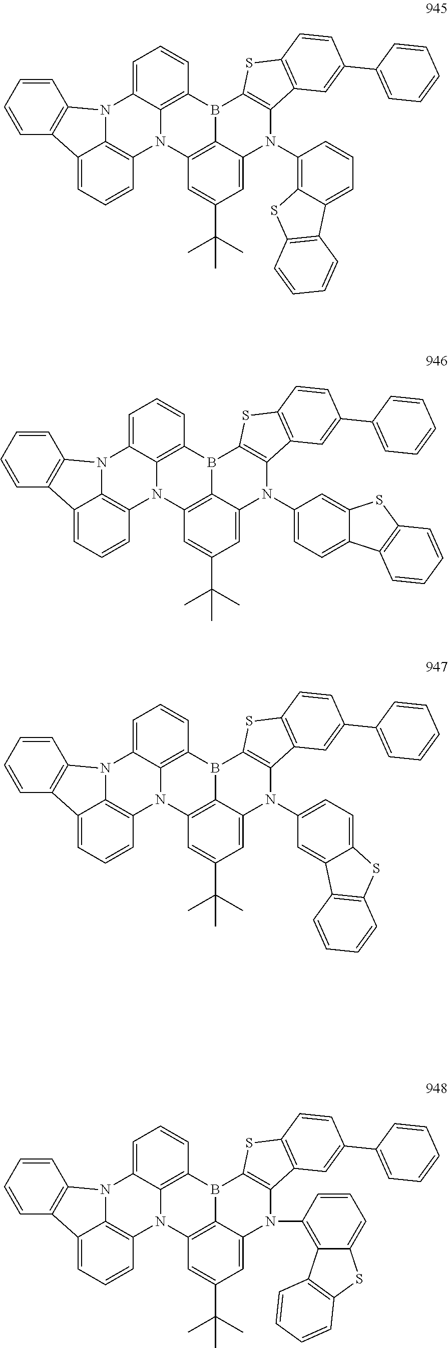 [SMILES: CC(C)(C)c1cc2c3c(c1)N1c4c(cccc4-n4c5ccccc5c5cccc1c54)B3c1sc3ccc(-c4ccccc4)cc3c1N2c1cccc2c1sc1ccccc12 ; CC(C)(C)c1cc2c3c(c1)N1c4c(cccc4-n4c5ccccc5c5cccc1c54)B3c1sc3ccc(-c4ccccc4)cc3c1N2c1ccc2c(c1)sc1ccccc12 ; CC(C)(C)c1cc2c3c(c1)N1c4c(cccc4-n4c5ccccc5c5cccc1c54)B3c1sc3ccc(-c4ccccc4)cc3c1N2c1ccc2sc3ccccc3c2c1 ; CC(C)(C)c1cc2c3c(c1)N1c4c(cccc4-n4c5ccccc5c5cccc1c54)B3c1sc3ccc(-c4ccccc4)cc3c1N2c1cccc2sc3ccccc3c12]

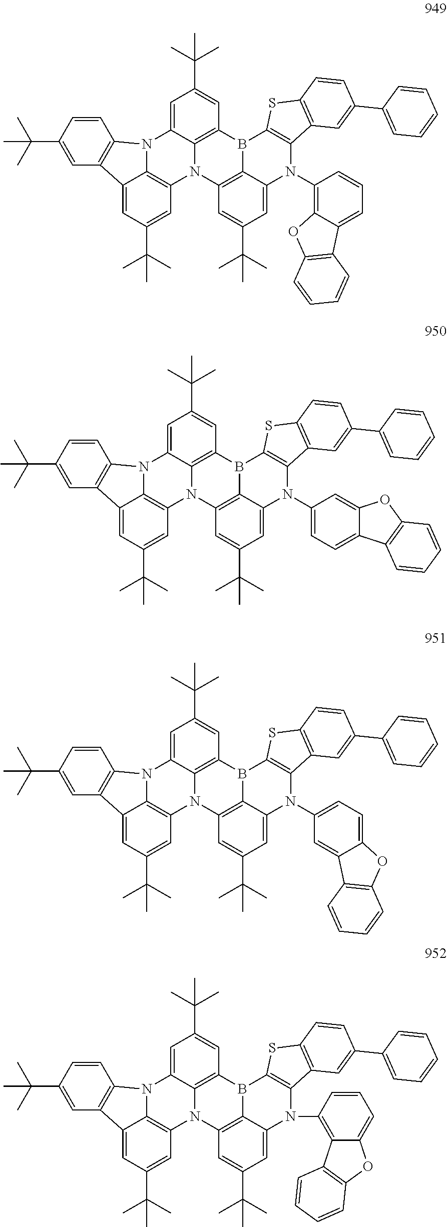

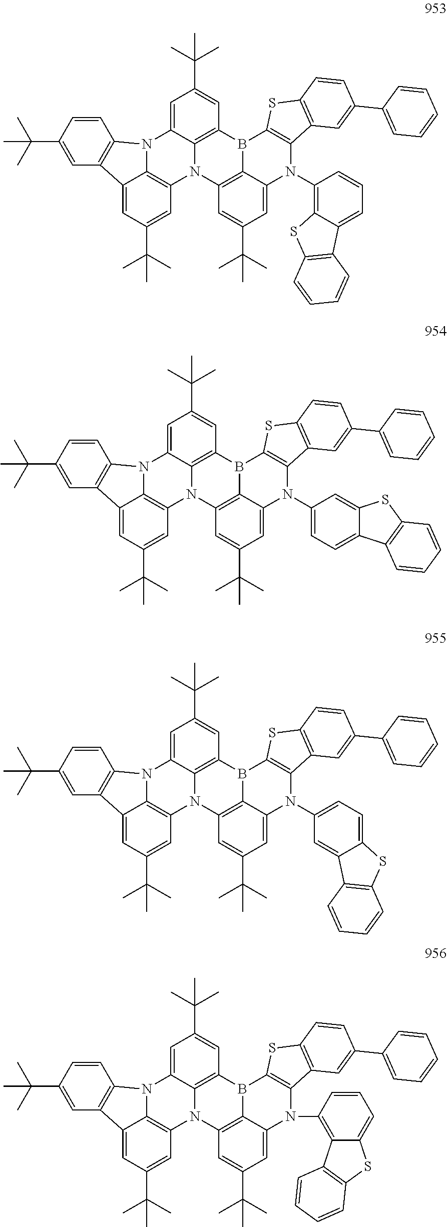

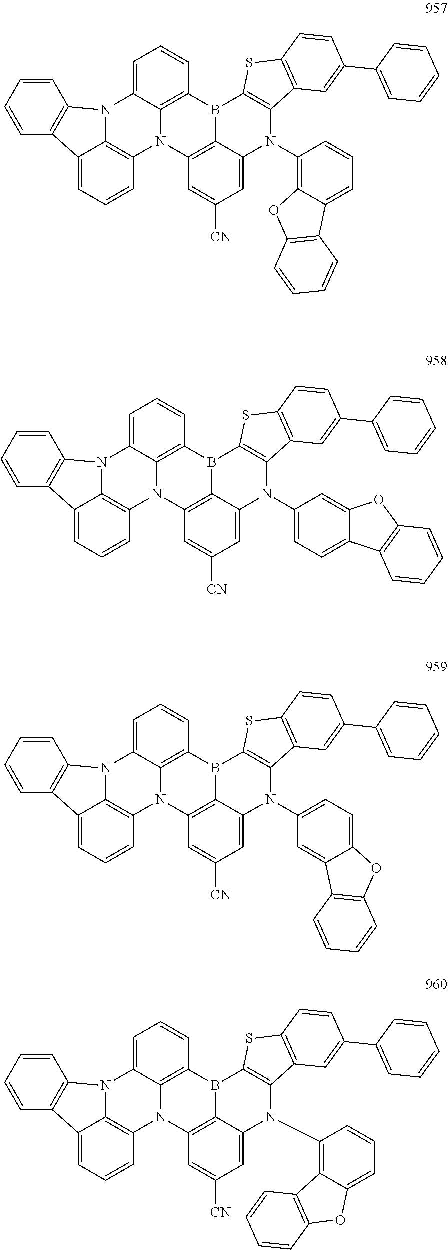 [SMILES: N#Cc1cc2c3c(c1)N1c4c(cccc4-n4c5ccccc5c5cccc1c54)B3c1sc3ccc(-c4ccccc4)cc3c1N2c1cccc2c1oc1ccccc12 ; N#Cc1cc2c3c(c1)N1c4c(cccc4-n4c5ccccc5c5cccc1c54)B3c1sc3ccc(-c4ccccc4)cc3c1N2c1ccc2c(c1)oc1ccccc12 ; N#Cc1cc2c3c(c1)N1c4c(cccc4-n4c5ccccc5c5cccc1c54)B3c1sc3ccc(-c4ccccc4)cc3c1N2c1ccc2oc3ccccc3c2c1 ; N#Cc1cc2c3c(c1)N1c4c(cccc4-n4c5ccccc5c5cccc1c54)B3c1sc3ccc(-c4ccccc4)cc3c1N2c1cccc2oc3ccccc3c12]

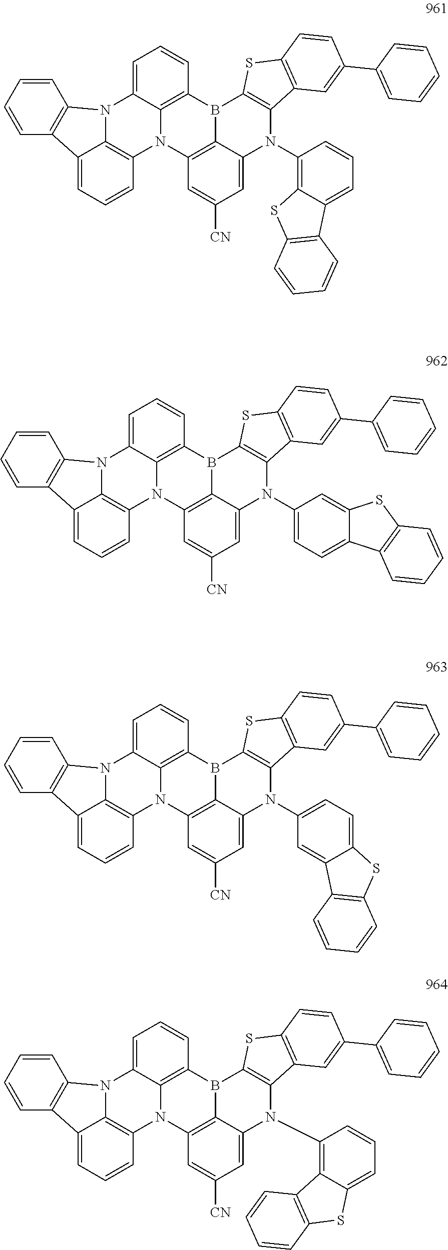 [SMILES: N#Cc1cc2c3c(c1)N1c4c(cccc4-n4c5ccccc5c5cccc1c54)B3c1sc3ccc(-c4ccccc4)cc3c1N2c1cccc2c1sc1ccccc12 ; N#Cc1cc2c3c(c1)N1c4c(cccc4-n4c5ccccc5c5cccc1c54)B3c1sc3ccc(-c4ccccc4)cc3c1N2c1ccc2c(c1)sc1ccccc12 ; N#Cc1cc2c3c(c1)N1c4c(cccc4-n4c5ccccc5c5cccc1c54)B3c1sc3ccc(-c4ccccc4)cc3c1N2c1ccc2sc3ccccc3c2c1 ; N#Cc1cc2c3c(c1)N1c4c(cccc4-n4c5ccccc5c5cccc1c54)B3c1sc3ccc(-c4ccccc4)cc3c1N2c1cccc2sc3ccccc3c12]

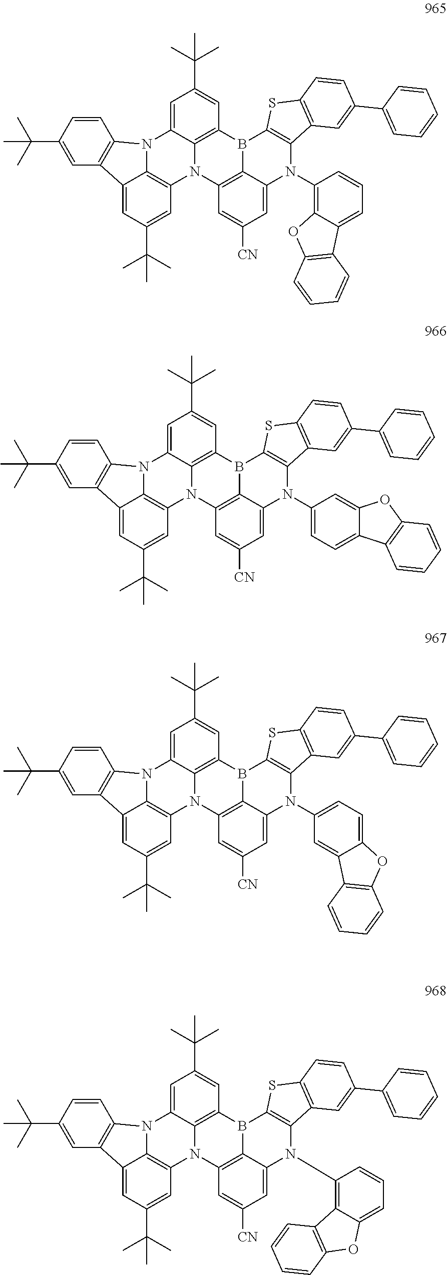

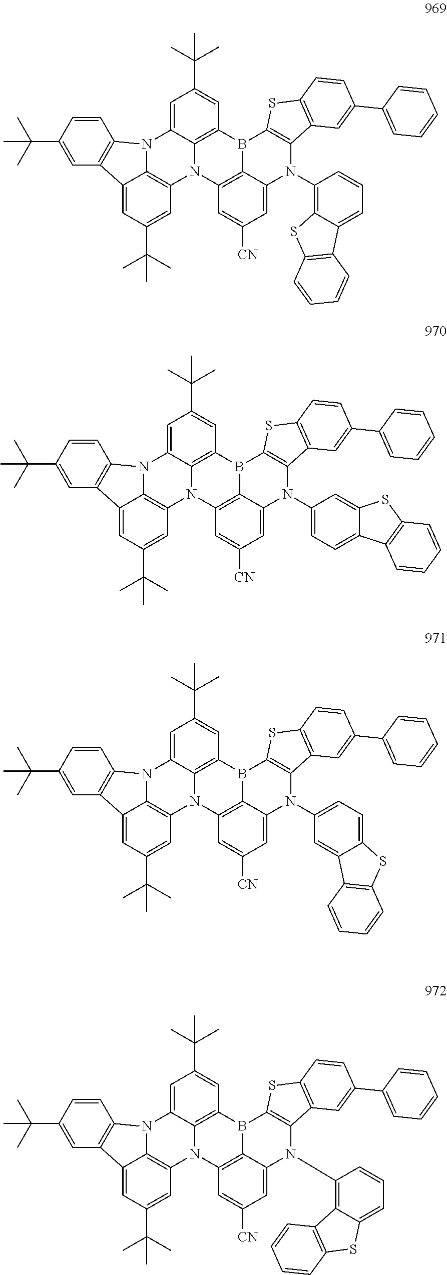

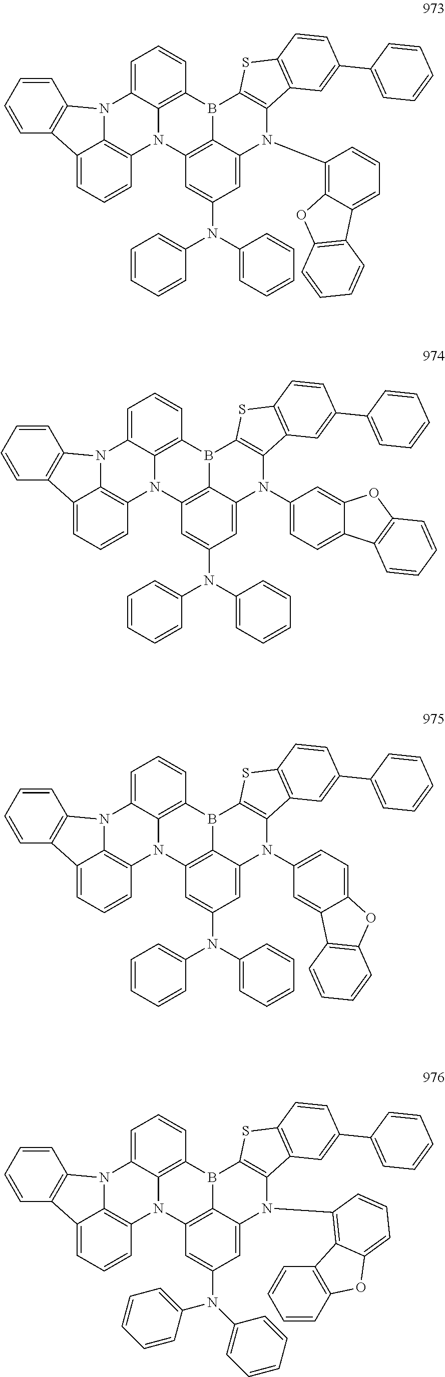 [SMILES: c1ccc(-c2ccc3sc4c(c3c2)N(c2cccc3c2oc2ccccc23)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2ccc3c(c2)oc2ccccc23)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2ccc3oc5ccccc5c3c2)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2cccc3oc5ccccc5c23)c2cc(N(c3ccccc3)c3ccccc3)cc3c2B4c2cccc4c2N3c2cccc3c5ccccc5n-4c23)cc1]

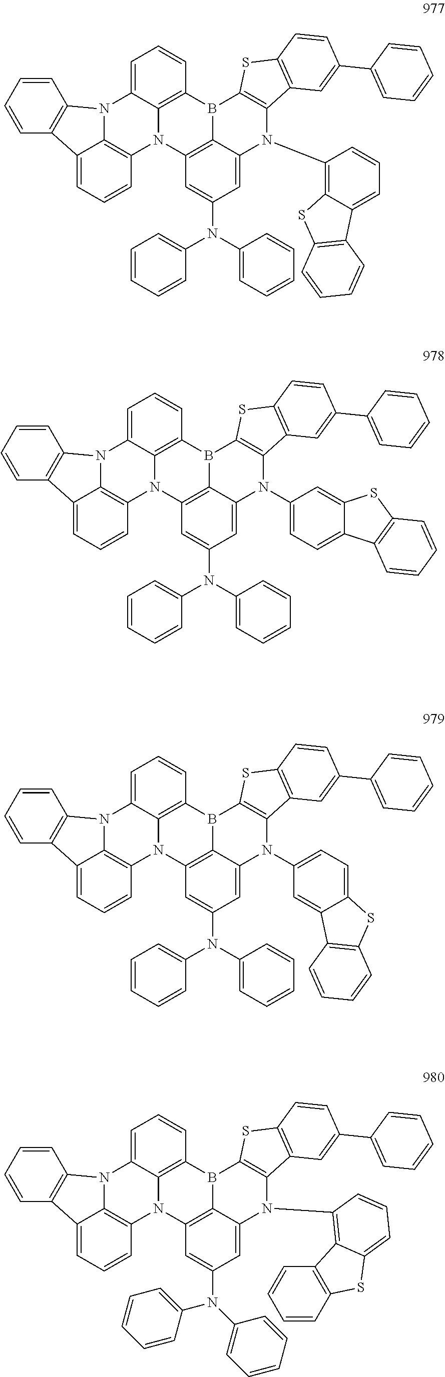 [SMILES: c1ccc(-c2ccc3sc4c(c3c2)N(c2cccc3c2sc2ccccc23)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2ccc3c(c2)sc2ccccc23)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2ccc3sc5ccccc5c3c2)c2cc(N(c3ccccc3)c3ccccc3)cc3c2B4c2cccc4c2N3c2cccc3c5ccccc5n-4c23)cc1 ; c1ccc(-c2ccc3sc4c(c3c2)N(c2cccc3sc5ccccc5c23)c2cc(N(c3ccccc3)c3ccccc3)cc3c2B4c2cccc4c2N3c2cccc3c5ccccc5n-4c23)cc1]

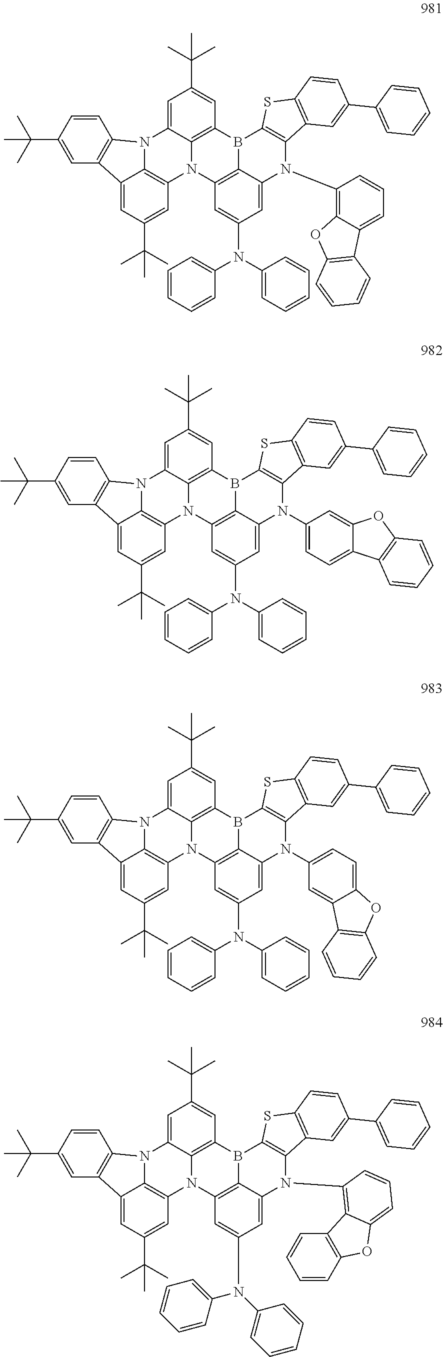

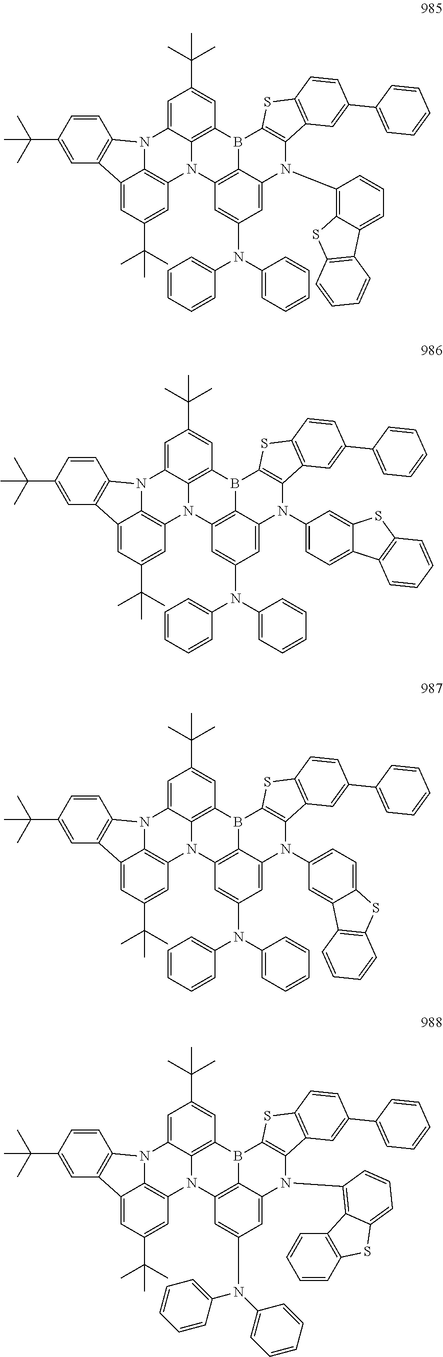

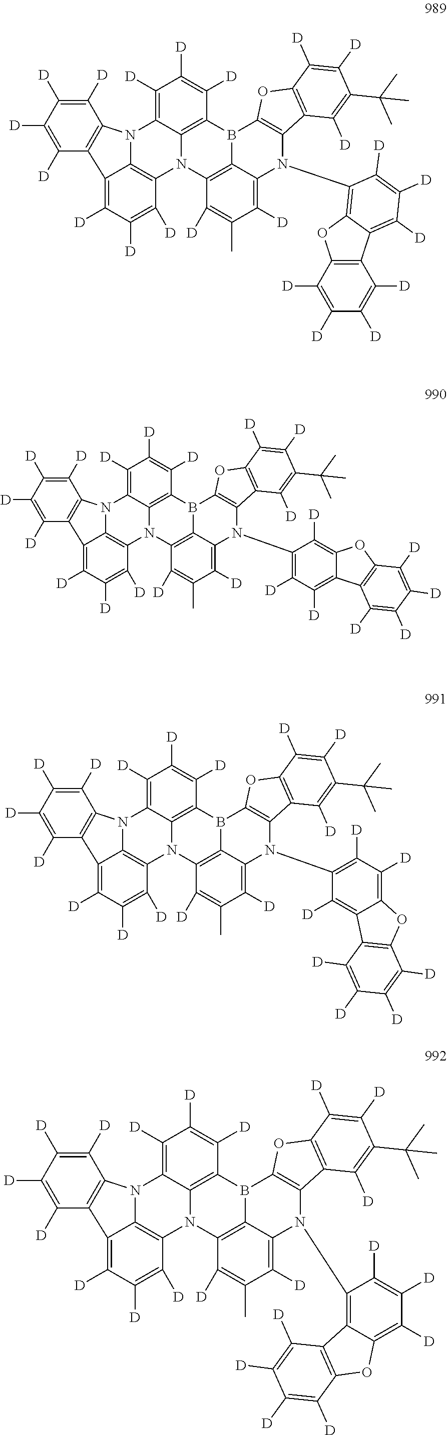

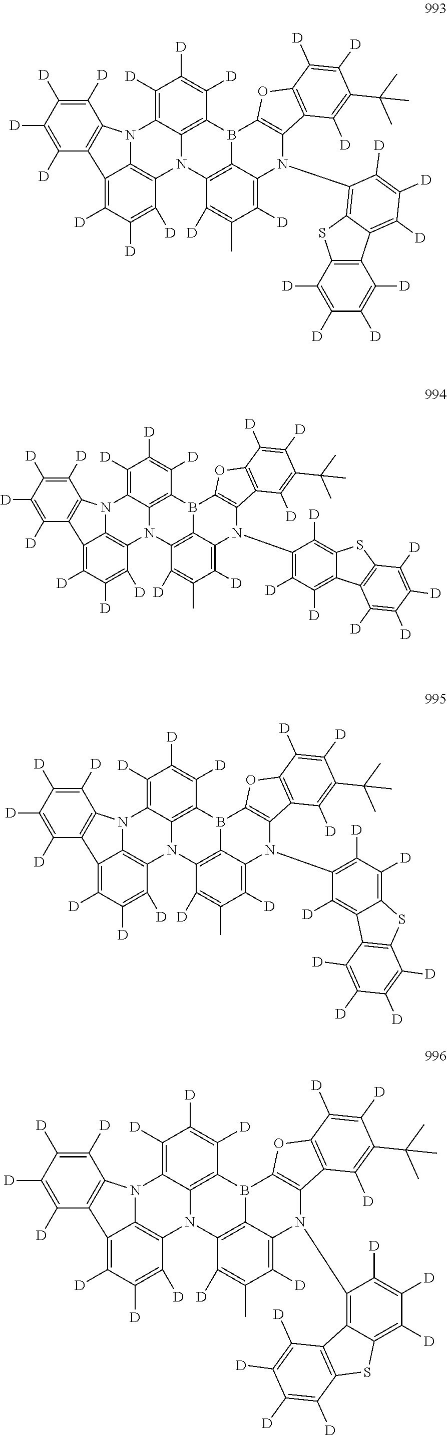

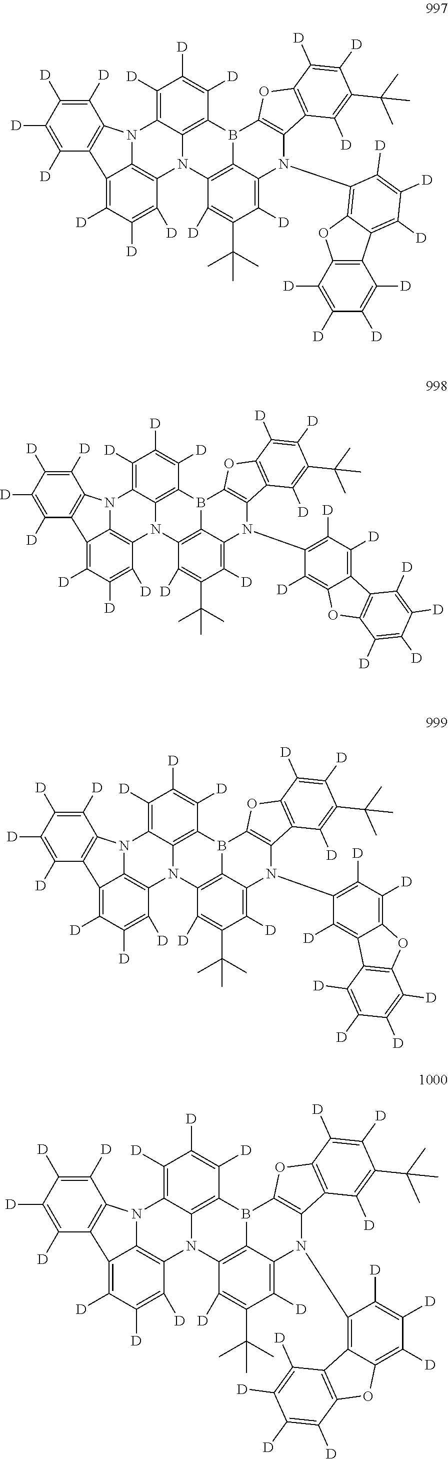

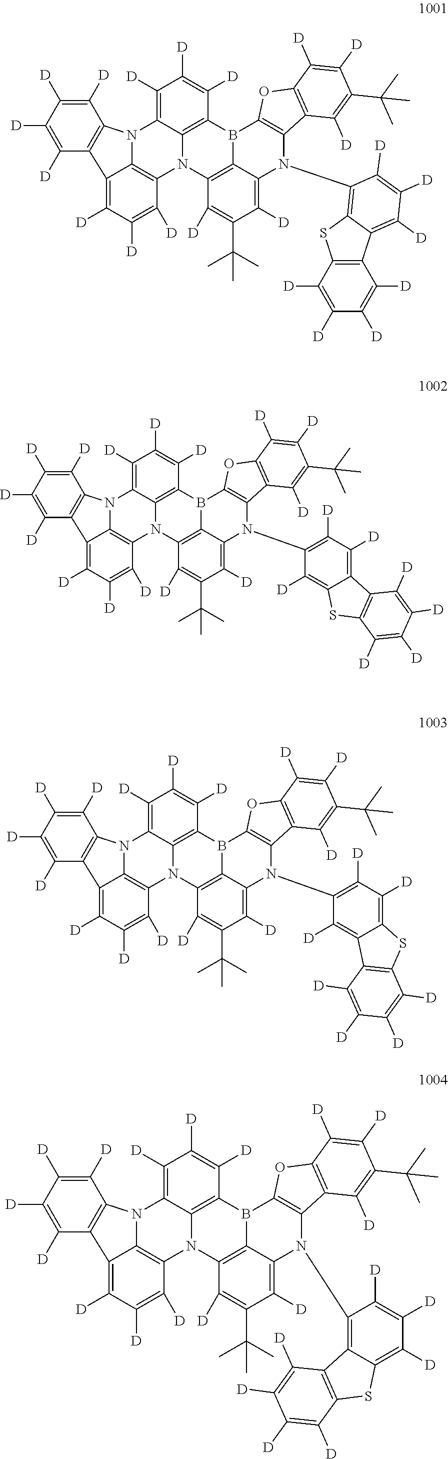

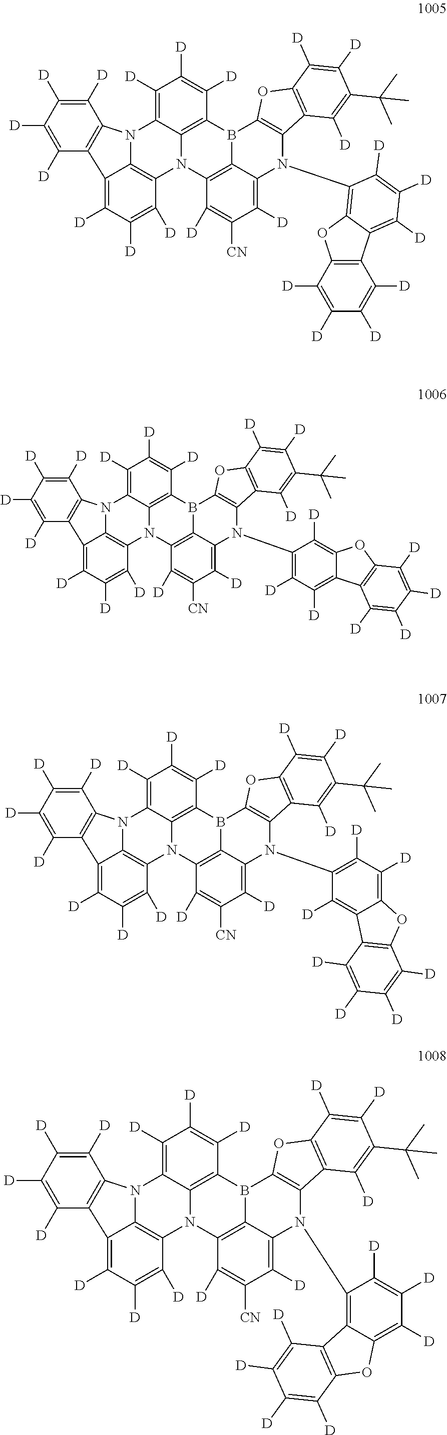

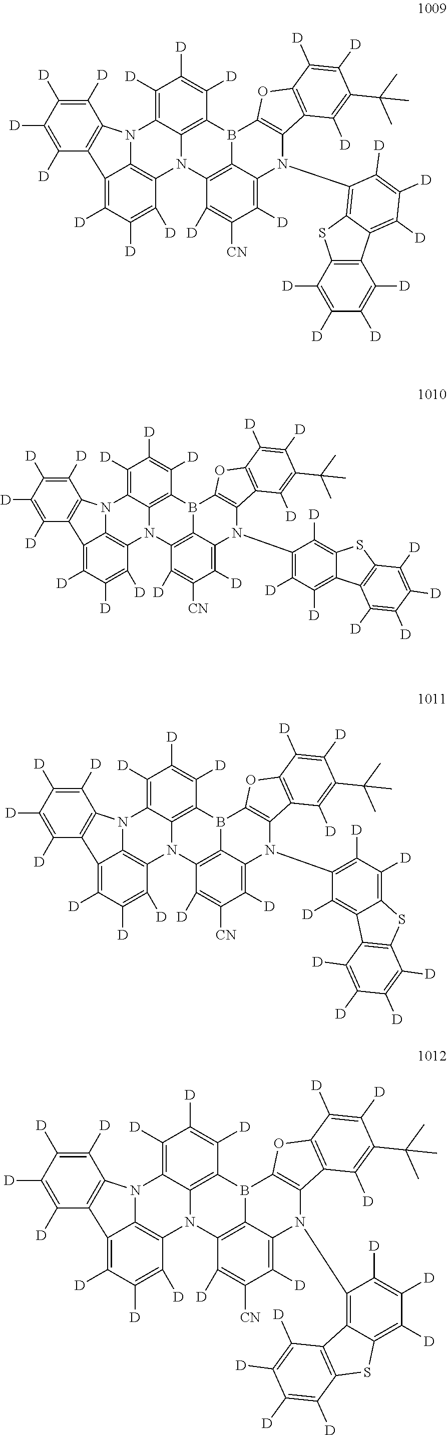

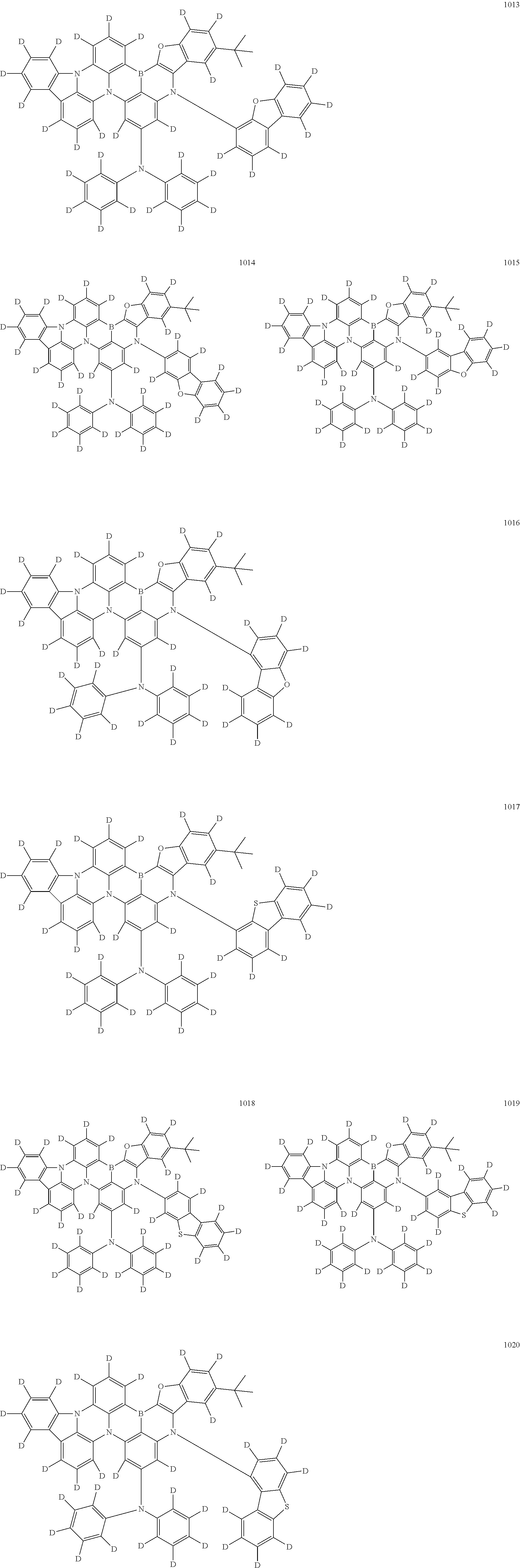

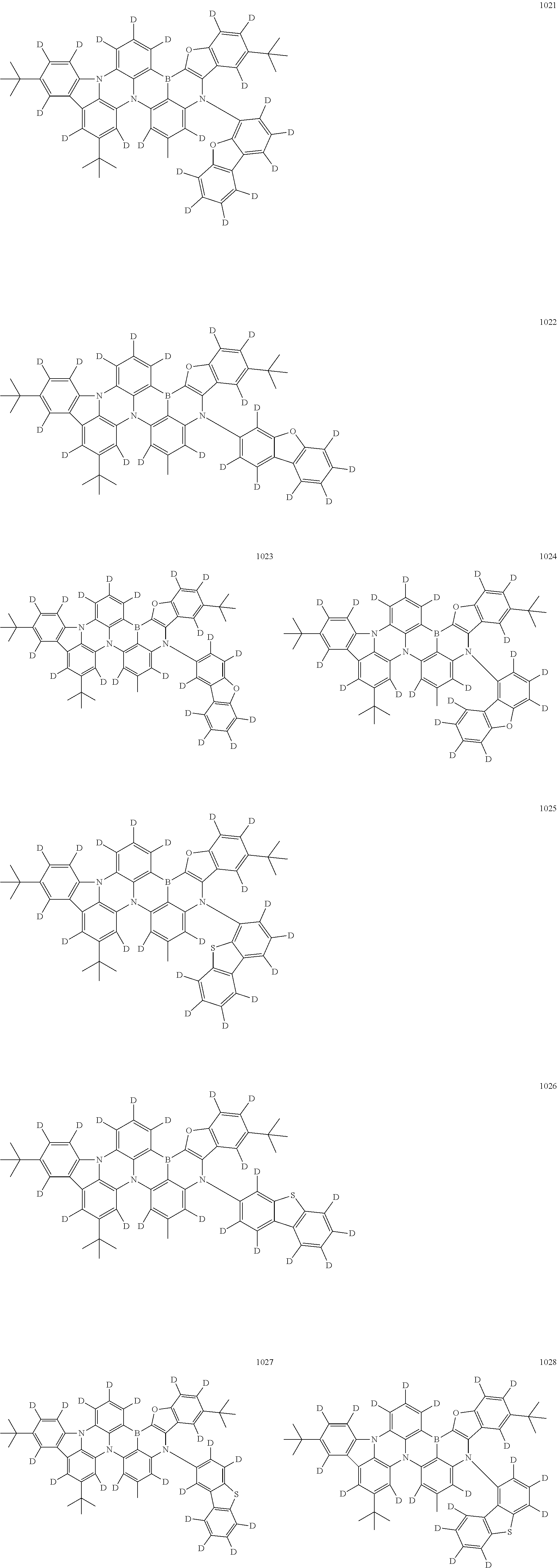

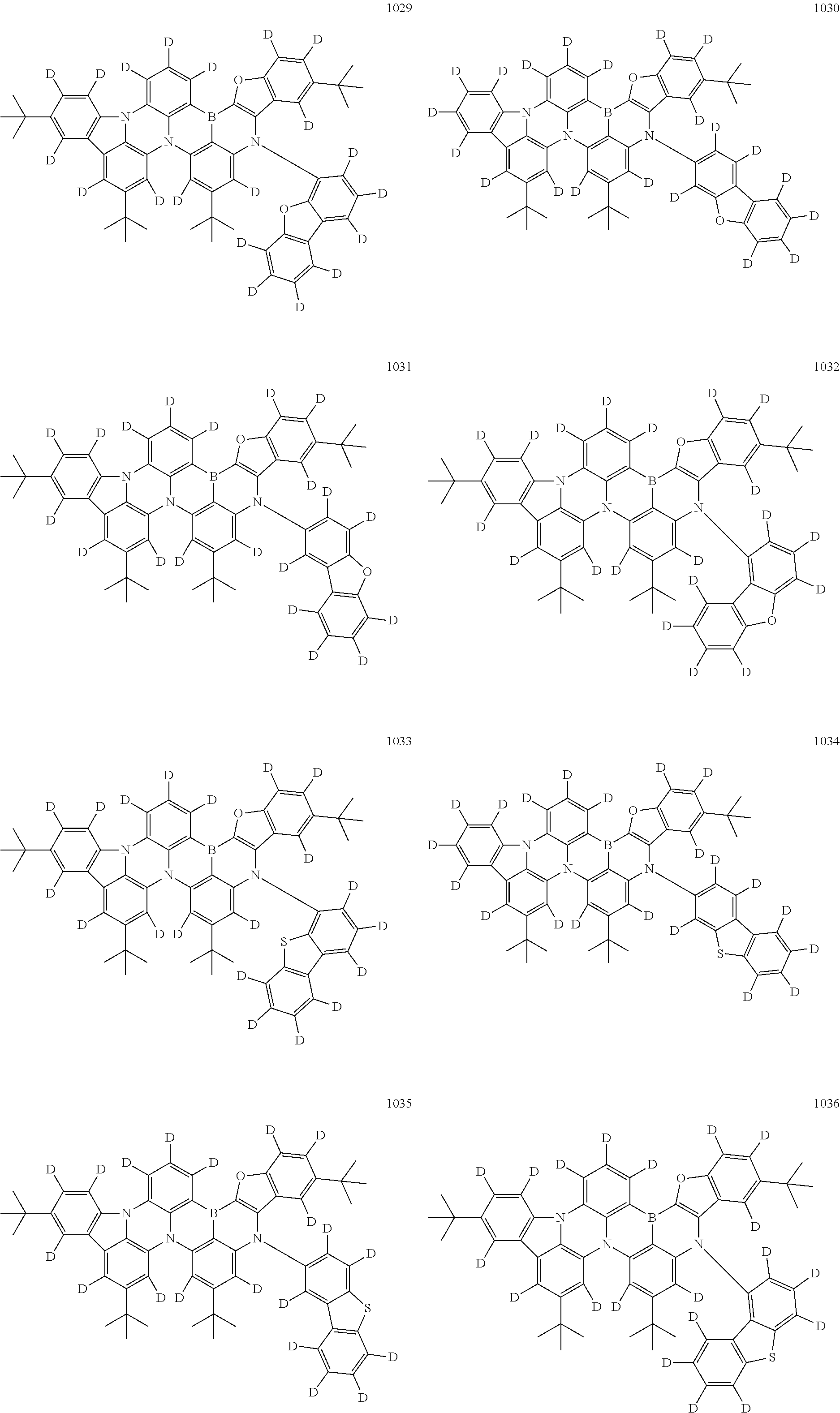

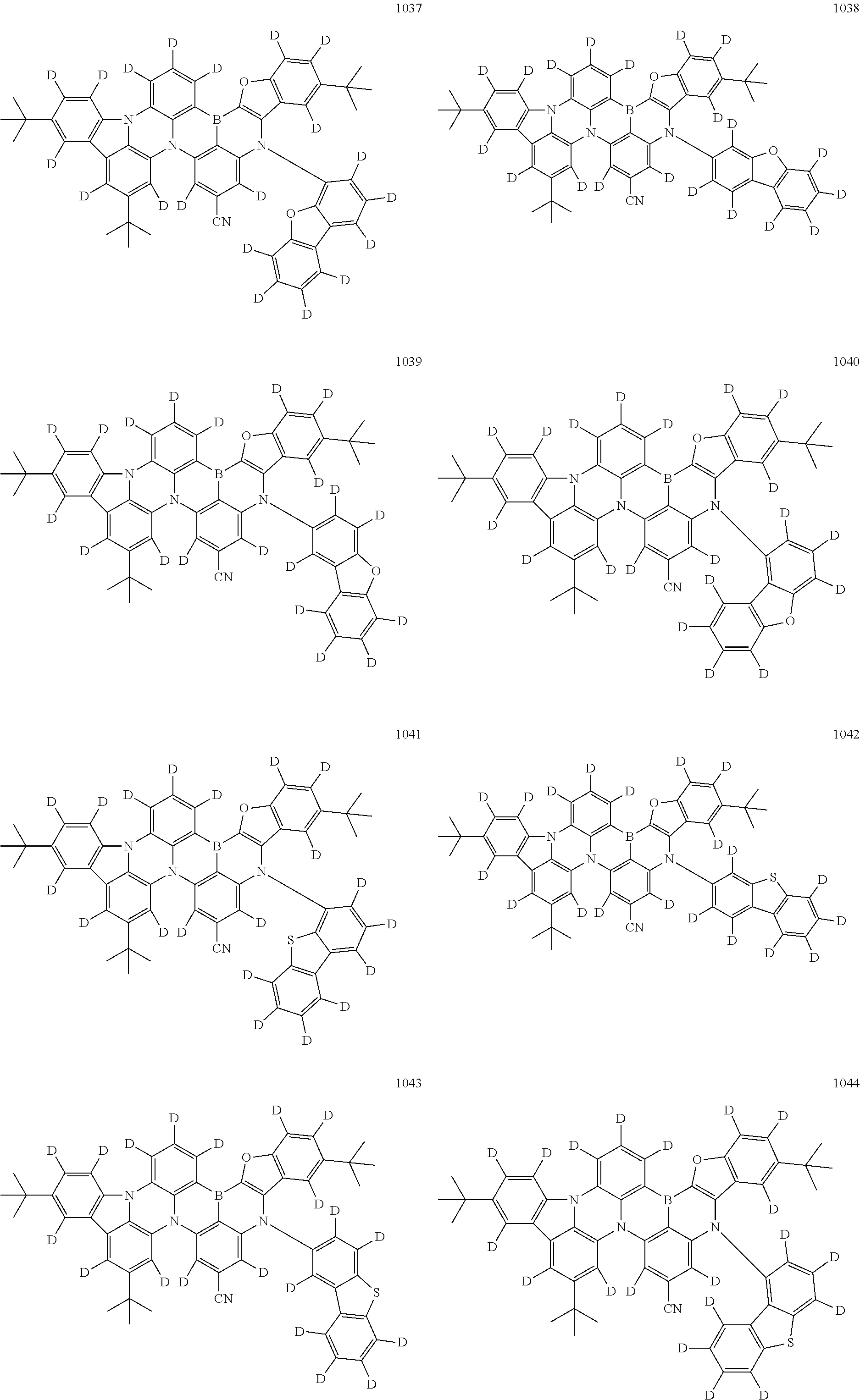

[chemical structure]

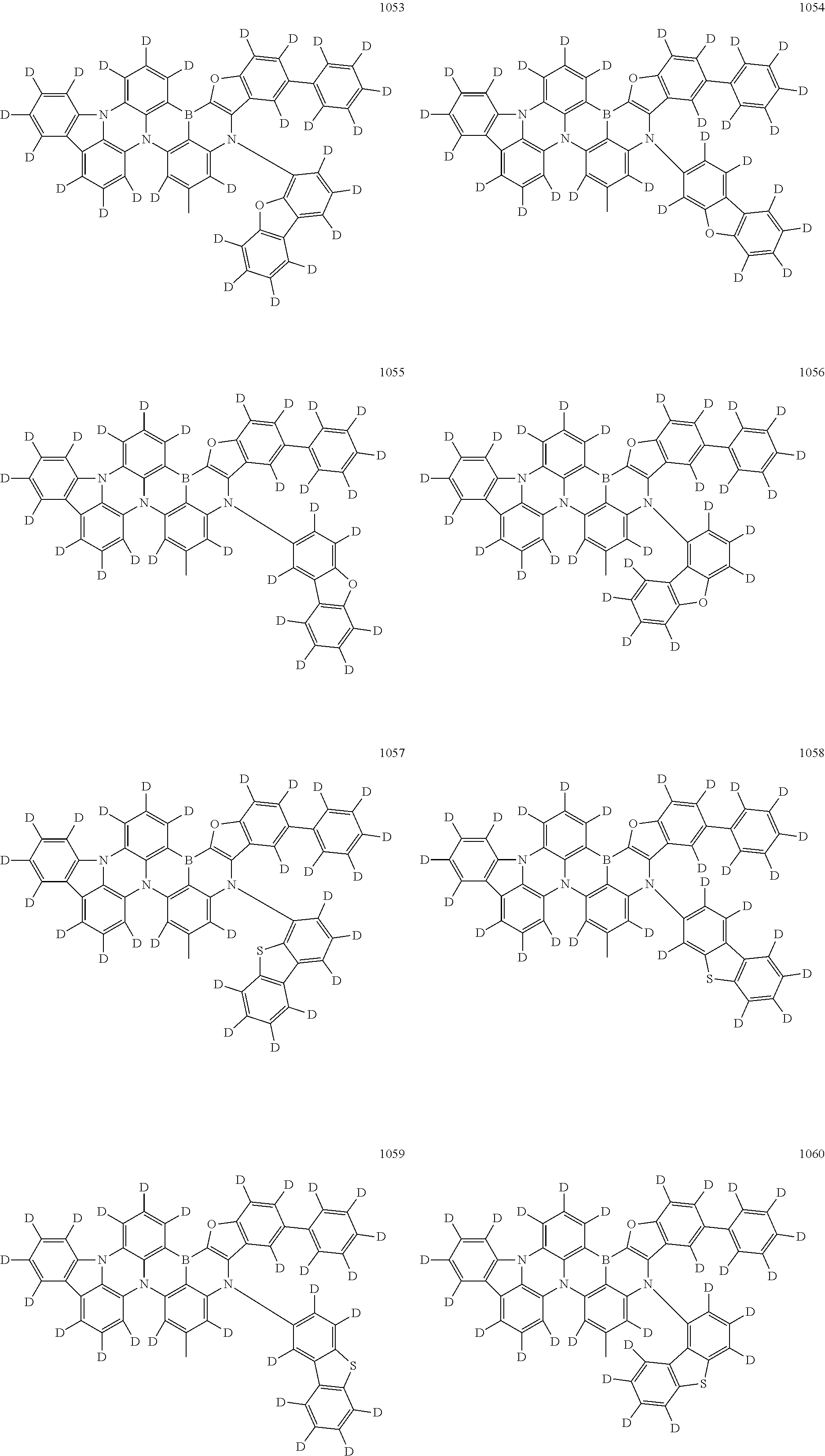

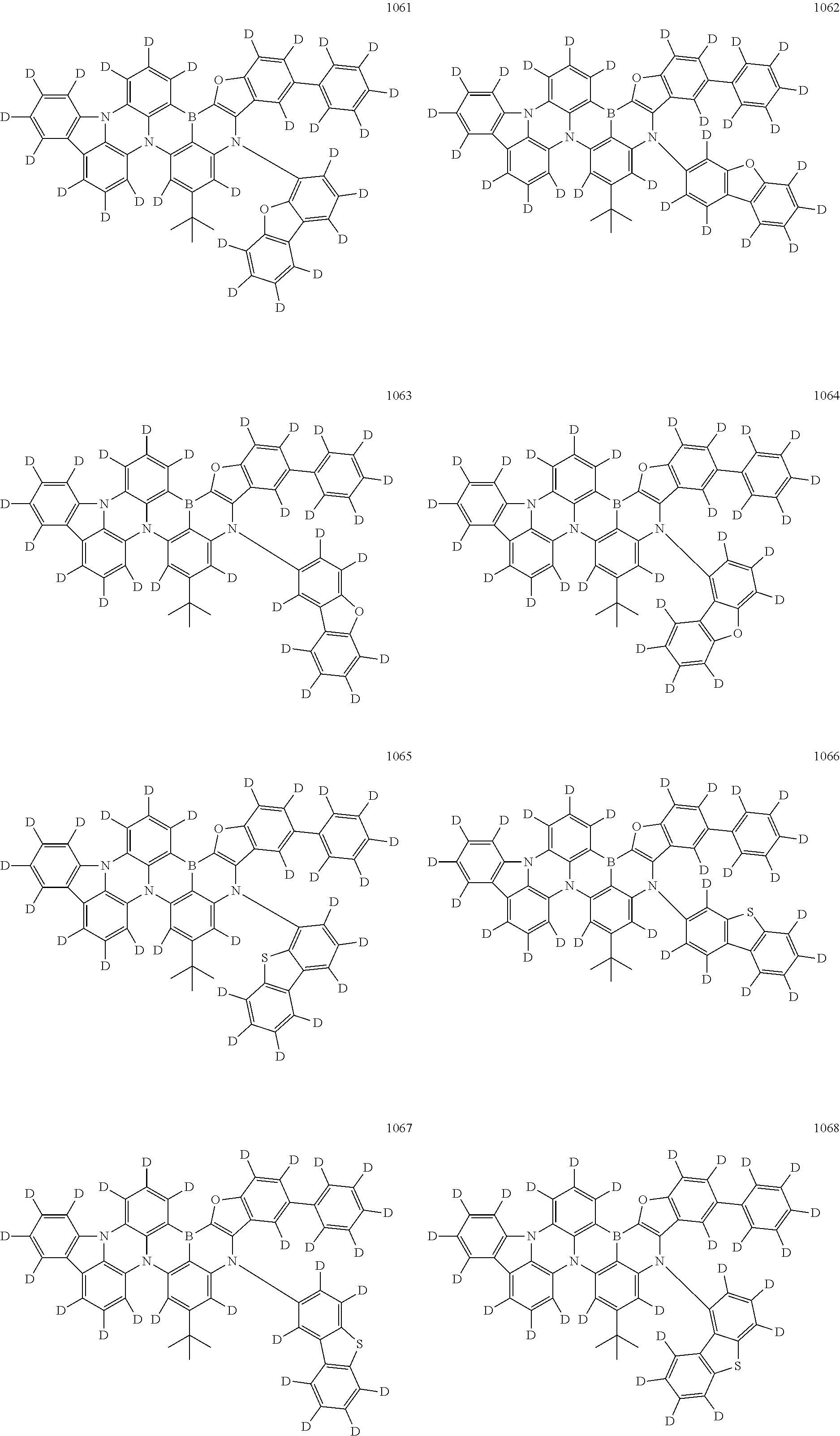

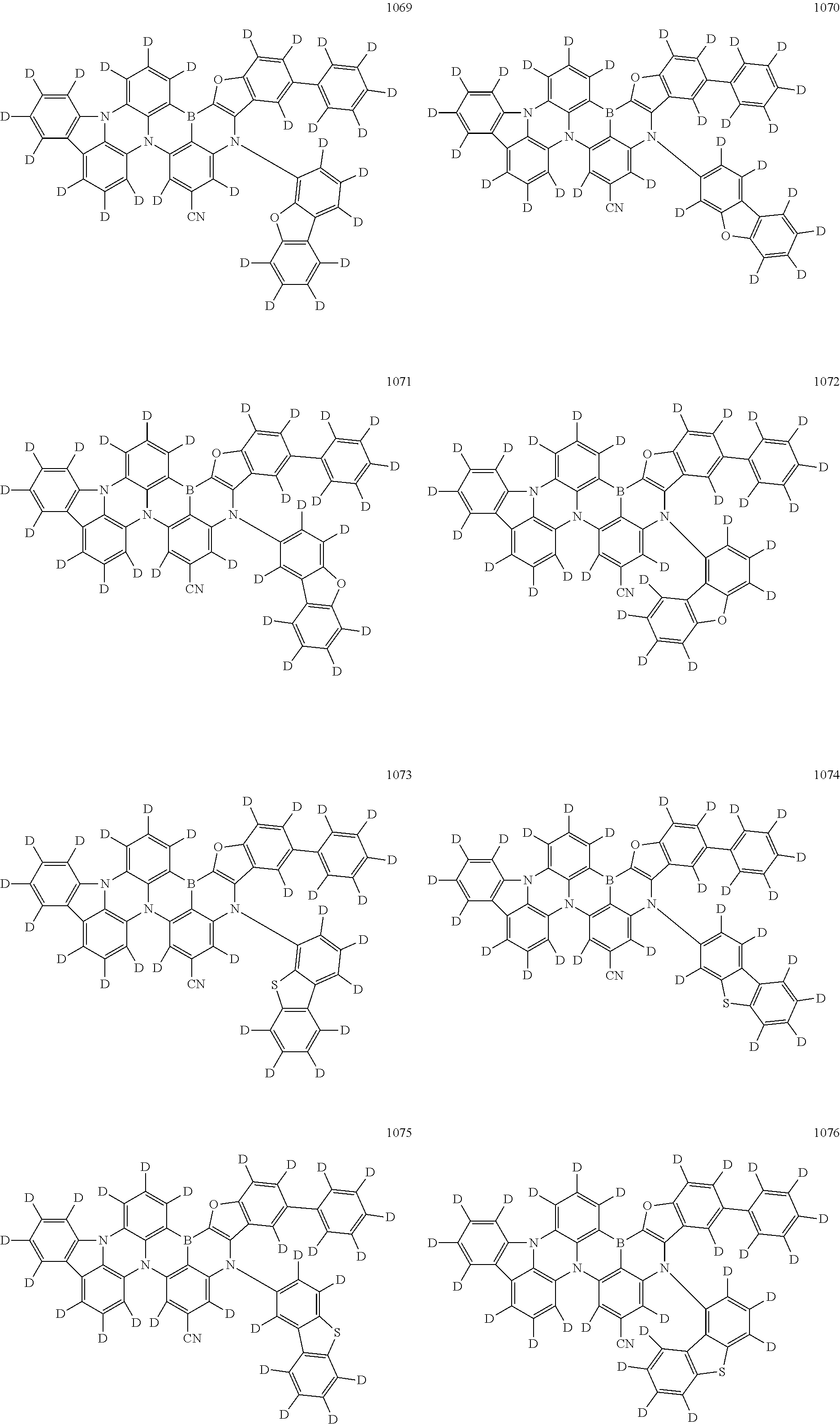

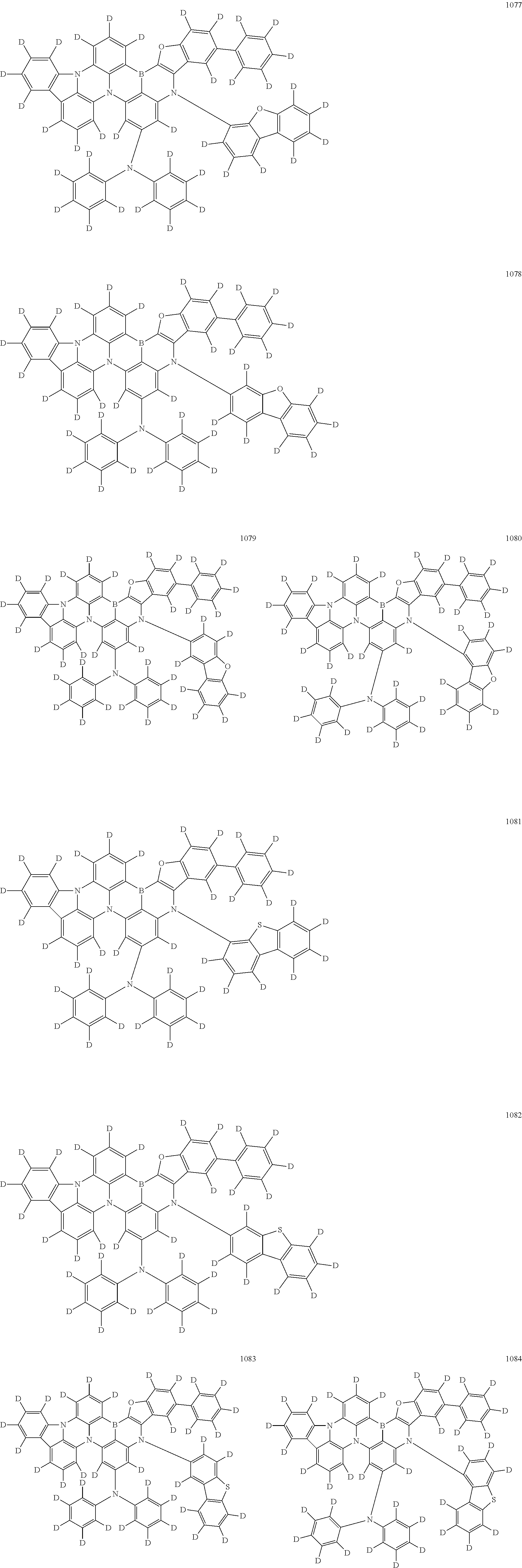

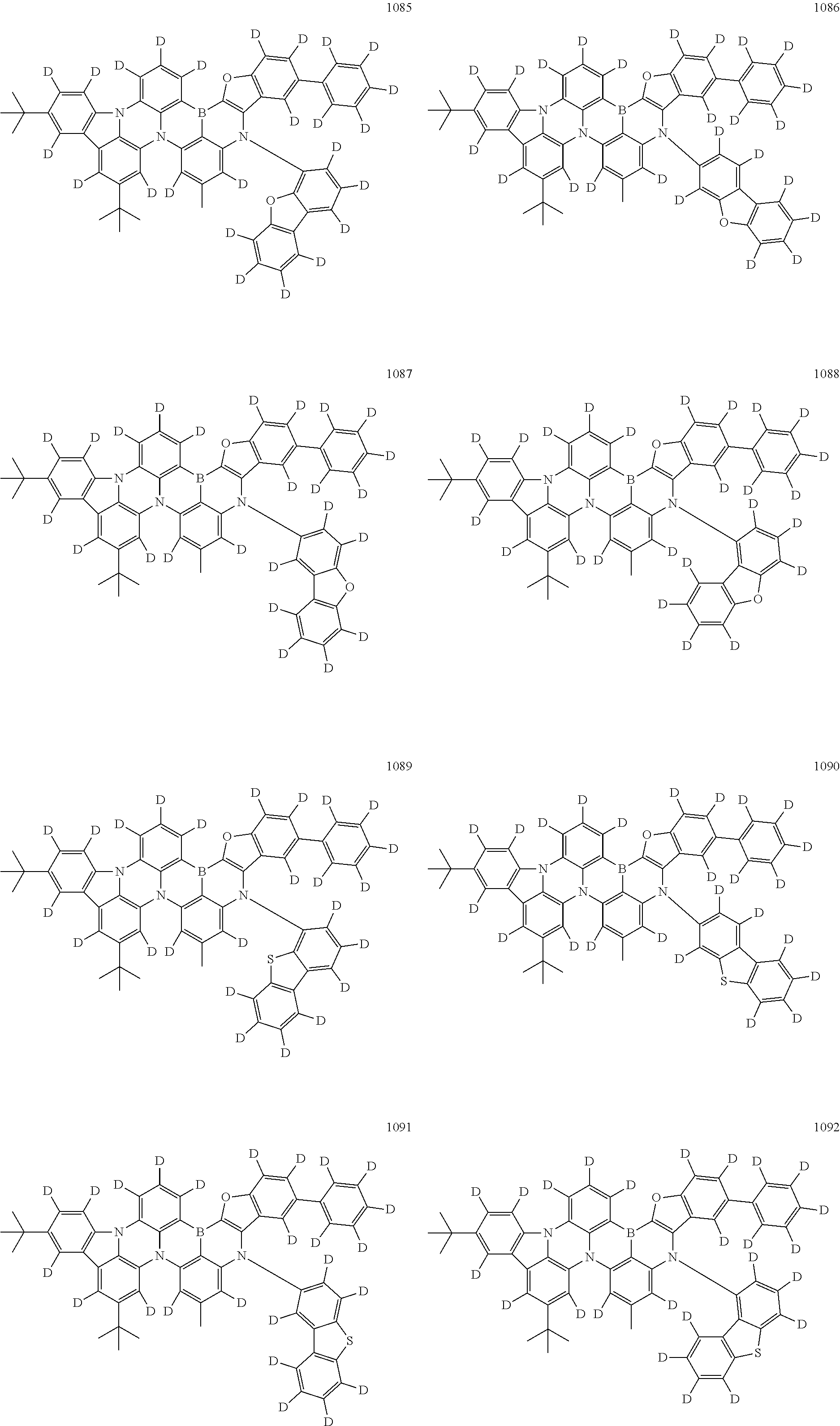

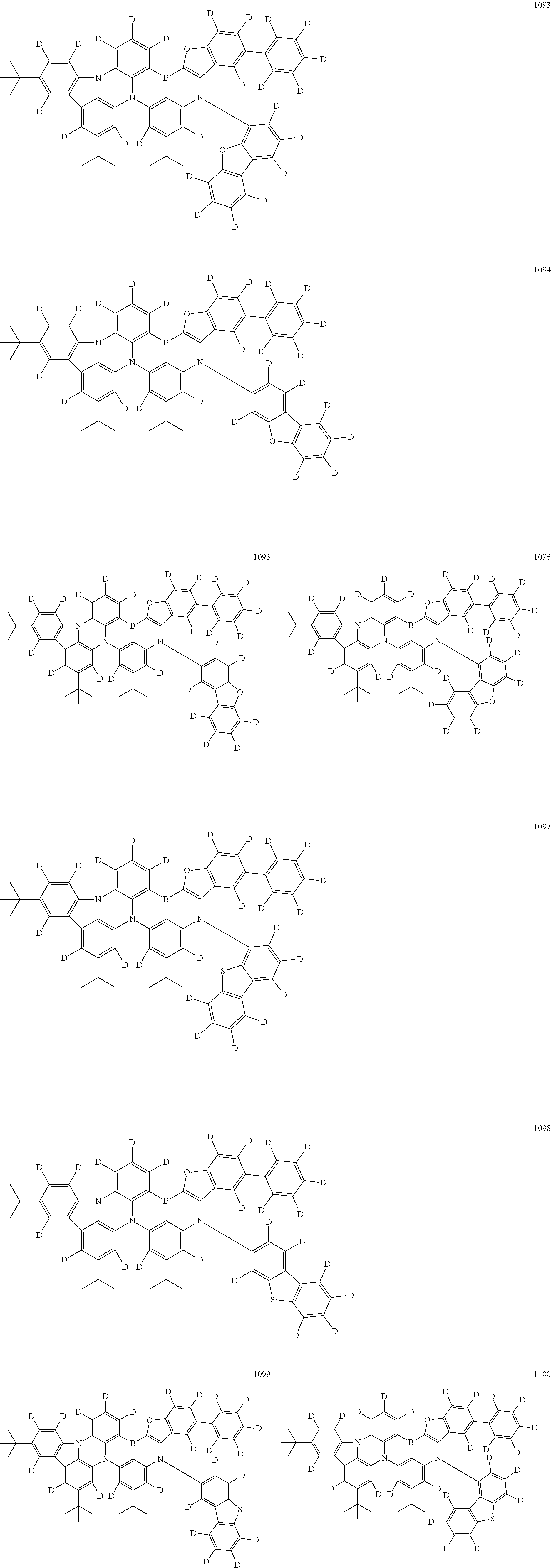

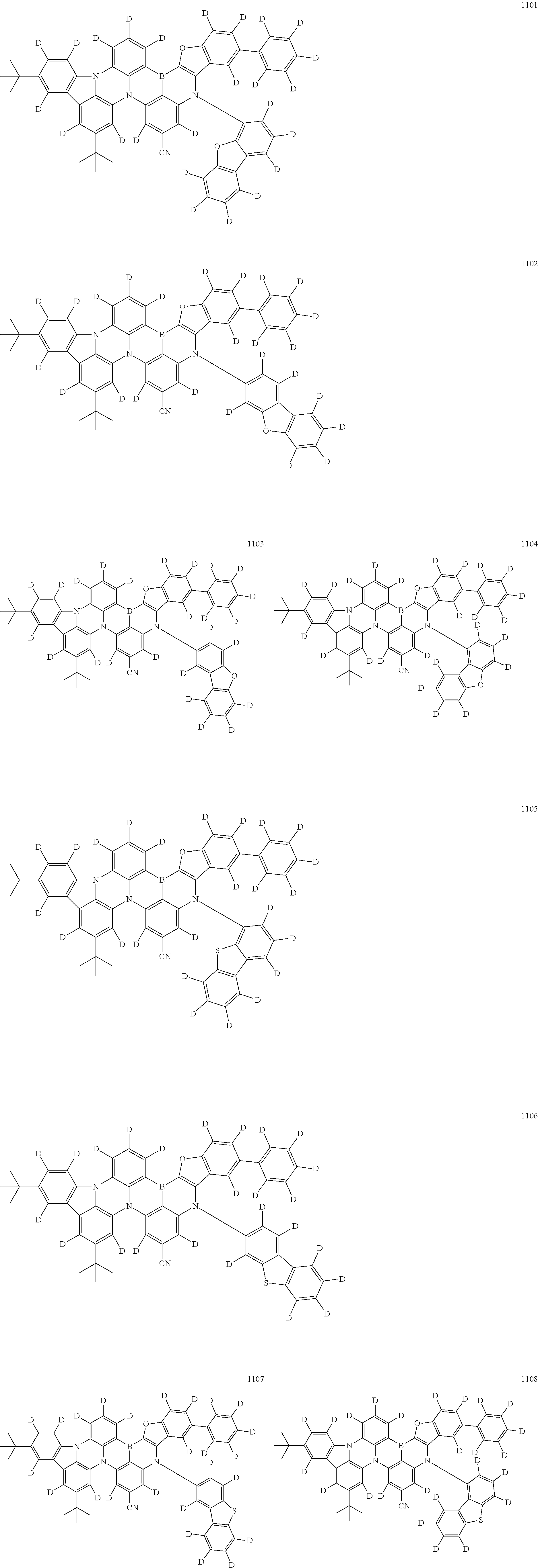

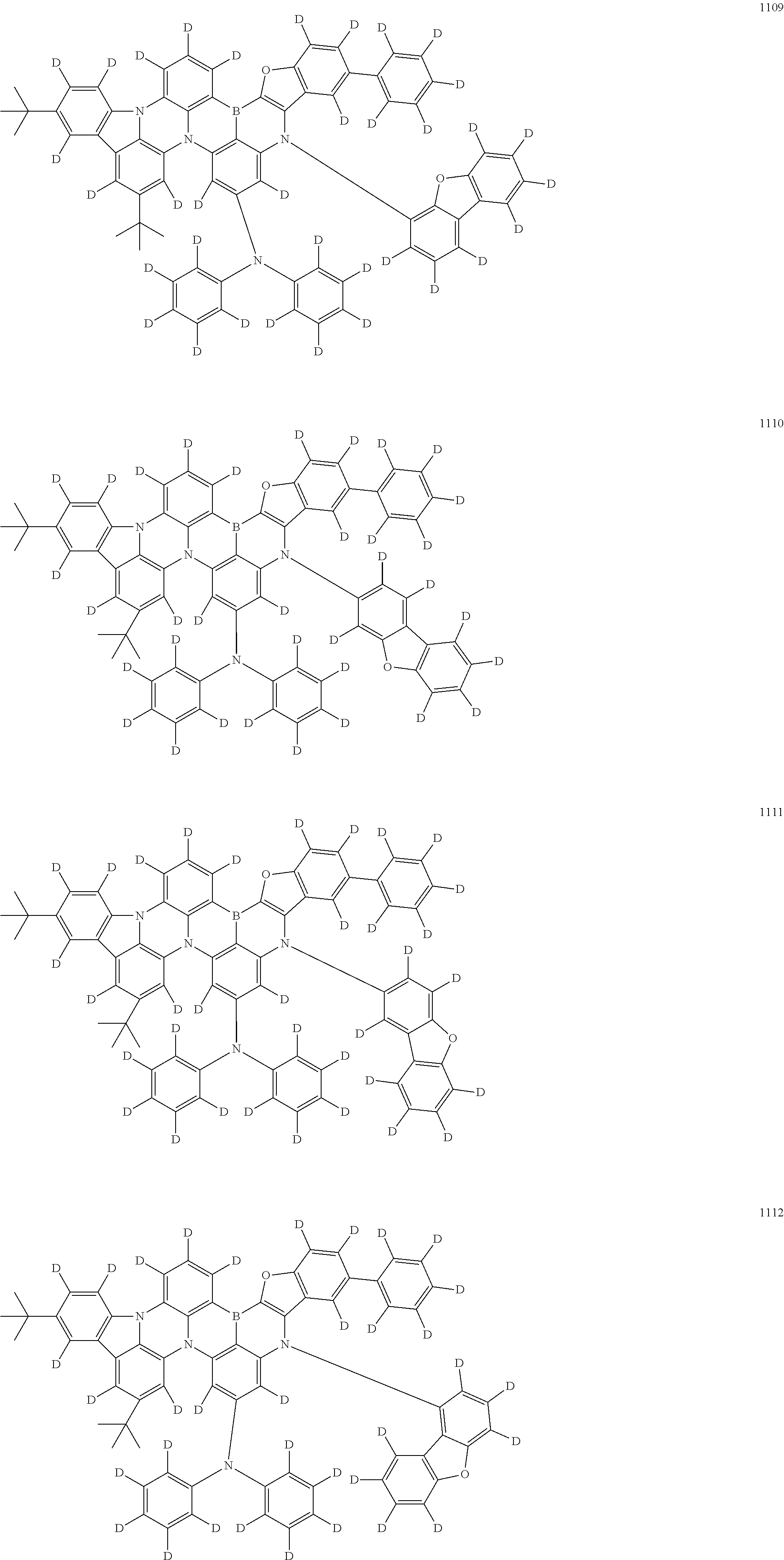

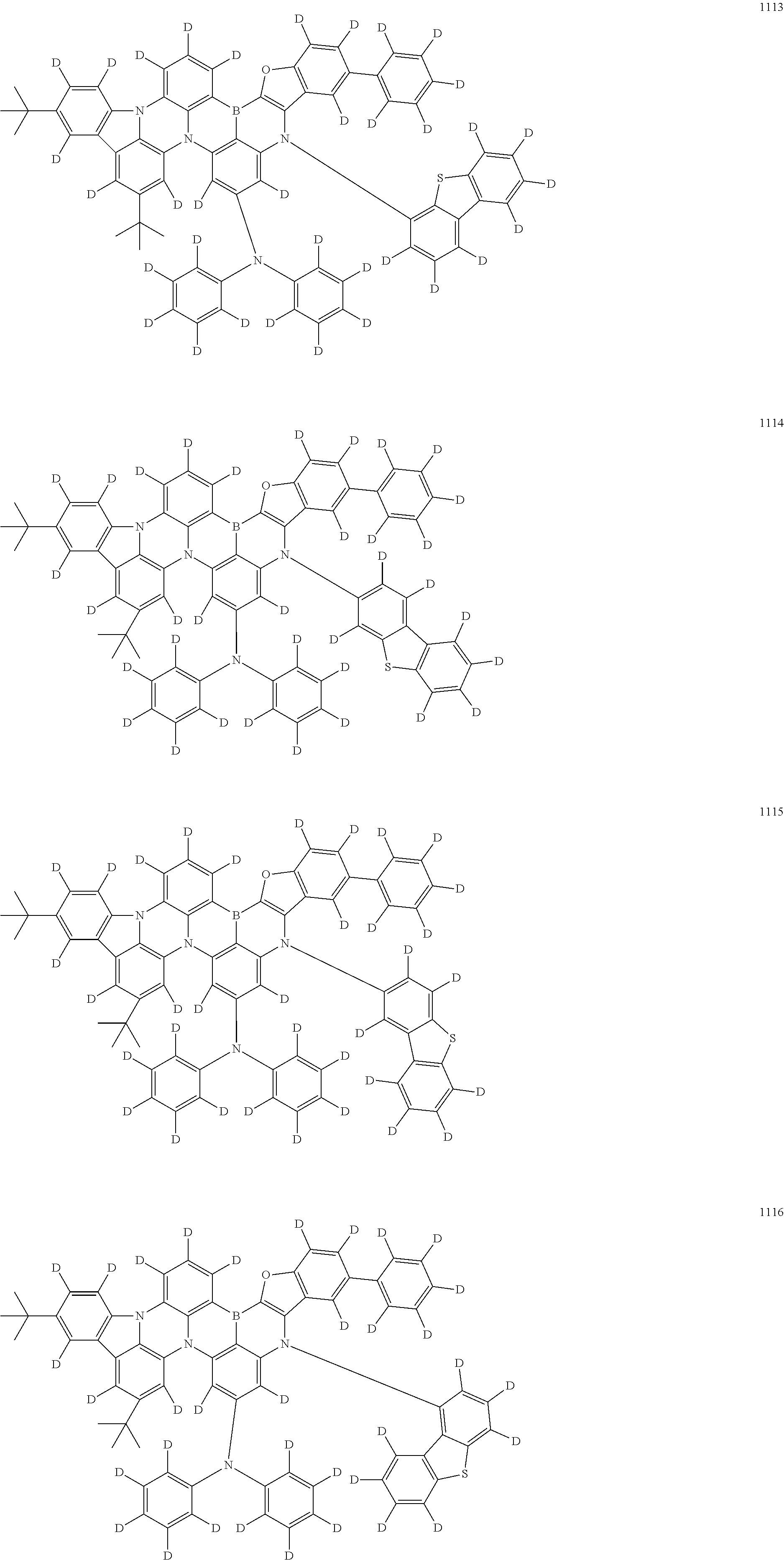

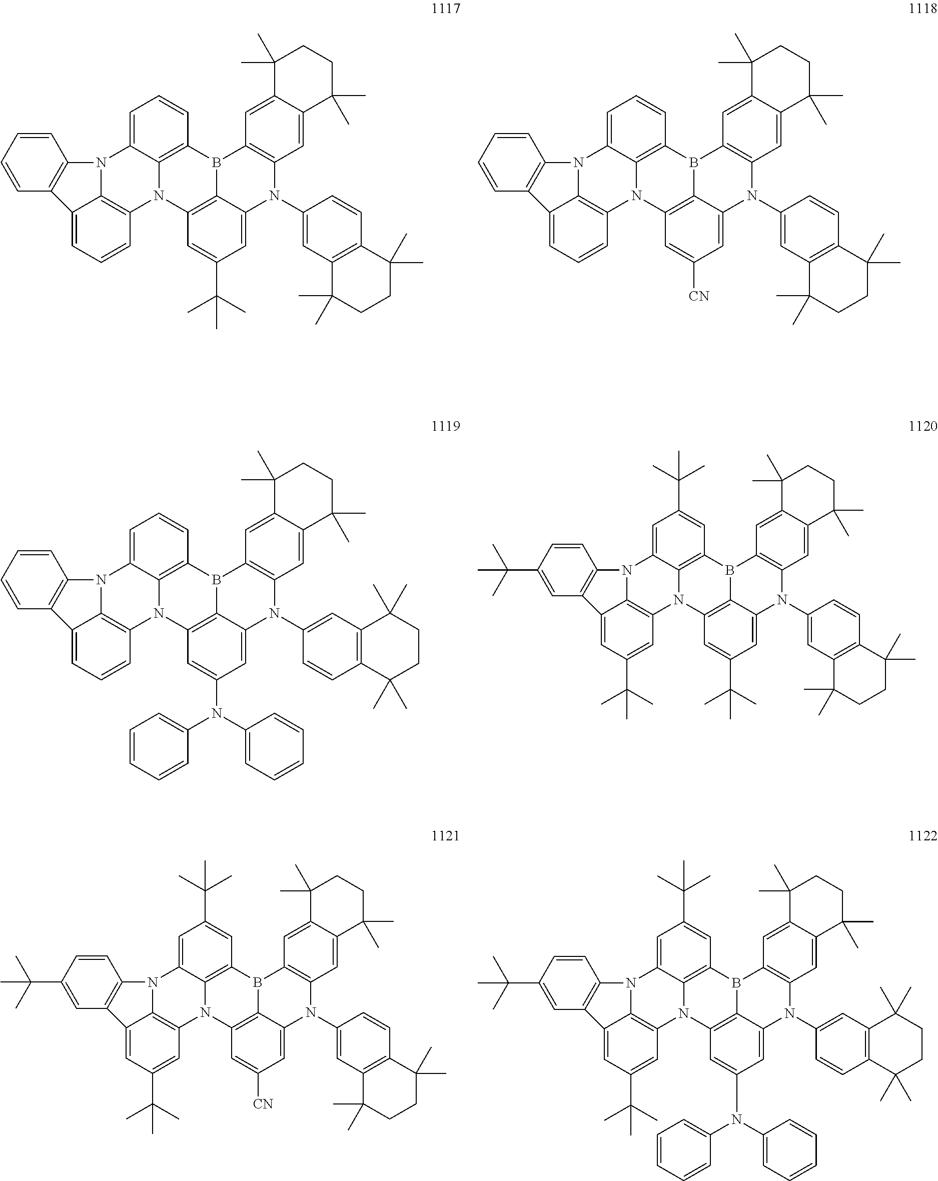

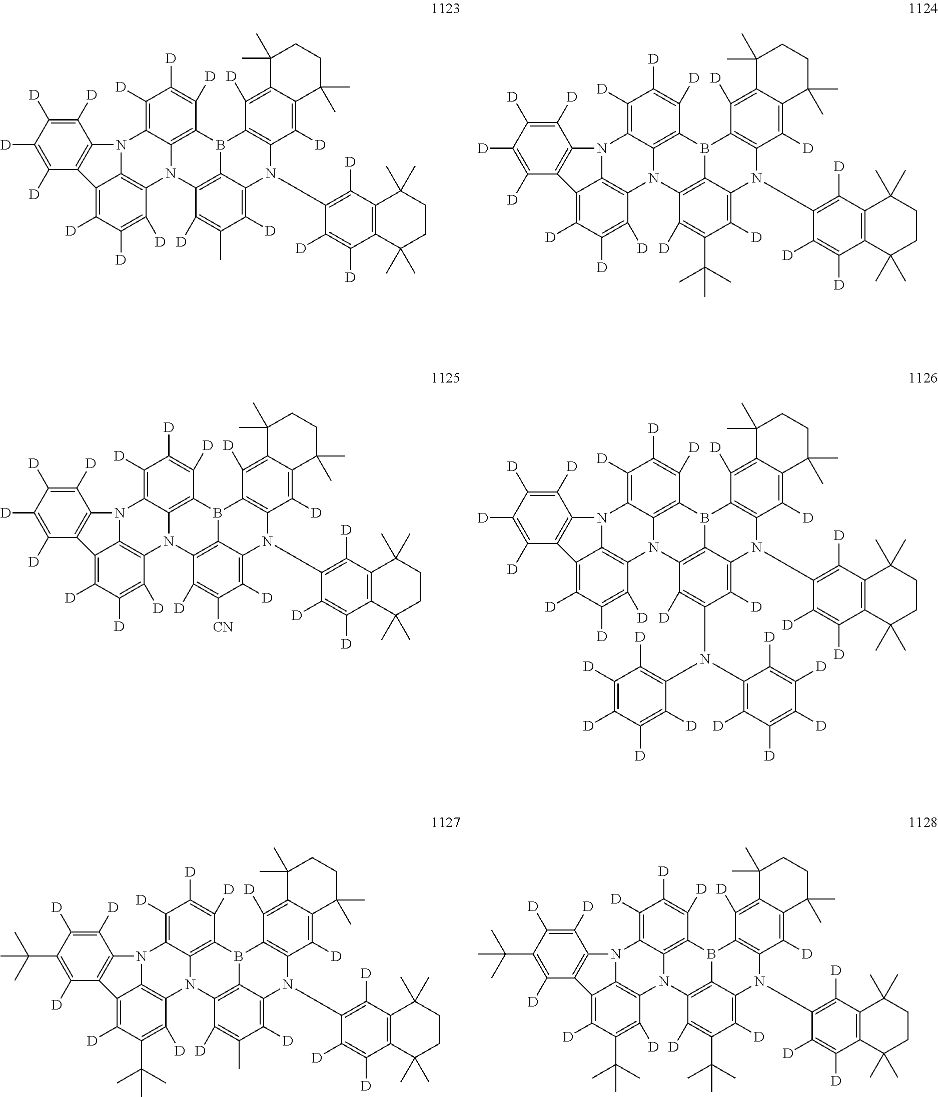

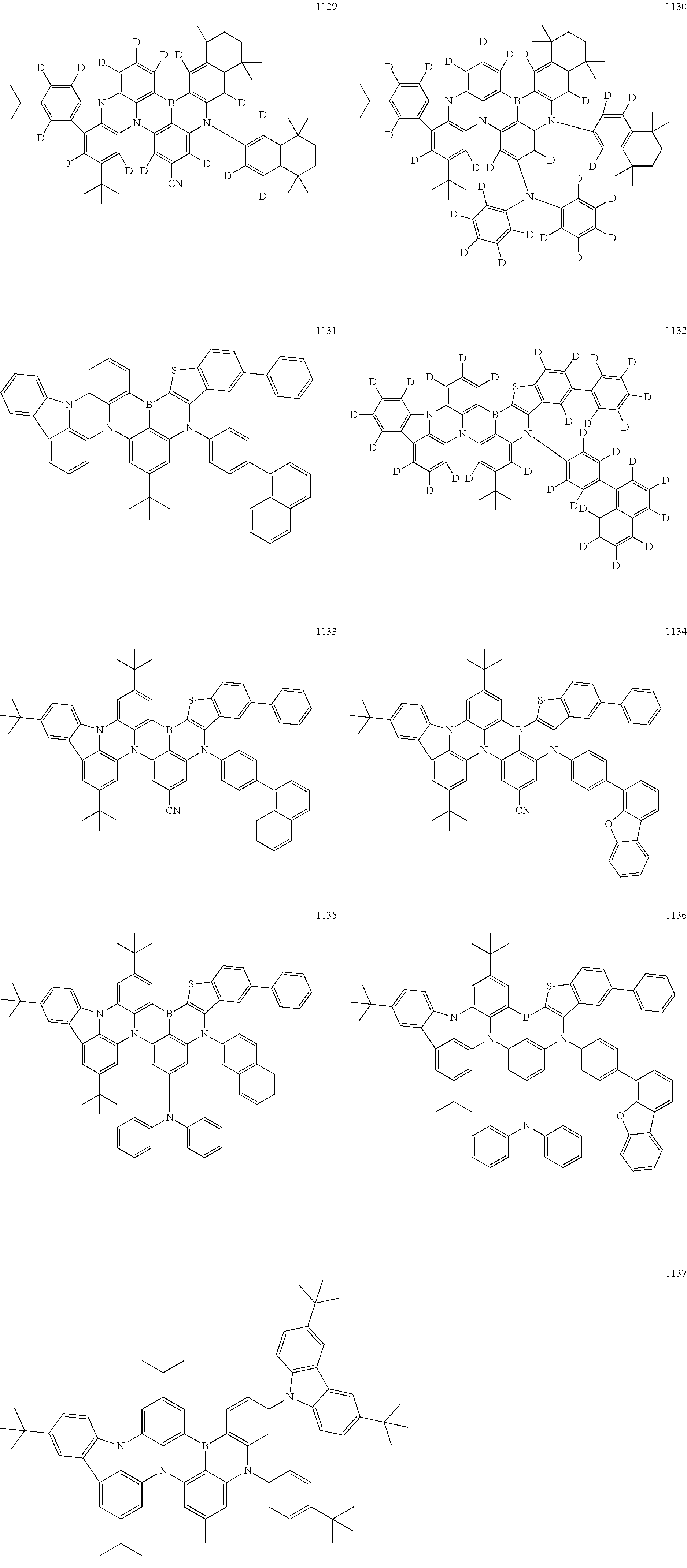

An organic layer of an organic light emitting diode according to one embodiment of the present invention may include at least one of a hole injection layer, a hole transport layer, an electron blocking layer, an emitting layer, a hole blocking layer, an electron transport layer, or an electron injection layer, and may further include a charge generation layer, a hole transport aid layer, an emitting aid layer, an electron transport auxiliary layer, and the like.

For example, the organic light emitting diode may have a structure in which a first electrode (anode), a hole injection layer (HIL), a hole transport layer (HTL), an electron blocking layer (EBL), an emitting layer (EML), a hole blocking layer (HBL), an electron transport layer (ETL), an electron injection layer (EIL), and a second electrode (cathode) are stacked sequentially.

For example, the first electrode may include a transparent and highly conductive material, such as indium tin oxide (ITO), indium zinc oxide (IZO), tin oxide (SnO₂), zinc oxide (ZnO), and the like.

A compound for the hole injection layer or the hole transport layer is not particularly restricted and may include any compound commonly used for hole injection layers or hole transport layers. Non-limiting examples of the compound for the hole injection layer or the hole transport layer may include phthalocyanine derivatives, porphyrin derivatives, triarylamine derivatives, and indolocarbazole derivatives. For example, the compound for the hole injection layer or the hole transport layer may include 1,4,5,8,9,11-hexaazatriphenylene-hexacarbonitrile (HAT-CN), copper phthalocyanine (CuPc), 4,4′,4″-tris(3-methylphenylamino)triphenylamine (m-MTDATA), 4,4′,4″-tris(3-methylphenylamino)phenoxybenzene (m-MTDAPB), 4,4′,4″-tris(N-carbazolyl)triphenylamine (TCTA), 4,4′,4″-tris(N-(2-naphthyl)-N-phenylamino)-triphenylamine (2-TNATA), N4,N4,N4′,N4′-tetra([1,1′-biphenyl]-4-yl)-[1,1′-biphenyl]-4,4′-diamine, bis(N-(1-naphthyl-n-phenyl))benzidine (α-NPD), N,N′-di(naphthalen-1-yl)-N,N′-biphenyl-benzidine (NPB), N,N′-biphenyl-N,N′-bis(3-methylphenyl)-1,1′-biphenyl-4,4′-diamine (TPD), or the like, without being limited thereto.

In the present invention, the compound represented by Chemical Formula 1 may be included into the emitting layer (EML). For example, the compound represented by Chemical Formula 1 may be used as a dopant of a green emitting layer or a blue emitting layer, preferably a green emitting layer, thereby improving performance of the organic light emitting diode.

As a host compound for the emitting layer, at least one luminescent host material, for example, a hole transport host, an electron transport host, or a combination thereof, may be used. Non-limiting examples of the luminescent host compound include condensed ring derivatives, such as anthracene or pyrene, bis-styryl derivatives, such as bis-styryl anthracene derivatives or distyrylbenzene derivatives, tetraphenylbutadiene derivatives, cyclopentadiene derivatives, fluorene derivatives, benzofluorene derivatives, N-phenylcarbazole derivatives, carbazonitrile derivatives, and the like. Non-limiting examples of the hole transport host include carbazole derivatives, dibenzofuran derivatives, dibenzothiophene derivatives, triarylamine derivatives, indolocarbazole derivatives, and benzooxazinophenoxazine derivatives. Non-limiting examples of the electron transport host include pyridine derivatives, triazine derivatives, phosphine oxide derivatives, benzofuropyridine derivatives, and dibenzoxacillin derivatives. For example, the host compound for the emitting layer may include 9,10-bis(2-naphthyl)anthracene (ADN), tris(8-hydroxyquinolinato)aluminium (Alq₃), 8-hydroxyquinoline beryllium salt (BAlq), 4,4′-bis(2,2-biphenylethynyl)-1,1′-biphenyl (DPVBi), spiro-4,4′-bis(2,2-biphenylethenyl)-1,1′-biphenyl (spiro-DPVBi), 2-(2-benzoxazolyl)-phenol lithium salt (LiPBO), bis(biphenylvinyl)benzene, aluminum-quinoline metal complexes, metal complexes of imidazole, thiazole, and oxazole, and the like.

According to one embodiment, when the compound represented by Chemical Formula 1 is used as a dopant of a green emitting layer, a host of the green emitting layer may include 5-(3-(dibenzo[b,d]furan-1-yl)phenyl)-5H-benzofuro[3,2-c]carbazole and a compound disclosed in WO2020122118A, WO2022196749A, or WO2022230574A. When the compound represented by Chemical Formula 1 is used as a dopant of a blue emitting layer, a host of the blue emitting layer may include 9-(1-naphthyl)-10-(2-naphthyl)anthracene and a compound disclosed in WO2005061656A or JP2005314239A.

According to one embodiment, the dopant may be present in an amount of 1 wt % to 20 wt %, for example, 2 wt % to 15 wt %, for example, 3 wt % to 10 wt %, for example, 4 wt % to 6 wt %, based on the total weight of the dopant and the host of the emitting layer.

The electron blocking layer (EBL) may be formed between the hole transport layer and the emitting layer. A compound for the electron blocking layer is not particularly restricted and may include any compound commonly used for electron blocking layers. For example, the electron blocking layer may include N-phenyl-N-(4-(spiro[benzo[d,e]anthracene-7,9′-fluoren]-2′-yl)phenyl)dibenzo[b,d]furan-4-amine) and the like.

A compound for the electron injection layer or the electron transport layer is not particularly restricted and may include any compound commonly used for electron injection layers or electron transport layers. Non-limiting examples of the compound for the electron injection layer or the electron transport layer include pyridine derivatives, naphthalene derivatives, anthracene derivatives, phenanthroline derivatives, perinone derivatives, coumarin derivatives, naphthalimide derivatives, anthraquinone derivatives, diphenoquinone derivatives, diphenylquinone derivatives, perylene derivatives, oxadiazole derivatives, thiophene derivatives, triazole derivatives, thiadiazole derivatives, metal complexes of auxin derivatives, quinolinol-based metal complexes, quinoxaline derivatives, polymers of quinoxaline derivatives, benzazole compounds, gallium complexes, pyrazole derivatives, perfluorinated phenylene derivatives, triazine derivatives, pyrazine derivatives, benzoquinoline derivatives, imidazopyridine derivatives, borane derivatives, benzoimidazole derivatives, benzooxazole derivatives, benzothiazole derivatives, quinoline derivatives, oligopyridine derivatives, such as terpyridine, bipyridine derivatives, terpyridine derivatives, naphthyridine derivatives, aldazine derivatives, carbazole derivatives, indole derivatives, phosphine oxide derivatives, bis-styryl derivatives, quinolinol-based metal complexes, hydroxyazole-based metal complexes, azomethine-based metal complexes, tropolone-based metal complexes, flavonol-based metal complexes, benzoquinoline-based metal complexes, metal salts, and the like. These materials may be used alone or as a mixture thereof. For example, the compound for the electron injection layer or the electron transport layer may include 2-(4-(9,10-di(naphthalen-2-yl)anthracen-2-yl)phenyl)-1-phenyl-1H-benzo[d]imidazole, tris(8-hydroxyquinolinato)aluminium (Alq₃), LiF, Liq, Li₂O , BaO, NaCl, CsF, and the like.

The second electrode (cathode) may include lithium (Li), aluminum (Al), aluminum-lithium (Al—Li ), calcium (Ca), magnesium (Mg), magnesium-indium (Mg—In ), magnesium-silver (Mg—Ag), and the like. In addition, for a top-emission organic light emitting diode, the second electrode may be a light-transmissive cathode formed of indium tin oxide (ITO) or indium zinc oxide (IZO).

The first electrode or the second electrode may be provided on a surface thereof with one or more capping layers (protective or encapsulation layers). A compound for the capping layer is not particularly restricted and may include any compound commonly used for capping layers. Non-limiting examples of the compound for the capping layer include arylamine derivatives, naphthalene derivatives, anthracene derivatives, phenanthrene derivatives, carbazole derivatives, pyridine derivatives, dibenzofuran derivatives, dibenzothiophene derivatives, pyrimidine derivatives, quinoline derivatives, isoquinoline derivatives, benzoxazole derivatives, benzothiazole derivatives, benzoimidazole derivatives, N4,N4′-bis[4-[bis(3-methylphenyl)amino]phenyl]-N4,N4′-diphenyl-[1,1′-biphenyl]-4,4′-diamine (DNTPD), tris(8-hydroxyquinolinato)aluminium(Alq₃), LiF, Liq, Li₂O , BaO, NaCl, CsF, and the like.

The organic light emitting diode according to one embodiment of the present invention may be a top-emission organic light emitting diode or a bottom-emission organic light emitting diode.

The organic light emitting diode according to one embodiment of the present invention may be used in display apparatuses.

The organic light emitting diode according to one embodiment of the present invention may be used in a transparent display apparatus, a mobile display apparatus, a flexible display apparatus, and the like, without being limited thereto.

Next, synthetic examples, preparative examples, and experimental examples of the aforementioned compounds will be described by way of representative examples. However, it should be noted that methods of synthesizing the compounds of the present invention are not limited to the methods described below, or that practice of the present invention is not limited to the following examples.

### Synthetic Example

A final product of the present invention may be synthesized according to Scheme 1 (Buchwald-Hartwig Cross Coupling Reaction), without being limited thereto.

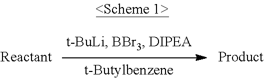

The organic compound represented by Chemical Formula 1 of the present invention (“Product”) may be synthesized according to Scheme 1, and a specific synthesis method is as follows, without being limited thereto.

In a 500 mL flask under nitrogen (N₂) atmosphere, 20.0 mmol (1 eq) of Reactant and 10 volume of t-butylbenzene were placed. Then, 40.0 mmol (2 eq) of t-butyllithium (t-BuLi) was slowly added at −78° C., followed by stirring at room temperature for 1 hour and at 70° C. for 2 hours. After confirming complete consumption of Reactant by thin-layer chromatography (TLC), 40 mmol (2 eq) of boron tribromide (BBr₃) was added at −78° C., followed by stirring at room temperature for 1 hour and at 70° C. for 2 hours. After confirming completion of the reaction by TLC, 40.0 mmol (2 eq) of diisopropylethylamine (DIPEA) was added, followed by stirring at room temperature for 2 hours, and then water was added and an organic layer was extracted with dichloromethane. The extracted organic layer was dried over MgSO₄, filtered, and concentrated, followed by purification by silica gel column chromatography. Thereafter, the purified organic layer was recrystallized from a mixture of dichloromethane and acetone, thereby obtaining Product as shown in Table 1.

TABLE 1

| | | | Ac- | |
|---|---|---|---|---|
| | | | tual | |
| | | | yield | |
| | | | (per- | MS |
| Com- | | | cent | [M + |
| pound | Reactant | Product | yield) | H]+ |
| 1 | 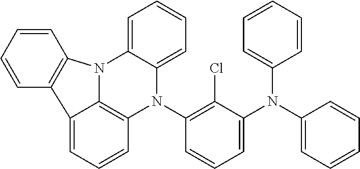 [SMILES: Clc1c(N(c2ccccc2)c2ccccc2)cccc1N1c2ccccc2-n2c3ccccc3c3cccc1c32] | 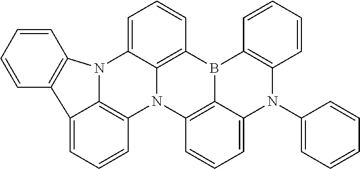 [SMILES: c1ccc(N2c3ccccc3B3c4cccc5c4N(c4cccc2c43)c2cccc3c4ccccc4n-5c23)cc1] | 1.82 g (17%) | 507.19 |
| 7 | 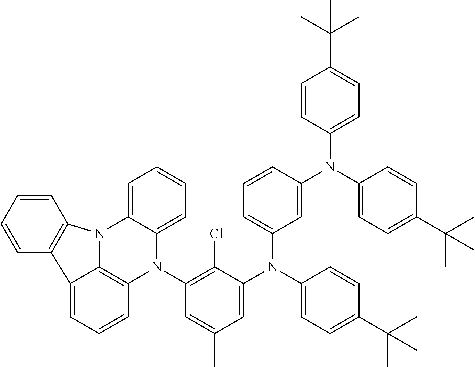 [SMILES: Cc1cc(N(c2ccc(C(C)(C)C)cc2)c2cccc(N(c3ccc(C(C)(C)C)cc3)c3ccc(C(C)(C)C)cc3)c2)c(Cl)c(N2c3ccccc3-n3c4ccccc4c4cccc2c43)c1] | 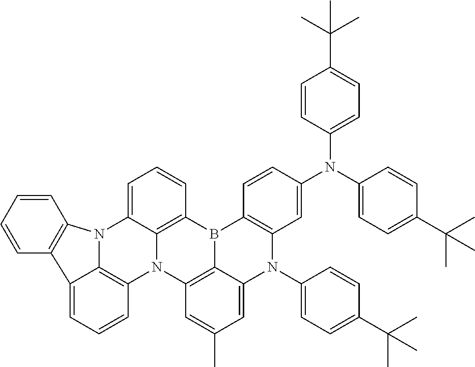 [SMILES: Cc1cc2c3c(c1)N1c4c(cccc4-n4c5ccccc5c5cccc1c54)B3c1ccc(N(c3ccc(C(C)(C)C)cc3)c3ccc(C(C)(C)C)cc3)cc1N2c1ccc(C(C)(C)C)cc1] | 3.36 g (19%) | 856.47 |
| 8 | 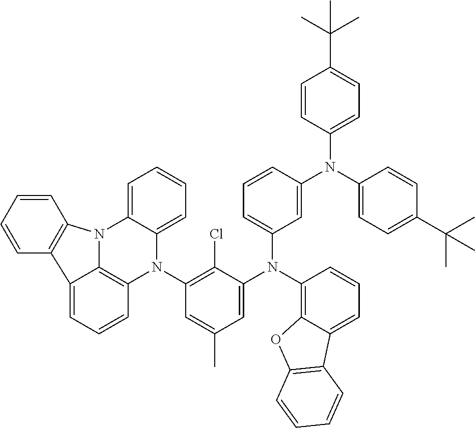 [SMILES: Cc1cc(N(c2cccc(N(c3ccc(C(C)(C)C)cc3)c3ccc(C(C)(C)C)cc3)c2)c2cccc3c2oc2ccccc23)c(Cl)c(N2c3ccccc3-n3c4ccccc4c4cccc2c43)c1] | 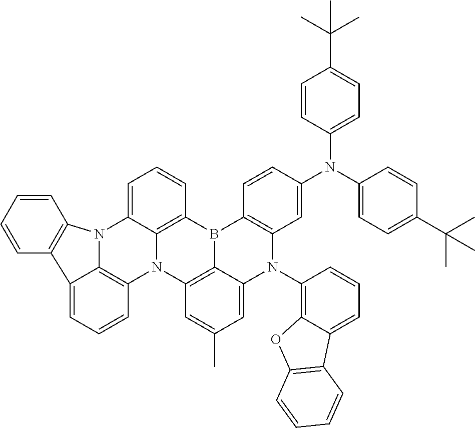 [SMILES: Cc1cc2c3c(c1)N1c4c(cccc4-n4c5ccccc5c5cccc1c54)B3c1ccc(N(c3ccc(C(C)(C)C)cc3)c3ccc(C(C)(C)C)cc3)cc1N2c1cccc2c1oc1ccccc12] | 3.30 g (18%) | 890.42 |
| 13 | 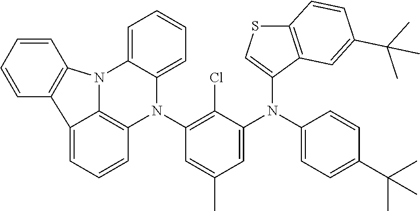 [SMILES: Cc1cc(N(c2ccc(C(C)(C)C)cc2)c2csc3ccc(C(C)(C)C)cc23)c(Cl)c(N2c3ccccc3-n3c4ccccc4c4cccc2c43)c1] | 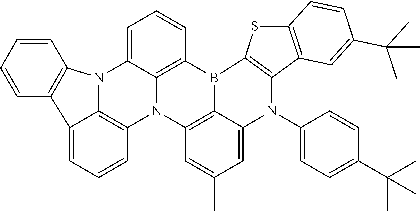 [SMILES: Cc1cc2c3c(c1)N1c4c(cccc4-n4c5ccccc5c5cccc1c54)B3c1sc3ccc(C(C)(C)C)cc3c1N2c1ccc(C(C)(C)C)cc1] | 3.29 g (23%) | 689.30 |
| 21 | 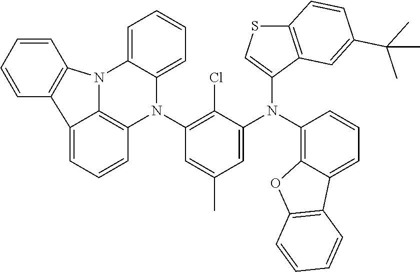 [SMILES: Cc1cc(N(c2csc3ccc(C(C)(C)C)cc23)c2cccc3c2oc2ccccc23)c(Cl)c(N2c3ccccc3-n3c4ccccc4c4cccc2c43)c1] | 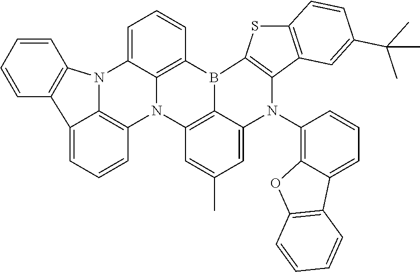 [SMILES: Cc1cc2c3c(c1)N1c4c(cccc4-n4c5ccccc5c5cccc1c54)B3c1sc3ccc(C(C)(C)C)cc3c1N2c1cccc2c1oc1ccccc12] | 3.30 g (22%) | 723.25 |
| 31 | 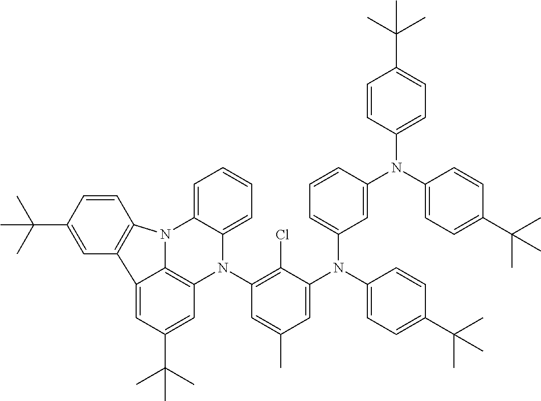 [SMILES: Cc1cc(N(c2ccc(C(C)(C)C)cc2)c2cccc(N(c3ccc(C(C)(C)C)cc3)c3ccc(C(C)(C)C)cc3)c2)c(Cl)c(N2c3ccccc3-n3c4ccc(C(C)(C)C)cc4c4cc(C(C)(C)C)cc2c43)c1] | 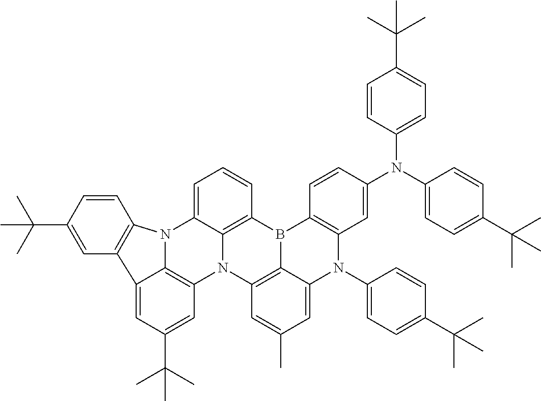 [SMILES: Cc1cc2c3c(c1)N1c4c(cccc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(C(C)(C)C)cc1] | 3.98 g (20%) | 968.59 |
| 32 | 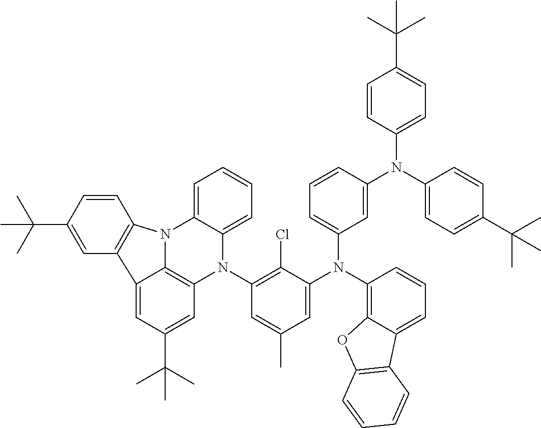 [SMILES: Cc1cc(N(c2cccc(N(c3ccc(C(C)(C)C)cc3)c3ccc(C(C)(C)C)cc3)c2)c2cccc3c2oc2ccccc23)c(Cl)c(N2c3ccccc3-n3c4ccc(C(C)(C)C)cc4c4cc(C(C)(C)C)cc2c43)c1] | 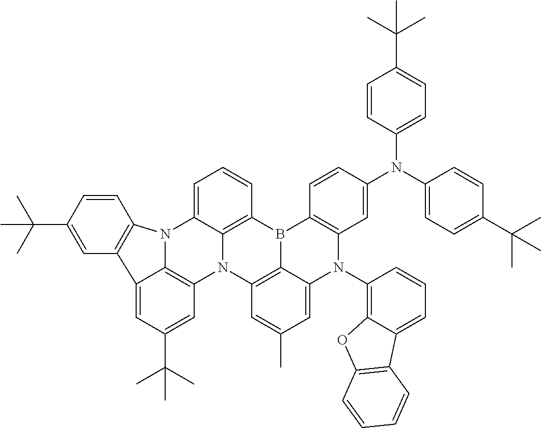 [SMILES: Cc1cc2c3c(c1)N1c4c(cccc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1cccc2c1oc1ccccc12] | 3.91 g (19%) | 1002.54 |
| 37 | 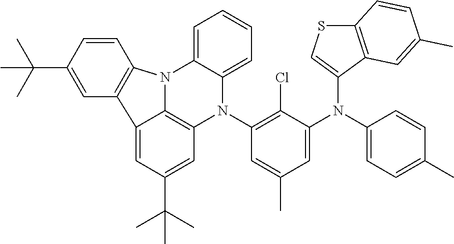 [SMILES: Cc1ccc(N(c2cc(C)cc(N3c4ccccc4-n4c5ccc(C(C)(C)C)cc5c5cc(C(C)(C)C)cc3c54)c2Cl)c2csc3ccc(C)cc23)cc1] | 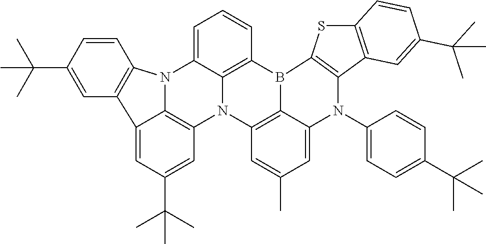 [SMILES: Cc1cc2c3c(c1)N1c4c(cccc4-n4c5ccc(C(C)(C)C)cc5c5cc(C(C)(C)C)cc1c54)B3c1sc3ccc(C(C)(C)C)cc3c1N2c1ccc(C(C)(C)C)cc1] | 3.64 g (22%) | 801.43 |
| 45 | 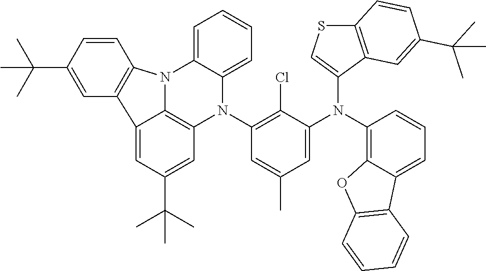 [SMILES: Cc1cc(N(c2csc3ccc(C(C)(C)C)cc23)c2cccc3c2oc2ccccc23)c(Cl)c(N2c3ccccc3-n3c4ccc(C(C)(C)C)cc4c4cc(C(C)(C)C)cc2c43)c1] | 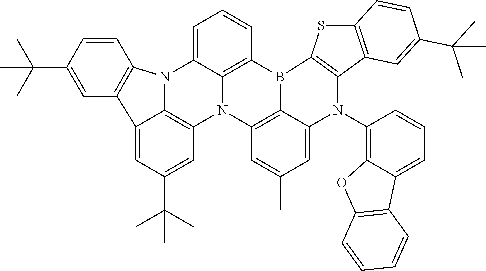 [SMILES: Cc1cc2c3c(c1)N1c4c(cccc4-n4c5ccc(C(C)(C)C)cc5c5cc(C(C)(C)C)cc1c54)B3c1sc3ccc(C(C)(C)C)cc3c1N2c1cccc2c1oc1ccccc12] | 3.45 g (20%) | 835.38 |
| 73 | 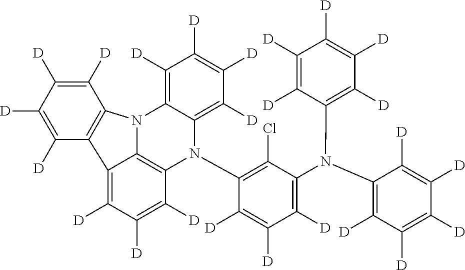 [SMILES: [2H]c1c([2H])c([2H])c(N(c2c([2H])c([2H])c([2H])c([2H])c2[2H])c2c([2H])c([2H])c([2H])c(N3c4c([2H])c([2H])c([2H])c([2H])c4-n4c5c([2H])c([2H])c([2H])c([2H])c5c5c([2H])c([2H])c([2H])c3c54)c2Cl)c([2H])c1[2H]] | 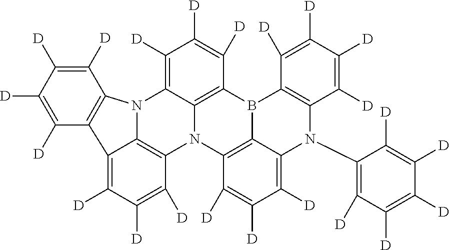 [SMILES: [2H]c1c([2H])c([2H])c(N2c3c([2H])c([2H])c([2H])c([2H])c3B3c4c2c([2H])c([2H])c([2H])c4N2c4c3c([2H])c([2H])c([2H])c4-n3c4c([2H])c([2H])c([2H])c([2H])c4c4c([2H])c([2H])c([2H])c2c43)c([2H])c1[2H]] | 1.45 g (13%) | 528.32 |
| 93 | 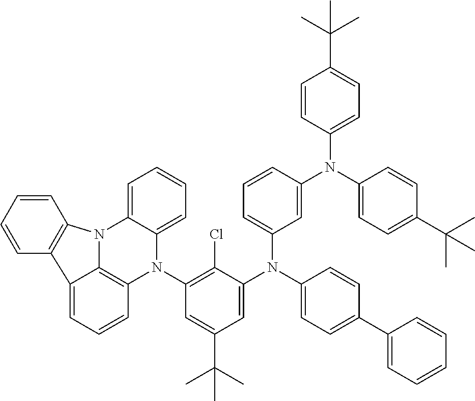 [SMILES: CC(C)(C)c1ccc(N(c2ccc(C(C)(C)C)cc2)c2cccc(N(c3ccc(-c4ccccc4)cc3)c3cc(C(C)(C)C)cc(N4c5ccccc5-n5c6ccccc6c6cccc4c65)c3Cl)c2)cc1] | 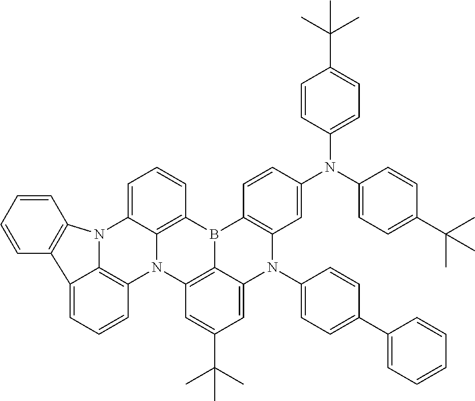 [SMILES: CC(C)(C)c1ccc(N(c2ccc(C(C)(C)C)cc2)c2ccc3c(c2)N(c2ccc(-c4ccccc4)cc2)c2cc(C(C)(C)C)cc4c2B3c2cccc3c2N4c2cccc4c5ccccc5n-3c24)cc1] | 2.67 g (13%) | 918.48 |
| 96 | 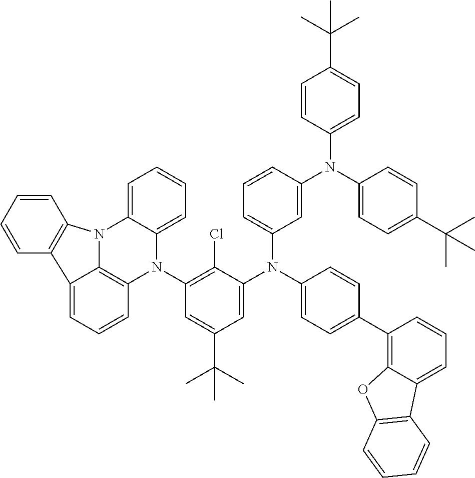 [SMILES: CC(C)(C)c1ccc(N(c2ccc(C(C)(C)C)cc2)c2cccc(N(c3ccc(-c4cccc5c4oc4ccccc45)cc3)c3cc(C(C)(C)C)cc(N4c5ccccc5-n5c6ccccc6c6cccc4c65)c3Cl)c2)cc1] | 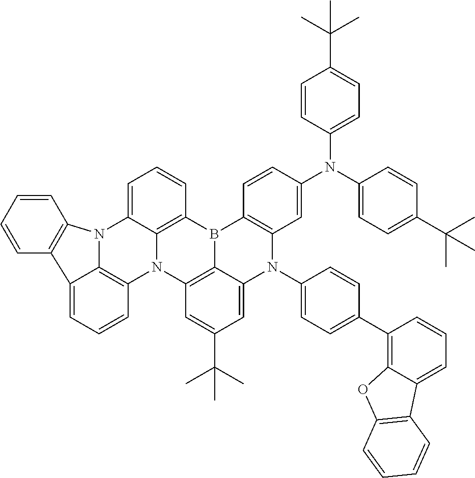 [SMILES: CC(C)(C)c1ccc(N(c2ccc(C(C)(C)C)cc2)c2ccc3c(c2)N(c2ccc(-c4cccc5c4oc4ccccc45)cc2)c2cc(C(C)(C)C)cc4c2B3c2cccc3c2N4c2cccc4c5ccccc5n-3c24)cc1] | 2.46 g (12%) | 1008.49 |
| 102 | 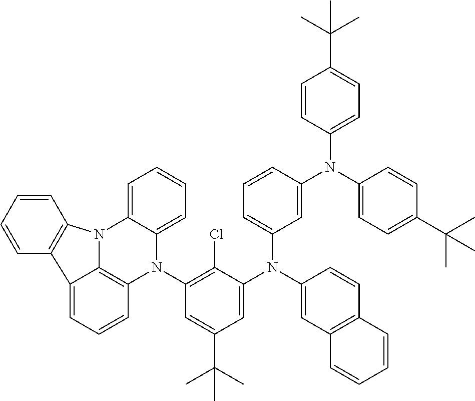 [SMILES: CC(C)(C)c1ccc(N(c2ccc(C(C)(C)C)cc2)c2cccc(N(c3ccc4ccccc4c3)c3cc(C(C)(C)C)cc(N4c5ccccc5-n5c6ccccc6c6cccc4c65)c3Cl)c2)cc1] | 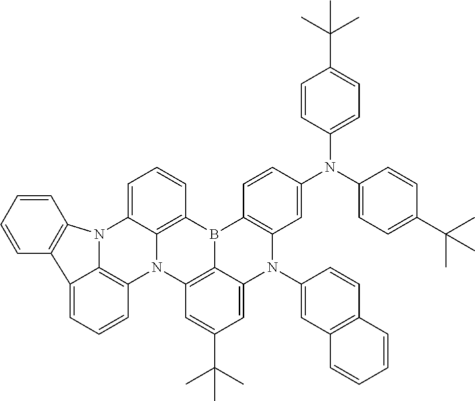 [SMILES: CC(C)(C)c1ccc(N(c2ccc(C(C)(C)C)cc2)c2ccc3c(c2)N(c2ccc4ccccc4c2)c2cc(C(C)(C)C)cc4c2B3c2cccc3c2N4c2cccc4c5ccccc5n-3c24)cc1] | 2.88 g (14%) | 892.47 |
| 104 | 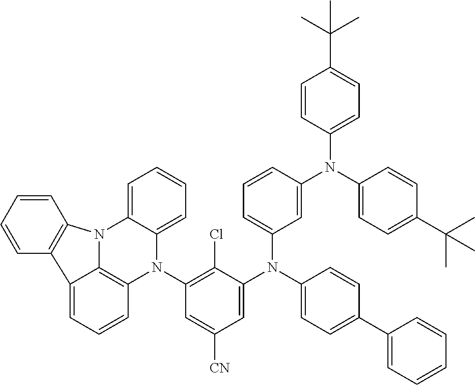 [SMILES: CC(C)(C)c1ccc(N(c2ccc(C(C)(C)C)cc2)c2cccc(N(c3ccc(-c4ccccc4)cc3)c3cc(C#N)cc(N4c5ccccc5-n5c6ccccc6c6cccc4c65)c3Cl)c2)cc1] | 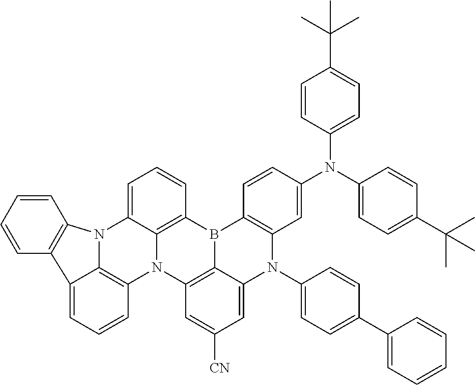 [SMILES: CC(C)(C)c1ccc(N(c2ccc(C(C)(C)C)cc2)c2ccc3c(c2)N(c2ccc(-c4ccccc4)cc2)c2cc(C#N)cc4c2B3c2cccc3c2N4c2cccc4c5ccccc5n-3c24)cc1] | 3.09 g (15%) | 887.42 |
| 107 | 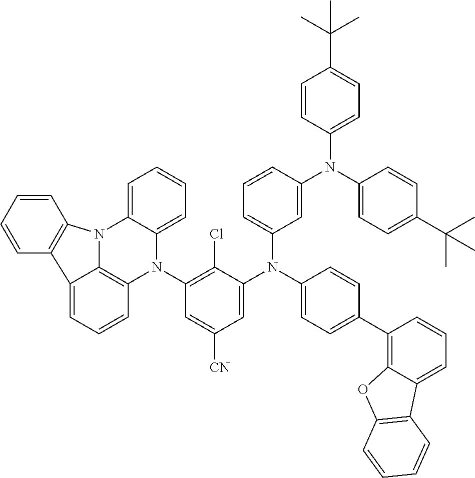 [SMILES: CC(C)(C)c1ccc(N(c2ccc(C(C)(C)C)cc2)c2cccc(N(c3ccc(-c4cccc5c4oc4ccccc45)cc3)c3cc(C#N)cc(N4c5ccccc5-n5c6ccccc6c6cccc4c65)c3Cl)c2)cc1] | 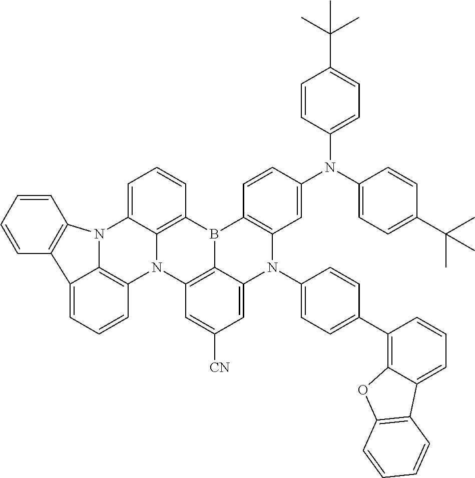 [SMILES: CC(C)(C)c1ccc(N(c2ccc(C(C)(C)C)cc2)c2ccc3c(c2)N(c2ccc(-c4cccc5c4oc4ccccc45)cc2)c2cc(C#N)cc4c2B3c2cccc3c2N4c2cccc4c5ccccc5n-3c24)cc1] | 2.67 g (13%) | 977.43 |
| 125 | 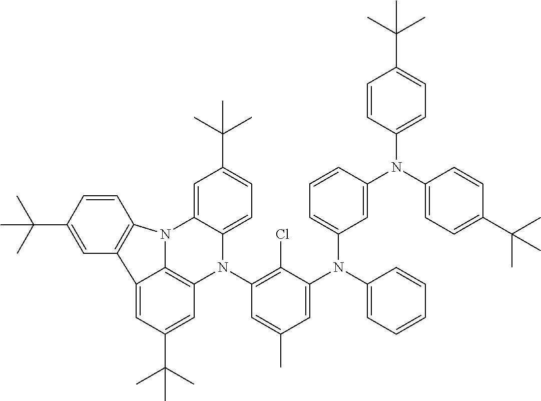 [SMILES: Cc1cc(N(c2ccccc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 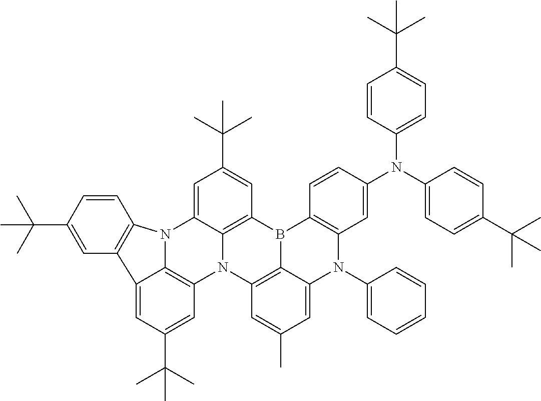 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccccc1] | 3.29 g (16%) | 968.59 |
| 126 | 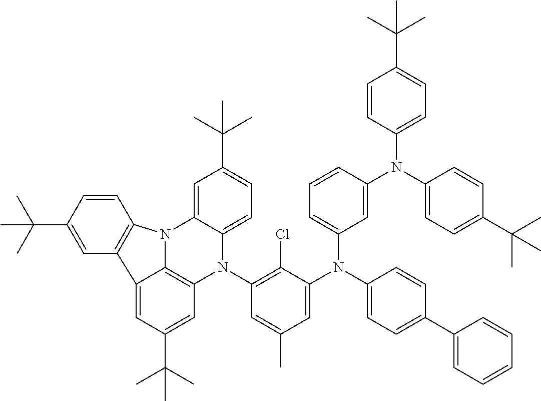 [SMILES: Cc1cc(N(c2ccc(-c3ccccc3)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 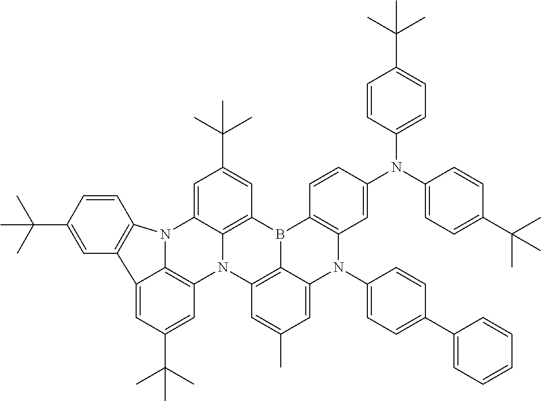 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2ccccc2)cc1] | 2.25 g (11%) | 1044.62 |
| 127 | 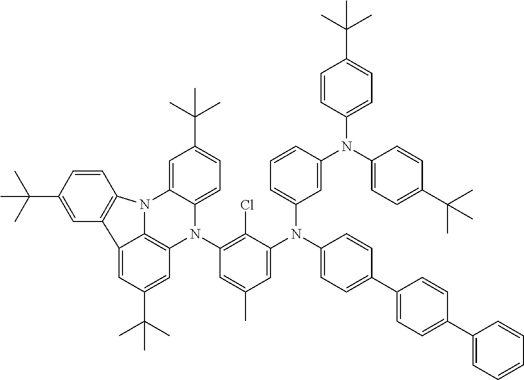 [SMILES: Cc1cc(N(c2ccc(-c3ccc(-c4ccccc4)cc3)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 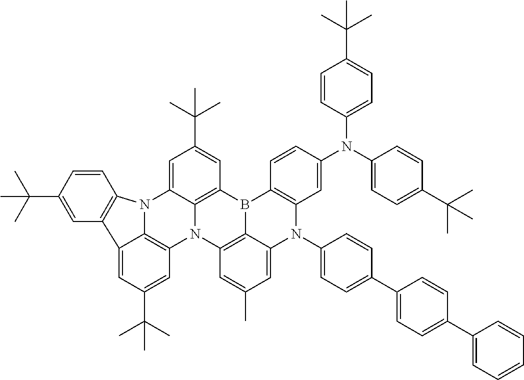 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2ccc(-c3ccccc3)cc2)cc1] | 2.05 g (10%) | 1120.66 |
| 128 | 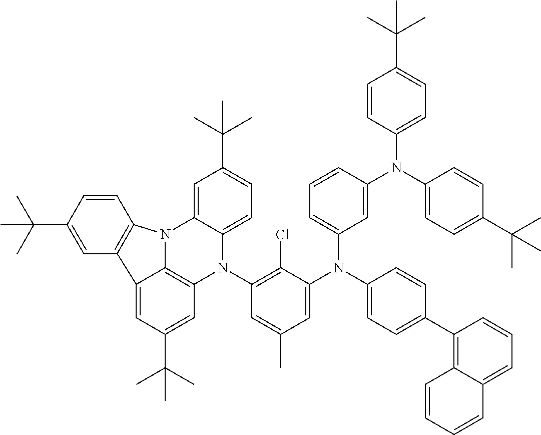 [SMILES: Cc1cc(N(c2ccc(-c3cccc4ccccc34)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 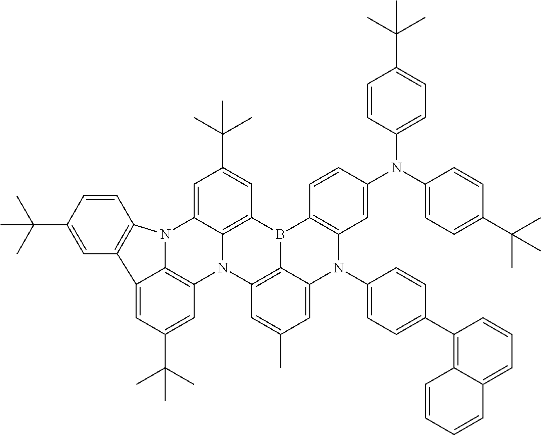 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2cccc3ccccc23)cc1] | 2.46 g (12%) | 1094.64 |
| 129 | 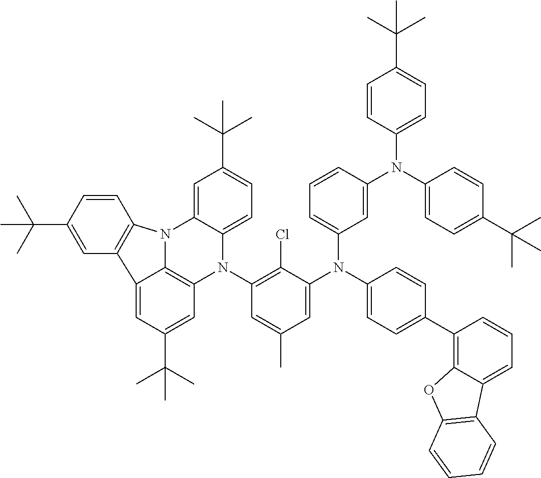 [SMILES: Cc1cc(N(c2ccc(-c3cccc4c3oc3ccccc34)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 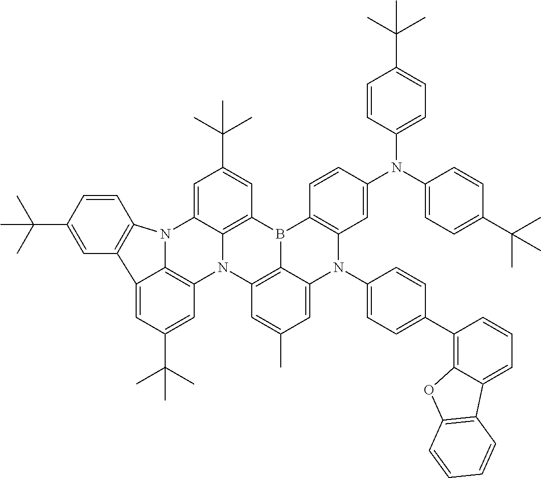 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2cccc3c2oc2ccccc23)cc1] | 2.66 g (13%) | 1134.63 |
| 131 | 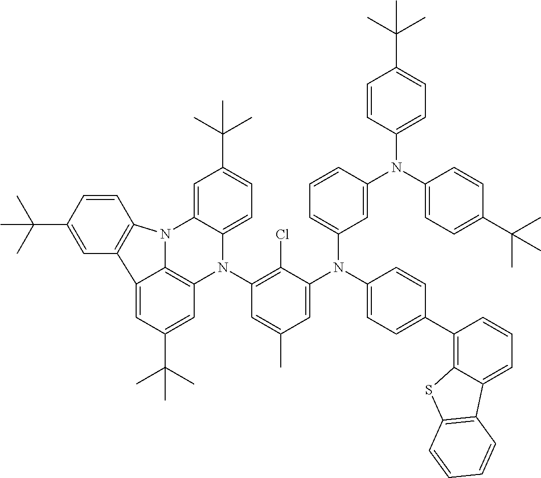 [SMILES: Cc1cc(N(c2ccc(-c3cccc4c3sc3ccccc34)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 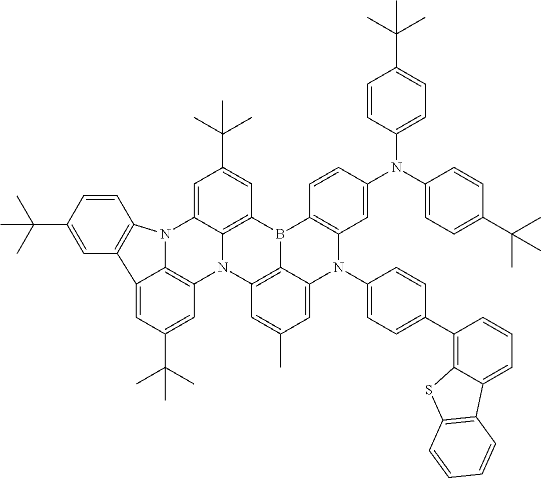 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2cccc3c2sc2ccccc23)cc1] | 3.07 g (15%) | 1150.61 |
| 133 | 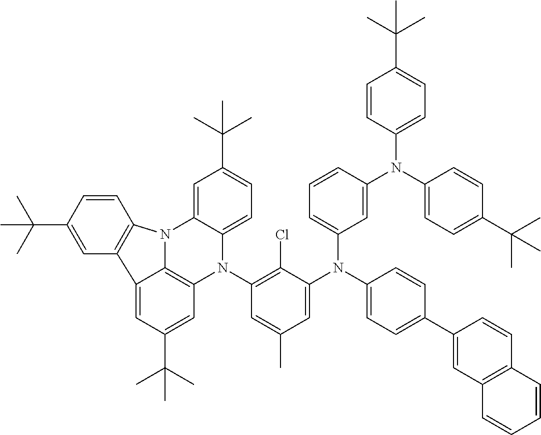 [SMILES: Cc1cc(N(c2ccc(-c3ccc4ccccc4c3)cc2)c2cccc(N(c3ccc(C(C)(C)C)cc3)c3ccc(C(C)(C)C)cc3)c2)c(Cl)c(N2c3ccc(C(C)(C)C)cc3-n3c4ccc(C(C)(C)C)cc4c4cc(C(C)(C)C)cc2c43)c1] | 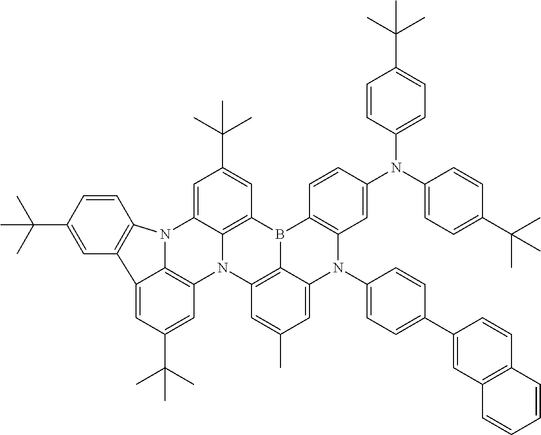 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc(-c2ccc3ccccc3c2)cc1] | 2.46 g (12%) | 1094.64 |
| 134 | 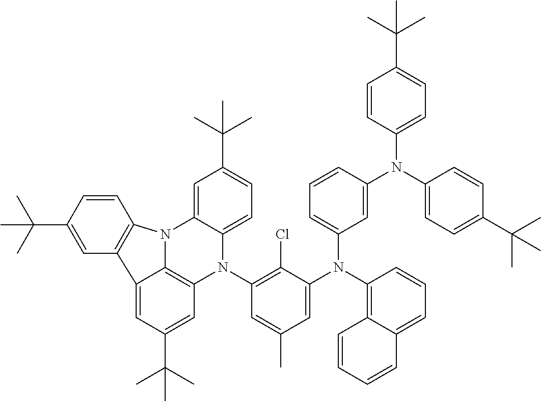 [SMILES: Cc1cc(N(c2cccc(N(c3ccc(C(C)(C)C)cc3)c3ccc(C(C)(C)C)cc3)c2)c2cccc3ccccc23)c(Cl)c(N2c3ccc(C(C)(C)C)cc3-n3c4ccc(C(C)(C)C)cc4c4cc(C(C)(C)C)cc2c43)c1] | 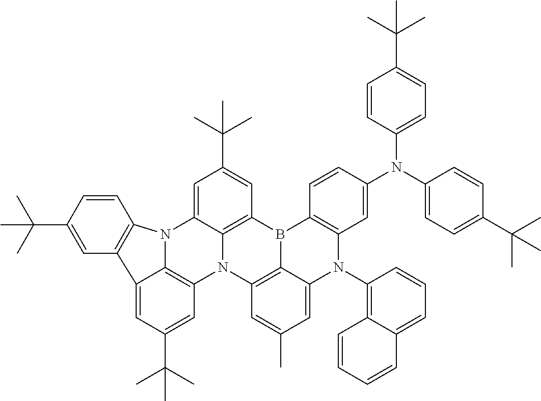 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1cccc2ccccc12] | 3.28 g (16%) | 1018.61 |
| 135 | 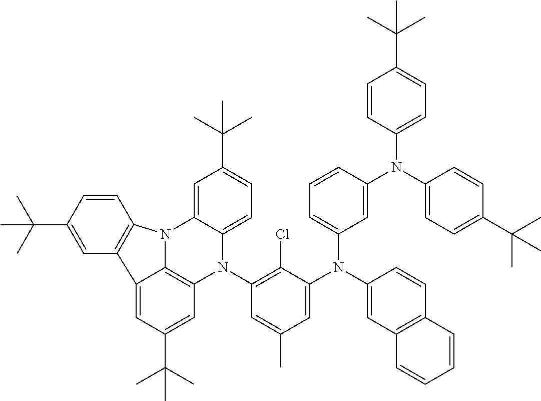 [SMILES: Cc1cc(N(c2cccc(N(c3ccc(C(C)(C)C)cc3)c3ccc(C(C)(C)C)cc3)c2)c2ccc3ccccc3c2)c(Cl)c(N2c3ccc(C(C)(C)C)cc3-n3c4ccc(C(C)(C)C)cc4c4cc(C(C)(C)C)cc2c43)c1] | 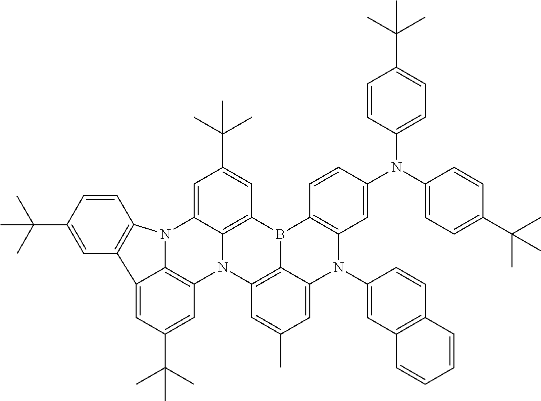 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(N(c3ccc(C(C)(C)C)cc3)c3ccc(C(C)(C)C)cc3)cc1N2c1ccc2ccccc2c1] | 3.08 g (15%) | 1018.61 |
| 159 | 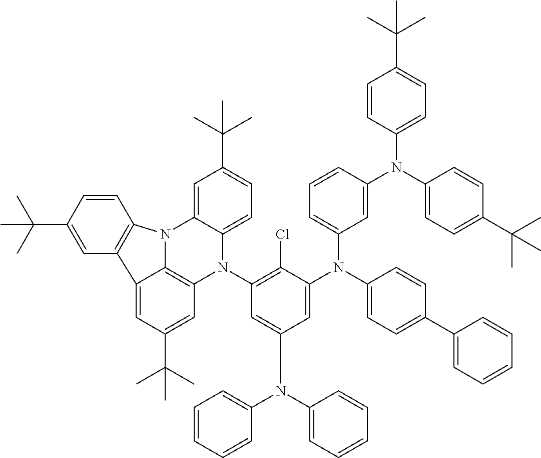 [SMILES: CC(C)(C)c1ccc(N(c2ccc(C(C)(C)C)cc2)c2cccc(N(c3ccc(-c4ccccc4)cc3)c3cc(N(c4ccccc4)c4ccccc4)cc(N4c5ccc(C(C)(C)C)cc5-n5c6ccc(C(C)(C)C)cc6c6cc(C(C)(C)C)cc4c65)c3Cl)c2)cc1] | 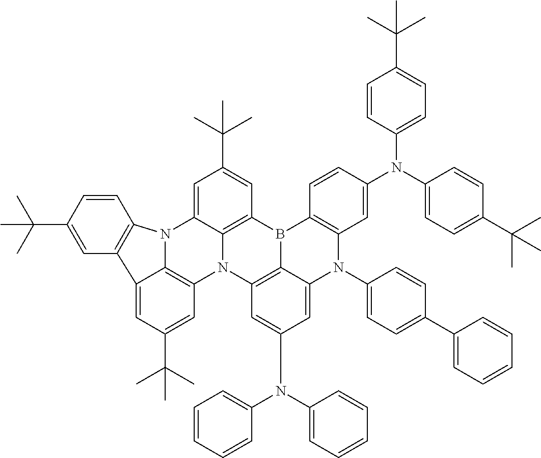 [SMILES: CC(C)(C)c1ccc(N(c2ccc(C(C)(C)C)cc2)c2ccc3c(c2)N(c2ccc(-c4ccccc4)cc2)c2cc(N(c4ccccc4)c4ccccc4)cc4c2B3c2cc(C(C)(C)C)cc3c2N4c2cc(C(C)(C)C)cc4c5cc(C(C)(C)C)ccc5n-3c24)cc1] | 3.47 g (17%) | 1197.68 |
| 325 | 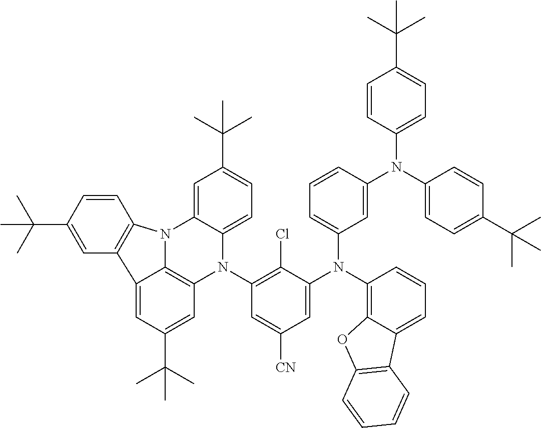 [SMILES: CC(C)(C)c1ccc(N(c2ccc(C(C)(C)C)cc2)c2cccc(N(c3cc(C#N)cc(N4c5ccc(C(C)(C)C)cc5-n5c6ccc(C(C)(C)C)cc6c6cc(C(C)(C)C)cc4c65)c3Cl)c3cccc4c3oc3ccccc34)c2)cc1] | 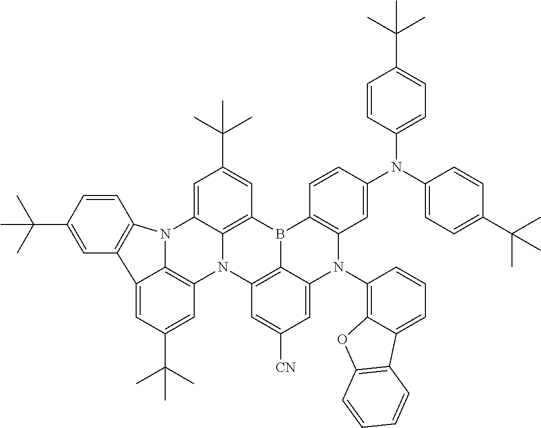 [SMILES: CC(C)(C)c1ccc(N(c2ccc(C(C)(C)C)cc2)c2ccc3c(c2)N(c2cccc4c2oc2ccccc24)c2cc(C#N)cc4c2B3c2cc(C(C)(C)C)cc3c2N4c2cc(C(C)(C)C)cc4c5cc(C(C)(C)C)ccc5n-3c24)cc1] | 3.07 g (15%) | 1069.58 |
| 353 | 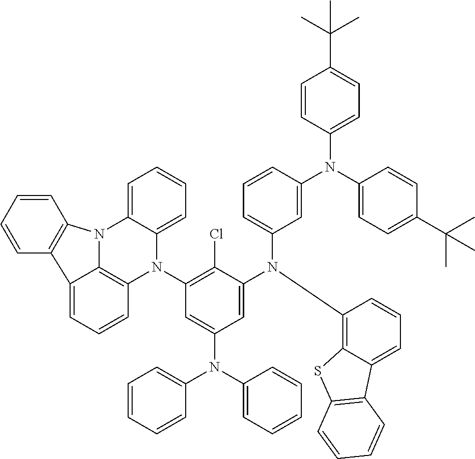 [SMILES: CC(C)(C)c1ccc(N(c2ccc(C(C)(C)C)cc2)c2cccc(N(c3cc(N(c4ccccc4)c4ccccc4)cc(N4c5ccccc5-n5c6ccccc6c6cccc4c65)c3Cl)c3cccc4c3sc3ccccc34)c2)cc1] | 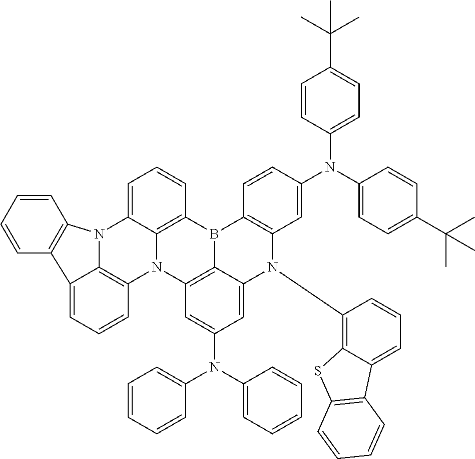 [SMILES: CC(C)(C)c1ccc(N(c2ccc(C(C)(C)C)cc2)c2ccc3c(c2)N(c2cccc4c2sc2ccccc24)c2cc(N(c4ccccc4)c4ccccc4)cc4c2B3c2cccc3c2N4c2cccc4c5ccccc5n-3c24)cc1] | 3.28 g (16%) | 1059.45 |
| 213 | 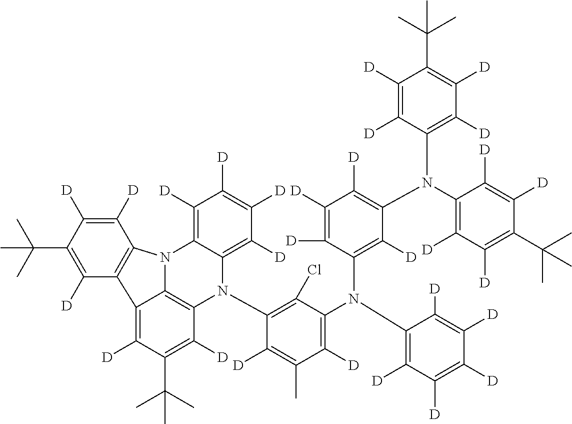 [SMILES: [2H]c1c([2H])c([2H])c(N(c2c([2H])c([2H])c([2H])c(N(c3c([2H])c([2H])c(C(C)(C)C)c([2H])c3[2H])c3c([2H])c([2H])c(C(C)(C)C)c([2H])c3[2H])c2[2H])c2c([2H])c(C)c([2H])c(N3c4c([2H])c([2H])c([2H])c([2H])c4-n4c5c([2H])c([2H])c(C(C)(C)C)c([2H])c5c5c([2H])c(C(C)(C)C)c([2H])c3c54)c2Cl)c([2H])c1[2H]] | 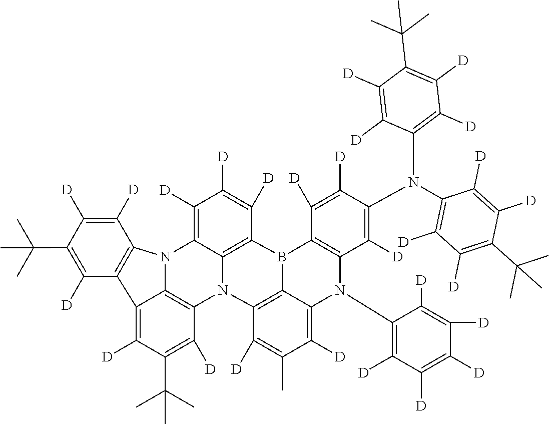 [SMILES: [2H]c1c([2H])c([2H])c(N2c3c([2H])c(N(c4c([2H])c([2H])c(C(C)(C)C)c([2H])c4[2H])c4c([2H])c([2H])c(C(C)(C)C)c([2H])c4[2H])c([2H])c([2H])c3B3c4c2c([2H])c(C)c([2H])c4N2c4c3c([2H])c([2H])c([2H])c4-n3c4c([2H])c([2H])c(C(C)(C)C)c([2H])c4c4c([2H])c(C(C)(C)C)c([2H])c2c43)c([2H])c1[2H]] | 2.68 g (13%) | 938.69 |
| 214 | 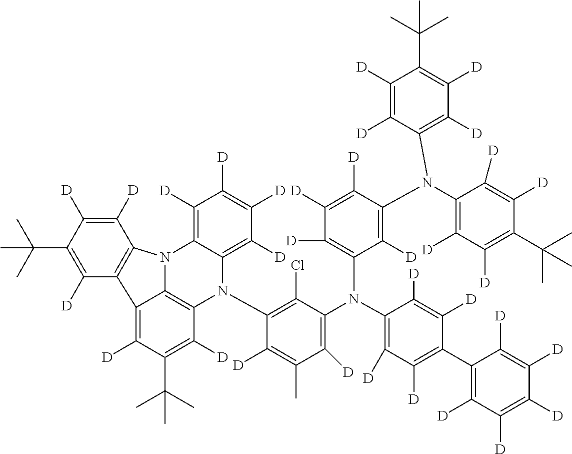 [SMILES: [2H]c1c([2H])c([2H])c(-c2c([2H])c([2H])c(N(c3c([2H])c([2H])c([2H])c(N(c4c([2H])c([2H])c(C(C)(C)C)c([2H])c4[2H])c4c([2H])c([2H])c(C(C)(C)C)c([2H])c4[2H])c3[2H])c3c([2H])c(C)c([2H])c(N4c5c([2H])c([2H])c([2H])c([2H])c5-n5c6c([2H])c([2H])c(C(C)(C)C)c([2H])c6c6c([2H])c(C(C)(C)C)c([2H])c4c65)c3Cl)c([2H])c2[2H])c([2H])c1[2H]] | 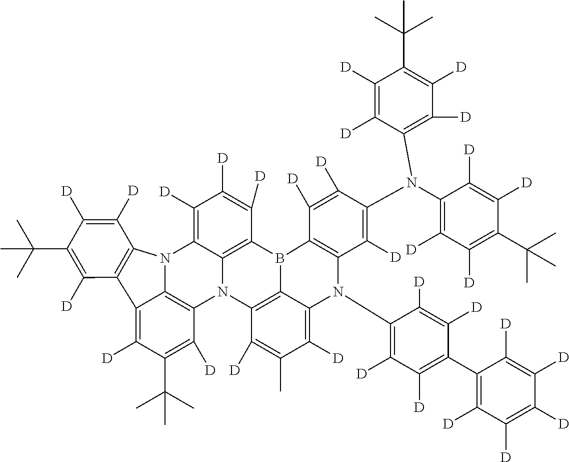 [SMILES: [2H]c1c([2H])c([2H])c(-c2c([2H])c([2H])c(N3c4c([2H])c(N(c5c([2H])c([2H])c(C(C)(C)C)c([2H])c5[2H])c5c([2H])c([2H])c(C(C)(C)C)c([2H])c5[2H])c([2H])c([2H])c4B4c5c3c([2H])c(C)c([2H])c5N3c5c4c([2H])c([2H])c([2H])c5-n4c5c([2H])c([2H])c(C(C)(C)C)c([2H])c5c5c([2H])c(C(C)(C)C)c([2H])c3c54)c([2H])c2[2H])c([2H])c1[2H]] | 2.47 g (12%) | 1017.74 |
| 369 | 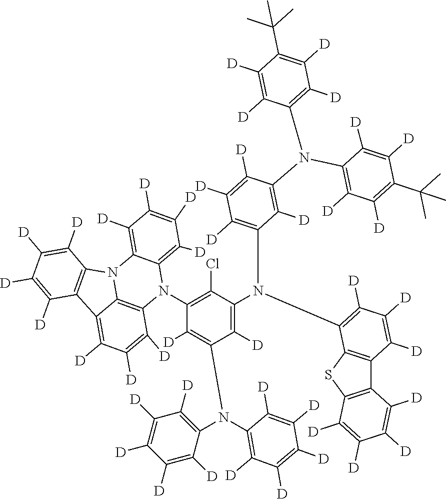 [SMILES: [2H]c1c([2H])c([2H])c(N(c2c([2H])c([2H])c([2H])c([2H])c2[2H])c2c([2H])c(N(c3c([2H])c([2H])c([2H])c(N(c4c([2H])c([2H])c(C(C)(C)C)c([2H])c4[2H])c4c([2H])c([2H])c(C(C)(C)C)c([2H])c4[2H])c3[2H])c3c([2H])c([2H])c([2H])c4c3sc3c([2H])c([2H])c([2H])c([2H])c34)c(Cl)c(N3c4c([2H])c([2H])c([2H])c([2H])c4-n4c5c([2H])c([2H])c([2H])c([2H])c5c5c([2H])c([2H])c([2H])c3c54)c2[2H])c([2H])c1[2H]] | 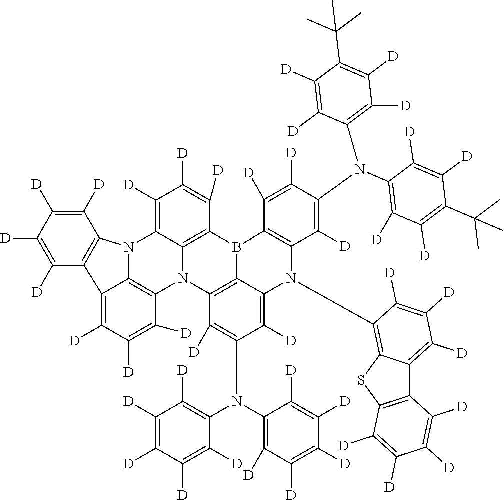 [SMILES: [2H]c1c([2H])c([2H])c(N(c2c([2H])c([2H])c([2H])c([2H])c2[2H])c2c([2H])c3c4c(c2[2H])N2c5c(c([2H])c([2H])c([2H])c5-n5c6c([2H])c([2H])c([2H])c([2H])c6c6c([2H])c([2H])c([2H])c2c65)B4c2c([2H])c([2H])c(N(c4c([2H])c([2H])c(C(C)(C)C)c([2H])c4[2H])c4c([2H])c([2H])c(C(C)(C)C)c([2H])c4[2H])c([2H])c2N3c2c([2H])c([2H])c([2H])c3c2sc2c([2H])c([2H])c([2H])c([2H])c23)c([2H])c1[2H]] | 2.46 g (12%) | 1099.70 |
| 382 | 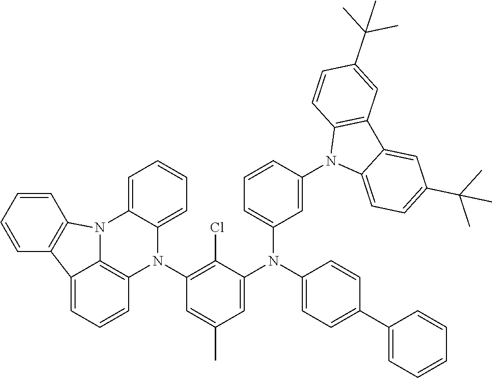 [SMILES: Cc1cc(N(c2ccc(-c3ccccc3)cc2)c2cccc(-n3c4ccc(C(C)(C)C)cc4c4cc(C(C)(C)C)ccc43)c2)c(Cl)c(N2c3ccccc3-n3c4ccccc4c4cccc2c43)c1] | 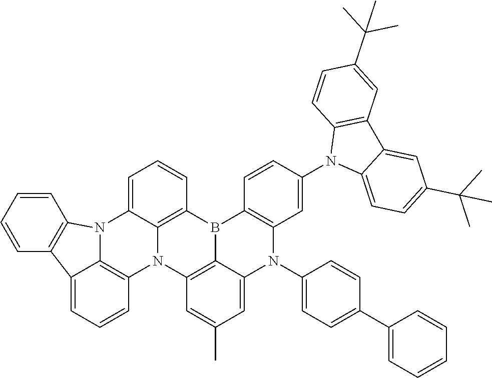 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1ccc(-c2ccccc2)cc1] | 3.09 g (15%) | 874.42 |
| 390 | 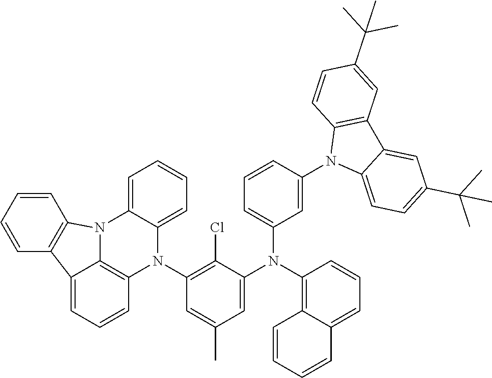 [SMILES: Cc1cc(N(c2cccc(-n3c4ccc(C(C)(C)C)cc4c4cc(C(C)(C)C)ccc43)c2)c2cccc3ccccc23)c(Cl)c(N2c3ccccc3-n3c4ccccc4c4cccc2c43)c1] | 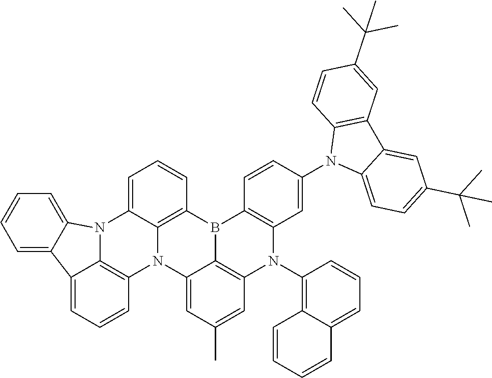 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2ccccc12] | 3.09 g (15%) | 848.41 |
| 396 | 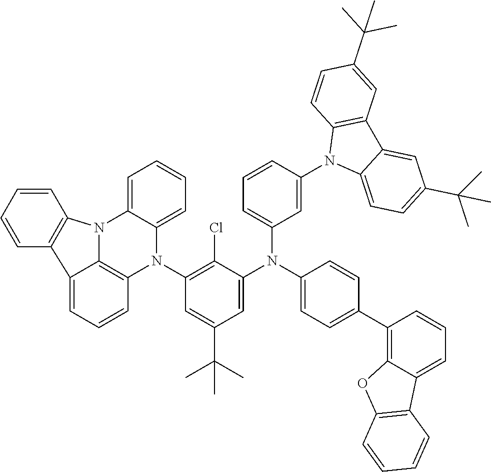 [SMILES: CC(C)(C)c1cc(N(c2ccc(-c3cccc4c3oc3ccccc34)cc2)c2cccc(-n3c4ccc(C(C)(C)C)cc4c4cc(C(C)(C)C)ccc43)c2)c(Cl)c(N2c3ccccc3-n3c4ccccc4c4cccc2c43)c1] | 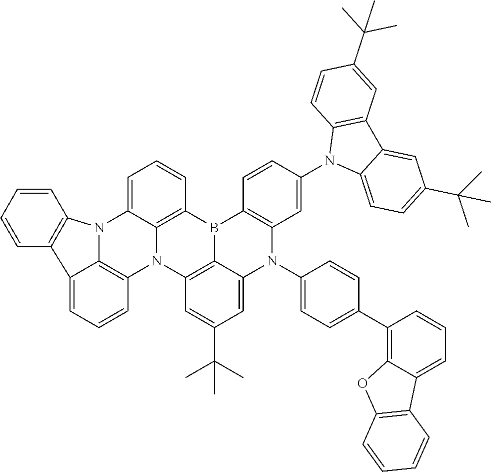 [SMILES: CC(C)(C)c1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1ccc(-c2cccc3c2oc2ccccc23)cc1] | 2.67 g (13%) | 1006.48 |
| 415 | 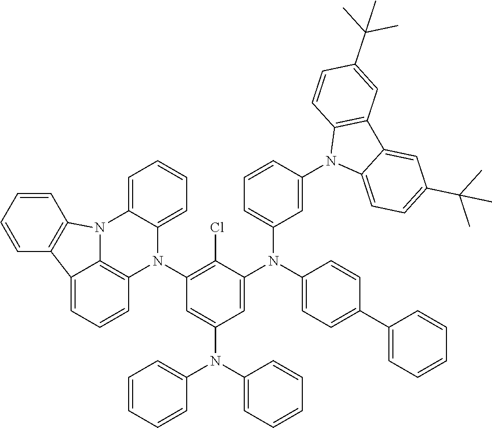 [SMILES: CC(C)(C)c1ccc2c(c1)c1cc(C(C)(C)C)ccc1n2-c1cccc(N(c2ccc(-c3ccccc3)cc2)c2cc(N(c3ccccc3)c3ccccc3)cc(N3c4ccccc4-n4c5ccccc5c5cccc3c54)c2Cl)c1] | 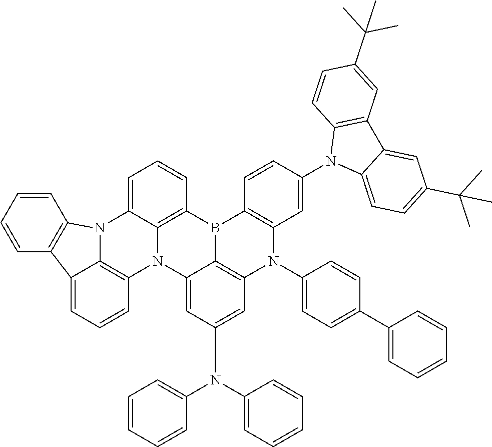 [SMILES: CC(C)(C)c1ccc2c(c1)c1cc(C(C)(C)C)ccc1n2-c1ccc2c(c1)N(c1ccc(-c3ccccc3)cc1)c1cc(N(c3ccccc3)c3ccccc3)cc3c1B2c1cccc2c1N3c1cccc3c4ccccc4n-2c13] | 3.28 g (16%) | 1027.48 |
| 426 | 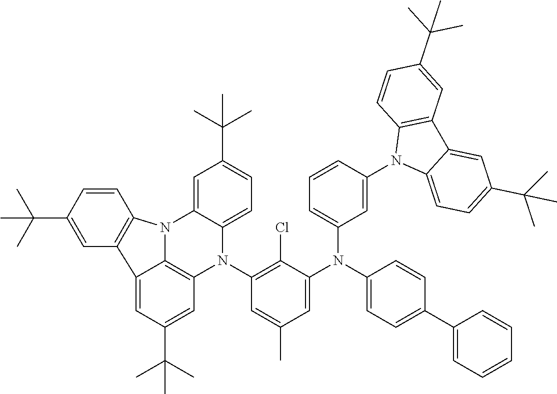 [SMILES: Cc1cc(N(c2ccc(-c3ccccc3)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 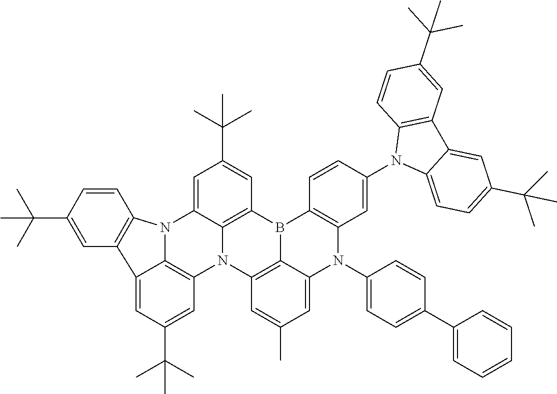 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2ccccc2)cc1] | 2.87 g (14%) | 1042.61 |
| 427 | 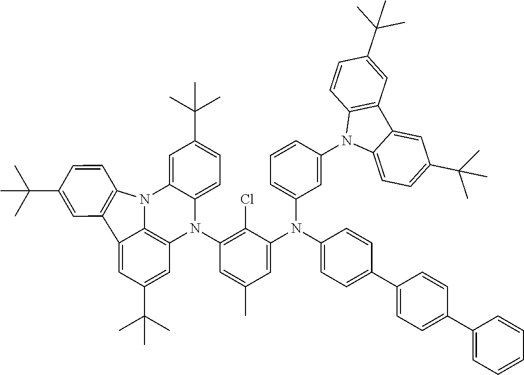 [SMILES: Cc1cc(N(c2ccc(-c3ccc(-c4ccccc4)cc3)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 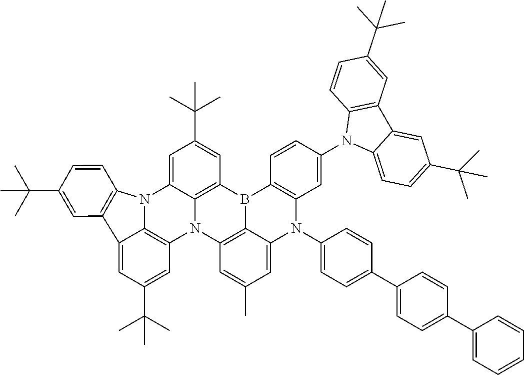 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2ccc(-c3ccccc3)cc2)cc1] | 2.46 g (12%) | 1118.64 |
| 428 | 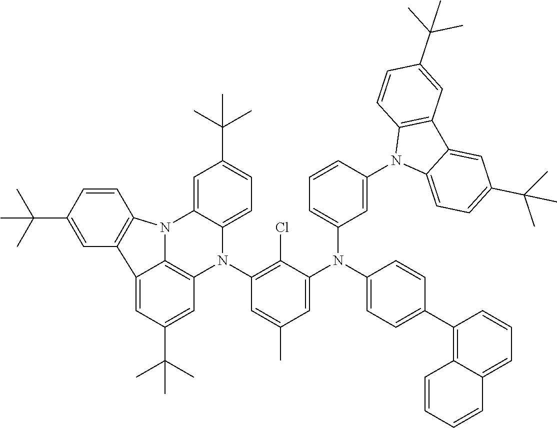 [SMILES: Cc1cc(N(c2ccc(-c3cccc4ccccc34)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 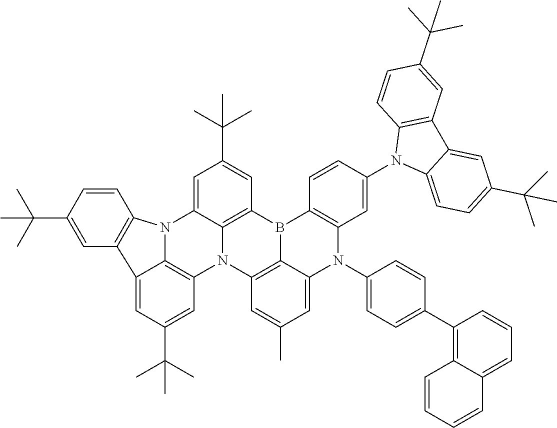 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2cccc3ccccc23)cc1] | 2.25 g (11%) | 1092.62 |
| 429 | 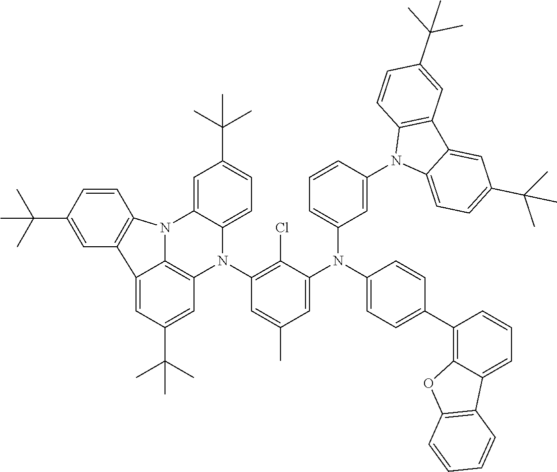 [SMILES: Cc1cc(N(c2ccc(-c3cccc4c3oc3ccccc34)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 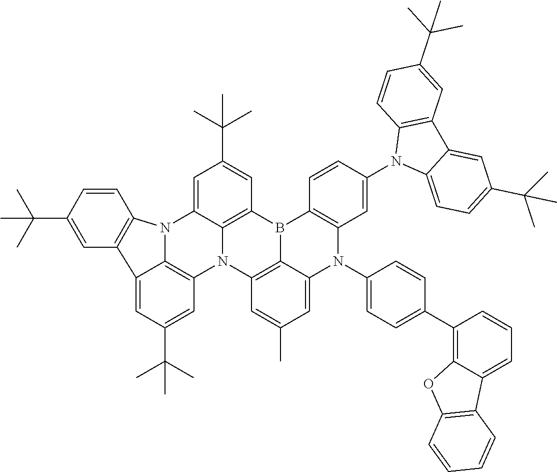 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2cccc3c2oc2ccccc23)cc1] | 2.66 g (13%) | 1132.62 |
| 431 | 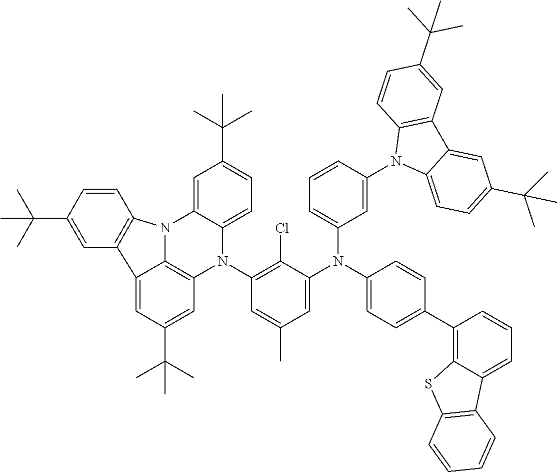 [SMILES: Cc1cc(N(c2ccc(-c3cccc4c3sc3ccccc34)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 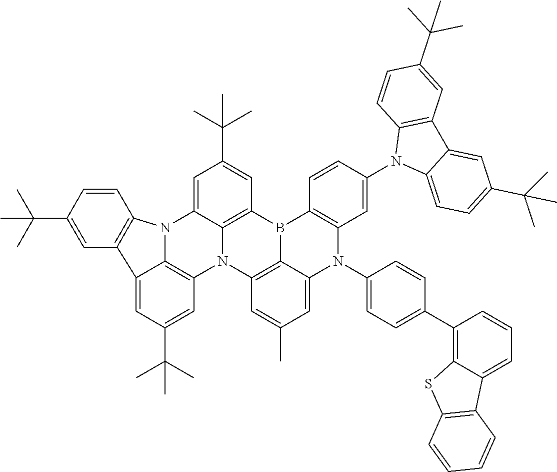 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2cccc3c2sc2ccccc23)cc1] | 2.66 g (13%) | 1148.62 |
| 433 | 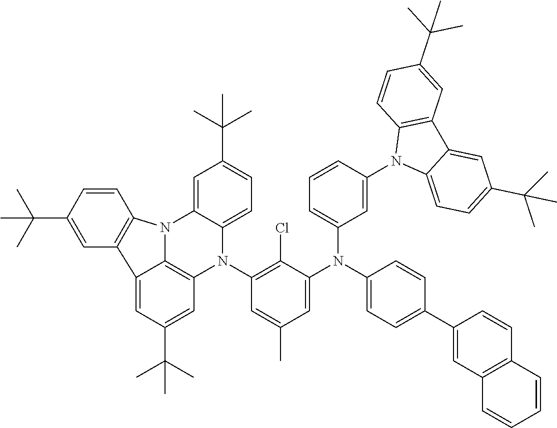 [SMILES: Cc1cc(N(c2ccc(-c3ccc4ccccc4c3)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 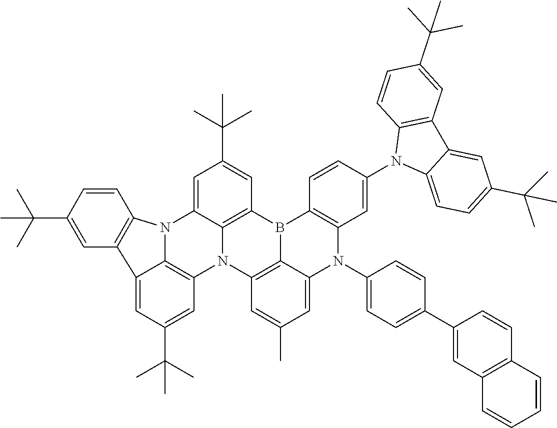 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2ccc3ccccc3c2)cc1] | 2.46 g (12%) | 1092.62 |
| 437 | 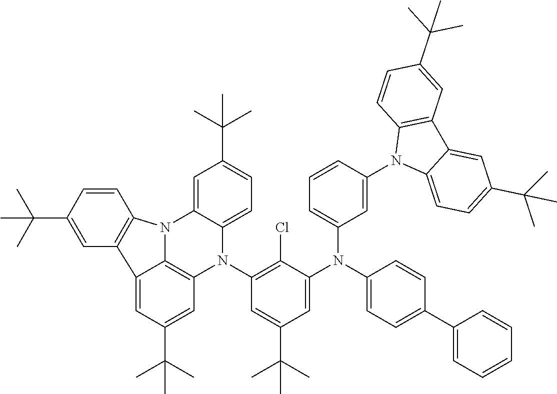 [SMILES: CC(C)(C)c1cc(N(c2ccc(-c3ccccc3)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 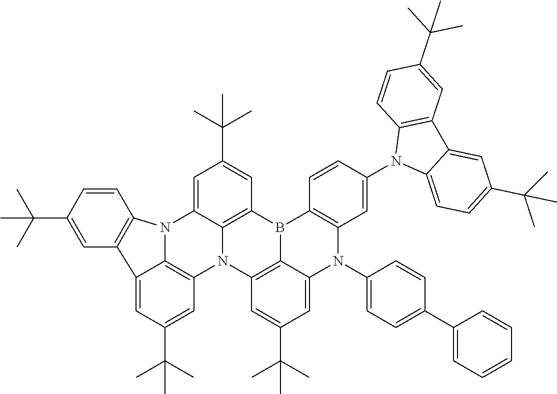 [SMILES: CC(C)(C)c1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(-c2ccccc2)cc1] | 3.07 g (15%) | 1084.66 |
| 450 | 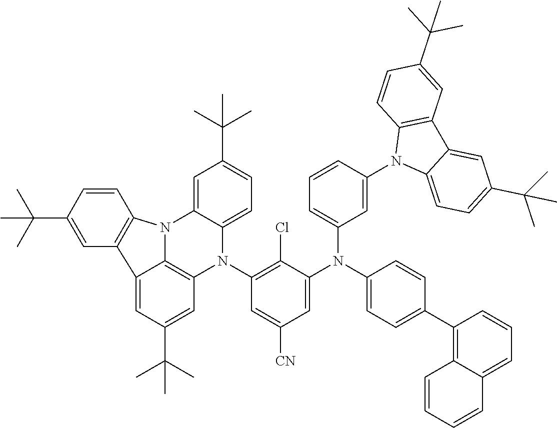 [SMILES: CC(C)(C)c1ccc2c(c1)-n1c3ccc(C(C)(C)C)cc3c3cc(C(C)(C)C)cc(c31)N2c1cc(C#N)cc(N(c2ccc(-c3cccc4ccccc34)cc2)c2cccc(-n3c4ccc(C(C)(C)C)cc4c4cc(C(C)(C)C)ccc43)c2)c1Cl] | 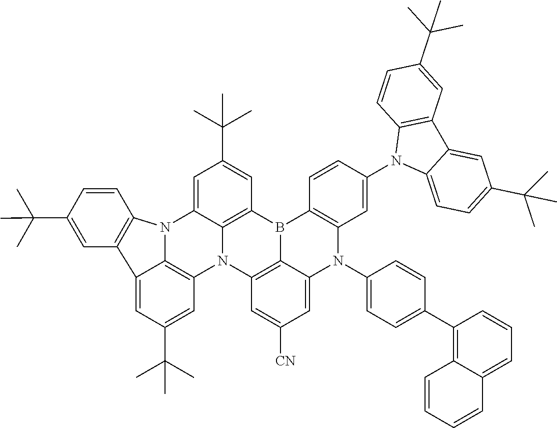 [SMILES: CC(C)(C)c1cc2c3c(c1)-n1c4ccc(C(C)(C)C)cc4c4cc(C(C)(C)C)cc(c41)N3c1cc(C#N)cc3c1B2c1ccc(-n2c4ccc(C(C)(C)C)cc4c4cc(C(C)(C)C)ccc42)cc1N3c1ccc(-c2cccc3ccccc23)cc1] | 2.87 g (14%) | 1103.60 |
| 462 | 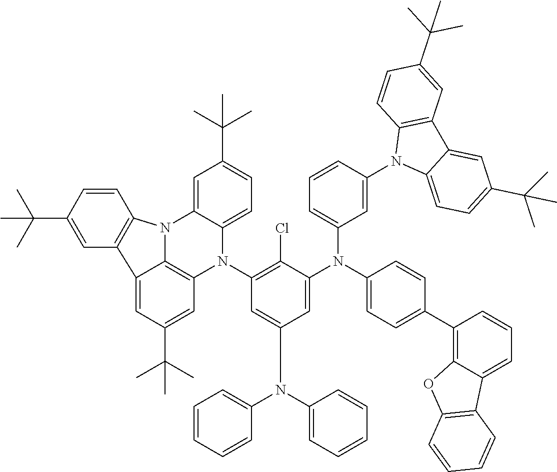 [SMILES: CC(C)(C)c1ccc2c(c1)-n1c3ccc(C(C)(C)C)cc3c3cc(C(C)(C)C)cc(c31)N2c1cc(N(c2ccccc2)c2ccccc2)cc(N(c2ccc(-c3cccc4c3oc3ccccc34)cc2)c2cccc(-n3c4ccc(C(C)(C)C)cc4c4cc(C(C)(C)C)ccc43)c2)c1Cl] | 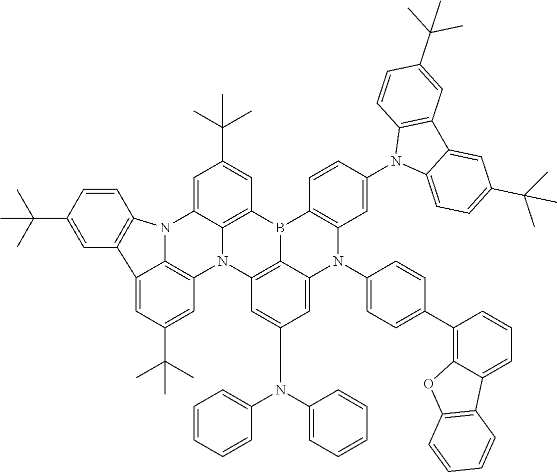 [SMILES: CC(C)(C)c1cc2c3c(c1)-n1c4ccc(C(C)(C)C)cc4c4cc(C(C)(C)C)cc(c41)N3c1cc(N(c3ccccc3)c3ccccc3)cc3c1B2c1ccc(-n2c4ccc(C(C)(C)C)cc4c4cc(C(C)(C)C)ccc42)cc1N3c1ccc(-c2cccc3c2oc2ccccc23)cc1] | 3.06 g (15%) | 1285.68 |
| 505 | 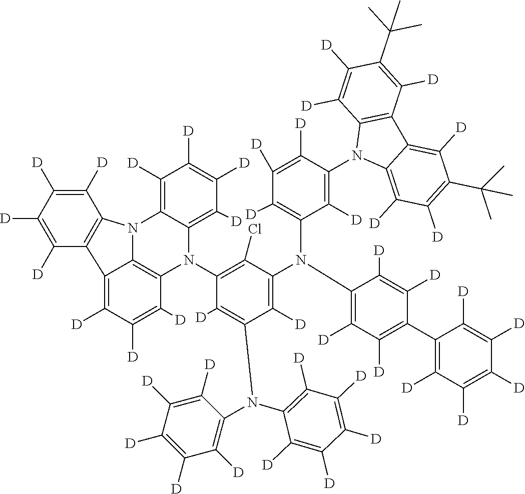 [SMILES: [2H]c1c([2H])c([2H])c(-c2c([2H])c([2H])c(N(c3c([2H])c([2H])c([2H])c(-n4c5c([2H])c([2H])c(C(C)(C)C)c([2H])c5c5c([2H])c(C(C)(C)C)c([2H])c([2H])c54)c3[2H])c3c([2H])c(N(c4c([2H])c([2H])c([2H])c([2H])c4[2H])c4c([2H])c([2H])c([2H])c([2H])c4[2H])c([2H])c(N4c5c([2H])c([2H])c([2H])c([2H])c5-n5c6c([2H])c([2H])c([2H])c([2H])c6c6c([2H])c([2H])c([2H])c4c65)c3Cl)c([2H])c2[2H])c([2H])c1[2H]] | 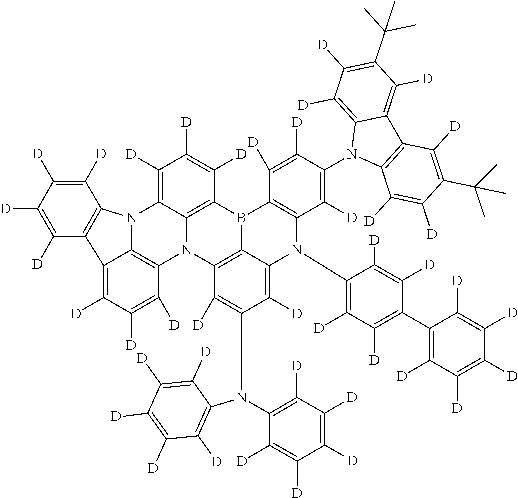 [SMILES: [2H]c1c([2H])c([2H])c(-c2c([2H])c([2H])c(N3c4c([2H])c(-n5c6c([2H])c([2H])c(C(C)(C)C)c([2H])c6c6c([2H])c(C(C)(C)C)c([2H])c([2H])c65)c([2H])c([2H])c4B4c5c3c([2H])c(N(c3c([2H])c([2H])c([2H])c([2H])c3[2H])c3c([2H])c([2H])c([2H])c([2H])c3[2H])c([2H])c5N3c5c4c([2H])c([2H])c([2H])c5-n4c5c([2H])c([2H])c([2H])c([2H])c5c5c([2H])c([2H])c([2H])c3c54)c([2H])c2[2H])c([2H])c1[2H]] | 2.67 g (13%) | 1066.72 |
| 515 | 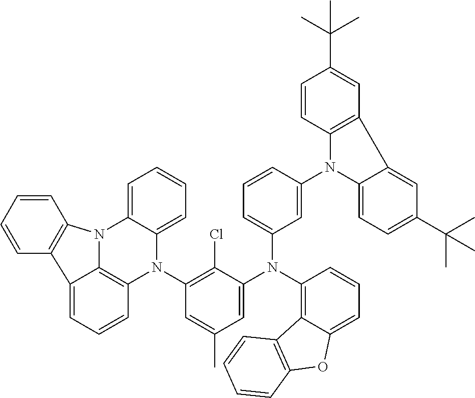 [SMILES: Cc1cc(N(c2cccc(-n3c4ccc(C(C)(C)C)cc4c4cc(C(C)(C)C)ccc43)c2)c2cccc3oc4ccccc4c23)c(Cl)c(N2c3ccccc3-n3c4ccccc4c4cccc2c43)c1] | 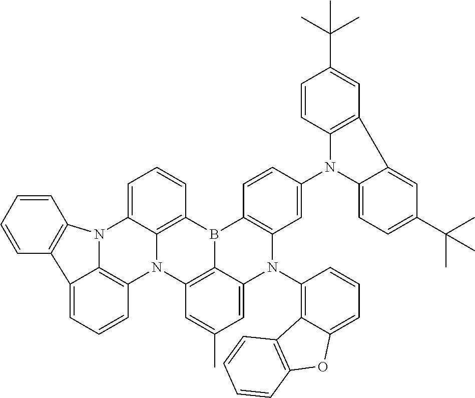 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2oc3ccccc3c12] | 3.29 g (16%) | 888.40 |
| 516 | 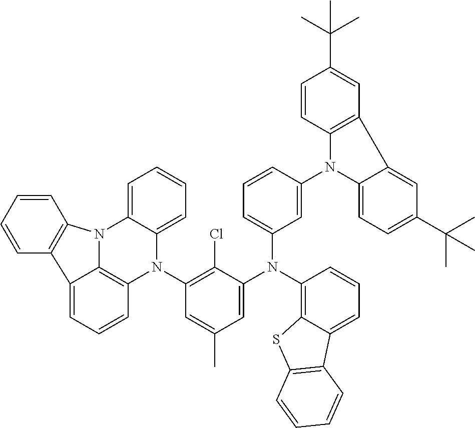 [SMILES: Cc1cc(N(c2cccc(-n3c4ccc(C(C)(C)C)cc4c4cc(C(C)(C)C)ccc43)c2)c2cccc3c2sc2ccccc23)c(Cl)c(N2c3ccccc3-n3c4ccccc4c4cccc2c43)c1] | 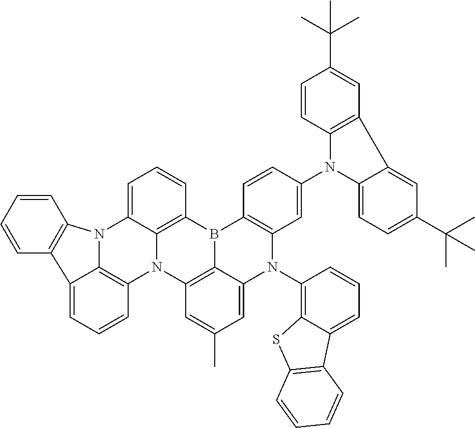 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2c1sc1ccccc12] | 3.50 g (17%) | 904.38 |
| 519 | 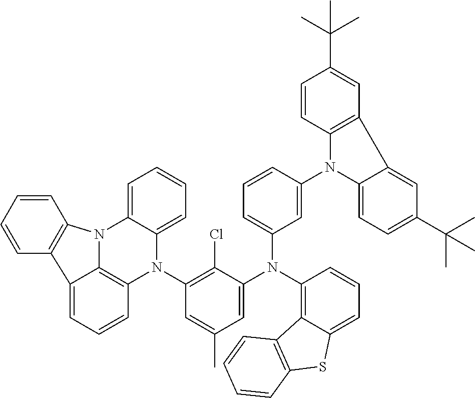 [SMILES: Cc1cc(N(c2cccc(-n3c4ccc(C(C)(C)C)cc4c4cc(C(C)(C)C)ccc43)c2)c2cccc3sc4ccccc4c23)c(Cl)c(N2c3ccccc3-n3c4ccccc4c4cccc2c43)c1] | 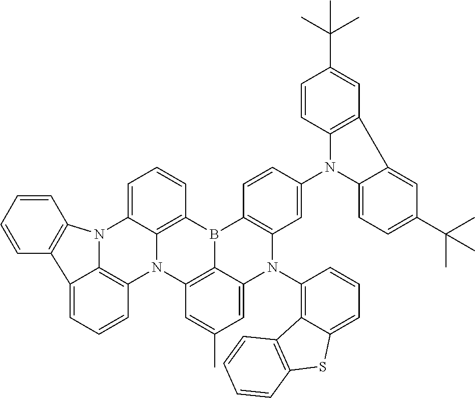 [SMILES: Cc1cc2c3c(c1)N1c4c(cccc4-n4c5ccccc5c5cccc1c54)B3c1ccc(-n3c4ccc(C(C)(C)C)cc4c4cc(C(C)(C)C)ccc43)cc1N2c1cccc2sc3ccccc3c12] | 3.09 g (15%) | 904.38 |
| 535 | 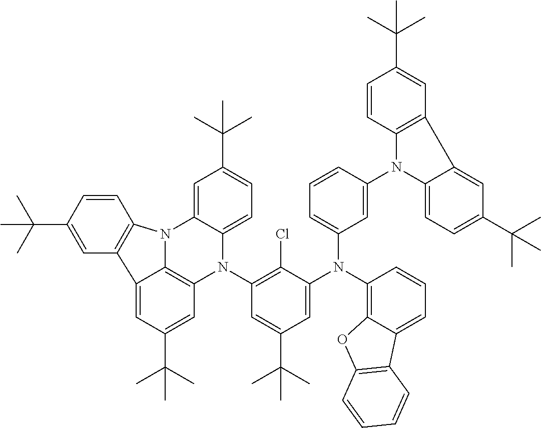 [SMILES: CC(C)(C)c1cc(N(c2cccc(-n3c4ccc(C(C)(C)C)cc4c4cc(C(C)(C)C)ccc43)c2)c2cccc3c2oc2ccccc23)c(Cl)c(N2c3ccc(C(C)(C)C)cc3-n3c4ccc(C(C)(C)C)cc4c4cc(C(C)(C)C)cc2c43)c1] | 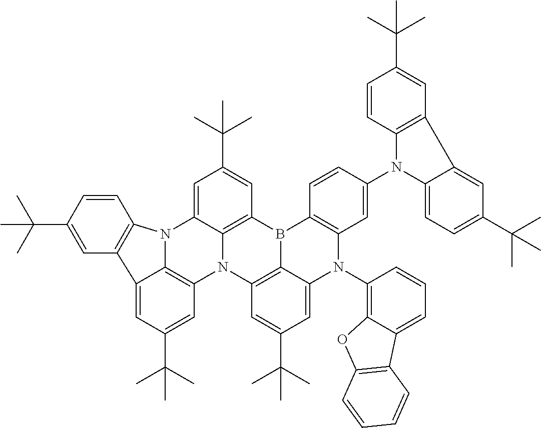 [SMILES: CC(C)(C)c1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1cccc2c1oc1ccccc12] | 3.28 g (16%) | 1098.63 |
| 543 | 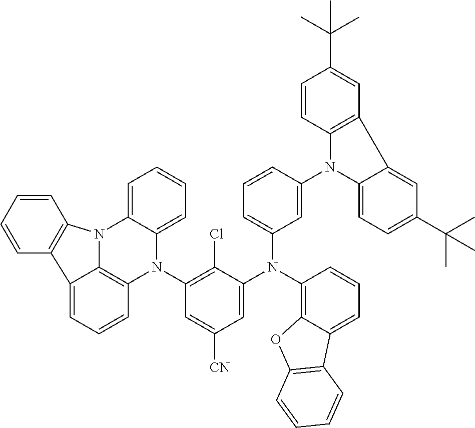 [SMILES: CC(C)(C)c1ccc2c(c1)c1cc(C(C)(C)C)ccc1n2-c1cccc(N(c2cc(C#N)cc(N3c4ccccc4-n4c5ccccc5c5cccc3c54)c2Cl)c2cccc3c2oc2ccccc23)c1] | 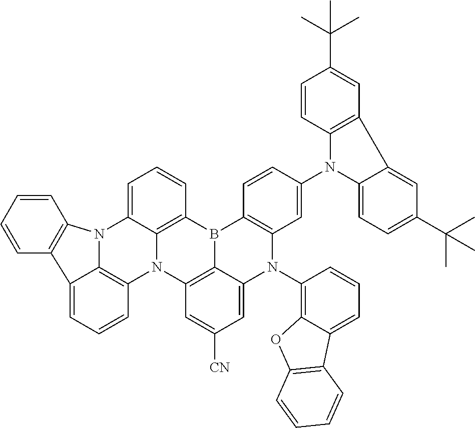 [SMILES: CC(C)(C)c1ccc2c(c1)c1cc(C(C)(C)C)ccc1n2-c1ccc2c(c1)N(c1cccc3c1oc1ccccc13)c1cc(C#N)cc3c1B2c1cccc2c1N3c1cccc3c4ccccc4n-2c13] | 2.68 g (13%) | 899.38 |
| 545 | 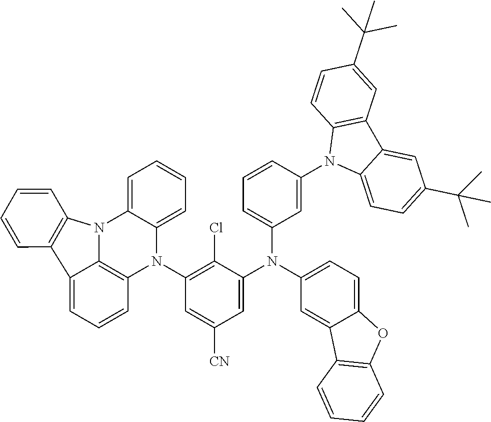 [SMILES: CC(C)(C)c1ccc2c(c1)c1cc(C(C)(C)C)ccc1n2-c1cccc(N(c2ccc3oc4ccccc4c3c2)c2cc(C#N)cc(N3c4ccccc4-n4c5ccccc5c5cccc3c54)c2Cl)c1] | 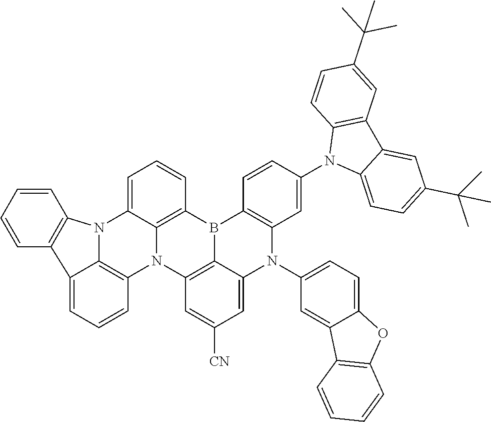 [SMILES: CC(C)(C)c1ccc2c(c1)c1cc(C(C)(C)C)ccc1n2-c1ccc2c(c1)N(c1ccc3oc4ccccc4c3c1)c1cc(C#N)cc3c1B2c1cccc2c1N3c1cccc3c4ccccc4n-2c13] | 2.47 g (12%) | 899.38 |
| 547 | 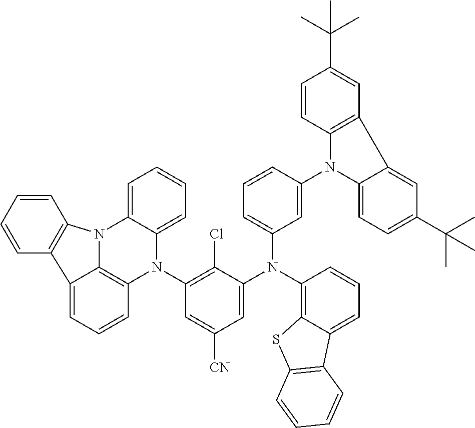 [SMILES: CC(C)(C)c1ccc2c(c1)c1cc(C(C)(C)C)ccc1n2-c1cccc(N(c2cc(C#N)cc(N3c4ccccc4-n4c5ccccc5c5cccc3c54)c2Cl)c2cccc3c2sc2ccccc23)c1] | 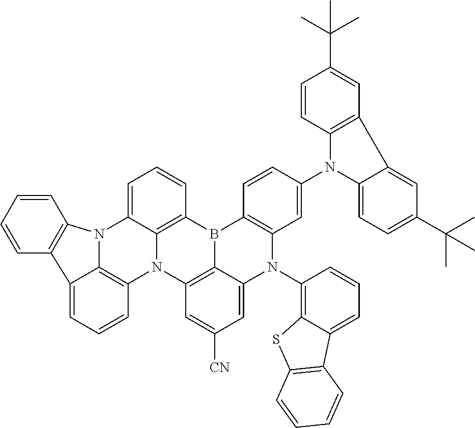 [SMILES: CC(C)(C)c1ccc2c(c1)c1cc(C(C)(C)C)ccc1n2-c1ccc2c(c1)N(c1cccc3c1sc1ccccc13)c1cc(C#N)cc3c1B2c1cccc2c1N3c1cccc3c4ccccc4n-2c13] | 2.67 g (13%) | 915.36 |
| 555 | 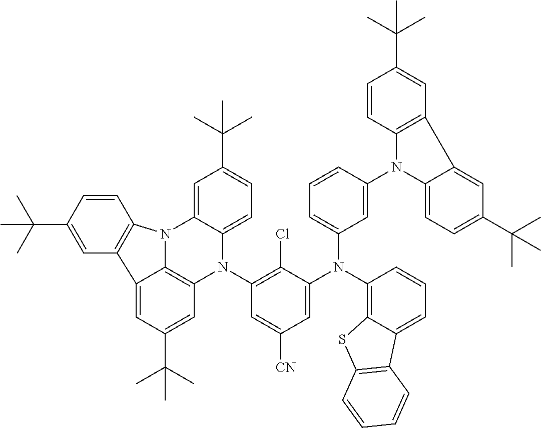 [SMILES: CC(C)(C)c1ccc2c(c1)-n1c3ccc(C(C)(C)C)cc3c3cc(C(C)(C)C)cc(c31)N2c1cc(C#N)cc(N(c2cccc(-n3c4ccc(C(C)(C)C)cc4c4cc(C(C)(C)C)ccc43)c2)c2cccc3c2sc2ccccc23)c1Cl] | 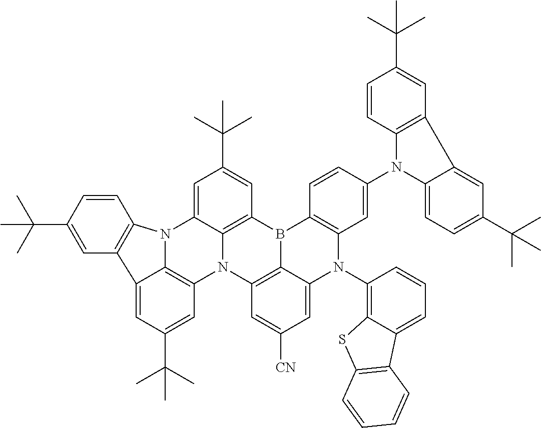 [SMILES: CC(C)(C)c1cc2c3c(c1)-n1c4ccc(C(C)(C)C)cc4c4cc(C(C)(C)C)cc(c41)N3c1cc(C#N)cc3c1B2c1ccc(-n2c4ccc(C(C)(C)C)cc4c4cc(C(C)(C)C)ccc42)cc1N3c1cccc2c1sc1ccccc12] | 2.66 g (13%) | 1083.54 |
| 573 | 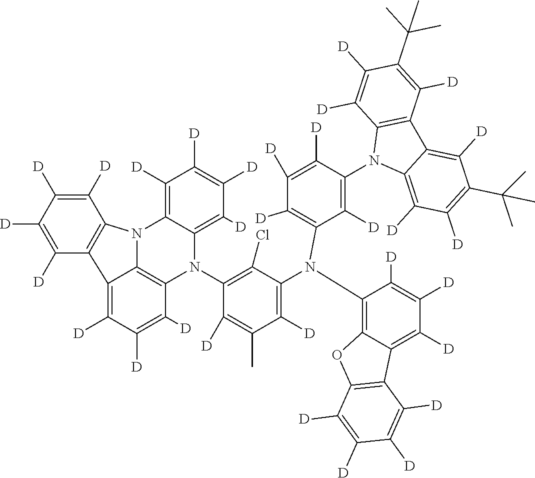 [SMILES: [2H]c1c([2H])c([2H])c2c(c1[2H])N(c1c([2H])c(C)c([2H])c(N(c3c([2H])c([2H])c([2H])c(-n4c5c([2H])c([2H])c(C(C)(C)C)c([2H])c5c5c([2H])c(C(C)(C)C)c([2H])c([2H])c54)c3[2H])c3c([2H])c([2H])c([2H])c4c3oc3c([2H])c([2H])c([2H])c([2H])c34)c1Cl)c1c([2H])c([2H])c([2H])c3c4c([2H])c([2H])c([2H])c([2H])c4n-2c13] | 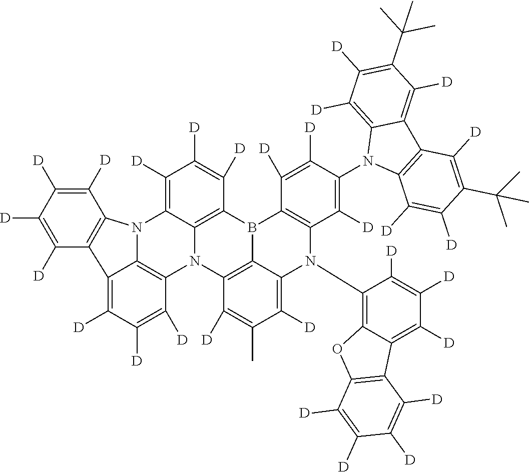 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C)c([2H])c3c1B2c1c([2H])c([2H])c(-n2c4c([2H])c([2H])c(C(C)(C)C)c([2H])c4c4c([2H])c(C(C)(C)C)c([2H])c([2H])c42)c([2H])c1N3c1c([2H])c([2H])c([2H])c2c1oc1c([2H])c([2H])c([2H])c([2H])c12] | 2.47 g (12%) | 916.58 |
| 577 | 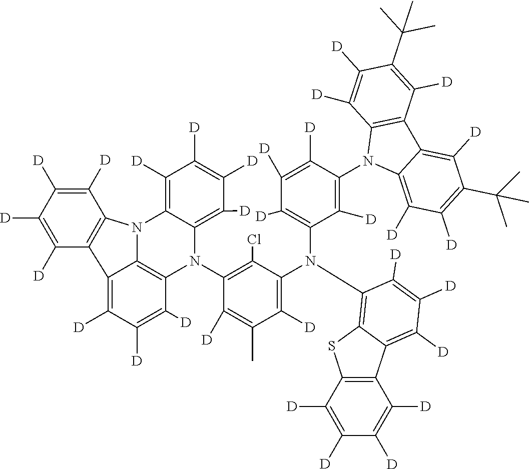 [SMILES: [2H]c1c([2H])c([2H])c2c(c1[2H])N(c1c([2H])c(C)c([2H])c(N(c3c([2H])c([2H])c([2H])c(-n4c5c([2H])c([2H])c(C(C)(C)C)c([2H])c5c5c([2H])c(C(C)(C)C)c([2H])c([2H])c54)c3[2H])c3c([2H])c([2H])c([2H])c4c3sc3c([2H])c([2H])c([2H])c([2H])c34)c1Cl)c1c([2H])c([2H])c([2H])c3c4c([2H])c([2H])c([2H])c([2H])c4n-2c13] | 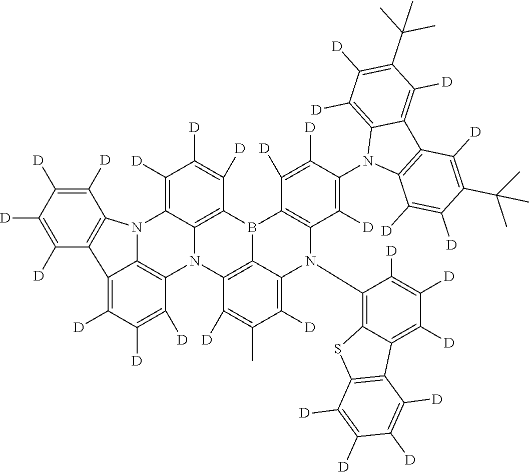 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C)c([2H])c3c1B2c1c([2H])c([2H])c(-n2c4c([2H])c([2H])c(C(C)(C)C)c([2H])c4c4c([2H])c(C(C)(C)C)c([2H])c([2H])c42)c([2H])c1N3c1c([2H])c([2H])c([2H])c2c1sc1c([2H])c([2H])c([2H])c([2H])c12] | 2.47 g (12%) | 932.55 |
| 633 | 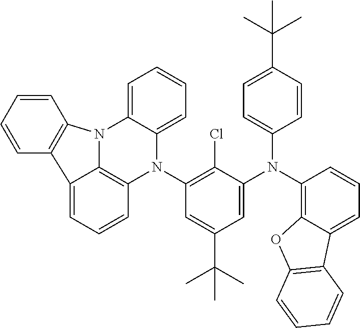 [SMILES: CC(C)(C)c1ccc(N(c2cc(C(C)(C)C)cc(N3c4ccccc4-n4c5ccccc5c5cccc3c54)c2Cl)c2cccc3c2oc2ccccc23)cc1] | 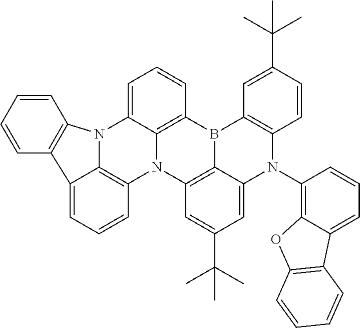 [SMILES: CC(C)(C)c1ccc2c(c1)B1c3cccc4c3N(c3cc(C(C)(C)C)cc(c31)N2c1cccc2c1oc1ccccc12)c1cccc2c3ccccc3n-4c12] | 3.32 g (16%) | 709.33 |
| 637 | 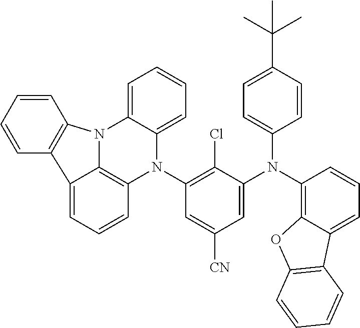 [SMILES: CC(C)(C)c1ccc(N(c2cc(C#N)cc(N3c4ccccc4-n4c5ccccc5c5cccc3c54)c2Cl)c2cccc3c2oc2ccccc23)cc1] | 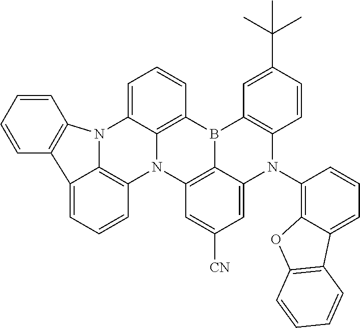 [SMILES: CC(C)(C)c1ccc2c(c1)B1c3cccc4c3N(c3cc(C#N)cc(c31)N2c1cccc2c1oc1ccccc12)c1cccc2c3ccccc3n-4c12] | 2.70 g (13%) | 678.26 |
| 641 | 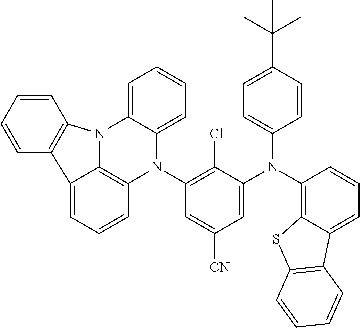 [SMILES: CC(C)(C)c1ccc(N(c2cc(C#N)cc(N3c4ccccc4-n4c5ccccc5c5cccc3c54)c2Cl)c2cccc3c2sc2ccccc23)cc1] | 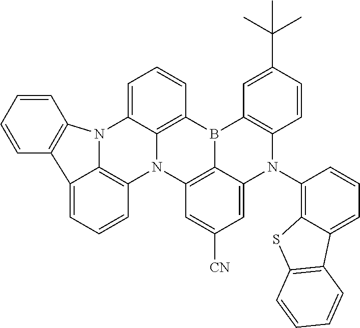 [SMILES: CC(C)(C)c1ccc2c(c1)B1c3cccc4c3N(c3cc(C#N)cc(c31)N2c1cccc2c1sc1ccccc12)c1cccc2c3ccccc3n-4c12] | 2.70 g (13%) | 694.24 |
| 645 | 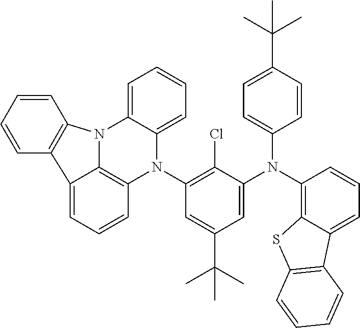 [SMILES: CC(C)(C)c1ccc(N(c2cc(C(C)(C)C)cc(N3c4ccccc4-n4c5ccccc5c5cccc3c54)c2Cl)c2cccc3c2sc2ccccc23)cc1] | 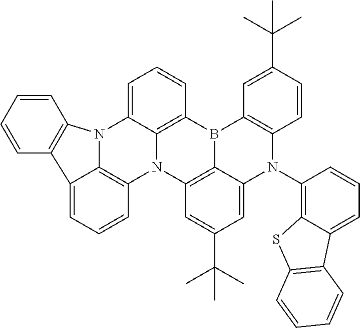 [SMILES: CC(C)(C)c1ccc2c(c1)B1c3cccc4c3N(c3cc(C(C)(C)C)cc(c31)N2c1cccc2c1sc1ccccc12)c1cccc2c3ccccc3n-4c12] | 3.11g (15%) | 725.30 |
| 657 | 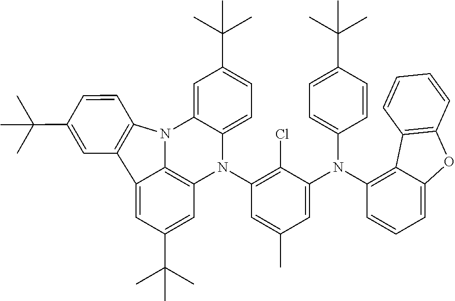 [SMILES: Cc1cc(N(c2ccc(C(C)(C)C)cc2)c2cccc3oc4ccccc4c23)c(Cl)c(N2c3ccc(C(C)(C)C)cc3-n3c4ccc(C(C)(C)C)cc4c4cc(C(C)(C)C)cc2c43)c1] | 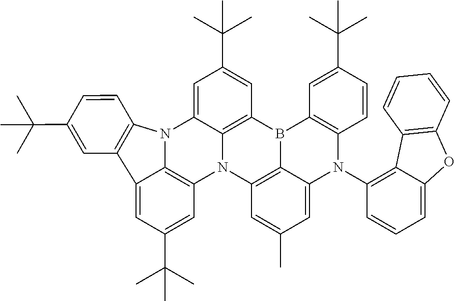 [SMILES: Cc1cc2c3c(c1)N1c4c(cc(C(C)(C)C)cc4-n4c5ccc(C(C)(C)C)cc5c5cc(C(C)(C)C)cc1c54)B3c1cc(C(C)(C)C)ccc1N2c1cccc2oc3ccccc3c12] | 3.30 g (16%) | 835.47 |
| 660 | 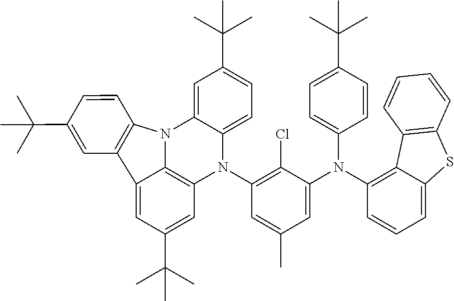 [SMILES: Cc1cc(N(c2ccc(C(C)(C)C)cc2)c2cccc3sc4ccccc4c23)c(Cl)c(N2c3ccc(C(C)(C)C)cc3-n3c4ccc(C(C)(C)C)cc4c4cc(C(C)(C)C)cc2c43)c1] | 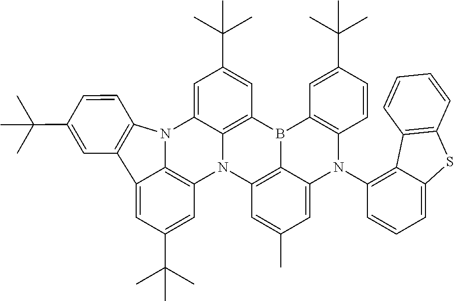 [SMILES: Cc1cc2c3c(c1)N1c4c(cc(C(C)(C)C)cc4-n4c5ccc(C(C)(C)C)cc5c5cc(C(C)(C)C)cc1c54)B3c1cc(C(C)(C)C)ccc1N2c1cccc2sc3ccccc3c12] | 3.30 g (16%) | 851.44 |
| 661 | 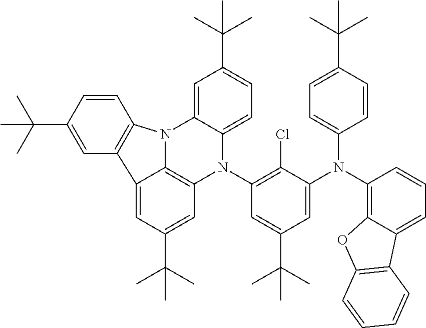 [SMILES: CC(C)(C)c1ccc(N(c2cc(C(C)(C)C)cc(N3c4ccc(C(C)(C)C)cc4-n4c5ccc(C(C)(C)C)cc5c5cc(C(C)(C)C)cc3c54)c2Cl)c2cccc3c2oc2ccccc23)cc1] | 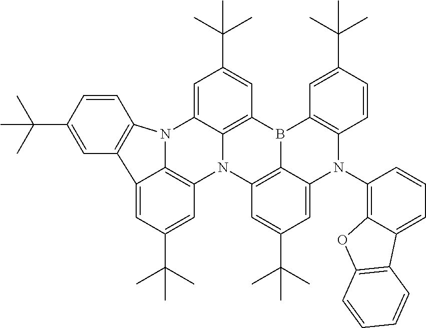 [SMILES: CC(C)(C)c1ccc2c(c1)B1c3cc(C(C)(C)C)cc4c3N(c3cc(C(C)(C)C)cc(c31)N2c1cccc2c1oc1ccccc12)c1cc(C(C)(C)C)cc2c3cc(C(C)(C)C)ccc3n-4c12] | 3.09 g (15%) | 877.51 |
| 665 | 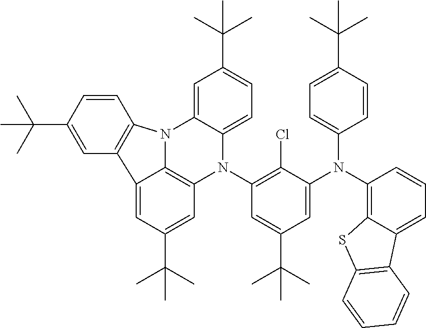 [SMILES: CC(C)(C)c1ccc(N(c2cc(C(C)(C)C)cc(N3c4ccc(C(C)(C)C)cc4-n4c5ccc(C(C)(C)C)cc5c5cc(C(C)(C)C)cc3c54)c2Cl)c2cccc3c2sc2ccccc23)cc1] | 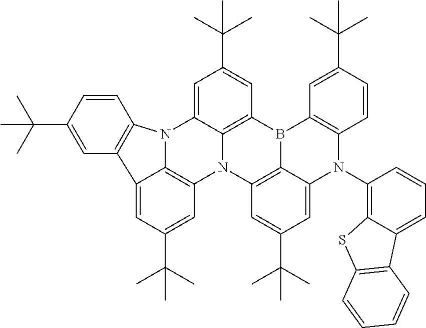 [SMILES: CC(C)(C)c1ccc2c(c1)B1c3cc(C(C)(C)C)cc4c3N(c3cc(C(C)(C)C)cc(c31)N2c1cccc2c1sc1ccccc12)c1cc(C(C)(C)C)cc2c3cc(C(C)(C)C)ccc3n-4c12] | 3.09 g (15%) | 893.49 |
| 677 | 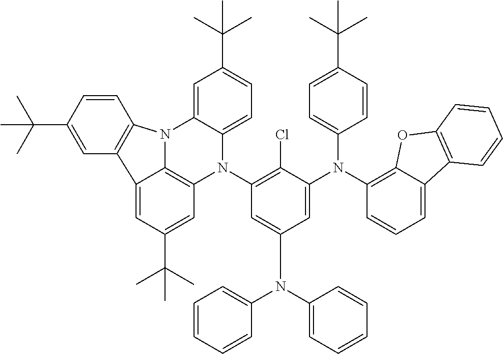 [SMILES: CC(C)(C)c1ccc(N(c2cc(N(c3ccccc3)c3ccccc3)cc(N3c4ccc(C(C)(C)C)cc4-n4c5ccc(C(C)(C)C)cc5c5cc(C(C)(C)C)cc3c54)c2Cl)c2cccc3c2oc2ccccc23)cc1] | 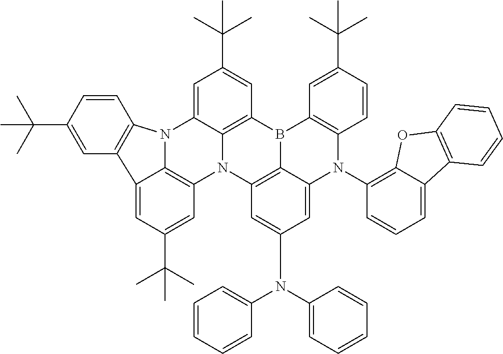 [SMILES: CC(C)(C)c1ccc2c(c1)B1c3cc(C(C)(C)C)cc4c3N(c3cc(N(c5ccccc5)c5ccccc5)cc(c31)N2c1cccc2c1oc1ccccc12)c1cc(C(C)(C)C)cc2c3cc(C(C)(C)C)ccc3n-4c12] | 2.87 g (14%) | 988.53 |
| 681 | 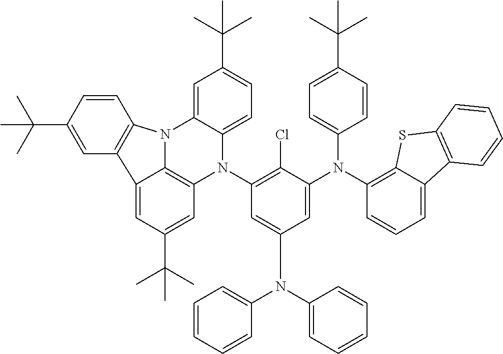 [SMILES: CC(C)(C)c1ccc(N(c2cc(N(c3ccccc3)c3ccccc3)cc(N3c4ccc(C(C)(C)C)cc4-n4c5ccc(C(C)(C)C)cc5c5cc(C(C)(C)C)cc3c54)c2Cl)c2cccc3c2sc2ccccc23)cc1] | 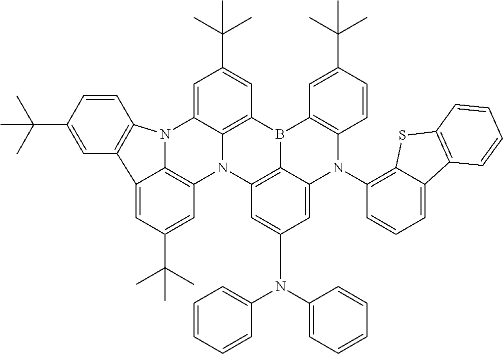 [SMILES: CC(C)(C)c1ccc2c(c1)B1c3cc(C(C)(C)C)cc4c3N(c3cc(N(c5ccccc5)c5ccccc5)cc(c31)N2c1cccc2c1sc1ccccc12)c1cc(C(C)(C)C)cc2c3cc(C(C)(C)C)ccc3n-4c12] | 3.08 g (15%) | 1004.50 |
| 693 | 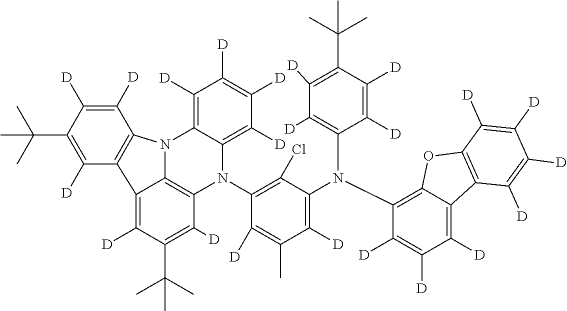 [SMILES: [2H]c1c([2H])c([2H])c2c(c1[2H])N(c1c([2H])c(C)c([2H])c(N(c3c([2H])c([2H])c(C(C)(C)C)c([2H])c3[2H])c3c([2H])c([2H])c([2H])c4c3oc3c([2H])c([2H])c([2H])c([2H])c34)c1Cl)c1c([2H])c(C(C)(C)C)c([2H])c3c4c([2H])c(C(C)(C)C)c([2H])c([2H])c4n-2c13] | 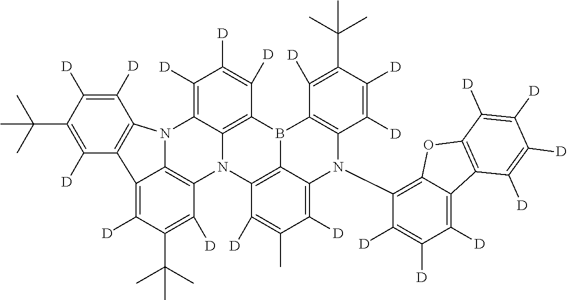 [SMILES: [2H]c1c([2H])c2c3c(c1[2H])-n1c4c([2H])c([2H])c(C(C)(C)C)c([2H])c4c4c([2H])c(C(C)(C)C)c([2H])c(c41)N3c1c([2H])c(C)c([2H])c3c1B2c1c([2H])c(C(C)(C)C)c([2H])c([2H])c1N3c1c([2H])c([2H])c([2H])c2c1oc1c([2H])c([2H])c([2H])c([2H])c12] | 2.90 g (14%) | 799.53 |
| 697 | 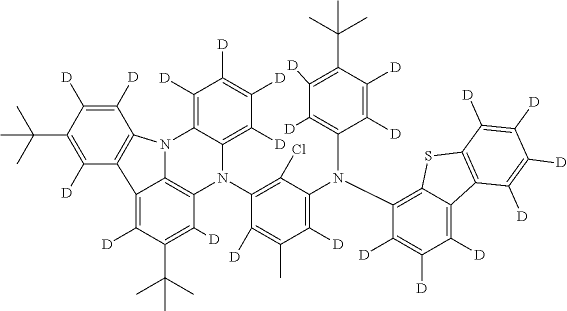 [SMILES: [2H]c1c([2H])c([2H])c2c(c1[2H])N(c1c([2H])c(C)c([2H])c(N(c3c([2H])c([2H])c(C(C)(C)C)c([2H])c3[2H])c3c([2H])c([2H])c([2H])c4c3sc3c([2H])c([2H])c([2H])c([2H])c34)c1Cl)c1c([2H])c(C(C)(C)C)c([2H])c3c4c([2H])c(C(C)(C)C)c([2H])c([2H])c4n-2c13] | 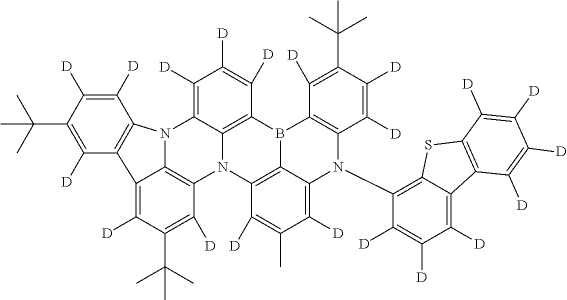 [SMILES: [2H]c1c([2H])c2c3c(c1[2H])-n1c4c([2H])c([2H])c(C(C)(C)C)c([2H])c4c4c([2H])c(C(C)(C)C)c([2H])c(c41)N3c1c([2H])c(C)c([2H])c3c1B2c1c([2H])c(C(C)(C)C)c([2H])c([2H])c1N3c1c([2H])c([2H])c([2H])c2c1sc1c([2H])c([2H])c([2H])c([2H])c12] | 3.10 g (15%) | 815.51 |
| 709 | 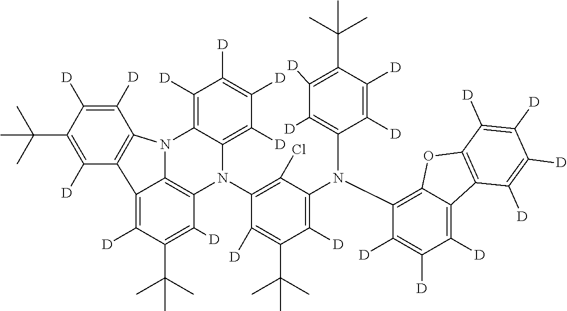 [SMILES: [2H]c1c([2H])c([2H])c2c(c1[2H])N(c1c([2H])c(C(C)(C)C)c([2H])c(N(c3c([2H])c([2H])c(C(C)(C)C)c([2H])c3[2H])c3c([2H])c([2H])c([2H])c4c3oc3c([2H])c([2H])c([2H])c([2H])c34)c1Cl)c1c([2H])c(C(C)(C)C)c([2H])c3c4c([2H])c(C(C)(C)C)c([2H])c([2H])c4n-2c13] | 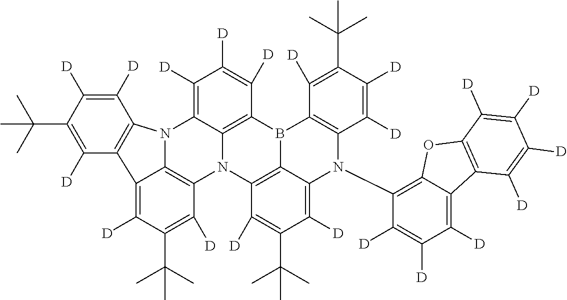 [SMILES: [2H]c1c([2H])c2c3c(c1[2H])-n1c4c([2H])c([2H])c(C(C)(C)C)c([2H])c4c4c([2H])c(C(C)(C)C)c([2H])c(c41)N3c1c([2H])c(C(C)(C)C)c([2H])c3c1B2c1c([2H])c(C(C)(C)C)c([2H])c([2H])c1N3c1c([2H])c([2H])c([2H])c2c1oc1c([2H])c([2H])c([2H])c([2H])c12] | 2.89 g (14%) | 841.58 |
| 713 | 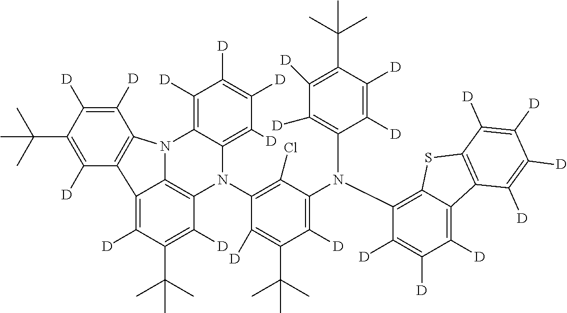 [SMILES: [2H]c1c([2H])c([2H])c2c(c1[2H])N(c1c([2H])c(C(C)(C)C)c([2H])c(N(c3c([2H])c([2H])c(C(C)(C)C)c([2H])c3[2H])c3c([2H])c([2H])c([2H])c4c3sc3c([2H])c([2H])c([2H])c([2H])c34)c1Cl)c1c([2H])c(C(C)(C)C)c([2H])c3c4c([2H])c(C(C)(C)C)c([2H])c([2H])c4n-2c13] | 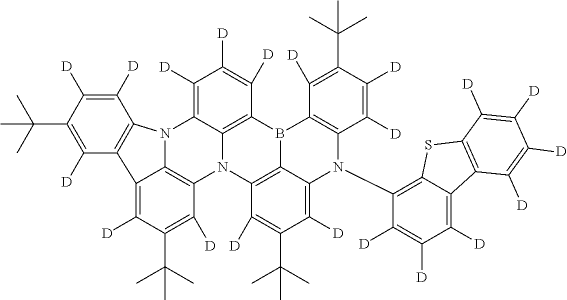 [SMILES: [2H]c1c([2H])c2c3c(c1[2H])-n1c4c([2H])c([2H])c(C(C)(C)C)c([2H])c4c4c([2H])c(C(C)(C)C)c([2H])c(c41)N3c1c([2H])c(C(C)(C)C)c([2H])c3c1B2c1c([2H])c(C(C)(C)C)c([2H])c([2H])c1N3c1c([2H])c([2H])c([2H])c2c1sc1c([2H])c([2H])c([2H])c([2H])c12] | 2.68 g (13%) | 857.55 |
| 721 | 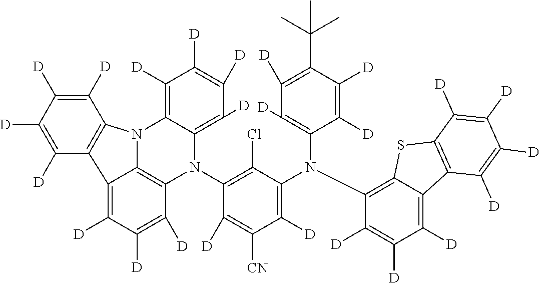 [SMILES: [2H]c1c([2H])c([2H])c2c(c1[2H])N(c1c([2H])c(C#N)c([2H])c(N(c3c([2H])c([2H])c(C(C)(C)C)c([2H])c3[2H])c3c([2H])c([2H])c([2H])c4c3sc3c([2H])c([2H])c([2H])c([2H])c34)c1Cl)c1c([2H])c([2H])c([2H])c3c4c([2H])c([2H])c([2H])c([2H])c4n-2c13] | 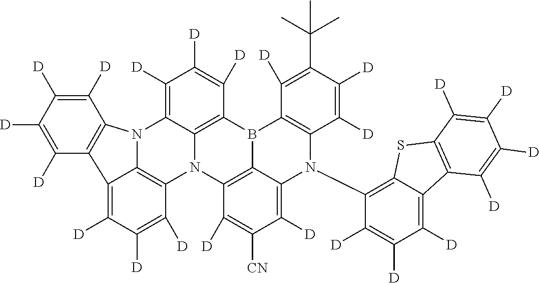 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C#N)c([2H])c3c1B2c1c([2H])c(C(C)(C)C)c([2H])c([2H])c1N3c1c([2H])c([2H])c([2H])c2c1sc1c([2H])c([2H])c([2H])c([2H])c12] | 2.91 g (14%) | 716.37 |
| 745 | 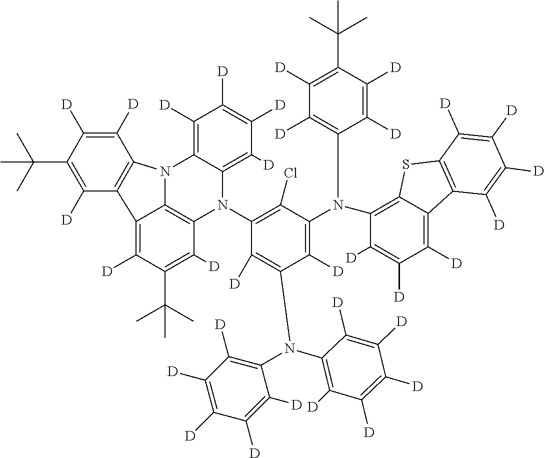 [SMILES: [2H]c1c([2H])c([2H])c(N(c2c([2H])c([2H])c([2H])c([2H])c2[2H])c2c([2H])c(N(c3c([2H])c([2H])c(C(C)(C)C)c([2H])c3[2H])c3c([2H])c([2H])c([2H])c4c3sc3c([2H])c([2H])c([2H])c([2H])c34)c(Cl)c(N3c4c([2H])c([2H])c([2H])c([2H])c4-n4c5c([2H])c([2H])c(C(C)(C)C)c([2H])c5c5c([2H])c(C(C)(C)C)c([2H])c3c54)c2[2H])c([2H])c1[2H]] | 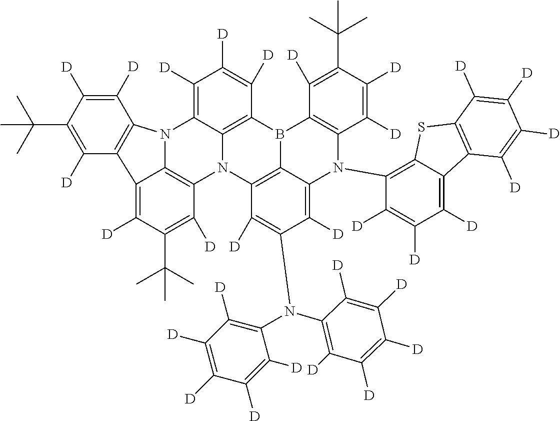 [SMILES: [2H]c1c([2H])c([2H])c(N(c2c([2H])c([2H])c([2H])c([2H])c2[2H])c2c([2H])c3c4c(c2[2H])N2c5c(c([2H])c([2H])c([2H])c5-n5c6c([2H])c([2H])c(C(C)(C)C)c([2H])c6c6c([2H])c(C(C)(C)C)c([2H])c2c65)B4c2c([2H])c(C(C)(C)C)c([2H])c([2H])c2N3c2c([2H])c([2H])c([2H])c3c2sc2c([2H])c([2H])c([2H])c([2H])c23)c([2H])c1[2H]] | 2.67 g (13%) | 978.63 |
| 759 | 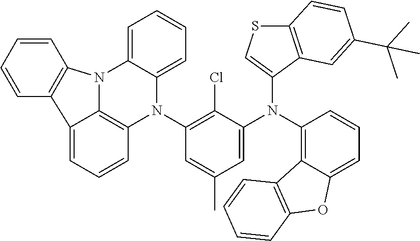 [SMILES: Cc1cc(N(c2csc3ccc(C(C)(C)C)cc23)c2cccc3oc4ccccc4c23)c(Cl)c(N2c3ccccc3-n3c4ccccc4c4cccc2c43)c1] | 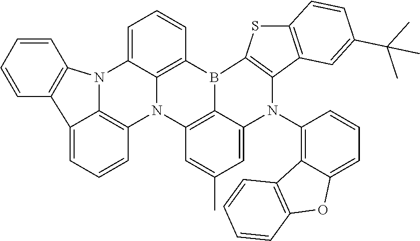 [SMILES: Cc1cc2c3c(c1)N1c4c(cccc4-n4c5ccccc5c5cccc1c54)B3c1sc3ccc(C(C)(C)C)cc3c1N2c1cccc2oc3ccccc3c12] | 3.31 g (16%) | 723.25 |
| 821 | 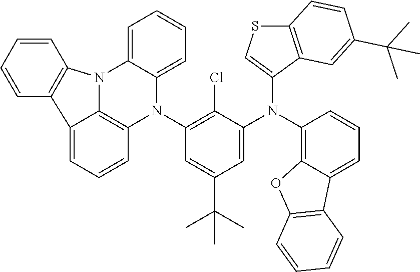 [SMILES: CC(C)(C)c1cc(N(c2csc3ccc(C(C)(C)C)cc23)c2cccc3c2oc2ccccc23)c(Cl)c(N2c3ccccc3-n3c4ccccc4c4cccc2c43)c1] | 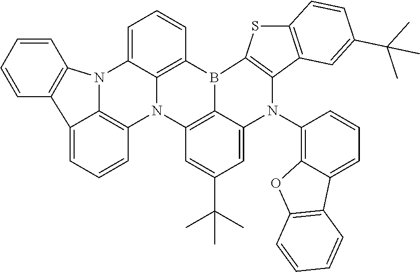 [SMILES: CC(C)(C)c1cc2c3c(c1)N1c4c(cccc4-n4c5ccccc5c5cccc1c54)B3c1sc3ccc(C(C)(C)C)cc3c1N2c1cccc2c1oc1ccccc12] | 2.48 g (12%) | 765.30 |
| 825 | 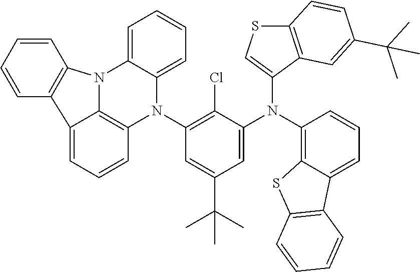 [SMILES: CC(C)(C)c1cc(N(c2csc3ccc(C(C)(C)C)cc23)c2cccc3c2sc2ccccc23)c(Cl)c(N2c3ccccc3-n3c4ccccc4c4cccc2c43)c1] | 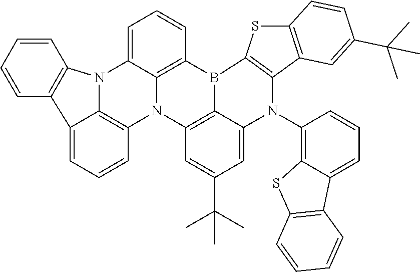 [SMILES: CC(C)(C)c1cc2c3c(c1)N1c4c(cccc4-n4c5ccccc5c5cccc1c54)B3c1sc3ccc(C(C)(C)C)cc3c1N2c1cccc2c1sc1ccccc12] | 2.48 g (12%) | 781.28 |
| 829 | 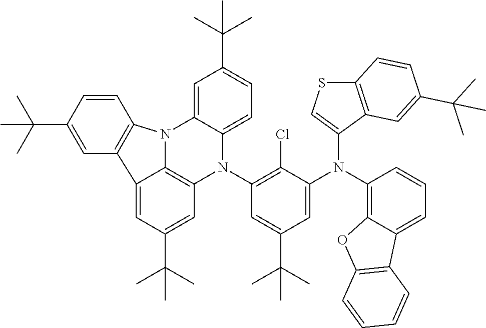 [SMILES: CC(C)(C)c1cc(N(c2csc3ccc(C(C)(C)C)cc23)c2cccc3c2oc2ccccc23)c(Cl)c(N2c3ccc(C(C)(C)C)cc3-n3c4ccc(C(C)(C)C)cc4c4cc(C(C)(C)C)cc2c43)c1] | 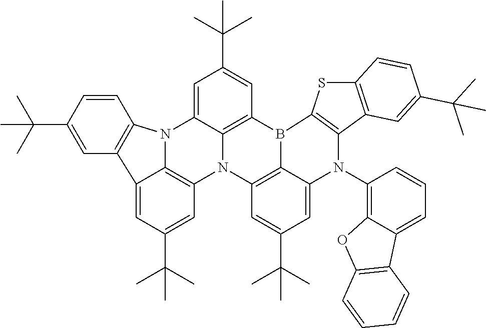 [SMILES: CC(C)(C)c1cc2c3c(c1)N1c4c(cc(C(C)(C)C)cc4-n4c5ccc(C(C)(C)C)cc5c5cc(C(C)(C)C)cc1c54)B3c1sc3ccc(C(C)(C)C)cc3c1N2c1cccc2c1oc1ccccc12] | 2.26 g (11%) | 933.49 |
| 833 | 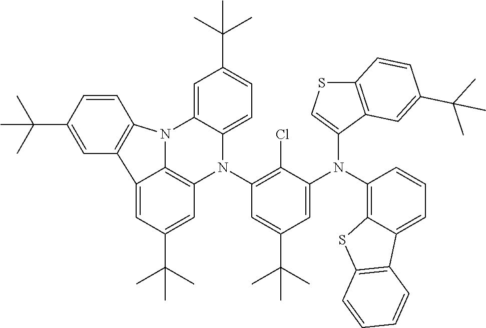 [SMILES: CC(C)(C)c1cc(N(c2csc3ccc(C(C)(C)C)cc23)c2cccc3c2sc2ccccc23)c(Cl)c(N2c3ccc(C(C)(C)C)cc3-n3c4ccc(C(C)(C)C)cc4c4cc(C(C)(C)C)cc2c43)c1] | 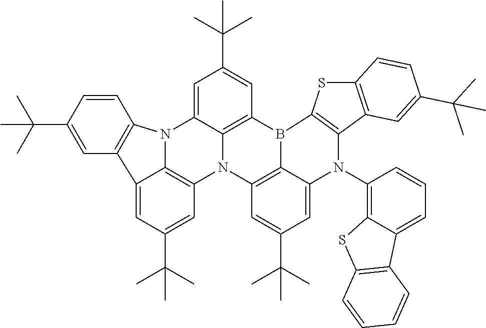 [SMILES: CC(C)(C)c1cc2c3c(c1)N1c4c(cc(C(C)(C)C)cc4-n4c5ccc(C(C)(C)C)cc5c5cc(C(C)(C)C)cc1c54)B3c1sc3ccc(C(C)(C)C)cc3c1N2c1cccc2c1sc1ccccc12] | 2.67 g (13%) | 949.46 |
| 837 | 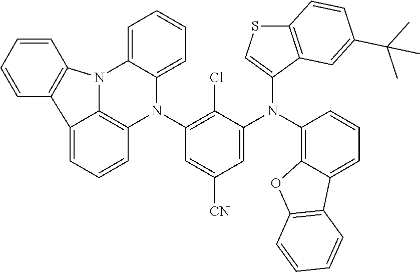 [SMILES: CC(C)(C)c1ccc2scc(N(c3cc(C#N)cc(N4c5ccccc5-n5c6ccccc6c6cccc4c65)c3Cl)c3cccc4c3oc3ccccc34)c2c1] | 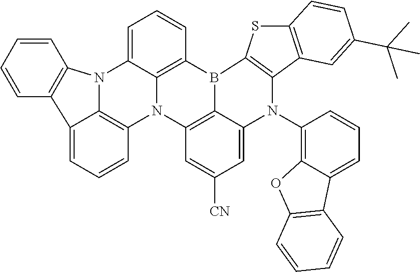 [SMILES: CC(C)(C)c1ccc2sc3c(c2c1)N(c1cccc2c1oc1ccccc12)c1cc(C#N)cc2c1B3c1cccc3c1N2c1cccc2c4ccccc4n-3c12] | 2.07 g (10%) | 734.23 |
| 841 | 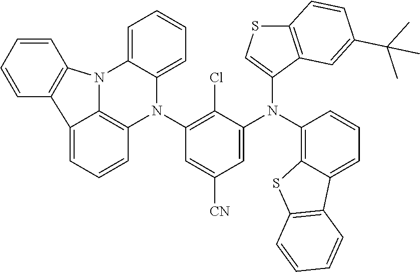 [SMILES: CC(C)(C)c1ccc2scc(N(c3cc(C#N)cc(N4c5ccccc5-n5c6ccccc6c6cccc4c65)c3Cl)c3cccc4c3sc3ccccc34)c2c1] | 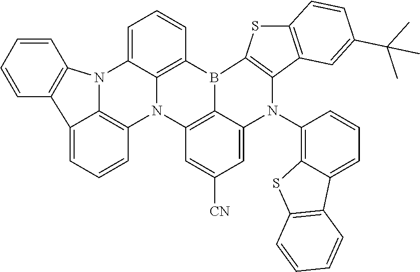 [SMILES: CC(C)(C)c1ccc2sc3c(c2c1)N(c1cccc2c1sc1ccccc12)c1cc(C#N)cc2c1B3c1cccc3c1N2c1cccc2c4ccccc4n-3c12] | 2.28 g (11%) | 750.21 |
| 861 | 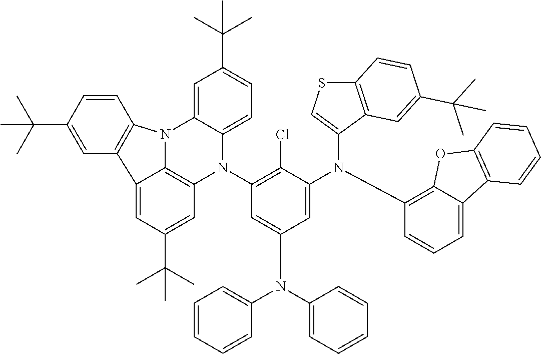 [SMILES: CC(C)(C)c1ccc2c(c1)-n1c3ccc(C(C)(C)C)cc3c3cc(C(C)(C)C)cc(c31)N2c1cc(N(c2ccccc2)c2ccccc2)cc(N(c2csc3ccc(C(C)(C)C)cc23)c2cccc3c2oc2ccccc23)c1Cl] | 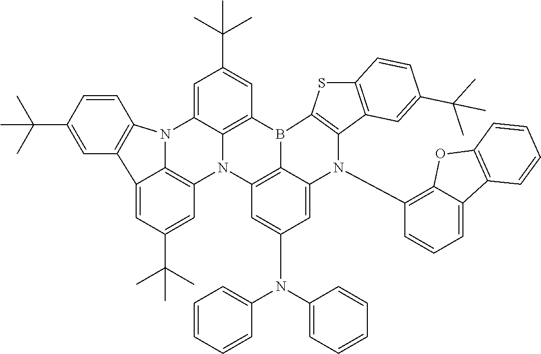 [SMILES: CC(C)(C)c1cc2c3c(c1)-n1c4ccc(C(C)(C)C)cc4c4cc(C(C)(C)C)cc(c41)N3c1cc(N(c3ccccc3)c3ccccc3)cc3c1B2c1sc2ccc(C(C)(C)C)cc2c1N3c1cccc2c1oc1ccccc12] | 2.46 g (12%) | 1044.50 |
| 936 | 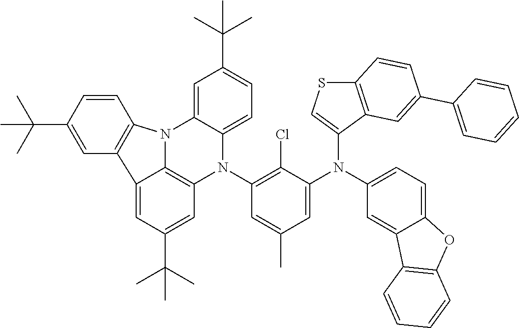 [SMILES: Cc1cc(N(c2ccc3oc4ccccc4c3c2)c2csc3ccc(-c4ccccc4)cc23)c(Cl)c(N2c3ccc(C(C)(C)C)cc3-n3c4ccc(C(C)(C)C)cc4c4cc(C(C)(C)C)cc2c43)c1] | 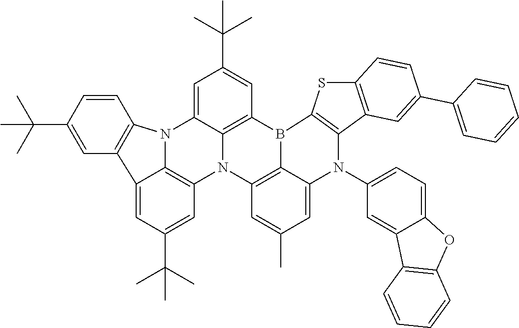 [SMILES: Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2oc3ccccc3c2c1] | 2.67 g (13%) | 911.41 |
| 939 | 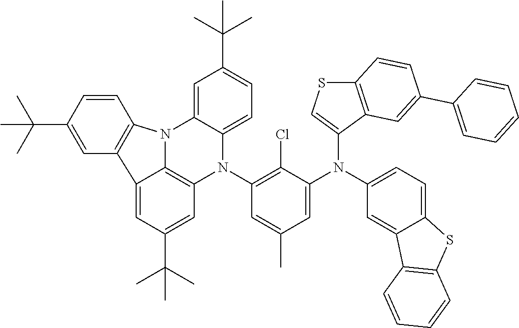 [SMILES: Cc1cc(N(c2ccc3sc4ccccc4c3c2)c2csc3ccc(-c4ccccc4)cc23)c(Cl)c(N2c3ccc(C(C)(C)C)cc3-n3c4ccc(C(C)(C)C)cc4c4cc(C(C)(C)C)cc2c43)c1] | 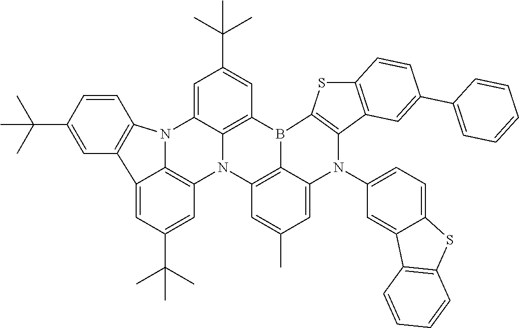 [SMILES: Cc1cc2c3c(c1)N1c4c(cc(C(C)(C)C)cc4-n4c5ccc(C(C)(C)C)cc5c5cc(C(C)(C)C)cc1c54)B3c1sc3ccc(-c4ccccc4)cc3c1N2c1ccc2sc3ccccc3c2c1] | 2.47 g (12%) | 927.39 |
| 941 | 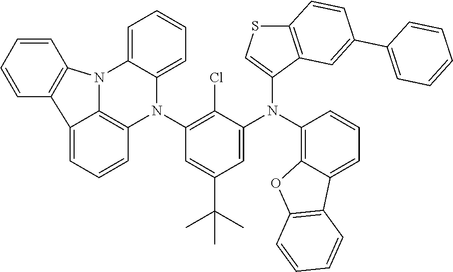 [SMILES: CC(C)(C)c1cc(N(c2csc3ccc(-c4ccccc4)cc23)c2cccc3c2oc2ccccc23)c(Cl)c(N2c3ccccc3-n3c4ccccc4c4cccc2c43)c1] | 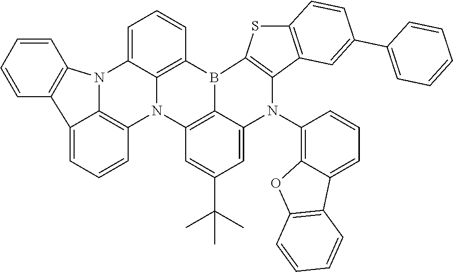 [SMILES: CC(C)(C)c1cc2c3c(c1)N1c4c(cccc4-n4c5ccccc5c5cccc1c54)B3c1sc3ccc(-c4ccccc4)cc3c1N2c1cccc2c1oc1ccccc12] | 2.89 g (14%) | 785.27 |
| 945 | 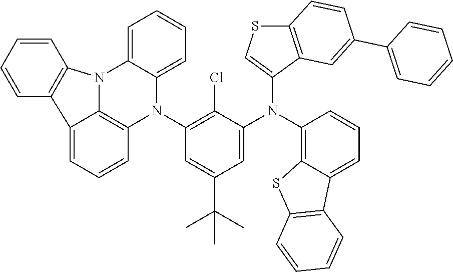 [SMILES: CC(C)(C)c1cc(N(c2csc3ccc(-c4ccccc4)cc23)c2cccc3c2sc2ccccc23)c(Cl)c(N2c3ccccc3-n3c4ccccc4c4cccc2c43)c1] | 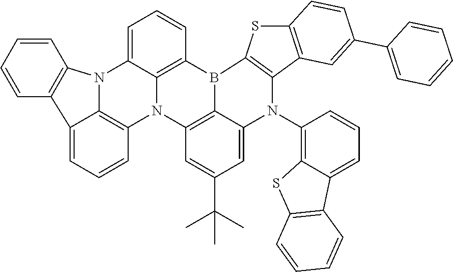 [SMILES: CC(C)(C)c1cc2c3c(c1)N1c4c(cccc4-n4c5ccccc5c5cccc1c54)B3c1sc3ccc(-c4ccccc4)cc3c1N2c1cccc2c1sc1ccccc12] | 2.68 g (13%) | 801.24 |
| 957 | 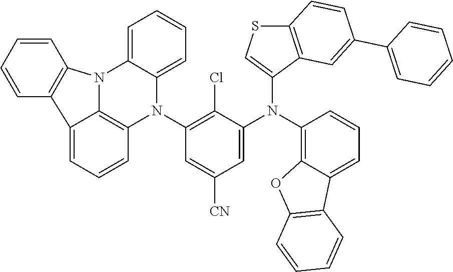 [SMILES: N#Cc1cc(N(c2csc3ccc(-c4ccccc4)cc23)c2cccc3c2oc2ccccc23)c(Cl)c(N2c3ccccc3-n3c4ccccc4c4cccc2c43)c1] | 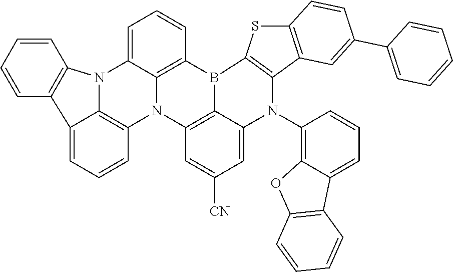 [SMILES: N#Cc1cc2c3c(c1)N1c4c(cccc4-n4c5ccccc5c5cccc1c54)B3c1sc3ccc(-c4ccccc4)cc3c1N2c1cccc2c1oc1ccccc12] | 2.48 g (12%) | 754.20 |
| 997 | 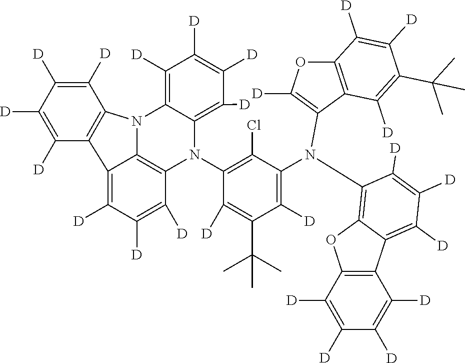 [SMILES: [2H]c1oc2c([2H])c([2H])c(C(C)(C)C)c([2H])c2c1N(c1c([2H])c(C(C)(C)C)c([2H])c(N2c3c([2H])c([2H])c([2H])c([2H])c3-n3c4c([2H])c([2H])c([2H])c([2H])c4c4c([2H])c([2H])c([2H])c2c43)c1Cl)c1c([2H])c([2H])c([2H])c2c1oc1c([2H])c([2H])c([2H])c([2H])c12] | 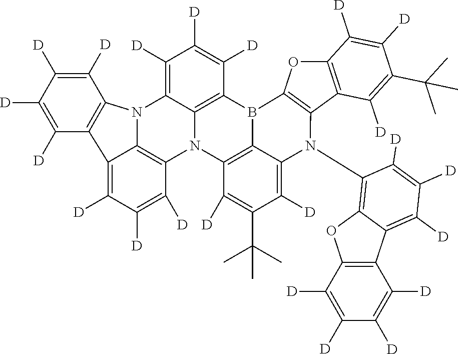 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C(C)(C)C)c([2H])c3c1B2c1oc2c([2H])c([2H])c(C(C)(C)C)c([2H])c2c1N3c1c([2H])c([2H])c([2H])c2c1oc1c([2H])c([2H])c([2H])c([2H])c12] | 2.28 g (11%) | 771.46 |
| 1053 | 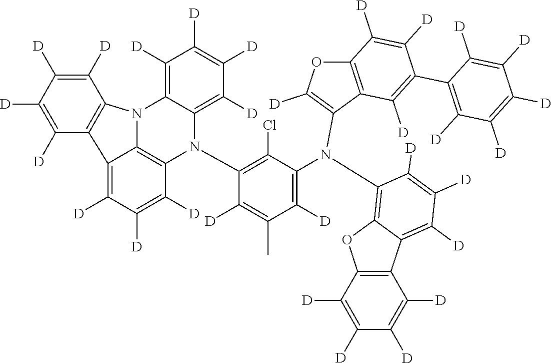 [SMILES: [2H]c1oc2c([2H])c([2H])c(-c3c([2H])c([2H])c([2H])c([2H])c3[2H])c([2H])c2c1N(c1c([2H])c(C)c([2H])c(N2c3c([2H])c([2H])c([2H])c([2H])c3-n3c4c([2H])c([2H])c([2H])c([2H])c4c4c([2H])c([2H])c([2H])c2c43)c1Cl)c1c([2H])c([2H])c([2H])c2c1oc1c([2H])c([2H])c([2H])c([2H])c12] | 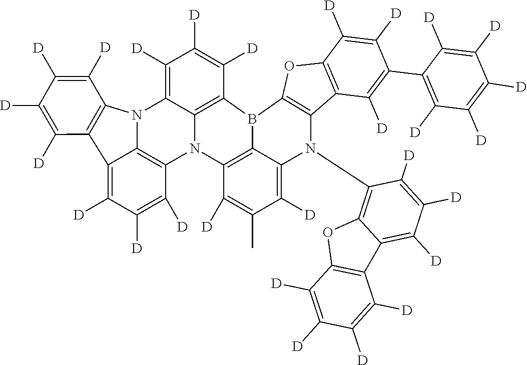 [SMILES: [2H]c1c([2H])c([2H])c(-c2c([2H])c([2H])c3oc4c(c3c2[2H])N(c2c([2H])c([2H])c([2H])c3c2oc2c([2H])c([2H])c([2H])c([2H])c23)c2c([2H])c(C)c([2H])c3c2B4c2c([2H])c([2H])c([2H])c4c2N3c2c([2H])c([2H])c([2H])c3c5c([2H])c([2H])c([2H])c([2H])c5n-4c23)c([2H])c1[2H]] | 2.49 g (12%) | 754.41 |
| 1057 | 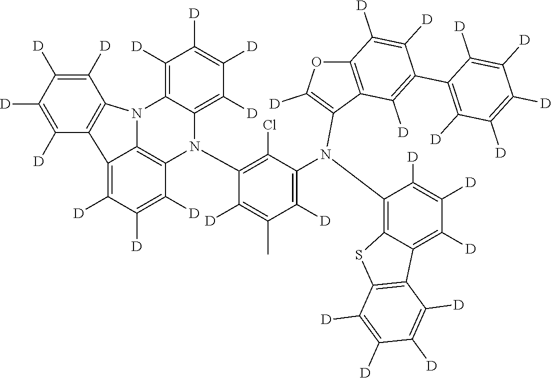 [SMILES: [2H]c1oc2c([2H])c([2H])c(-c3c([2H])c([2H])c([2H])c([2H])c3[2H])c([2H])c2c1N(c1c([2H])c(C)c([2H])c(N2c3c([2H])c([2H])c([2H])c([2H])c3-n3c4c([2H])c([2H])c([2H])c([2H])c4c4c([2H])c([2H])c([2H])c2c43)c1Cl)c1c([2H])c([2H])c([2H])c2c1sc1c([2H])c([2H])c([2H])c([2H])c12] | 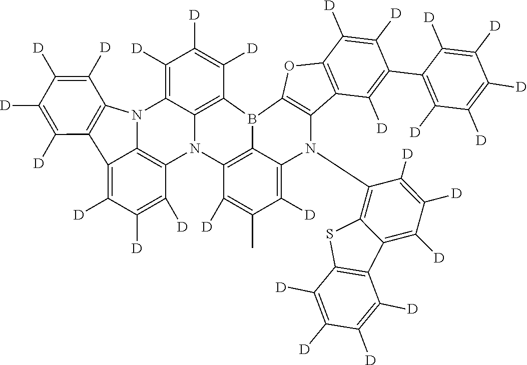 [SMILES: [2H]c1c([2H])c([2H])c(-c2c([2H])c([2H])c3oc4c(c3c2[2H])N(c2c([2H])c([2H])c([2H])c3c2sc2c([2H])c([2H])c([2H])c([2H])c23)c2c([2H])c(C)c([2H])c3c2B4c2c([2H])c([2H])c([2H])c4c2N3c2c([2H])c([2H])c([2H])c3c5c([2H])c([2H])c([2H])c([2H])c5n-4c23)c([2H])c1[2H]] | 2.49 g (12%) | 770.39 |
| 1077 | 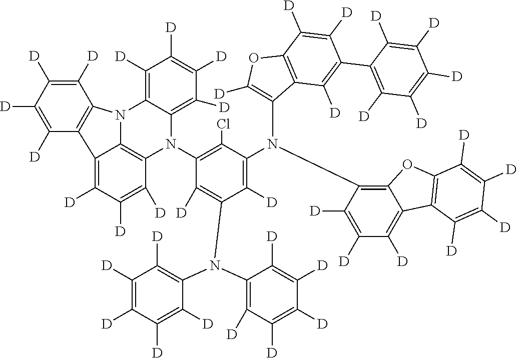 [SMILES: [2H]c1oc2c([2H])c([2H])c(-c3c([2H])c([2H])c([2H])c([2H])c3[2H])c([2H])c2c1N(c1c([2H])c(N(c2c([2H])c([2H])c([2H])c([2H])c2[2H])c2c([2H])c([2H])c([2H])c([2H])c2[2H])c([2H])c(N2c3c([2H])c([2H])c([2H])c([2H])c3-n3c4c([2H])c([2H])c([2H])c([2H])c4c4c([2H])c([2H])c([2H])c2c43)c1Cl)c1c([2H])c([2H])c([2H])c2c1oc1c([2H])c([2H])c([2H])c([2H])c12] | 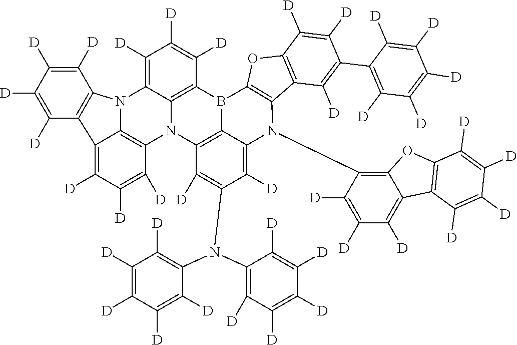 [SMILES: [2H]c1c([2H])c([2H])c(-c2c([2H])c([2H])c3oc4c(c3c2[2H])N(c2c([2H])c([2H])c([2H])c3c2oc2c([2H])c([2H])c([2H])c([2H])c23)c2c([2H])c(N(c3c([2H])c([2H])c([2H])c([2H])c3[2H])c3c([2H])c([2H])c([2H])c([2H])c3[2H])c([2H])c3c2B4c2c([2H])c([2H])c([2H])c4c2N3c2c([2H])c([2H])c([2H])c3c5c([2H])c([2H])c([2H])c([2H])c5n-4c23)c([2H])c1[2H]] | 2.27 g (11%) | 917.53 |
| 1085 | 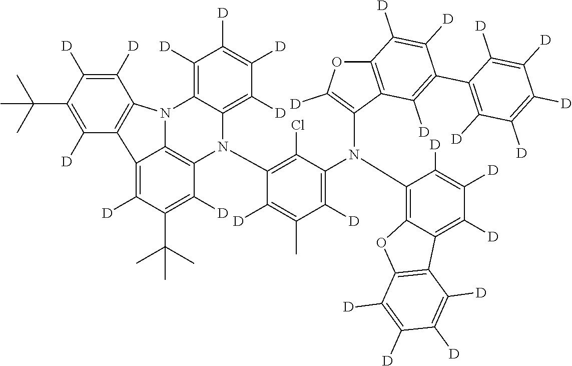 [SMILES: [2H]c1oc2c([2H])c([2H])c(-c3c([2H])c([2H])c([2H])c([2H])c3[2H])c([2H])c2c1N(c1c([2H])c(C)c([2H])c(N2c3c([2H])c([2H])c([2H])c([2H])c3-n3c4c([2H])c([2H])c(C(C)(C)C)c([2H])c4c4c([2H])c(C(C)(C)C)c([2H])c2c43)c1Cl)c1c([2H])c([2H])c([2H])c2c1oc1c([2H])c([2H])c([2H])c([2H])c12] | 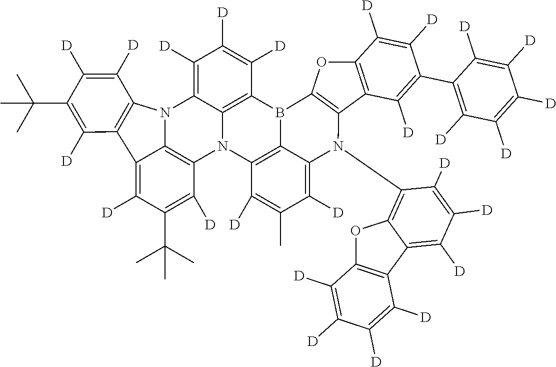 [SMILES: [2H]c1c([2H])c([2H])c(-c2c([2H])c([2H])c3oc4c(c3c2[2H])N(c2c([2H])c([2H])c([2H])c3c2oc2c([2H])c([2H])c([2H])c([2H])c23)c2c([2H])c(C)c([2H])c3c2B4c2c([2H])c([2H])c([2H])c4c2N3c2c([2H])c(C(C)(C)C)c([2H])c3c5c([2H])c(C(C)(C)C)c([2H])c([2H])c5n-4c23)c([2H])c1[2H]] | 2.68 g (13%) | 864.53 |
| 1089 | 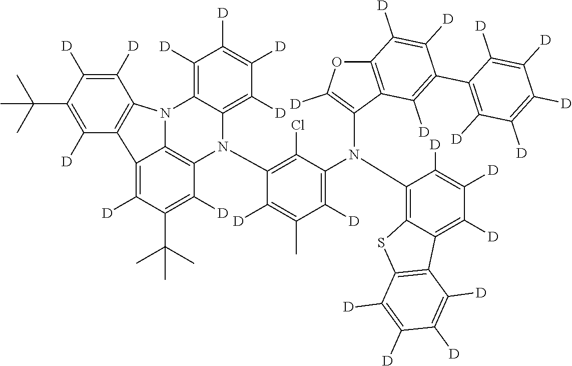 [SMILES: [2H]c1oc2c([2H])c([2H])c(-c3c([2H])c([2H])c([2H])c([2H])c3[2H])c([2H])c2c1N(c1c([2H])c(C)c([2H])c(N2c3c([2H])c([2H])c([2H])c([2H])c3-n3c4c([2H])c([2H])c(C(C)(C)C)c([2H])c4c4c([2H])c(C(C)(C)C)c([2H])c2c43)c1Cl)c1c([2H])c([2H])c([2H])c2c1sc1c([2H])c([2H])c([2H])c([2H])c12] | 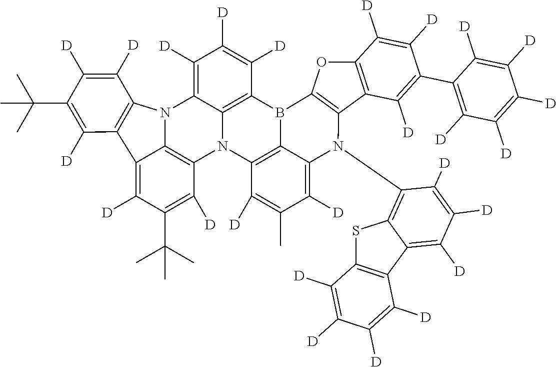 [SMILES: [2H]c1c([2H])c([2H])c(-c2c([2H])c([2H])c3oc4c(c3c2[2H])N(c2c([2H])c([2H])c([2H])c3c2sc2c([2H])c([2H])c([2H])c([2H])c23)c2c([2H])c(C)c([2H])c3c2B4c2c([2H])c([2H])c([2H])c4c2N3c2c([2H])c(C(C)(C)C)c([2H])c3c5c([2H])c(C(C)(C)C)c([2H])c([2H])c5n-4c23)c([2H])c1[2H]] | 2.48 g (12%) | 880.50 |
| 1117 | 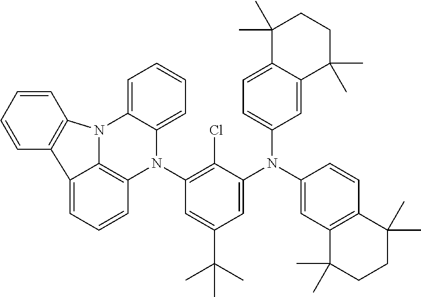 [SMILES: CC(C)(C)c1cc(N(c2ccc3c(c2)C(C)(C)CCC3(C)C)c2ccc3c(c2)C(C)(C)CCC3(C)C)c(Cl)c(N2c3ccccc3-n3c4ccccc4c4cccc2c43)c1] | 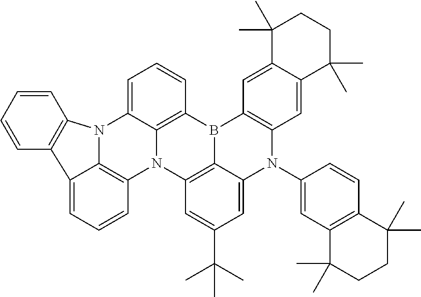 [SMILES: CC(C)(C)c1cc2c3c(c1)N1c4c(cccc4-n4c5ccccc5c5cccc1c54)B3c1cc3c(cc1N2c1ccc2c(c1)C(C)(C)CCC2(C)C)C(C)(C)CCC3(C)C] | 3.51 g (17%) | 783.47 |
| 1118 | 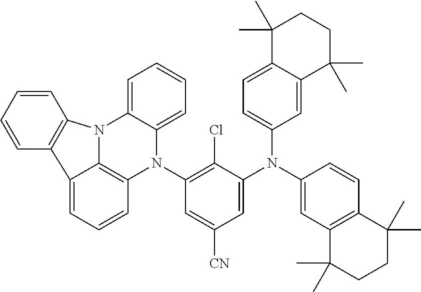 [SMILES: CC1(C)CCC(C)(C)c2cc(N(c3ccc4c(c3)C(C)(C)CCC4(C)C)c3cc(C#N)cc(N4c5ccccc5-n5c6ccccc6c6cccc4c65)c3Cl)ccc21] | 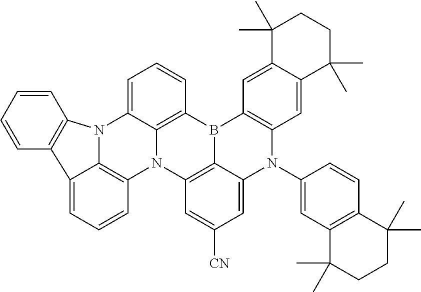 [SMILES: CC1(C)CCC(C)(C)c2cc(N3c4cc5c(cc4B4c6cccc7c6N(c6cc(C#N)cc3c64)c3cccc4c6ccccc6n-7c34)C(C)(C)CCC5(C)C)ccc21] | 2.69 g (13%) | 752.41 |
| 1119 | 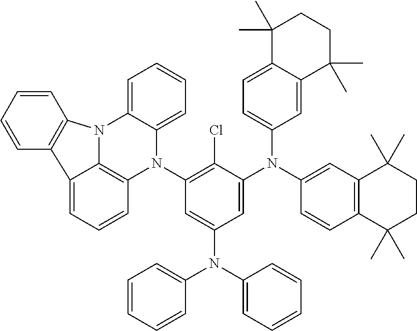 [SMILES: CC1(C)CCC(C)(C)c2cc(N(c3ccc4c(c3)C(C)(C)CCC4(C)C)c3cc(N(c4ccccc4)c4ccccc4)cc(N4c5ccccc5-n5c6ccccc6c6cccc4c65)c3Cl)ccc21] | 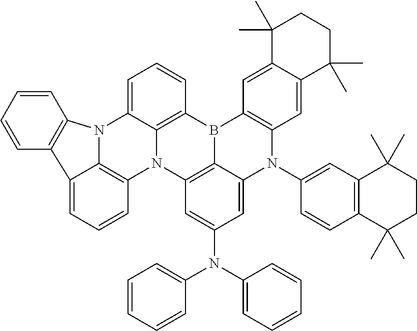 [SMILES: CC1(C)CCC(C)(C)c2cc(N3c4cc5c(cc4B4c6cccc7c6N(c6cc(N(c8ccccc8)c8ccccc8)cc3c64)c3cccc4c6ccccc6n-7c34)C(C)(C)CCC5(C)C)ccc21] | 3.09 g (15%) | 894.48 |
| 1120 | 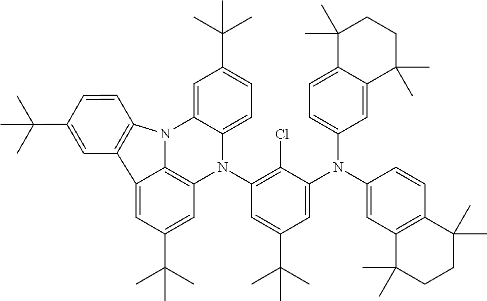 [SMILES: CC(C)(C)c1cc(N(c2ccc3c(c2)C(C)(C)CCC3(C)C)c2ccc3c(c2)C(C)(C)CCC3(C)C)c(Cl)c(N2c3ccc(C(C)(C)C)cc3-n3c4ccc(C(C)(C)C)cc4c4cc(C(C)(C)C)cc2c43)c1] | 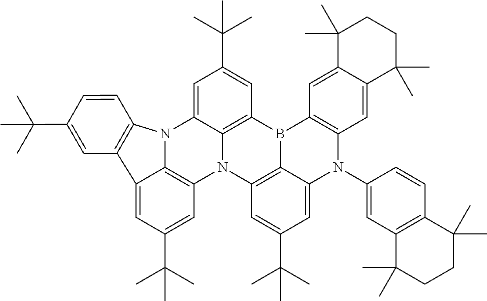 [SMILES: CC(C)(C)c1cc2c3c(c1)N1c4c(cc(C(C)(C)C)cc4-n4c5ccc(C(C)(C)C)cc5c5cc(C(C)(C)C)cc1c54)B3c1cc3c(cc1N2c1ccc2c(c1)C(C)(C)CCC2(C)C)C(C)(C)CCC3(C)C] | 3.29 g (16%) | 951.66 |
| 1121 | 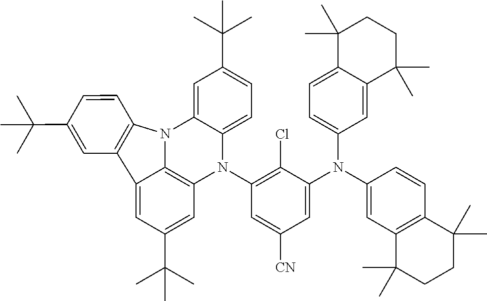 [SMILES: CC(C)(C)c1ccc2c(c1)-n1c3ccc(C(C)(C)C)cc3c3cc(C(C)(C)C)cc(c31)N2c1cc(C#N)cc(N(c2ccc3c(c2)C(C)(C)CCC3(C)C)c2ccc3c(c2)C(C)(C)CCC3(C)C)c1Cl] | 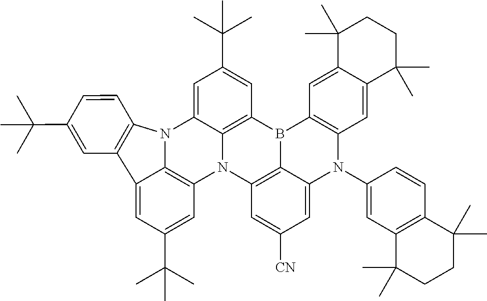 [SMILES: CC(C)(C)c1cc2c3c(c1)-n1c4ccc(C(C)(C)C)cc4c4cc(C(C)(C)C)cc(c41)N3c1cc(C#N)cc3c1B2c1cc2c(cc1N3c1ccc3c(c1)C(C)(C)CCC3(C)C)C(C)(C)CCC2(C)C] | 2.47g (12%) | 920.59 |
| 1122 | 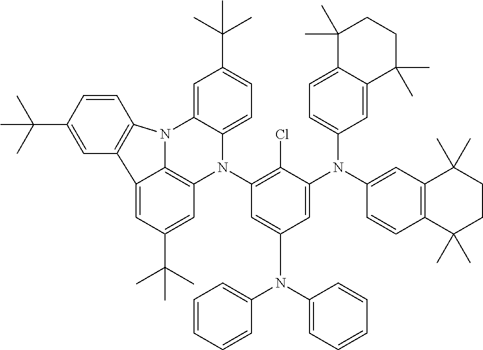 [SMILES: CC(C)(C)c1ccc2c(c1)-n1c3ccc(C(C)(C)C)cc3c3cc(C(C)(C)C)cc(c31)N2c1cc(N(c2ccccc2)c2ccccc2)cc(N(c2ccc3c(c2)C(C)(C)CCC3(C)C)c2ccc3c(c2)C(C)(C)CCC3(C)C)c1Cl] | 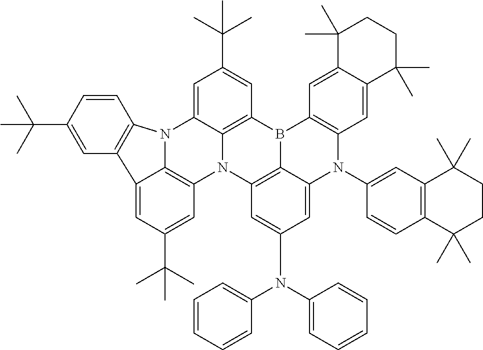 [SMILES: CC(C)(C)c1cc2c3c(c1)-n1c4ccc(C(C)(C)C)cc4c4cc(C(C)(C)C)cc(c41)N3c1cc(N(c3ccccc3)c3ccccc3)cc3c1B2c1cc2c(cc1N3c1ccc3c(c1)C(C)(C)CCC3(C)C)C(C)(C)CCC2(C)C] | 3.07 g (15%) | 1062.67 |
| 1123 | 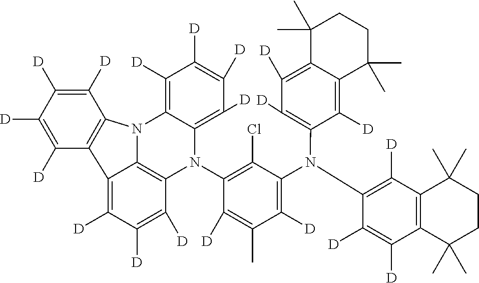 [SMILES: [2H]c1c([2H])c([2H])c2c(c1[2H])N(c1c([2H])c(C)c([2H])c(N(c3c([2H])c([2H])c4c(c3[2H])C(C)(C)CCC4(C)C)c3c([2H])c([2H])c4c(c3[2H])C(C)(C)CCC4(C)C)c1Cl)c1c([2H])c([2H])c([2H])c3c4c([2H])c([2H])c([2H])c([2H])c4n-2c13] | 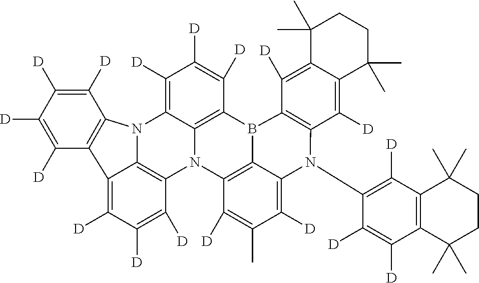 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C)c([2H])c3c1B2c1c([2H])c2c(c([2H])c1N3c1c([2H])c([2H])c3c(c1[2H])C(C)(C)CCC3(C)C)C(C)(C)CCC2(C)C] | 3.32 g (16%) | 758.53 |
| 1124 | 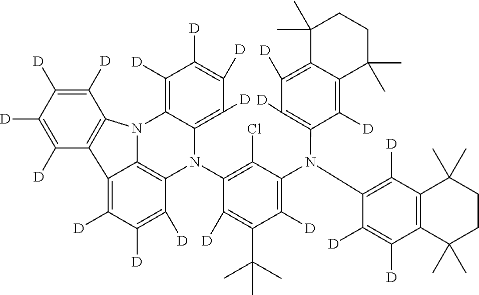 [SMILES: [2H]c1c([2H])c([2H])c2c(c1[2H])N(c1c([2H])c(C(C)(C)C)c([2H])c(N(c3c([2H])c([2H])c4c(c3[2H])C(C)(C)CCC4(C)C)c3c([2H])c([2H])c4c(c3[2H])C(C)(C)CCC4(C)C)c1Cl)c1c([2H])c([2H])c([2H])c3c4c([2H])c([2H])c([2H])c([2H])c4n-2c13] | 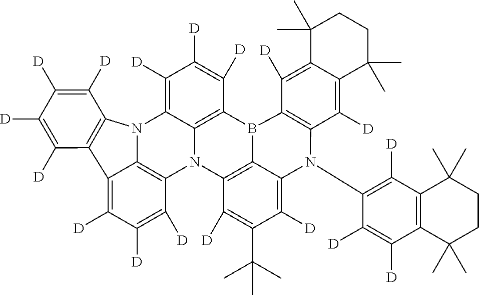 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C(C)(C)C)c([2H])c3c1B2c1c([2H])c2c(c([2H])c1N3c1c([2H])c([2H])c3c(c1[2H])C(C)(C)CCC3(C)C)C(C)(C)CCC2(C)C] | 3.10 g (15%) | 800.58 |
| 1125 | 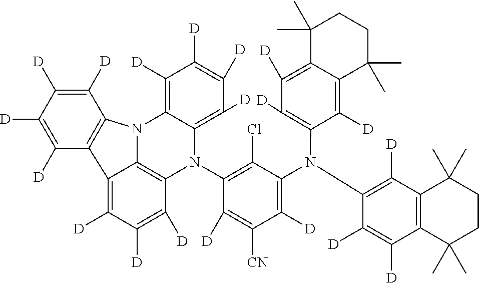 [SMILES: [2H]c1c([2H])c([2H])c2c(c1[2H])N(c1c([2H])c(C#N)c([2H])c(N(c3c([2H])c([2H])c4c(c3[2H])C(C)(C)CCC4(C)C)c3c([2H])c([2H])c4c(c3[2H])C(C)(C)CCC4(C)C)c1Cl)c1c([2H])c([2H])c([2H])c3c4c([2H])c([2H])c([2H])c([2H])c4n-2c13] | 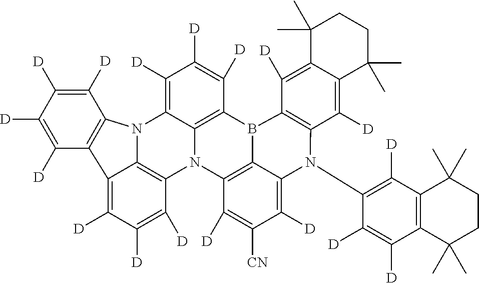 [SMILES: [2H]c1c([2H])c2c3c(c1[2H])-n1c4c([2H])c([2H])c([2H])c([2H])c4c4c([2H])c([2H])c([2H])c(c41)N3c1c([2H])c(C#N)c([2H])c3c1B2c1c([2H])c2c(c([2H])c1N3c1c([2H])c([2H])c3c(c1[2H])C(C)(C)CCC3(C)C)C(C)(C)CCC2(C)C] | 2.69 g (13%) | 769.51 |
| 1126 | 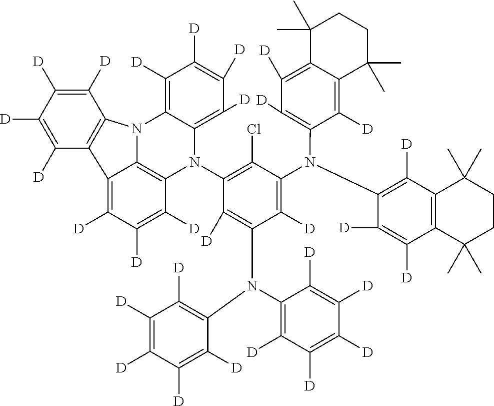 [SMILES: [2H]c1c([2H])c([2H])c(N(c2c([2H])c([2H])c([2H])c([2H])c2[2H])c2c([2H])c(N(c3c([2H])c([2H])c4c(c3[2H])C(C)(C)CCC4(C)C)c3c([2H])c([2H])c4c(c3[2H])C(C)(C)CCC4(C)C)c(Cl)c(N3c4c([2H])c([2H])c([2H])c([2H])c4-n4c5c([2H])c([2H])c([2H])c([2H])c5c5c([2H])c([2H])c([2H])c3c54)c2[2H])c([2H])c1[2H]] | 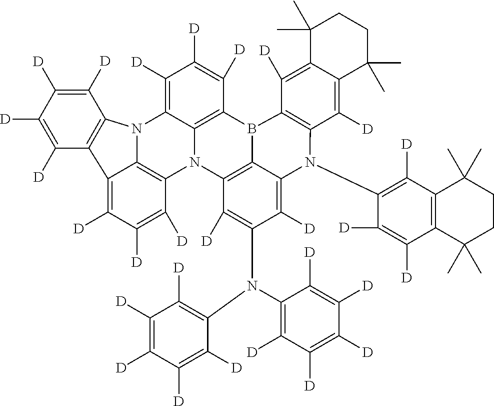 [SMILES: [2H]c1c([2H])c([2H])c(N(c2c([2H])c([2H])c([2H])c([2H])c2[2H])c2c([2H])c3c4c(c2[2H])N2c5c(c([2H])c([2H])c([2H])c5-n5c6c([2H])c([2H])c([2H])c([2H])c6c6c([2H])c([2H])c([2H])c2c65)B4c2c([2H])c4c(c([2H])c2N3c2c([2H])c([2H])c3c(c2[2H])C(C)(C)CCC3(C)C)C(C)(C)CCC4(C)C)c([2H])c1[2H]] | 2.89 g (14%) | 921.65 |
| 14 | 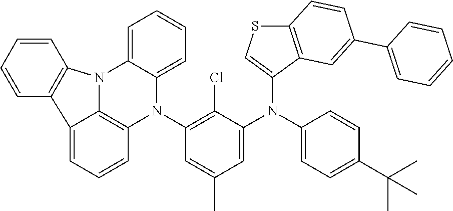 [SMILES: Cc1cc(N(c2ccc(C(C)(C)C)cc2)c2csc3ccc(-c4ccccc4)cc23)c(Cl)c(N2c3ccccc3-n3c4ccccc4c4cccc2c43)c1] | 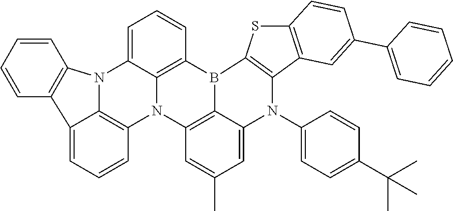 [SMILES: Cc1cc2c3c(c1)N1c4c(cccc4-n4c5ccccc5c5cccc1c54)B3c1sc3ccc(-c4ccccc4)cc3c1N2c1ccc(C(C)(C)C)cc1] | 2.90 g (14%) | 709.27 |
| 38 | 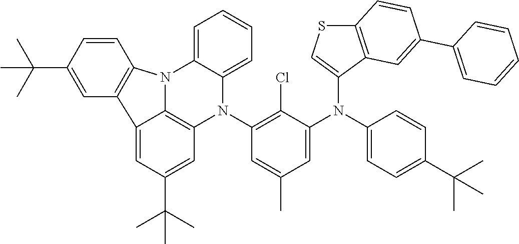 [SMILES: Cc1cc(N(c2ccc(C(C)(C)C)cc2)c2csc3ccc(-c4ccccc4)cc23)c(Cl)c(N2c3ccccc3-n3c4ccc(C(C)(C)C)cc4c4cc(C(C)(C)C)cc2c43)c1] | 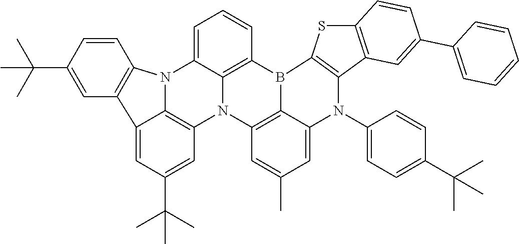 [SMILES: Cc1cc2c3c(c1)N1c4c(cccc4-n4c5ccc(C(C)(C)C)cc5c5cc(C(C)(C)C)cc1c54)B3c1sc3ccc(-c4ccccc4)cc3c1N2c1ccc(C(C)(C)C)cc1] | 2.68 g (13%) | 821.40 |
| 78 | 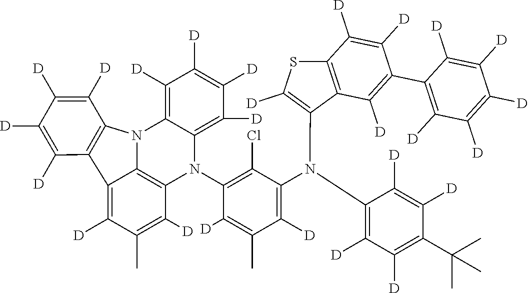 [SMILES: [2H]c1sc2c([2H])c([2H])c(-c3c([2H])c([2H])c([2H])c([2H])c3[2H])c([2H])c2c1N(c1c([2H])c([2H])c(C(C)(C)C)c([2H])c1[2H])c1c([2H])c(C)c([2H])c(N2c3c([2H])c([2H])c([2H])c([2H])c3-n3c4c([2H])c([2H])c([2H])c([2H])c4c4c([2H])c(C)c([2H])c2c43)c1Cl] | 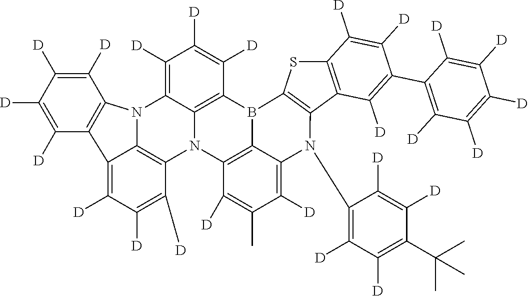 [SMILES: [2H]c1c([2H])c([2H])c(-c2c([2H])c([2H])c3sc4c(c3c2[2H])N(c2c([2H])c([2H])c(C(C)(C)C)c([2H])c2[2H])c2c([2H])c(C)c([2H])c3c2B4c2c([2H])c([2H])c([2H])c4c2N3c2c([2H])c([2H])c([2H])c3c5c([2H])c([2H])c([2H])c([2H])c5n-4c23)c([2H])c1[2H]] | 2.49 g (12%) | 733.42 |
| 1131 | 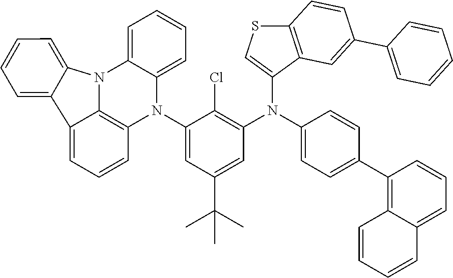 [SMILES: CC(C)(C)c1cc(N(c2ccc(-c3cccc4ccccc34)cc2)c2csc3ccc(-c4ccccc4)cc23)c(Cl)c(N2c3ccccc3-n3c4ccccc4c4cccc2c43)c1] | 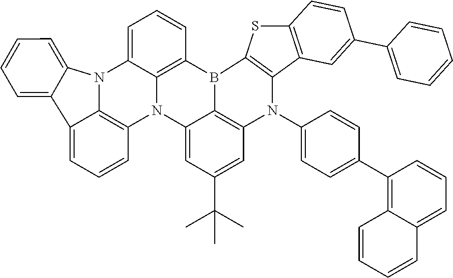 [SMILES: CC(C)(C)c1cc2c3c(c1)N1c4c(cccc4-n4c5ccccc5c5cccc1c54)B3c1sc3ccc(-c4ccccc4)cc3c1N2c1ccc(-c2cccc3ccccc23)cc1] | 2.48 g (12%) | 821.30 |
| 1132 | 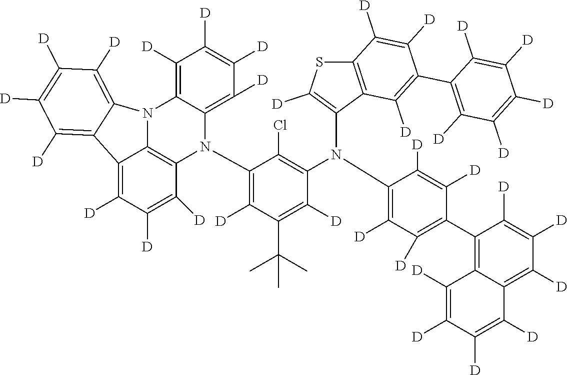 [SMILES: [2H]c1sc2c([2H])c([2H])c(-c3c([2H])c([2H])c([2H])c([2H])c3[2H])c([2H])c2c1N(c1c([2H])c([2H])c(-c2c([2H])c([2H])c([2H])c3c([2H])c([2H])c([2H])c([2H])c23)c([2H])c1[2H])c1c([2H])c(C(C)(C)C)c([2H])c(N2c3c([2H])c([2H])c([2H])c([2H])c3-n3c4c([2H])c([2H])c([2H])c([2H])c4c4c([2H])c([2H])c([2H])c2c43)c1Cl] | 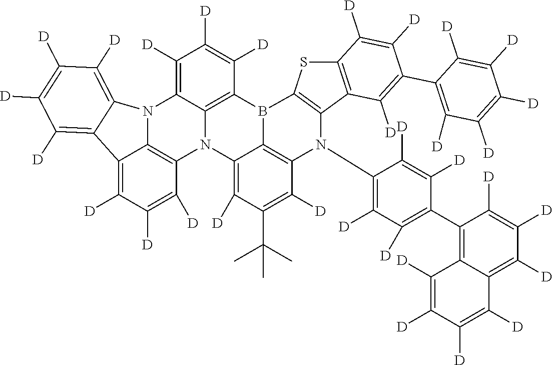 [SMILES: [2H]c1c([2H])c([2H])c(-c2c([2H])c([2H])c3sc4c(c3c2[2H])N(c2c([2H])c([2H])c(-c3c([2H])c([2H])c([2H])c5c([2H])c([2H])c([2H])c([2H])c35)c([2H])c2[2H])c2c([2H])c(C(C)(C)C)c([2H])c3c2B4c2c([2H])c([2H])c([2H])c4c2N3c2c([2H])c([2H])c([2H])c3c5c([2H])c([2H])c([2H])c([2H])c5n-4c23)c([2H])c1[2H]] | 2.48 g (12%) | 852.50 |
| 1133 | 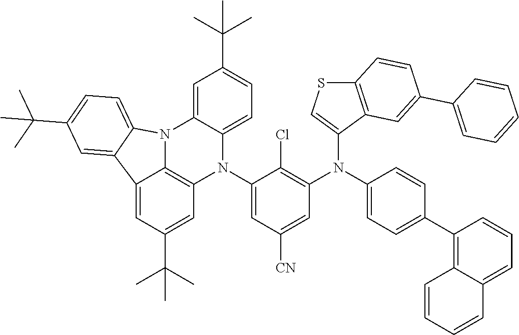 [SMILES: CC(C)(C)c1ccc2c(c1)-n1c3ccc(C(C)(C)C)cc3c3cc(C(C)(C)C)cc(c31)N2c1cc(C#N)cc(N(c2ccc(-c3cccc4ccccc34)cc2)c2csc3ccc(-c4ccccc4)cc23)c1Cl] | 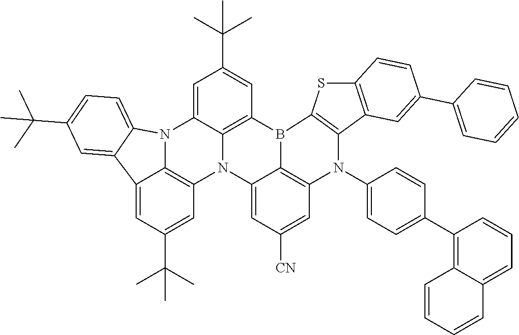 [SMILES: CC(C)(C)c1cc2c3c(c1)-n1c4ccc(C(C)(C)C)cc4c4cc(C(C)(C)C)cc(c41)N3c1cc(C#N)cc3c1B2c1sc2ccc(-c4ccccc4)cc2c1N3c1ccc(-c2cccc3ccccc23)cc1] | 2.67 g (13%) | 958.42 |
| 1134 | 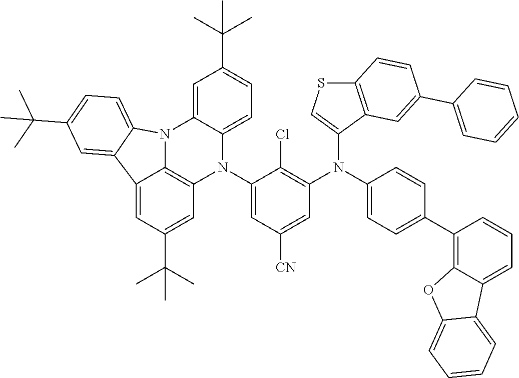 [SMILES: CC(C)(C)c1ccc2c(c1)-n1c3ccc(C(C)(C)C)cc3c3cc(C(C)(C)C)cc(c31)N2c1cc(C#N)cc(N(c2ccc(-c3cccc4c3oc3ccccc34)cc2)c2csc3ccc(-c4ccccc4)cc23)c1Cl] | 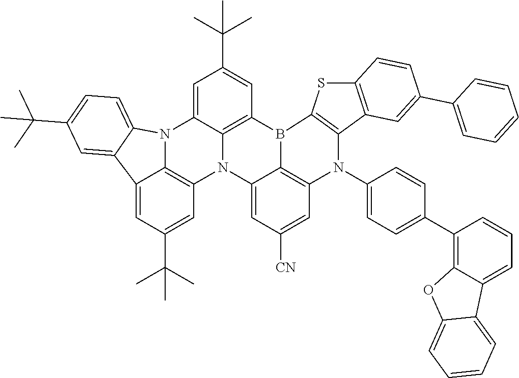 [SMILES: CC(C)(C)c1cc2c3c(c1)-n1c4ccc(C(C)(C)C)cc4c4cc(C(C)(C)C)cc(c41)N3c1cc(C#N)cc3c1B2c1sc2ccc(-c4ccccc4)cc2c1N3c1ccc(-c2cccc3c2oc2ccccc23)cc1] | 2.67 g (13%) | 998.42 |
| 1135 | 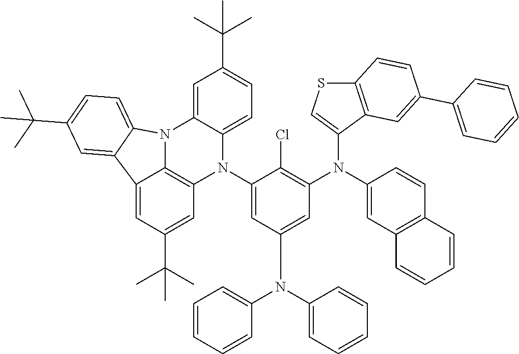 [SMILES: CC(C)(C)c1ccc2c(c1)-n1c3ccc(C(C)(C)C)cc3c3cc(C(C)(C)C)cc(c31)N2c1cc(N(c2ccccc2)c2ccccc2)cc(N(c2ccc3ccccc3c2)c2csc3ccc(-c4ccccc4)cc23)c1Cl] | 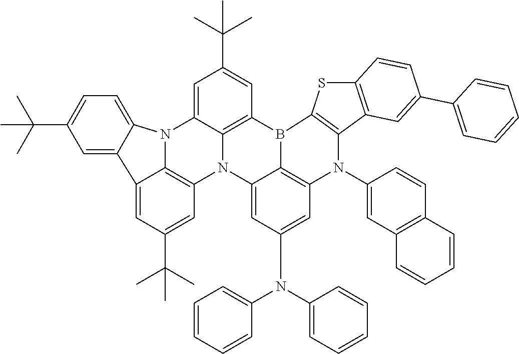 [SMILES: CC(C)(C)c1cc2c3c(c1)-n1c4ccc(C(C)(C)C)cc4c4cc(C(C)(C)C)cc(c41)N3c1cc(N(c3ccccc3)c3ccccc3)cc3c1B2c1sc2ccc(-c4ccccc4)cc2c1N3c1ccc2ccccc2c1] | 2.46 g (12%) | 1024.47 |
| 1136 | 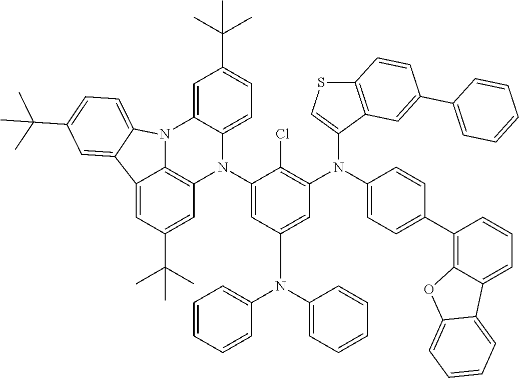 [SMILES: CC(C)(C)c1ccc2c(c1)-n1c3ccc(C(C)(C)C)cc3c3cc(C(C)(C)C)cc(c31)N2c1cc(N(c2ccccc2)c2ccccc2)cc(N(c2ccc(-c3cccc4c3oc3ccccc34)cc2)c2csc3ccc(-c4ccccc4)cc23)c1Cl] | 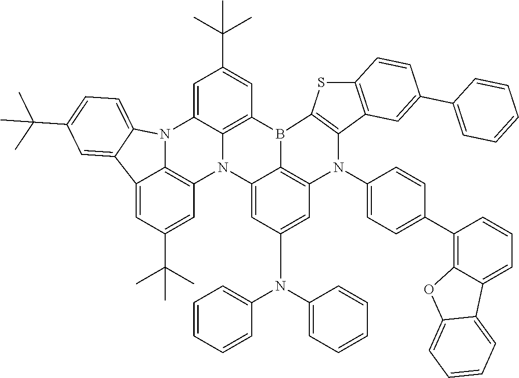 [SMILES: CC(C)(C)c1cc2c3c(c1)-n1c4ccc(C(C)(C)C)cc4c4cc(C(C)(C)C)cc(c41)N3c1cc(N(c3ccccc3)c3ccccc3)cc3c1B2c1sc2ccc(-c4ccccc4)cc2c1N3c1ccc(-c2cccc3c2oc2ccccc23)cc1] | 2.45 g (12%) | 1140.50 |
| 1137 | 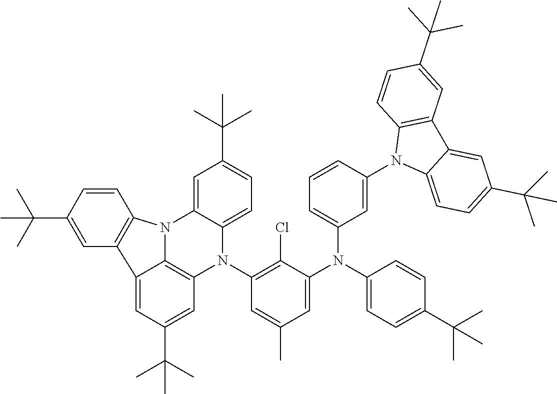 [SMILES: Cc1cc(N(c2ccc(C(C)(C)C)cc2)c2cccc(-n3c4ccc(C(C)(C)C)cc4c4cc(C(C)(C)C)ccc43)c2)c(Cl)c(N2c3ccc(C(C)(C)C)cc3-n3c4ccc(C(C)(C)C)cc4c4cc(C(C)(C)C)cc2c43)c1] | 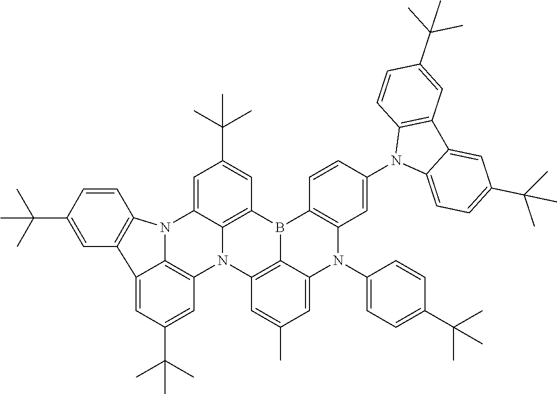 [SMILES: Cc1cc2c3c(c1)N1c4c(cc(C(C)(C)C)cc4-n4c5ccc(C(C)(C)C)cc5c5cc(C(C)(C)C)cc1c54)B3c1ccc(-n3c4ccc(C(C)(C)C)cc4c4cc(C(C)(C)C)ccc43)cc1N2c1ccc(C(C)(C)C)cc1] | 2.92 g (14%) | 1023.27 |

### Preparative Example: Preparation of Organic Light Emitting Diode (Green Emitting Layer)

### Example 1

A substrate with ITO (100 nm) deposited thereon as a first electrode of an organic light emitting diode was patterned by photolithography to define regions corresponding to the first electrode, a second electrode, and an insulating layer, followed by treatment with UV-ozone and surface treatment with O₂:N₂ plasma to enhance the work-function of the first electrode (ITO) and surface cleanness.

Next, 1,4,5,8,9,11-hexaazatriphenylenehexacarbonitrile (HAT-CN) as a hole injection layer (HIL) was deposited to a thickness of 10 nm on the first electrode. Thereafter, N4,N4,N4,N4′,N4′-tetra([1,1′-biphenyl]-4-yl)-[1,1′-biphenyl]-4,4′-diamine as a hole transport layer (HTL) was vacuum deposited to a thickness of 90 nm on the hole injection layer, followed by depositing N-phenyl-N-(4-(spiro[benzo[d,e]anthracene-7,9′-fluoren]-2′-yl)phenyl)dibenzo[b,d]furan-4-amine as an electron blocking layer (EBL) to a thickness of 15 nm on the hole transport layer (HTL).

Next, a green emitting layer (EML) having a thickness of 25 nm was formed on the electron blocking layer (EBL) by depositing a mixture of 5-3-(dibenzo[b,d]furan-1-yl)phenyl)-5-H-benzofuro[3,2-c]carbazole as a host and Compound 7 as a dopant (weight ratio of host to dopant: 95:5). Thereafter, a mixture of 2-(4-(9,10-di(naphthalene-2-yl)anthracene-2-yl)phenyl)-1-phenyl-1H-benzo[d]imidazole and Liq (weight ratio: 1:1) as an electron transport layer (ETL) was deposited to a thickness of 25 nm on the green emitting layer (EML), followed by depositing Liq as an electron injection layer (EIL) to a thickness of 1 nm on the electron transport layer (ETL). Thereafter, a mixture of magnesium and silver (Ag) (weight ratio: 1:4) as a second electrode was deposited to a thickness of 16 nm on the substrate, followed by depositing N4,N4′-bis[4-[bis(3-methylphenyl)amino]phenyl]-N4,N4′-diphenyl-[1,1′-biphenyl]-4,4′-diamine (DNTPD) as a capping layer to a thickness of 60 nm on the second electrode. A seal cap containing a moisture absorbent was bonded to the capping layer using a UV-curable adhesive to form a protective layer (or encapsulation layer) to provide protection from atmospheric oxygen or moisture, thereby manufacturing an organic light emitting diode.

### Examples 2 to 114

Organic light emitting diodes of Examples 2 to 114 were manufactured in the same manner as in Example 1 except that compounds listed in Table 2 were used as the dopant instead of Compound 7.

### Comparative Examples 1 to 3

Organic light emitting diodes of Comparative Examples 1 to 3 were prepared in the same manner as in Example 1 except that compounds listed in Table 2 were used as the dopant instead of Compound 7. Compounds A to C used in Comparative Examples 1 to 3 were as follows:

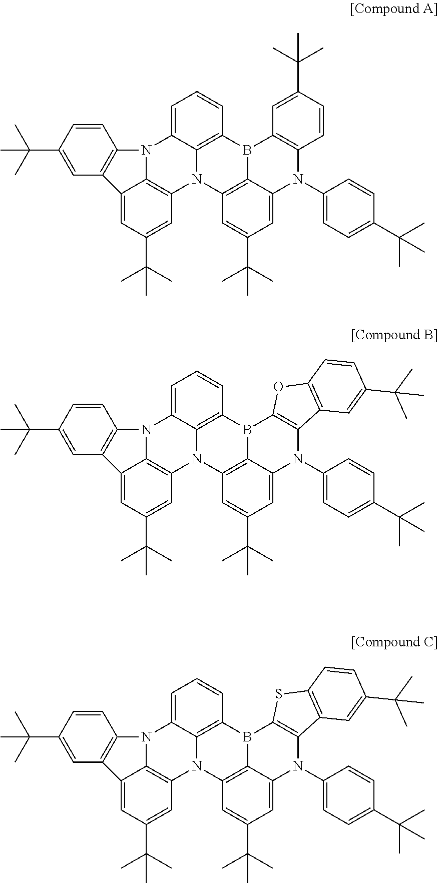

### EXPERIMENTAL Example 1: Performance Test of Organic Light Emitting Diode

For each of the organic light emitting diodes prepared in Examples 1 to 114 and Comparative Examples 1 to 3, driving voltage (V) and external quantum efficiency (EQE) (%) were measured by applying a current of 10 mA/cm² using a spectroradiometer (CS-2000, Konica Minolta Inc.). In addition, lifetime (LT95) (hrs) was determined by measuring the time taken for luminance to decrease to 95% of initial value thereof under a constant current density of 10 mA/cm² using an OLED lifetime test system (M6000, McScience Inc.). Results are shown in Table 2.

TABLE 2

| | | Driving | Luminous | |
|---|---|---|---|---|
| | | voltage | efficacy | Lifetime |
| Item | Dopant | (V) | EQE (%) | LT95 (hrs) |
| Example 1 | Compound 7 | 3.12 | 30.2 | 270 |
| Example 2 | Compound 8 | 3.13 | 30.1 | 270 |
| Example 3 | Compound 31 | 3.13 | 30.1 | 267 |
| Example 4 | Compound 32 | 3.14 | 30.0 | 267 |
| Example 5 | Compound 125 | 3.14 | 29.8 | 265 |
| Example 6 | Compound 126 | 3.15 | 29.7 | 265 |
| Example 7 | Compound 127 | 3.15 | 29.7 | 265 |
| Example 8 | Compound 128 | 3.15 | 29.5 | 265 |
| Example 9 | Compound 129 | 3.16 | 29.3 | 265 |
| Example 10 | Compound 131 | 3.16 | 29.3 | 262 |
| Example 11 | Compound 133 | 3.16 | 29.1 | 260 |
| Example 12 | Compound 134 | 3.18 | 29.1 | 260 |
| Example 13 | Compound 135 | 3.18 | 29.1 | 265 |
| Example 14 | Compound 159 | 3.19 | 29.0 | 265 |
| Example 15 | Compound 213 | 3.19 | 29.0 | 286 |
| Example 16 | Compound 214 | 3.20 | 28.8 | 285 |
| Example 17 | Compound 93 | 3.20 | 28.6 | 258 |
| Example 18 | Compound 96 | 3.21 | 28.4 | 258 |
| Example 19 | Compound 102 | 3.21 | 28.4 | 258 |
| Example 20 | Compound 104 | 3.21 | 28.3 | 256 |
| Example 21 | Compound 107 | 3.22 | 28.3 | 256 |
| Example 22 | Compound 325 | 3.22 | 28.2 | 256 |
| Example 23 | Compound 353 | 3.22 | 28.1 | 252 |
| Example 24 | Compound 55 | 3.22 | 28.2 | 254 |
| Example 25 | Compound 56 | 3.22 | 28.1 | 253 |
| Example 26 | Compound 369 | 3.22 | 28.1 | 277 |
| Example 27 | Compound 382 | 3.23 | 26.2 | 296 |
| Example 28 | Compound 390 | 3.23 | 26.1 | 295 |
| Example 29 | Compound 415 | 3.23 | 26.1 | 290 |
| Example 30 | Compound 426 | 3.24 | 26.1 | 290 |
| Example 31 | Compound 515 | 3.24 | 26.0 | 290 |
| Example 32 | Compound 516 | 3.24 | 26.0 | 290 |
| Example 33 | Compound 519 | 3.25 | 25.8 | 288 |
| Example 34 | Compound 535 | 3.25 | 25.8 | 287 |
| Example 35 | Compound 543 | 3.27 | 25.7 | 287 |
| Example 36 | Compound 545 | 3.27 | 25.6 | 285 |
| Example 37 | Compound 547 | 3.27 | 25.6 | 285 |
| Example 38 | Compound 555 | 3.27 | 25.4 | 283 |
| Example 39 | Compound 59 | 3.27 | 25.5 | 284 |
| Example 40 | Compound 1137 | 3.27 | 25.4 | 283 |
| Example 41 | Compound 573 | 3.27 | 25.3 | 299 |
| Example 42 | Compound 577 | 3.27 | 25.3 | 298 |
| Example 43 | Compound 427 | 3.29 | 25.1 | 285 |
| Example 44 | Compound 428 | 3.29 | 25.8 | 285 |
| Example 45 | Compound 429 | 3.29 | 25.8 | 277 |
| Example 46 | Compound 431 | 3.29 | 25.8 | 277 |
| Example 47 | Compound 433 | 3.30 | 25.6 | 275 |
| Example 48 | Compound 396 | 3.30 | 25.6 | 275 |
| Example 49 | Compound 437 | 3.31 | 25.6 | 273 |
| Example 50 | Compound 450 | 3.31 | 25.3 | 273 |
| Example 51 | Compound 462 | 3.32 | 25.3 | 270 |
| Example 52 | Compound 505 | 3.32 | 25.1 | 289 |
| Example 53 | Compound 633 | 3.35 | 28.0 | 240 |
| Example 54 | Compound 637 | 3.35 | 27.9 | 238 |
| Example 55 | Compound 641 | 3.35 | 27.9 | 238 |
| Example 56 | Compound 645 | 3.36 | 27.8 | 235 |
| Example 57 | Compound 657 | 3.36 | 27.8 | 235 |
| Example 58 | Compound 660 | 3.38 | 27.6 | 230 |
| Example 59 | Compound 661 | 3.38 | 27.6 | 230 |
| Example 60 | Compound 665 | 3.38 | 27.5 | 230 |
| Example 61 | Compound 677 | 3.40 | 27.5 | 228 |
| Example 62 | Compound 681 | 3.40 | 27.3 | 228 |
| Example 63 | Compound 53 | 3.40 | 27.4 | 227 |
| Example 64 | Compound 693 | 3.40 | 27.3 | 250 |
| Example 65 | Compound 697 | 3.41 | 27.1 | 255 |
| Example 66 | Compound 709 | 3.41 | 27.1 | 253 |
| Example 67 | Compound 713 | 3.43 | 27.0 | 252 |
| Example 68 | Compound 721 | 3.43 | 26.8 | 248 |
| Example 69 | Compound 745 | 3.45 | 26.6 | 247 |
| Example 70 | Compound 70 | 3.46 | 29.9 | 260 |
| Example 71 | Compound 821 | 3.46 | 29.9 | 259 |
| Example 72 | Compound 825 | 3.46 | 29.8 | 259 |
| Example 73 | Compound 829 | 3.46 | 29.7 | 259 |
| Example 74 | Compound 833 | 3.47 | 29.8 | 258 |
| Example 75 | Compound 837 | 3.47 | 29.5 | 258 |
| Example 76 | Compound 841 | 3.47 | 29.2 | 259 |
| Example 77 | Compound 936 | 3.48 | 29.0 | 257 |
| Example 78 | Compound 939 | 3.48 | 29.2 | 256 |
| Example 79 | Compound 941 | 3.49 | 29.1 | 254 |
| Example 80 | Compound 945 | 3.49 | 28.9 | 255 |
| Example 81 | Compound 1053 | 3.49 | 28.6 | 275 |
| Example 82 | Compound 1057 | 3.50 | 28.7 | 270 |
| Example 83 | Compound 1085 | 3.50 | 28.7 | 268 |
| Example 84 | Compound 1089 | 3.50 | 28.6 | 273 |
| Example 85 | Compound 759 | 3.50 | 28.5 | 253 |
| Example 86 | Compound 861 | 3.50 | 28.5 | 252 |
| Example 87 | Compound 957 | 3.52 | 28.4 | 252 |
| Example 88 | Compound 69 | 3.52 | 28.3 | 253 |
| Example 89 | Compound 71 | 3.51 | 28.4 | 254 |
| Example 90 | Compound 64 | 3.52 | 28.3 | 252 |
| Example 91 | Compound 72 | 3.51 | 28.3 | 254 |
| Example 92 | Compound 997 | 3.52 | 28.3 | 275 |
| Example 93 | Compound 1077 | 3.52 | 28.2 | 273 |
| Example 94 | Compound 1117 | 3.59 | 22.0 | 238 |
| Example 95 | Compound 1118 | 3.59 | 22.0 | 237 |
| Example 96 | Compound 1119 | 3.59 | 22.0 | 235 |
| Example 97 | Compound 1120 | 3.61 | 21.5 | 235 |
| Example 98 | Compound 1121 | 3.61 | 21.5 | 234 |
| Example 99 | Compound 1122 | 3.63 | 21.2 | 235 |
| Example 100 | Compound 58 | 3.63 | 21.1 | 234 |
| Example 101 | Compound 1124 | 3.63 | 21.0 | 256 |
| Example 102 | Compound 1125 | 3.65 | 20.9 | 260 |
| Example 103 | Compound 1126 | 3.67 | 20.7 | 255 |
| Example 104 | Compound 1123 | 3.62 | 20.8 | 257 |
| Example 105 | Compound 62 | 3.53 | 28.0 | 250 |
| Example 106 | Compound 14 | 3.54 | 27.8 | 249 |
| Example 107 | Compound 38 | 3.54 | 27.6 | 249 |
| Example 108 | Compound 78 | 3.54 | 27.7 | 269 |
| Example 109 | Compound 1131 | 3.55 | 27.5 | 247 |
| Example 110 | Compound 1132 | 3.55 | 27.0 | 267 |
| Example 111 | Compound 1133 | 3.55 | 26.9 | 242 |
| Example 112 | Compound 1134 | 3.55 | 26.8 | 243 |
| Example 113 | Compound 1135 | 3.55 | 26.8 | 241 |
| Example 114 | Compound 1136 | 3.56 | 26.6 | 240 |
| Comparative | Compound A | 3.75 | 19.1 | 180 |
| Example 1 | | | | |
| Comparative | Compound B | 3.77 | 18.8 | 178 |
| Example 2 | | | | |
| Comparative | Compound C | 3.80 | 18.5 | 175 |
| Example 3 | | | | |

As described above, the organic compound represented by Chemical Formula 1 has a polycyclic aromatic structure with a core structure containing boron (B) and nitrogen (N) atoms on the right and left sides of boron, wherein the nitrogen atom on the left side of the core is fused to a carbazole group, the nitrogen atom on the right side is fused to circle A together with boron to form a fused, and Ar₁ is bonded to the nitrogen atom on the right side of a backbone including the core structure via a linker L. Accordingly, as can be seen from the results of Experimental Example, the organic light emitting diodes including an emitting layer containing the compound represented by Chemical Formula 1 as a dopant thereof exhibited a lower driving voltage compared to the organic light emitting diodes of Comparative Examples 1 to 3, in which Compounds A to C not conforming to Chemical Formula 1 were used.

Furthermore, as described above, fusion of the carbazole group to the left side of the core and fusion of circle A to the right side of the core suppress structural deformation of molecules, and a resonance structure spread within the molecules through connection between multiple aromatic rings as depicted in Chemical Formula 1 ensures a stable structure, thereby enhancing stability of the dopant molecules. Accordingly, the organic light emitting diodes according to the present invention exhibited increased lifetime compared to the organic light emitting diodes of Comparative Examples 1 to 3.

Additionally, due to the substituent introduced onto a benzene ring located at a bottom of the backbone containing the core, the organic light emitting diodes according to the present invention exhibited enhanced luminous efficacy compared to Comparative Examples 1 to 3.

### Experimental Example 2: Measurement of Photoluminescence (“PL” for Short)

To evaluate suitability of the compound represented by Chemical Formula 1 as a dopant of a green emitting layer, emission wavelength (unit: nm) and corresponding intensity (unit: a.u.) were determined using Gaussian software (B3LYP DFT 6-31G(d) by Gaussian 16.0) by a photoluminescence (PL) measurement method. An emission wavelength corresponding to a maximum PL intensity peak in a PL spectrum is shown in Table 3.

TABLE 3

| | Emission | | Emission | | Emission |
|---|---|---|---|---|---|
| | wavelength | | wavelength | | wavelength |
| Compound | (nm) | Compound | (nm) | Compound | (nm) |
| Compound 55 | 515 | Compound 56 | 512 | Compound 58 | 513 |
| Compound 59 | 519 | Compound 62 | 525 | Compound 64 | 523 |
| Compound 69 | 522 | Compound 70 | 527 | Compound 71 | 523 |
| Compound 72 | 525 | Compound 1137 | 517 | t-DABNA | 458 |

Similar to t-DABNA represented by the following formula, the compound represented by Chemical Formula 1 according to the present invention has a polycyclic aromatic structure with a core structure containing boron (B) and nitrogen (N) atoms on the right and left sides of the boron. However, unlike t-DABNA, in the compound represented Chemical Formula 1 according to the present invention, the nitrogen atom on the left side of the core is fused to a carbazole group and the nitrogen atom on the right side of the core is fused to circle A together with boron to a form a fused ring. Consequently, as can be seen from the PL measurement results, the compound represented Chemical Formula 1 emits light in the green spectrum (wavelength range: about 500 nm to about 580 nm).

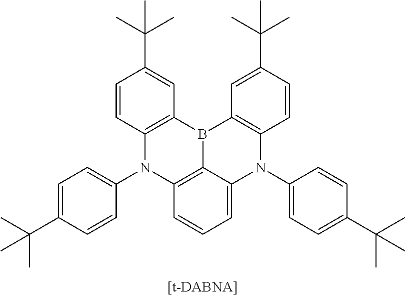 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention.

1. An organic compound represented by Chemical Formula 1: 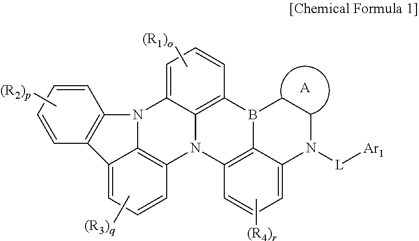
where circle A has a structure selected from among structures (A-1) and (A-2): 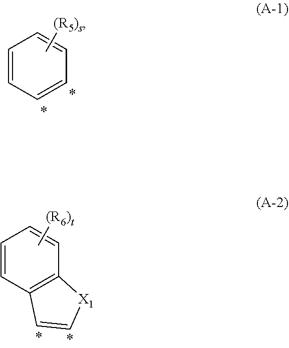
(where * is a linking site and X₁ is oxygen (O) or sulfur (S));
o, q, and r are integers selected from among 0 to 3, and p, s, and t are integers selected from among 0 to 4;
L is a single bond or a substituted or unsubstituted C₆ to C₃₀ arylene group;
Ar₁ is selected from among a substituted or unsubstituted C₆ to C₃₀ aryl group, a substituted or unsubstituted C₅ to C₆₀ heteroaryl group, a substituted or unsubstituted C₆ to C₃₀ arylamino group, and a compound represented by Formula a1 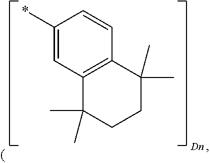
where Dn denotes the number of substituted deuterium atoms therein, n being an integer selected from among 0 to 3);
R₁ to R₆ are identical to each other or different from each other, are each independently one selected from the group consisting of hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group, and form a structure represented by Formula b 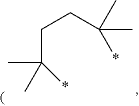 [SMILES: *C(C)(C)CCC(*)(C)C]
where * is a linking site) with a functional group adjacent thereto; and,
when substituted, L, Ar₁, and R₁ to R₆ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

2. The organic compound according to claim 1, wherein Chemical Formula 1 is represented by one of Chemical Formulas 2 to 4: 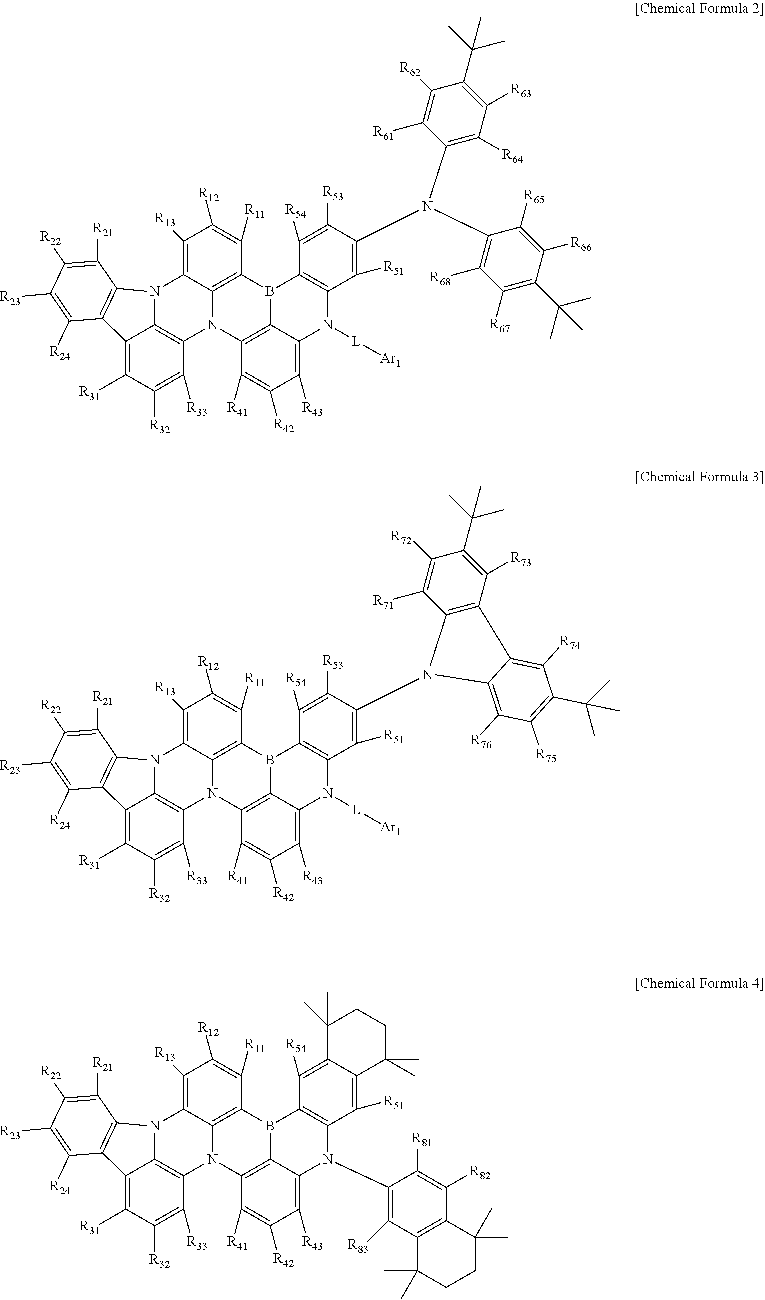
where L and Ar₁ are the same as defined in Chemical Formula 1;
R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, and R₈₁ to R₈₃ are identical to each other or different from each other, are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group; and,
when substituted, R₁₁ to R₁₃, R₂₁ to R₂₄, R₃₁ to R₃₃, R₄₁ to R₄₃, R₅₁, R₅₃, R₅₄, R₆₁ to R₆₈, R₇₁ to R₇₆, R₈₁ to R₈₃, and Ar₁ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

3. The organic compound according to claim 1, wherein Chemical Formula 1 is represented by Chemical Formula 5: 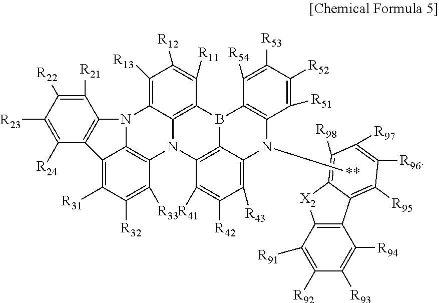
where R₁₁ to R₁₃, R₂₁ to R₂₄, R₃₁ to R₃₃, R₄₁ to R₄₃, R₅₁ to R₅₄, and R₉₁ to R₉₈ are identical to each other or different from each other and are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆a heteroaryl group, and a substituted or unsubstituted C₆ to C₃₀ arylamino group;
X₂ is oxygen (O) or sulfur (S);
** is a linking site, the linking site being one selected from among R₉₅, R₉₆, R₉₇, and R₉₈; and,
when substituted, R₁₁ to R₁₃, R₂₁ to R₂₄, R₃₁ to R₃₃, R₄₁ to R₄₃, R₅₁ to R₅₄, and R₉₁ to R₉₈ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

4. The organic compound according to claim 1, wherein Chemical Formula 1 is represented by one of Chemical Formulas 6 to 9: 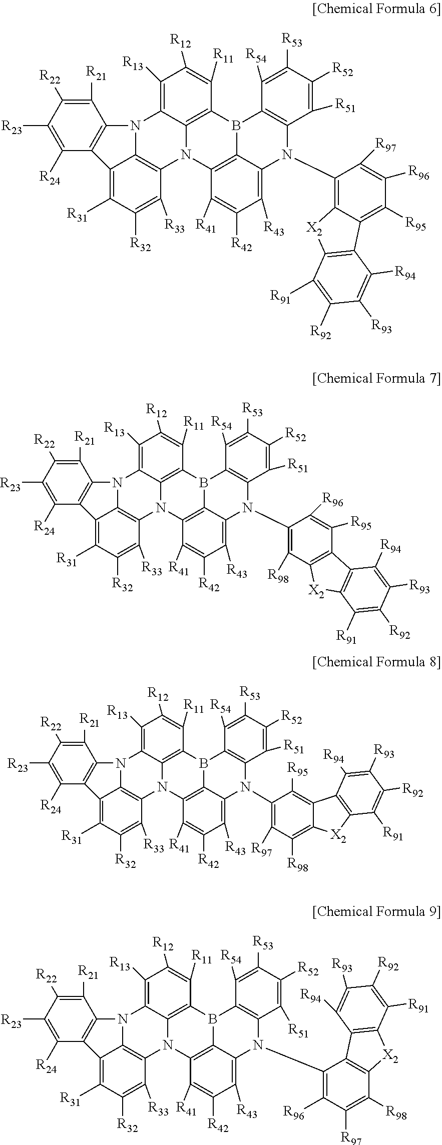
where R₁₁ to R₁₃, R₂₁ to R₂₄, R₃₁ to R₃₃, R₄₁ to R₄₃, R₅₁ to R₅₄, and R₉₁ to R₉₈ are identical to each other or different from each other and are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group;
X₂ is oxygen (O) or sulfur (S); and,
when substituted, R₁₁ to R₁₃, R₂₁ to R₂₄, R₃₁ to R₃₃, R₄₁ to R₄₃, R₅₁ to R₅₄, and R₉₁ to R₉₈ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

5. The organic compound according to claim 1, wherein Chemical Formula 1 is represented by Chemical Formula 10: 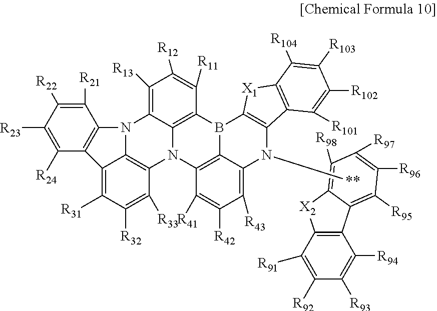
where X₁ and X₂ are each independently oxygen (O) or sulfur (S);
R₁₁ to R₁₃, R₂₁ to R₂₄, R₃₁ to R₃₃, R₄₁ to R₄₃, R₉₁ to R₉₈, and R₁₀₁ to R₁₀₄ are identical to each other or different from each other and are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group;
** is a linking site, the linking site being one selected from among R₉₅, R₉₆, R₉₇, and R₉₈; and,
when substituted, R₁₁ to R₁₃, R₂₁ to R₂₄, R₃₁ to R₃₃, R₄₁ to R₄₃, R₉₁ to R₉₈, and R₁₀₁ to R₁₀₄ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

6. The organic compound according to claim 1, wherein Chemical Formula 1 is represented by one of Chemical Formulas 11 to 14: 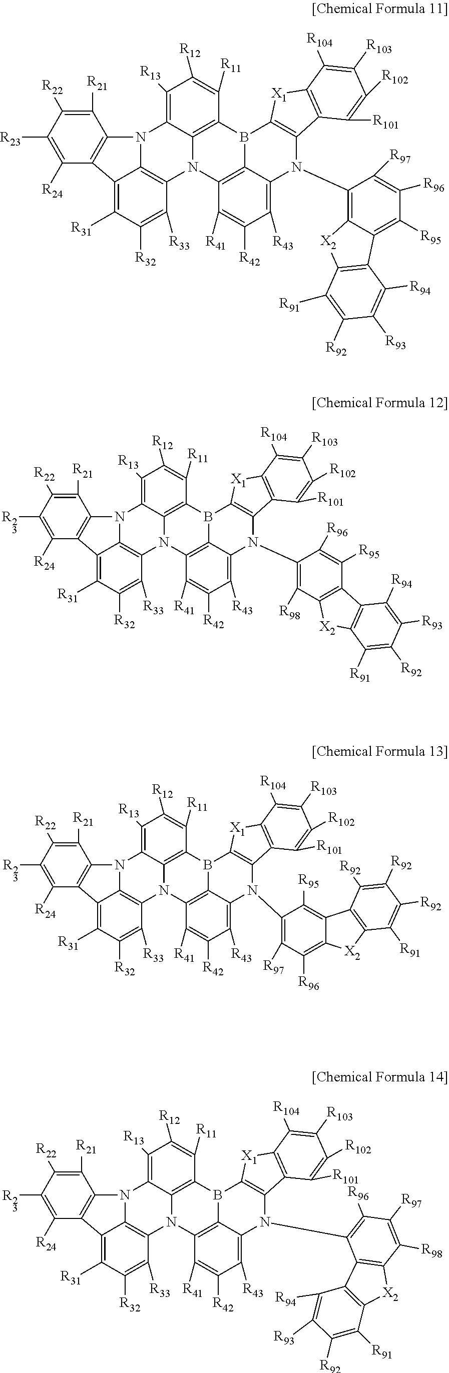
where X₁ and X₂ are each independently oxygen (O) or sulfur (S);
R₁₁ to R₁₃, R₂₁ to R₂₄, R₃₁ to R₃₃, R₄₁ to R₄₃, R₉₁ to R₉₈, and R₁₀₁ to R₁₀₄ are identical to each other or different from each other and are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆a heteroaryl group, and a substituted or unsubstituted C₆ to C₃₀ arylamino group; and,
when substituted, R₁₁ to R₁₃, R₂₁ to R₂₄, R₃₁ to R₃₃, R₄₁ to R₄₃, R₉₁ to R₉₈, and R₁₀₁ to R₁₀₄ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

7. The organic compound according to claim 1, wherein Chemical Formula 1 is represented by Chemical Formula 15: 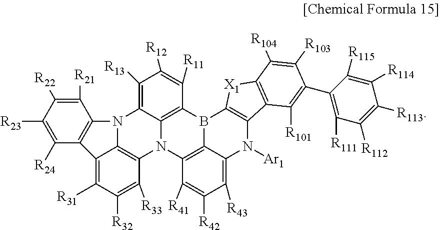
where X₁ is oxygen (O) or sulfur (S);
Ar₁ is the same as defined in Chemical Formula 1;
R₁₁ to R₁₃, R₂₁ to R₂₄, R₃₁ to R₃₃, R₄₁ to R₄₃, R₁₀₁, R₁₀₃, R₁₀₄, and R₁₁₁ to R₁₁₅ are identical to each other or different from each other and are each independently one selected from among hydrogen, deuterium, a cyano group, a substituted or unsubstituted C₁ to C₃₀ alkyl group, a substituted or unsubstituted C₆ to C₃₀ aryl group, a substituted or unsubstituted C₅ to C₆₀ heteroaryl group, and a substituted or unsubstituted C₆ to C₃₀ arylamino group; and,
when substituted, R₁₁ to R₁₃, R₂₁ to R₂₄, R₃₁ to R₃₃, R₄₁ to R₄₃, R₁₀₁, R₁₀₃, R₁₀₄, and R₁₁₁ to R₁₁₅ are each independently substituted with at least one substituent selected from among deuterium, a cyano group, a nitro group, a halogen group, a hydroxyl group, a C₁ to C₃₀ alkyl group, a C₂ to C₃₀ alkenyl group, a C₂ to C₂₄ alkynyl group, a C₂ to C₃₀ heteroalkyl group, a C₆ to C₃₀ aralkyl group, a C₃ to C₂₀ cycloalkyl group, a C₃ to C₂₀ heterocycloalkyl group, a C₆ to C₃₀ aryl group, a C₂ to C₃₀ heteroaryl group, a C₃ to C₃₀ heteroarylalkyl group, a C₁ to C₃₀ alkoxy group, a C₁ to C₃₀ alkylsilyl group, a C₆ to C₃₀ arylsilyl group, and a C₆ to C₃₀ aryloxy group and, when a plurality of substituents is used, the substituents are identical to each other or different from each other.

8. An organic light emitting diode comprising:
a first electrode;
a second electrode facing the first electrode; and
one or more organic layers disposed between the first electrode and the second electrode,
wherein at least one of the organic layers comprises the organic compound according to claim 1.

9. The organic light emitting diode according to claim 8, wherein the organic layer comprising the organic compound according to claim 1 is a green emitting layer, and the organic compound according to claim 1 is used as a dopant of the green emitting layer.

10. The organic light emitting diode according to claim 8, wherein the organic layer further comprise at least one selected from among a hole injection layer, a hole transport layer, an electron transport layer, and an electron injection layer.
